(19) United States
(12) Patent Application Publication
(10) Pub. No.: US 2023/0363255 A1
(43) Pub. Date: Nov. 9, 2023

(54) CONDENSED CYCLIC COMPOUND, ORGANIC LIGHT-EMITTING DEVICE INCLUDING THE SAME, AND ELECTRONIC APPARATUS INCLUDING THE ORGANIC LIGHT-EMITTING DEVICE

(71) Applicant: Samsung Electronics Co., Ltd., Suwon-si (KR)

(72) Inventors: Eunsuk KWON, Suwon-si (KR); Sangho PARK, Suwon-si (KR); Eunhye AN, Yongin-si (KR); Jong Soo KIM, Suwon-si (KR); Hwang Suk KIM, Suwon-si (KR); Yeon Sook CHUNG, Suwon-si (KR); Yongsik JUNG, Suwon-si (KR); Giwook KANG, Yongin-si (KR); Eunjeong CHOI, Yongin-si (KR)

(21) Appl. No.: 18/068,734

(22) Filed: Dec. 20, 2022

(30) Foreign Application Priority Data
May 4, 2022 (KR) 10-2022-0055744

(51) Int. Cl. H10K 85/40; C07F 7/08

(52) U.S. Cl. CPC H01L 51/0094; C07F 7/0812; H01L 51/5028

(57) ABSTRACT

Provided are a condensed cyclic compound represented by Formula 1, an organic light-emitting device including the same, and an electronic apparatus including the organic light-emitting device.

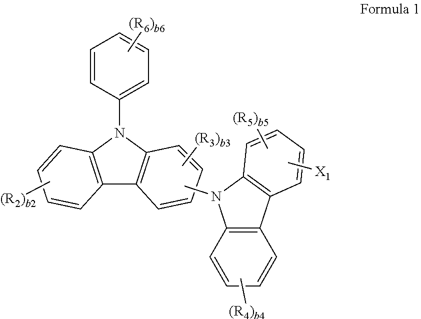

The details of Formula 1 are as described herein.

### CROSS-REFERENCE TO RELATED APPLICATION

This application claims priority under 35 U.S.C. § 119 to Korean Patent Application No. 10-2022-0055744, filed on May 4, 2022, in the Korean Intellectual Property Office, the disclosure of which is incorporated by reference herein in its entirety.

### BACKGROUND

### 1. Field

The disclosure relates to a condensed cyclic compound, an organic light-emitting device including the same, and an electronic apparatus including the organic light-emitting device.

### 2. Description of the Related Art

Organic light-emitting devices are self-emissive devices that, as compared with devices of the related art, have wide viewing angles, high contrast ratios, short response times, and excellent characteristics in terms of luminance, driving voltage, and response speed, and produce full-color images.

In an example, an organic light-emitting device includes an anode, a cathode, and an organic layer that is arranged between the anode and the cathode and includes an emission layer. A hole transport region may be arranged between the anode and the emission layer, and an electron transport region may be arranged between the emission layer and the cathode. Holes provided from the anode move toward the emission layer through the hole transport region, and electrons provided from the cathode move toward the emission layer through the electron transport region. Carriers, such as holes and electrons, recombine in the emission layer to produce excitons. These excitons transition from an excited state to a ground state, thereby generating light.

### SUMMARY

Provided are a condensed cyclic compound, an organic light-emitting device including the same, and an electronic apparatus including the organic light-emitting device.

Additional aspects will be set forth in part in the description which follows and, in part, will be apparent from the description, or may be learned by practice of the presented embodiments of the disclosure.

According to an aspect of the disclosure, provided is a condensed cyclic compound represented by Formula 1.

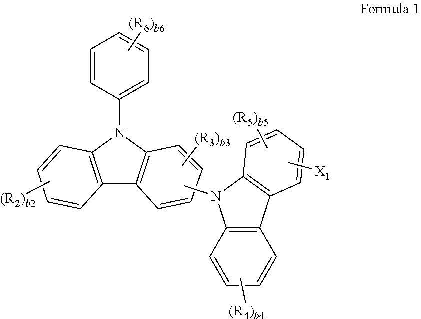

In Formula 1,
X₁ is represented by Formula 2,

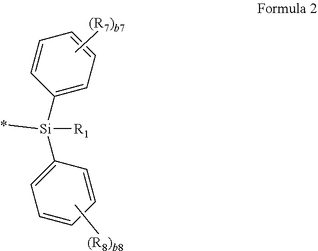

in Formulae 1 and 2,
R₁ is a substituted or unsubstituted C₁-C₆₀ alkyl group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group,
R₂ is hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), or —B(Q₁)(Q₂),
R₃ is hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted monovalent non-aromatic condensed polycyclic group, —Si(Q₁)(Q₂)(Q₃), —N(Q₁)(Q₂), or —B(Q₁)(Q₂),
R₄ to R₈ are each independently hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), or —B(Q₁)(Q₂),
b2 and b4 are each independently an integer from 1 to 4,
b3 and b5 are each independently an integer from 1 to 3,
b6 to b8 are each independently an integer from 1 to 5,
Q₁ to Q₃ are each independently hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, a C₁-C₆₀ alkyl group substituted with at least one deuterium, —F, a cyano group, a C₁-C₂₀ alkyl group, a C₆-C₃₀ aryl group, or any combination thereof, or a C₆-C₆₀ aryl group substituted with at least one deuterium, —F, a cyano group, a C₁-C₂₀ alkyl group, a C₆-C₃₀ aryl group, or any combination thereof, and
* may indicate a binding site to a neighboring atom.

According to another aspect of the disclosure, an organic light-emitting device includes a first electrode, a second electrode, and an organic layer arranged between the first electrode and the second electrode and including an emission layer, wherein the organic layer includes the condensed cyclic compound.

According to another aspect of the disclosure, an electronic apparatus includes the organic light-emitting device.

### BRIEF DESCRIPTION OF THE DRAWING

The above and other aspects, features, and advantages of certain embodiments of the disclosure will be more apparent from the following description taken in conjunction with FIGURE which shows a schematic cross-sectional view of an organic light-emitting device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the FIGURES, to explain aspects. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly on the other element or intervening elements may be present therebetween In contrast, when an element is referred to as being “directly on” another element, there are no intervening elements present

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise.

“Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the FIGURES. It will be understood that relative terms are intended to encompass different orientations of the device in addition to the orientation depicted in the FIGURES. For example, if the device in one of the FIGURES is turned over, elements described as being on the “lower” side of other elements would then be oriented on “upper” sides of the other elements. The exemplary term “lower,” can therefore, encompasses both an orientation of “lower” and “upper,” depending on the particular orientation of the FIGURE. Similarly, if the device in one of the FIGURES is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded Thus, the regions illustrated in the figures are schematic in nature and their shapes are not intended to illustrate the precise shape of a region and are not intended to limit the scope of the present claims.

### [Condensed Cyclic Compound]

An aspect of the disclosure provides a condensed cyclic compound represented by Formula 1:

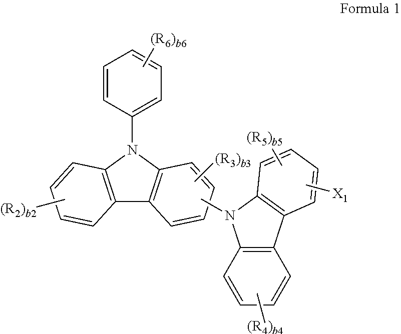

wherein, in Formula 1,
X₁ may be represented by Formula 2:

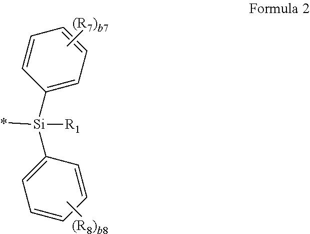

wherein, in Formulae 1 and 2, R₁ to R₈ and b2 to b8 may each be the same as described herein, and
* may indicate a binding site to a neighboring atom.

In an embodiment, X₁ may be represented by Formula 2-1:

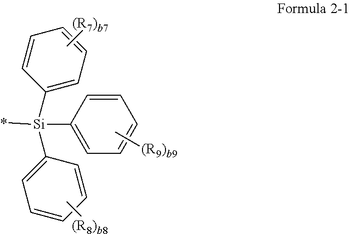

wherein, in Formula 2-1,
R₇ to R₉ may each be the same as described in connection with R₇,
b7 to b9 may each be the same as described in connection with b7, and
* may indicate a binding site to a neighboring atom.

In Formula 2, R₁ may be a substituted or unsubstituted C₁-C₆₀ alkyl group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

In an embodiment, R₁ may be: a C₁-C₂₀ alkyl group unsubstituted or substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, 2.2.1[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a pyridinyl group, or a pyrimidinyl group; or
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group; or
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, an imidazopyrimidinyl group, —Si(Q₁₁)(Q₁₂)(Q₁₃), —B(Q₁₁)(Q₁₂), —N(Q₁₁)(Q₁₂), or any combination thereof, and
Q₁₁ to Q₁₃ may each independently be:
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group; or
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, or a naphthyl group, each substituted with at least one deuterium, a phenyl group, or a combination thereof.

In one or more embodiments, in Formula 2, R₁ may be: a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group; or
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, an imidazopyrimidinyl group, or any combination thereof.

In one or more embodiments, in Formula 2, R₁ may be a phenyl group unsubstituted or substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, an imidazopyrimidinyl group. or any combination thereof.

In Formula 1, R₂ may be hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), or —B(Q₁)(Q₂), and
Q₁ to Q₃ may each independently be hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, a C₁-C₆₀ alkyl group substituted with at least one deuterium, —F, a cyano group, a C₁-C₂₀ alkyl group, a C₆-C₃₀ aryl group, or any combination thereof, or a C₆-C₆₀ aryl group substituted with at least one deuterium, —F, a cyano group, a C₁-C₂₀ alkyl group, a C₆-C₃₀ aryl group, or any combination thereof.

In an embodiment, in Formula 1, R₂ may be: hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, or a C₁-C₂₀ alkoxy group;
a C₁-C₂₀ alkyl group or a C₁-C₂₀ alkoxy group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a pyridinyl group, a pyrimidinyl group, or any combination thereof;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, an imidazopyrimidinyl group, —Si(Q₁₁)(Q₁₂)(Q₁₃), —B(Q₁₁)(Q₁₂), —N(Q₁₁)(Q₁₂), or any combination thereof; or
—Si(Q₁)(Q₂)(Q₃), —B(Q₁)(Q₂), or —N(Q₁)(Q₂), and
Q₁ to Q₃ and Q₁₁ to Q₁₃ may each independently be:
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group; or
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, or a naphthyl group, each substituted with at least one deuterium, a phenyl group, or any combination thereof.

In one or more embodiments, in Formula 1, R₂ may be: hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, or a phosphoric acid group or a salt thereof;
a C₁-C₂₀ alkyl group unsubstituted or substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, or any combination thereof;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, or a chrysenyl group;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, or a chrysenyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, —Si(Q₁₁)(Q₁₂)(Q₁₃), or any combination thereof; or
—Si(Q₁)(Q₂)(Q₃), and
Q₁ to Q₃ and Q₁₁ to Q₁₃ may each independently be:
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group; or
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, or a naphthyl group, each substituted with at least one deuterium, a phenyl group, or any combination thereof.

In Formula 1, R₃ may be hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted monovalent non-aromatic condensed polycyclic group, —Si(Q₁)(Q₂)(Q₃), —N(Q₁)(Q₂), or —B(Q₁)(Q₂), and
Q₁ to Q₃ may each independently be hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, a C₁-C₆₀ alkyl group substituted with at least one deuterium, —F, a cyano group, a C₁-C₂₀ alkyl group, a C₆-C₃₀ aryl group, or any combination thereof, or a C₆-C₆₀ aryl group substituted with at least one deuterium, —F, a cyano group, a C₁-C₂₀ alkyl group, a C₆-C₃₀ aryl group, or any combination thereof.

In an embodiment, in Formula 1, R₃ may be: hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, or a C₁-C₂₀ alkoxy group, a C₁-C₂₀ alkyl group or a C₁-C₂₀ alkoxy group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a pyridinyl group, a pyrimidinyl group, or any combination thereof;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, or a chrysenyl group;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, or a chrysenyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, an imidazopyrimidinyl group, —Si(Q₁₁)(Q₁₂)(Q₁₃), —B(Q₁₁)(Q₁₂), or —N(Q₁₁)(Q₁₂); or
—Si(Q₁)(Q₂)(Q₃), —B(Q₁)(Q₂), or —N(Q₁)(Q₂), and
Q₁ to Q₃ and Q₁₁ to Q₁₃ may each independently be:
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group; or
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, or a naphthyl group, each substituted with at least one deuterium, a phenyl group, or any combination thereof.

In one or more embodiments, in Formula 1, R₃ may be: hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, or a phosphoric acid group or a salt thereof;
a C₁-C₂₀ alkyl group unsubstituted or substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, or a naphthyl group;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, or a chrysenyl group;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, or a chrysenyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, —Si(Q₁₁)(Q₁₂)(Q₁₃), or a combination thereof; or
—Si(Q₁)(Q₂)(Q₃), and
Q₁ to Q₃ and Q₁₁ to Q₁₃ may each independently be:
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group; or
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, or a naphthyl group, each substituted with at least one deuterium, a phenyl group, or any combination thereof.

In Formulae 1 and 2, R₄ to R₈ may each independently be hydrogen, deuterium, —F, —C₁, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), or —B(Q₁)(Q₂), and
Q₁ and Q₂ may each independently be hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, a C₁-C₆₀ alkyl group substituted with at least one deuterium, —F, a cyano group, a C₁-C₂₀ alkyl group, a C₆-C₃₀ aryl group, or any combination thereof, or a C₆-C₆₀ aryl group substituted with at least one deuterium, —F, a cyano group, a C₁-C₂₀ alkyl group, a C₆-C₃₀ aryl group or any combination thereof.

In an embodiment, in Formulae 1 and 2, R₄ to R₈ may each independently be hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, or a C₁-C₂₀ alkoxy group;
a C₁-C₂₀ alkyl group or a C₁-C₂₀ alkoxy group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a pyridinyl group, a pyrimidinyl group, or any combination thereof;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, an imidazopyrimidinyl group, —B(Q₁₁)(Q₁₂), —N(Q₁₁)(Q₁₂), or any combination thereof; or
—B(Q₁)(Q₂) or —N(Q₁)(Q₂), and
Q₁, Q₂, Q₁₁, and Q₁₂ may each independently be:
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group; or
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, or a naphthyl group, each substituted with at least one deuterium, a phenyl group, or any combination thereof, or.

In one or more embodiments, in Formulae 1 and 2, R₄ to R₈ may each independently be: hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, or a phosphoric acid group or a salt thereof; a C₁-C₂₀ alkyl group unsubstituted or substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, or any combination thereof;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, or any combination thereof;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, or a chrysenyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, —B(Q₁₁)(Q₁₂), —N(Q₁₁)(Q₁₂), or any combination thereof; or
—B(Q₁)(Q₂) or —N(Q₁)(Q₂), and
Q₁, Q₂, Q₁₁, and Q₁₂ may each independently be:
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group; or
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, or a naphthyl group, each substituted with at least one deuterium, a phenyl group, or any combination thereof.

In an embodiment, in Formula 1, i) R₂ may be hydrogen, deuterium, a methyl group, an ethyl group, an n-propyl group, an isopropyl group, an n-butyl group, an isobutyl group, a sec-butyl group, a tert-butyl group, a phenyl group, a carbazolyl group, or one of a methyl group, an ethyl group, an n-propyl group, an isopropyl group, an n-butyl group, an isobutyl group, a sec-butyl group, a tert-butyl group, a phenyl group, or a carbazolyl group, each substituted with deuterium; ii) R₃ may be hydrogen, deuterium, a methyl group, an ethyl group, an n-propyl group, an isopropyl group, an n-butyl group, an isobutyl group, a sec-butyl group, a tert-butyl group, a phenyl group, or a methyl group, an ethyl group, an n-propyl group, an isopropyl group, an n-butyl group, an isobutyl group, a sec-butyl group, a tert-butyl group, or a phenyl group, each substituted with deuterium; iii) R₆ may be hydrogen, deuterium, a phenyl group, or a biphenyl group, or a phenyl group or a biphenyl group, each substituted with deuterium; iv) R₄ may be hydrogen, deuterium, a methyl group, an ethyl group, an n-propyl group, an isopropyl group, an n-butyl group, an isobutyl group, a sec-butyl group, a tert-butyl group, a phenyl group, a carbazolyl group, or a methyl group, an ethyl group, an n-propyl group, an isopropyl group, an n-butyl group, an isobutyl group, a sec-butyl group, a tert-butyl group, a phenyl group, or a carbazolyl group, each substituted with deuterium; or v) R₅ may be hydrogen, deuterium, a methyl group, an ethyl group, an n-propyl group, an isopropyl group, an n-butyl group, an isobutyl group, a sec-butyl group, a tert-butyl group, a phenyl group, a carbazolyl group, or a methyl group, an ethyl group, an n-propyl group, an isopropyl group, an n-butyl group, an isobutyl group, a sec-butyl group, a tert-butyl group, a phenyl group, or a carbazolyl group, each substituted with deuterium.

In an embodiment, in Formula 2, R₁ may be a methyl group, an ethyl group, an n-propyl group, an isopropyl group, an n-butyl group, an isobutyl group, a sec-butyl group, a tert-butyl group, a phenyl group, or one of a methyl group, an ethyl group, an n-propyl group, an isopropyl group, an n-butyl group, an isobutyl group, a sec-butyl group, a tert-butyl group, or a phenyl group, each substituted with deuterium.

In one or more embodiments, in Formulae 1 and 2, R₁ may be a methyl group, an ethyl group, an n-propyl group, an isopropyl group, an n-butyl group, an isobutyl group, a sec-butyl group, a tert-butyl group, a phenyl group, or a methyl group, an ethyl group, an n-propyl group, an isopropyl group, an n-butyl group, an isobutyl group, a sec-butyl group, a tert-butyl group, and a phenyl group, each substituted with deuterium; R₂ may be hydrogen, deuterium, a methyl group, an ethyl group, an n-propyl group, an isopropyl group, an n-butyl group, an isobutyl group, a sec-butyl group, a tert-butyl group, a phenyl group, a carbazolyl group, or one of a methyl group, an ethyl group, an n-propyl group, an isopropyl group, an n-butyl group, an isobutyl group, a sec-butyl group, a tert-butyl group, a phenyl group, or a carbazolyl group, each substituted with deuterium; R₃ may be hydrogen, deuterium, a methyl group, an ethyl group, an n-propyl group, an isopropyl group, an n-butyl group, an isobutyl group, a sec-butyl group, a tert-butyl group, a phenyl group, or one of a methyl group, an ethyl group, an n-propyl group, an isopropyl group, an n-butyl group, an isobutyl group, a sec-butyl group, a tert-butyl group, or a phenyl group, each substituted with deuterium; R₄ may be hydrogen, deuterium, a methyl group, an ethyl group, an n-propyl group, an isopropyl group, an n-butyl group, an isobutyl group, a sec-butyl group, a tert-butyl group, a phenyl group, a carbazolyl group, or a methyl group, an ethyl group, an n-propyl group, an isopropyl group, an n-butyl group, an isobutyl group, a sec-butyl group, a tert-butyl group, a phenyl group, or a carbazolyl group, each substituted with deuterium; R₅ may be hydrogen, deuterium, a methyl group, an ethyl group, an n-propyl group, an isopropyl group, an n-butyl group, an isobutyl group, a sec-butyl group, a tert-butyl group, a phenyl group, a carbazolyl group, or one of a methyl group, an ethyl group, an n-propyl group, an isopropyl group, an n-butyl group, an isobutyl group, a sec-butyl group, a tert-butyl group, a phenyl group, or a carbazolyl group, each substituted with deuterium; and R₆ may be hydrogen, deuterium, a phenyl group, a biphenyl group, or a phenyl group or a biphenyl group, each substituted with deuterium.

In Formulae 1 and 2, b2 to b8 may respectively indicate the number of substitution of R₂ to R₈, wherein b2 and b4 may each independently be an integer from 1 to 4, b3 and b5 may each independently be an integer from 1 to 3, and b6 to b8 may each independently be an integer from 1 to 5.

A moiety represented by

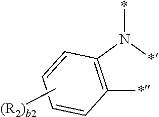

in Formula 1 may be represented by Formula 1A:

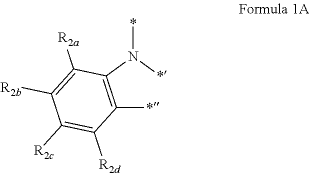

wherein, in Formula 1A,
R₂ₐ to R_{2d} may each be the same as described in connection with R₂, and
*, *′, and *″ each indicate a binding site to a neighboring atom.

A moiety represented by

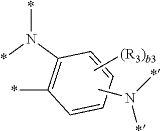

in Formula 1 may be represented by one of Formulae 1B-1 to 1B-4:

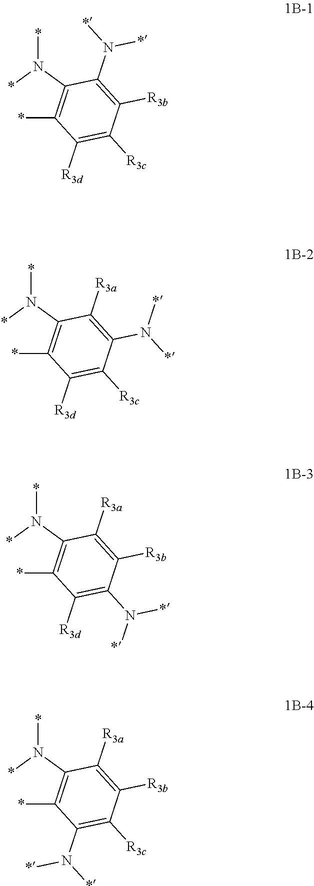

wherein, in Formulae 1B-1 to 1B-4,

R₃ₐ to R_{3d} may each be the same as described in connection with R₃, and
* and *′ each indicate a binding site to a neighboring atom.

A moiety represented by

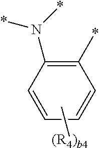

in Formula 1 may be represented by Formula 1C:

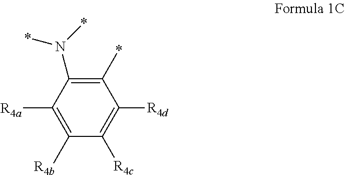

wherein, in Formula 1C,
R₄ₐ to R_{4d} may each be the same as described in connection with R₄, and
* indicates a binding site to a neighboring atom.

A moiety represented by

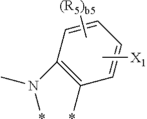

in Formula 1 may be represented by one of Formulae 1D-1 to 1D-4:

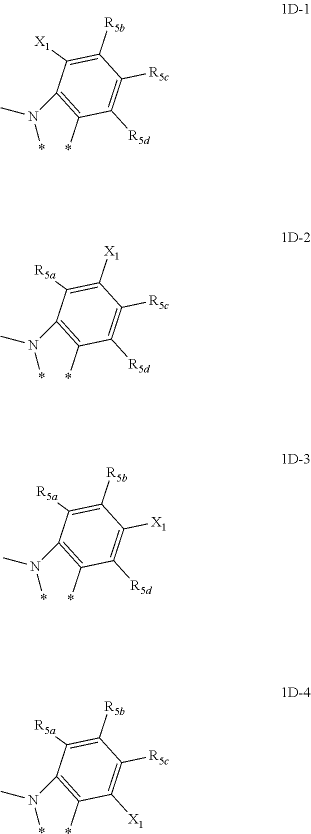

wherein, in Formulae 1D-1 to 1D-4,
R₅ₐ to R_{5d} may each be the same as described in connection with R₅, and
* indicates a binding site to a neighboring atom.

A moiety represented by

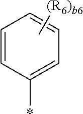

in Formula 1 may be represented by Formula 1E:

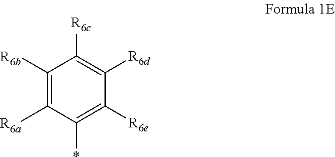

wherein, in Formula 1E,
R₆ₐ to R₆ₑ may each be the same as described in connection with R₆, and
* indicates a binding site to a neighboring atom.

A moiety represented by

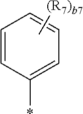

in Formula 1 may be represented by Formula 1F,
a moiety represented by

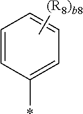

in Formula 1 may be represented by Formula 1G, and
R₁ may be represented by Formula 1H:

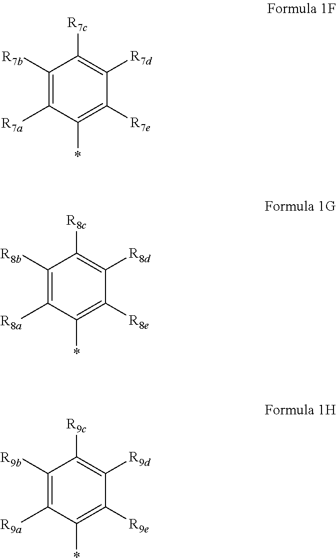

wherein, in Formulae 1F, 1G, and 1H,
R₇ₐ to R₇ₑ, R₈ₐ to R₈ₑ, and R₉ₐ to R₉ₑ may each be the same as described in connection with R₇, and
* indicates a binding site to a neighboring atom.

In an embodiment, the condensed cyclic compound may be represented by Formula 1-1:

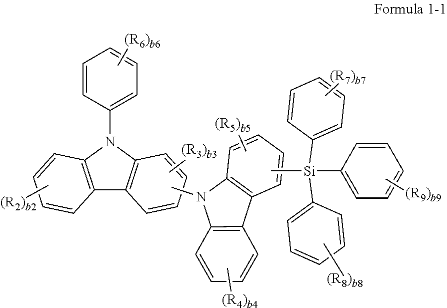

wherein, in Formula 1-1,
R₂ to R₈ and b2 to b8 may each be the same as described herein,
R₉ may be the same as described in connection with R₇, and
b9 may be the same as described in connection with b7.

For example, a moiety represented by

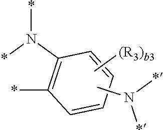

in Formula 1-1 may be represented by one of Formulae 1B-1 to 1B-4.

For example, a moiety represented by

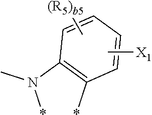

in Formula 1-1 may be represented by one of Formulae 1D-1 to 1D-4.

In one or more embodiments, the condensed cyclic compound may be represented by one of Formulae 1-11 to 1-14:

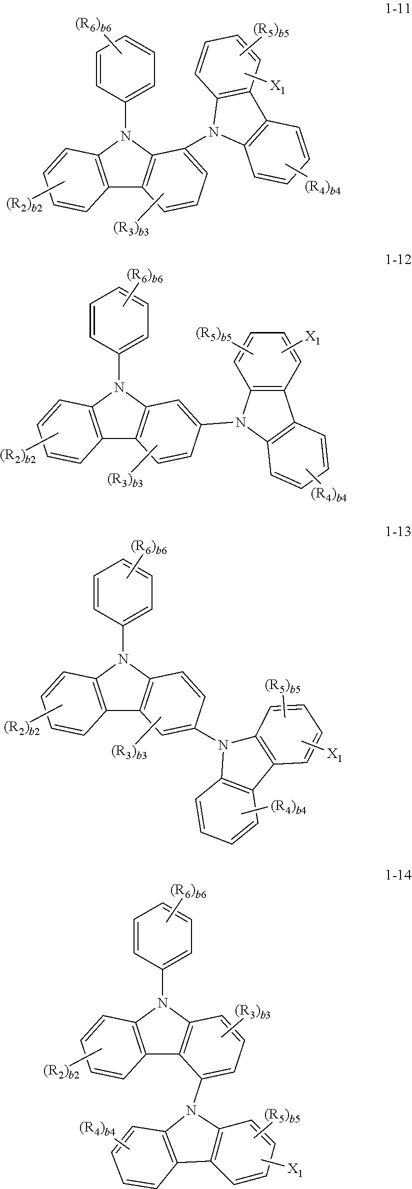

wherein, in Formulae 1-11 to 1-14,
X₁, R₂ to R₆, and b2 to b6 may each be the same as described herein.

For example, a moiety represented by

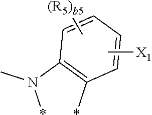

in Formulae 1-11 to 1-14 may be represented by one of Formulae 1D-1 to 1D-4.

In one or more embodiments, the condensed cyclic compound may be represented by one of Formulae 1-21 to 1-24:

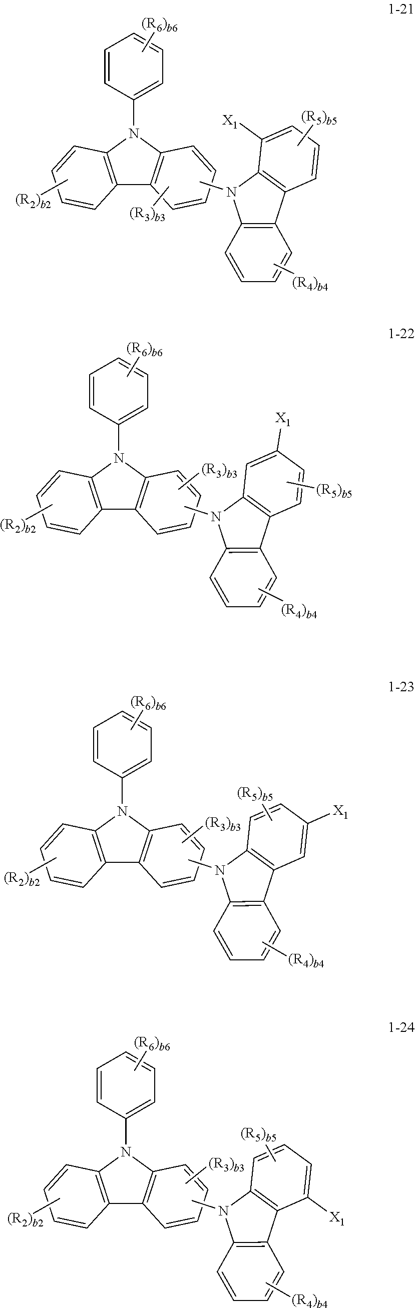

wherein, in Formulae 1-21 to 1-24,
X₁, R₂ to R₆, and b2 to b6 may each be the same as described herein.

For example, a moiety represented by

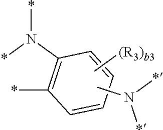

in Formulae 1-21 to 1-24 may be represented by one of Formulae 1B-1 to 1B-4.

In an embodiment, the condensed cyclic compound may be of Group I, but embodiments are not limited thereto:

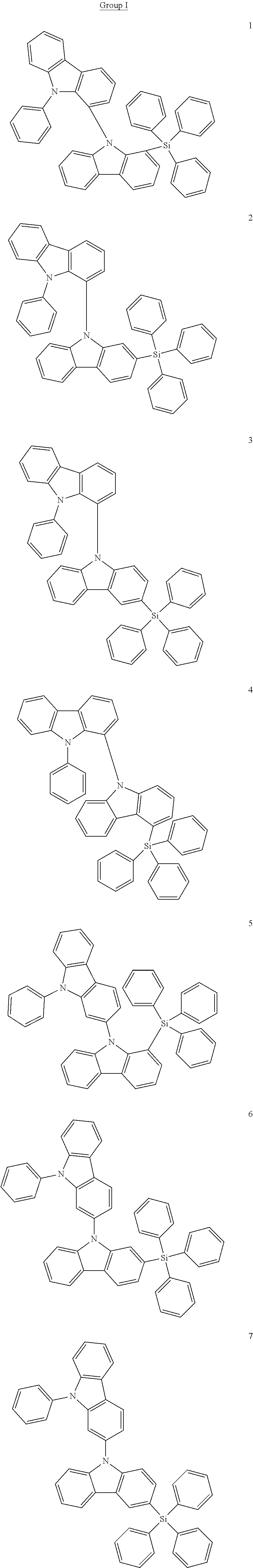

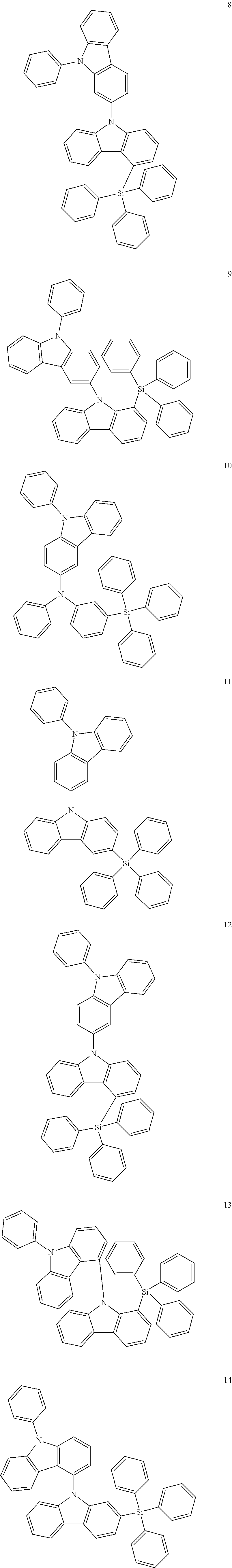

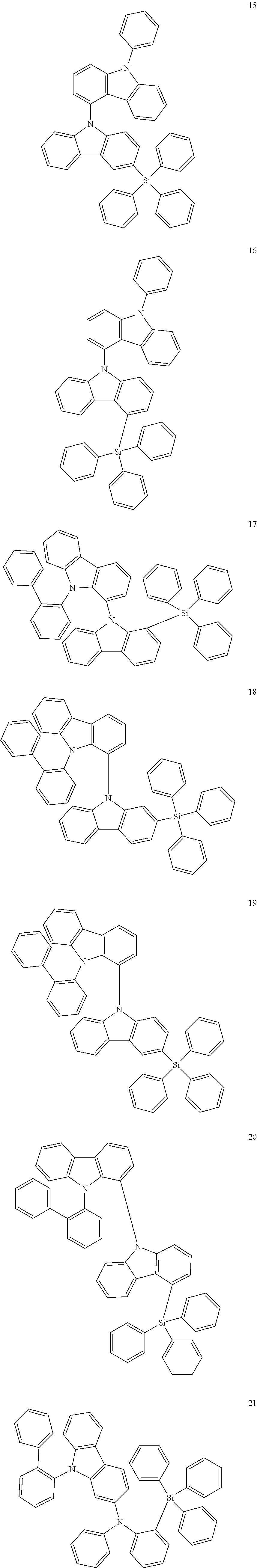

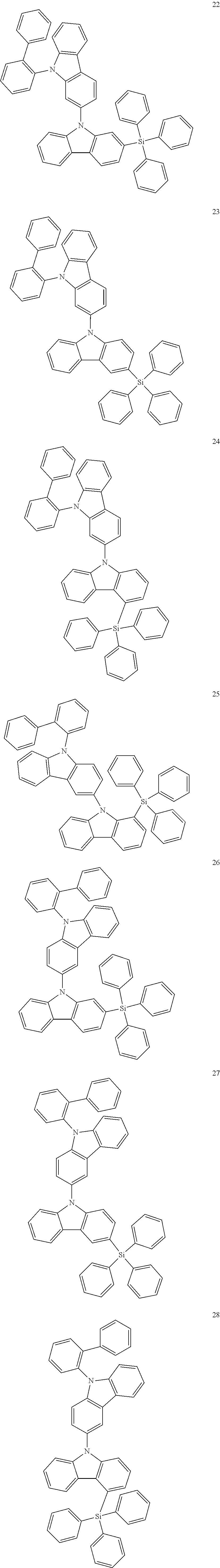

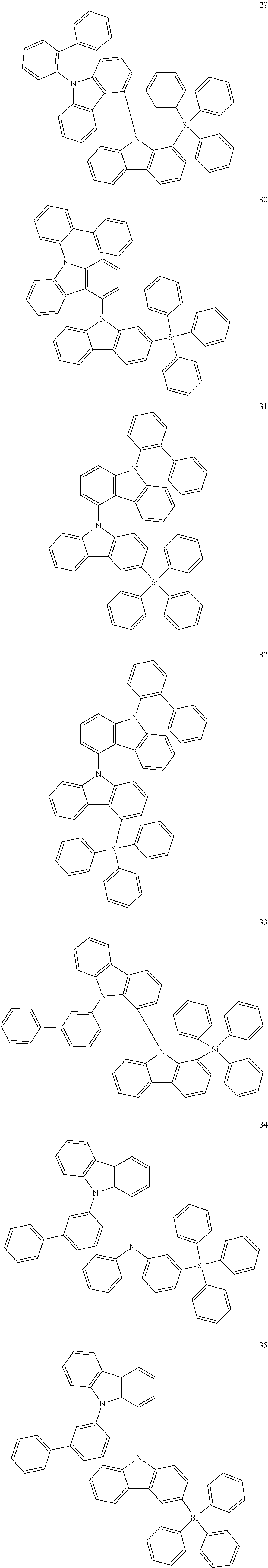

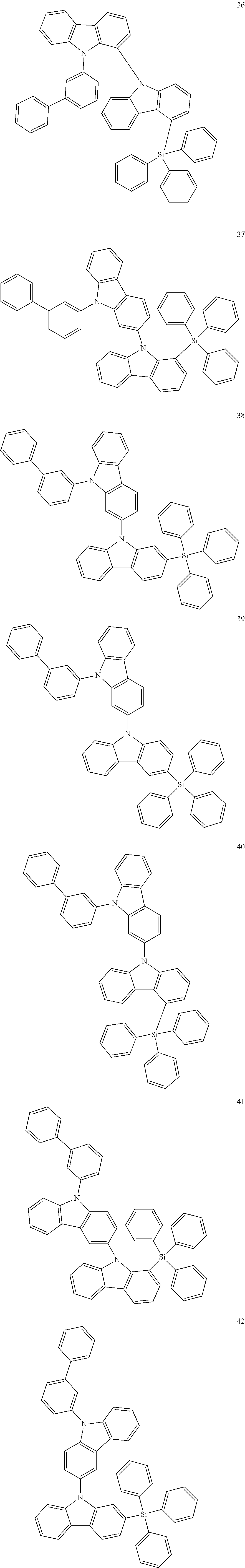

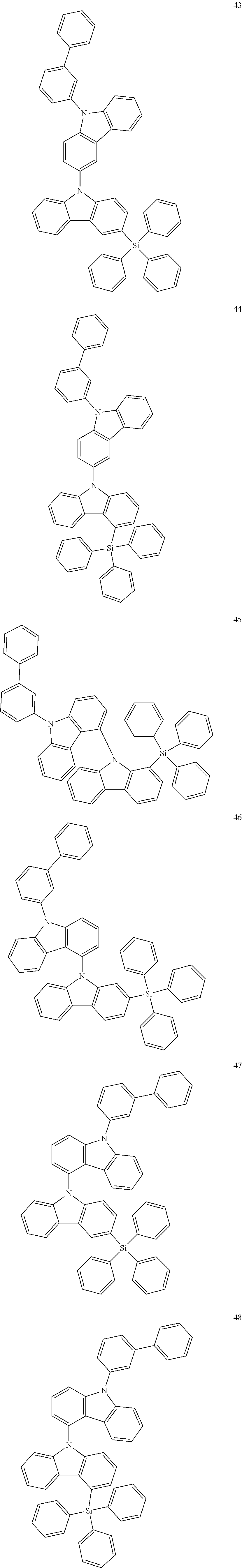

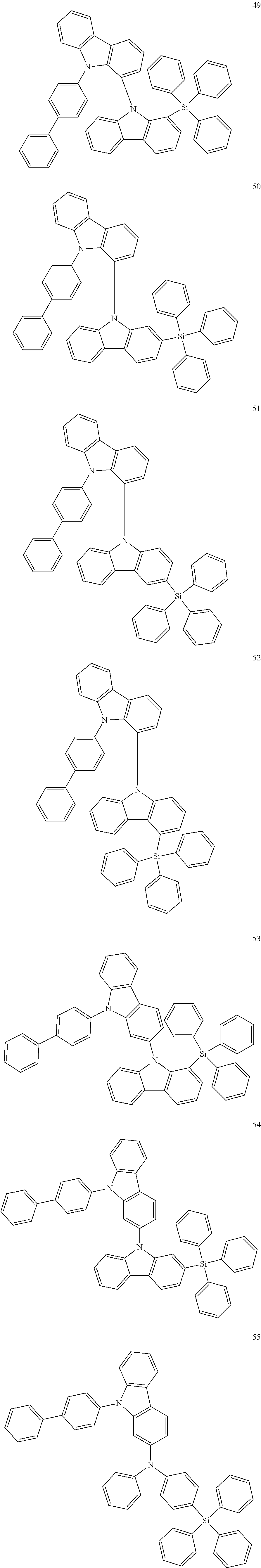

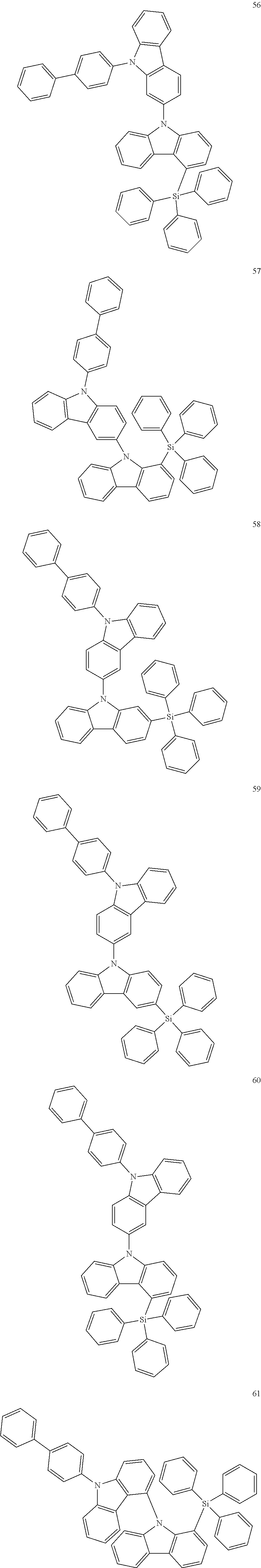

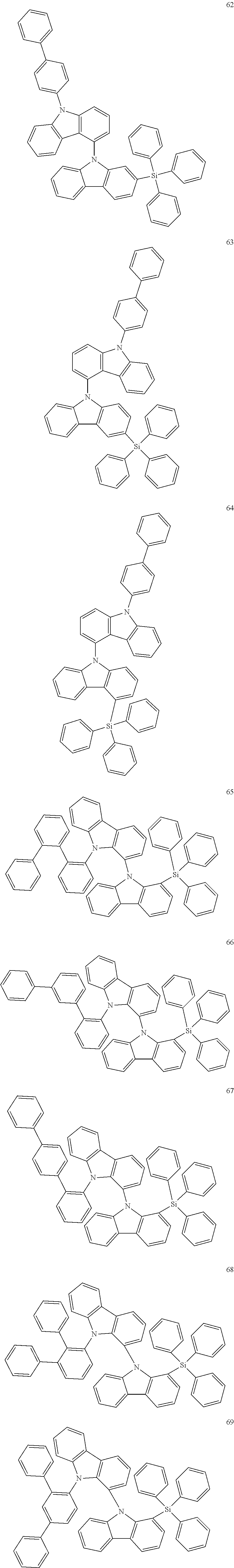

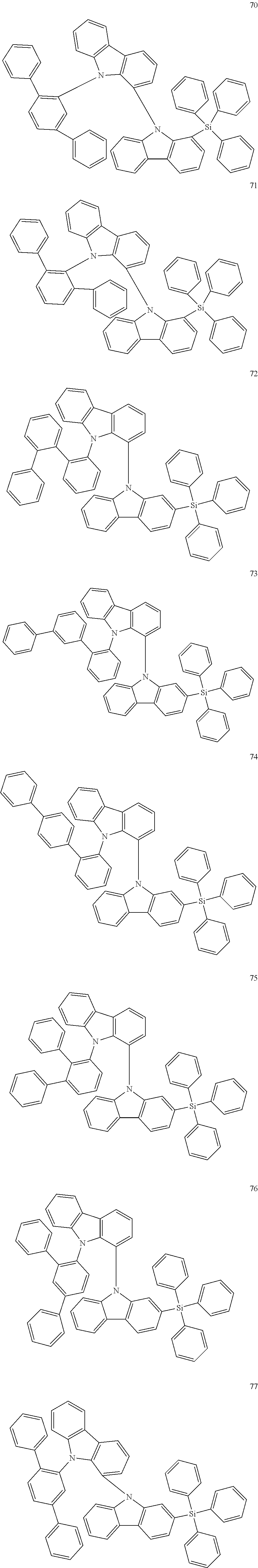

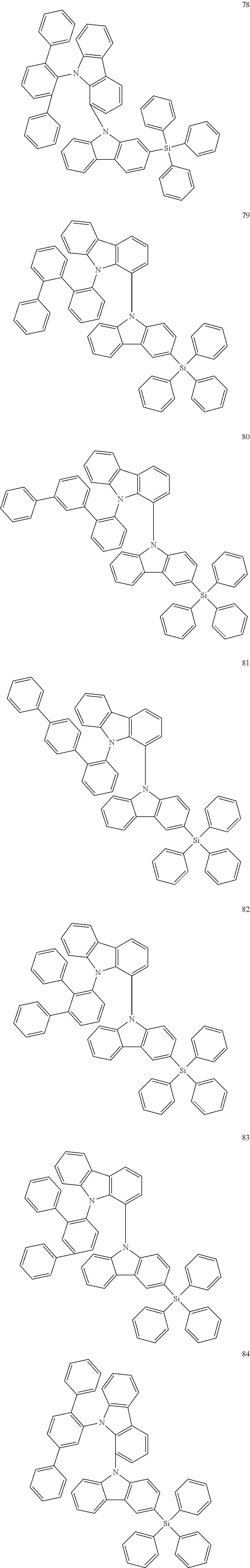

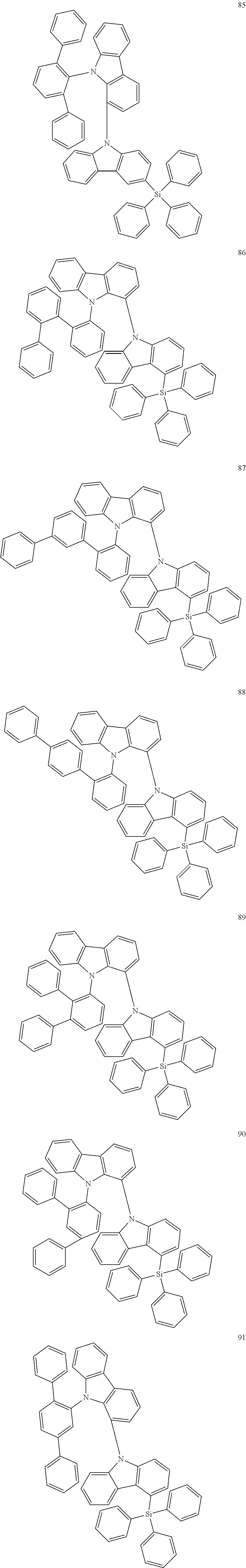

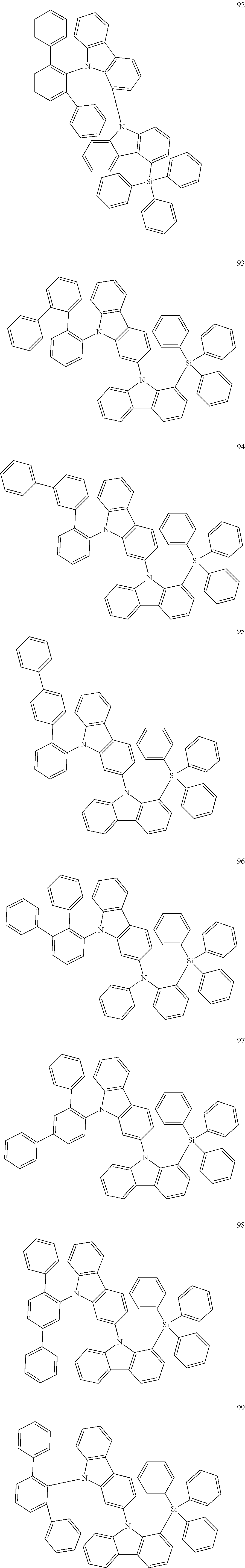

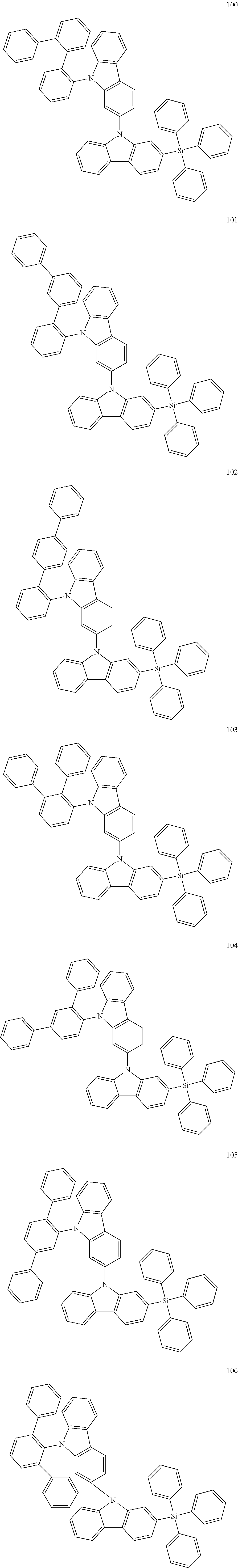

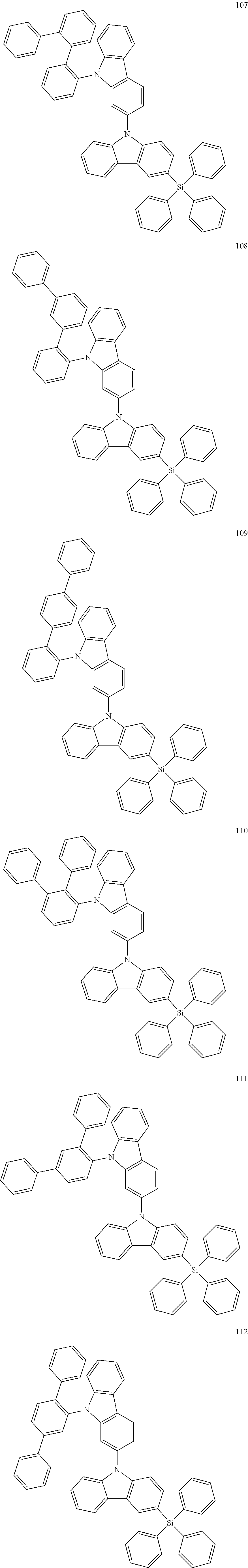

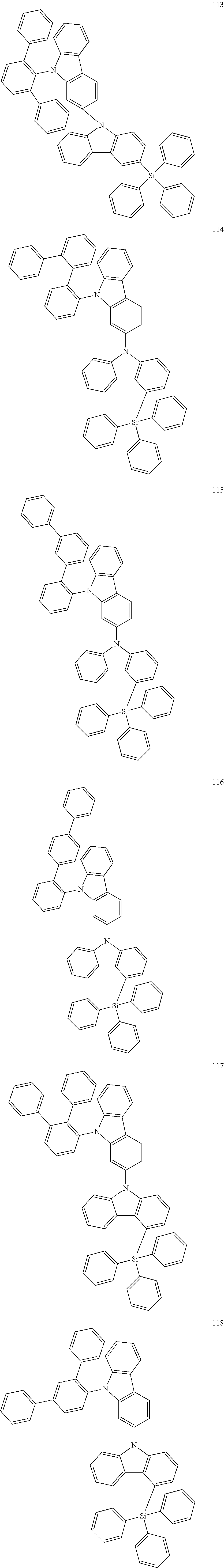

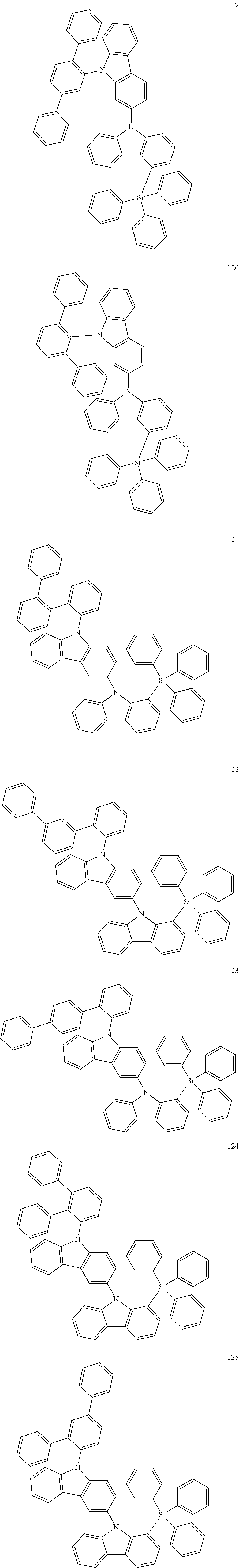

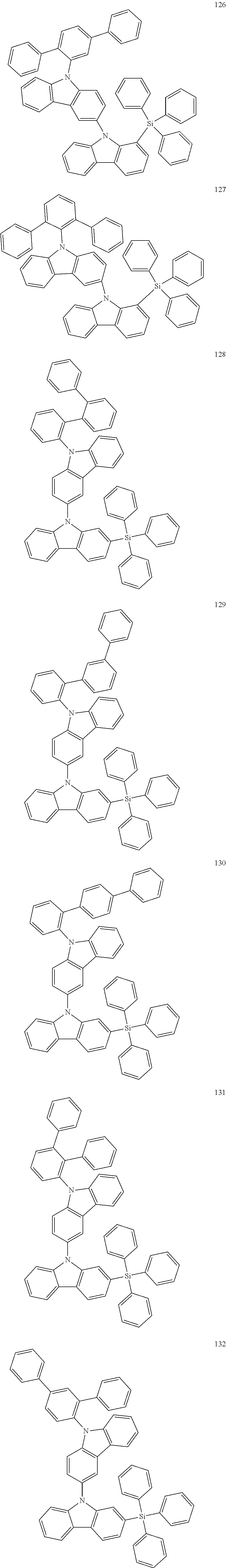

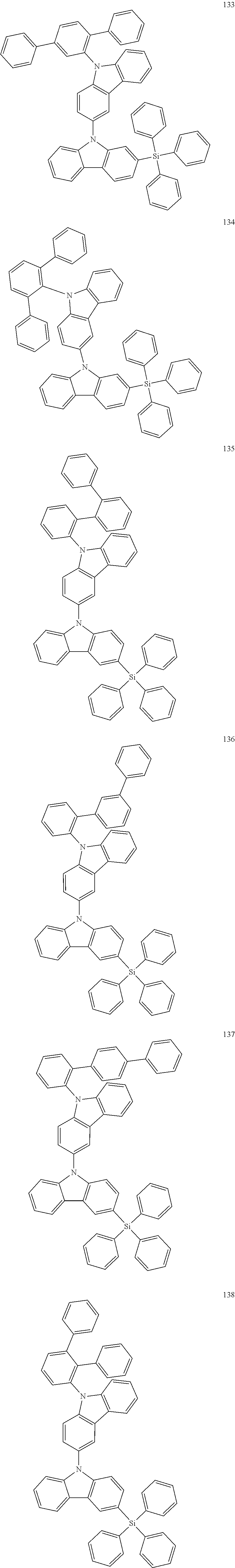

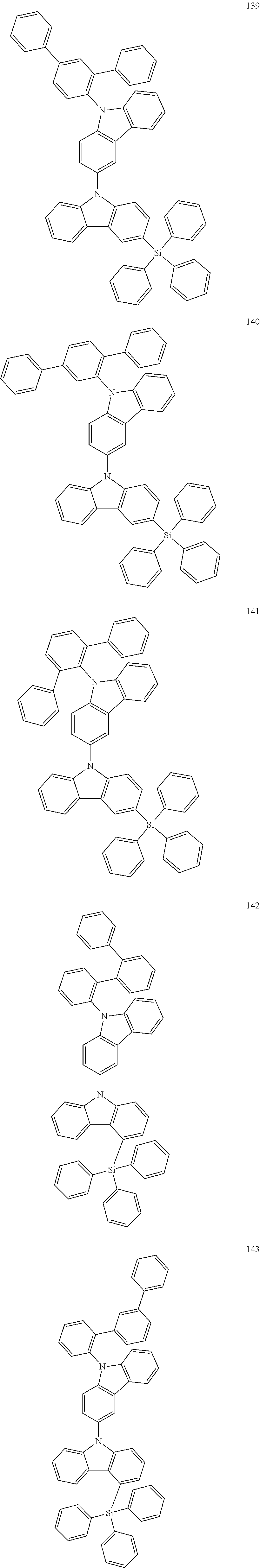

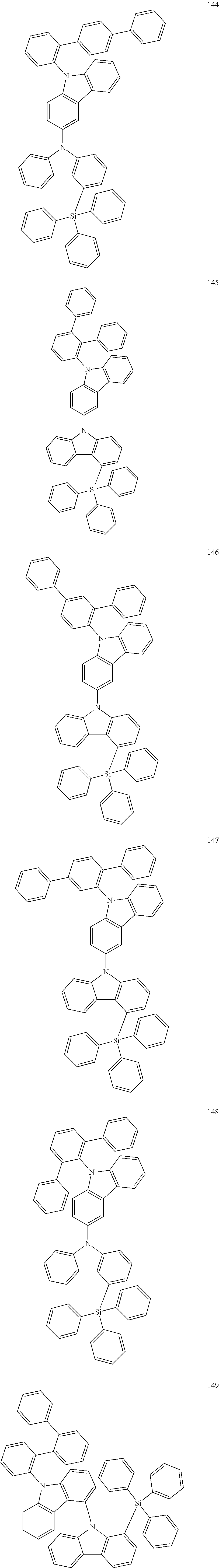

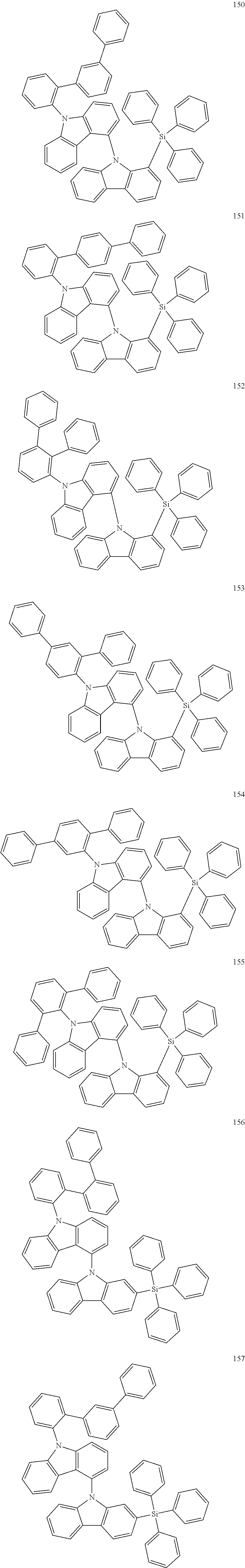

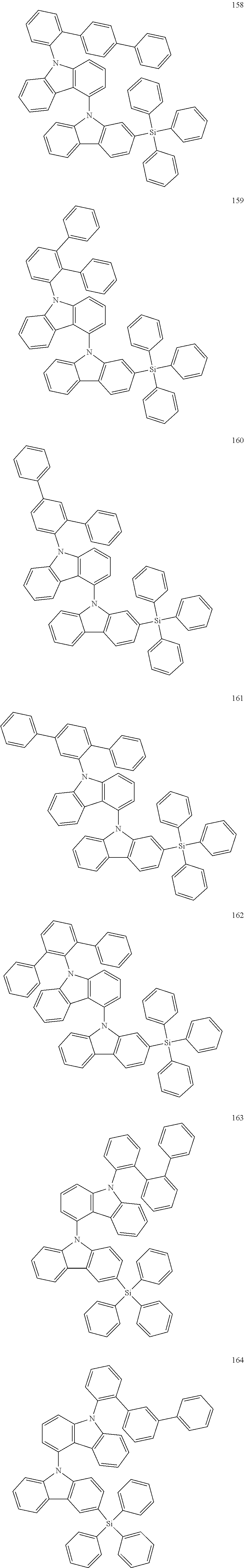

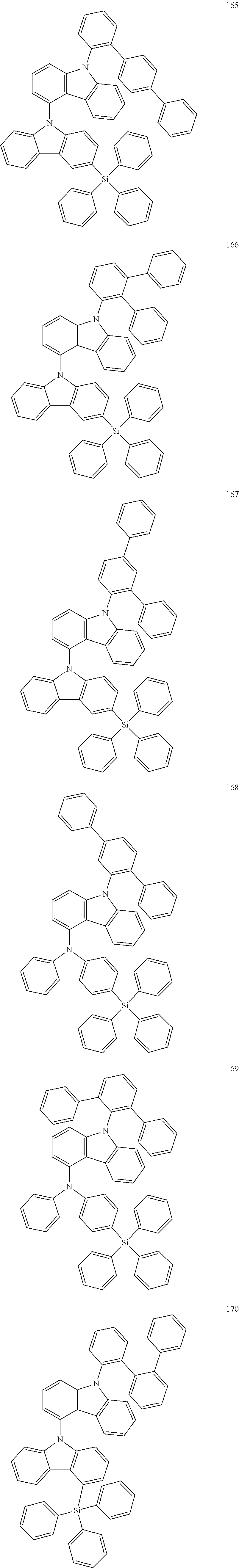

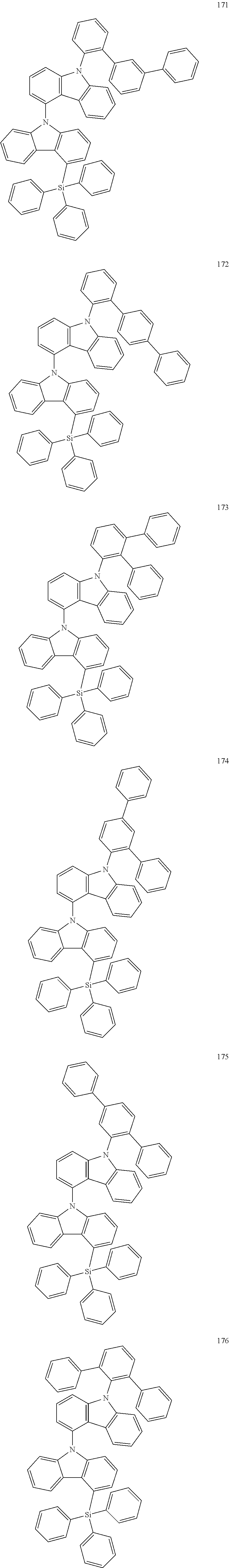

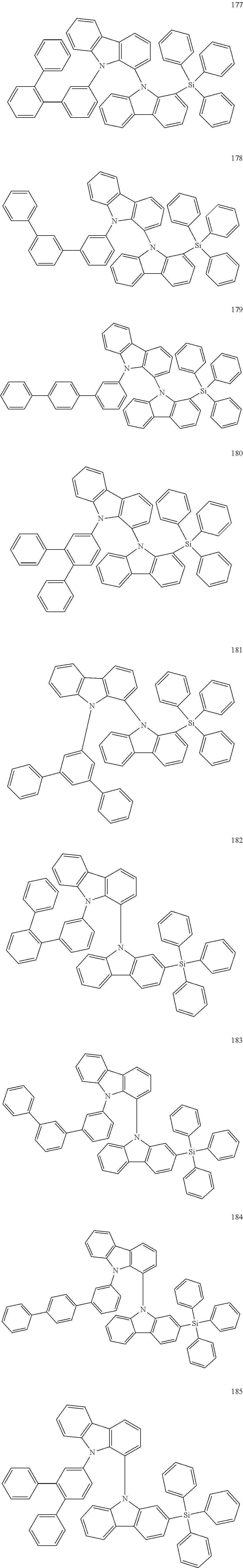

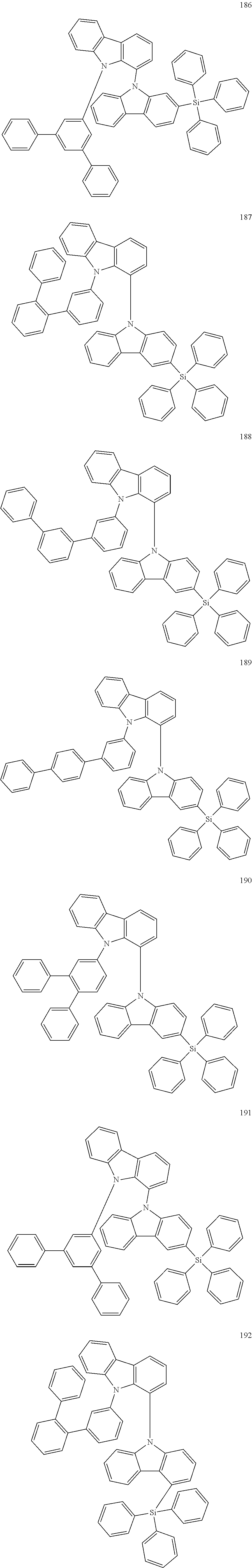

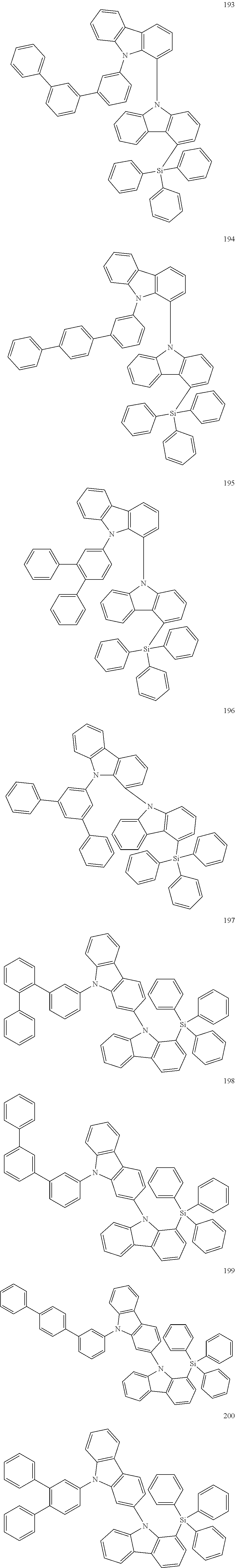

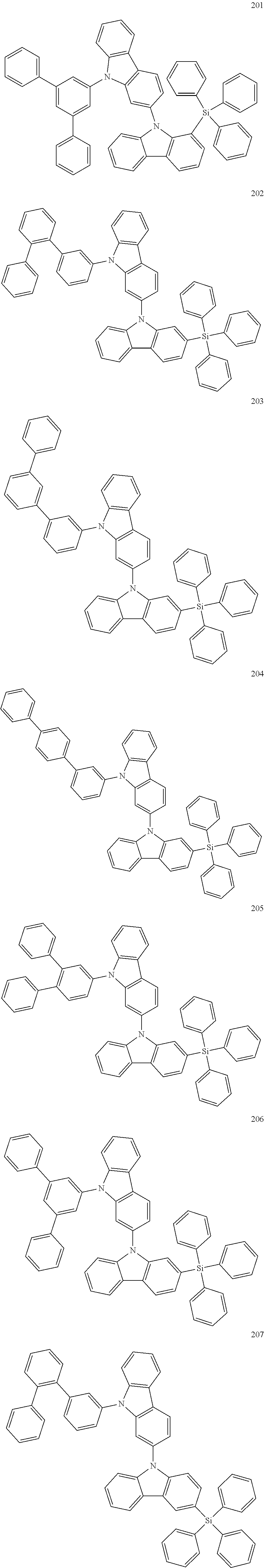

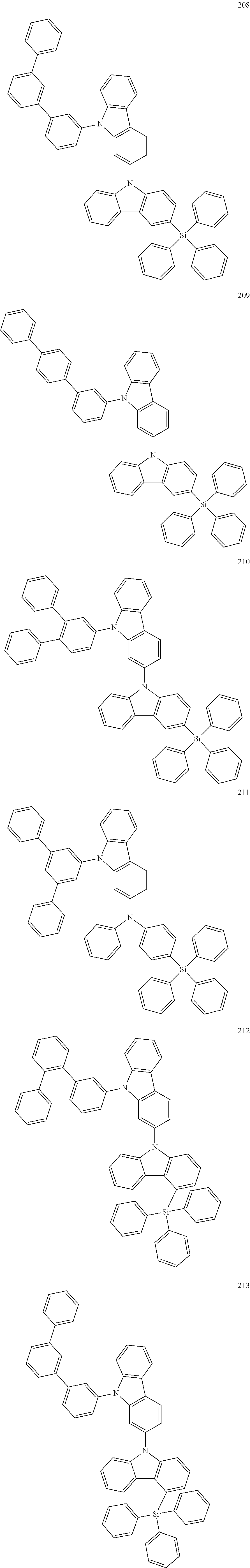

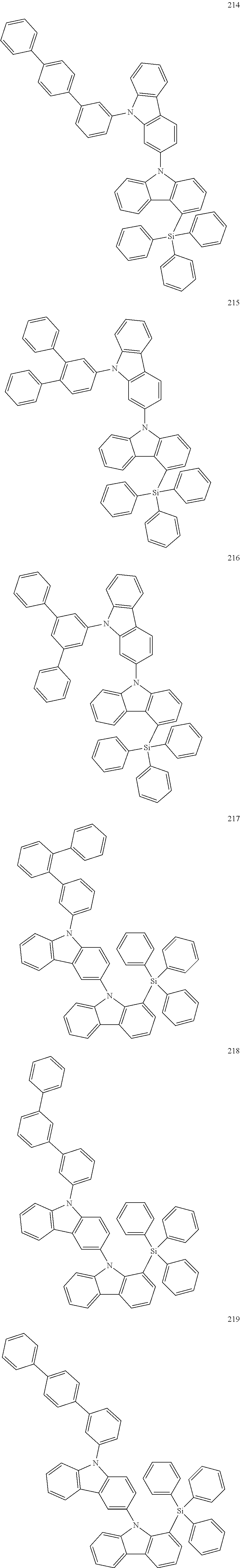

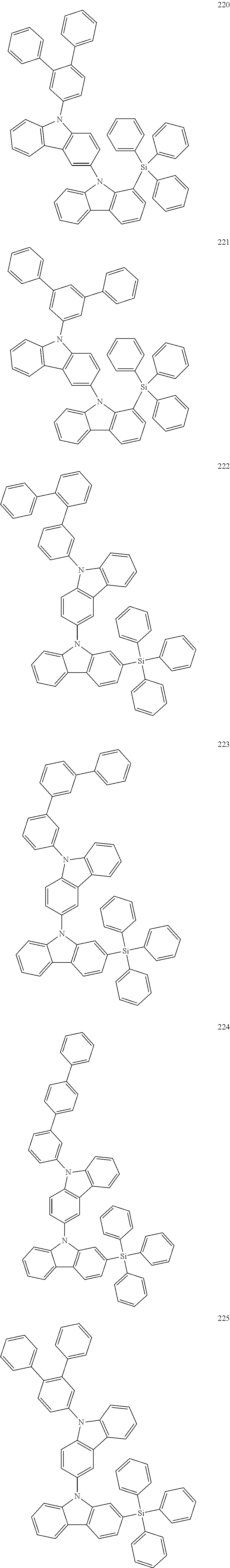

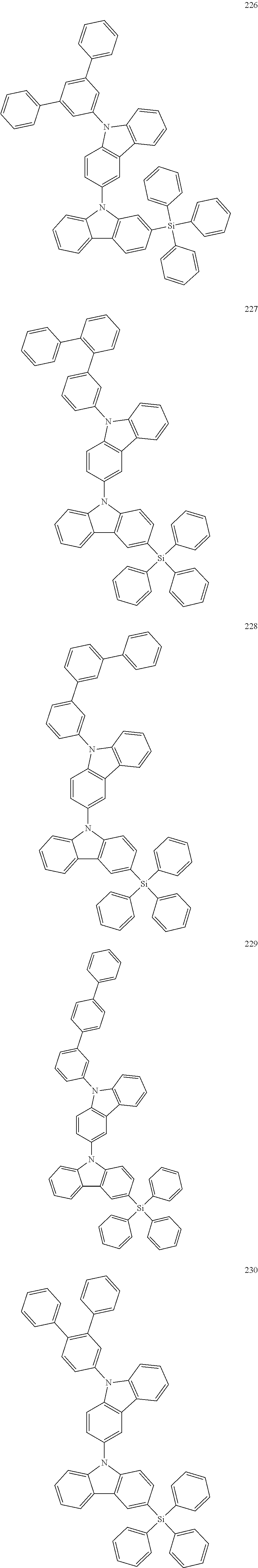

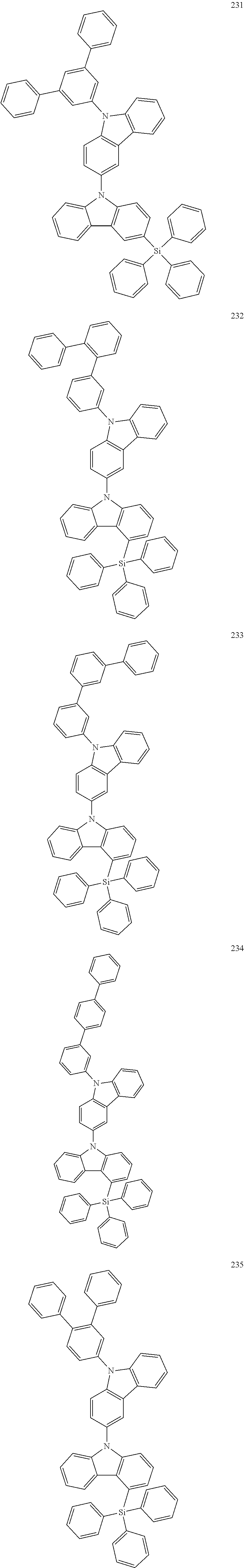

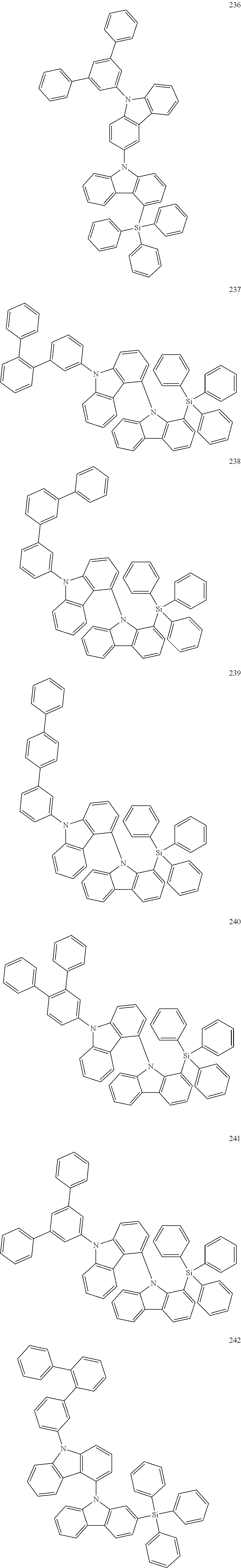

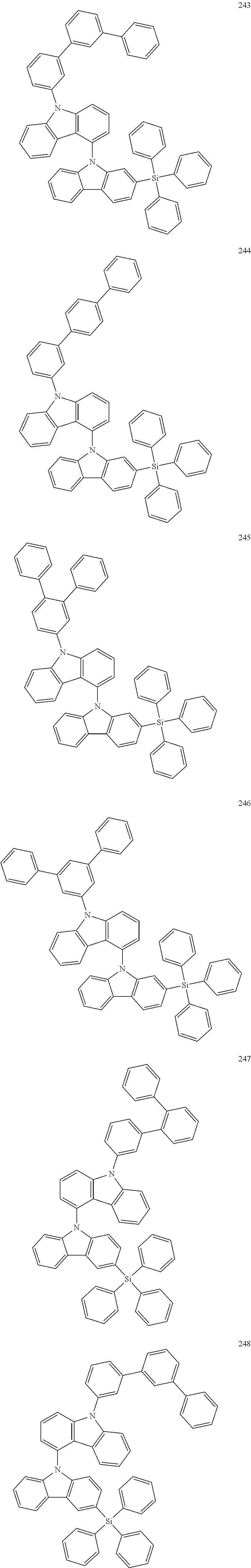

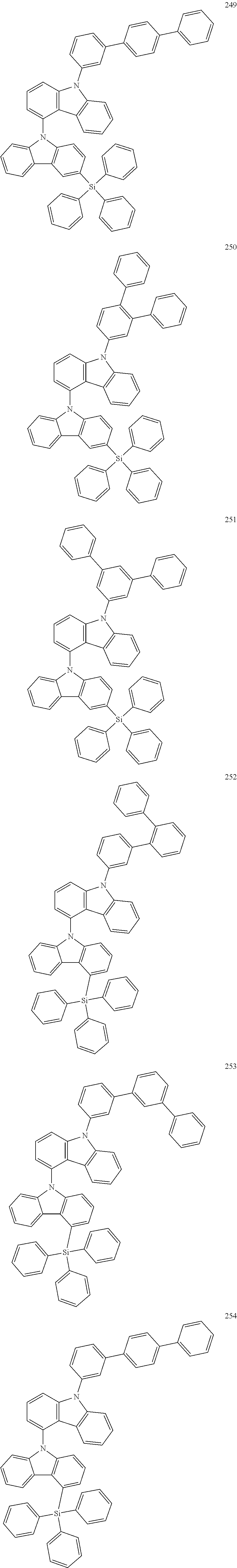

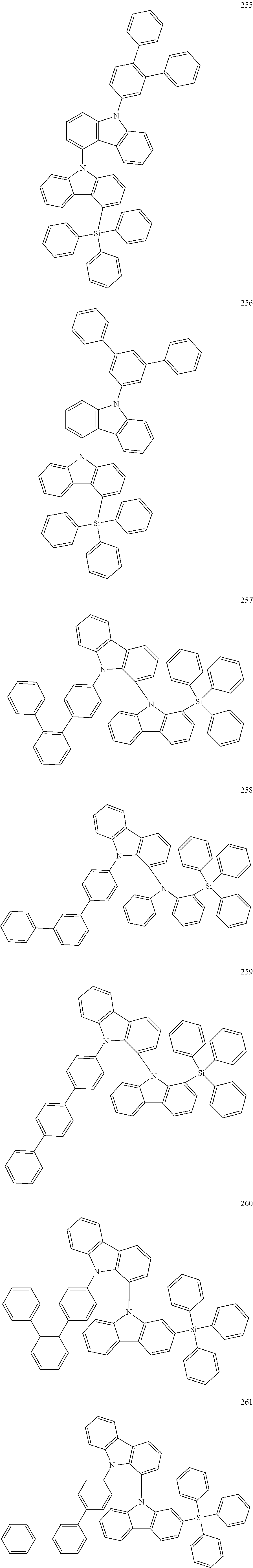

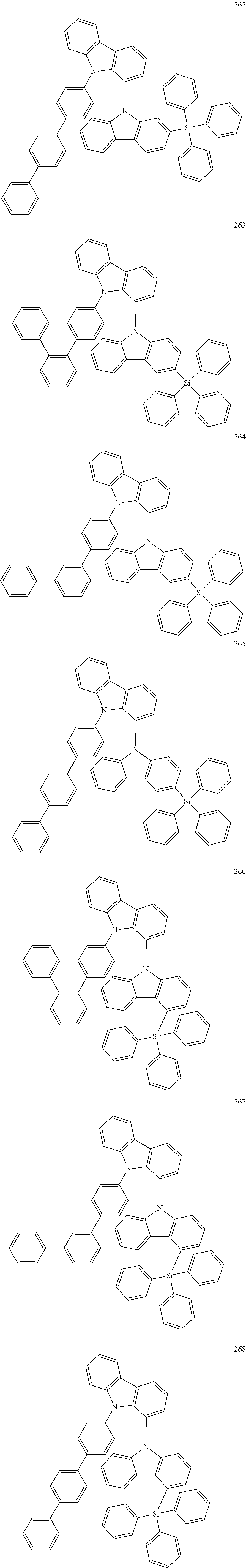

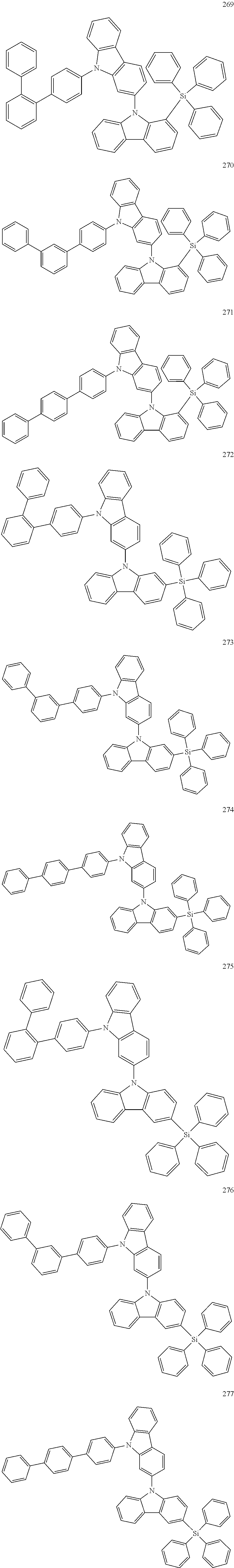

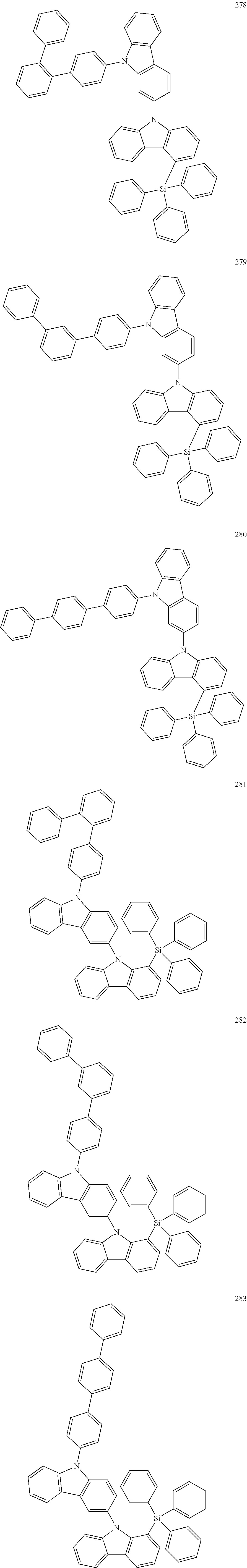

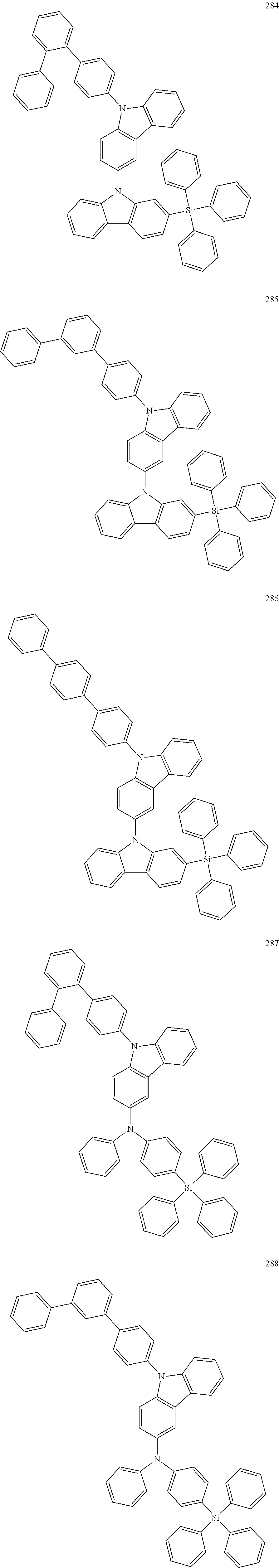

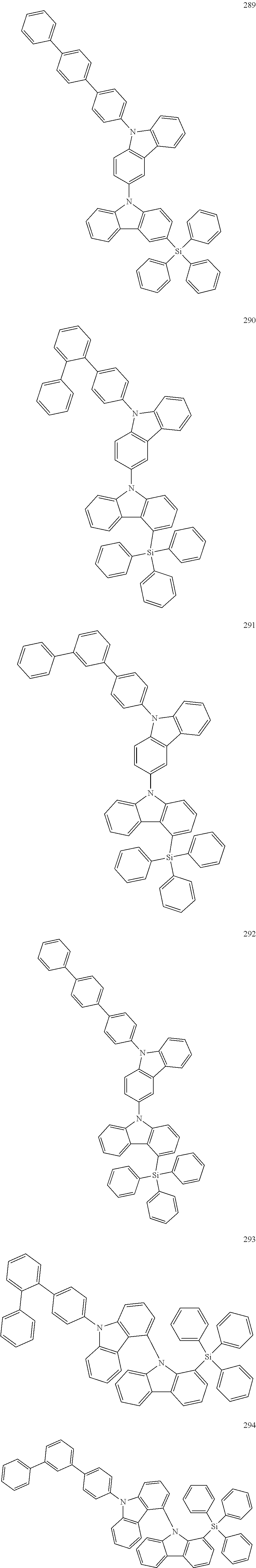

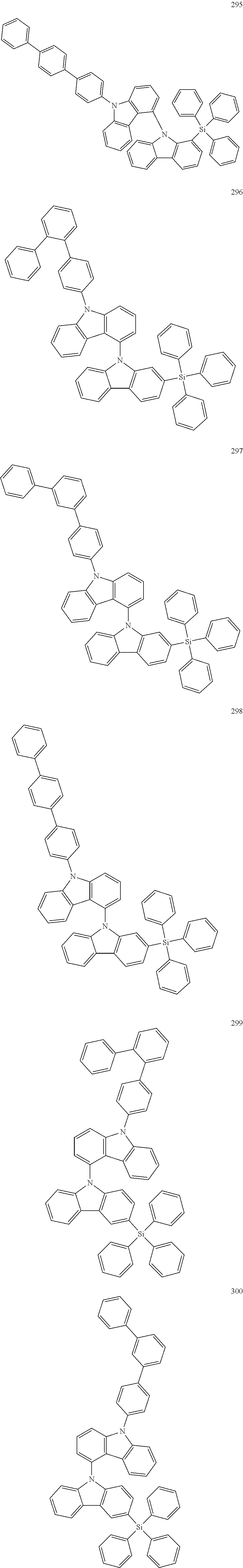

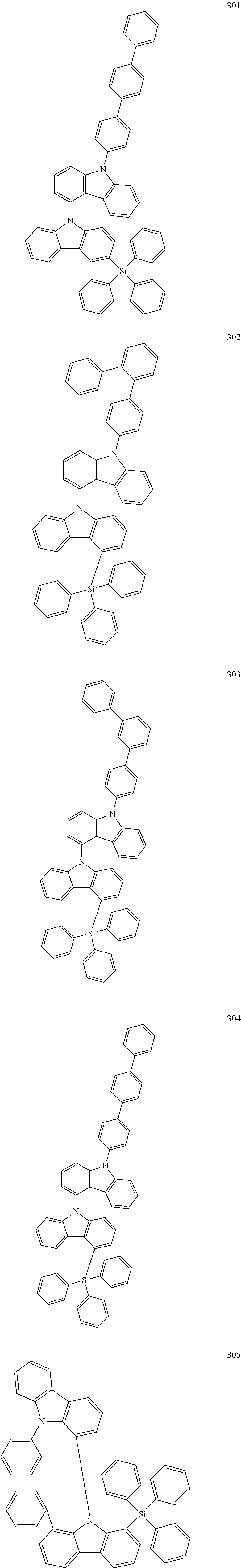

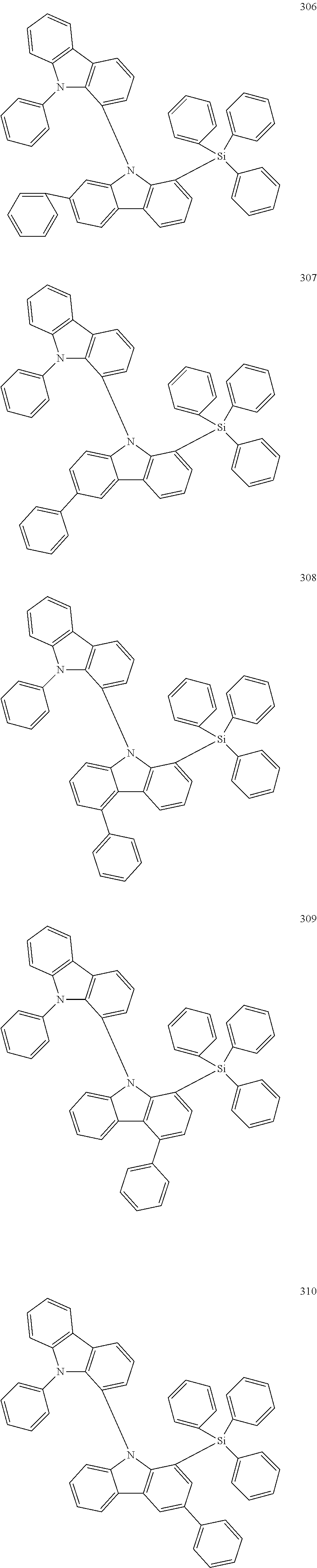 [SMILES: c1ccc(-c2ccc3c4cccc([Si](c5ccccc5)(c5ccccc5)c5ccccc5)c4n(-c4cccc5c6ccccc6n(-c6ccccc6)c45)c3c2)cc1 ; c1ccc(-c2ccc3c(c2)c2cccc([Si](c4ccccc4)(c4ccccc4)c4ccccc4)c2n3-c2cccc3c4ccccc4n(-c4ccccc4)c23)cc1 ; c1ccc(-c2cccc3c2c2cccc([Si](c4ccccc4)(c4ccccc4)c4ccccc4)c2n3-c2cccc3c4ccccc4n(-c4ccccc4)c23)cc1 ; c1ccc(-c2ccc([Si](c3ccccc3)(c3ccccc3)c3ccccc3)c3c2c2ccccc2n3-c2cccc3c4ccccc4n(-c4ccccc4)c23)cc1 ; c1ccc(-c2cc([Si](c3ccccc3)(c3ccccc3)c3ccccc3)c3c(c2)c2ccccc2n3-c2cccc3c4ccccc4n(-c4ccccc4)c23)cc1]

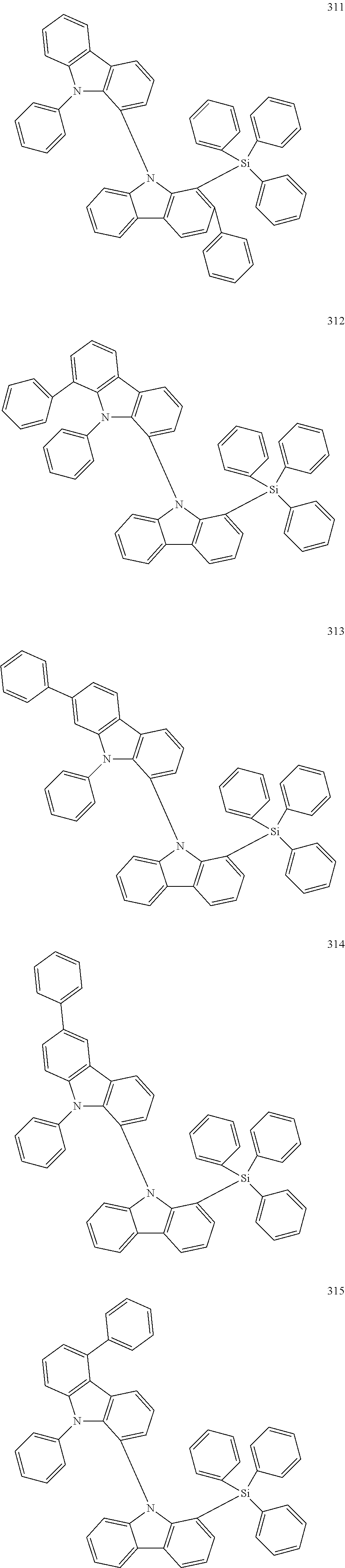 [SMILES: c1ccc(-c2ccc3c4ccccc4n(-c4cccc5c6ccccc6n(-c6ccccc6)c45)c3c2[Si](c2ccccc2)(c2ccccc2)c2ccccc2)cc1 ; c1ccc(-c2cccc3c4cccc(-n5c6ccccc6c6cccc([Si](c7ccccc7)(c7ccccc7)c7ccccc7)c65)c4n(-c4ccccc4)c23)cc1 ; c1ccc(-c2ccc3c4cccc(-n5c6ccccc6c6cccc([Si](c7ccccc7)(c7ccccc7)c7ccccc7)c65)c4n(-c4ccccc4)c3c2)cc1 ; c1ccc(-c2ccc3c(c2)c2cccc(-n4c5ccccc5c5cccc([Si](c6ccccc6)(c6ccccc6)c6ccccc6)c54)c2n3-c2ccccc2)cc1 ; c1ccc(-c2cccc3c2c2cccc(-n4c5ccccc5c5cccc([Si](c6ccccc6)(c6ccccc6)c6ccccc6)c54)c2n3-c2ccccc2)cc1]

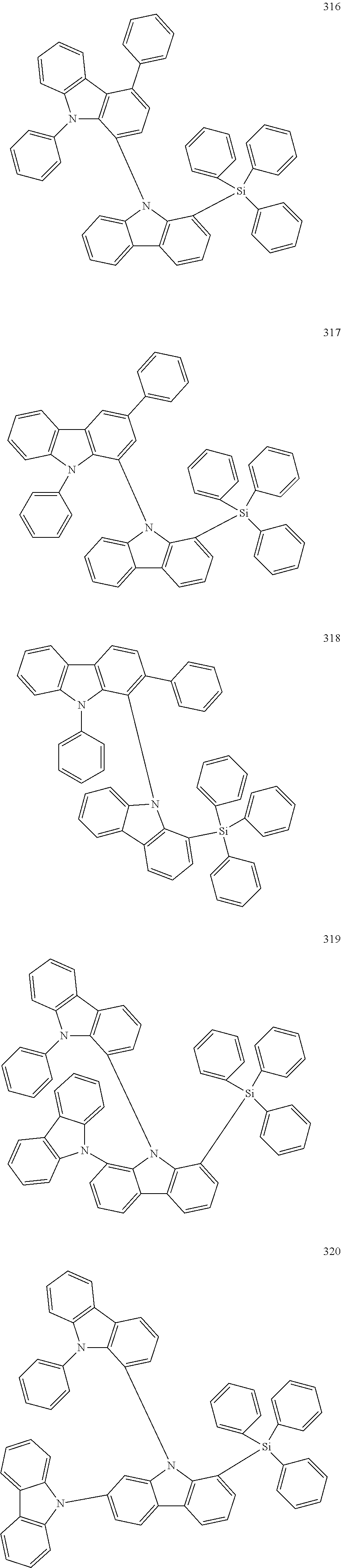

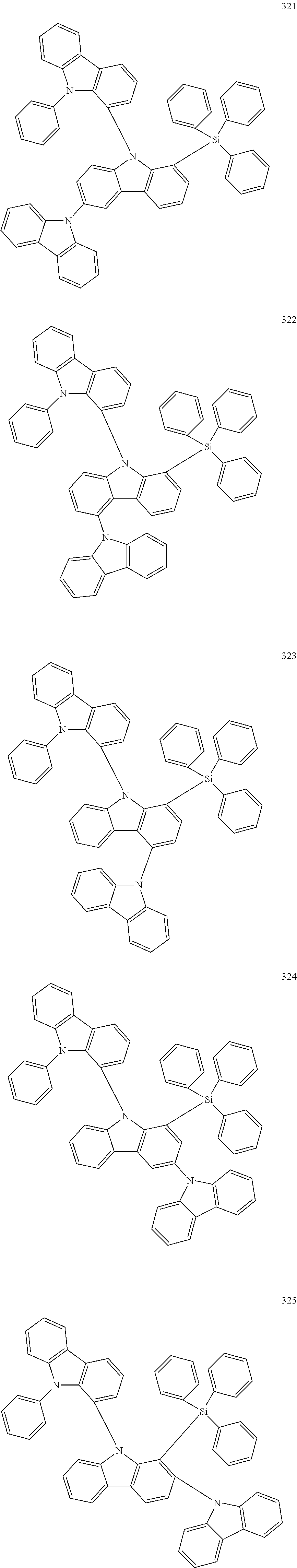

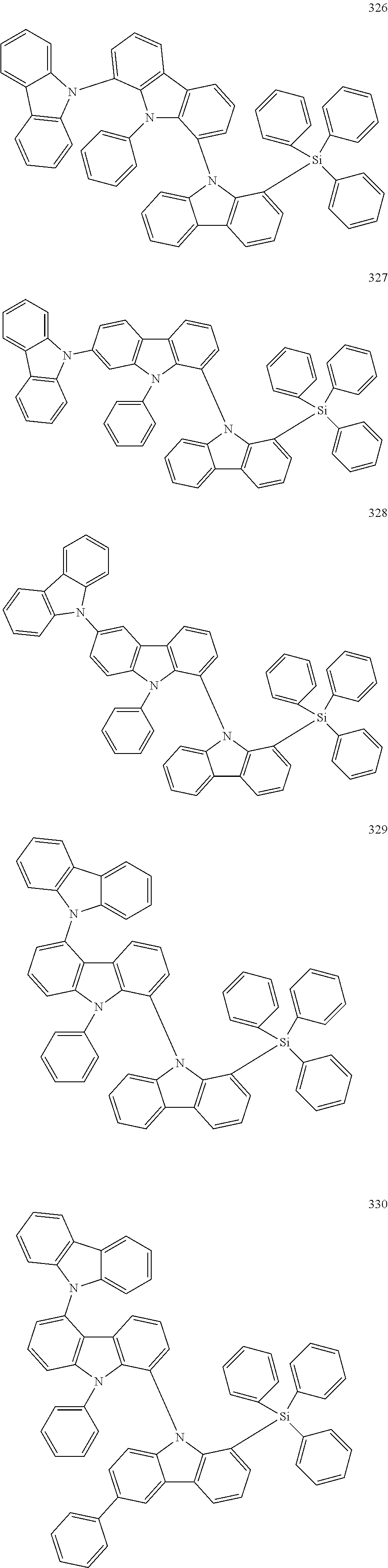

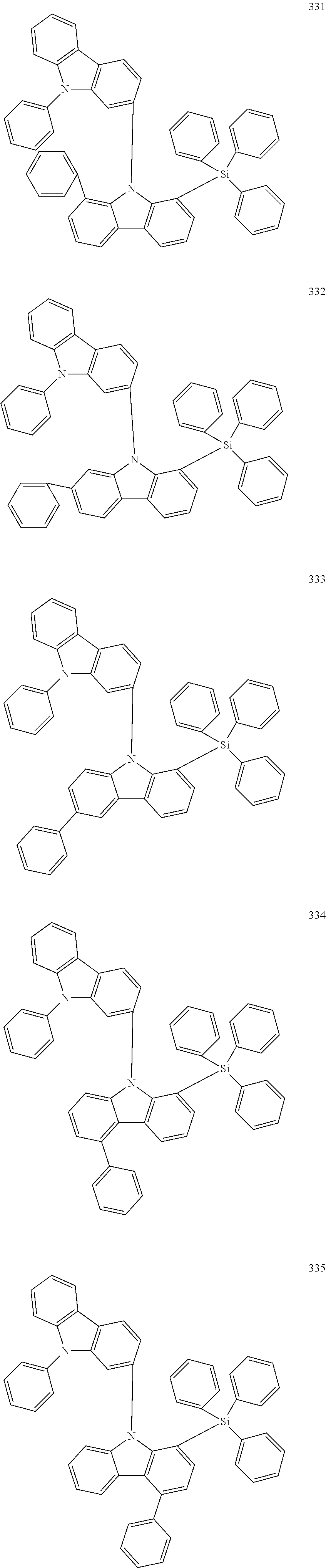 [SMILES: c1ccc(-c2cccc3c4cccc([Si](c5ccccc5)(c5ccccc5)c5ccccc5)c4n(-c4ccc5c6ccccc6n(-c6ccccc6)c5c4)c23)cc1 ; c1ccc(-c2ccc3c4cccc([Si](c5ccccc5)(c5ccccc5)c5ccccc5)c4n(-c4ccc5c6ccccc6n(-c6ccccc6)c5c4)c3c2)cc1 ; c1ccc(-c2ccc3c(c2)c2cccc([Si](c4ccccc4)(c4ccccc4)c4ccccc4)c2n3-c2ccc3c4ccccc4n(-c4ccccc4)c3c2)cc1 ; c1ccc(-c2cccc3c2c2cccc([Si](c4ccccc4)(c4ccccc4)c4ccccc4)c2n3-c2ccc3c4ccccc4n(-c4ccccc4)c3c2)cc1 ; c1ccc(-c2ccc([Si](c3ccccc3)(c3ccccc3)c3ccccc3)c3c2c2ccccc2n3-c2ccc3c4ccccc4n(-c4ccccc4)c3c2)cc1]

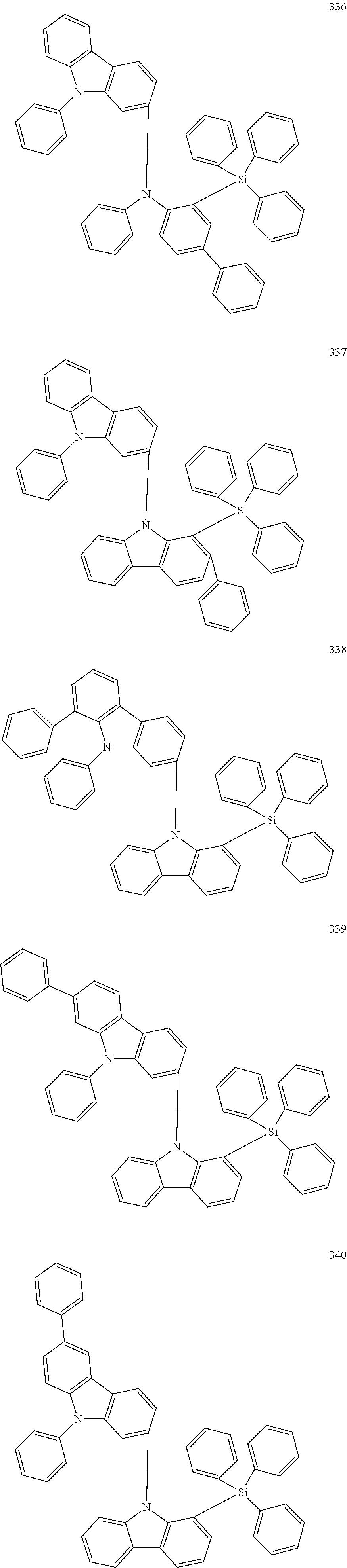 [SMILES: c1ccc(-c2cc([Si](c3ccccc3)(c3ccccc3)c3ccccc3)c3c(c2)c2ccccc2n3-c2ccc3c4ccccc4n(-c4ccccc4)c3c2)cc1 ; c1ccc(-c2ccc3c4ccccc4n(-c4ccc5c6ccccc6n(-c6ccccc6)c5c4)c3c2[Si](c2ccccc2)(c2ccccc2)c2ccccc2)cc1 ; c1ccc(-c2cccc3c4ccc(-n5c6ccccc6c6cccc([Si](c7ccccc7)(c7ccccc7)c7ccccc7)c65)cc4n(-c4ccccc4)c23)cc1 ; c1ccc(-c2ccc3c4ccc(-n5c6ccccc6c6cccc([Si](c7ccccc7)(c7ccccc7)c7ccccc7)c65)cc4n(-c4ccccc4)c3c2)cc1 ; c1ccc(-c2ccc3c(c2)c2ccc(-n4c5ccccc5c5cccc([Si](c6ccccc6)(c6ccccc6)c6ccccc6)c54)cc2n3-c2ccccc2)cc1]

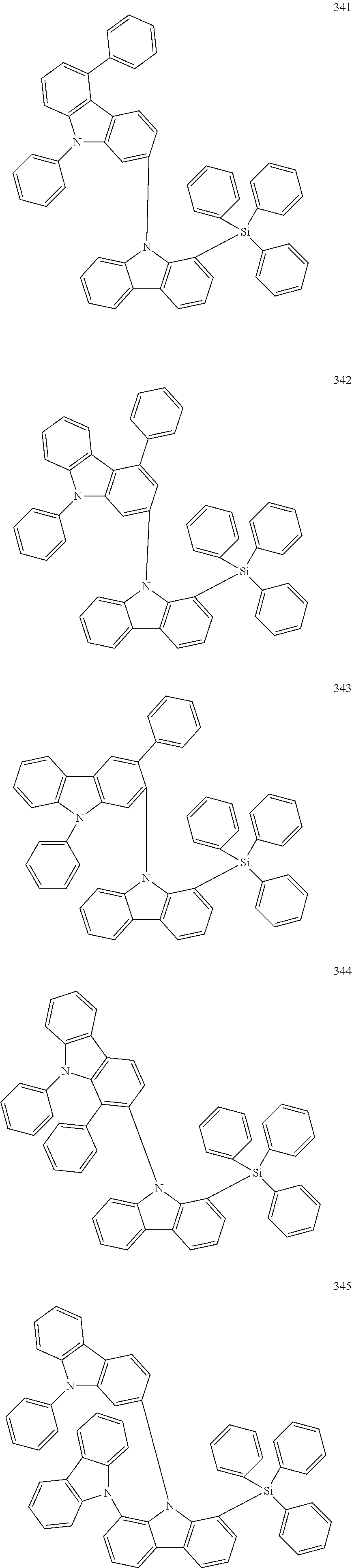

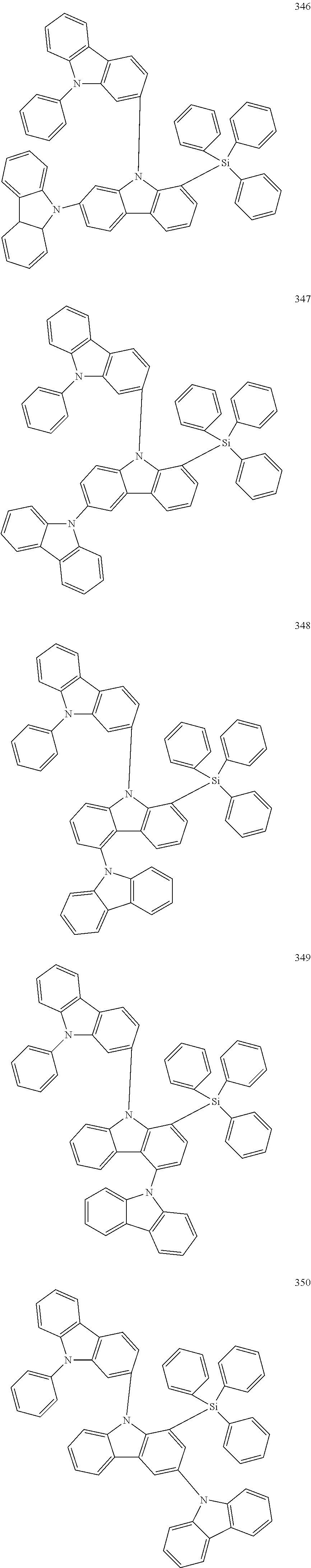

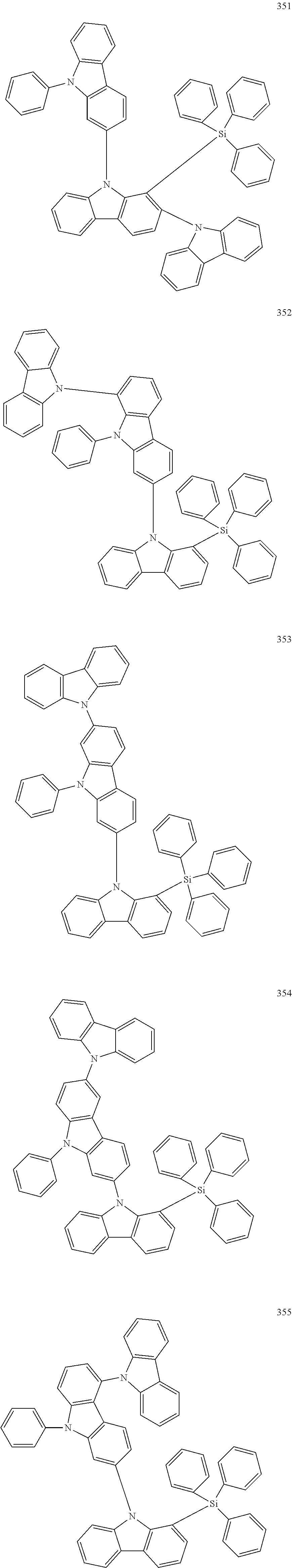

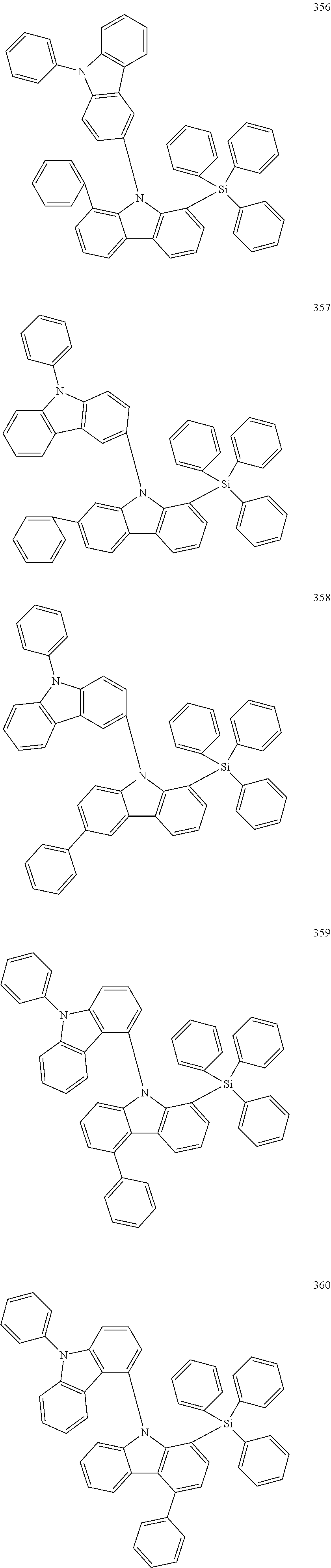 [SMILES: c1ccc(-c2cccc3c4cccc([Si](c5ccccc5)(c5ccccc5)c5ccccc5)c4n(-c4ccc5c(c4)c4ccccc4n5-c4ccccc4)c23)cc1 ; c1ccc(-c2ccc3c4cccc([Si](c5ccccc5)(c5ccccc5)c5ccccc5)c4n(-c4ccc5c(c4)c4ccccc4n5-c4ccccc4)c3c2)cc1 ; c1ccc(-c2ccc3c(c2)c2cccc([Si](c4ccccc4)(c4ccccc4)c4ccccc4)c2n3-c2ccc3c(c2)c2ccccc2n3-c2ccccc2)cc1 ; c1ccc(-c2cccc3c2c2cccc([Si](c4ccccc4)(c4ccccc4)c4ccccc4)c2n3-c2cccc3c2c2ccccc2n3-c2ccccc2)cc1 ; c1ccc(-c2ccc([Si](c3ccccc3)(c3ccccc3)c3ccccc3)c3c2c2ccccc2n3-c2cccc3c2c2ccccc2n3-c2ccccc2)cc1]

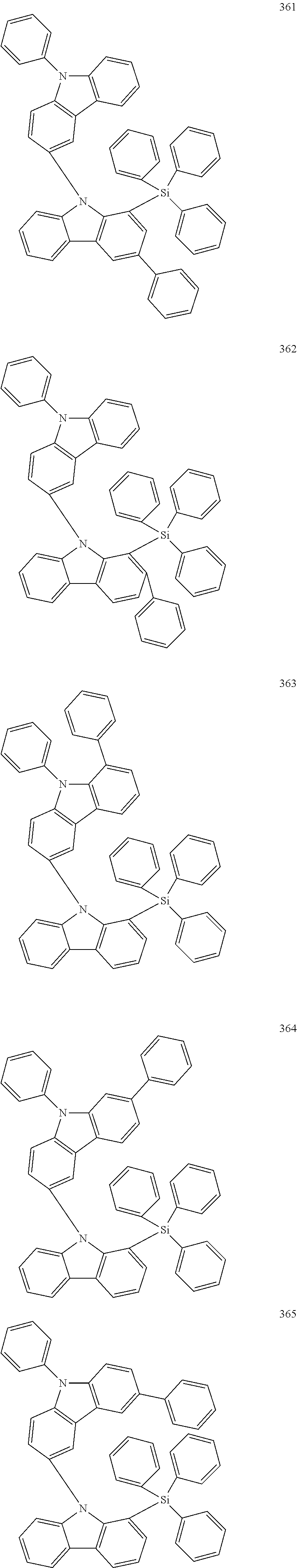

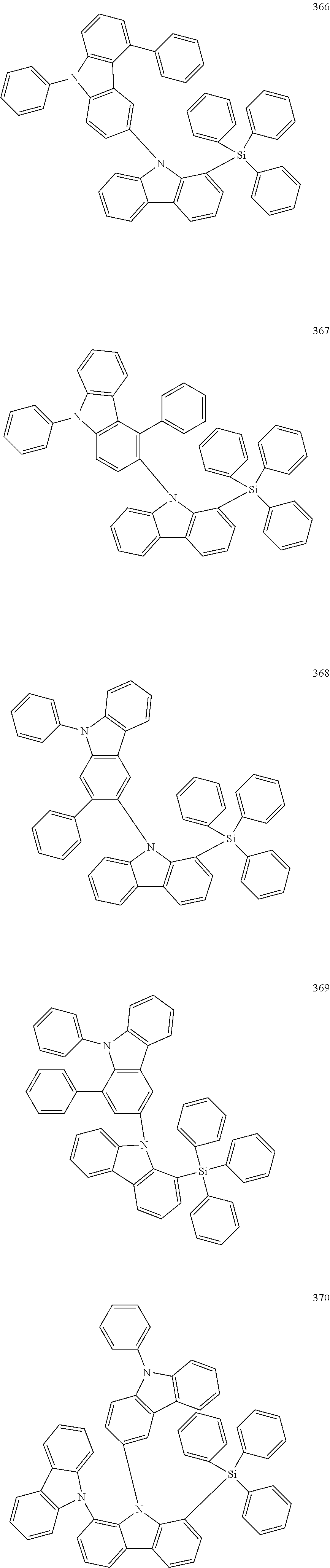

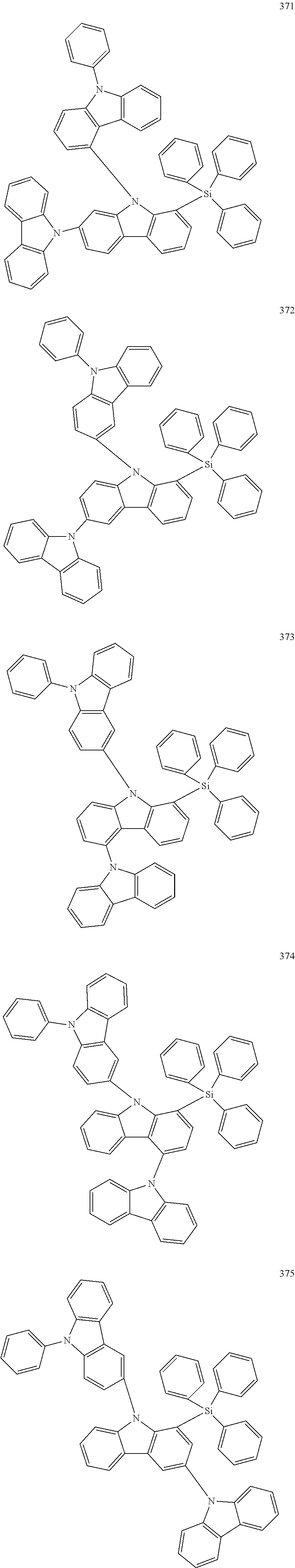

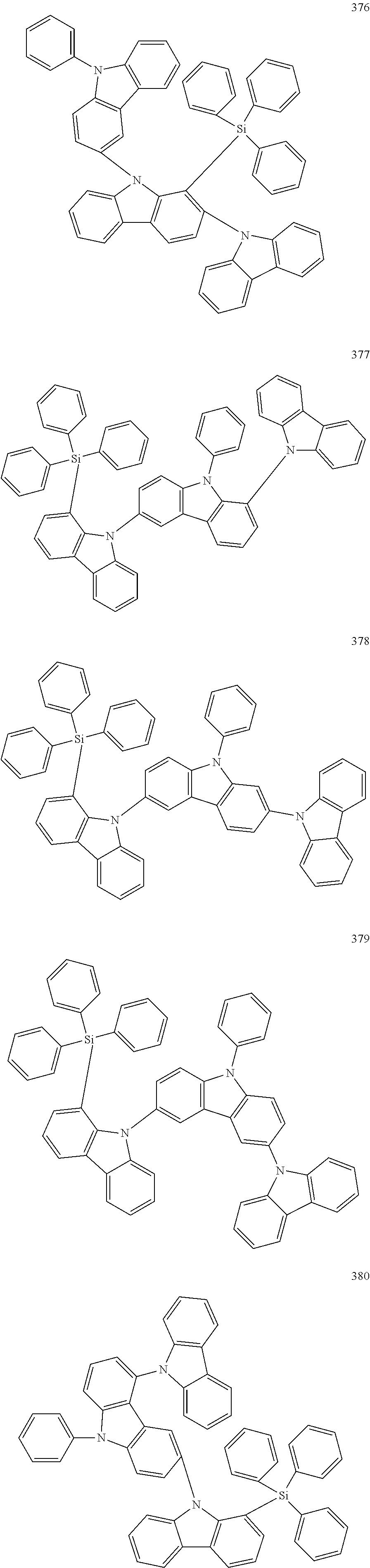

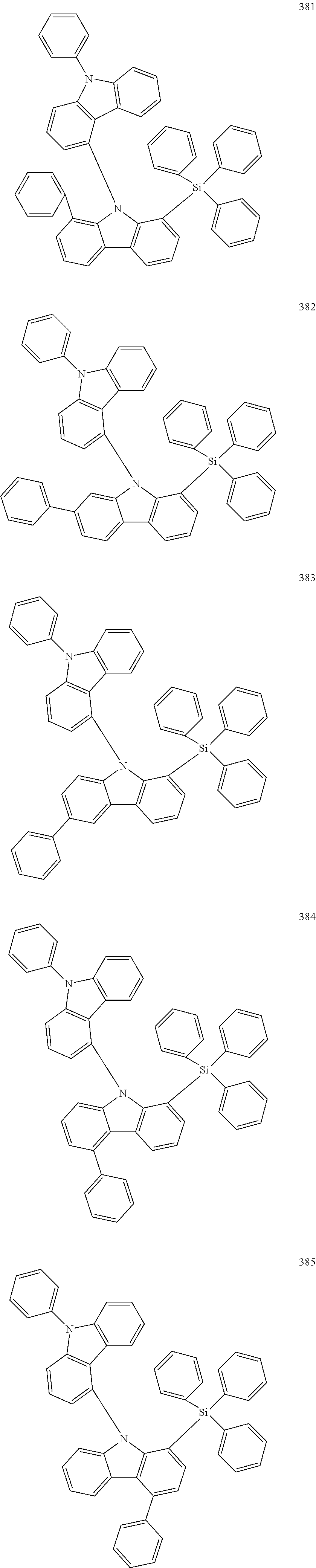 [SMILES: c1ccc(-c2cccc3c4cccc([Si](c5ccccc5)(c5ccccc5)c5ccccc5)c4n(-c4cccc5c4c4ccccc4n5-c4ccccc4)c23)cc1 ; c1ccc(-c2ccc3c4cccc([Si](c5ccccc5)(c5ccccc5)c5ccccc5)c4n(-c4cccc5c4c4ccccc4n5-c4ccccc4)c3c2)cc1 ; c1ccc(-c2ccc3c(c2)c2cccc([Si](c4ccccc4)(c4ccccc4)c4ccccc4)c2n3-c2cccc3c2c2ccccc2n3-c2ccccc2)cc1 ; c1ccc(-c2cccc3c2c2cccc([Si](c4ccccc4)(c4ccccc4)c4ccccc4)c2n3-c2cccc3c2c2ccccc2n3-c2ccccc2)cc1 ; c1ccc(-c2ccc([Si](c3ccccc3)(c3ccccc3)c3ccccc3)c3c2c2ccccc2n3-c2cccc3c2c2ccccc2n3-c2ccccc2)cc1]

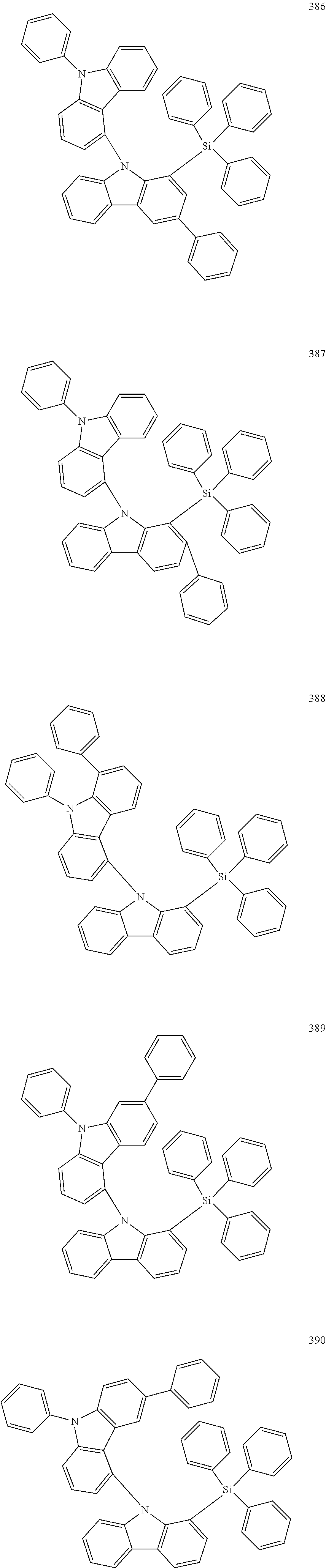 [SMILES: c1ccc(-c2cc([Si](c3ccccc3)(c3ccccc3)c3ccccc3)c3c(c2)c2ccccc2n3-c2cccc3c2c2ccccc2n3-c2ccccc2)cc1 ; c1ccc(-c2ccc3c4ccccc4n(-c4cccc5c4c4ccccc4n5-c4ccccc4)c3c2[Si](c2ccccc2)(c2ccccc2)c2ccccc2)cc1 ; c1ccc(-c2cccc3c4c(-n5c6ccccc6c6cccc([Si](c7ccccc7)(c7ccccc7)c7ccccc7)c65)cccc4n(-c4ccccc4)c23)cc1 ; c1ccc(-c2ccc3c4c(-n5c6ccccc6c6cccc([Si](c7ccccc7)(c7ccccc7)c7ccccc7)c65)cccc4n(-c4ccccc4)c3c2)cc1 ; c1ccc(-c2ccc3c(c2)c2c(-n4c5ccccc5c5cccc([Si](c6ccccc6)(c6ccccc6)c6ccccc6)c54)cccc2n3-c2ccccc2)cc1]

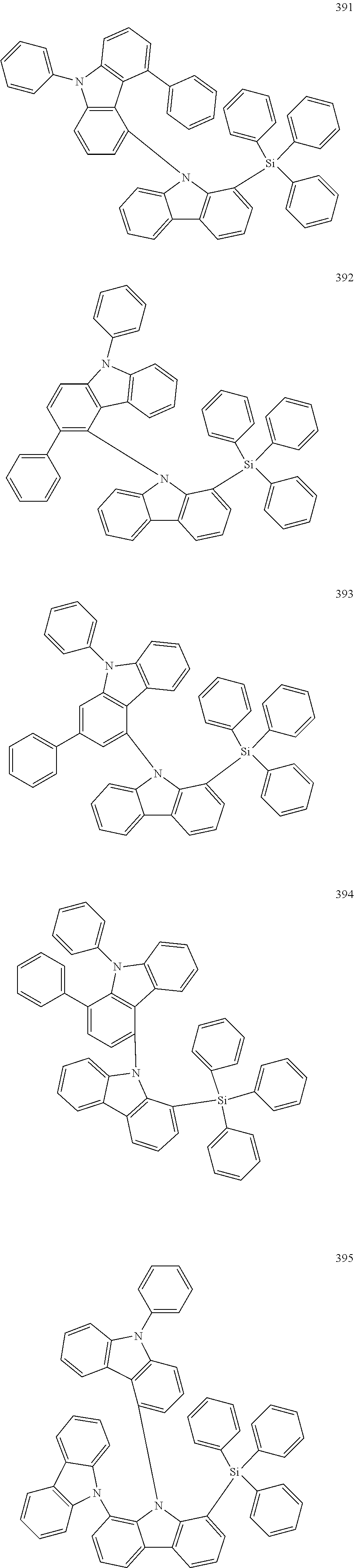

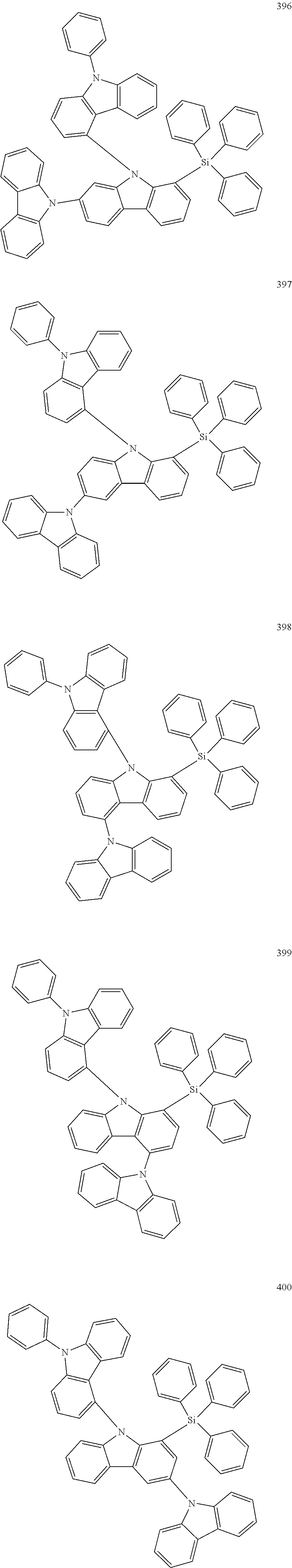

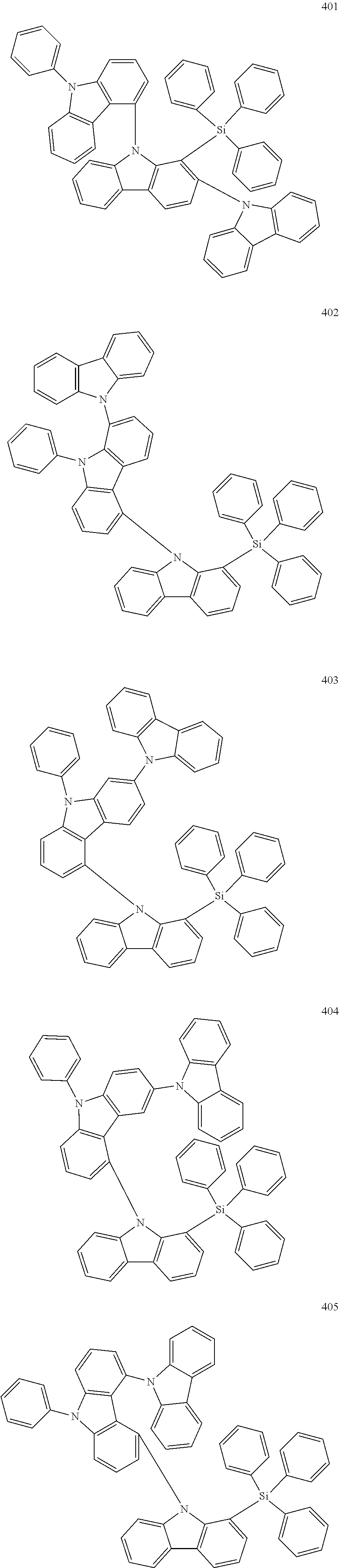

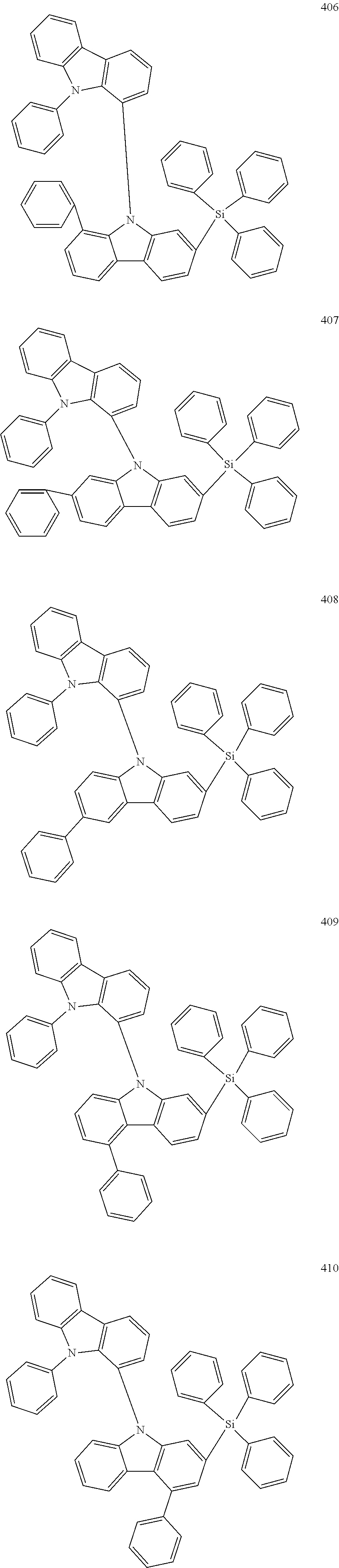 [SMILES: c1ccc(-c2cccc3c4ccc([Si](c5ccccc5)(c5ccccc5)c5ccccc5)cc4n(-c4cccc5c6ccccc6n(-c6ccccc6)c45)c23)cc1 ; c1ccc(-c2ccc3c4ccc([Si](c5ccccc5)(c5ccccc5)c5ccccc5)cc4n(-c4cccc5c6ccccc6n(-c6ccccc6)c45)c3c2)cc1 ; c1ccc(-c2ccc3c(c2)c2ccc([Si](c4ccccc4)(c4ccccc4)c4ccccc4)cc2n3-c2cccc3c4ccccc4n(-c4ccccc4)c23)cc1 ; c1ccc(-c2cccc3c2c2ccc([Si](c4ccccc4)(c4ccccc4)c4ccccc4)cc2n3-c2cccc3c4ccccc4n(-c4ccccc4)c23)cc1 ; c1ccc(-c2cc([Si](c3ccccc3)(c3ccccc3)c3ccccc3)cc3c2c2ccccc2n3-c2cccc3c4ccccc4n(-c4ccccc4)c23)cc1]

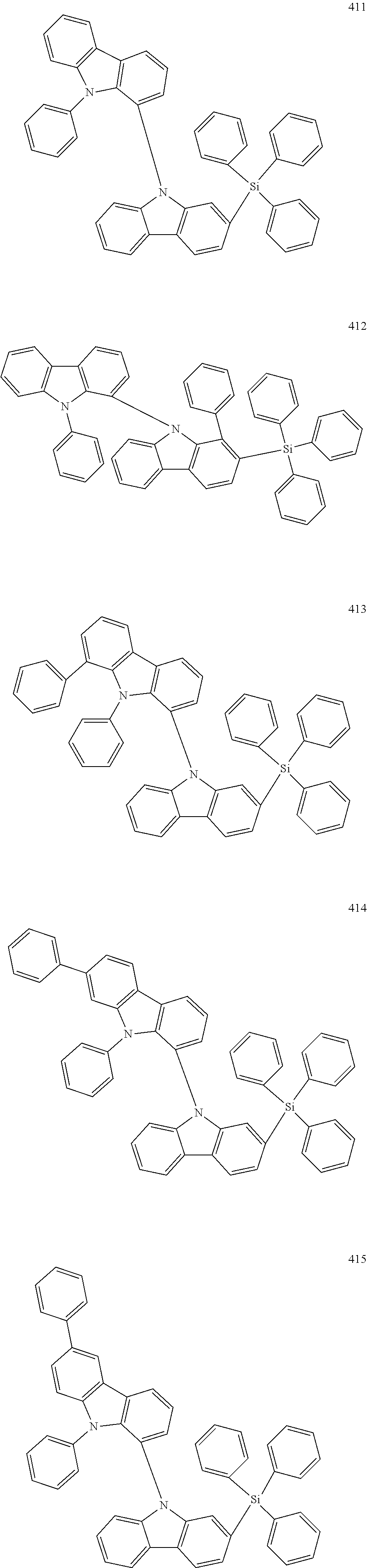 [SMILES: c1ccc(-n2c3ccccc3c3cccc(-n4c5ccccc5c5ccc([Si](c6ccccc6)(c6ccccc6)c6ccccc6)cc54)c32)cc1 ; c1ccc(-c2c([Si](c3ccccc3)(c3ccccc3)c3ccccc3)ccc3c4ccccc4n(-c4cccc5c6ccccc6n(-c6ccccc6)c45)c23)cc1 ; c1ccc(-c2cccc3c4cccc(-n5c6ccccc6c6ccc([Si](c7ccccc7)(c7ccccc7)c7ccccc7)cc65)c4n(-c4ccccc4)c23)cc1 ; c1ccc(-c2ccc3c4cccc(-n5c6ccccc6c6ccc([Si](c7ccccc7)(c7ccccc7)c7ccccc7)cc65)c4n(-c4ccccc4)c3c2)cc1 ; c1ccc(-c2ccc3c(c2)c2cccc(-n4c5ccccc5c5ccc([Si](c6ccccc6)(c6ccccc6)c6ccccc6)cc54)c2n3-c2ccccc2)cc1]

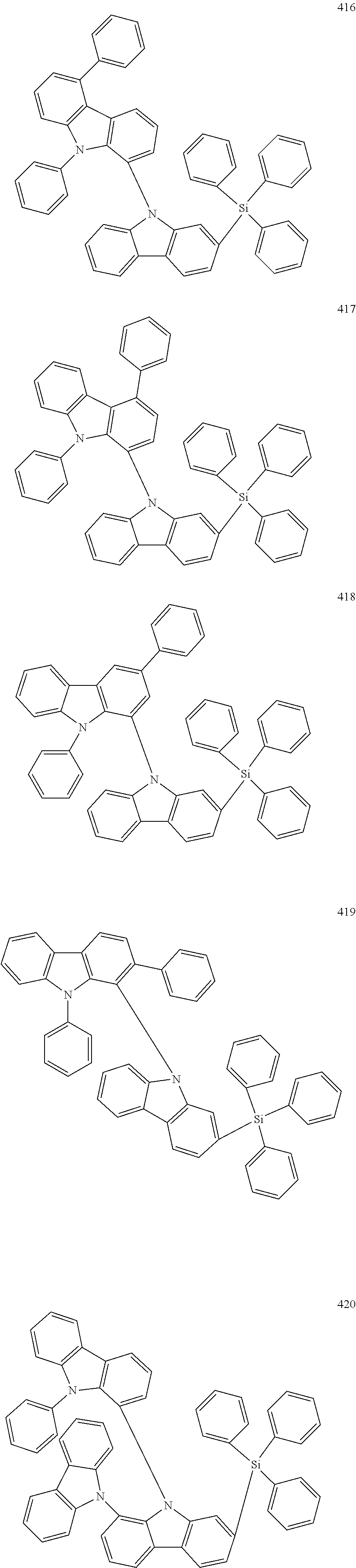

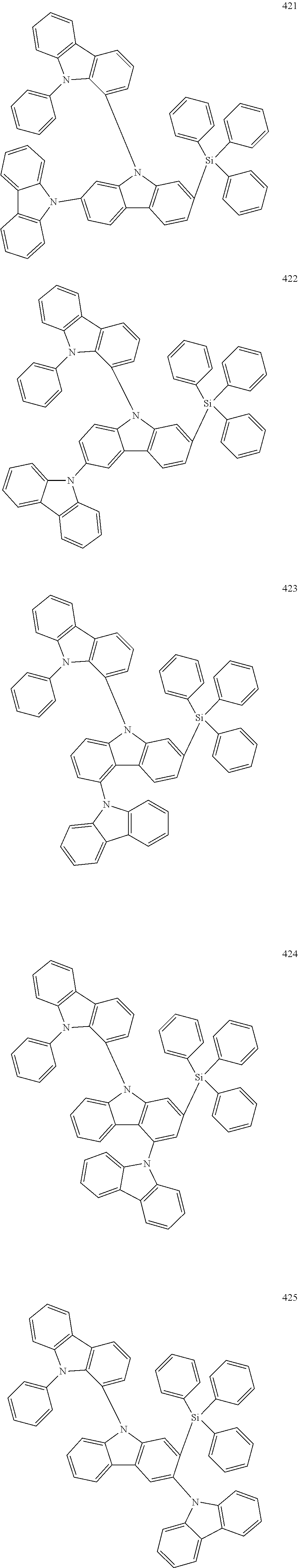

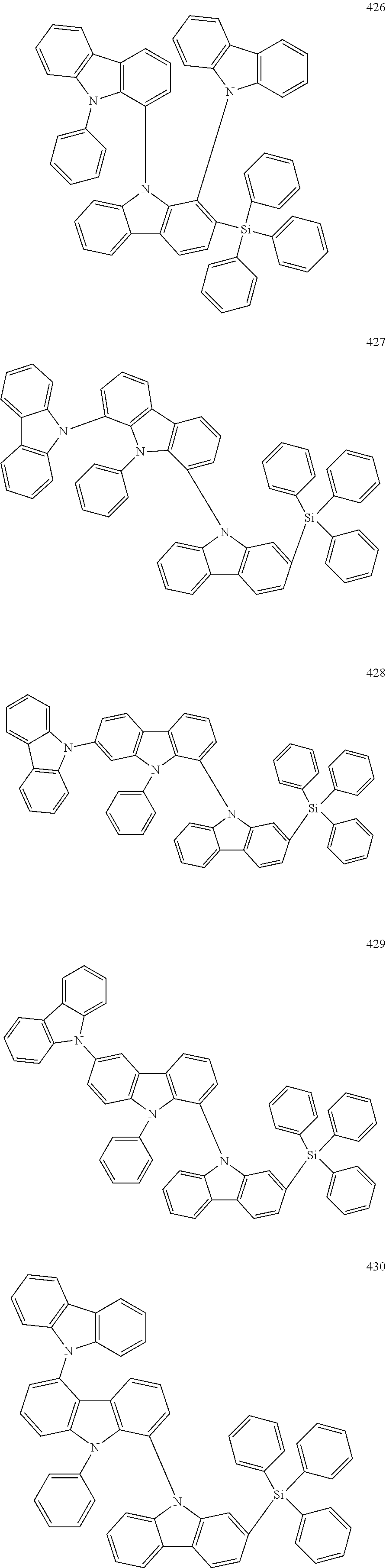

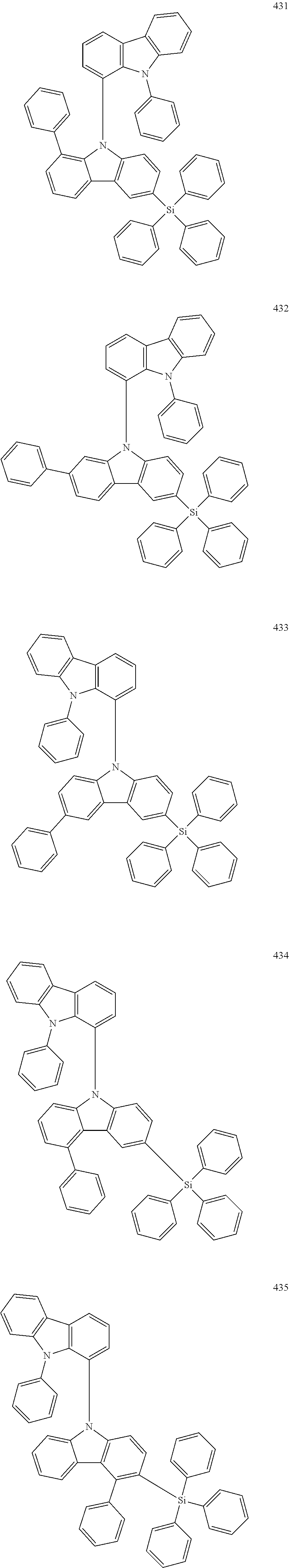 [SMILES: c1ccc(-c2cccc3c4cc([Si](c5ccccc5)(c5ccccc5)c5ccccc5)ccc4n(-c4cccc5c6ccccc6n(-c6ccccc6)c45)c23)cc1 ; c1ccc(-c2ccc3c4cc([Si](c5ccccc5)(c5ccccc5)c5ccccc5)ccc4n(-c4cccc5c6ccccc6n(-c6ccccc6)c45)c3c2)cc1 ; c1ccc(-c2ccc3c(c2)c2cc([Si](c4ccccc4)(c4ccccc4)c4ccccc4)ccc2n3-c2cccc3c4ccccc4n(-c4ccccc4)c23)cc1 ; c1ccc(-c2cccc3c2c2cc([Si](c4ccccc4)(c4ccccc4)c4ccccc4)ccc2n3-c2cccc3c4ccccc4n(-c4ccccc4)c23)cc1 ; c1ccc(-c2c([Si](c3ccccc3)(c3ccccc3)c3ccccc3)ccc3c2c2ccccc2n3-c2cccc3c4ccccc4n(-c4ccccc4)c23)cc1]

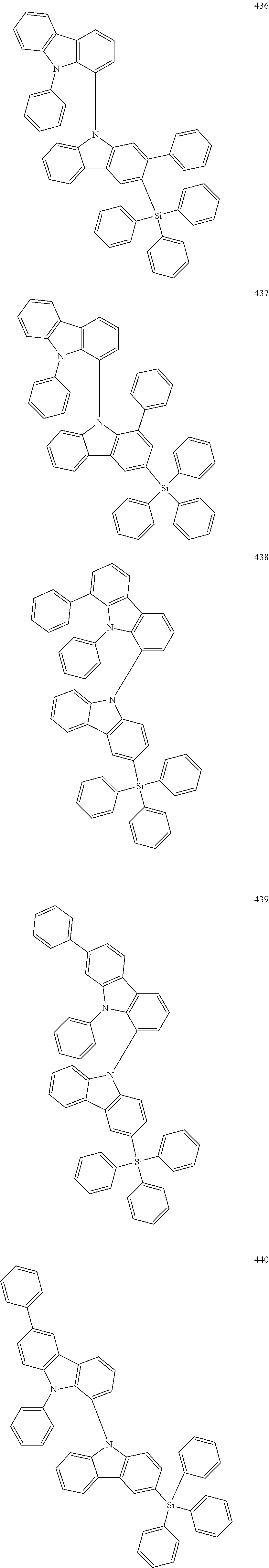

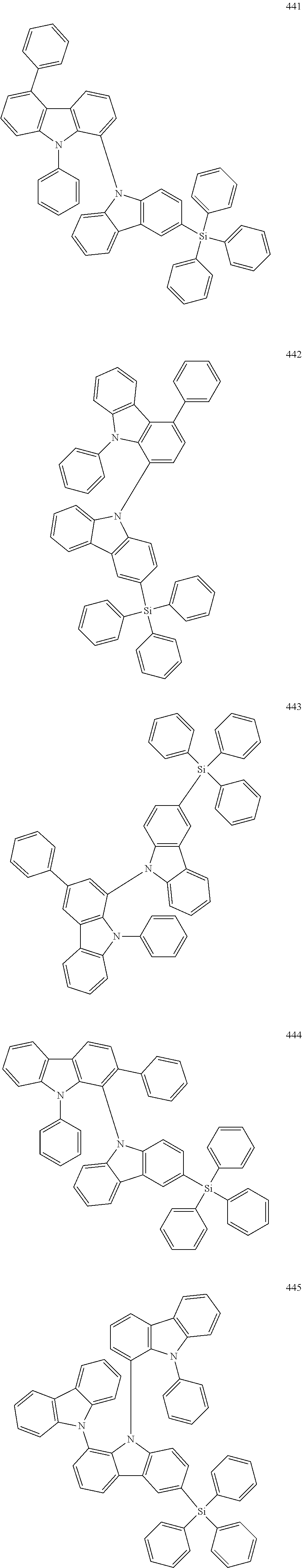

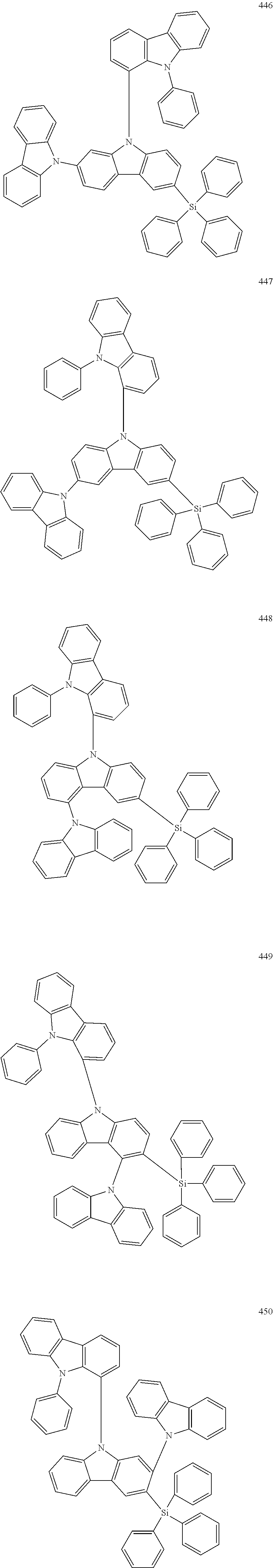

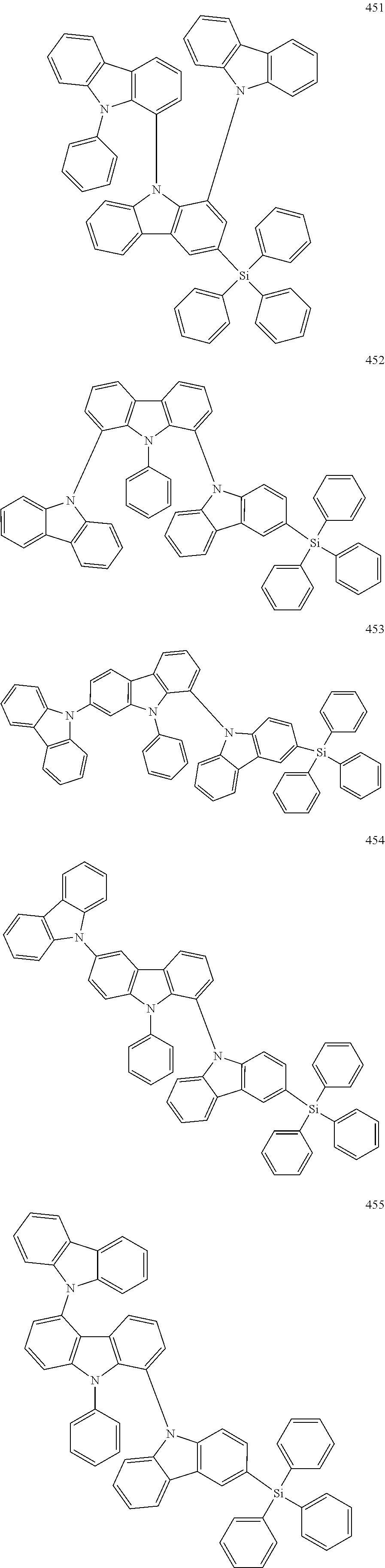

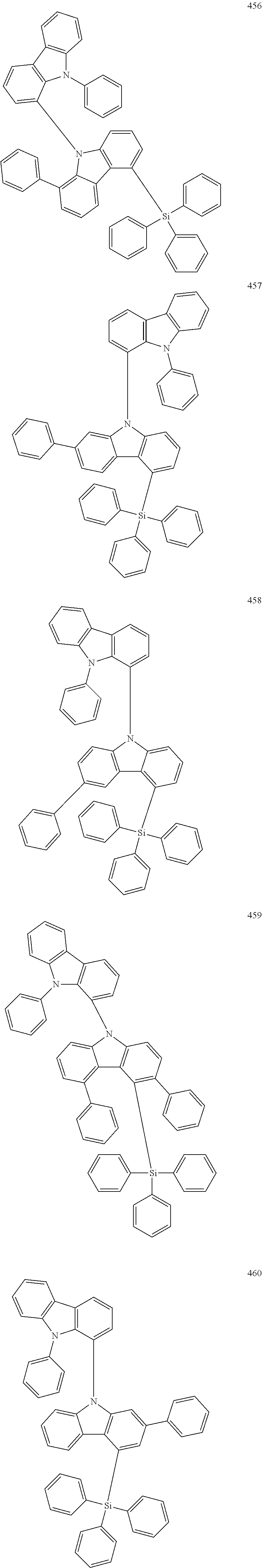

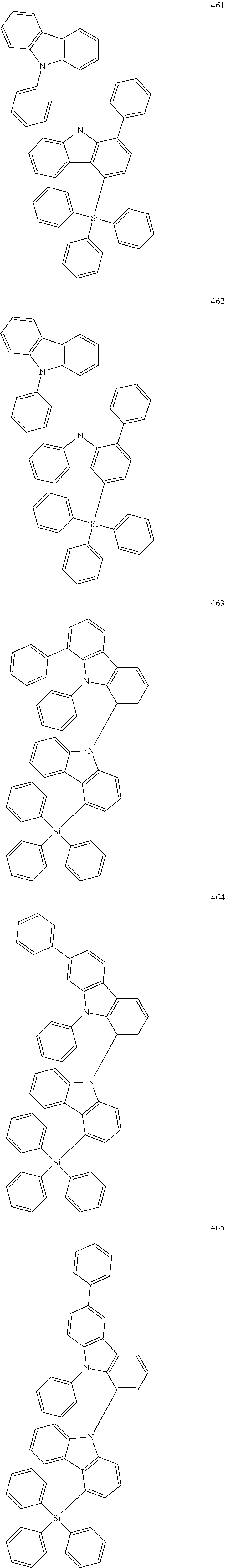 [SMILES: c1ccc(-c2ccc([Si](c3ccccc3)(c3ccccc3)c3ccccc3)c3c4ccccc4n(-c4cccc5c6ccccc6n(-c6ccccc6)c45)c23)cc1 ; c1ccc(-c2ccc([Si](c3ccccc3)(c3ccccc3)c3ccccc3)c3c4ccccc4n(-c4cccc5c6ccccc6n(-c6ccccc6)c45)c23)cc1 ; c1ccc(-c2cccc3c4cccc(-n5c6ccccc6c6c([Si](c7ccccc7)(c7ccccc7)c7ccccc7)cccc65)c4n(-c4ccccc4)c23)cc1 ; c1ccc(-c2ccc3c4cccc(-n5c6ccccc6c6c([Si](c7ccccc7)(c7ccccc7)c7ccccc7)cccc65)c4n(-c4ccccc4)c3c2)cc1 ; c1ccc(-c2ccc3c(c2)c2cccc(-n4c5ccccc5c5c([Si](c6ccccc6)(c6ccccc6)c6ccccc6)cccc54)c2n3-c2ccccc2)cc1]

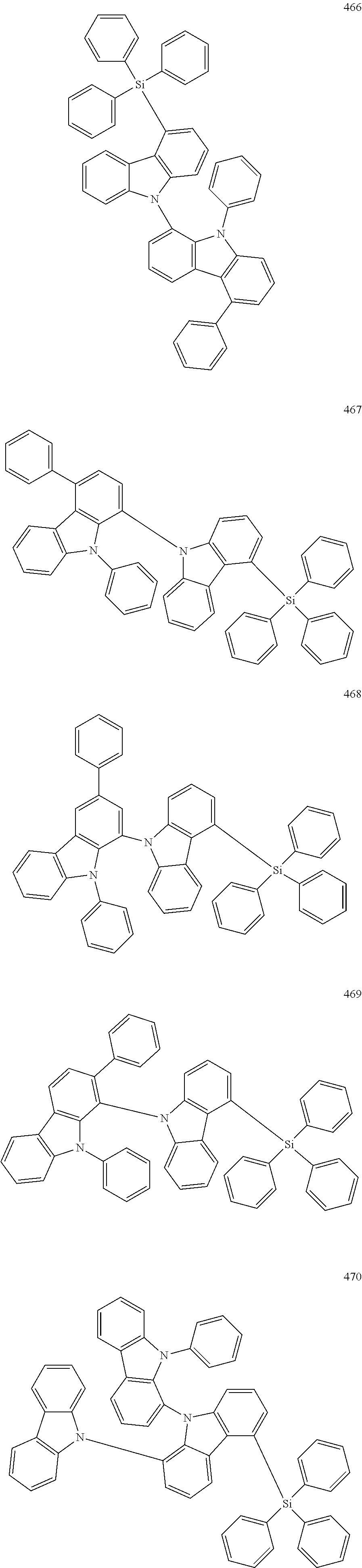

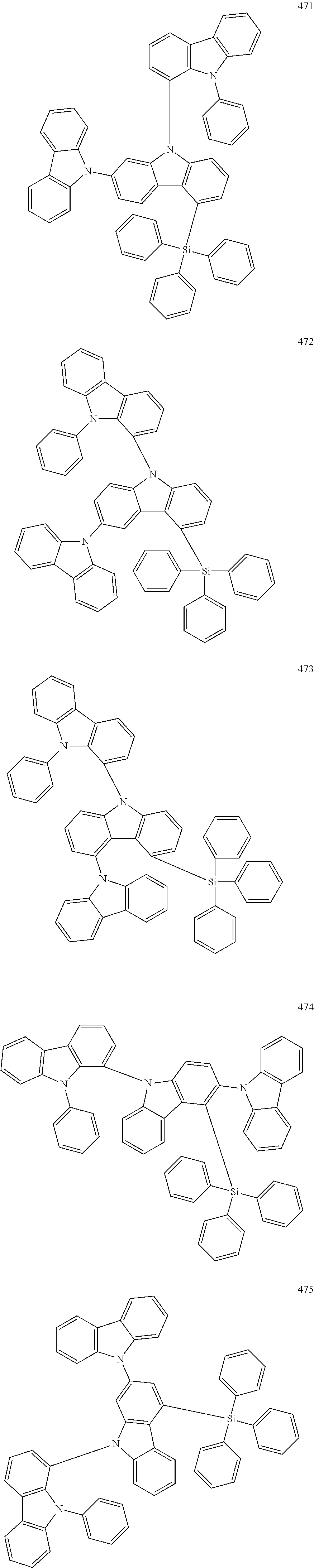

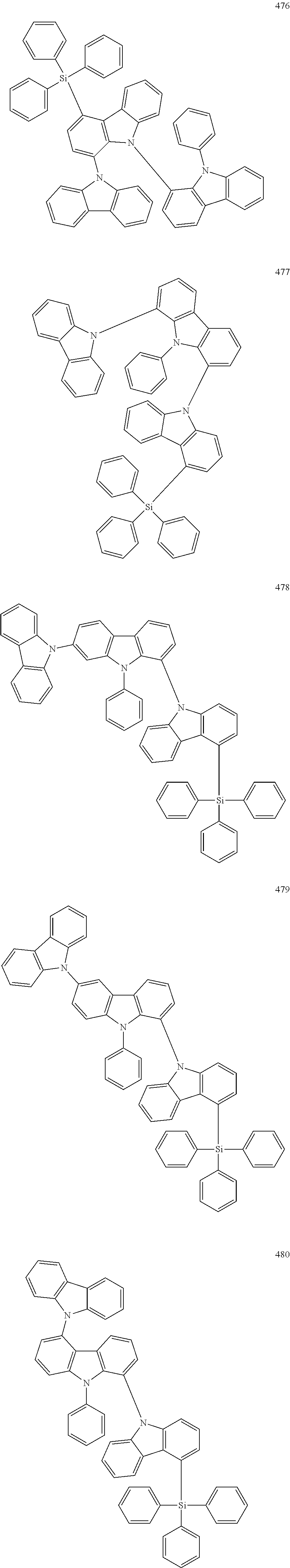

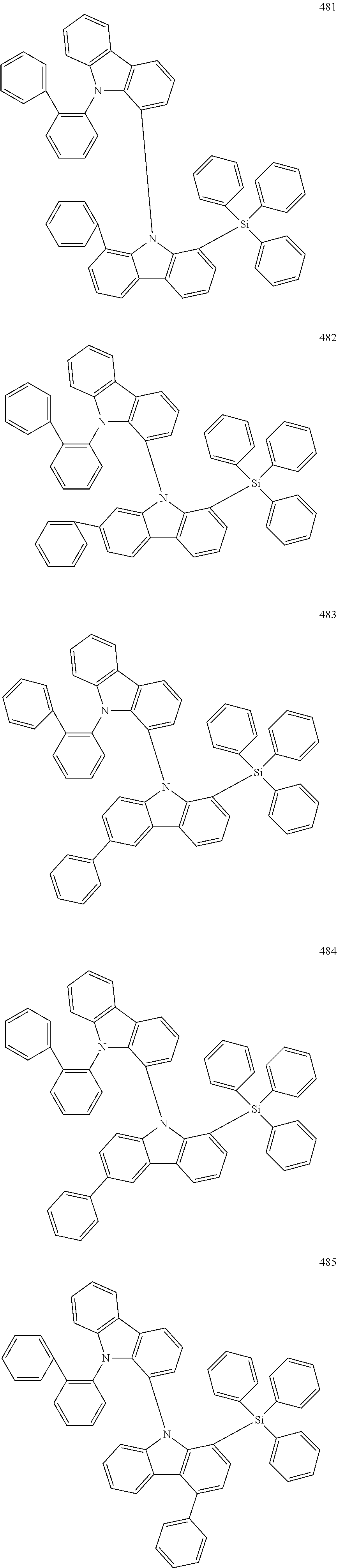

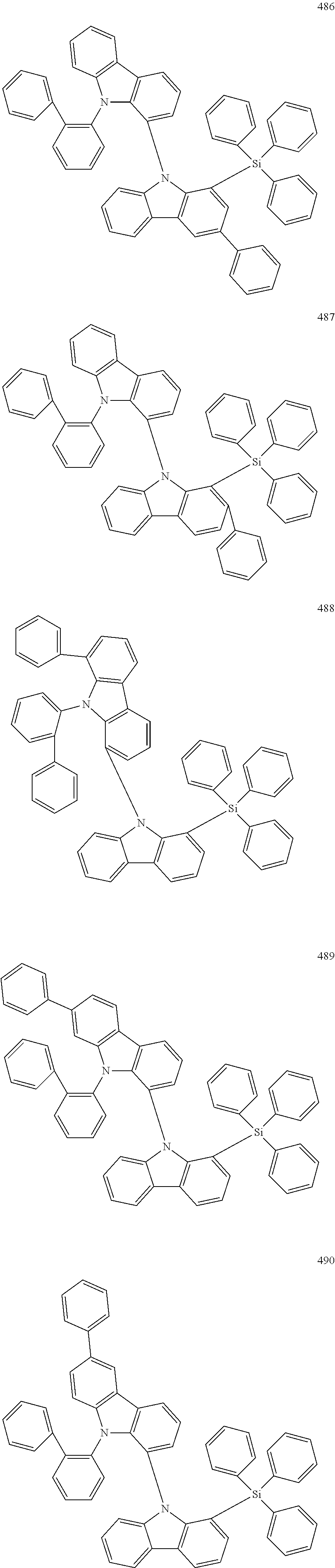

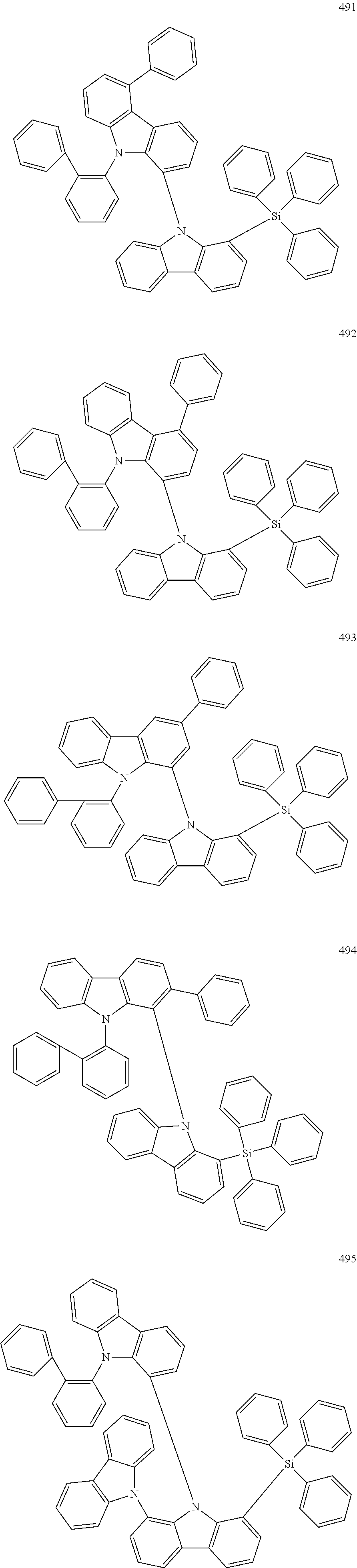

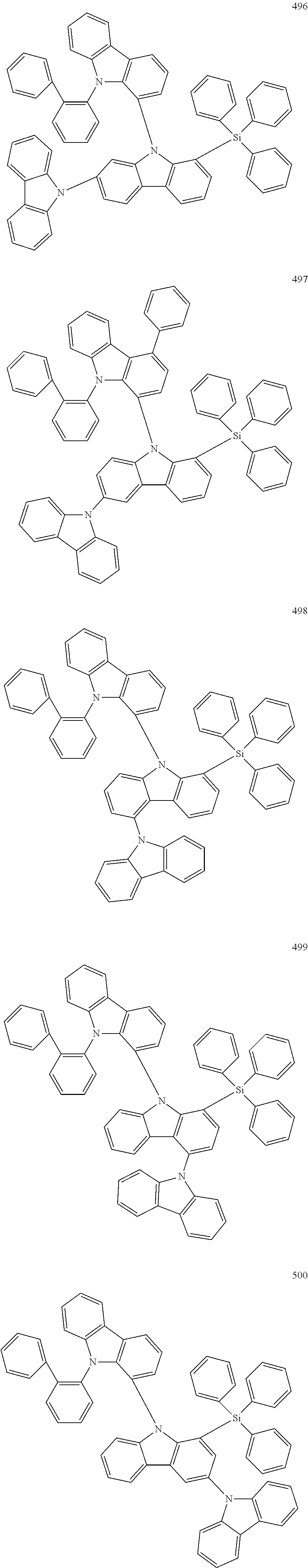

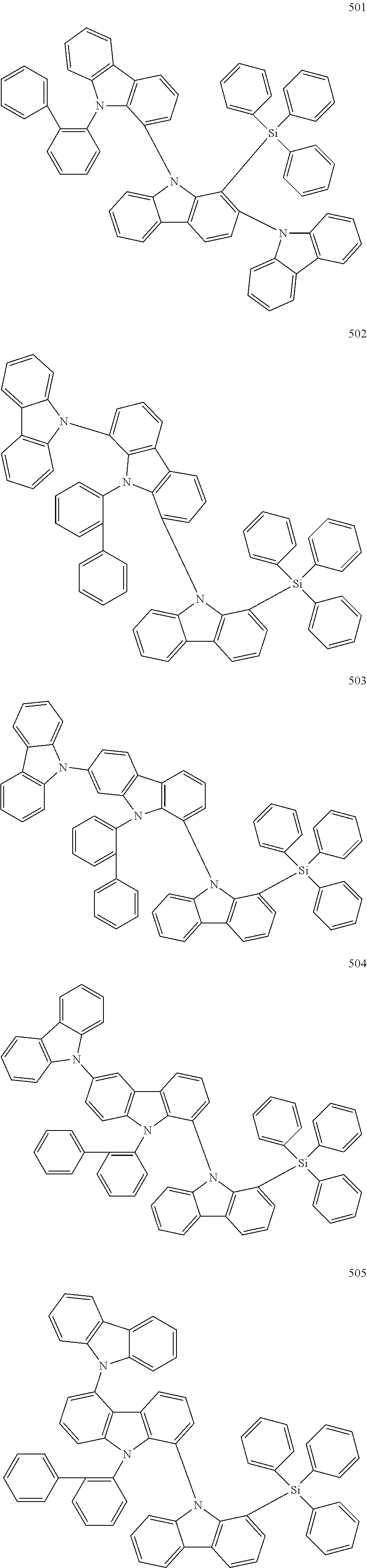

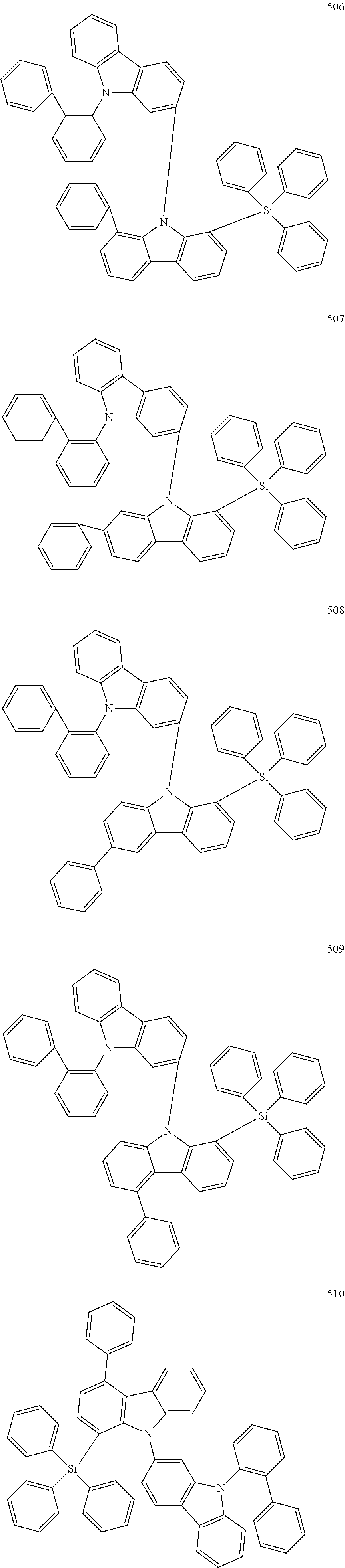

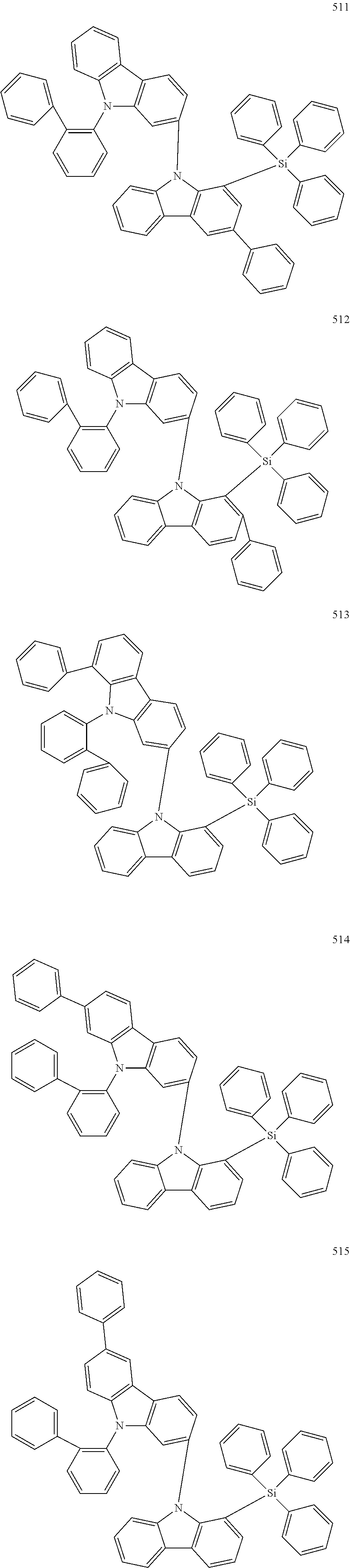

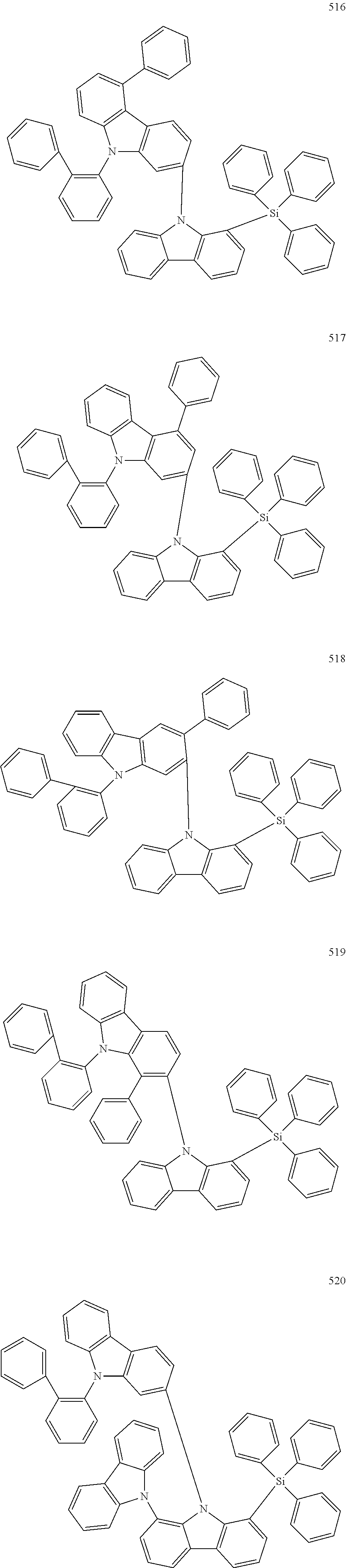

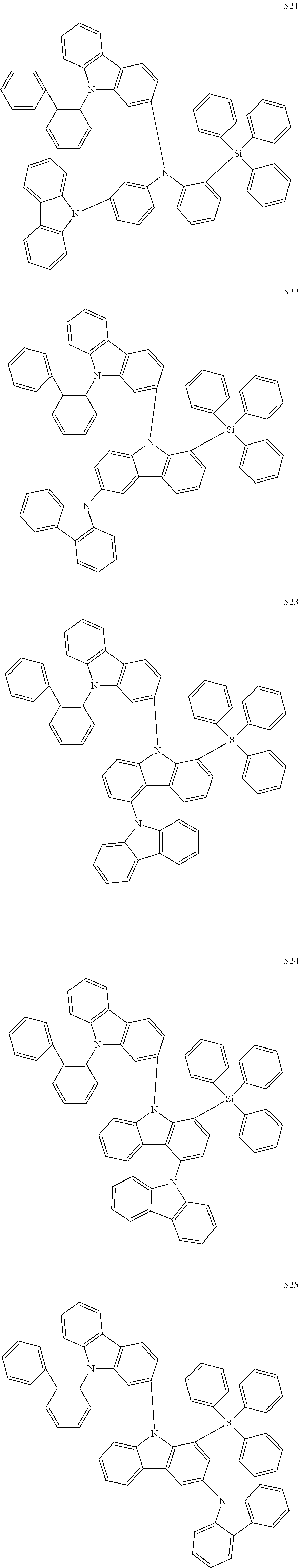

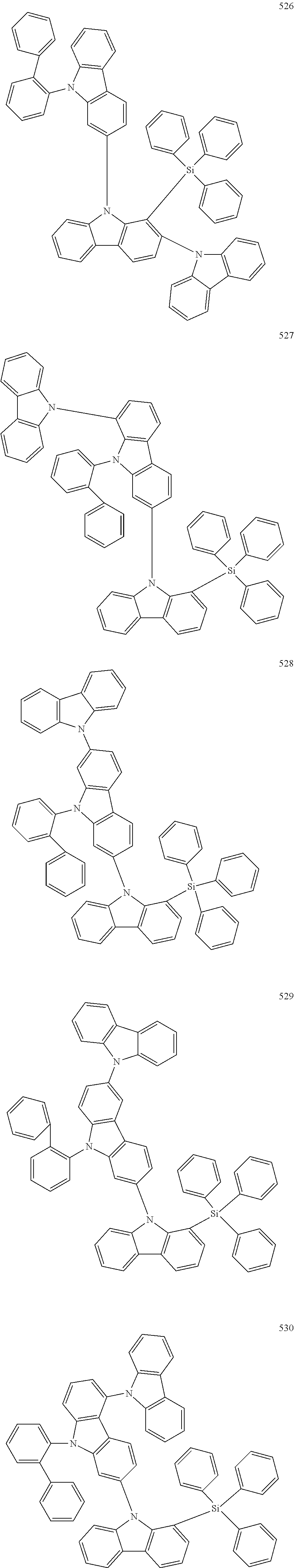

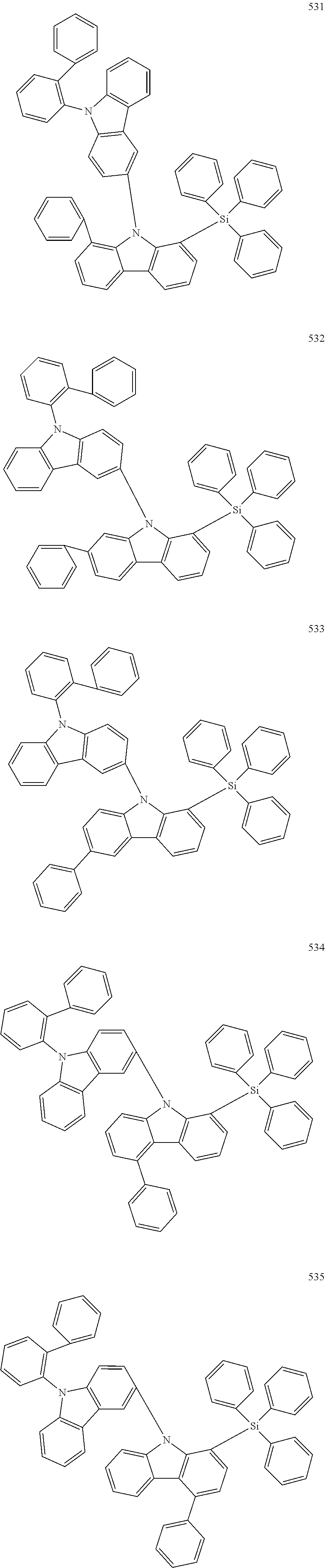

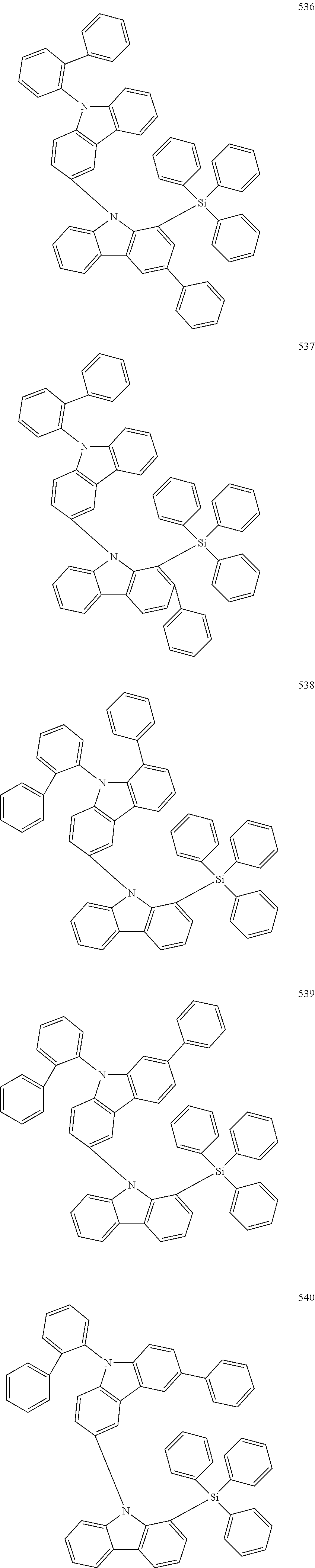

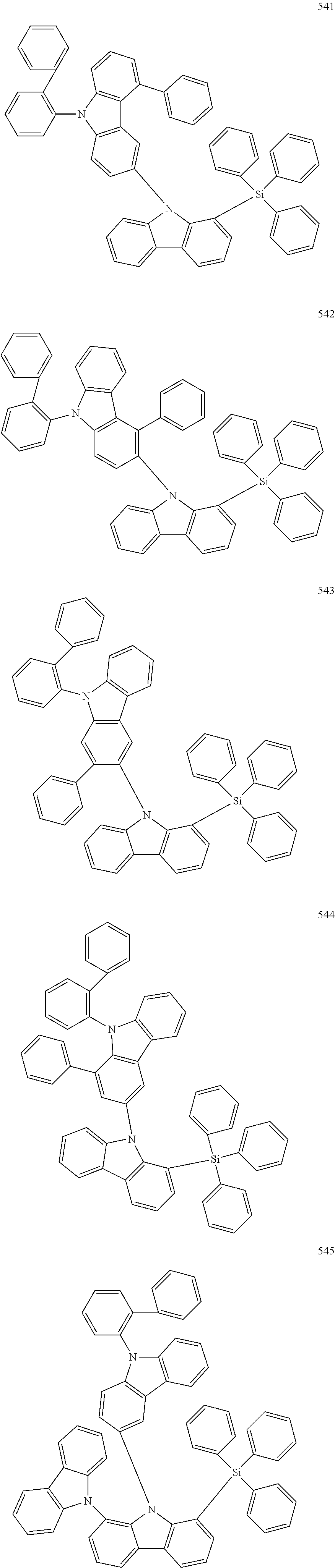

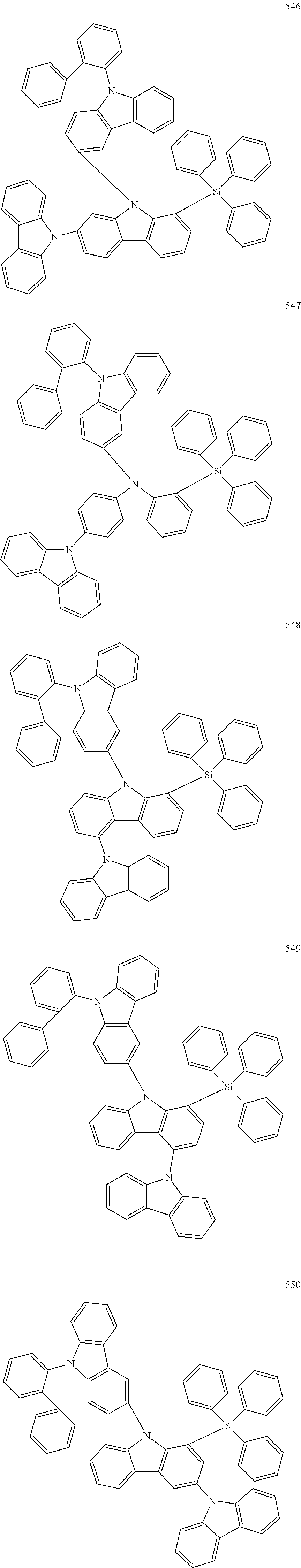

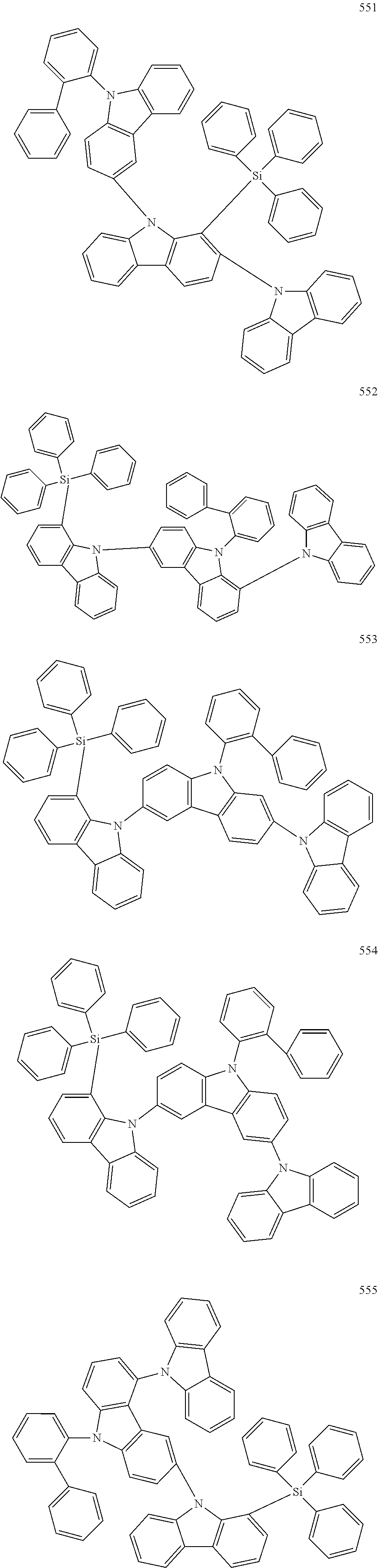

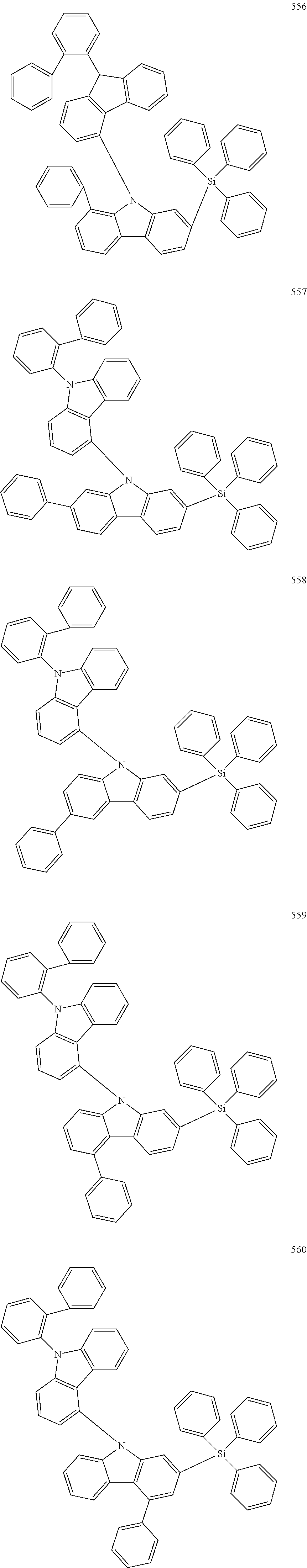

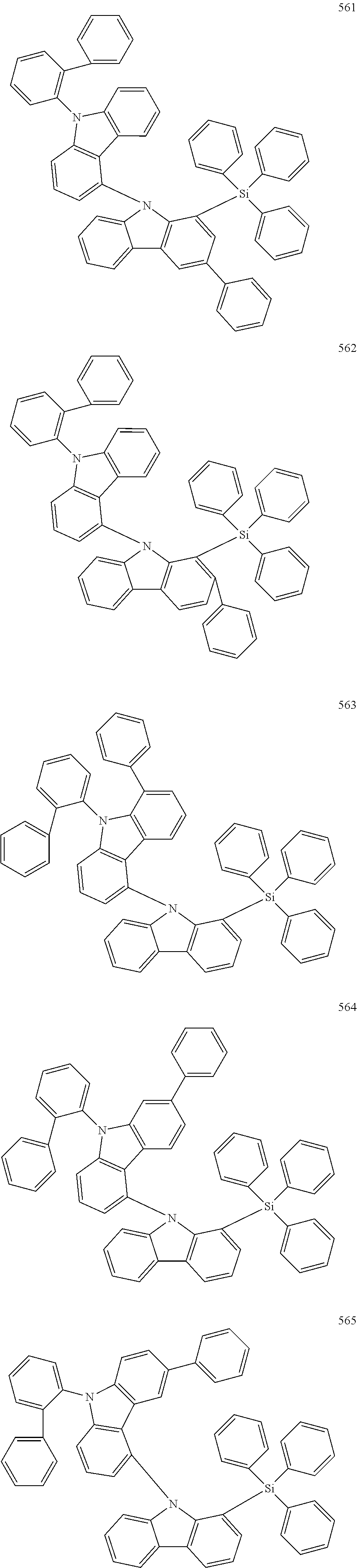

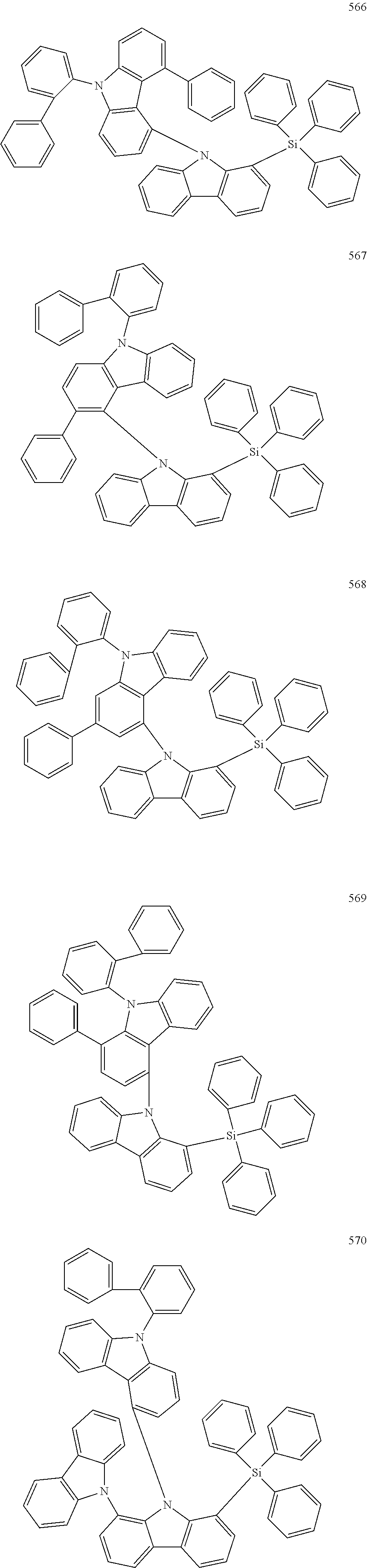

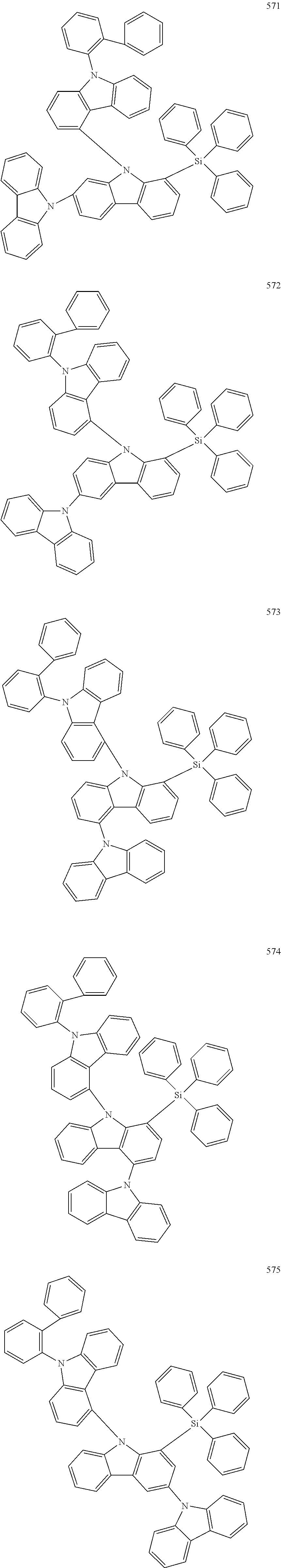

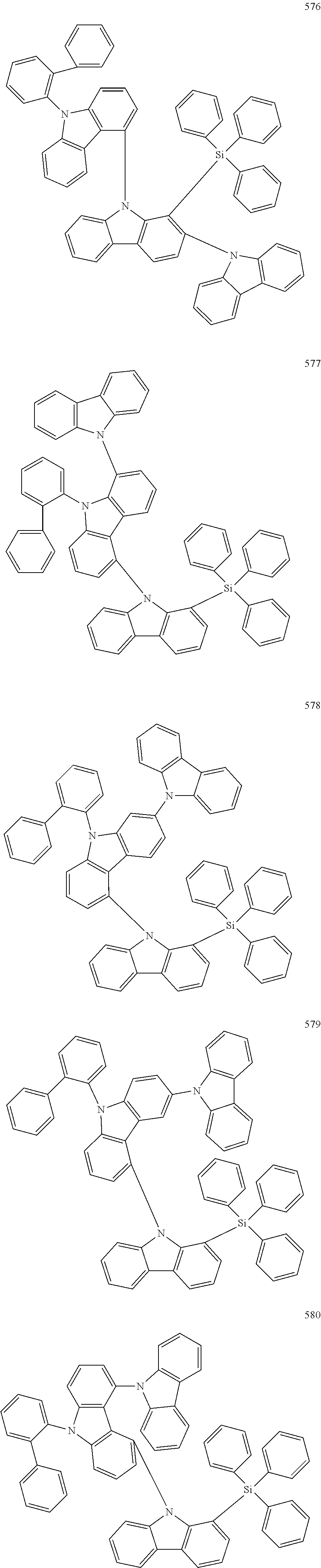

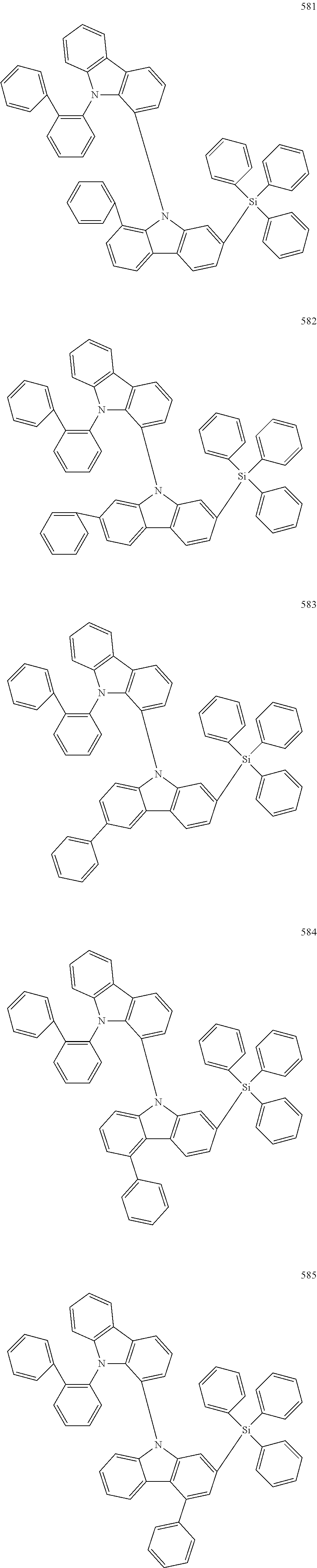

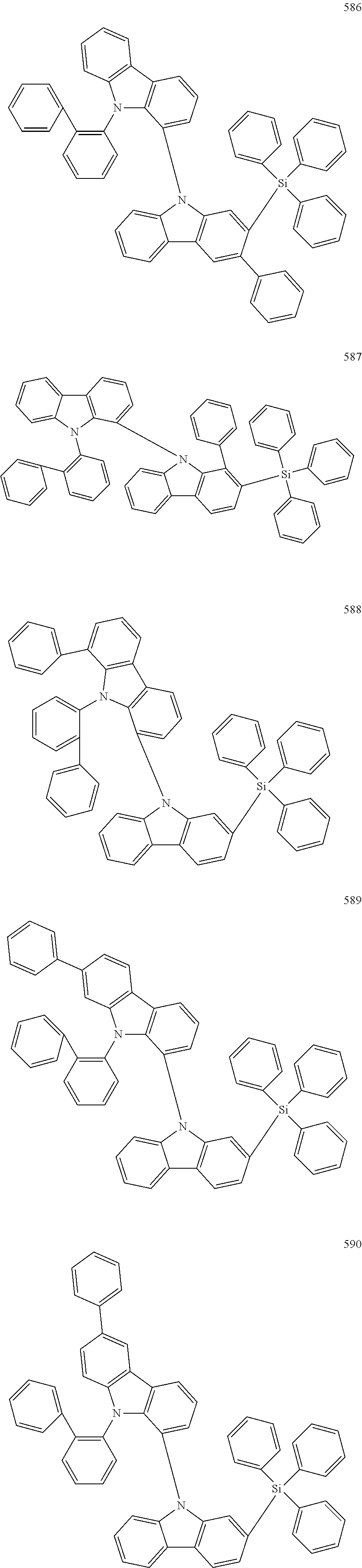

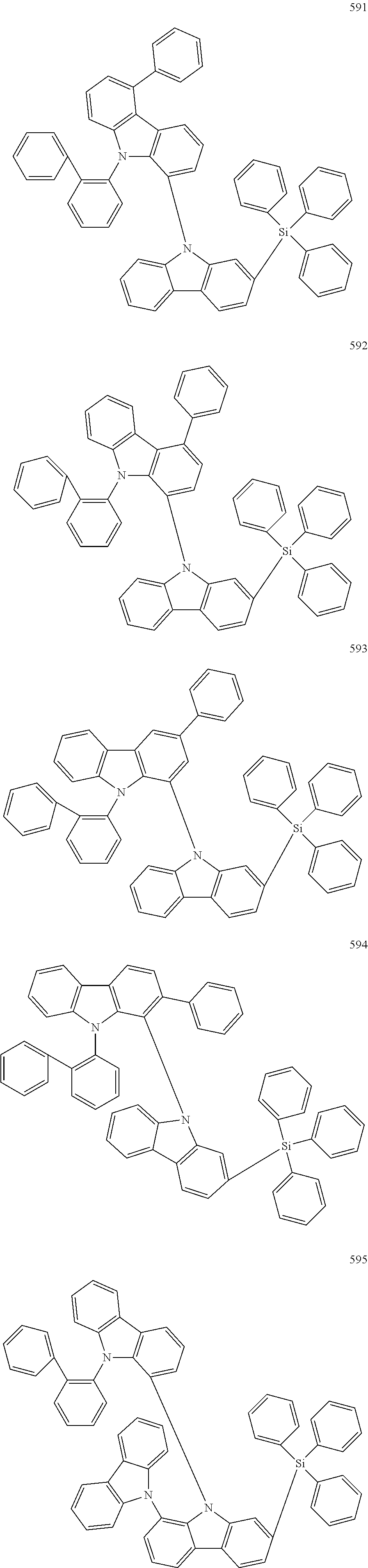

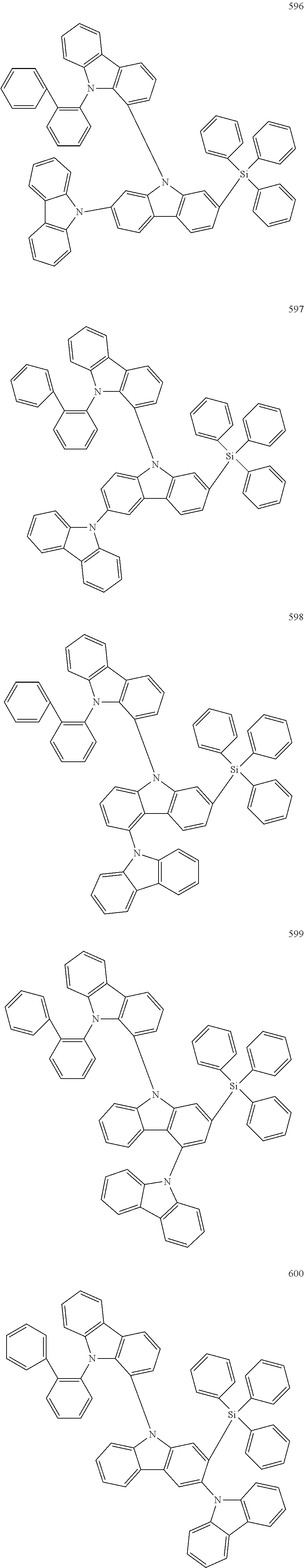

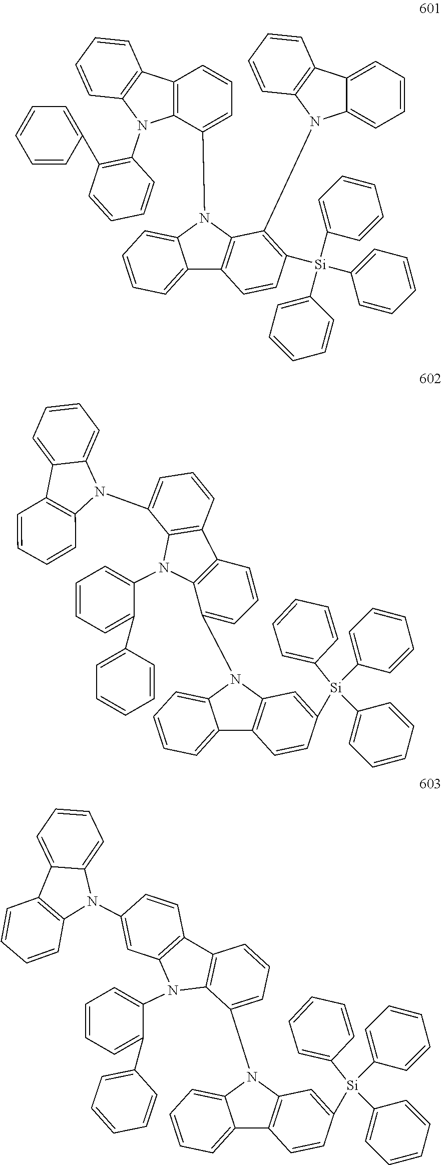 [SMILES: c1ccc(-c2ccccc2-n2c3ccccc3c3cccc(-n4c5ccccc5c5ccc([Si](c6ccccc6)(c6ccccc6)c6ccccc6)c(-n6c7ccccc7c7ccccc76)c54)c32)cc1 ; c1ccc(-c2ccccc2-n2c3c(-n4c5ccccc5c5ccccc54)cccc3c3cccc(-n4c5ccccc5c5ccc([Si](c6ccccc6)(c6ccccc6)c6ccccc6)cc54)c32)cc1 ; c1ccc(-c2ccccc2-n2c3cc(-n4c5ccccc5c5ccccc54)ccc3c3cccc(-n4c5ccccc5c5ccc([Si](c6ccccc6)(c6ccccc6)c6ccccc6)cc54)c32)cc1]

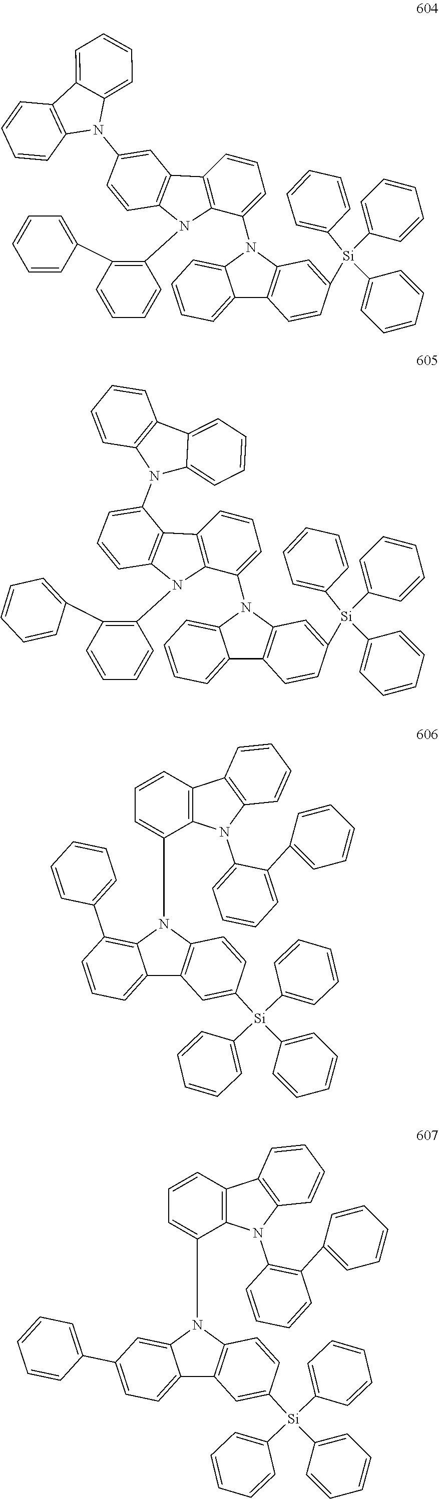 [SMILES: c1ccc(-c2ccccc2-n2c3ccc(-n4c5ccccc5c5ccccc54)cc3c3cccc(-n4c5ccccc5c5ccc([Si](c6ccccc6)(c6ccccc6)c6ccccc6)cc54)c32)cc1 ; c1ccc(-c2ccccc2-n2c3cccc(-n4c5ccccc5c5ccccc54)c3c3cccc(-n4c5ccccc5c5ccc([Si](c6ccccc6)(c6ccccc6)c6ccccc6)cc54)c32)cc1 ; c1ccc(-c2ccccc2-n2c3ccccc3c3cccc(-n4c5ccc([Si](c6ccccc6)(c6ccccc6)c6ccccc6)cc5c5cccc(-c6ccccc6)c54)c32)cc1 ; c1ccc(-c2ccc3c4cc([Si](c5ccccc5)(c5ccccc5)c5ccccc5)ccc4n(-c4cccc5c6ccccc6n(-c6ccccc6-c6ccccc6)c45)c3c2)cc1]

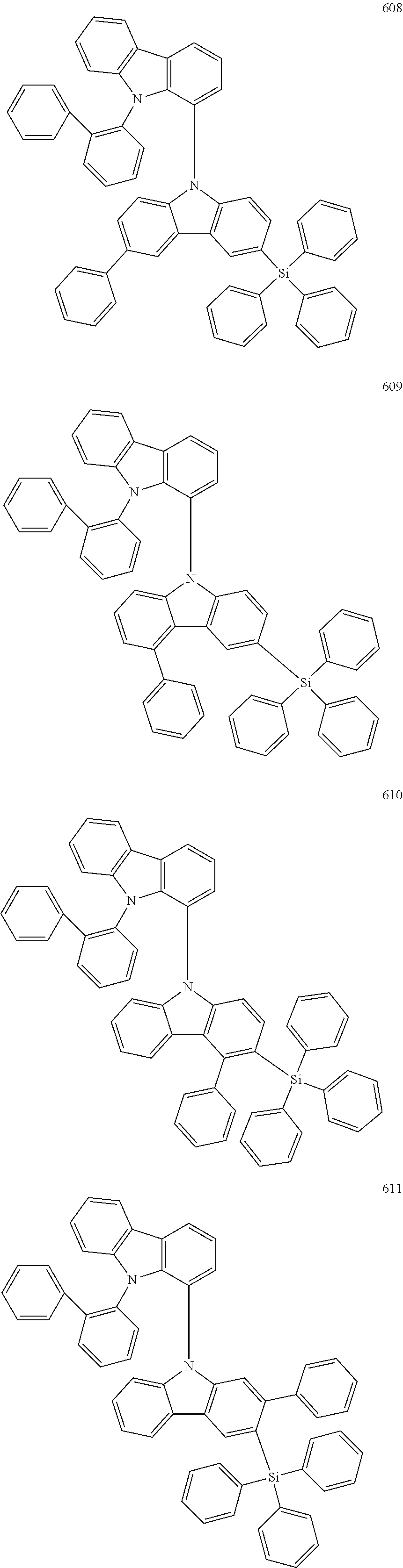 [SMILES: c1ccc(-c2ccc3c(c2)c2cc([Si](c4ccccc4)(c4ccccc4)c4ccccc4)ccc2n3-c2cccc3c4ccccc4n(-c4ccccc4-c4ccccc4)c23)cc1 ; c1ccc(-c2ccccc2-n2c3ccccc3c3cccc(-n4c5ccc([Si](c6ccccc6)(c6ccccc6)c6ccccc6)cc5c5c(-c6ccccc6)cccc54)c32)cc1 ; c1ccc(-c2ccccc2-n2c3ccccc3c3cccc(-n4c5ccccc5c5c(-c6ccccc6)c([Si](c6ccccc6)(c6ccccc6)c6ccccc6)ccc54)c32)cc1 ; c1ccc(-c2ccccc2-n2c3ccccc3c3cccc(-n4c5ccccc5c5cc([Si](c6ccccc6)(c6ccccc6)c6ccccc6)c(-c6ccccc6)cc54)c32)cc1]

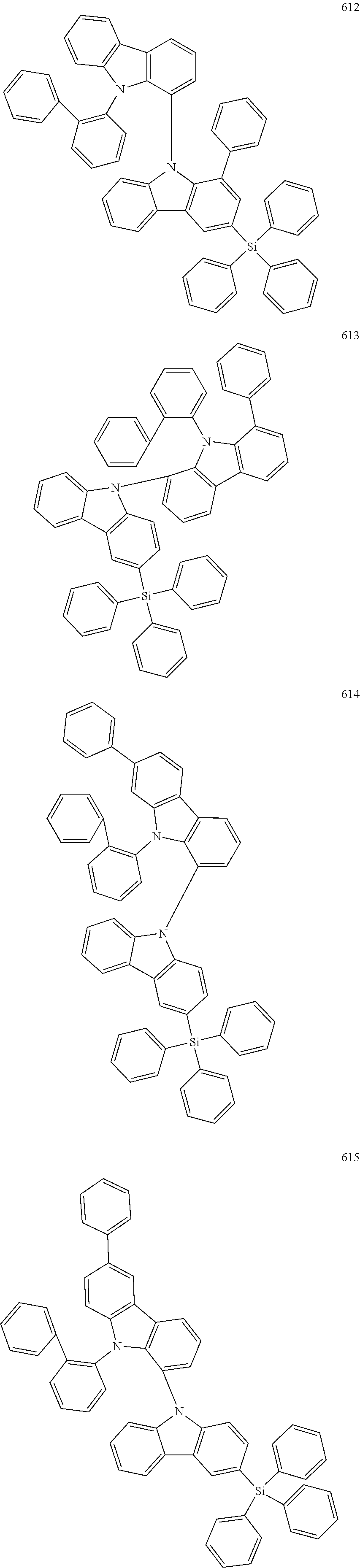

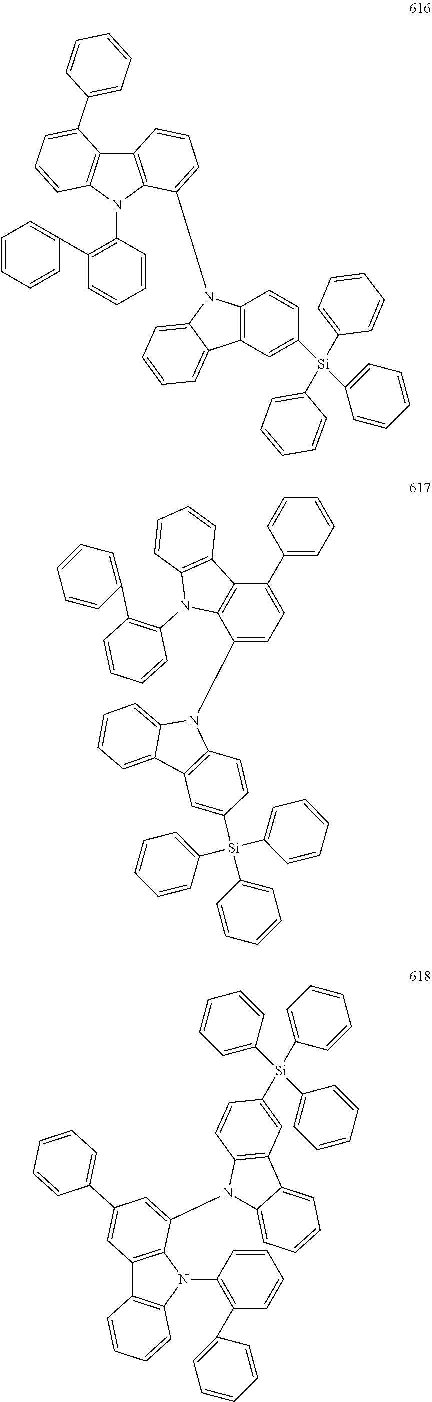

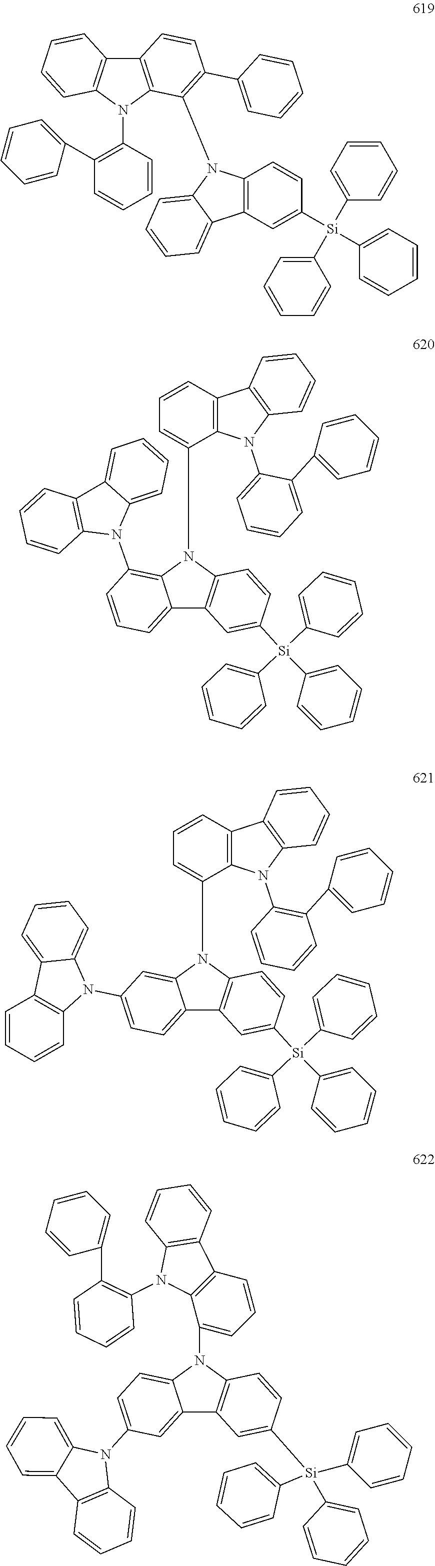

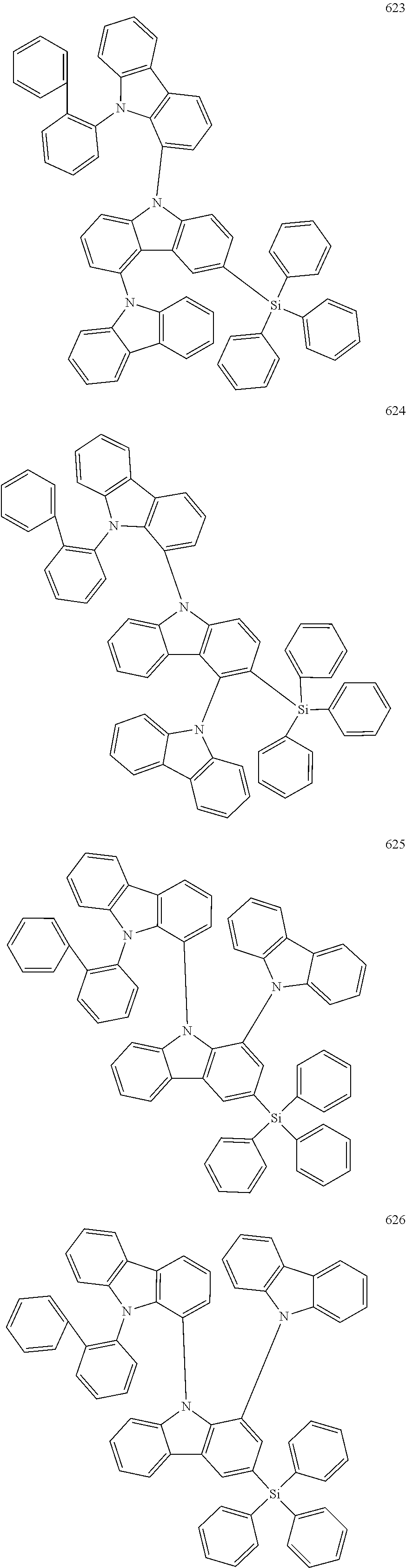

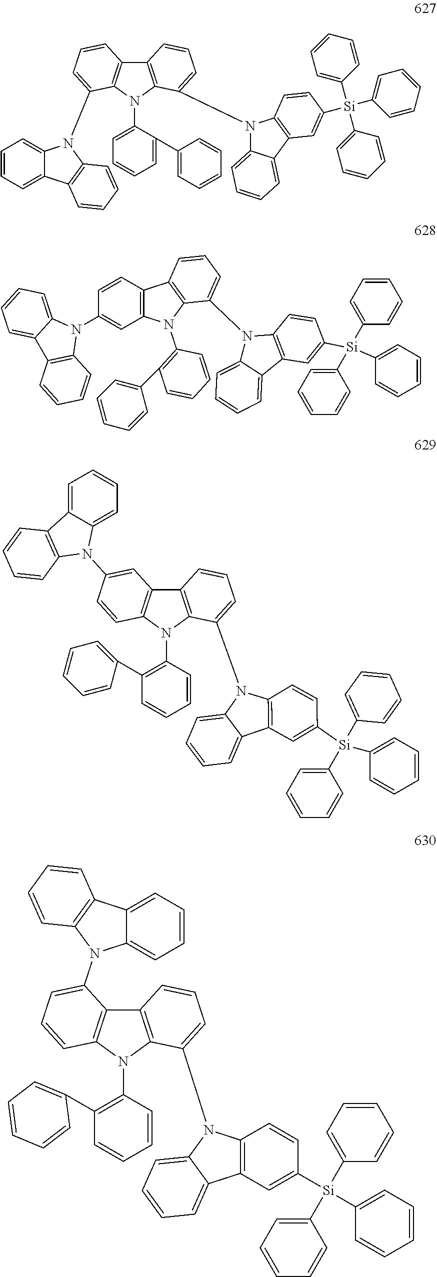 [SMILES: c1ccc(-c2ccccc2-n2c3c(-n4c5ccccc5c5ccccc54)cccc3c3cccc(-n4c5ccccc5c5cc([Si](c6ccccc6)(c6ccccc6)c6ccccc6)ccc54)c32)cc1 ; c1ccc(-c2ccccc2-n2c3cc(-n4c5ccccc5c5ccccc54)ccc3c3cccc(-n4c5ccccc5c5cc([Si](c6ccccc6)(c6ccccc6)c6ccccc6)ccc54)c32)cc1 ; c1ccc(-c2ccccc2-n2c3ccc(-n4c5ccccc5c5ccccc54)cc3c3cccc(-n4c5ccccc5c5cc([Si](c6ccccc6)(c6ccccc6)c6ccccc6)ccc54)c32)cc1 ; c1ccc(-c2ccccc2-n2c3cccc(-n4c5ccccc5c5ccccc54)c3c3cccc(-n4c5ccccc5c5cc([Si](c6ccccc6)(c6ccccc6)c6ccccc6)ccc54)c32)cc1]

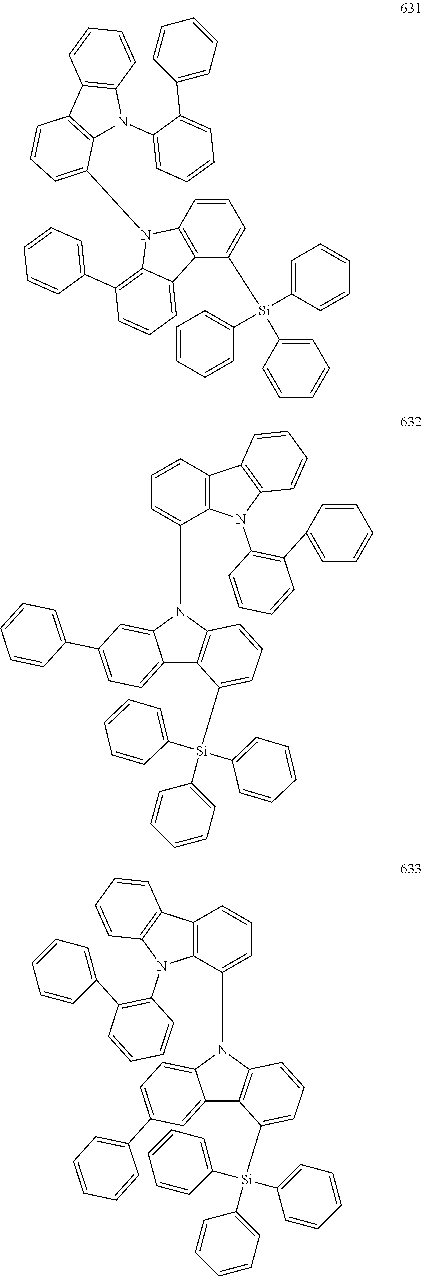

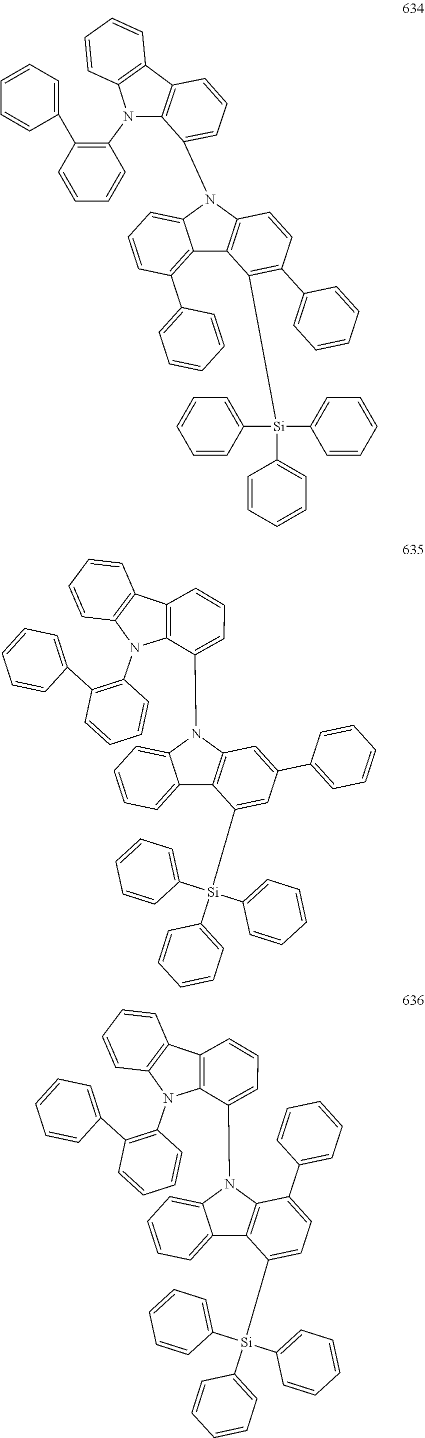

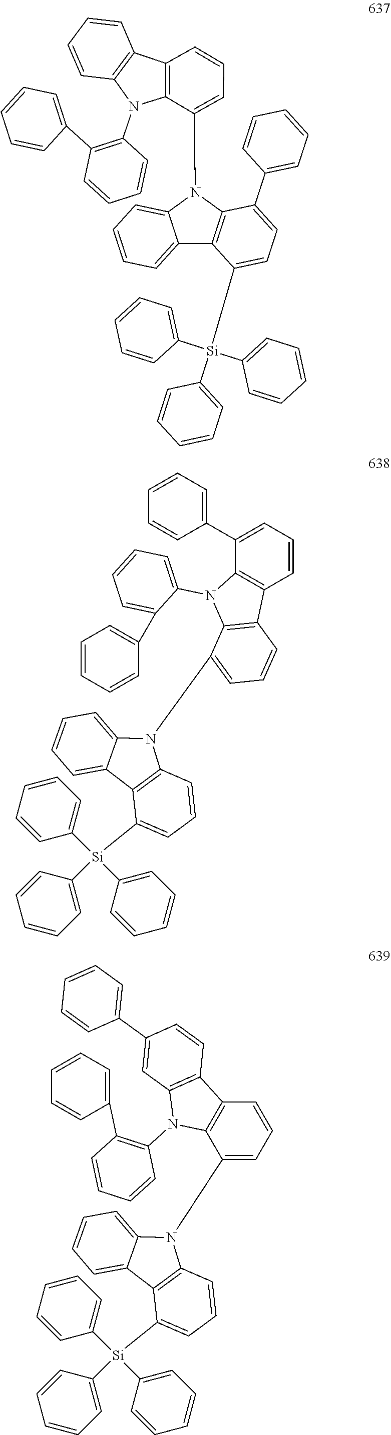

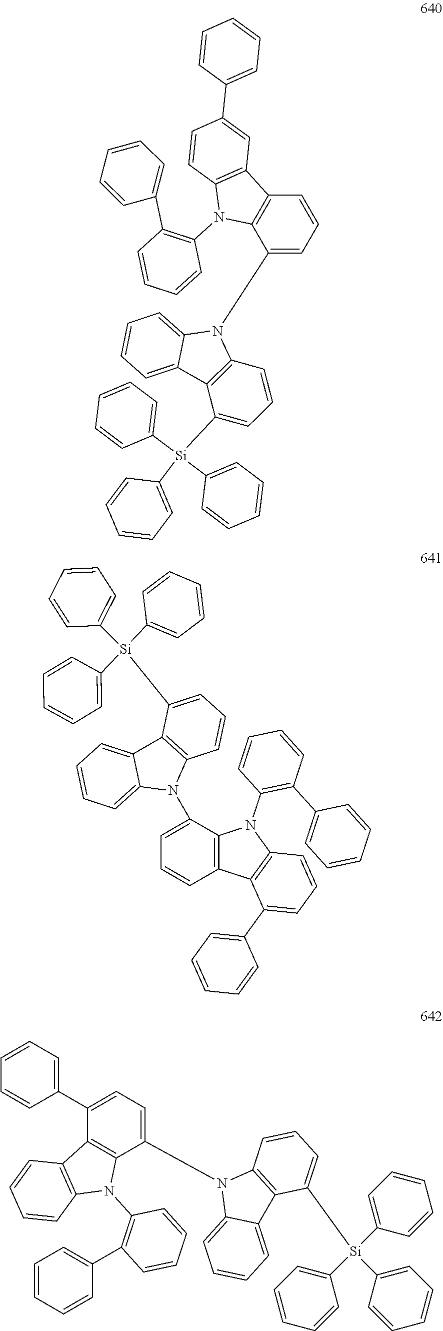

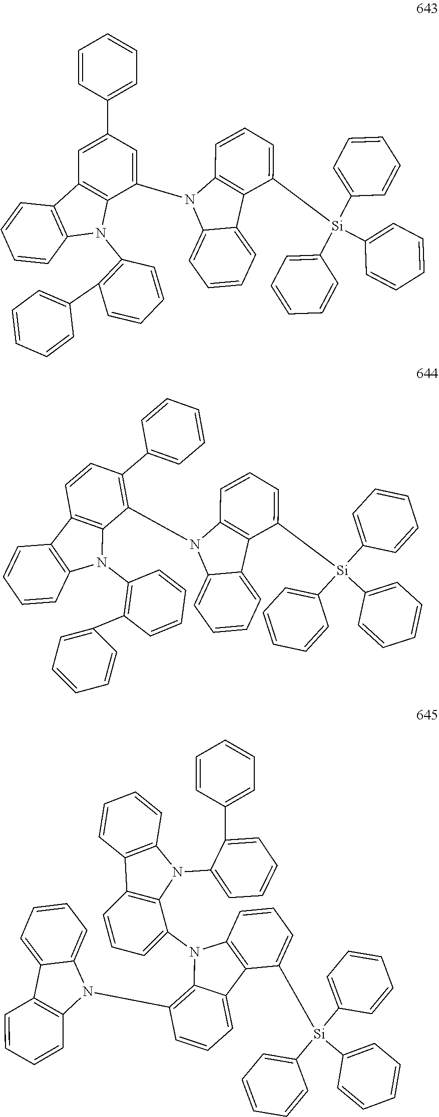 [SMILES: c1ccc(-c2cc(-n3c4ccccc4c4c([Si](c5ccccc5)(c5ccccc5)c5ccccc5)cccc43)c3c(c2)c2ccccc2n3-c2ccccc2-c2ccccc2)cc1 ; c1ccc(-c2ccccc2-n2c3ccccc3c3ccc(-c4ccccc4)c(-n4c5ccccc5c5c([Si](c6ccccc6)(c6ccccc6)c6ccccc6)cccc54)c32)cc1 ; c1ccc(-c2ccccc2-n2c3ccccc3c3cccc(-n4c5cccc([Si](c6ccccc6)(c6ccccc6)c6ccccc6)c5c5cccc(-n6c7ccccc7c7ccccc76)c54)c32)cc1]

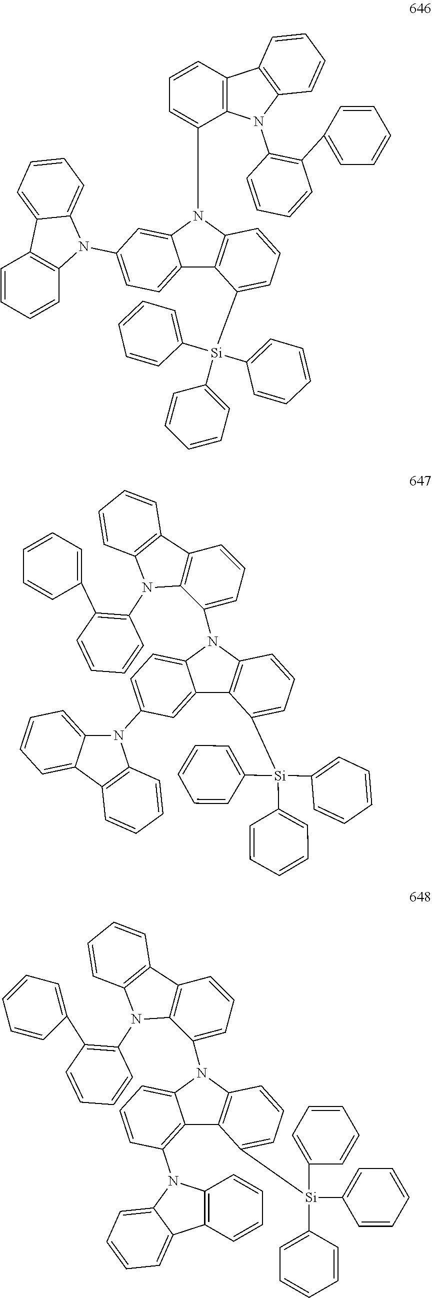 [SMILES: c1ccc(-c2ccccc2-n2c3ccccc3c3cccc(-n4c5cc(-n6c7ccccc7c7ccccc76)ccc5c5c([Si](c6ccccc6)(c6ccccc6)c6ccccc6)cccc54)c32)cc1 ; c1ccc(-c2ccccc2-n2c3ccccc3c3cccc(-n4c5ccc(-n6c7ccccc7c7ccccc76)cc5c5c([Si](c6ccccc6)(c6ccccc6)c6ccccc6)cccc54)c32)cc1 ; c1ccc(-c2ccccc2-n2c3ccccc3c3cccc(-n4c5cccc(-n6c7ccccc7c7ccccc76)c5c5c([Si](c6ccccc6)(c6ccccc6)c6ccccc6)cccc54)c32)cc1]

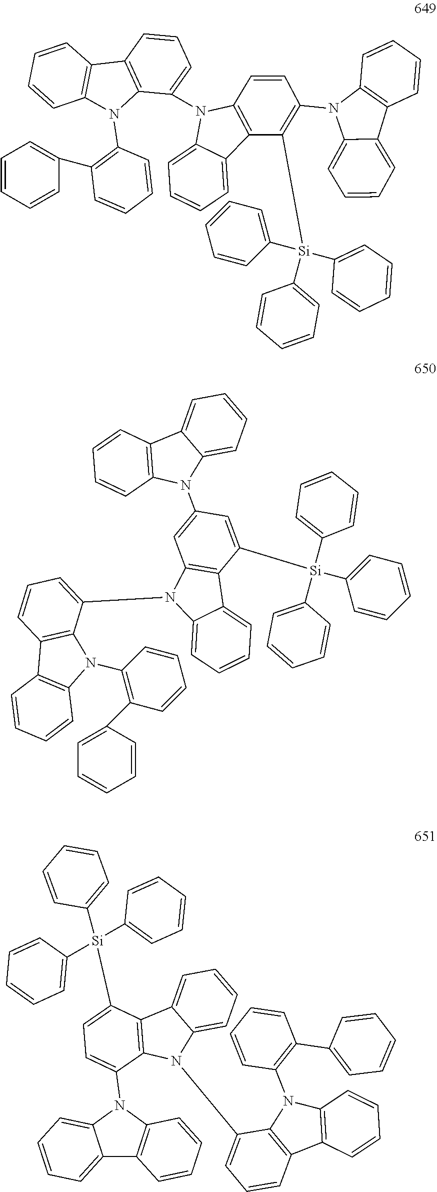 [SMILES: c1ccc(-c2ccccc2-n2c3ccccc3c3cccc(-n4c5ccccc5c5c([Si](c6ccccc6)(c6ccccc6)c6ccccc6)c(-n6c7ccccc7c7ccccc76)ccc54)c32)cc1 ; c1ccc(-c2ccccc2-n2c3ccccc3c3cccc(-n4c5ccccc5c5c([Si](c6ccccc6)(c6ccccc6)c6ccccc6)cc(-n6c7ccccc7c7ccccc76)cc54)c32)cc1 ; c1ccc(-c2ccccc2-n2c3ccccc3c3cccc(-n4c5ccccc5c5c([Si](c6ccccc6)(c6ccccc6)c6ccccc6)ccc(-n6c7ccccc7c7ccccc76)c54)c32)cc1]

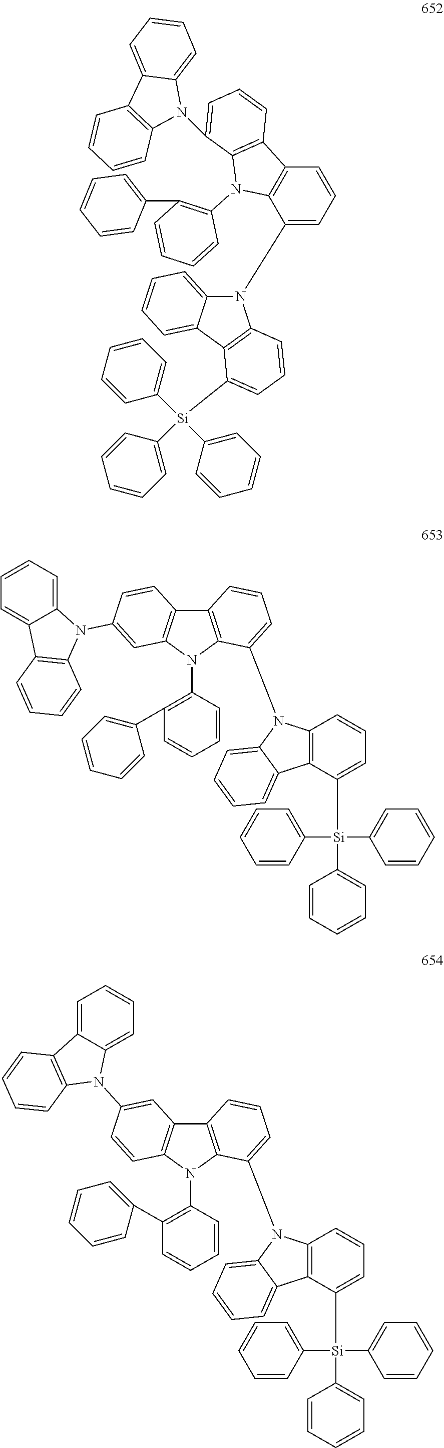 [SMILES: c1ccc(-c2ccccc2-n2c3c(-n4c5ccccc5c5ccccc54)cccc3c3cccc(-n4c5ccccc5c5c([Si](c6ccccc6)(c6ccccc6)c6ccccc6)cccc54)c32)cc1 ; c1ccc(-c2ccccc2-n2c3cc(-n4c5ccccc5c5ccccc54)ccc3c3cccc(-n4c5ccccc5c5c([Si](c6ccccc6)(c6ccccc6)c6ccccc6)cccc54)c32)cc1 ; c1ccc(-c2ccccc2-n2c3ccc(-n4c5ccccc5c5ccccc54)cc3c3cccc(-n4c5ccccc5c5c([Si](c6ccccc6)(c6ccccc6)c6ccccc6)cccc54)c32)cc1]

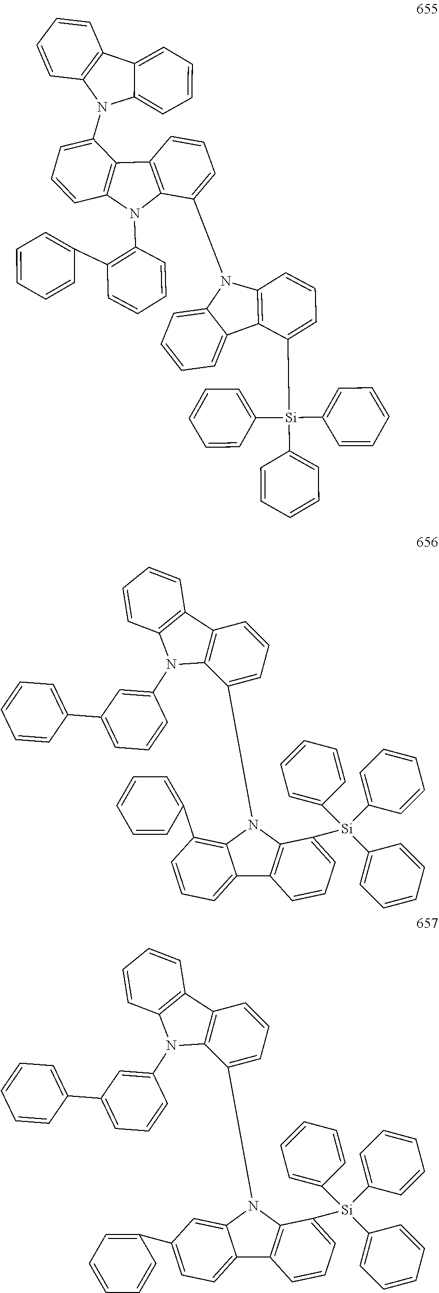 [SMILES: c1ccc(-c2ccccc2-n2c3cccc(-n4c5ccccc5c5ccccc54)c3c3cccc(-n4c5ccccc5c5c([Si](c6ccccc6)(c6ccccc6)c6ccccc6)cccc54)c32)cc1 ; c1ccc(-c2cccc(-n3c4ccccc4c4cccc(-n5c6c(-c7ccccc7)cccc6c6cccc([Si](c7ccccc7)(c7ccccc7)c7ccccc7)c65)c43)c2)cc1 ; c1ccc(-c2cccc(-n3c4ccccc4c4cccc(-n5c6cc(-c7ccccc7)ccc6c6cccc([Si](c7ccccc7)(c7ccccc7)c7ccccc7)c65)c43)c2)cc1]

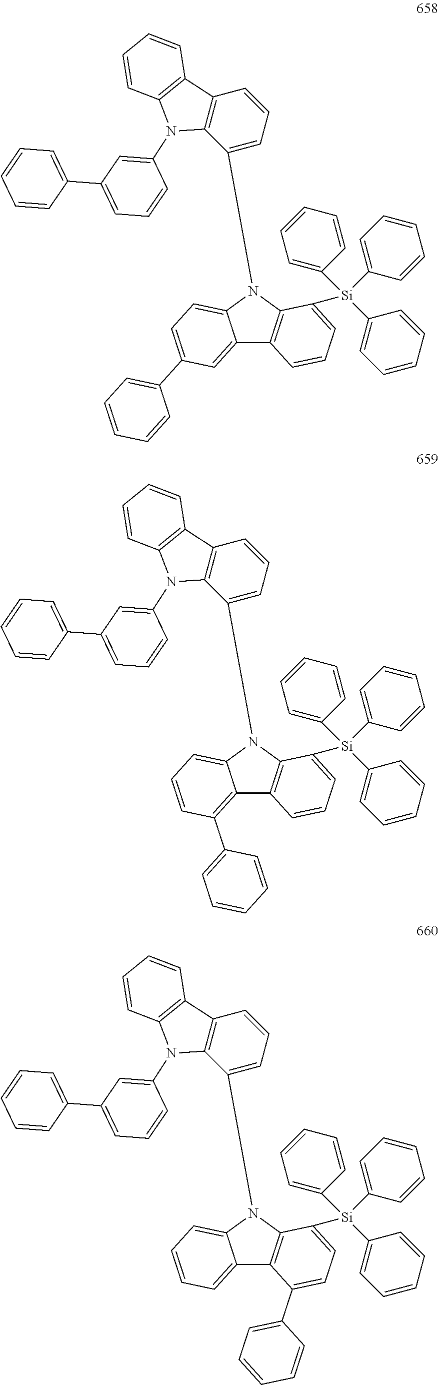

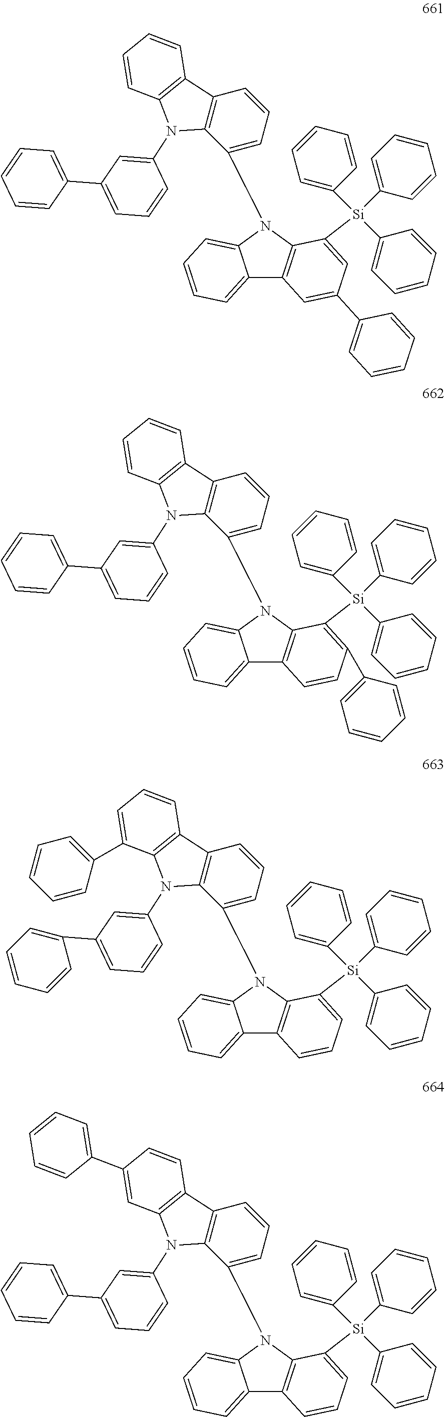 [SMILES: c1ccc(-c2cccc(-n3c4ccccc4c4cccc(-n5c6ccccc6c6cc(-c7ccccc7)cc([Si](c7ccccc7)(c7ccccc7)c7ccccc7)c65)c43)c2)cc1 ; c1ccc(-c2cccc(-n3c4ccccc4c4cccc(-n5c6ccccc6c6ccc(-c7ccccc7)c([Si](c7ccccc7)(c7ccccc7)c7ccccc7)c65)c43)c2)cc1 ; c1ccc(-c2cccc(-n3c4c(-c5ccccc5)cccc4c4cccc(-n5c6ccccc6c6cccc([Si](c7ccccc7)(c7ccccc7)c7ccccc7)c65)c43)c2)cc1 ; c1ccc(-c2cccc(-n3c4cc(-c5ccccc5)ccc4c4cccc(-n5c6ccccc6c6cccc([Si](c7ccccc7)(c7ccccc7)c7ccccc7)c65)c43)c2)cc1]

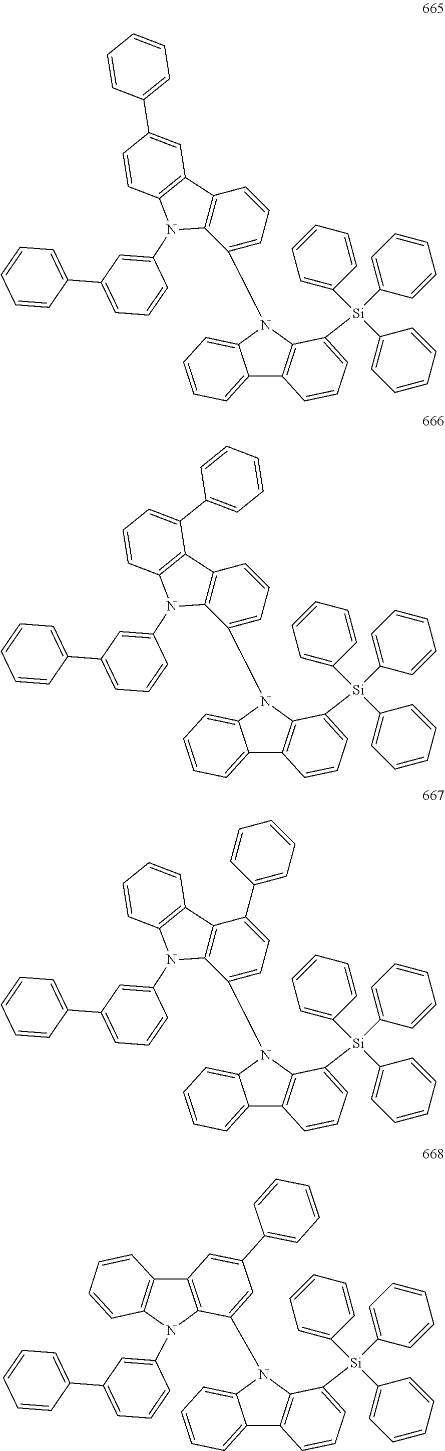

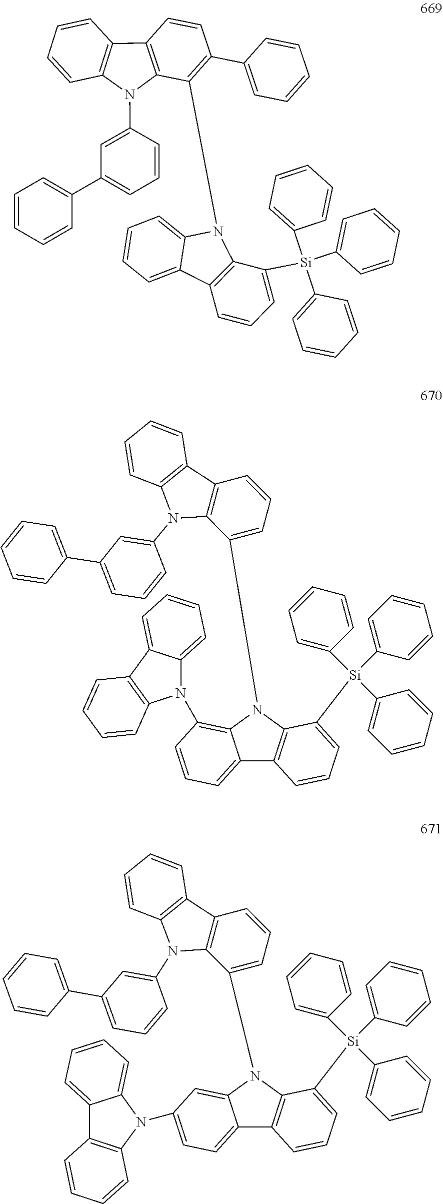 [SMILES: c1ccc(-c2cccc(-n3c4ccccc4c4ccc(-c5ccccc5)c(-n5c6ccccc6c6cccc([Si](c7ccccc7)(c7ccccc7)c7ccccc7)c65)c43)c2)cc1 ; c1ccc(-c2cccc(-n3c4ccccc4c4cccc(-n5c6c(-n7c8ccccc8c8ccccc87)cccc6c6cccc([Si](c7ccccc7)(c7ccccc7)c7ccccc7)c65)c43)c2)cc1 ; c1ccc(-c2cccc(-n3c4ccccc4c4cccc(-n5c6cc(-n7c8ccccc8c8ccccc87)ccc6c6cccc([Si](c7ccccc7)(c7ccccc7)c7ccccc7)c65)c43)c2)cc1]

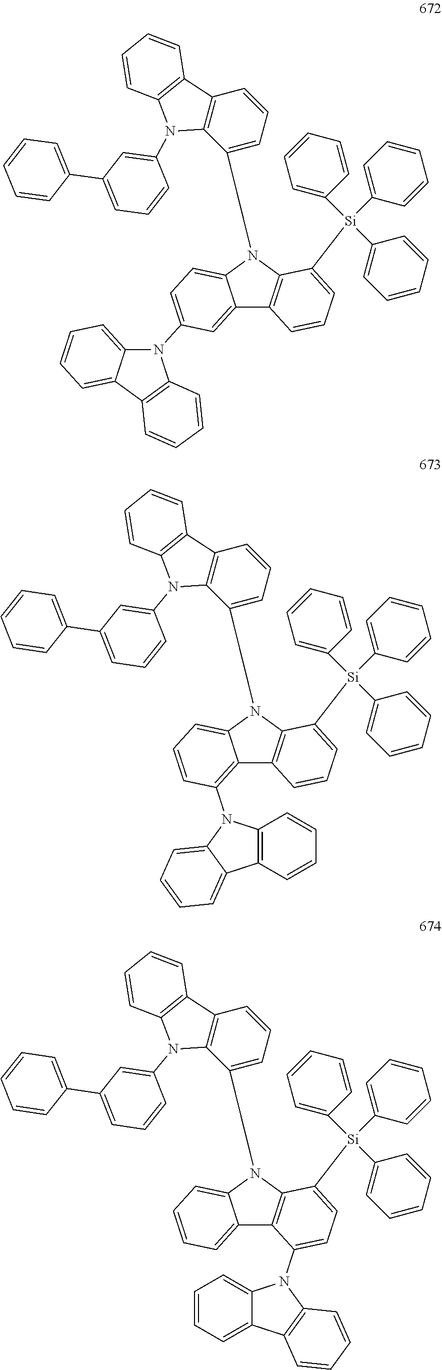 [SMILES: c1ccc(-c2cccc(-n3c4ccccc4c4cccc(-n5c6ccc(-n7c8ccccc8c8ccccc87)cc6c6cccc([Si](c7ccccc7)(c7ccccc7)c7ccccc7)c65)c43)c2)cc1 ; c1ccc(-c2cccc(-n3c4ccccc4c4cccc(-n5c6cccc(-n7c8ccccc8c8ccccc87)c6c6cccc([Si](c7ccccc7)(c7ccccc7)c7ccccc7)c65)c43)c2)cc1 ; c1ccc(-c2cccc(-n3c4ccccc4c4cccc(-n5c6ccccc6c6c(-n7c8ccccc8c8ccccc87)ccc([Si](c7ccccc7)(c7ccccc7)c7ccccc7)c65)c43)c2)cc1]

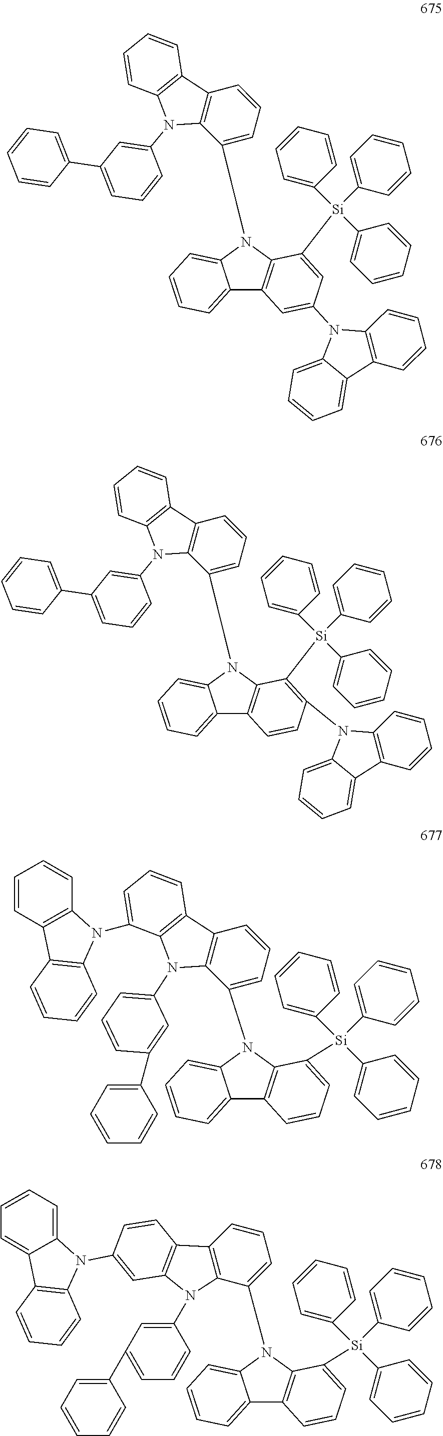 [SMILES: c1ccc(-c2cccc(-n3c4ccccc4c4cccc(-n5c6ccccc6c6cc(-n7c8ccccc8c8ccccc87)cc([Si](c7ccccc7)(c7ccccc7)c7ccccc7)c65)c43)c2)cc1 ; c1ccc(-c2cccc(-n3c4ccccc4c4cccc(-n5c6ccccc6c6ccc(-n7c8ccccc8c8ccccc87)c([Si](c7ccccc7)(c7ccccc7)c7ccccc7)c65)c43)c2)cc1 ; c1ccc(-c2cccc(-n3c4c(-n5c6ccccc6c6ccccc65)cccc4c4cccc(-n5c6ccccc6c6cccc([Si](c7ccccc7)(c7ccccc7)c7ccccc7)c65)c43)c2)cc1 ; c1ccc(-c2cccc(-n3c4cc(-n5c6ccccc6c6ccccc65)ccc4c4cccc(-n5c6ccccc6c6cccc([Si](c7ccccc7)(c7ccccc7)c7ccccc7)c65)c43)c2)cc1]

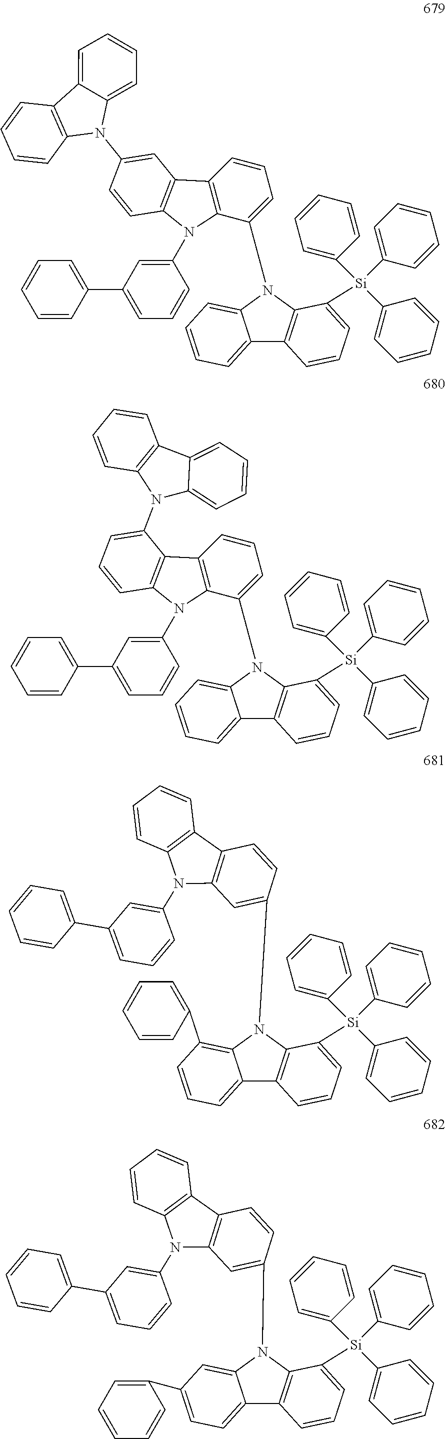 [SMILES: c1ccc(-c2cccc(-n3c4ccc(-n5c6ccccc6c6ccccc65)cc4c4cccc(-n5c6ccccc6c6cccc([Si](c7ccccc7)(c7ccccc7)c7ccccc7)c65)c43)c2)cc1 ; c1ccc(-c2cccc(-n3c4cccc(-n5c6ccccc6c6ccccc65)c4c4cccc(-n5c6ccccc6c6cccc([Si](c7ccccc7)(c7ccccc7)c7ccccc7)c65)c43)c2)cc1 ; c1ccc(-c2cccc(-n3c4ccccc4c4ccc(-n5c6c(-c7ccccc7)cccc6c6cccc([Si](c7ccccc7)(c7ccccc7)c7ccccc7)c65)cc43)c2)cc1 ; c1ccc(-c2cccc(-n3c4ccccc4c4ccc(-n5c6cc(-c7ccccc7)ccc6c6cccc([Si](c7ccccc7)(c7ccccc7)c7ccccc7)c65)cc43)c2)cc1]

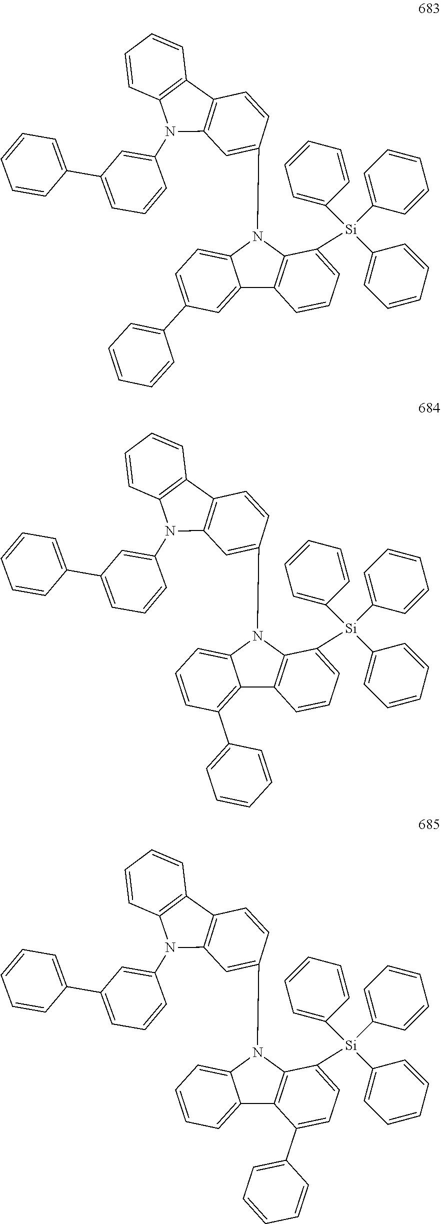

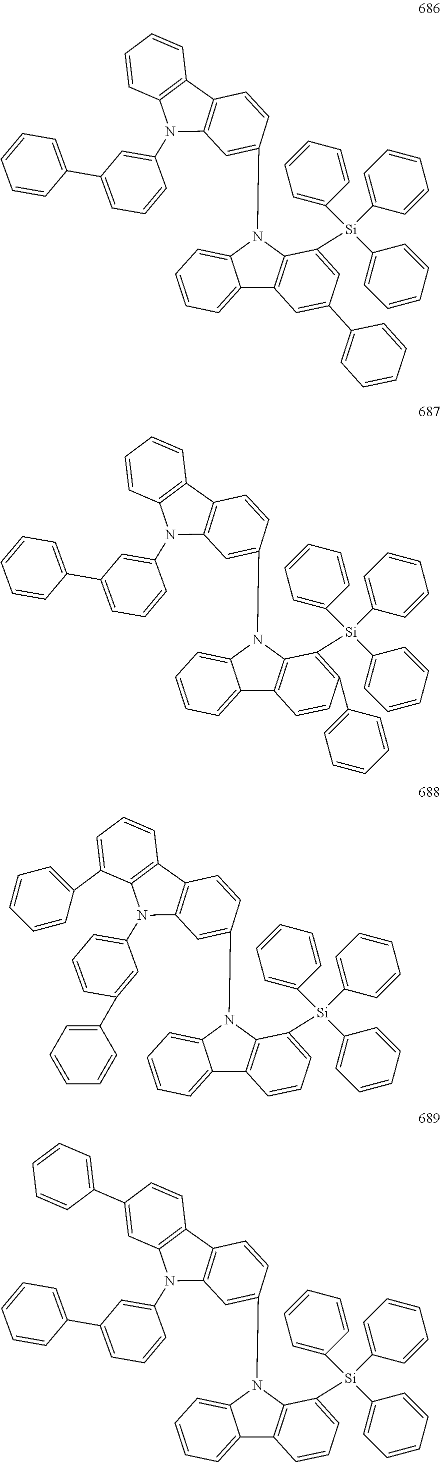 [SMILES: c1ccc(-c2cccc(-n3c4ccccc4c4ccc(-n5c6ccccc6c6cc(-c7ccccc7)cc([Si](c7ccccc7)(c7ccccc7)c7ccccc7)c65)cc43)c2)cc1 ; c1ccc(-c2cccc(-n3c4ccccc4c4ccc(-n5c6ccccc6c6ccc(-c7ccccc7)c([Si](c7ccccc7)(c7ccccc7)c7ccccc7)c65)cc43)c2)cc1 ; c1ccc(-c2cccc(-n3c4cc(-n5c6ccccc6c6cccc([Si](c7ccccc7)(c7ccccc7)c7ccccc7)c65)ccc4c4cccc(-c5ccccc5)c43)c2)cc1 ; c1ccc(-c2cccc(-n3c4cc(-c5ccccc5)ccc4c4ccc(-n5c6ccccc6c6cccc([Si](c7ccccc7)(c7ccccc7)c7ccccc7)c65)cc43)c2)cc1]

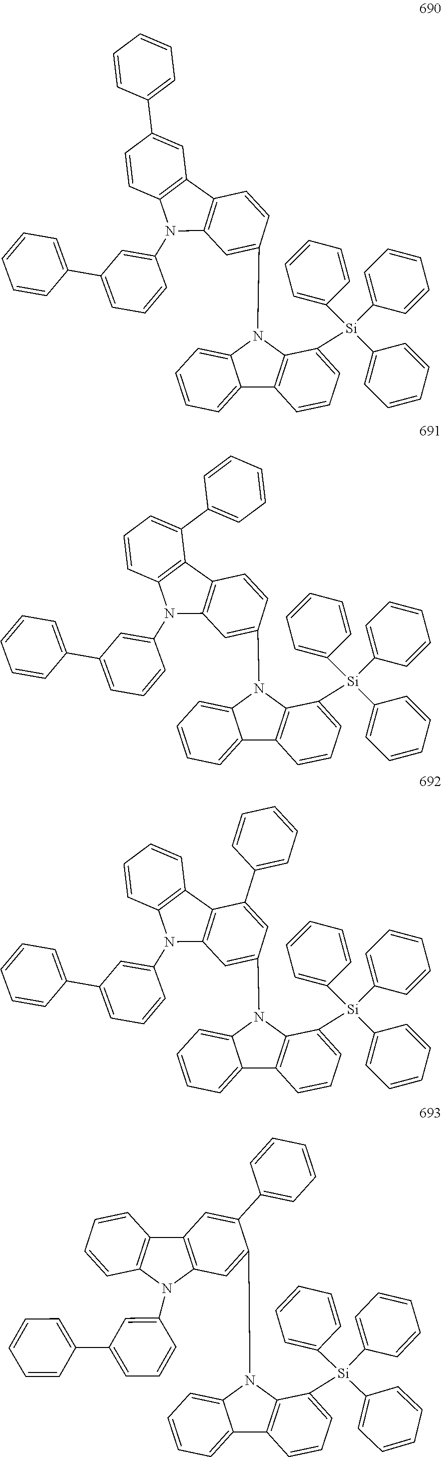

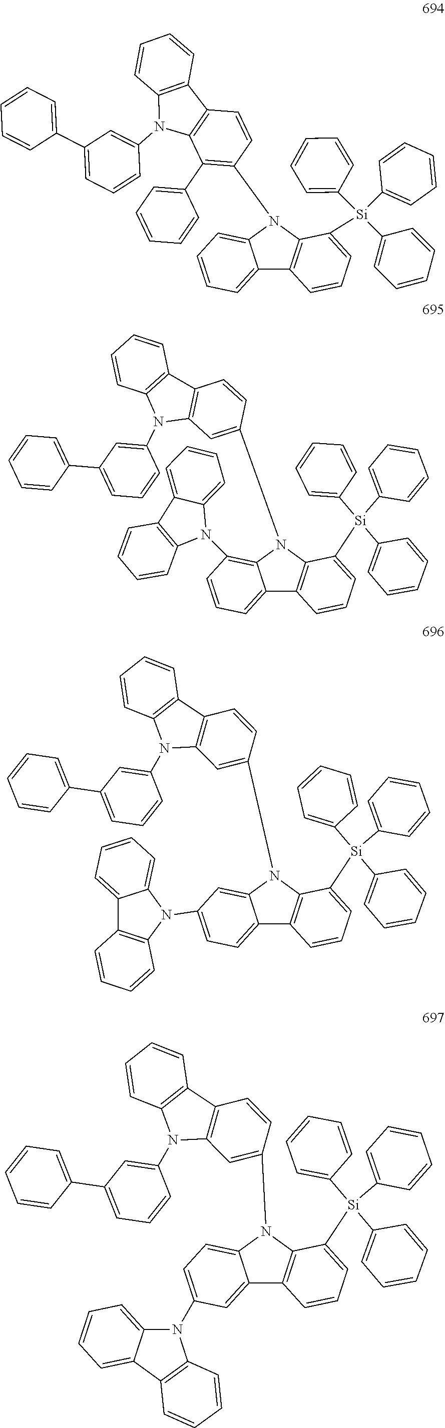 [SMILES: c1ccc(-c2cccc(-n3c4ccccc4c4ccc(-n5c6ccccc6c6cccc([Si](c7ccccc7)(c7ccccc7)c7ccccc7)c65)c(-c5ccccc5)c43)c2)cc1 ; c1ccc(-c2cccc(-n3c4ccccc4c4ccc(-n5c6c(-n7c8ccccc8c8ccccc87)cccc6c6cccc([Si](c7ccccc7)(c7ccccc7)c7ccccc7)c65)cc43)c2)cc1 ; c1ccc(-c2cccc(-n3c4ccccc4c4ccc(-n5c6cc(-n7c8ccccc8c8ccccc87)ccc6c6cccc([Si](c7ccccc7)(c7ccccc7)c7ccccc7)c65)cc43)c2)cc1 ; c1ccc(-c2cccc(-n3c4ccccc4c4ccc(-n5c6ccc(-n7c8ccccc8c8ccccc87)cc6c6cccc([Si](c7ccccc7)(c7ccccc7)c7ccccc7)c65)cc43)c2)cc1]

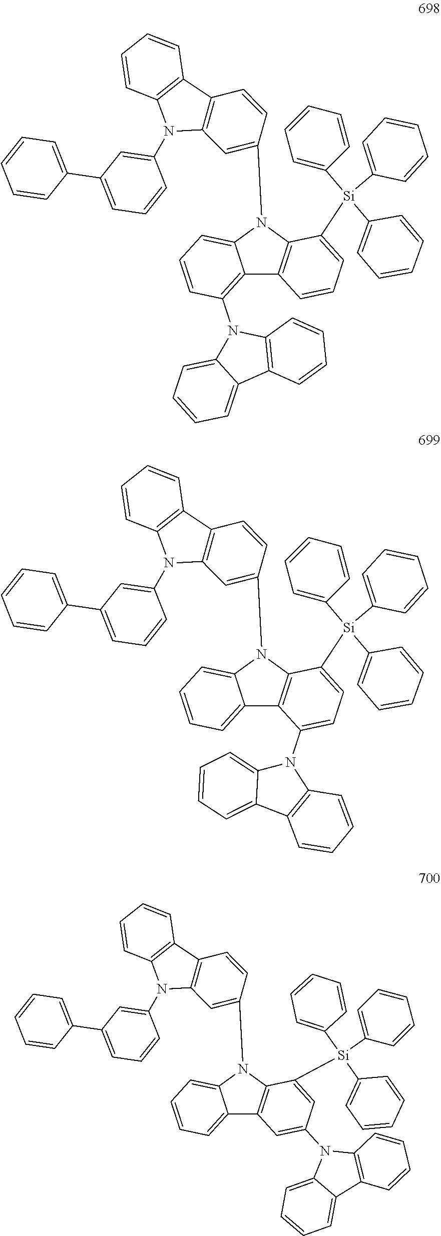 [SMILES: c1ccc(-c2cccc(-n3c4ccccc4c4ccc(-n5c6cccc(-n7c8ccccc8c8ccccc87)c6c6cccc([Si](c7ccccc7)(c7ccccc7)c7ccccc7)c65)cc43)c2)cc1 ; c1ccc(-c2cccc(-n3c4ccccc4c4ccc(-n5c6ccccc6c6c(-n7c8ccccc8c8ccccc87)ccc([Si](c7ccccc7)(c7ccccc7)c7ccccc7)c65)cc43)c2)cc1 ; c1ccc(-c2cccc(-n3c4ccccc4c4ccc(-n5c6ccccc6c6cc(-n7c8ccccc8c8ccccc87)cc([Si](c7ccccc7)(c7ccccc7)c7ccccc7)c65)cc43)c2)cc1]

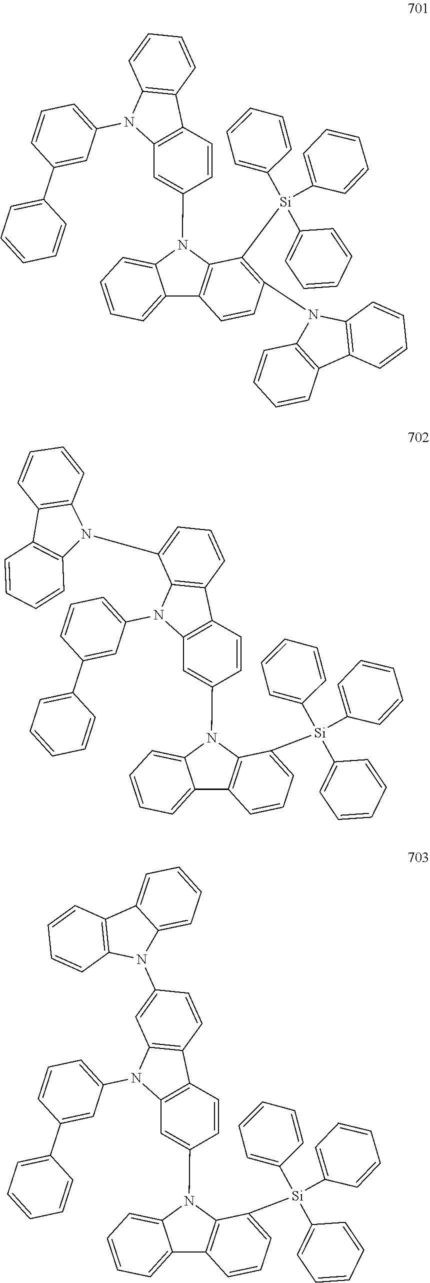 [SMILES: c1ccc(-c2cccc(-n3c4ccccc4c4ccc(-n5c6ccccc6c6ccc(-n7c8ccccc8c8ccccc87)c([Si](c7ccccc7)(c7ccccc7)c7ccccc7)c65)cc43)c2)cc1 ; c1ccc(-c2cccc(-n3c4cc(-n5c6ccccc6c6cccc([Si](c7ccccc7)(c7ccccc7)c7ccccc7)c65)ccc4c4cccc(-n5c6ccccc6c6ccccc65)c43)c2)cc1 ; c1ccc(-c2cccc(-n3c4cc(-n5c6ccccc6c6ccccc65)ccc4c4ccc(-n5c6ccccc6c6cccc([Si](c7ccccc7)(c7ccccc7)c7ccccc7)c65)cc43)c2)cc1]

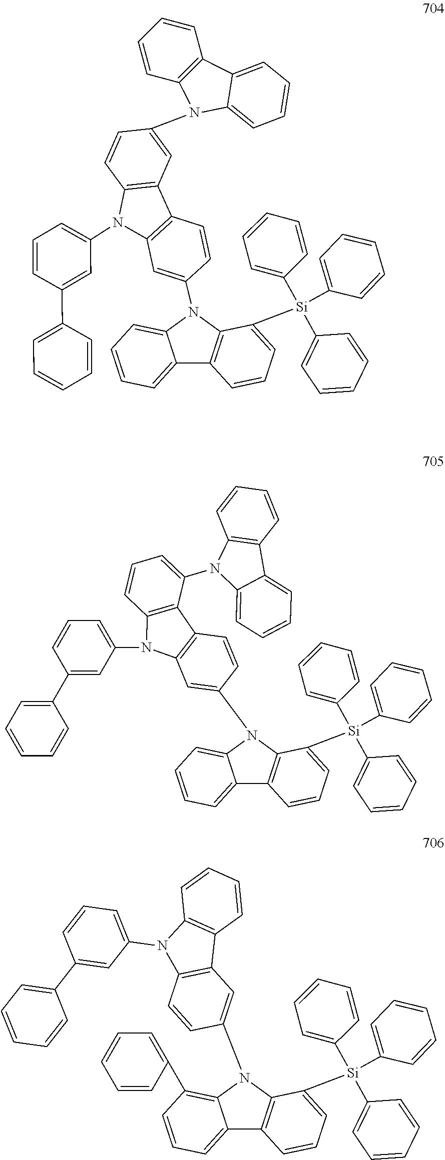 [SMILES: c1ccc(-c2cccc(-n3c4ccc(-n5c6ccccc6c6ccccc65)cc4c4ccc(-n5c6ccccc6c6cccc([Si](c7ccccc7)(c7ccccc7)c7ccccc7)c65)cc43)c2)cc1 ; c1ccc(-c2cccc(-n3c4cc(-n5c6ccccc6c6cccc([Si](c7ccccc7)(c7ccccc7)c7ccccc7)c65)ccc4c4c(-n5c6ccccc6c6ccccc65)cccc43)c2)cc1 ; c1ccc(-c2cccc(-n3c4ccccc4c4cc(-n5c6c(-c7ccccc7)cccc6c6cccc([Si](c7ccccc7)(c7ccccc7)c7ccccc7)c65)ccc43)c2)cc1]

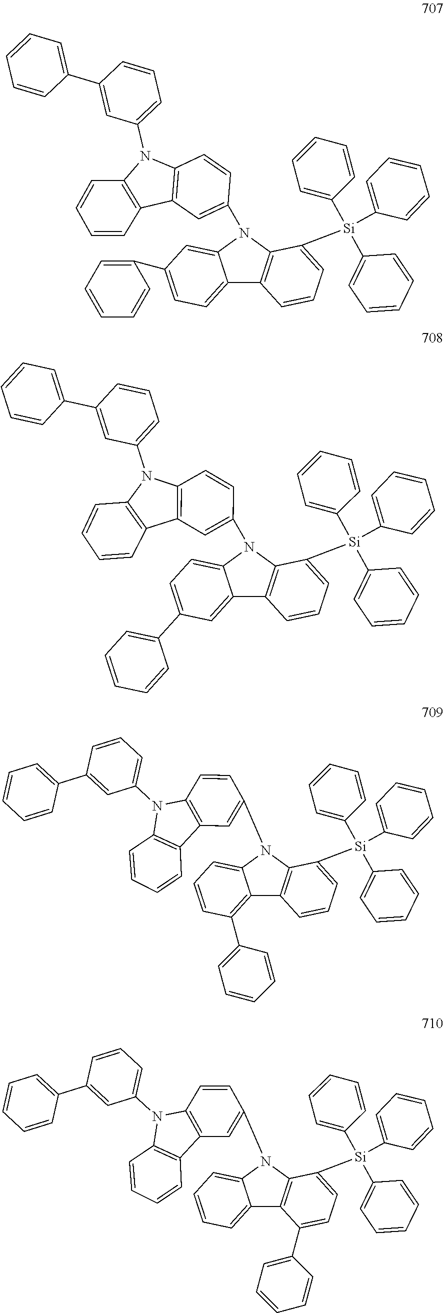 [SMILES: c1ccc(-c2cccc(-n3c4ccccc4c4cc(-n5c6cc(-c7ccccc7)ccc6c6cccc([Si](c7ccccc7)(c7ccccc7)c7ccccc7)c65)ccc43)c2)cc1 ; c1ccc(-c2cccc(-n3c4ccccc4c4cc(-n5c6ccc(-c7ccccc7)cc6c6cccc([Si](c7ccccc7)(c7ccccc7)c7ccccc7)c65)ccc43)c2)cc1 ; c1ccc(-c2cccc(-n3c4ccccc4c4cc(-n5c6cccc(-c7ccccc7)c6c6cccc([Si](c7ccccc7)(c7ccccc7)c7ccccc7)c65)ccc43)c2)cc1 ; c1ccc(-c2cccc(-n3c4ccccc4c4cc(-n5c6ccccc6c6c(-c7ccccc7)ccc([Si](c7ccccc7)(c7ccccc7)c7ccccc7)c65)ccc43)c2)cc1]

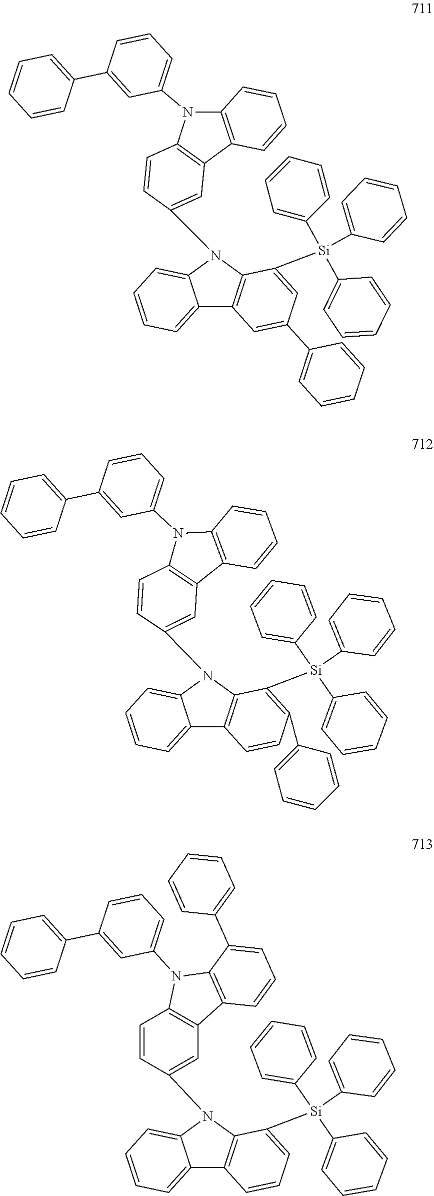 [SMILES: c1ccc(-c2cccc(-n3c4ccccc4c4cc(-n5c6ccccc6c6cc(-c7ccccc7)cc([Si](c7ccccc7)(c7ccccc7)c7ccccc7)c65)ccc43)c2)cc1 ; c1ccc(-c2cccc(-n3c4ccccc4c4cc(-n5c6ccccc6c6ccc(-c7ccccc7)c([Si](c7ccccc7)(c7ccccc7)c7ccccc7)c65)ccc43)c2)cc1 ; c1ccc(-c2cccc(-n3c4ccc(-n5c6ccccc6c6cccc([Si](c7ccccc7)(c7ccccc7)c7ccccc7)c65)cc4c4cccc(-c5ccccc5)c43)c2)cc1]

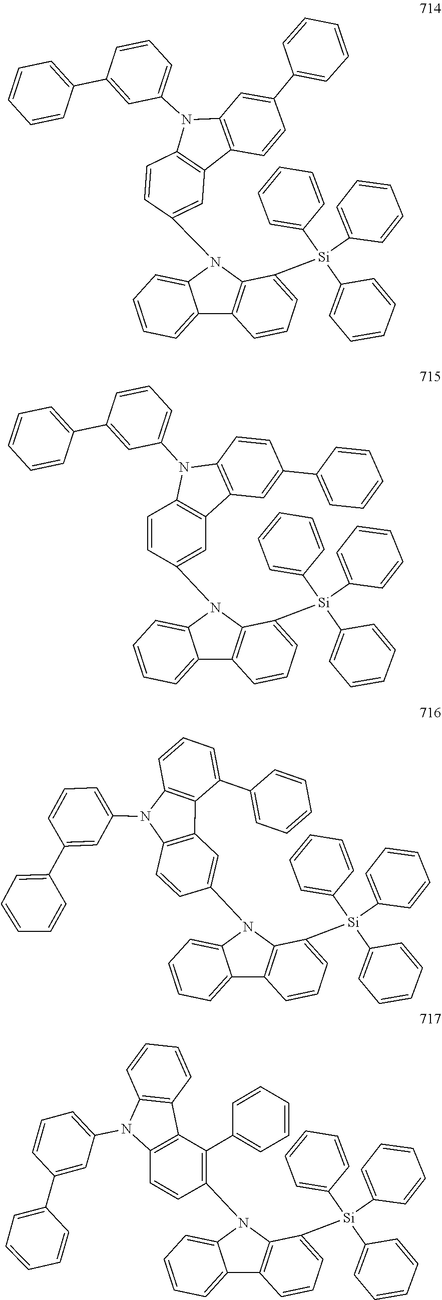 [SMILES: c1ccc(-c2cccc(-n3c4ccc(-n5c6ccccc6c6cccc([Si](c7ccccc7)(c7ccccc7)c7ccccc7)c65)cc4c4ccc(-c5ccccc5)cc43)c2)cc1 ; c1ccc(-c2cccc(-n3c4ccc(-c5ccccc5)cc4c4cc(-n5c6ccccc6c6cccc([Si](c7ccccc7)(c7ccccc7)c7ccccc7)c65)ccc43)c2)cc1 ; c1ccc(-c2cccc(-n3c4ccc(-n5c6ccccc6c6cccc([Si](c7ccccc7)(c7ccccc7)c7ccccc7)c65)cc4c4c(-c5ccccc5)cccc43)c2)cc1 ; c1ccc(-c2cccc(-n3c4ccccc4c4c(-c5ccccc5)c(-n5c6ccccc6c6cccc([Si](c7ccccc7)(c7ccccc7)c7ccccc7)c65)ccc43)c2)cc1]

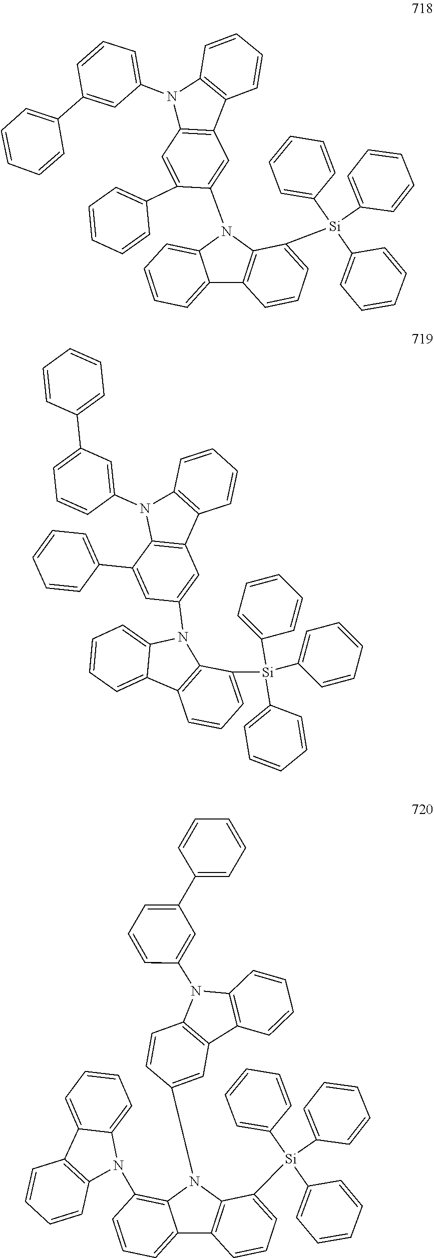 [SMILES: c1ccc(-c2cccc(-n3c4ccccc4c4cc(-n5c6ccccc6c6cccc([Si](c7ccccc7)(c7ccccc7)c7ccccc7)c65)c(-c5ccccc5)cc43)c2)cc1 ; c1ccc(-c2cccc(-n3c4ccccc4c4cc(-n5c6ccccc6c6cccc([Si](c7ccccc7)(c7ccccc7)c7ccccc7)c65)cc(-c5ccccc5)c43)c2)cc1 ; c1ccc(-c2cccc(-n3c4ccccc4c4cc(-n5c6c(-n7c8ccccc8c8ccccc87)cccc6c6cccc([Si](c7ccccc7)(c7ccccc7)c7ccccc7)c65)ccc43)c2)cc1]

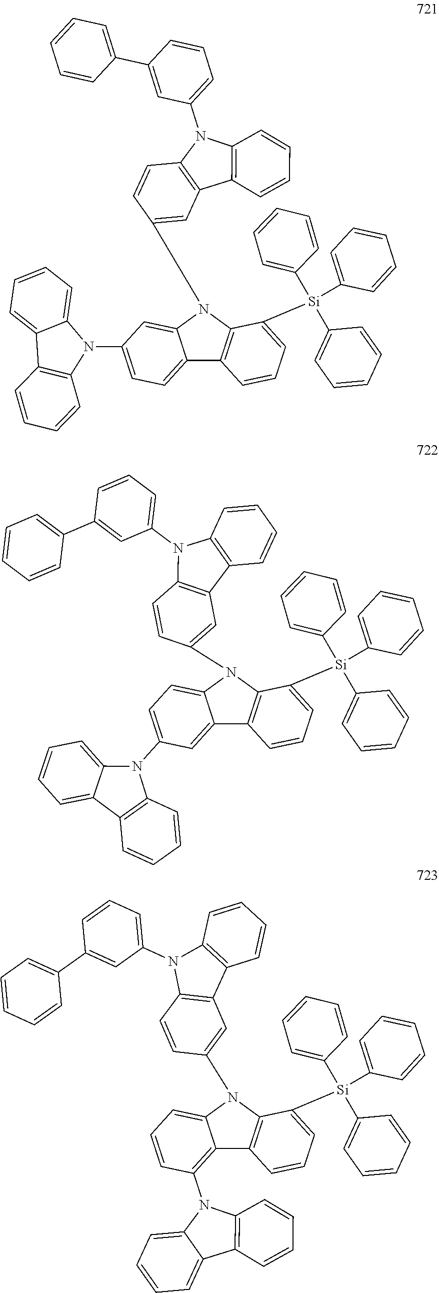 [SMILES: c1ccc(-c2cccc(-n3c4ccccc4c4cc(-n5c6cc(-n7c8ccccc8c8ccccc87)ccc6c6cccc([Si](c7ccccc7)(c7ccccc7)c7ccccc7)c65)ccc43)c2)cc1 ; c1ccc(-c2cccc(-n3c4ccccc4c4cc(-n5c6ccc(-n7c8ccccc8c8ccccc87)cc6c6cccc([Si](c7ccccc7)(c7ccccc7)c7ccccc7)c65)ccc43)c2)cc1 ; c1ccc(-c2cccc(-n3c4ccccc4c4cc(-n5c6cccc(-n7c8ccccc8c8ccccc87)c6c6cccc([Si](c7ccccc7)(c7ccccc7)c7ccccc7)c65)ccc43)c2)cc1]

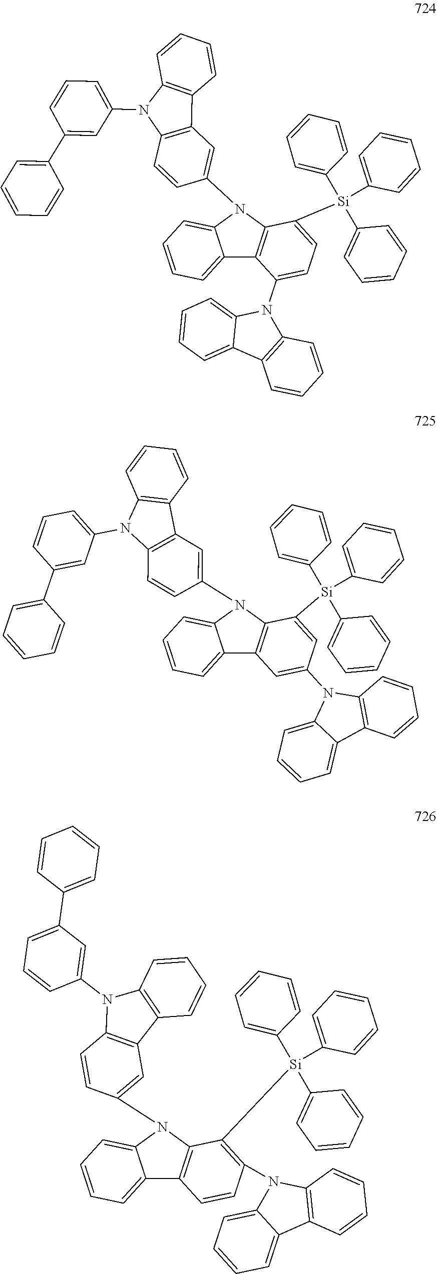 [SMILES: c1ccc(-c2cccc(-n3c4ccccc4c4cc(-n5c6ccccc6c6c(-n7c8ccccc8c8ccccc87)ccc([Si](c7ccccc7)(c7ccccc7)c7ccccc7)c65)ccc43)c2)cc1 ; c1ccc(-c2cccc(-n3c4ccccc4c4cc(-n5c6ccccc6c6cc(-n7c8ccccc8c8ccccc87)cc([Si](c7ccccc7)(c7ccccc7)c7ccccc7)c65)ccc43)c2)cc1 ; c1ccc(-c2cccc(-n3c4ccccc4c4cc(-n5c6ccccc6c6ccc(-n7c8ccccc8c8ccccc87)c([Si](c7ccccc7)(c7ccccc7)c7ccccc7)c65)ccc43)c2)cc1]

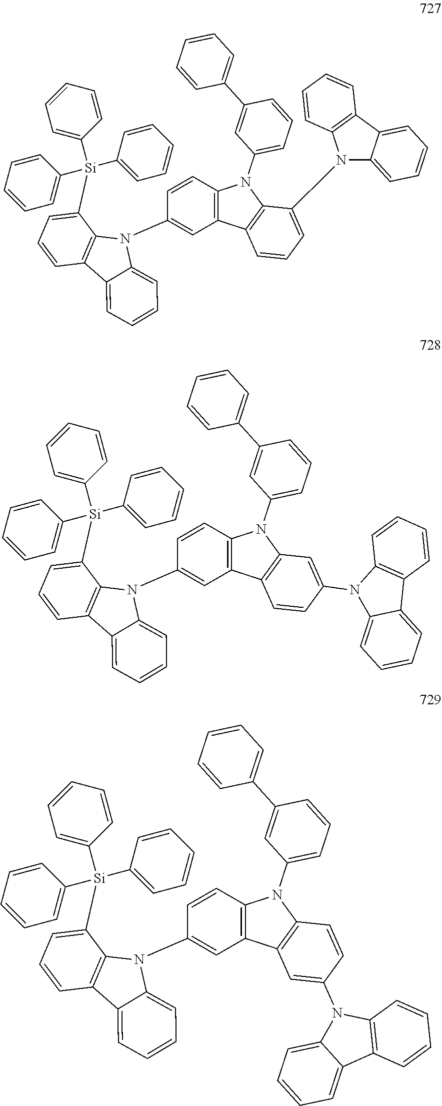 [SMILES: c1ccc(-c2cccc(-n3c4ccc(-n5c6ccccc6c6cccc([Si](c7ccccc7)(c7ccccc7)c7ccccc7)c65)cc4c4cccc(-n5c6ccccc6c6ccccc65)c43)c2)cc1 ; c1ccc(-c2cccc(-n3c4ccc(-n5c6ccccc6c6cccc([Si](c7ccccc7)(c7ccccc7)c7ccccc7)c65)cc4c4ccc(-n5c6ccccc6c6ccccc65)cc43)c2)cc1 ; c1ccc(-c2cccc(-n3c4ccc(-n5c6ccccc6c6ccccc65)cc4c4cc(-n5c6ccccc6c6cccc([Si](c7ccccc7)(c7ccccc7)c7ccccc7)c65)ccc43)c2)cc1]

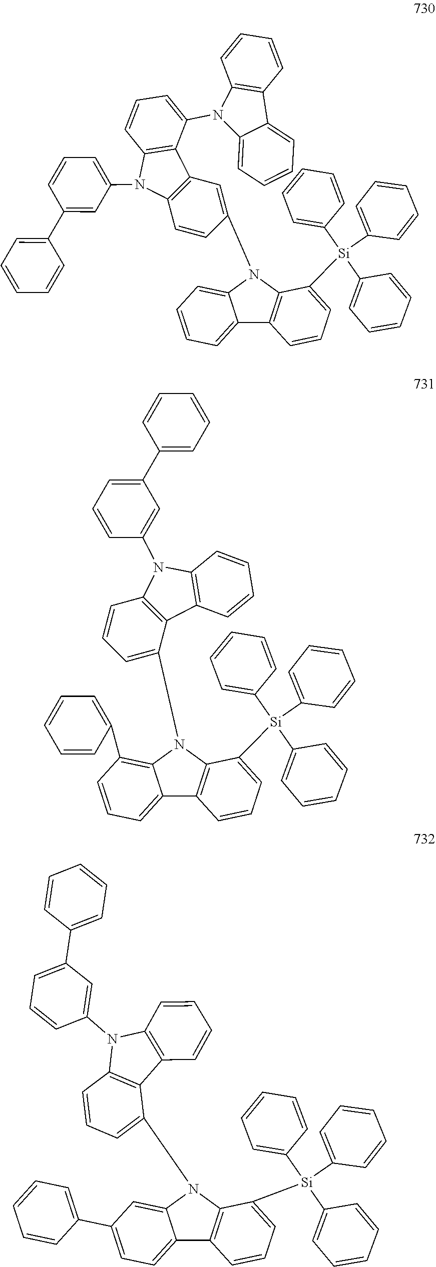 [SMILES: c1ccc(-c2cccc(-n3c4ccc(-n5c6ccccc6c6cccc([Si](c7ccccc7)(c7ccccc7)c7ccccc7)c65)cc4c4c(-n5c6ccccc6c6ccccc65)cccc43)c2)cc1 ; c1ccc(-c2cccc(-n3c4ccccc4c4c(-n5c6c(-c7ccccc7)cccc6c6cccc([Si](c7ccccc7)(c7ccccc7)c7ccccc7)c65)cccc43)c2)cc1 ; c1ccc(-c2cccc(-n3c4ccccc4c4c(-n5c6cc(-c7ccccc7)ccc6c6cccc([Si](c7ccccc7)(c7ccccc7)c7ccccc7)c65)cccc43)c2)cc1]

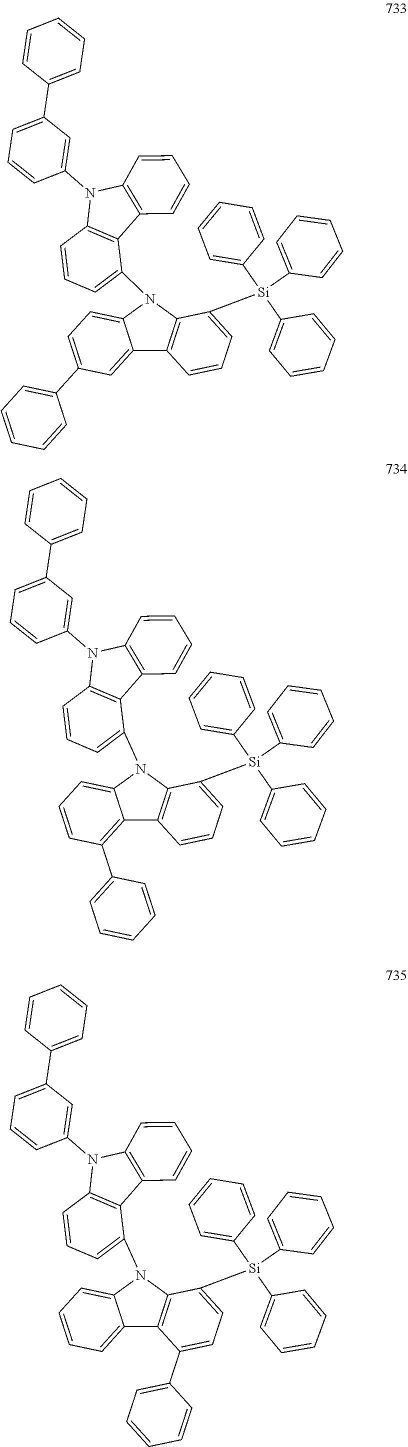

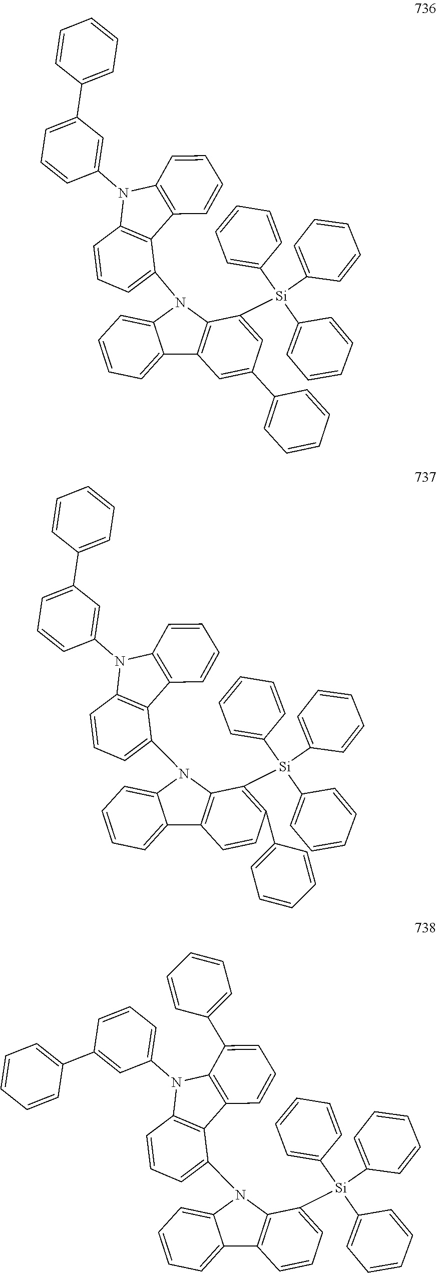 [SMILES: c1ccc(-c2cccc(-n3c4ccccc4c4c(-n5c6ccccc6c6cc(-c7ccccc7)cc([Si](c7ccccc7)(c7ccccc7)c7ccccc7)c65)cccc43)c2)cc1 ; c1ccc(-c2cccc(-n3c4ccccc4c4c(-n5c6ccccc6c6ccc(-c7ccccc7)c([Si](c7ccccc7)(c7ccccc7)c7ccccc7)c65)cccc43)c2)cc1 ; c1ccc(-c2cccc(-n3c4cccc(-n5c6ccccc6c6cccc([Si](c7ccccc7)(c7ccccc7)c7ccccc7)c65)c4c4cccc(-c5ccccc5)c43)c2)cc1]

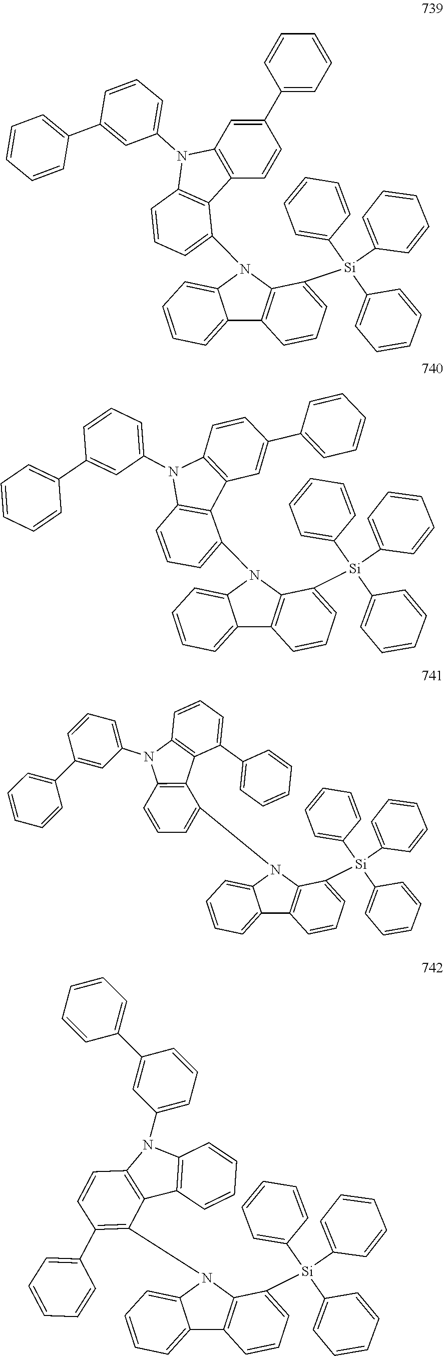 [SMILES: c1ccc(-c2cccc(-n3c4cc(-c5ccccc5)ccc4c4c(-n5c6ccccc6c6cccc([Si](c7ccccc7)(c7ccccc7)c7ccccc7)c65)cccc43)c2)cc1 ; c1ccc(-c2cccc(-n3c4ccc(-c5ccccc5)cc4c4c(-n5c6ccccc6c6cccc([Si](c7ccccc7)(c7ccccc7)c7ccccc7)c65)cccc43)c2)cc1 ; c1ccc(-c2cccc(-n3c4cccc(-c5ccccc5)c4c4c(-n5c6ccccc6c6cccc([Si](c7ccccc7)(c7ccccc7)c7ccccc7)c65)cccc43)c2)cc1 ; c1ccc(-c2cccc(-n3c4ccccc4c4c(-n5c6ccccc6c6cccc([Si](c7ccccc7)(c7ccccc7)c7ccccc7)c65)c(-c5ccccc5)ccc43)c2)cc1]

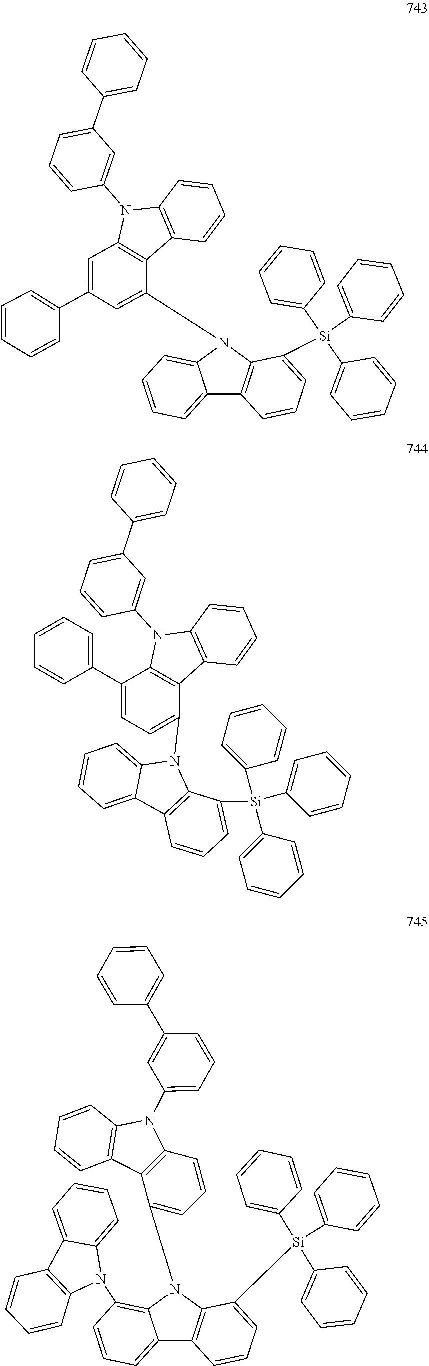

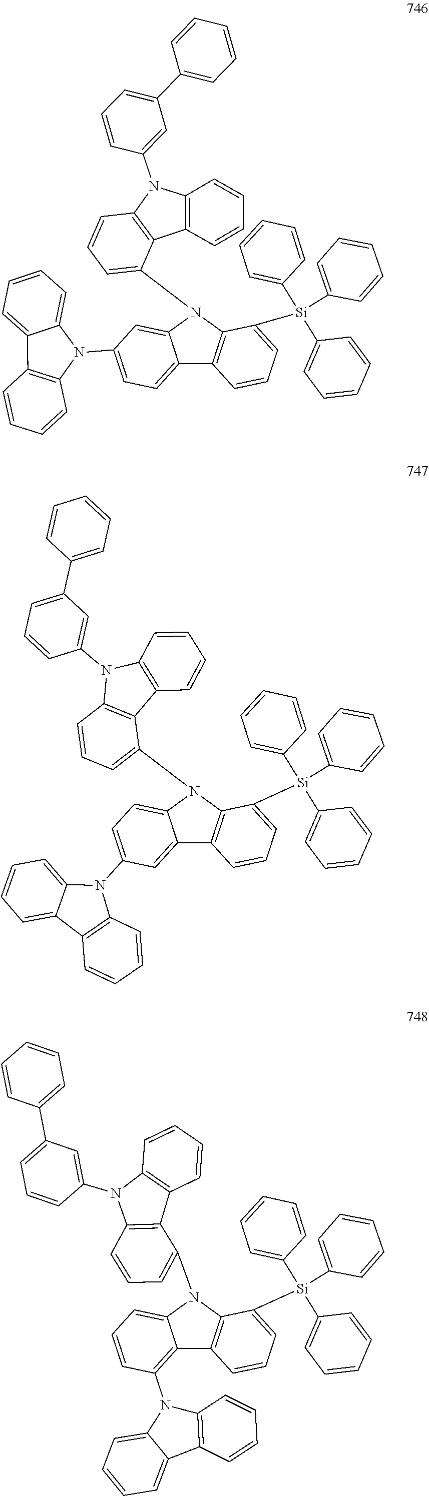 [SMILES: c1ccc(-c2cccc(-n3c4ccccc4c4c(-n5c6cc(-n7c8ccccc8c8ccccc87)ccc6c6cccc([Si](c7ccccc7)(c7ccccc7)c7ccccc7)c65)cccc43)c2)cc1 ; c1ccc(-c2cccc(-n3c4ccccc4c4c(-n5c6ccc(-n7c8ccccc8c8ccccc87)cc6c6cccc([Si](c7ccccc7)(c7ccccc7)c7ccccc7)c65)cccc43)c2)cc1 ; c1ccc(-c2cccc(-n3c4ccccc4c4c(-n5c6cccc(-n7c8ccccc8c8ccccc87)c6c6cccc([Si](c7ccccc7)(c7ccccc7)c7ccccc7)c65)cccc43)c2)cc1]

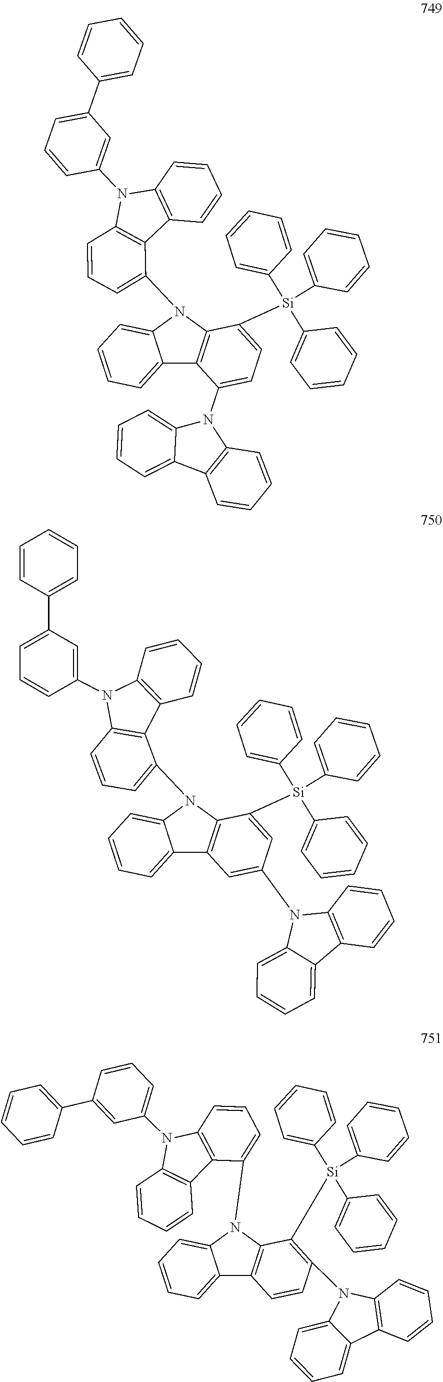 [SMILES: c1ccc(-c2cccc(-n3c4ccccc4c4c(-n5c6ccccc6c6c(-n7c8ccccc8c8ccccc87)ccc([Si](c7ccccc7)(c7ccccc7)c7ccccc7)c65)cccc43)c2)cc1 ; c1ccc(-c2cccc(-n3c4ccccc4c4c(-n5c6ccccc6c6cc(-n7c8ccccc8c8ccccc87)cc([Si](c7ccccc7)(c7ccccc7)c7ccccc7)c65)cccc43)c2)cc1 ; c1ccc(-c2cccc(-n3c4ccccc4c4c(-n5c6ccccc6c6ccc(-n7c8ccccc8c8ccccc87)c([Si](c7ccccc7)(c7ccccc7)c7ccccc7)c65)cccc43)c2)cc1]

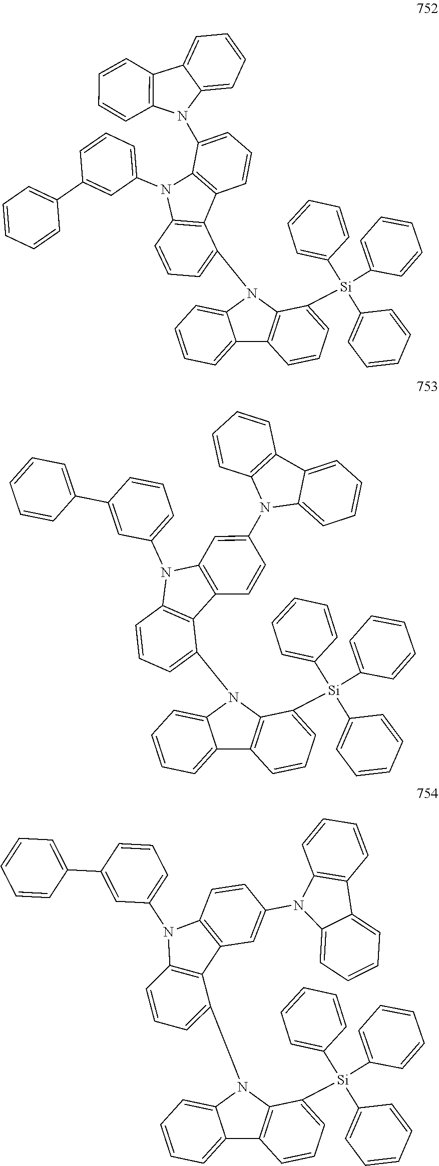 [SMILES: c1ccc(-c2cccc(-n3c4cccc(-n5c6ccccc6c6cccc([Si](c7ccccc7)(c7ccccc7)c7ccccc7)c65)c4c4cccc(-n5c6ccccc6c6ccccc65)c43)c2)cc1 ; c1ccc(-c2cccc(-n3c4cc(-n5c6ccccc6c6ccccc65)ccc4c4c(-n5c6ccccc6c6cccc([Si](c7ccccc7)(c7ccccc7)c7ccccc7)c65)cccc43)c2)cc1 ; c1ccc(-c2cccc(-n3c4ccc(-n5c6ccccc6c6ccccc65)cc4c4c(-n5c6ccccc6c6cccc([Si](c7ccccc7)(c7ccccc7)c7ccccc7)c65)cccc43)c2)cc1]

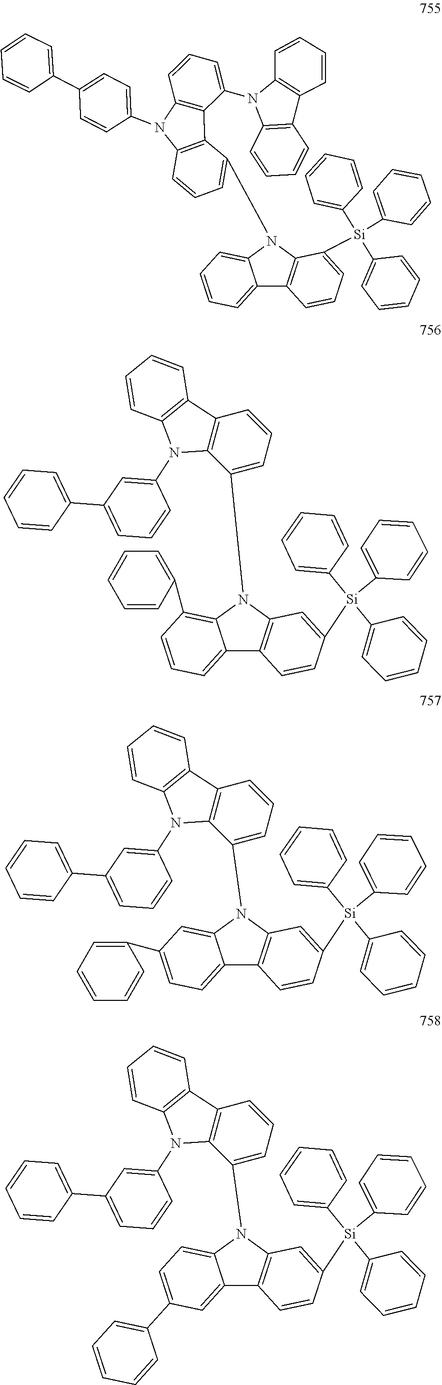 [SMILES: c1ccc(-c2ccc(-n3c4cccc(-n5c6ccccc6c6ccccc65)c4c4c(-n5c6ccccc6c6cccc([Si](c7ccccc7)(c7ccccc7)c7ccccc7)c65)cccc43)cc2)cc1 ; c1ccc(-c2cccc(-n3c4ccccc4c4cccc(-n5c6cc([Si](c7ccccc7)(c7ccccc7)c7ccccc7)ccc6c6cccc(-c7ccccc7)c65)c43)c2)cc1 ; c1ccc(-c2cccc(-n3c4ccccc4c4cccc(-n5c6cc(-c7ccccc7)ccc6c6ccc([Si](c7ccccc7)(c7ccccc7)c7ccccc7)cc65)c43)c2)cc1 ; c1ccc(-c2cccc(-n3c4ccccc4c4cccc(-n5c6ccc(-c7ccccc7)cc6c6ccc([Si](c7ccccc7)(c7ccccc7)c7ccccc7)cc65)c43)c2)cc1]

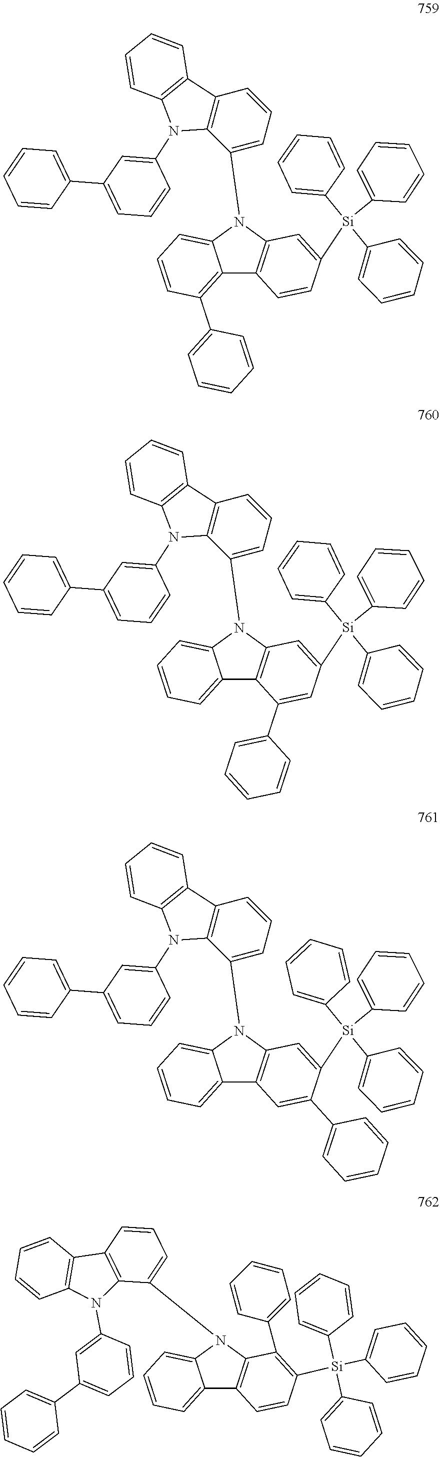 [SMILES: c1ccc(-c2cccc(-n3c4ccccc4c4cccc(-n5c6cc([Si](c7ccccc7)(c7ccccc7)c7ccccc7)ccc6c6c(-c7ccccc7)cccc65)c43)c2)cc1 ; c1ccc(-c2cccc(-n3c4ccccc4c4cccc(-n5c6ccccc6c6c(-c7ccccc7)cc([Si](c7ccccc7)(c7ccccc7)c7ccccc7)cc65)c43)c2)cc1 ; c1ccc(-c2cccc(-n3c4ccccc4c4cccc(-n5c6ccccc6c6cc(-c7ccccc7)c([Si](c7ccccc7)(c7ccccc7)c7ccccc7)cc65)c43)c2)cc1 ; c1ccc(-c2cccc(-n3c4ccccc4c4cccc(-n5c6ccccc6c6ccc([Si](c7ccccc7)(c7ccccc7)c7ccccc7)c(-c7ccccc7)c65)c43)c2)cc1]

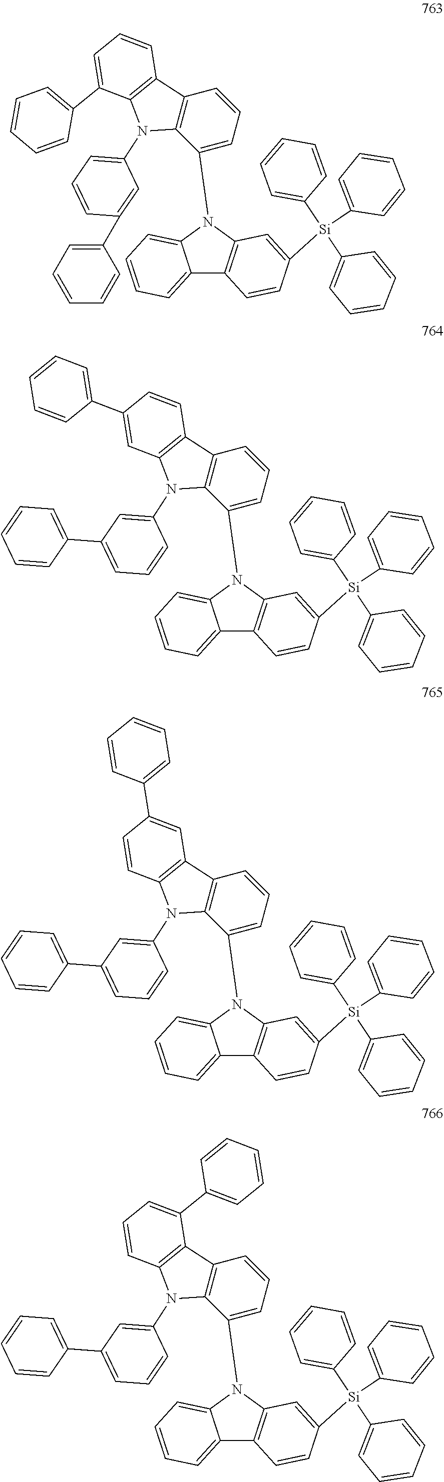 [SMILES: c1ccc(-c2cccc(-n3c4c(-c5ccccc5)cccc4c4cccc(-n5c6ccccc6c6ccc([Si](c7ccccc7)(c7ccccc7)c7ccccc7)cc65)c43)c2)cc1 ; c1ccc(-c2cccc(-n3c4cc(-c5ccccc5)ccc4c4cccc(-n5c6ccccc6c6ccc([Si](c7ccccc7)(c7ccccc7)c7ccccc7)cc65)c43)c2)cc1 ; c1ccc(-c2cccc(-n3c4ccc(-c5ccccc5)cc4c4cccc(-n5c6ccccc6c6ccc([Si](c7ccccc7)(c7ccccc7)c7ccccc7)cc65)c43)c2)cc1 ; c1ccc(-c2cccc(-n3c4cccc(-c5ccccc5)c4c4cccc(-n5c6ccccc6c6ccc([Si](c7ccccc7)(c7ccccc7)c7ccccc7)cc65)c43)c2)cc1]

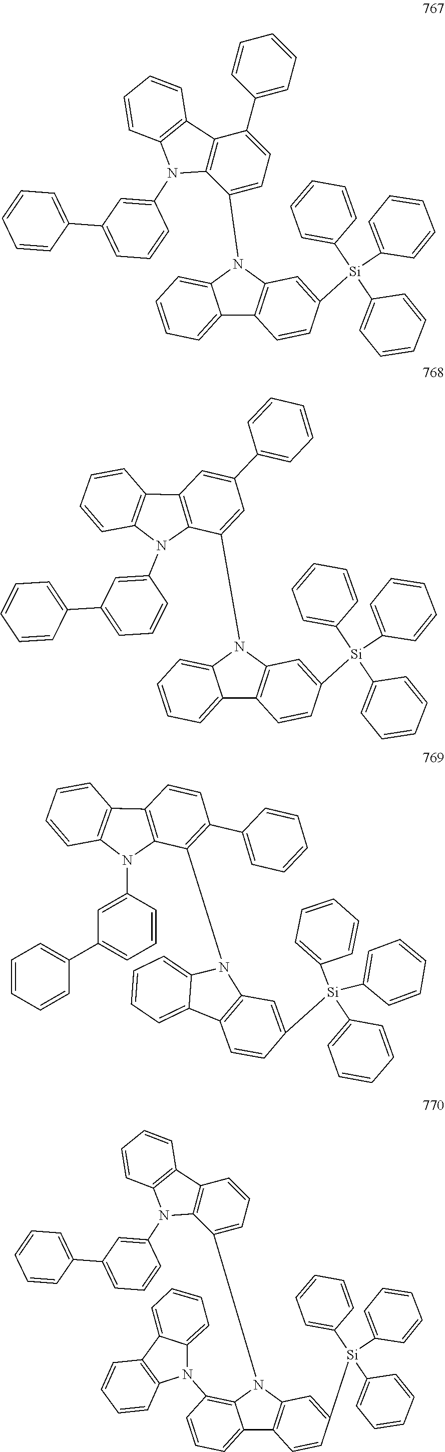 [SMILES: c1ccc(-c2cccc(-n3c4ccccc4c4c(-c5ccccc5)ccc(-n5c6ccccc6c6ccc([Si](c7ccccc7)(c7ccccc7)c7ccccc7)cc65)c43)c2)cc1 ; c1ccc(-c2cccc(-n3c4ccccc4c4cc(-c5ccccc5)cc(-n5c6ccccc6c6ccc([Si](c7ccccc7)(c7ccccc7)c7ccccc7)cc65)c43)c2)cc1 ; c1ccc(-c2cccc(-n3c4ccccc4c4ccc(-c5ccccc5)c(-n5c6ccccc6c6ccc([Si](c7ccccc7)(c7ccccc7)c7ccccc7)cc65)c43)c2)cc1 ; c1ccc(-c2cccc(-n3c4ccccc4c4cccc(-n5c6cc([Si](c7ccccc7)(c7ccccc7)c7ccccc7)ccc6c6cccc(-n7c8ccccc8c8ccccc87)c65)c43)c2)cc1]

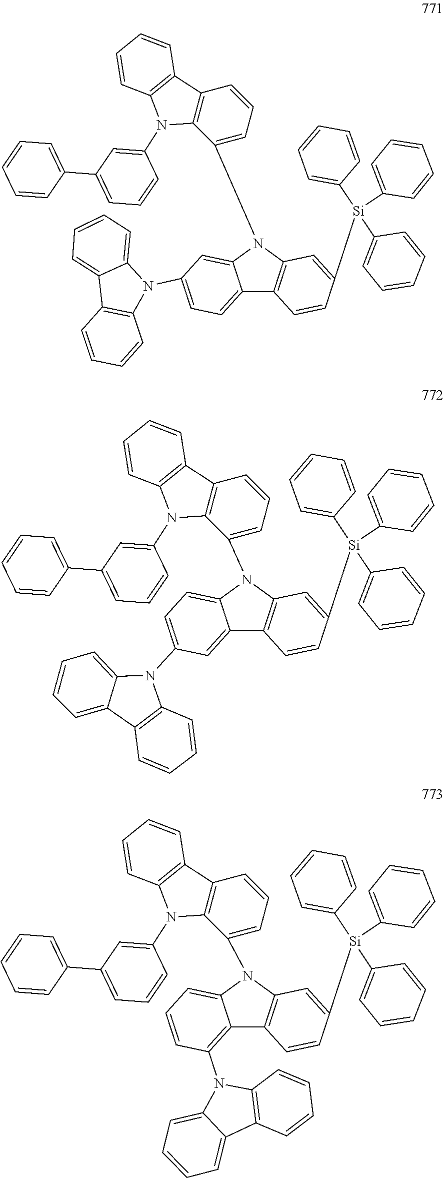 [SMILES: c1ccc(-c2cccc(-n3c4ccccc4c4cccc(-n5c6cc(-n7c8ccccc8c8ccccc87)ccc6c6ccc([Si](c7ccccc7)(c7ccccc7)c7ccccc7)cc65)c43)c2)cc1 ; c1ccc(-c2cccc(-n3c4ccccc4c4cccc(-n5c6ccc(-n7c8ccccc8c8ccccc87)cc6c6ccc([Si](c7ccccc7)(c7ccccc7)c7ccccc7)cc65)c43)c2)cc1 ; c1ccc(-c2cccc(-n3c4ccccc4c4cccc(-n5c6cc([Si](c7ccccc7)(c7ccccc7)c7ccccc7)ccc6c6c(-n7c8ccccc8c8ccccc87)cccc65)c43)c2)cc1]

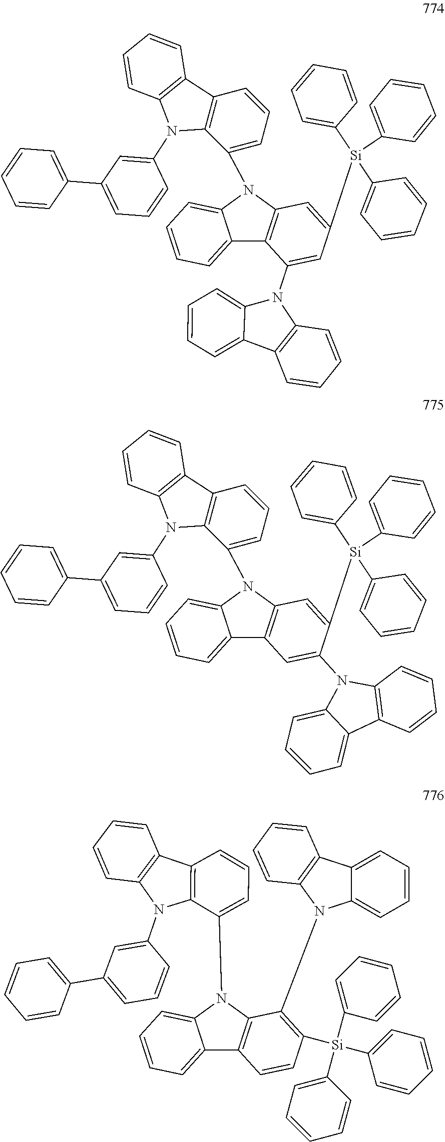 [SMILES: c1ccc(-c2cccc(-n3c4ccccc4c4cccc(-n5c6ccccc6c6c(-n7c8ccccc8c8ccccc87)cc([Si](c7ccccc7)(c7ccccc7)c7ccccc7)cc65)c43)c2)cc1 ; c1ccc(-c2cccc(-n3c4ccccc4c4cccc(-n5c6ccccc6c6cc(-n7c8ccccc8c8ccccc87)c([Si](c7ccccc7)(c7ccccc7)c7ccccc7)cc65)c43)c2)cc1 ; c1ccc(-c2cccc(-n3c4ccccc4c4cccc(-n5c6ccccc6c6ccc([Si](c7ccccc7)(c7ccccc7)c7ccccc7)c(-n7c8ccccc8c8ccccc87)c65)c43)c2)cc1]

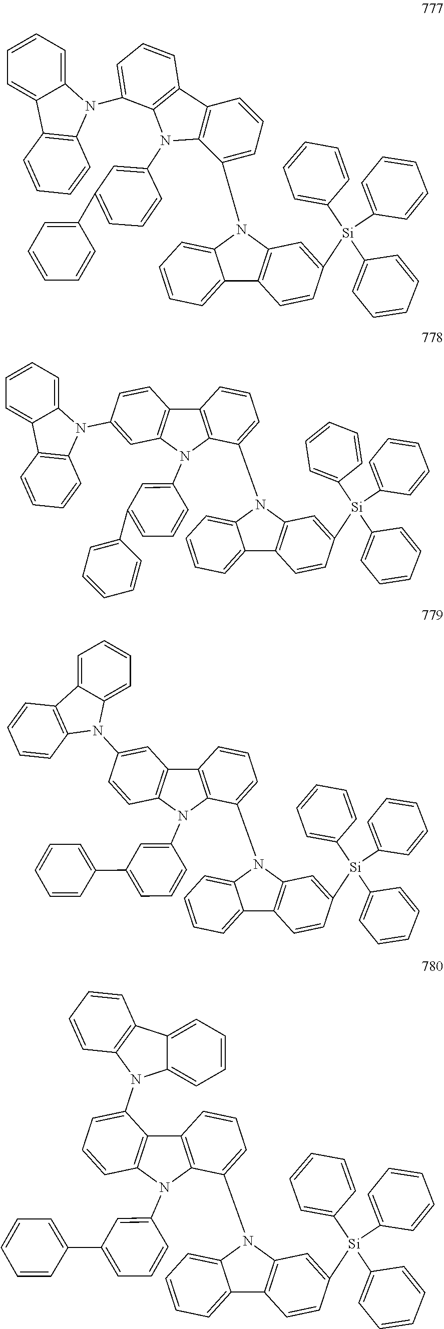

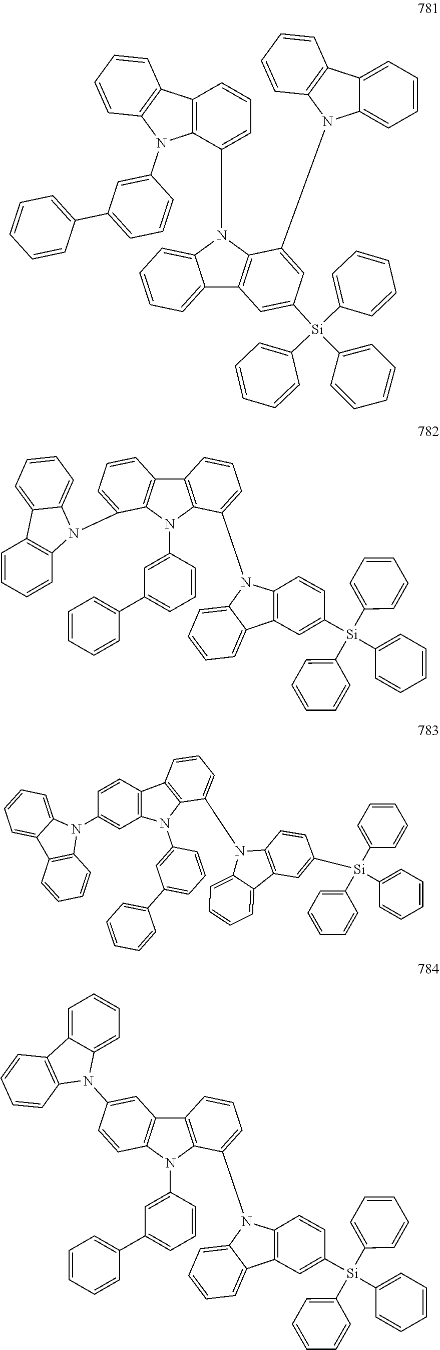 [SMILES: c1ccc(-c2cccc(-n3c4ccccc4c4cccc(-n5c6ccccc6c6cc([Si](c7ccccc7)(c7ccccc7)c7ccccc7)cc(-n7c8ccccc8c8ccccc87)c65)c43)c2)cc1 ; c1ccc(-c2cccc(-n3c4c(-n5c6ccccc6c6ccccc65)cccc4c4cccc(-n5c6ccccc6c6cc([Si](c7ccccc7)(c7ccccc7)c7ccccc7)ccc65)c43)c2)cc1 ; c1ccc(-c2cccc(-n3c4cc(-n5c6ccccc6c6ccccc65)ccc4c4cccc(-n5c6ccccc6c6cc([Si](c7ccccc7)(c7ccccc7)c7ccccc7)ccc65)c43)c2)cc1 ; c1ccc(-c2cccc(-n3c4ccc(-n5c6ccccc6c6ccccc65)cc4c4cccc(-n5c6ccccc6c6cc([Si](c7ccccc7)(c7ccccc7)c7ccccc7)ccc65)c43)c2)cc1]

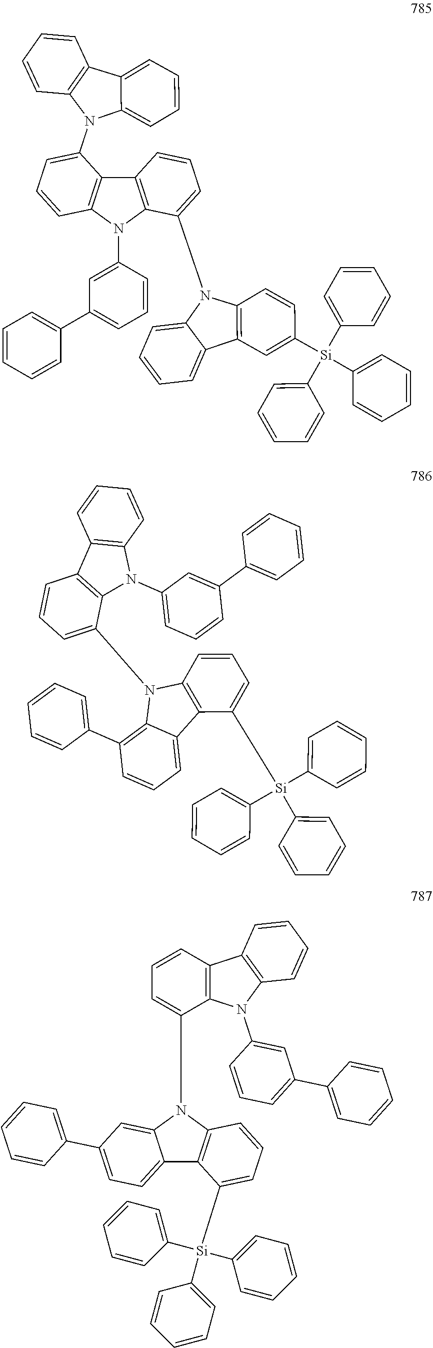 [SMILES: c1ccc(-c2cccc(-n3c4cccc(-n5c6ccccc6c6ccccc65)c4c4cccc(-n5c6ccccc6c6cc([Si](c7ccccc7)(c7ccccc7)c7ccccc7)ccc65)c43)c2)cc1 ; c1ccc(-c2cccc(-n3c4ccccc4c4cccc(-n5c6cccc([Si](c7ccccc7)(c7ccccc7)c7ccccc7)c6c6cccc(-c7ccccc7)c65)c43)c2)cc1 ; c1ccc(-c2cccc(-n3c4ccccc4c4cccc(-n5c6cc(-c7ccccc7)ccc6c6c([Si](c7ccccc7)(c7ccccc7)c7ccccc7)cccc65)c43)c2)cc1]

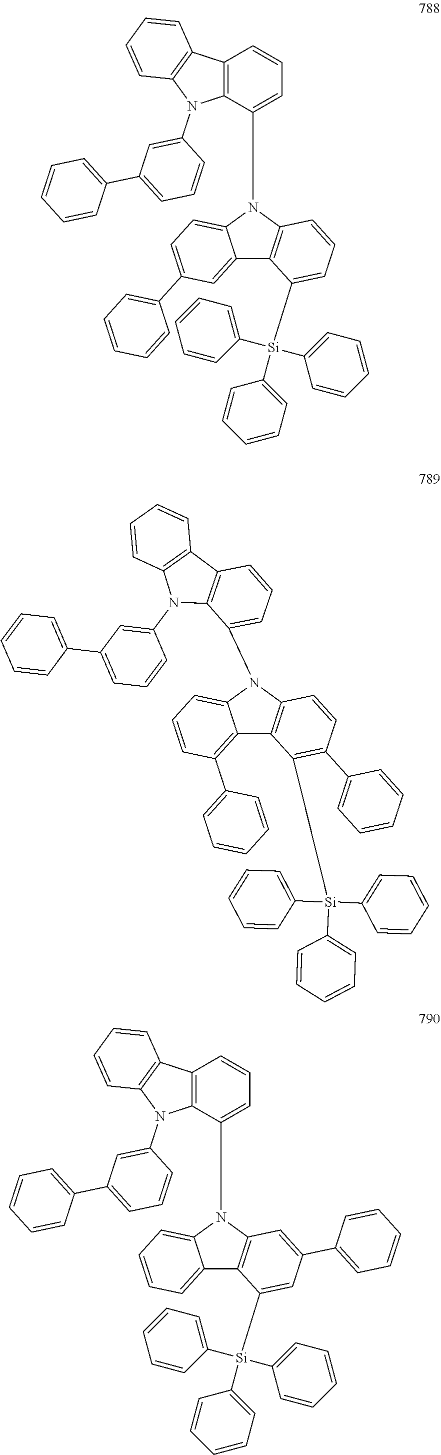 [SMILES: c1ccc(-c2cccc(-n3c4ccccc4c4cccc(-n5c6ccc(-c7ccccc7)cc6c6c([Si](c7ccccc7)(c7ccccc7)c7ccccc7)cccc65)c43)c2)cc1 ; c1ccc(-c2cccc(-n3c4ccccc4c4cccc(-n5c6cccc(-c7ccccc7)c6c6c([Si](c7ccccc7)(c7ccccc7)c7ccccc7)c(-c7ccccc7)ccc65)c43)c2)cc1 ; c1ccc(-c2cccc(-n3c4ccccc4c4cccc(-n5c6ccccc6c6c([Si](c7ccccc7)(c7ccccc7)c7ccccc7)cc(-c7ccccc7)cc65)c43)c2)cc1]

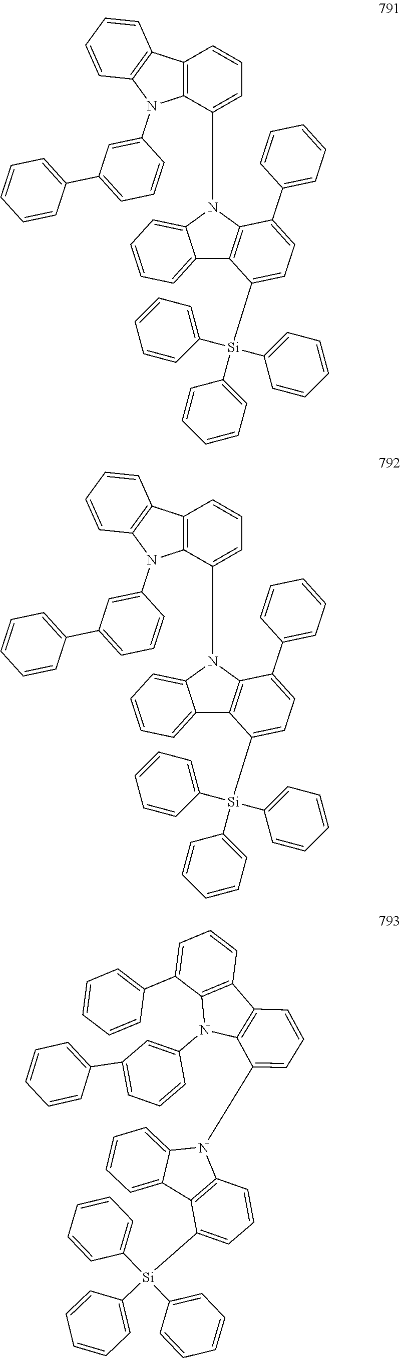

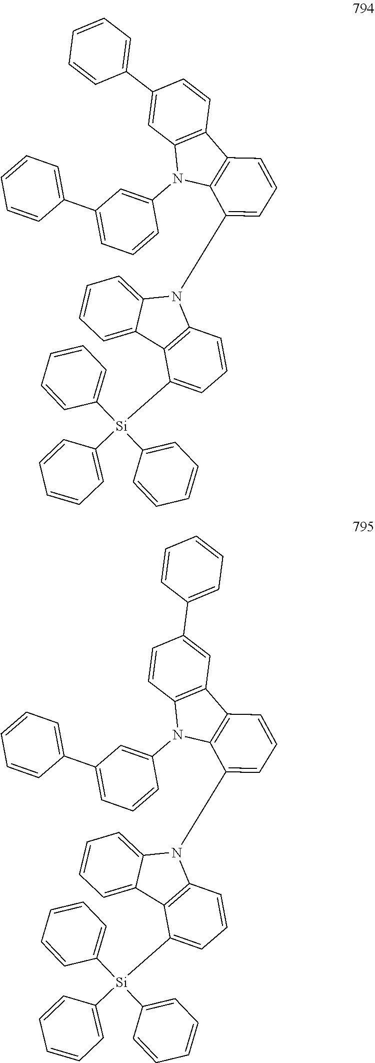

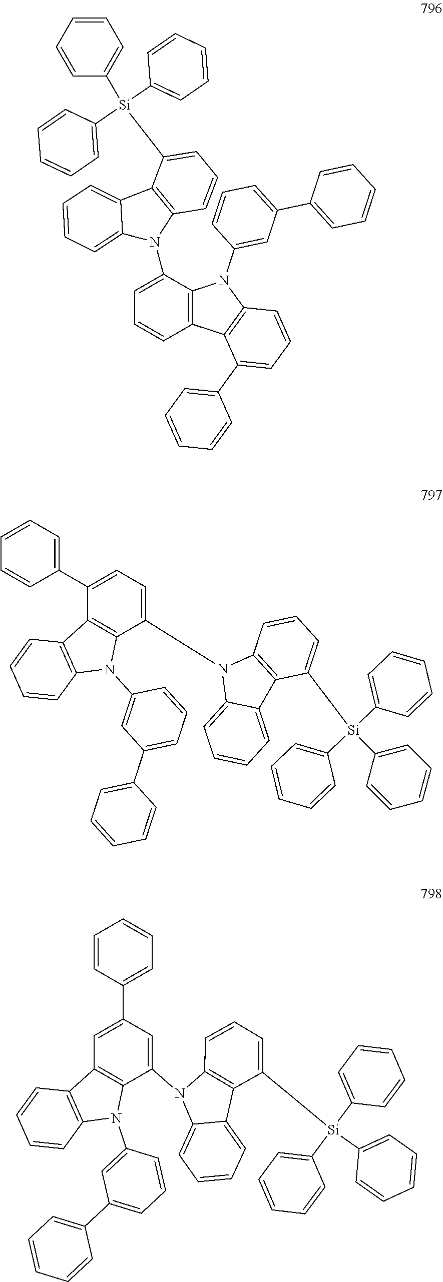 [SMILES: c1ccc(-c2cccc(-n3c4cccc(-c5ccccc5)c4c4cccc(-n5c6ccccc6c6c([Si](c7ccccc7)(c7ccccc7)c7ccccc7)cccc65)c43)c2)cc1 ; c1ccc(-c2cccc(-n3c4ccccc4c4c(-c5ccccc5)ccc(-n5c6ccccc6c6c([Si](c7ccccc7)(c7ccccc7)c7ccccc7)cccc65)c43)c2)cc1 ; c1ccc(-c2cccc(-n3c4ccccc4c4cc(-c5ccccc5)cc(-n5c6ccccc6c6c([Si](c7ccccc7)(c7ccccc7)c7ccccc7)cccc65)c43)c2)cc1]

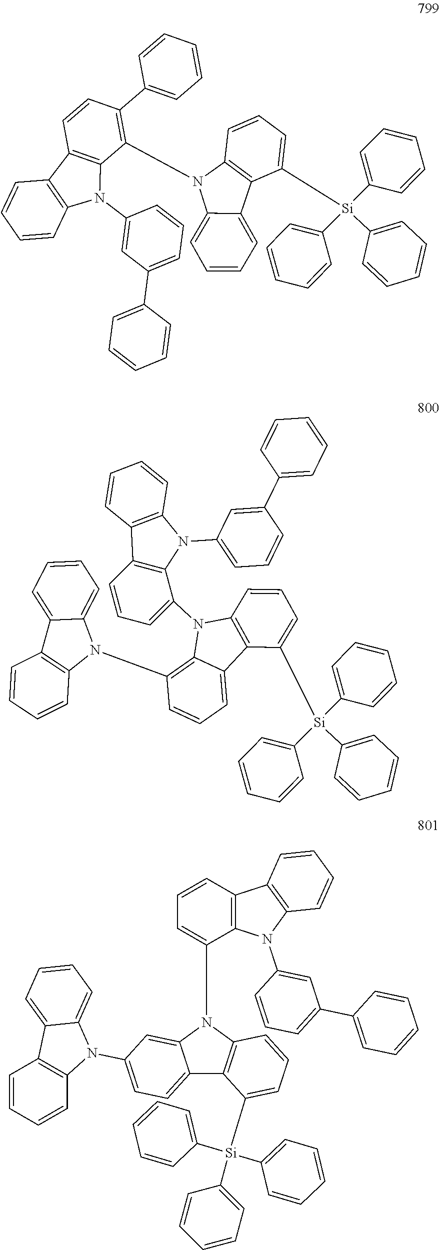 [SMILES: c1ccc(-c2cccc(-n3c4ccccc4c4ccc(-c5ccccc5)c(-n5c6ccccc6c6c([Si](c7ccccc7)(c7ccccc7)c7ccccc7)cccc65)c43)c2)cc1 ; c1ccc(-c2cccc(-n3c4ccccc4c4cccc(-n5c6cccc([Si](c7ccccc7)(c7ccccc7)c7ccccc7)c6c6cccc(-n7c8ccccc8c8ccccc87)c65)c43)c2)cc1 ; c1ccc(-c2cccc(-n3c4ccccc4c4cccc(-n5c6cc(-n7c8ccccc8c8ccccc87)ccc6c6c([Si](c7ccccc7)(c7ccccc7)c7ccccc7)cccc65)c43)c2)cc1]

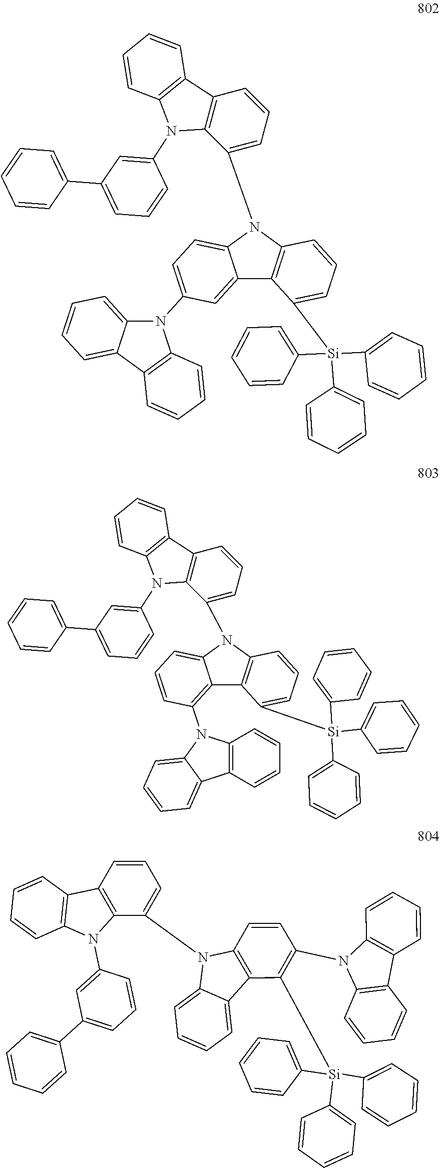 [SMILES: c1ccc(-c2cccc(-n3c4ccccc4c4cccc(-n5c6ccc(-n7c8ccccc8c8ccccc87)cc6c6c([Si](c7ccccc7)(c7ccccc7)c7ccccc7)cccc65)c43)c2)cc1 ; c1ccc(-c2cccc(-n3c4ccccc4c4cccc(-n5c6cccc(-n7c8ccccc8c8ccccc87)c6c6c([Si](c7ccccc7)(c7ccccc7)c7ccccc7)cccc65)c43)c2)cc1 ; c1ccc(-c2cccc(-n3c4ccccc4c4cccc(-n5c6ccccc6c6c([Si](c7ccccc7)(c7ccccc7)c7ccccc7)c(-n7c8ccccc8c8ccccc87)ccc65)c43)c2)cc1]

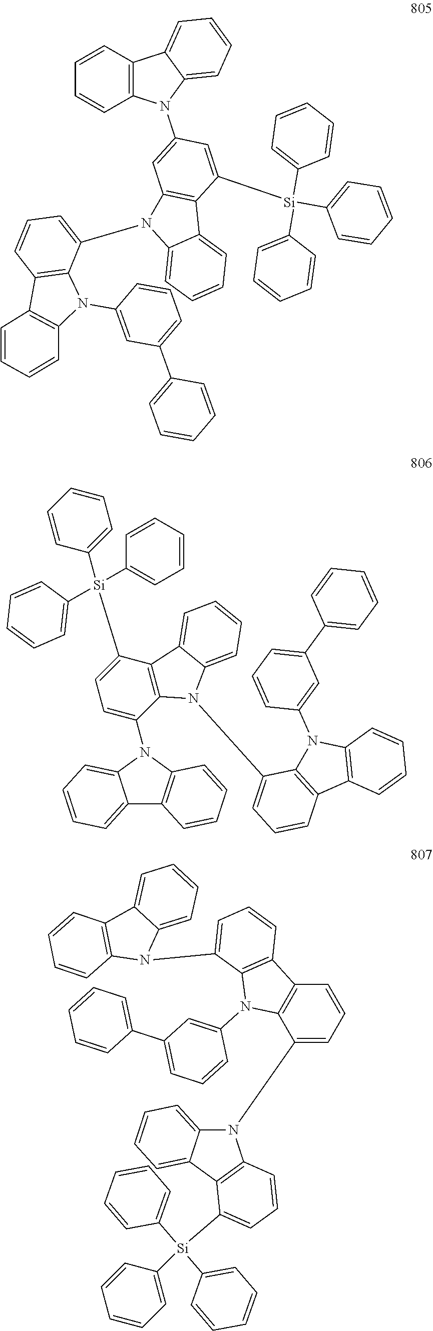

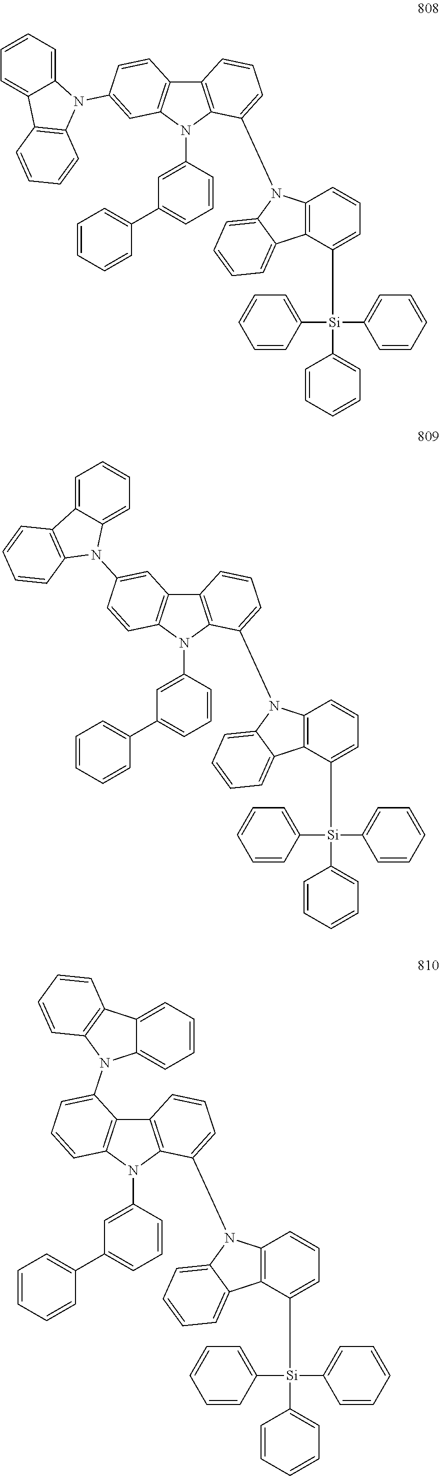 [SMILES: c1ccc(-c2cccc(-n3c4cc(-n5c6ccccc6c6ccccc65)ccc4c4cccc(-n5c6ccccc6c6c([Si](c7ccccc7)(c7ccccc7)c7ccccc7)cccc65)c43)c2)cc1 ; c1ccc(-c2cccc(-n3c4ccc(-n5c6ccccc6c6ccccc65)cc4c4cccc(-n5c6ccccc6c6c([Si](c7ccccc7)(c7ccccc7)c7ccccc7)cccc65)c43)c2)cc1 ; c1ccc(-c2cccc(-n3c4cccc(-n5c6ccccc6c6ccccc65)c4c4cccc(-n5c6ccccc6c6c([Si](c7ccccc7)(c7ccccc7)c7ccccc7)cccc65)c43)c2)cc1]

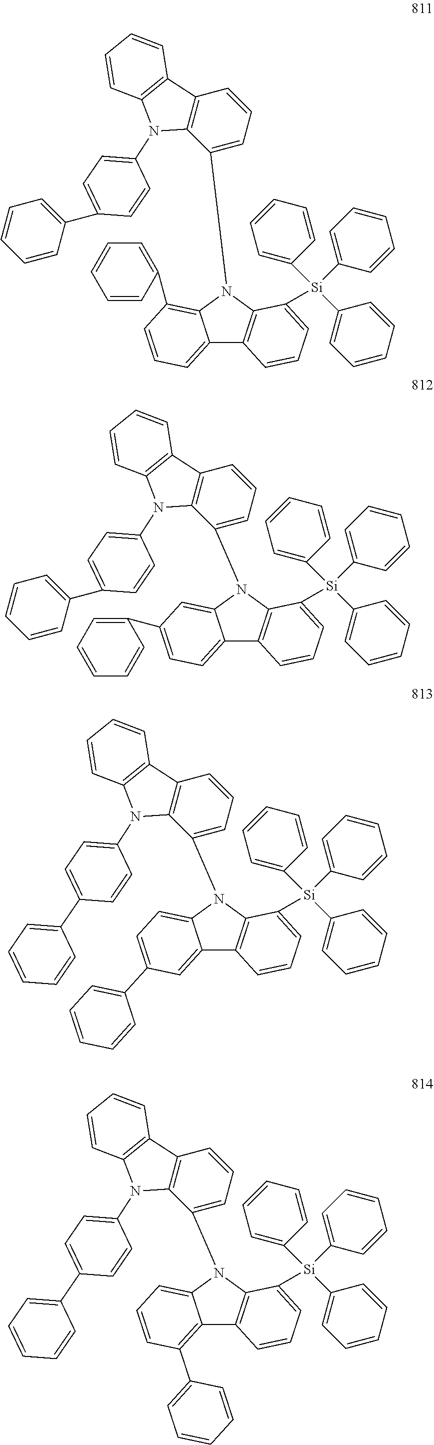

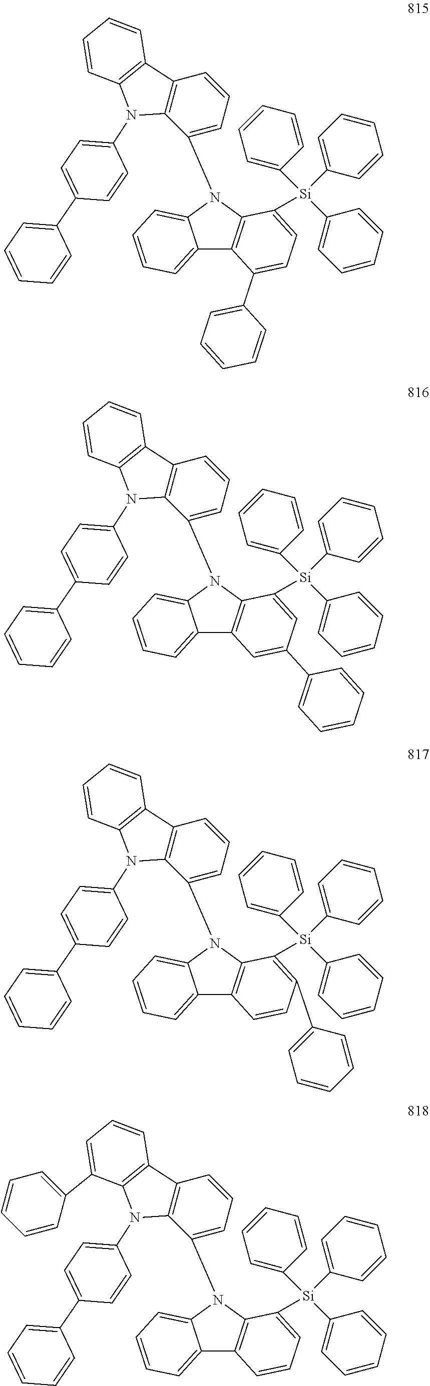 [SMILES: c1ccc(-c2ccc(-n3c4ccccc4c4cccc(-n5c6ccccc6c6c(-c7ccccc7)ccc([Si](c7ccccc7)(c7ccccc7)c7ccccc7)c65)c43)cc2)cc1 ; c1ccc(-c2ccc(-n3c4ccccc4c4cccc(-n5c6ccccc6c6cc(-c7ccccc7)cc([Si](c7ccccc7)(c7ccccc7)c7ccccc7)c65)c43)cc2)cc1 ; c1ccc(-c2ccc(-n3c4ccccc4c4cccc(-n5c6ccccc6c6ccc(-c7ccccc7)c([Si](c7ccccc7)(c7ccccc7)c7ccccc7)c65)c43)cc2)cc1 ; c1ccc(-c2ccc(-n3c4c(-c5ccccc5)cccc4c4cccc(-n5c6ccccc6c6cccc([Si](c7ccccc7)(c7ccccc7)c7ccccc7)c65)c43)cc2)cc1]

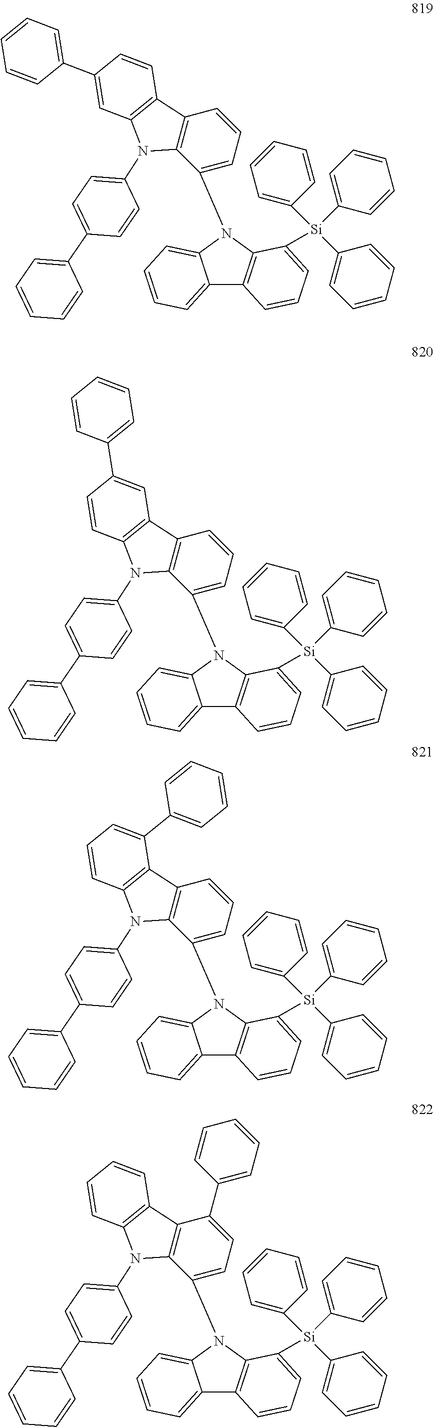

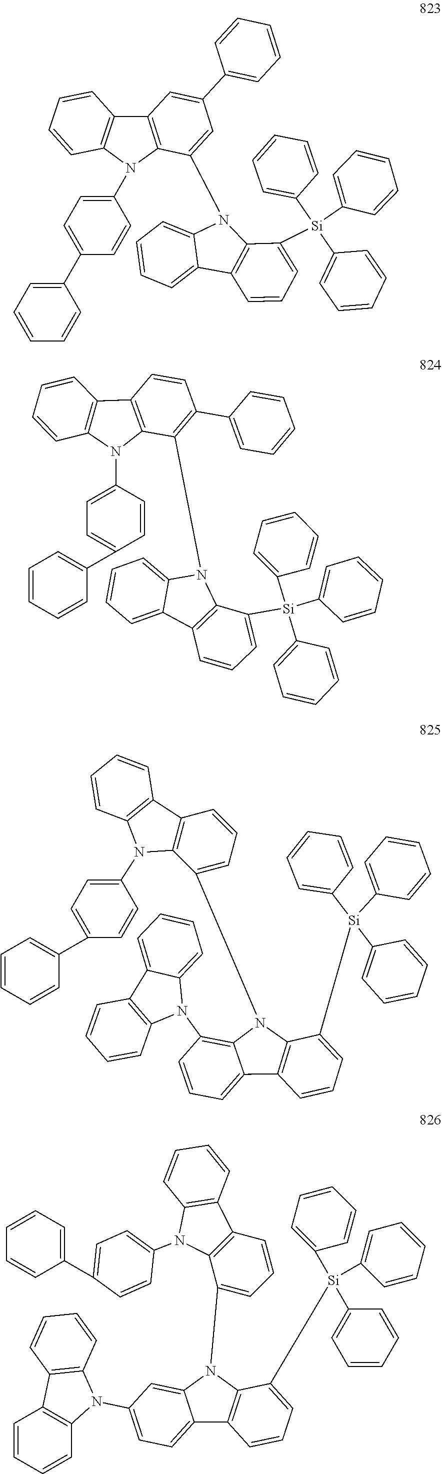

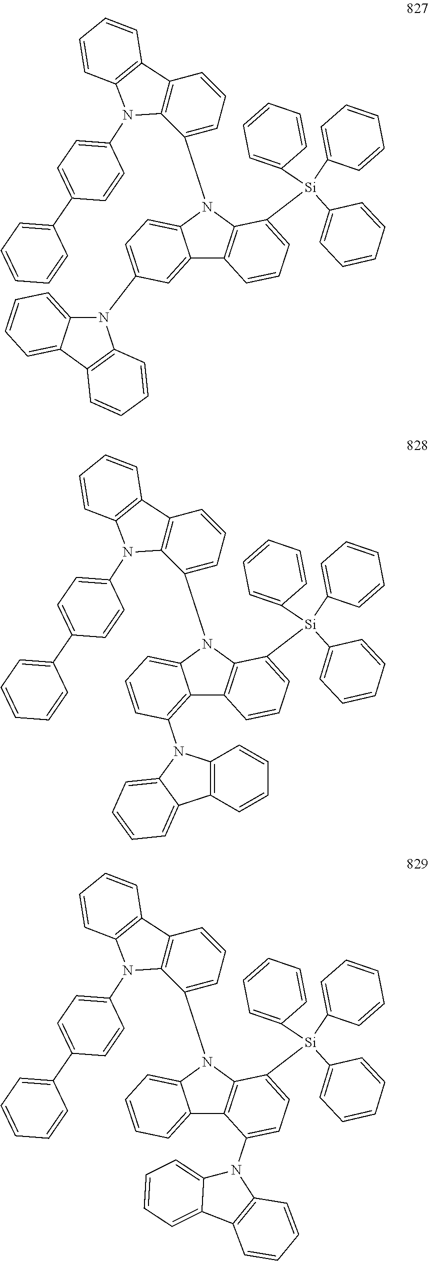

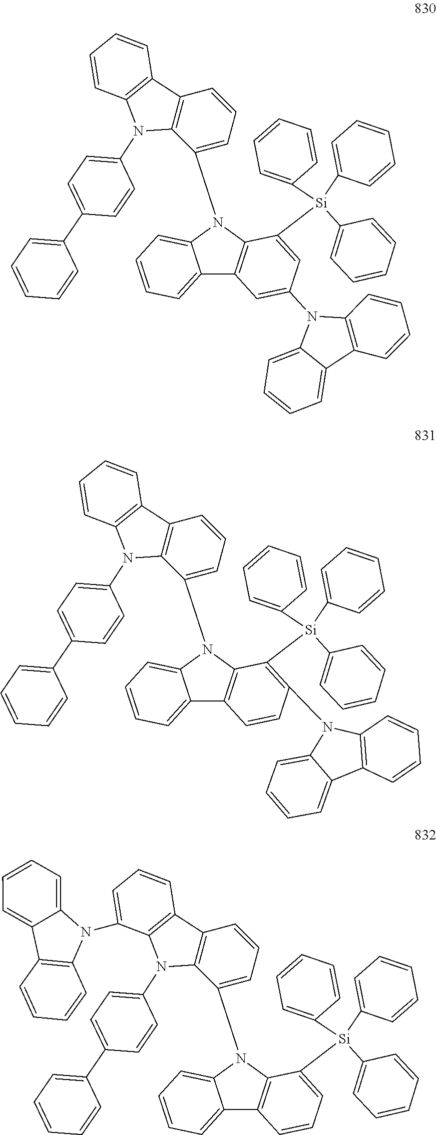 [SMILES: c1ccc(-c2ccc(-n3c4ccccc4c4cccc(-n5c6ccccc6c6cc(-n7c8ccccc8c8ccccc87)cc([Si](c7ccccc7)(c7ccccc7)c7ccccc7)c65)c43)cc2)cc1 ; c1ccc(-c2ccc(-n3c4ccccc4c4cccc(-n5c6ccccc6c6ccc(-n7c8ccccc8c8ccccc87)c([Si](c7ccccc7)(c7ccccc7)c7ccccc7)c65)c43)cc2)cc1 ; c1ccc(-c2ccc(-n3c4c(-n5c6ccccc6c6ccccc65)cccc4c4cccc(-n5c6ccccc6c6cccc([Si](c7ccccc7)(c7ccccc7)c7ccccc7)c65)c43)cc2)cc1]

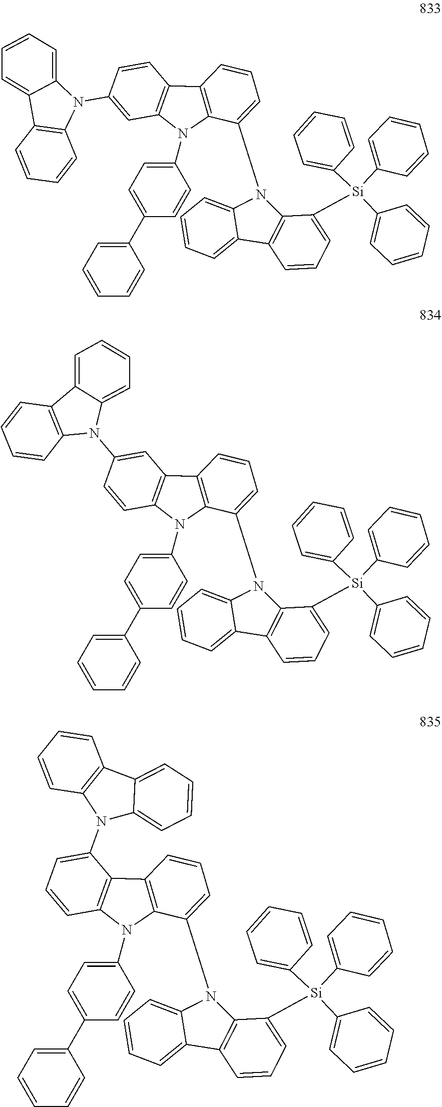 [SMILES: c1ccc(-c2ccc(-n3c4cc(-n5c6ccccc6c6ccccc65)ccc4c4cccc(-n5c6ccccc6c6cccc([Si](c7ccccc7)(c7ccccc7)c7ccccc7)c65)c43)cc2)cc1 ; c1ccc(-c2ccc(-n3c4ccc(-n5c6ccccc6c6ccccc65)cc4c4cccc(-n5c6ccccc6c6cccc([Si](c7ccccc7)(c7ccccc7)c7ccccc7)c65)c43)cc2)cc1 ; c1ccc(-c2ccc(-n3c4cccc(-n5c6ccccc6c6ccccc65)c4c4cccc(-n5c6ccccc6c6cccc([Si](c7ccccc7)(c7ccccc7)c7ccccc7)c65)c43)cc2)cc1]

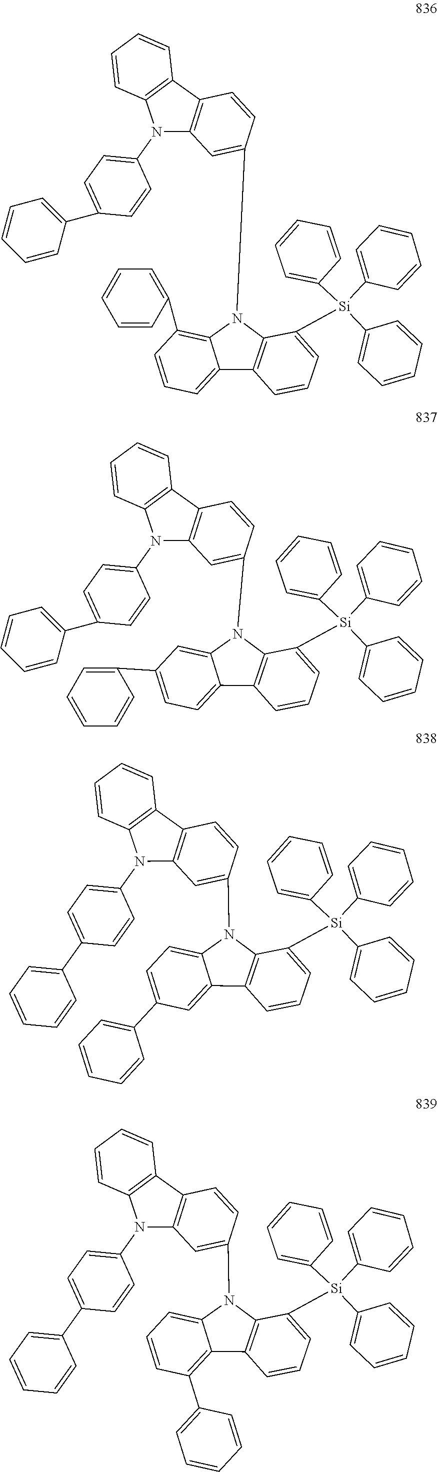

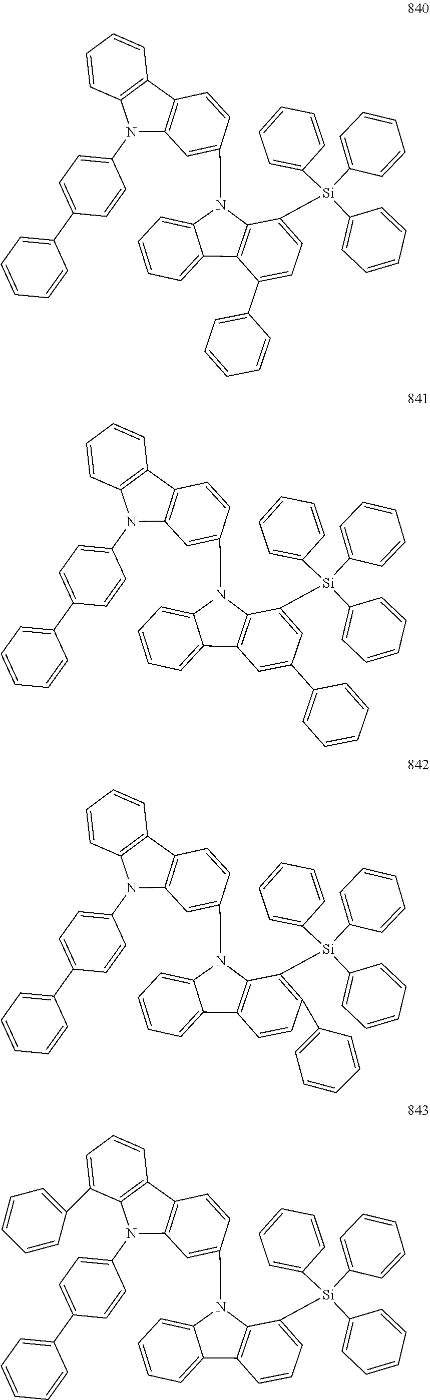 [SMILES: c1ccc(-c2ccc(-n3c4ccccc4c4ccc(-n5c6ccccc6c6c(-c7ccccc7)ccc([Si](c7ccccc7)(c7ccccc7)c7ccccc7)c65)cc43)cc2)cc1 ; c1ccc(-c2ccc(-n3c4ccccc4c4ccc(-n5c6ccccc6c6cc(-c7ccccc7)cc([Si](c7ccccc7)(c7ccccc7)c7ccccc7)c65)cc43)cc2)cc1 ; c1ccc(-c2ccc(-n3c4ccccc4c4ccc(-n5c6ccccc6c6ccc(-c7ccccc7)c([Si](c7ccccc7)(c7ccccc7)c7ccccc7)c65)cc43)cc2)cc1 ; c1ccc(-c2ccc(-n3c4cc(-n5c6ccccc6c6cccc([Si](c7ccccc7)(c7ccccc7)c7ccccc7)c65)ccc4c4cccc(-c5ccccc5)c43)cc2)cc1]

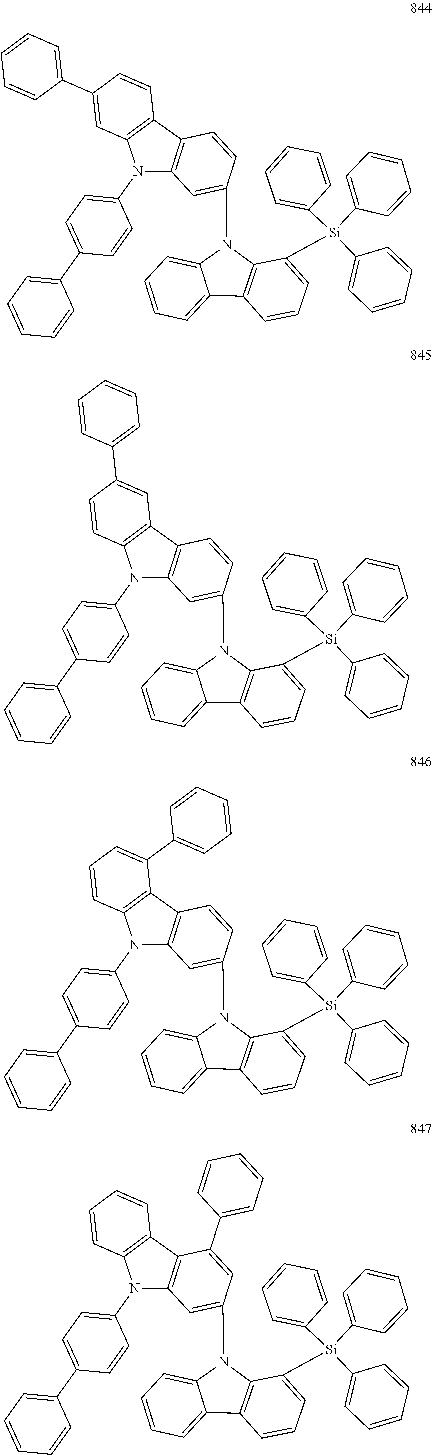 [SMILES: c1ccc(-c2ccc(-n3c4cc(-c5ccccc5)ccc4c4ccc(-n5c6ccccc6c6cccc([Si](c7ccccc7)(c7ccccc7)c7ccccc7)c65)cc43)cc2)cc1 ; c1ccc(-c2ccc(-n3c4ccc(-c5ccccc5)cc4c4ccc(-n5c6ccccc6c6cccc([Si](c7ccccc7)(c7ccccc7)c7ccccc7)c65)cc43)cc2)cc1 ; c1ccc(-c2ccc(-n3c4cc(-n5c6ccccc6c6cccc([Si](c7ccccc7)(c7ccccc7)c7ccccc7)c65)ccc4c4c(-c5ccccc5)cccc43)cc2)cc1 ; c1ccc(-c2ccc(-n3c4ccccc4c4c(-c5ccccc5)cc(-n5c6ccccc6c6cccc([Si](c7ccccc7)(c7ccccc7)c7ccccc7)c65)cc43)cc2)cc1]

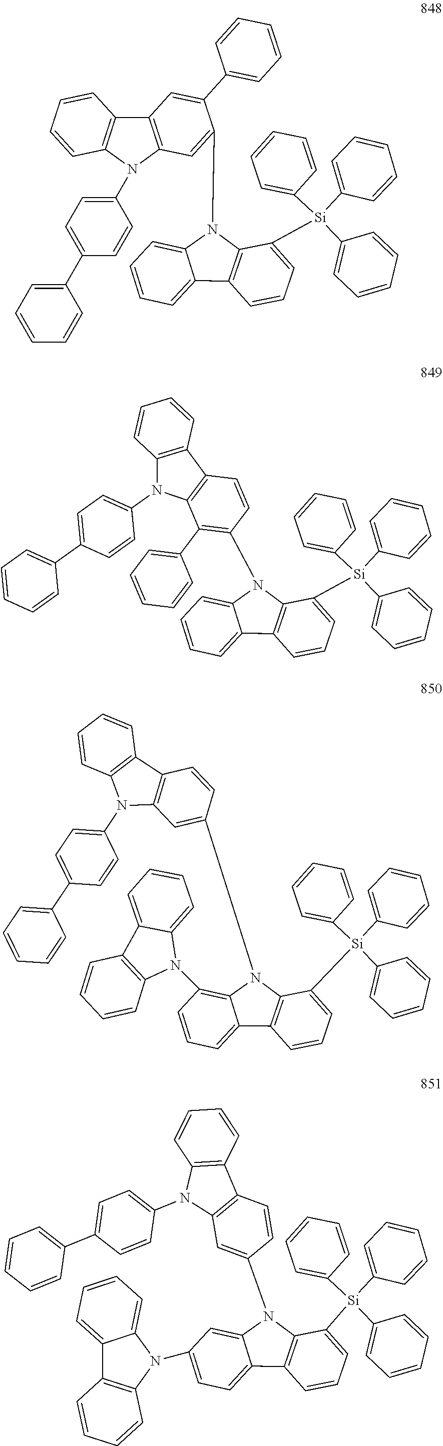 [SMILES: c1ccc(-c2ccc(-n3c4ccccc4c4cc(-c5ccccc5)c(-n5c6ccccc6c6cccc([Si](c7ccccc7)(c7ccccc7)c7ccccc7)c65)cc43)cc2)cc1 ; c1ccc(-c2ccc(-n3c4ccccc4c4ccc(-n5c6ccccc6c6cccc([Si](c7ccccc7)(c7ccccc7)c7ccccc7)c65)c(-c5ccccc5)c43)cc2)cc1 ; c1ccc(-c2ccc(-n3c4ccccc4c4ccc(-n5c6c(-n7c8ccccc8c8ccccc87)cccc6c6cccc([Si](c7ccccc7)(c7ccccc7)c7ccccc7)c65)cc43)cc2)cc1 ; c1ccc(-c2ccc(-n3c4ccccc4c4ccc(-n5c6cc(-n7c8ccccc8c8ccccc87)ccc6c6cccc([Si](c7ccccc7)(c7ccccc7)c7ccccc7)c65)cc43)cc2)cc1]

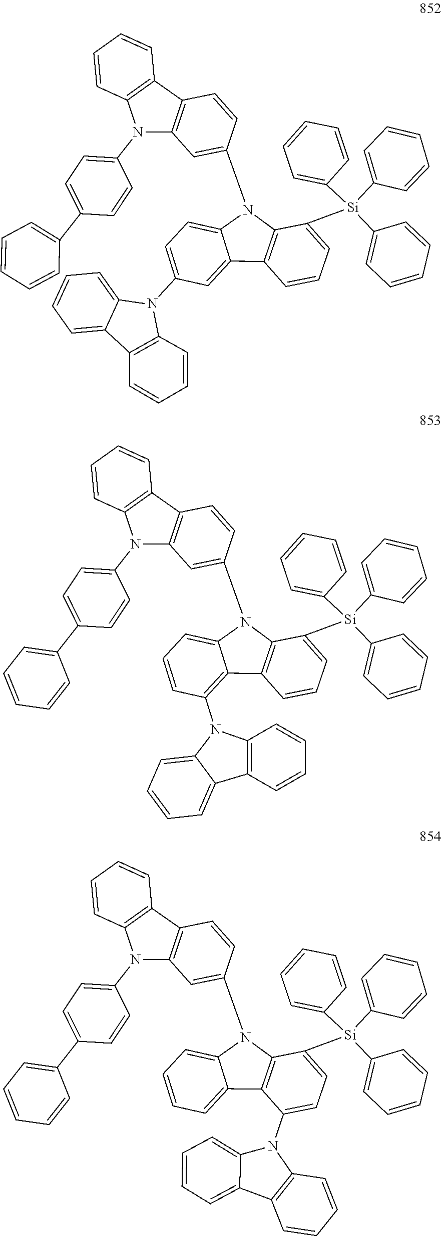 [SMILES: c1ccc(-c2ccc(-n3c4ccccc4c4ccc(-n5c6ccc(-n7c8ccccc8c8ccccc87)cc6c6cccc([Si](c7ccccc7)(c7ccccc7)c7ccccc7)c65)cc43)cc2)cc1 ; c1ccc(-c2ccc(-n3c4ccccc4c4ccc(-n5c6cccc(-n7c8ccccc8c8ccccc87)c6c6cccc([Si](c7ccccc7)(c7ccccc7)c7ccccc7)c65)cc43)cc2)cc1 ; c1ccc(-c2ccc(-n3c4ccccc4c4ccc(-n5c6ccccc6c6c(-n7c8ccccc8c8ccccc87)ccc([Si](c7ccccc7)(c7ccccc7)c7ccccc7)c65)cc43)cc2)cc1]

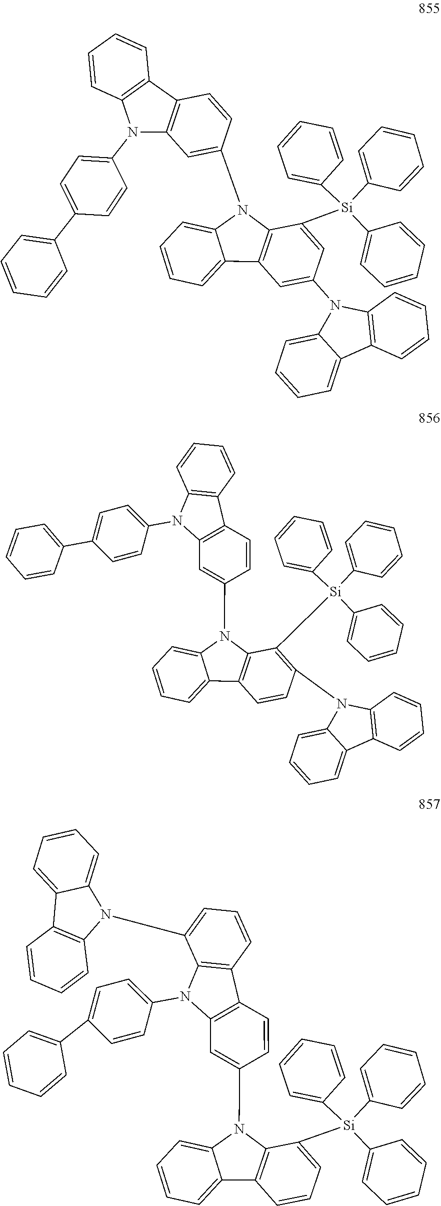 [SMILES: c1ccc(-c2ccc(-n3c4ccccc4c4ccc(-n5c6ccccc6c6cc(-n7c8ccccc8c8ccccc87)cc([Si](c7ccccc7)(c7ccccc7)c7ccccc7)c65)cc43)cc2)cc1 ; c1ccc(-c2ccc(-n3c4ccccc4c4ccc(-n5c6ccccc6c6ccc(-n7c8ccccc8c8ccccc87)c([Si](c7ccccc7)(c7ccccc7)c7ccccc7)c65)cc43)cc2)cc1 ; c1ccc(-c2ccc(-n3c4cc(-n5c6ccccc6c6cccc([Si](c7ccccc7)(c7ccccc7)c7ccccc7)c65)ccc4c4cccc(-n5c6ccccc6c6ccccc65)c43)cc2)cc1]

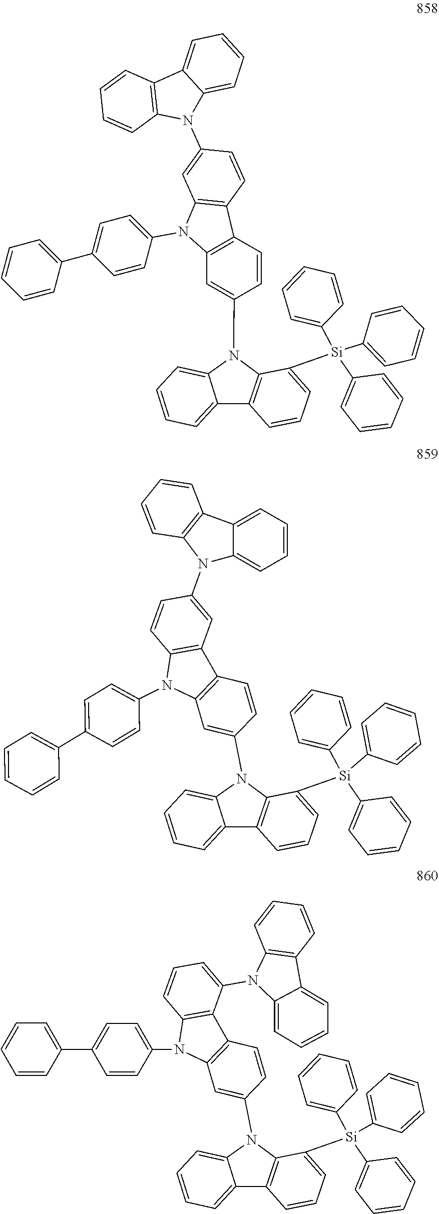 [SMILES: c1ccc(-c2ccc(-n3c4cc(-n5c6ccccc6c6ccccc65)ccc4c4ccc(-n5c6ccccc6c6cccc([Si](c7ccccc7)(c7ccccc7)c7ccccc7)c65)cc43)cc2)cc1 ; c1ccc(-c2ccc(-n3c4ccc(-n5c6ccccc6c6ccccc65)cc4c4ccc(-n5c6ccccc6c6cccc([Si](c7ccccc7)(c7ccccc7)c7ccccc7)c65)cc43)cc2)cc1 ; c1ccc(-c2ccc(-n3c4cc(-n5c6ccccc6c6cccc([Si](c7ccccc7)(c7ccccc7)c7ccccc7)c65)ccc4c4c(-n5c6ccccc6c6ccccc65)cccc43)cc2)cc1]

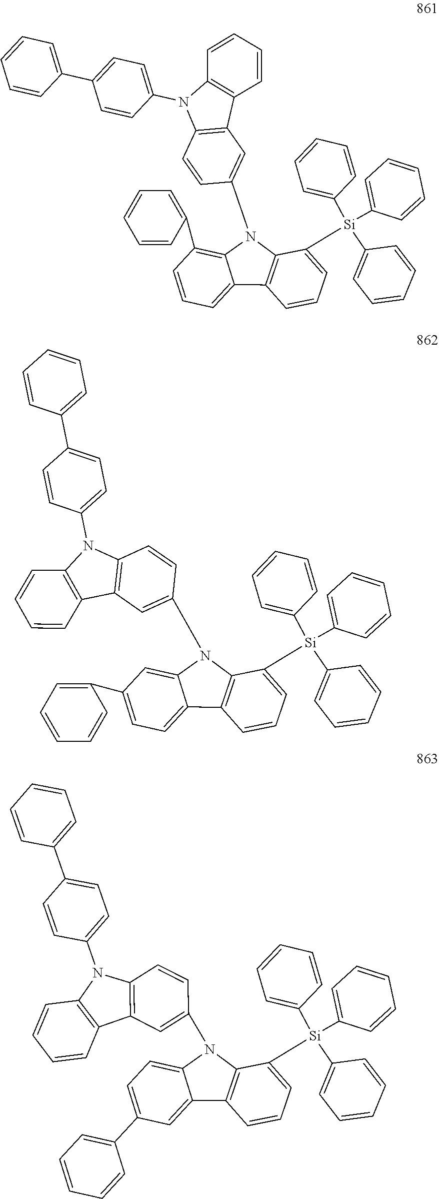 [SMILES: c1ccc(-c2ccc(-n3c4ccccc4c4cc(-n5c6c(-c7ccccc7)cccc6c6cccc([Si](c7ccccc7)(c7ccccc7)c7ccccc7)c65)ccc43)cc2)cc1 ; c1ccc(-c2ccc(-n3c4ccccc4c4cc(-n5c6cc(-c7ccccc7)ccc6c6cccc([Si](c7ccccc7)(c7ccccc7)c7ccccc7)c65)ccc43)cc2)cc1 ; c1ccc(-c2ccc(-n3c4ccccc4c4cc(-n5c6ccc(-c7ccccc7)cc6c6cccc([Si](c7ccccc7)(c7ccccc7)c7ccccc7)c65)ccc43)cc2)cc1]

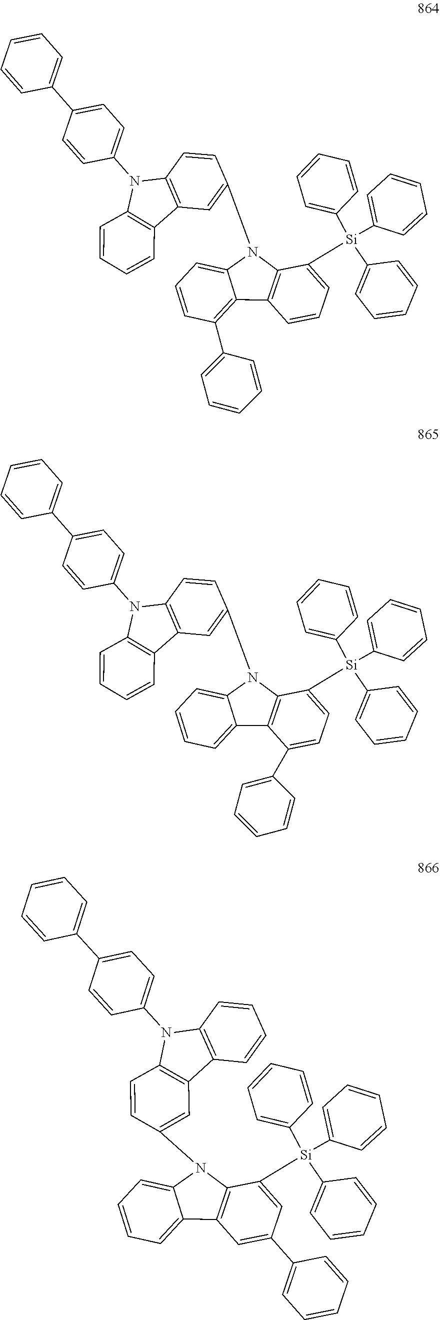 [SMILES: c1ccc(-c2ccc(-n3c4ccccc4c4cc(-n5c6cccc(-c7ccccc7)c6c6cccc([Si](c7ccccc7)(c7ccccc7)c7ccccc7)c65)ccc43)cc2)cc1 ; c1ccc(-c2ccc(-n3c4ccccc4c4cc(-n5c6ccccc6c6c(-c7ccccc7)ccc([Si](c7ccccc7)(c7ccccc7)c7ccccc7)c65)ccc43)cc2)cc1 ; c1ccc(-c2ccc(-n3c4ccccc4c4cc(-n5c6ccccc6c6cc(-c7ccccc7)cc([Si](c7ccccc7)(c7ccccc7)c7ccccc7)c65)ccc43)cc2)cc1]

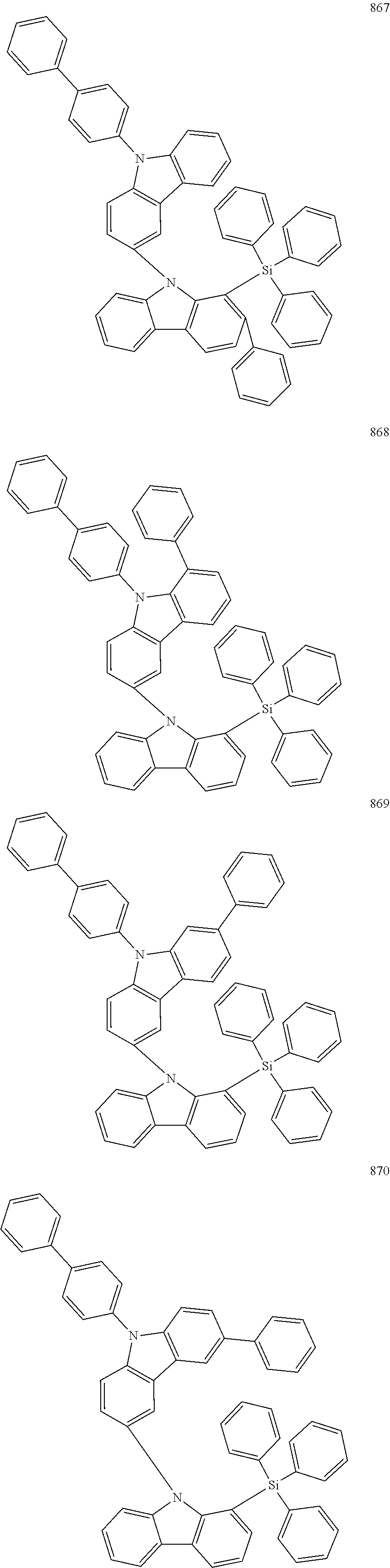 [SMILES: c1ccc(-c2ccc(-n3c4ccccc4c4cc(-n5c6ccccc6c6ccc(-c7ccccc7)c([Si](c7ccccc7)(c7ccccc7)c7ccccc7)c65)ccc43)cc2)cc1 ; c1ccc(-c2ccc(-n3c4ccc(-n5c6ccccc6c6cccc([Si](c7ccccc7)(c7ccccc7)c7ccccc7)c65)cc4c4cccc(-c5ccccc5)c43)cc2)cc1 ; c1ccc(-c2ccc(-n3c4ccc(-n5c6ccccc6c6cccc([Si](c7ccccc7)(c7ccccc7)c7ccccc7)c65)cc4c4ccc(-c5ccccc5)cc43)cc2)cc1 ; c1ccc(-c2ccc(-n3c4ccc(-c5ccccc5)cc4c4cc(-n5c6ccccc6c6cccc([Si](c7ccccc7)(c7ccccc7)c7ccccc7)c65)ccc43)cc2)cc1]

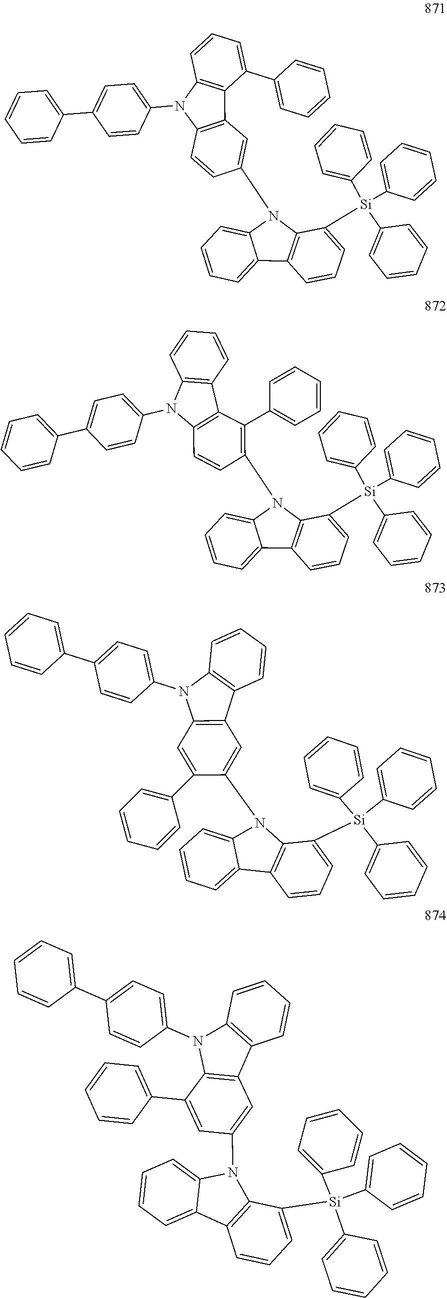 [SMILES: c1ccc(-c2ccc(-n3c4ccc(-n5c6ccccc6c6cccc([Si](c7ccccc7)(c7ccccc7)c7ccccc7)c65)cc4c4c(-c5ccccc5)cccc43)cc2)cc1 ; c1ccc(-c2ccc(-n3c4ccccc4c4c(-c5ccccc5)c(-n5c6ccccc6c6cccc([Si](c7ccccc7)(c7ccccc7)c7ccccc7)c65)ccc43)cc2)cc1 ; c1ccc(-c2ccc(-n3c4ccccc4c4cc(-n5c6ccccc6c6cccc([Si](c7ccccc7)(c7ccccc7)c7ccccc7)c65)c(-c5ccccc5)cc43)cc2)cc1 ; c1ccc(-c2ccc(-n3c4ccccc4c4cc(-n5c6ccccc6c6cccc([Si](c7ccccc7)(c7ccccc7)c7ccccc7)c65)cc(-c5ccccc5)c43)cc2)cc1]

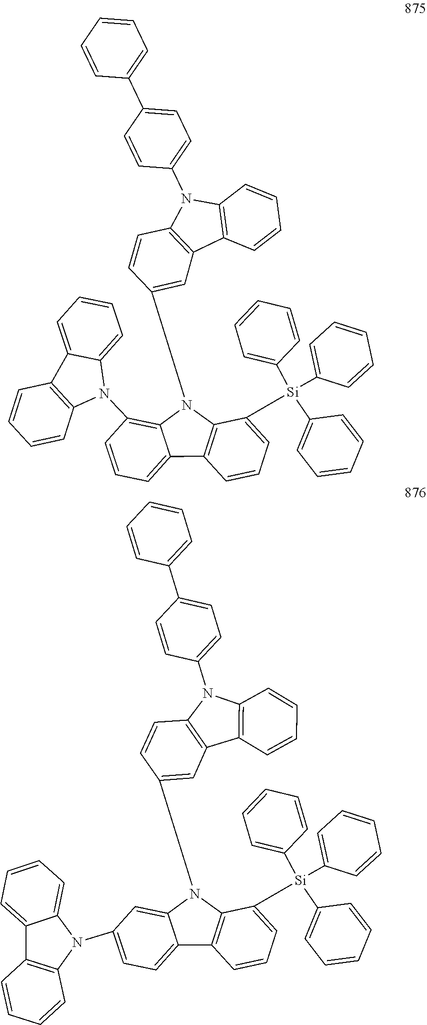

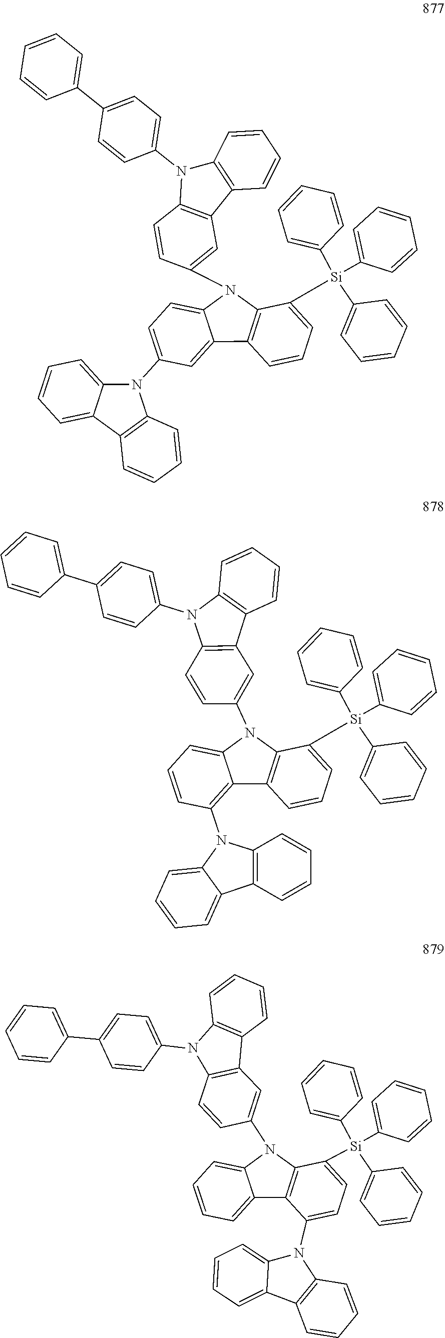 [SMILES: c1ccc(-c2ccc(-n3c4ccccc4c4cc(-n5c6ccc(-n7c8ccccc8c8ccccc87)cc6c6cccc([Si](c7ccccc7)(c7ccccc7)c7ccccc7)c65)ccc43)cc2)cc1 ; c1ccc(-c2ccc(-n3c4ccccc4c4cc(-n5c6cccc(-n7c8ccccc8c8ccccc87)c6c6cccc([Si](c7ccccc7)(c7ccccc7)c7ccccc7)c65)ccc43)cc2)cc1 ; c1ccc(-c2ccc(-n3c4ccccc4c4cc(-n5c6ccccc6c6c(-n7c8ccccc8c8ccccc87)ccc([Si](c7ccccc7)(c7ccccc7)c7ccccc7)c65)ccc43)cc2)cc1]

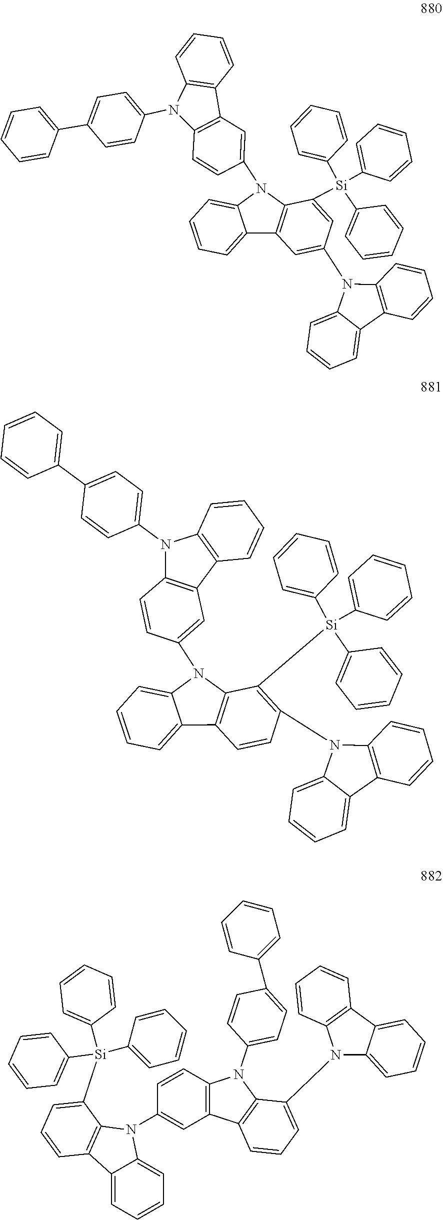 [SMILES: c1ccc(-c2ccc(-n3c4ccccc4c4cc(-n5c6ccccc6c6cc(-n7c8ccccc8c8ccccc87)cc([Si](c7ccccc7)(c7ccccc7)c7ccccc7)c65)ccc43)cc2)cc1 ; c1ccc(-c2ccc(-n3c4ccccc4c4cc(-n5c6ccccc6c6ccc(-n7c8ccccc8c8ccccc87)c([Si](c7ccccc7)(c7ccccc7)c7ccccc7)c65)ccc43)cc2)cc1 ; c1ccc(-c2ccc(-n3c4ccc(-n5c6ccccc6c6cccc([Si](c7ccccc7)(c7ccccc7)c7ccccc7)c65)cc4c4cccc(-n5c6ccccc6c6ccccc65)c43)cc2)cc1]

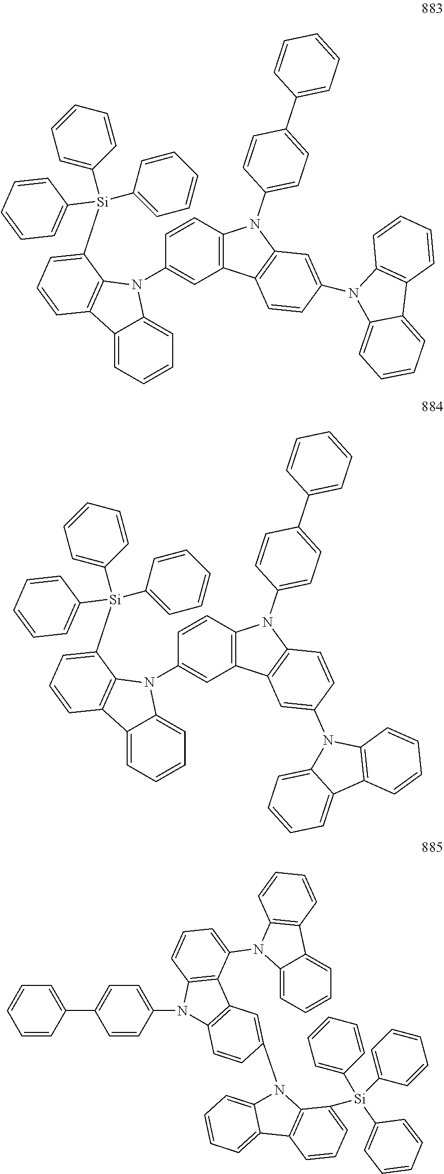

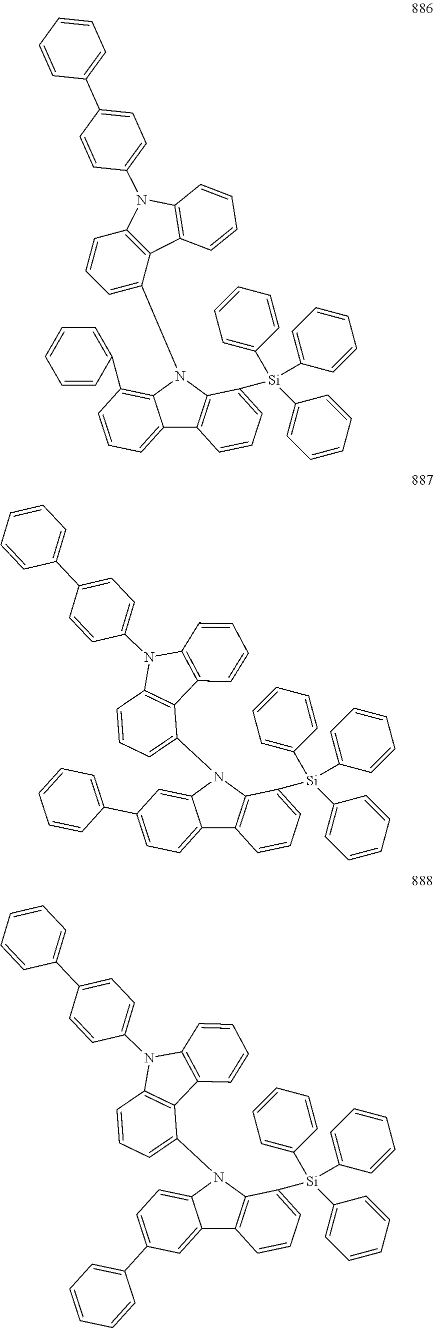 [SMILES: c1ccc(-c2ccc(-n3c4ccccc4c4c(-n5c6c(-c7ccccc7)cccc6c6cccc([Si](c7ccccc7)(c7ccccc7)c7ccccc7)c65)cccc43)cc2)cc1 ; c1ccc(-c2ccc(-n3c4ccccc4c4c(-n5c6cc(-c7ccccc7)ccc6c6cccc([Si](c7ccccc7)(c7ccccc7)c7ccccc7)c65)cccc43)cc2)cc1 ; c1ccc(-c2ccc(-n3c4ccccc4c4c(-n5c6ccc(-c7ccccc7)cc6c6cccc([Si](c7ccccc7)(c7ccccc7)c7ccccc7)c65)cccc43)cc2)cc1]

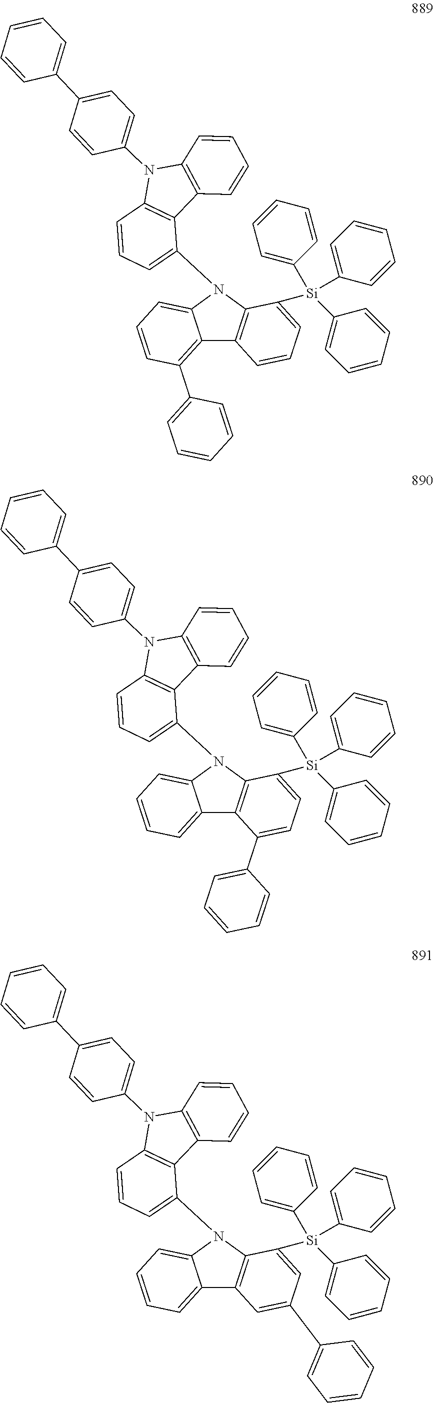 [SMILES: c1ccc(-c2ccc(-n3c4ccccc4c4c(-n5c6cccc(-c7ccccc7)c6c6cccc([Si](c7ccccc7)(c7ccccc7)c7ccccc7)c65)cccc43)cc2)cc1 ; c1ccc(-c2ccc(-n3c4ccccc4c4c(-n5c6ccccc6c6c(-c7ccccc7)ccc([Si](c7ccccc7)(c7ccccc7)c7ccccc7)c65)cccc43)cc2)cc1 ; c1ccc(-c2ccc(-n3c4ccccc4c4c(-n5c6ccccc6c6cc(-c7ccccc7)cc([Si](c7ccccc7)(c7ccccc7)c7ccccc7)c65)cccc43)cc2)cc1]

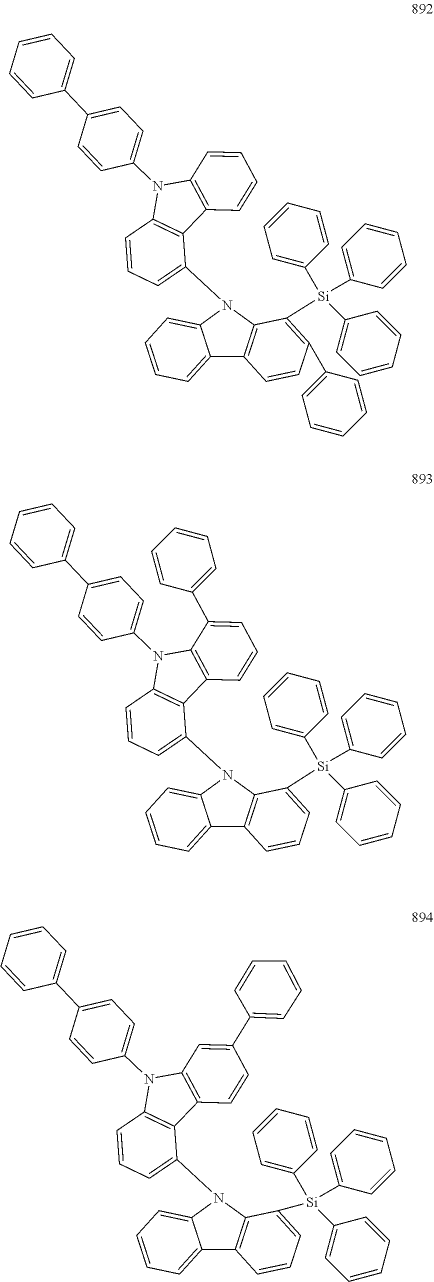 [SMILES: c1ccc(-c2ccc(-n3c4ccccc4c4c(-n5c6ccccc6c6ccc(-c7ccccc7)c([Si](c7ccccc7)(c7ccccc7)c7ccccc7)c65)cccc43)cc2)cc1 ; c1ccc(-c2ccc(-n3c4cccc(-n5c6ccccc6c6cccc([Si](c7ccccc7)(c7ccccc7)c7ccccc7)c65)c4c4cccc(-c5ccccc5)c43)cc2)cc1 ; c1ccc(-c2ccc(-n3c4cc(-c5ccccc5)ccc4c4c(-n5c6ccccc6c6cccc([Si](c7ccccc7)(c7ccccc7)c7ccccc7)c65)cccc43)cc2)cc1]

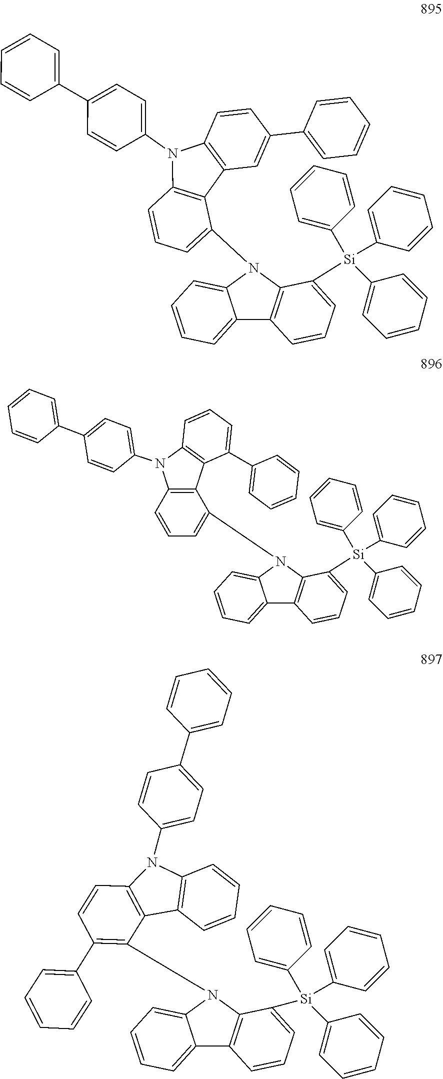 [SMILES: c1ccc(-c2ccc(-n3c4ccc(-c5ccccc5)cc4c4c(-n5c6ccccc6c6cccc([Si](c7ccccc7)(c7ccccc7)c7ccccc7)c65)cccc43)cc2)cc1 ; c1ccc(-c2ccc(-n3c4cccc(-c5ccccc5)c4c4c(-n5c6ccccc6c6cccc([Si](c7ccccc7)(c7ccccc7)c7ccccc7)c65)cccc43)cc2)cc1 ; c1ccc(-c2ccc(-n3c4ccccc4c4c(-n5c6ccccc6c6cccc([Si](c7ccccc7)(c7ccccc7)c7ccccc7)c65)c(-c5ccccc5)ccc43)cc2)cc1]

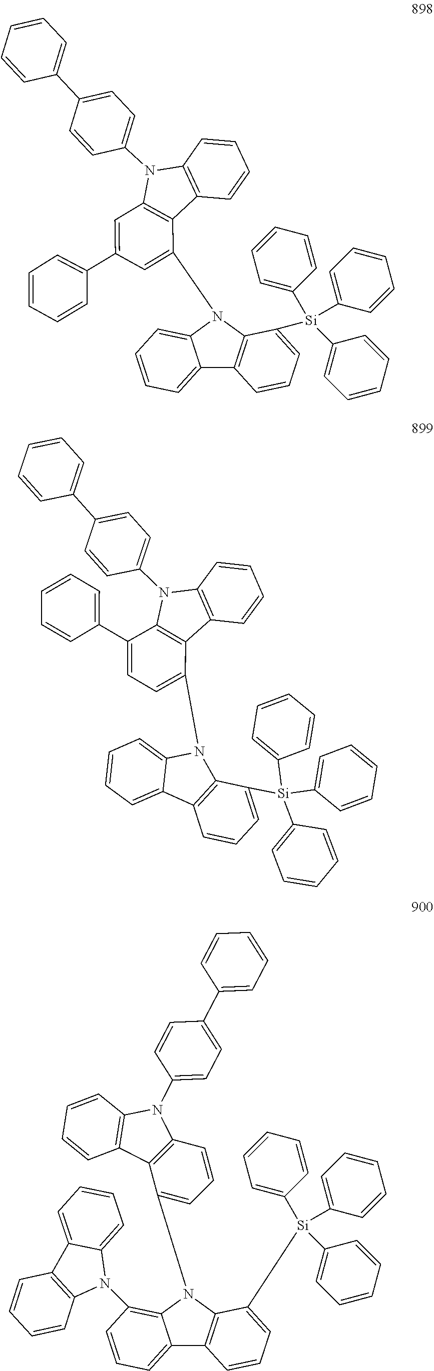 [SMILES: c1ccc(-c2ccc(-n3c4ccccc4c4c(-n5c6ccccc6c6cccc([Si](c7ccccc7)(c7ccccc7)c7ccccc7)c65)cc(-c5ccccc5)cc43)cc2)cc1 ; c1ccc(-c2ccc(-n3c4ccccc4c4c(-n5c6ccccc6c6cccc([Si](c7ccccc7)(c7ccccc7)c7ccccc7)c65)ccc(-c5ccccc5)c43)cc2)cc1 ; c1ccc(-c2ccc(-n3c4ccccc4c4c(-n5c6c(-n7c8ccccc8c8ccccc87)cccc6c6cccc([Si](c7ccccc7)(c7ccccc7)c7ccccc7)c65)cccc43)cc2)cc1]

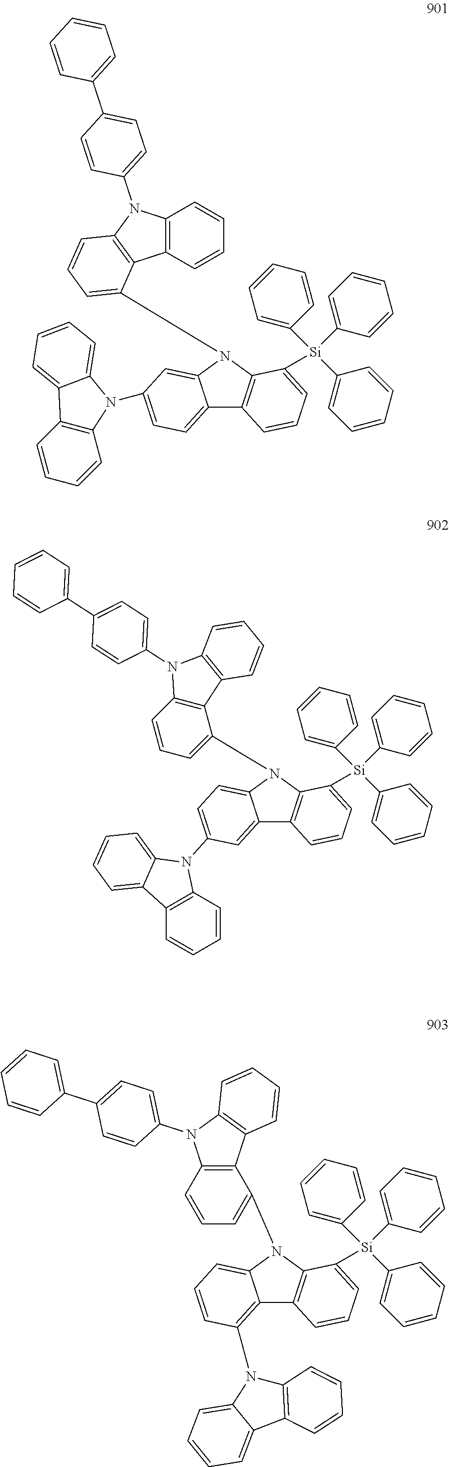 [SMILES: c1ccc(-c2ccc(-n3c4ccccc4c4c(-n5c6cc(-n7c8ccccc8c8ccccc87)ccc6c6cccc([Si](c7ccccc7)(c7ccccc7)c7ccccc7)c65)cccc43)cc2)cc1 ; c1ccc(-c2ccc(-n3c4ccccc4c4c(-n5c6ccc(-n7c8ccccc8c8ccccc87)cc6c6cccc([Si](c7ccccc7)(c7ccccc7)c7ccccc7)c65)cccc43)cc2)cc1 ; c1ccc(-c2ccc(-n3c4ccccc4c4c(-n5c6cccc(-n7c8ccccc8c8ccccc87)c6c6cccc([Si](c7ccccc7)(c7ccccc7)c7ccccc7)c65)cccc43)cc2)cc1]

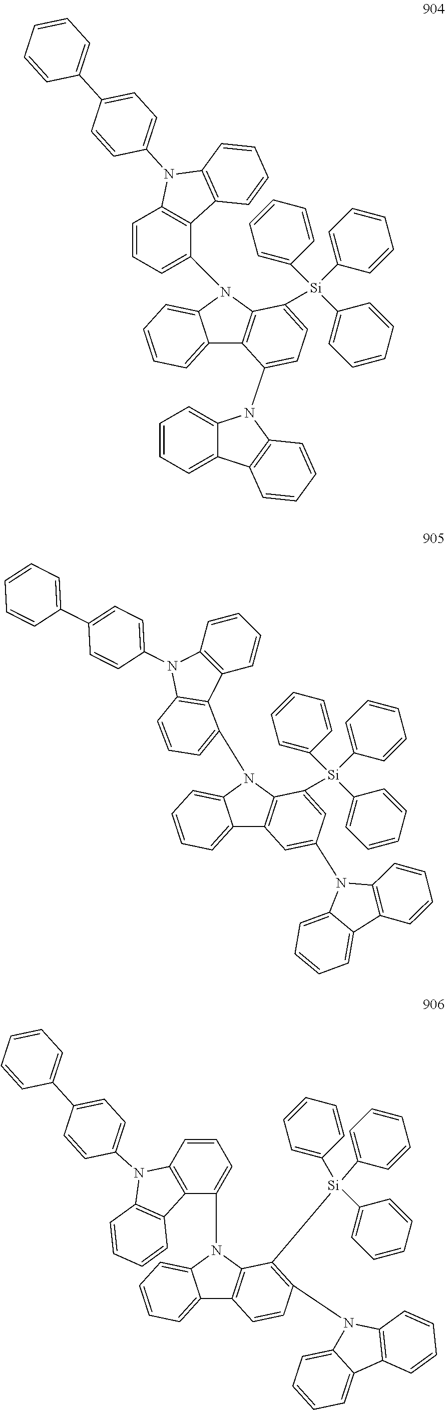 [SMILES: c1ccc(-c2ccc(-n3c4ccccc4c4c(-n5c6ccccc6c6c(-n7c8ccccc8c8ccccc87)ccc([Si](c7ccccc7)(c7ccccc7)c7ccccc7)c65)cccc43)cc2)cc1 ; c1ccc(-c2ccc(-n3c4ccccc4c4c(-n5c6ccccc6c6cc(-n7c8ccccc8c8ccccc87)cc([Si](c7ccccc7)(c7ccccc7)c7ccccc7)c65)cccc43)cc2)cc1 ; c1ccc(-c2ccc(-n3c4ccccc4c4c(-n5c6ccccc6c6ccc(-n7c8ccccc8c8ccccc87)c([Si](c7ccccc7)(c7ccccc7)c7ccccc7)c65)cccc43)cc2)cc1]

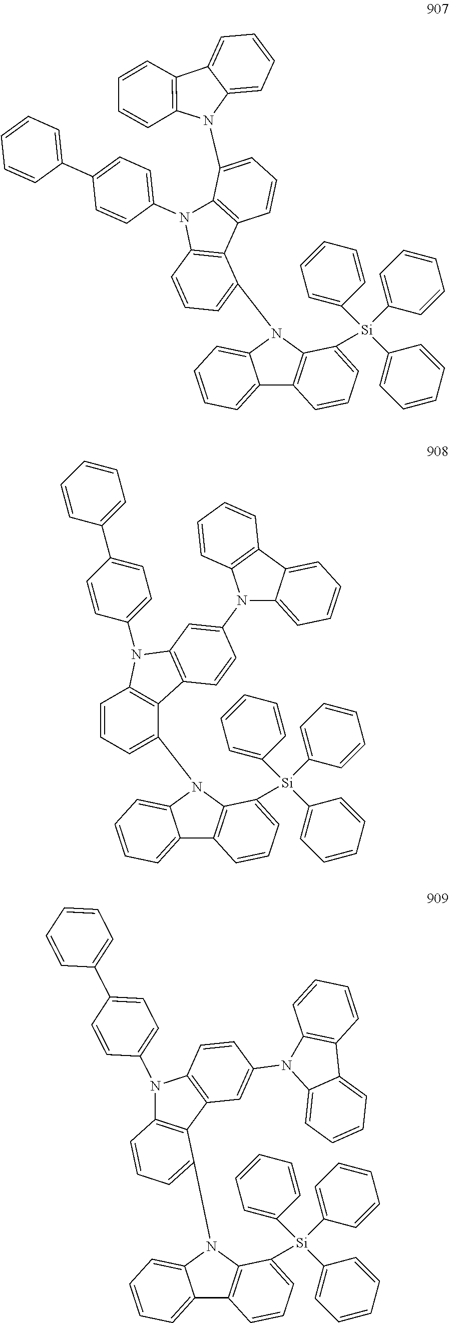 [SMILES: c1ccc(-c2ccc(-n3c4cccc(-n5c6ccccc6c6cccc([Si](c7ccccc7)(c7ccccc7)c7ccccc7)c65)c4c4cccc(-n5c6ccccc6c6ccccc65)c43)cc2)cc1 ; c1ccc(-c2ccc(-n3c4cc(-n5c6ccccc6c6ccccc65)ccc4c4c(-n5c6ccccc6c6cccc([Si](c7ccccc7)(c7ccccc7)c7ccccc7)c65)cccc43)cc2)cc1 ; c1ccc(-c2ccc(-n3c4ccc(-n5c6ccccc6c6ccccc65)cc4c4c(-n5c6ccccc6c6cccc([Si](c7ccccc7)(c7ccccc7)c7ccccc7)c65)cccc43)cc2)cc1]

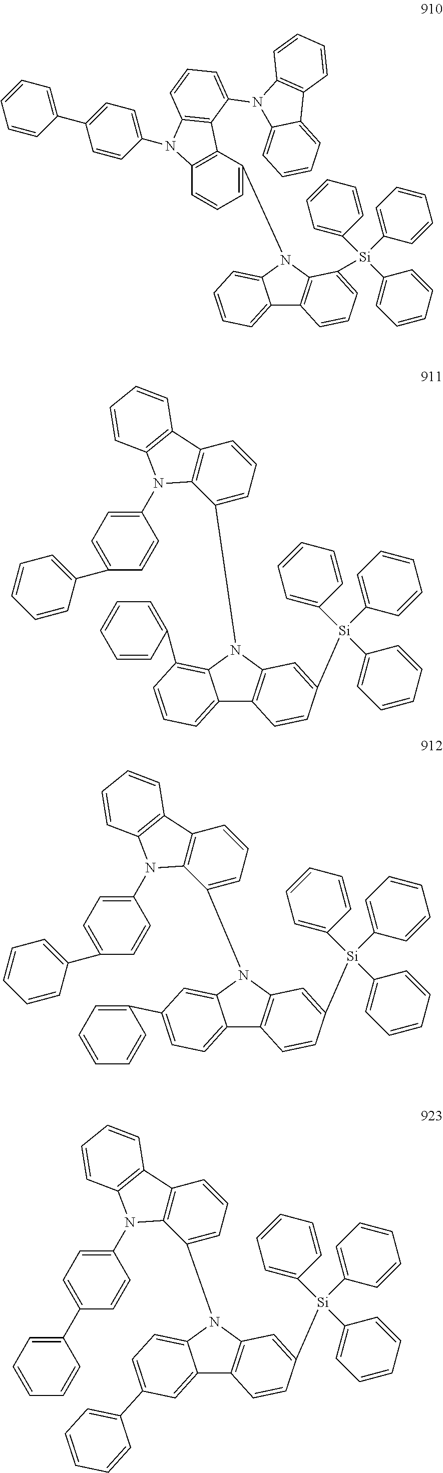 [SMILES: c1ccc(-c2ccc(-n3c4cccc(-n5c6ccccc6c6ccccc65)c4c4c(-n5c6ccccc6c6cccc([Si](c7ccccc7)(c7ccccc7)c7ccccc7)c65)cccc43)cc2)cc1 ; c1ccc(-c2ccc(-n3c4ccccc4c4cccc(-n5c6cc([Si](c7ccccc7)(c7ccccc7)c7ccccc7)ccc6c6cccc(-c7ccccc7)c65)c43)cc2)cc1 ; c1ccc(-c2ccc(-n3c4ccccc4c4cccc(-n5c6cc(-c7ccccc7)ccc6c6ccc([Si](c7ccccc7)(c7ccccc7)c7ccccc7)cc65)c43)cc2)cc1 ; c1ccc(-c2ccc(-n3c4ccccc4c4cccc(-n5c6ccc(-c7ccccc7)cc6c6ccc([Si](c7ccccc7)(c7ccccc7)c7ccccc7)cc65)c43)cc2)cc1]

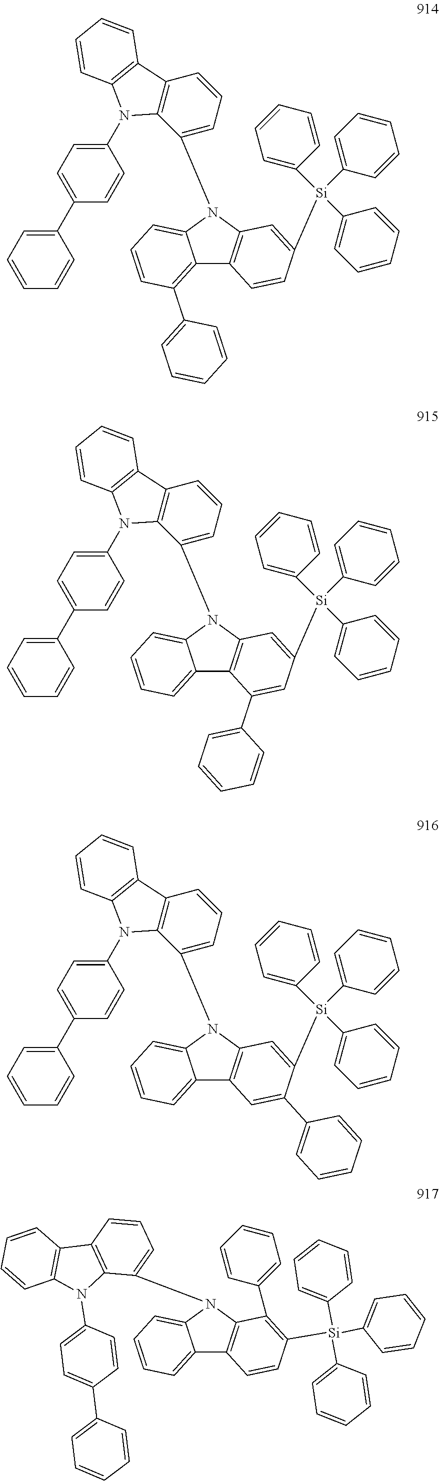 [SMILES: c1ccc(-c2ccc(-n3c4ccccc4c4cccc(-n5c6cc([Si](c7ccccc7)(c7ccccc7)c7ccccc7)ccc6c6c(-c7ccccc7)cccc65)c43)cc2)cc1 ; c1ccc(-c2ccc(-n3c4ccccc4c4cccc(-n5c6ccccc6c6c(-c7ccccc7)cc([Si](c7ccccc7)(c7ccccc7)c7ccccc7)cc65)c43)cc2)cc1 ; c1ccc(-c2ccc(-n3c4ccccc4c4cccc(-n5c6ccccc6c6cc(-c7ccccc7)c([Si](c7ccccc7)(c7ccccc7)c7ccccc7)cc65)c43)cc2)cc1 ; c1ccc(-c2ccc(-n3c4ccccc4c4cccc(-n5c6ccccc6c6ccc([Si](c7ccccc7)(c7ccccc7)c7ccccc7)c(-c7ccccc7)c65)c43)cc2)cc1]

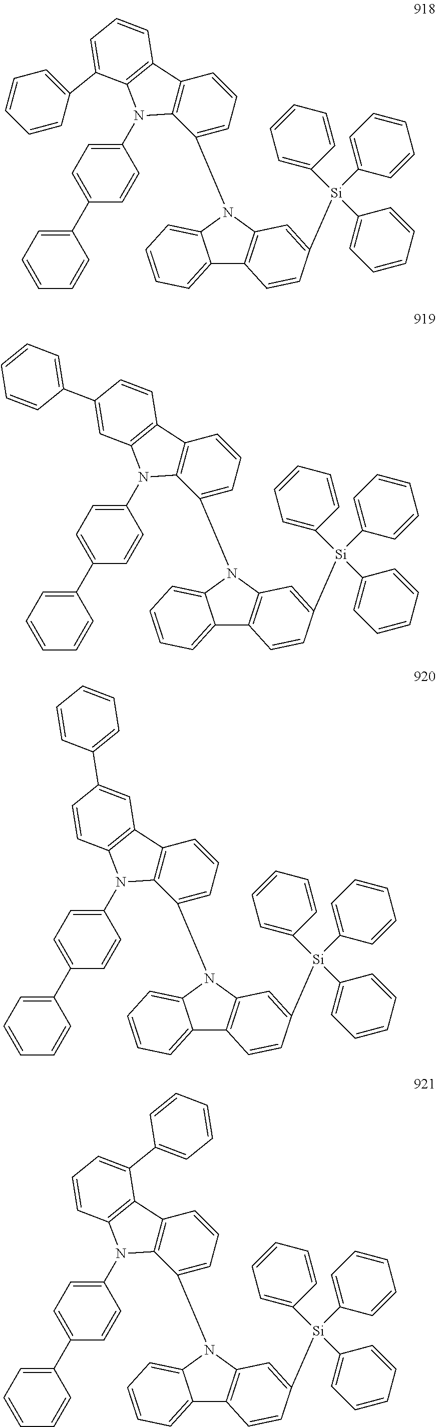

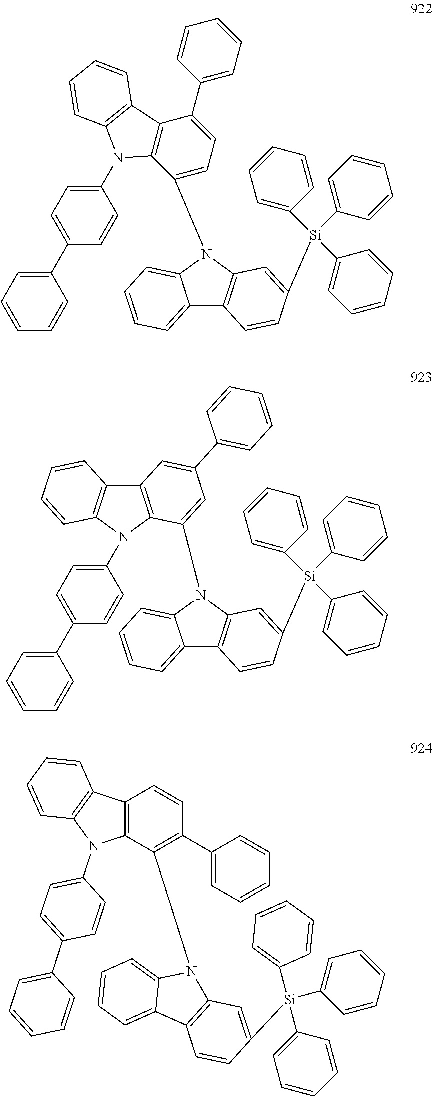 [SMILES: c1ccc(-c2ccc(-n3c4ccccc4c4c(-c5ccccc5)ccc(-n5c6ccccc6c6ccc([Si](c7ccccc7)(c7ccccc7)c7ccccc7)cc65)c43)cc2)cc1 ; c1ccc(-c2ccc(-n3c4ccccc4c4cc(-c5ccccc5)cc(-n5c6ccccc6c6ccc([Si](c7ccccc7)(c7ccccc7)c7ccccc7)cc65)c43)cc2)cc1 ; c1ccc(-c2ccc(-n3c4ccccc4c4ccc(-c5ccccc5)c(-n5c6ccccc6c6ccc([Si](c7ccccc7)(c7ccccc7)c7ccccc7)cc65)c43)cc2)cc1]

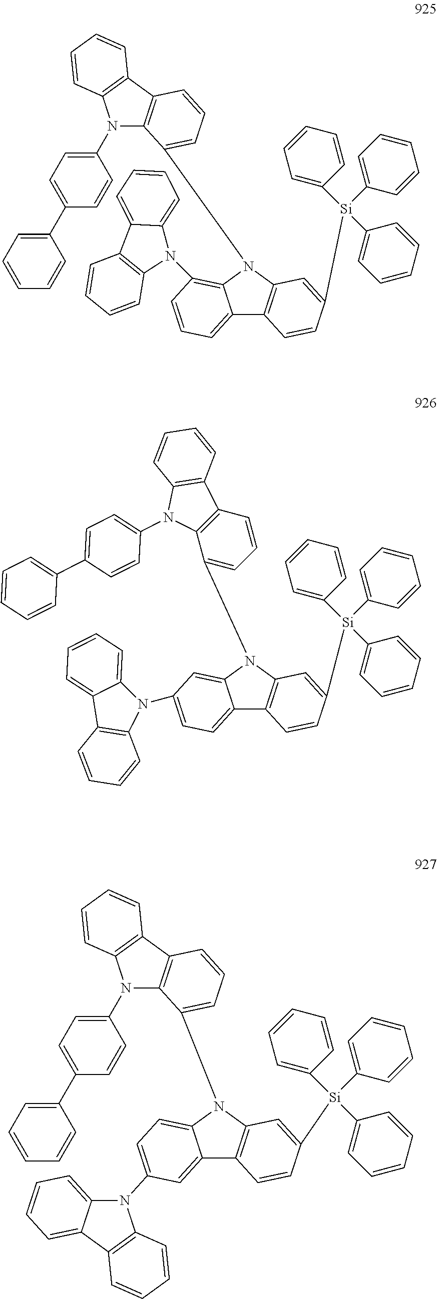 [SMILES: c1ccc(-c2ccc(-n3c4ccccc4c4cccc(-n5c6cc([Si](c7ccccc7)(c7ccccc7)c7ccccc7)ccc6c6cccc(-n7c8ccccc8c8ccccc87)c65)c43)cc2)cc1 ; c1ccc(-c2ccc(-n3c4ccccc4c4cccc(-n5c6cc(-n7c8ccccc8c8ccccc87)ccc6c6ccc([Si](c7ccccc7)(c7ccccc7)c7ccccc7)cc65)c43)cc2)cc1 ; c1ccc(-c2ccc(-n3c4ccccc4c4cccc(-n5c6ccc(-n7c8ccccc8c8ccccc87)cc6c6ccc([Si](c7ccccc7)(c7ccccc7)c7ccccc7)cc65)c43)cc2)cc1]

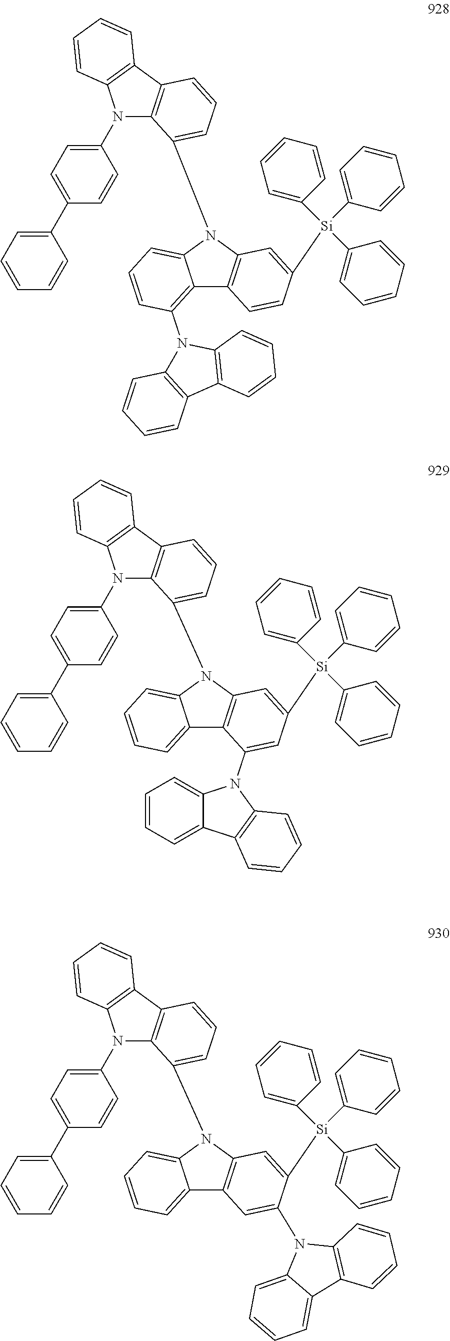 [SMILES: c1ccc(-c2ccc(-n3c4ccccc4c4cccc(-n5c6cc([Si](c7ccccc7)(c7ccccc7)c7ccccc7)ccc6c6c(-n7c8ccccc8c8ccccc87)cccc65)c43)cc2)cc1 ; c1ccc(-c2ccc(-n3c4ccccc4c4cccc(-n5c6ccccc6c6c(-n7c8ccccc8c8ccccc87)cc([Si](c7ccccc7)(c7ccccc7)c7ccccc7)cc65)c43)cc2)cc1 ; c1ccc(-c2ccc(-n3c4ccccc4c4cccc(-n5c6ccccc6c6cc(-n7c8ccccc8c8ccccc87)c([Si](c7ccccc7)(c7ccccc7)c7ccccc7)cc65)c43)cc2)cc1]

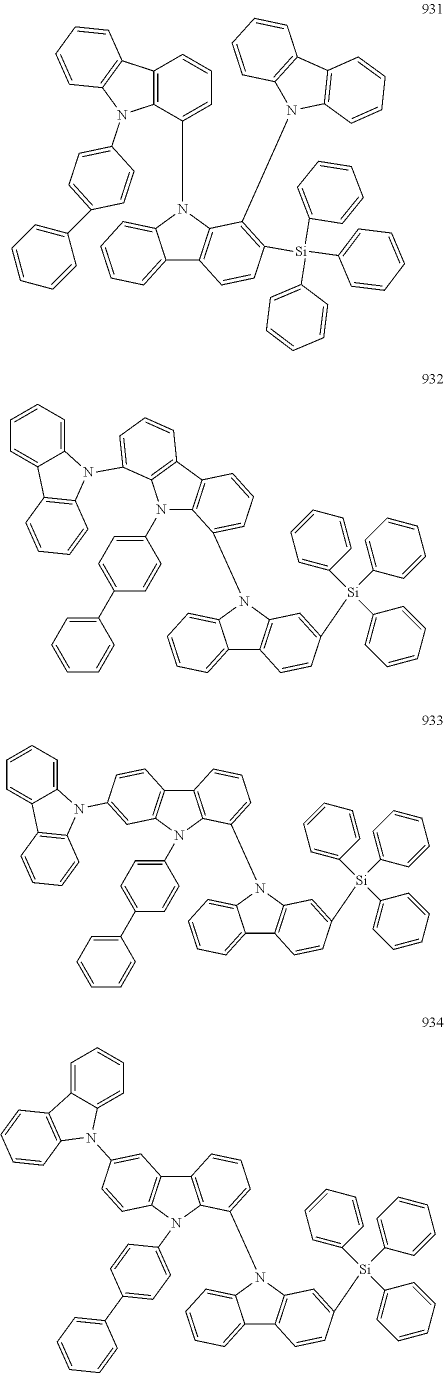 [SMILES: c1ccc(-c2ccc(-n3c4ccccc4c4cccc(-n5c6ccccc6c6ccc([Si](c7ccccc7)(c7ccccc7)c7ccccc7)c(-n7c8ccccc8c8ccccc87)c65)c43)cc2)cc1 ; c1ccc(-c2ccc(-n3c4c(-n5c6ccccc6c6ccccc65)cccc4c4cccc(-n5c6ccccc6c6ccc([Si](c7ccccc7)(c7ccccc7)c7ccccc7)cc65)c43)cc2)cc1 ; c1ccc(-c2ccc(-n3c4cc(-n5c6ccccc6c6ccccc65)ccc4c4cccc(-n5c6ccccc6c6ccc([Si](c7ccccc7)(c7ccccc7)c7ccccc7)cc65)c43)cc2)cc1 ; c1ccc(-c2ccc(-n3c4ccc(-n5c6ccccc6c6ccccc65)cc4c4cccc(-n5c6ccccc6c6ccc([Si](c7ccccc7)(c7ccccc7)c7ccccc7)cc65)c43)cc2)cc1]

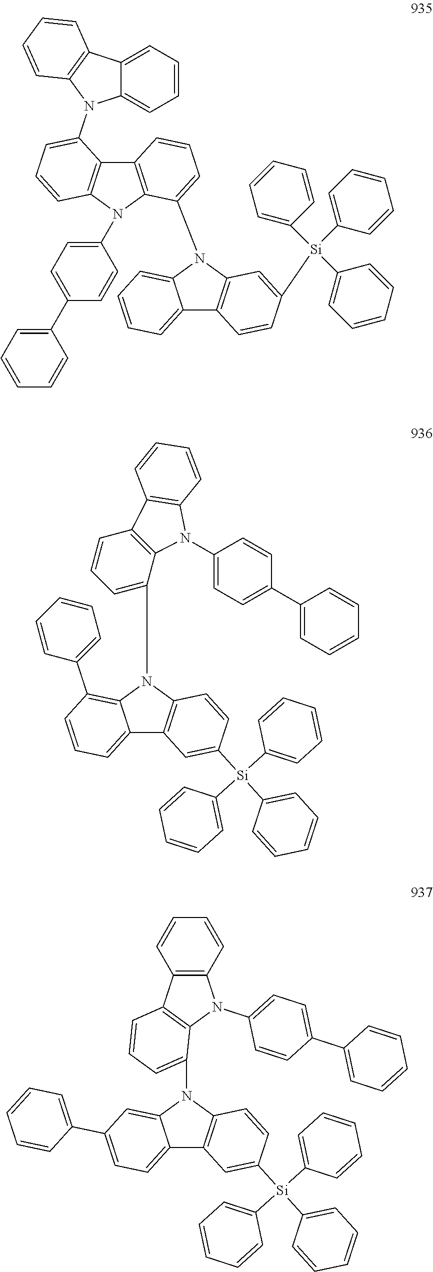 [SMILES: c1ccc(-c2ccc(-n3c4cccc(-n5c6ccccc6c6ccccc65)c4c4cccc(-n5c6ccccc6c6ccc([Si](c7ccccc7)(c7ccccc7)c7ccccc7)cc65)c43)cc2)cc1 ; c1ccc(-c2ccc(-n3c4ccccc4c4cccc(-n5c6ccc([Si](c7ccccc7)(c7ccccc7)c7ccccc7)cc6c6cccc(-c7ccccc7)c65)c43)cc2)cc1 ; c1ccc(-c2ccc(-n3c4ccccc4c4cccc(-n5c6ccc([Si](c7ccccc7)(c7ccccc7)c7ccccc7)cc6c6ccc(-c7ccccc7)cc65)c43)cc2)cc1]

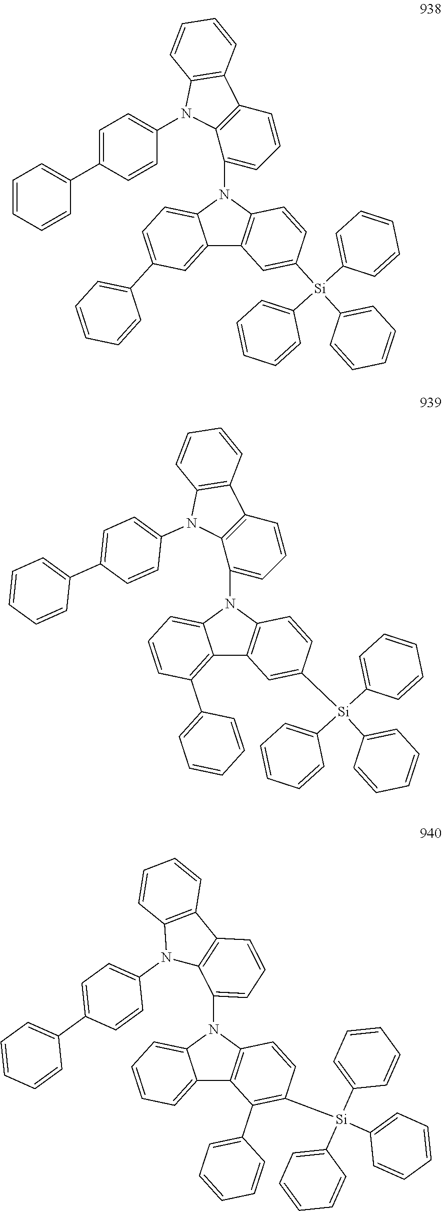 [SMILES: c1ccc(-c2ccc(-n3c4ccccc4c4cccc(-n5c6ccc(-c7ccccc7)cc6c6cc([Si](c7ccccc7)(c7ccccc7)c7ccccc7)ccc65)c43)cc2)cc1 ; c1ccc(-c2ccc(-n3c4ccccc4c4cccc(-n5c6ccc([Si](c7ccccc7)(c7ccccc7)c7ccccc7)cc6c6c(-c7ccccc7)cccc65)c43)cc2)cc1 ; c1ccc(-c2ccc(-n3c4ccccc4c4cccc(-n5c6ccccc6c6c(-c7ccccc7)c([Si](c7ccccc7)(c7ccccc7)c7ccccc7)ccc65)c43)cc2)cc1]

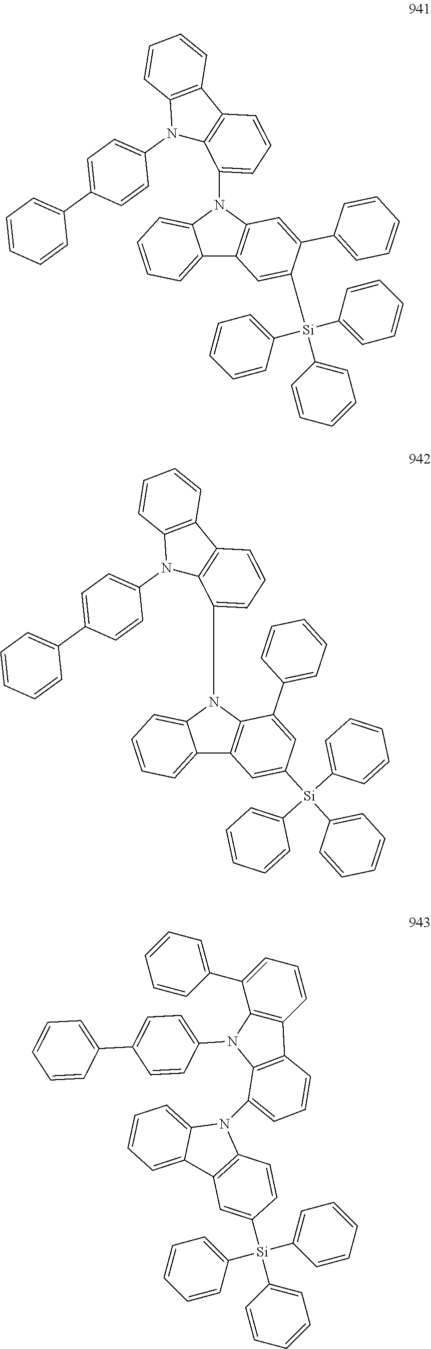 [SMILES: c1ccc(-c2ccc(-n3c4ccccc4c4cccc(-n5c6ccccc6c6cc([Si](c7ccccc7)(c7ccccc7)c7ccccc7)c(-c7ccccc7)cc65)c43)cc2)cc1 ; c1ccc(-c2ccc(-n3c4ccccc4c4cccc(-n5c6ccccc6c6cc([Si](c7ccccc7)(c7ccccc7)c7ccccc7)cc(-c7ccccc7)c65)c43)cc2)cc1 ; c1ccc(-c2ccc(-n3c4c(-c5ccccc5)cccc4c4cccc(-n5c6ccccc6c6cc([Si](c7ccccc7)(c7ccccc7)c7ccccc7)ccc65)c43)cc2)cc1]

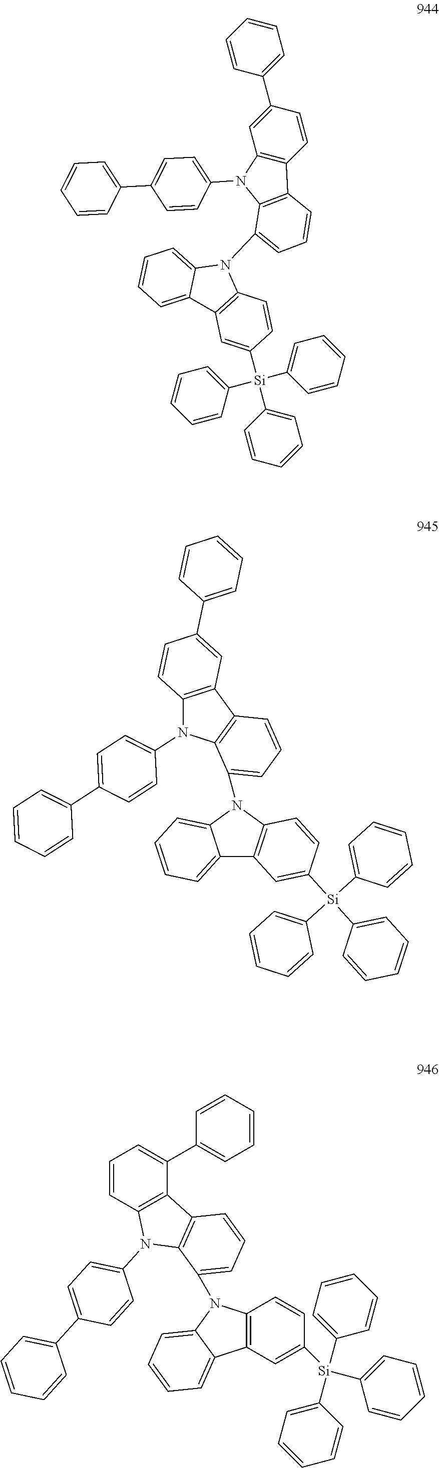 [SMILES: c1ccc(-c2ccc(-n3c4cc(-c5ccccc5)ccc4c4cccc(-n5c6ccccc6c6cc([Si](c7ccccc7)(c7ccccc7)c7ccccc7)ccc65)c43)cc2)cc1 ; c1ccc(-c2ccc(-n3c4ccc(-c5ccccc5)cc4c4cccc(-n5c6ccccc6c6cc([Si](c7ccccc7)(c7ccccc7)c7ccccc7)ccc65)c43)cc2)cc1 ; c1ccc(-c2ccc(-n3c4cccc(-c5ccccc5)c4c4cccc(-n5c6ccccc6c6cc([Si](c7ccccc7)(c7ccccc7)c7ccccc7)ccc65)c43)cc2)cc1]

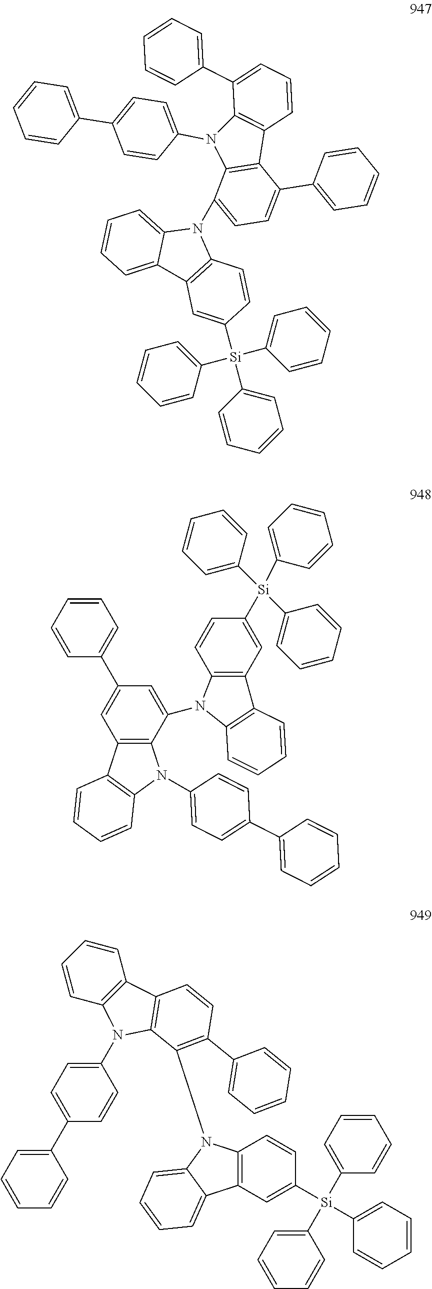 [SMILES: c1ccc(-c2ccc(-n3c4c(-c5ccccc5)cccc4c4c(-c5ccccc5)ccc(-n5c6ccccc6c6cc([Si](c7ccccc7)(c7ccccc7)c7ccccc7)ccc65)c43)cc2)cc1 ; c1ccc(-c2ccc(-n3c4ccccc4c4cc(-c5ccccc5)cc(-n5c6ccccc6c6cc([Si](c7ccccc7)(c7ccccc7)c7ccccc7)ccc65)c43)cc2)cc1 ; c1ccc(-c2ccc(-n3c4ccccc4c4ccc(-c5ccccc5)c(-n5c6ccccc6c6cc([Si](c7ccccc7)(c7ccccc7)c7ccccc7)ccc65)c43)cc2)cc1]

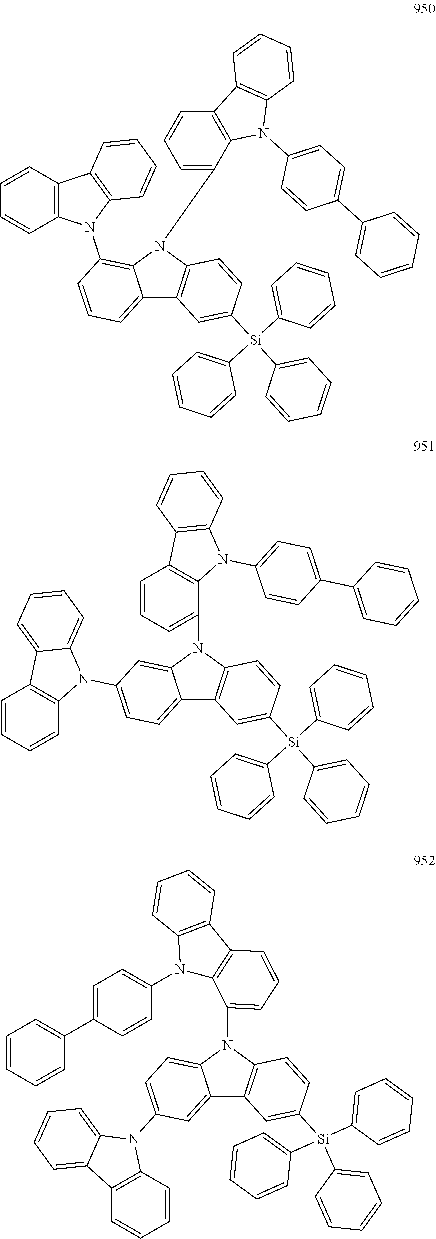 [SMILES: c1ccc(-c2ccc(-n3c4ccccc4c4cccc(-n5c6ccc([Si](c7ccccc7)(c7ccccc7)c7ccccc7)cc6c6cccc(-n7c8ccccc8c8ccccc87)c65)c43)cc2)cc1 ; c1ccc(-c2ccc(-n3c4ccccc4c4cccc(-n5c6ccc([Si](c7ccccc7)(c7ccccc7)c7ccccc7)cc6c6ccc(-n7c8ccccc8c8ccccc87)cc65)c43)cc2)cc1 ; c1ccc(-c2ccc(-n3c4ccccc4c4cccc(-n5c6ccc(-n7c8ccccc8c8ccccc87)cc6c6cc([Si](c7ccccc7)(c7ccccc7)c7ccccc7)ccc65)c43)cc2)cc1]

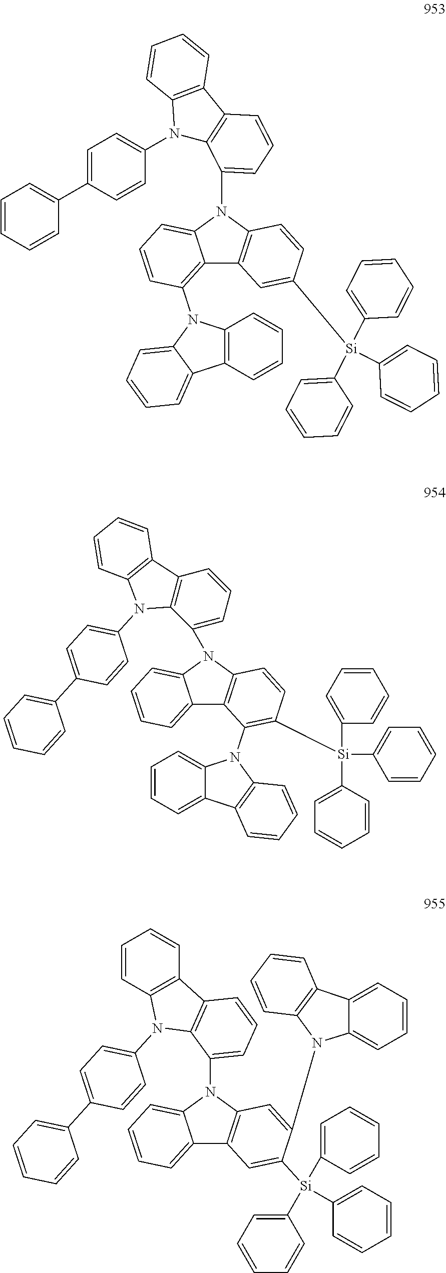 [SMILES: c1ccc(-c2ccc(-n3c4ccccc4c4cccc(-n5c6ccc([Si](c7ccccc7)(c7ccccc7)c7ccccc7)cc6c6c(-n7c8ccccc8c8ccccc87)cccc65)c43)cc2)cc1 ; c1ccc(-c2ccc(-n3c4ccccc4c4cccc(-n5c6ccccc6c6c(-n7c8ccccc8c8ccccc87)c([Si](c7ccccc7)(c7ccccc7)c7ccccc7)ccc65)c43)cc2)cc1 ; c1ccc(-c2ccc(-n3c4ccccc4c4cccc(-n5c6ccccc6c6cc([Si](c7ccccc7)(c7ccccc7)c7ccccc7)c(-n7c8ccccc8c8ccccc87)cc65)c43)cc2)cc1]

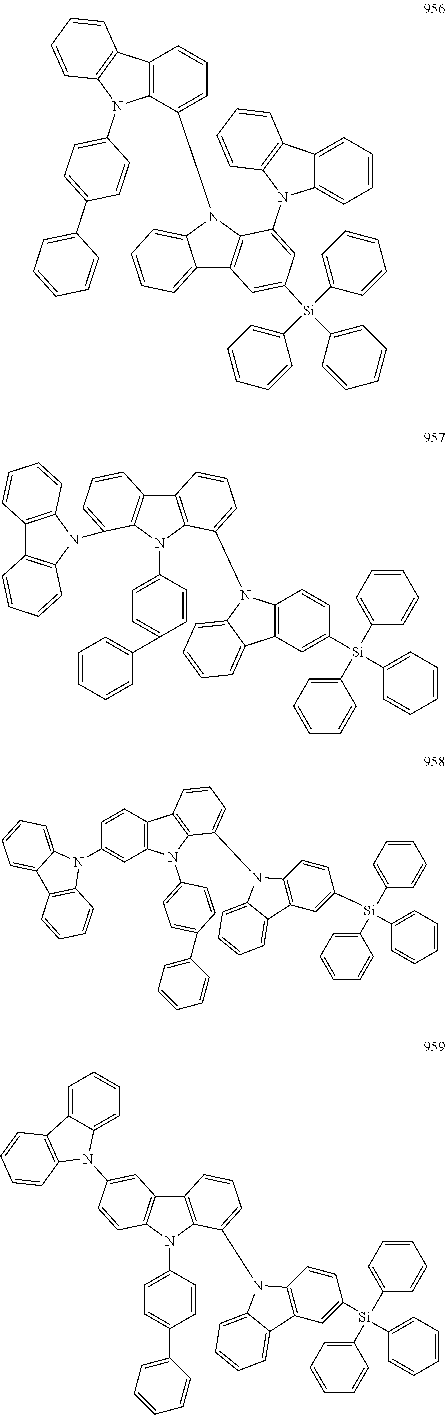 [SMILES: c1ccc(-c2ccc(-n3c4ccccc4c4cccc(-n5c6ccccc6c6cc([Si](c7ccccc7)(c7ccccc7)c7ccccc7)cc(-n7c8ccccc8c8ccccc87)c65)c43)cc2)cc1 ; c1ccc(-c2ccc(-n3c4c(-n5c6ccccc6c6ccccc65)cccc4c4cccc(-n5c6ccccc6c6cc([Si](c7ccccc7)(c7ccccc7)c7ccccc7)ccc65)c43)cc2)cc1 ; c1ccc(-c2ccc(-n3c4cc(-n5c6ccccc6c6ccccc65)ccc4c4cccc(-n5c6ccccc6c6cc([Si](c7ccccc7)(c7ccccc7)c7ccccc7)ccc65)c43)cc2)cc1 ; c1ccc(-c2ccc(-n3c4ccc(-n5c6ccccc6c6ccccc65)cc4c4cccc(-n5c6ccccc6c6cc([Si](c7ccccc7)(c7ccccc7)c7ccccc7)ccc65)c43)cc2)cc1]

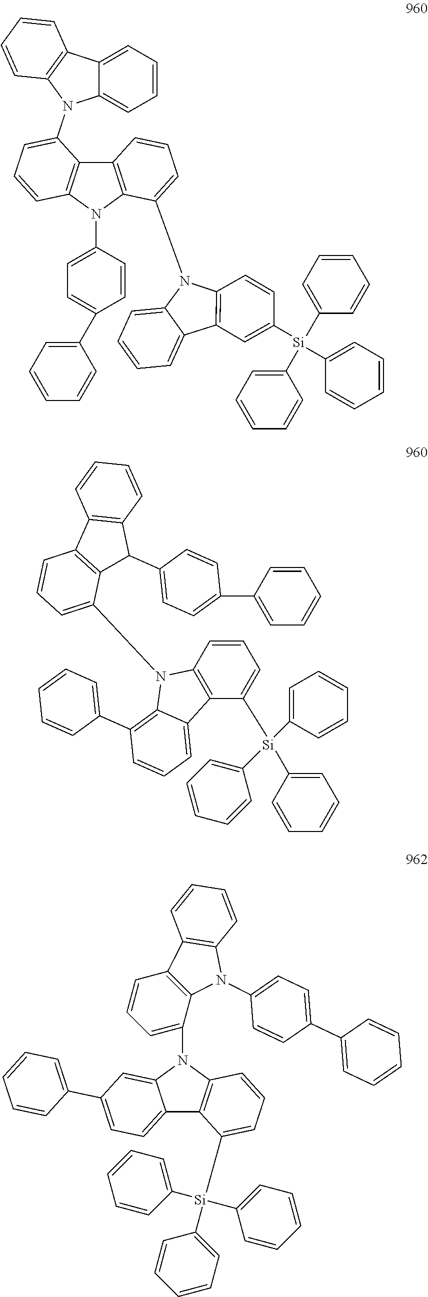 [SMILES: c1ccc(-c2ccc(-n3c4cccc(-n5c6ccccc6c6ccccc65)c4c4cccc(-n5c6ccccc6c6cc([Si](c7ccccc7)(c7ccccc7)c7ccccc7)ccc65)c43)cc2)cc1 ; c1ccc(-c2ccc(C3c4ccccc4-c4cccc(-n5c6cccc([Si](c7ccccc7)(c7ccccc7)c7ccccc7)c6c6cccc(-c7ccccc7)c65)c43)cc2)cc1 ; c1ccc(-c2ccc(-n3c4ccccc4c4cccc(-n5c6cc(-c7ccccc7)ccc6c6c([Si](c7ccccc7)(c7ccccc7)c7ccccc7)cccc65)c43)cc2)cc1]

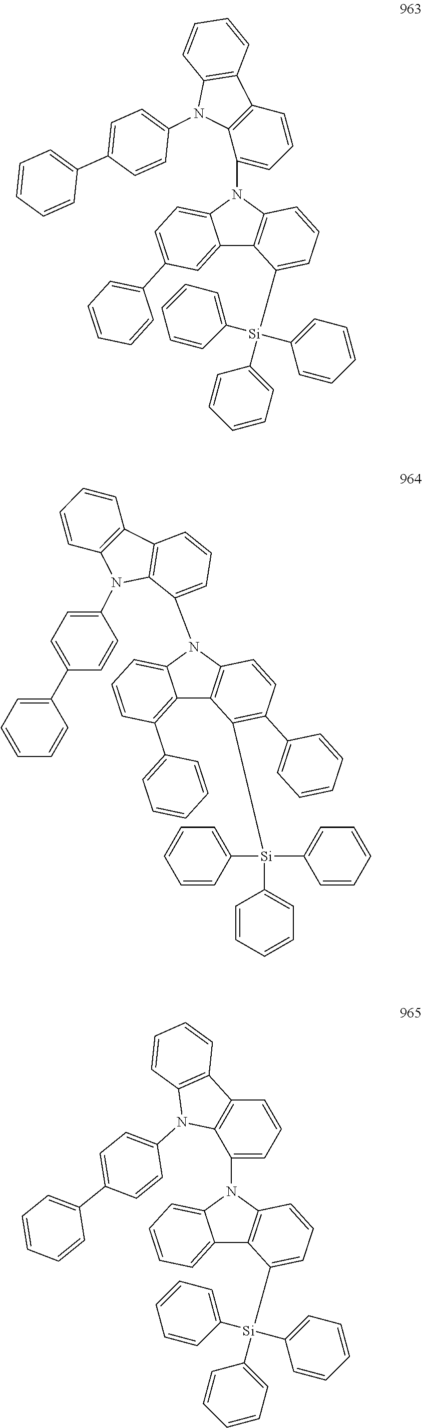 [SMILES: c1ccc(-c2ccc(-n3c4ccccc4c4cccc(-n5c6ccc(-c7ccccc7)cc6c6c([Si](c7ccccc7)(c7ccccc7)c7ccccc7)cccc65)c43)cc2)cc1 ; c1ccc(-c2ccc(-n3c4ccccc4c4cccc(-n5c6cccc(-c7ccccc7)c6c6c([Si](c7ccccc7)(c7ccccc7)c7ccccc7)c(-c7ccccc7)ccc65)c43)cc2)cc1 ; c1ccc(-c2ccc(-n3c4ccccc4c4cccc(-n5c6ccccc6c6c([Si](c7ccccc7)(c7ccccc7)c7ccccc7)cccc65)c43)cc2)cc1]

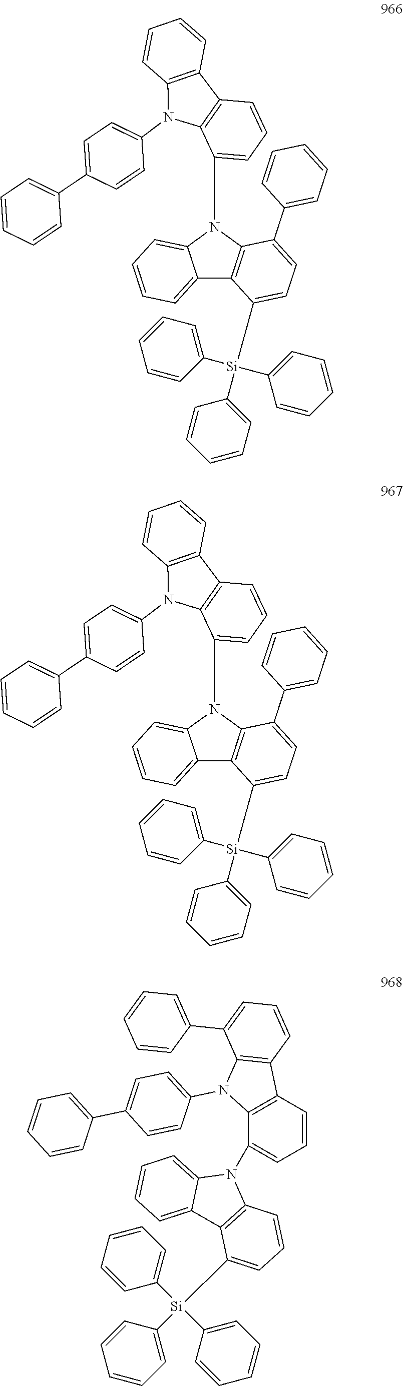 [SMILES: c1ccc(-c2ccc(-n3c4ccccc4c4cccc(-n5c6ccccc6c6c([Si](c7ccccc7)(c7ccccc7)c7ccccc7)ccc(-c7ccccc7)c65)c43)cc2)cc1 ; c1ccc(-c2ccc(-n3c4ccccc4c4cccc(-n5c6ccccc6c6c([Si](c7ccccc7)(c7ccccc7)c7ccccc7)ccc(-c7ccccc7)c65)c43)cc2)cc1 ; c1ccc(-c2ccc(-n3c4c(-c5ccccc5)cccc4c4cccc(-n5c6ccccc6c6c([Si](c7ccccc7)(c7ccccc7)c7ccccc7)cccc65)c43)cc2)cc1]

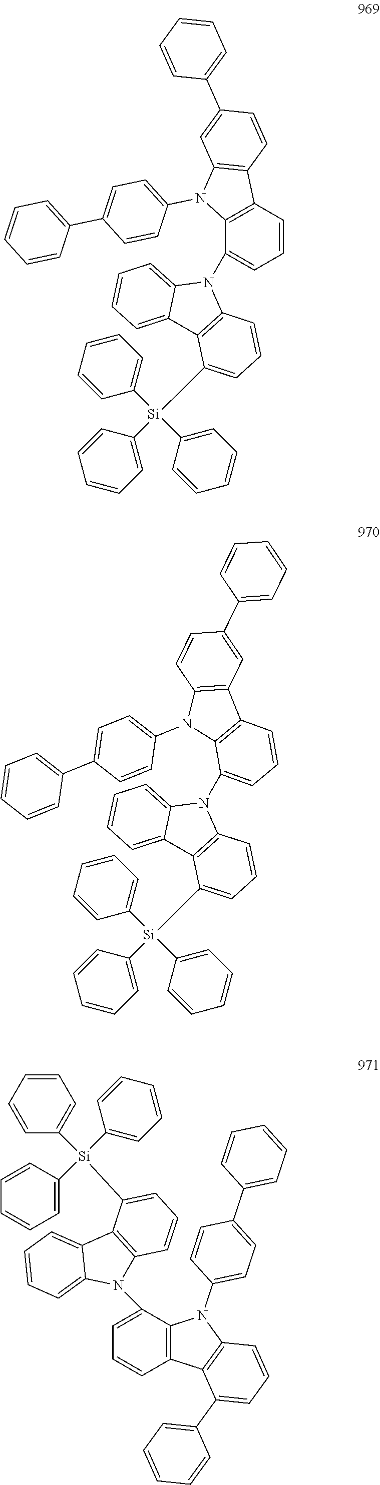 [SMILES: c1ccc(-c2ccc(-n3c4cc(-c5ccccc5)ccc4c4cccc(-n5c6ccccc6c6c([Si](c7ccccc7)(c7ccccc7)c7ccccc7)cccc65)c43)cc2)cc1 ; c1ccc(-c2ccc(-n3c4ccc(-c5ccccc5)cc4c4cccc(-n5c6ccccc6c6c([Si](c7ccccc7)(c7ccccc7)c7ccccc7)cccc65)c43)cc2)cc1 ; c1ccc(-c2ccc(-n3c4cccc(-c5ccccc5)c4c4cccc(-n5c6ccccc6c6c([Si](c7ccccc7)(c7ccccc7)c7ccccc7)cccc65)c43)cc2)cc1]

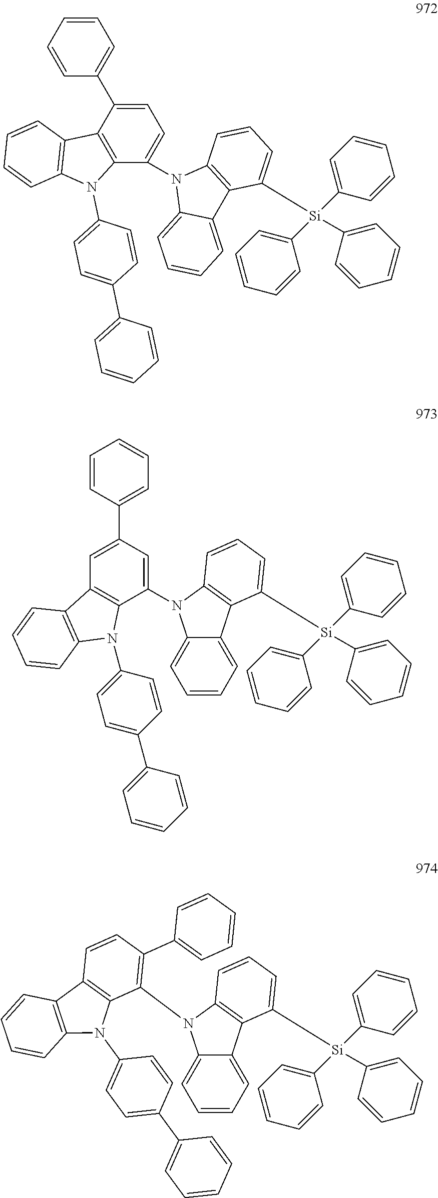 [SMILES: c1ccc(-c2ccc(-n3c4ccccc4c4c(-c5ccccc5)ccc(-n5c6ccccc6c6c([Si](c7ccccc7)(c7ccccc7)c7ccccc7)cccc65)c43)cc2)cc1 ; c1ccc(-c2ccc(-n3c4ccccc4c4cc(-c5ccccc5)cc(-n5c6ccccc6c6c([Si](c7ccccc7)(c7ccccc7)c7ccccc7)cccc65)c43)cc2)cc1 ; c1ccc(-c2ccc(-n3c4ccccc4c4ccc(-c5ccccc5)c(-n5c6ccccc6c6c([Si](c7ccccc7)(c7ccccc7)c7ccccc7)cccc65)c43)cc2)cc1]

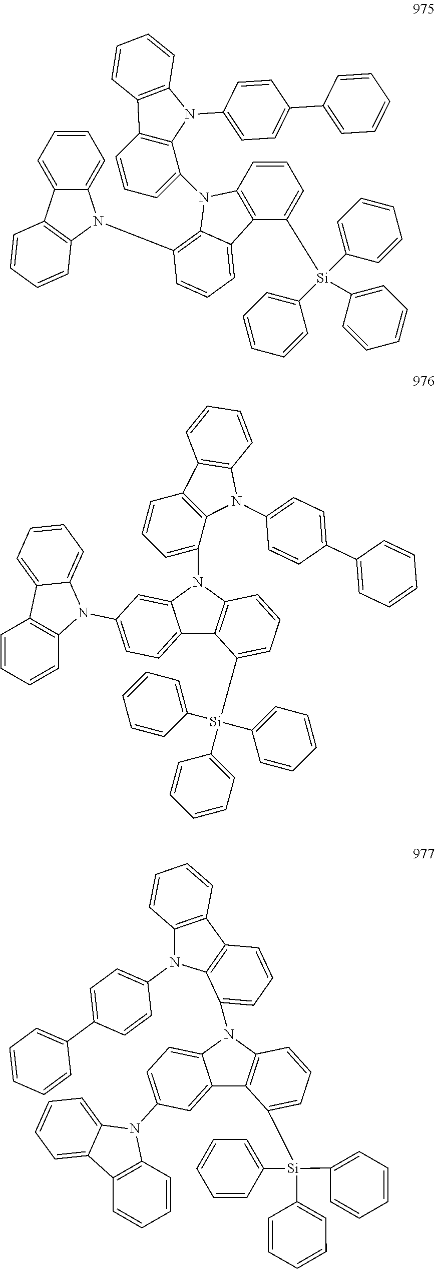

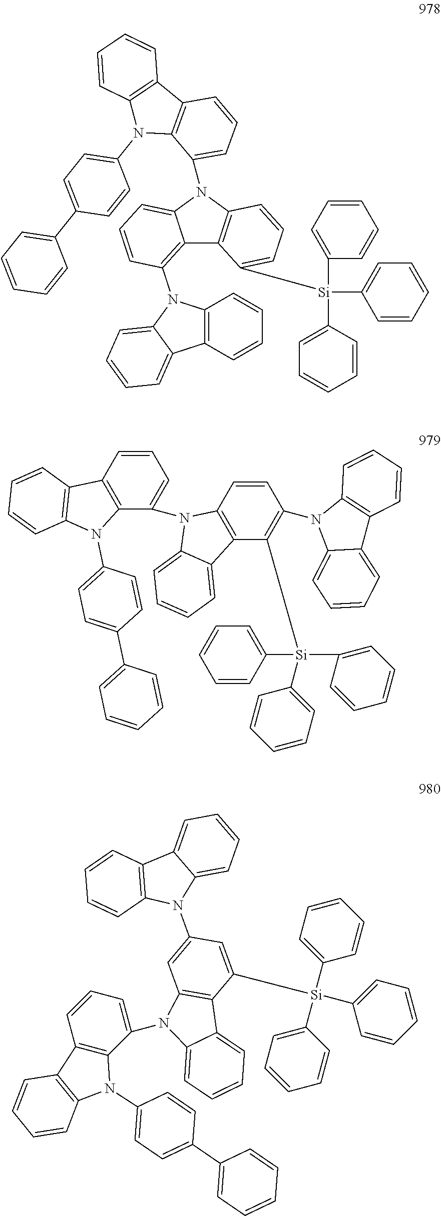 [SMILES: c1ccc(-c2ccc(-n3c4ccccc4c4cccc(-n5c6cccc(-n7c8ccccc8c8ccccc87)c6c6c([Si](c7ccccc7)(c7ccccc7)c7ccccc7)cccc65)c43)cc2)cc1 ; c1ccc(-c2ccc(-n3c4ccccc4c4cccc(-n5c6ccccc6c6c([Si](c7ccccc7)(c7ccccc7)c7ccccc7)c(-n7c8ccccc8c8ccccc87)ccc65)c43)cc2)cc1 ; c1ccc(-c2ccc(-n3c4ccccc4c4cccc(-n5c6ccccc6c6c([Si](c7ccccc7)(c7ccccc7)c7ccccc7)cc(-n7c8ccccc8c8ccccc87)cc65)c43)cc2)cc1]

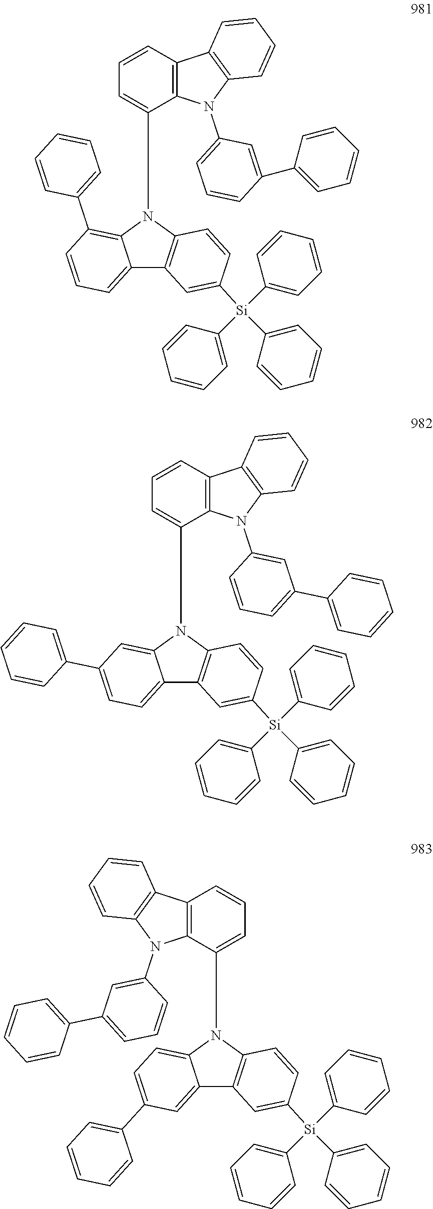

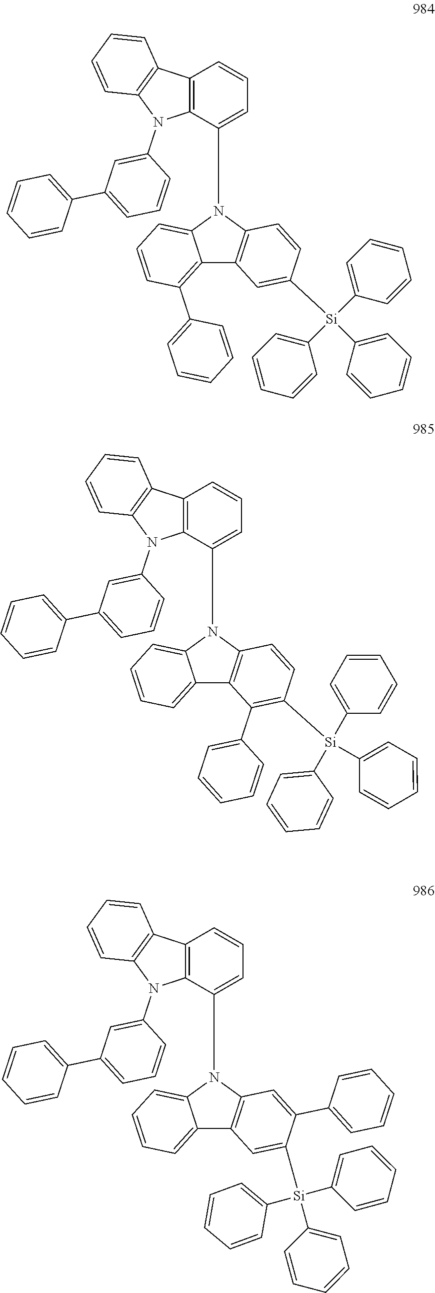 [SMILES: c1ccc(-c2cccc(-n3c4ccccc4c4cccc(-n5c6ccc([Si](c7ccccc7)(c7ccccc7)c7ccccc7)cc6c6c(-c7ccccc7)cccc65)c43)c2)cc1 ; c1ccc(-c2cccc(-n3c4ccccc4c4cccc(-n5c6ccccc6c6c(-c7ccccc7)c([Si](c7ccccc7)(c7ccccc7)c7ccccc7)ccc65)c43)c2)cc1 ; c1ccc(-c2cccc(-n3c4ccccc4c4cccc(-n5c6ccccc6c6cc([Si](c7ccccc7)(c7ccccc7)c7ccccc7)c(-c7ccccc7)cc65)c43)c2)cc1]

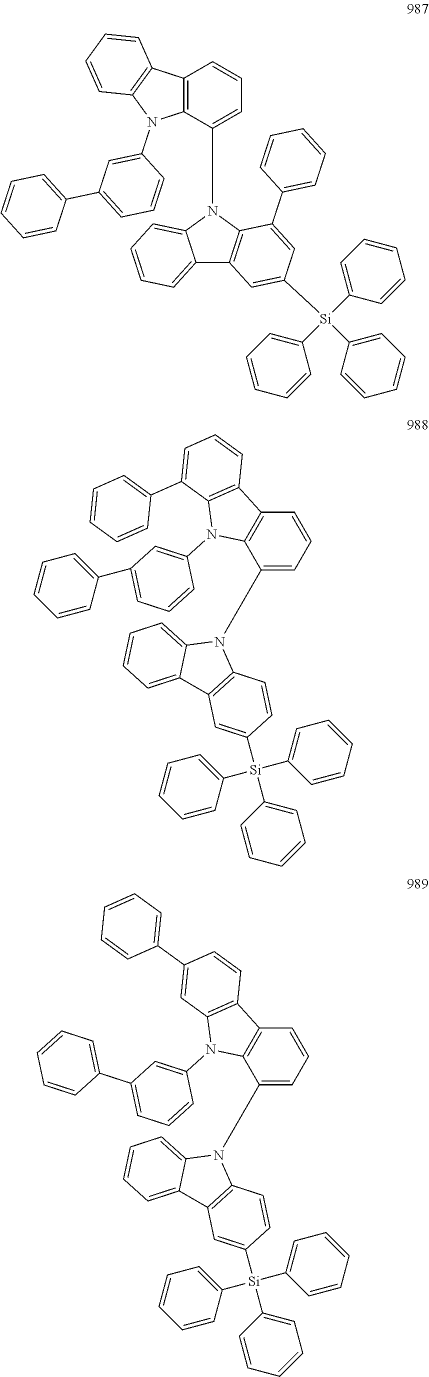 [SMILES: c1ccc(-c2cccc(-n3c4ccccc4c4cccc(-n5c6ccccc6c6cc([Si](c7ccccc7)(c7ccccc7)c7ccccc7)cc(-c7ccccc7)c65)c43)c2)cc1 ; c1ccc(-c2cccc(-n3c4c(-c5ccccc5)cccc4c4cccc(-n5c6ccccc6c6cc([Si](c7ccccc7)(c7ccccc7)c7ccccc7)ccc65)c43)c2)cc1 ; c1ccc(-c2cccc(-n3c4cc(-c5ccccc5)ccc4c4cccc(-n5c6ccccc6c6cc([Si](c7ccccc7)(c7ccccc7)c7ccccc7)ccc65)c43)c2)cc1]

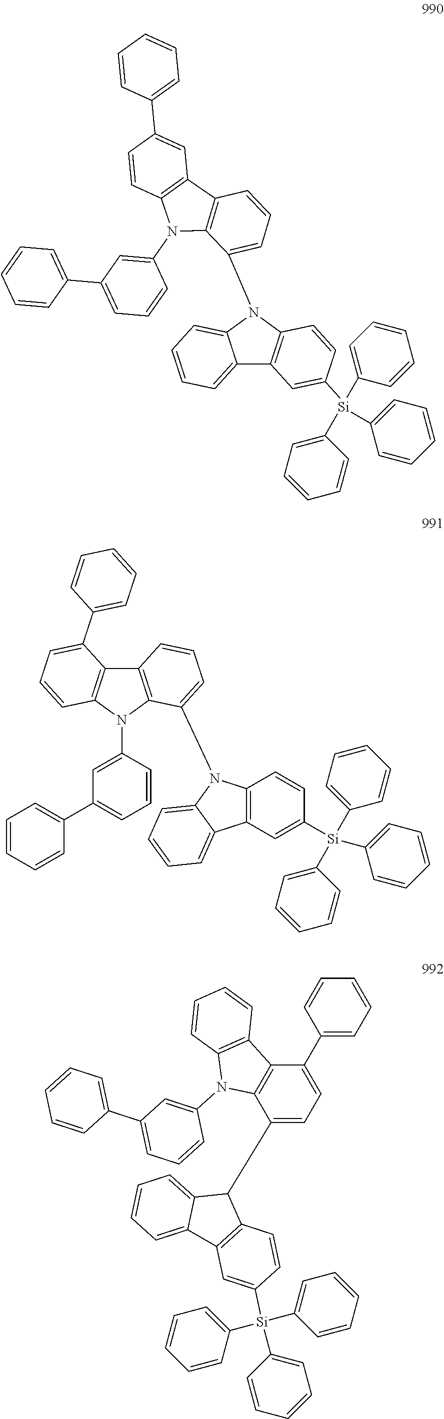 [SMILES: c1ccc(-c2cccc(-n3c4ccc(-c5ccccc5)cc4c4cccc(-n5c6ccccc6c6cc([Si](c7ccccc7)(c7ccccc7)c7ccccc7)ccc65)c43)c2)cc1 ; c1ccc(-c2cccc(-n3c4cccc(-c5ccccc5)c4c4cccc(-n5c6ccccc6c6cc([Si](c7ccccc7)(c7ccccc7)c7ccccc7)ccc65)c43)c2)cc1 ; c1ccc(-c2cccc(-n3c4ccccc4c4c(-c5ccccc5)ccc(C5c6ccccc6-c6cc([Si](c7ccccc7)(c7ccccc7)c7ccccc7)ccc65)c43)c2)cc1]

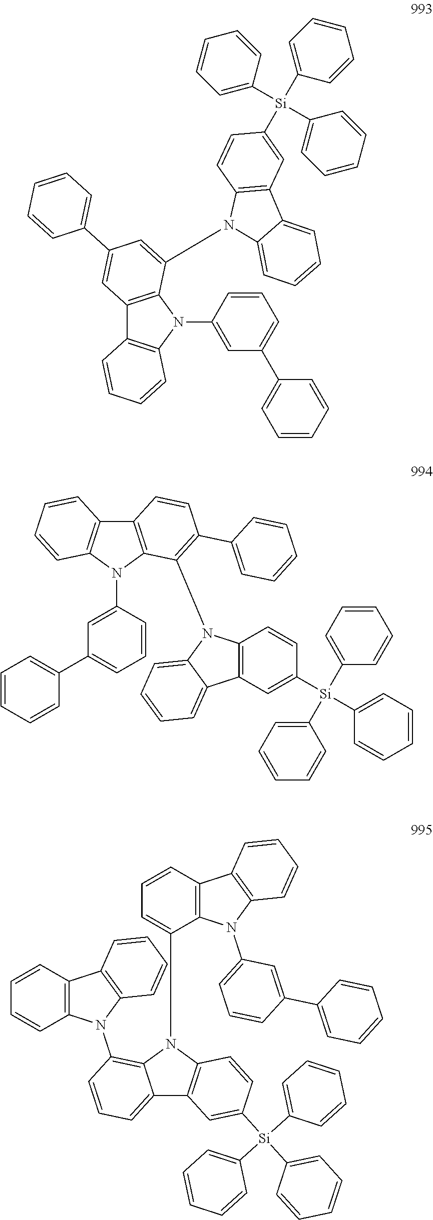 [SMILES: c1ccc(-c2cccc(-n3c4ccccc4c4cc(-c5ccccc5)cc(-n5c6ccccc6c6cc([Si](c7ccccc7)(c7ccccc7)c7ccccc7)ccc65)c43)c2)cc1 ; c1ccc(-c2cccc(-n3c4ccccc4c4ccc(-c5ccccc5)c(-n5c6ccccc6c6cc([Si](c7ccccc7)(c7ccccc7)c7ccccc7)ccc65)c43)c2)cc1 ; c1ccc(-c2cccc(-n3c4ccccc4c4cccc(-n5c6ccc([Si](c7ccccc7)(c7ccccc7)c7ccccc7)cc6c6cccc(-n7c8ccccc8c8ccccc87)c65)c43)c2)cc1]

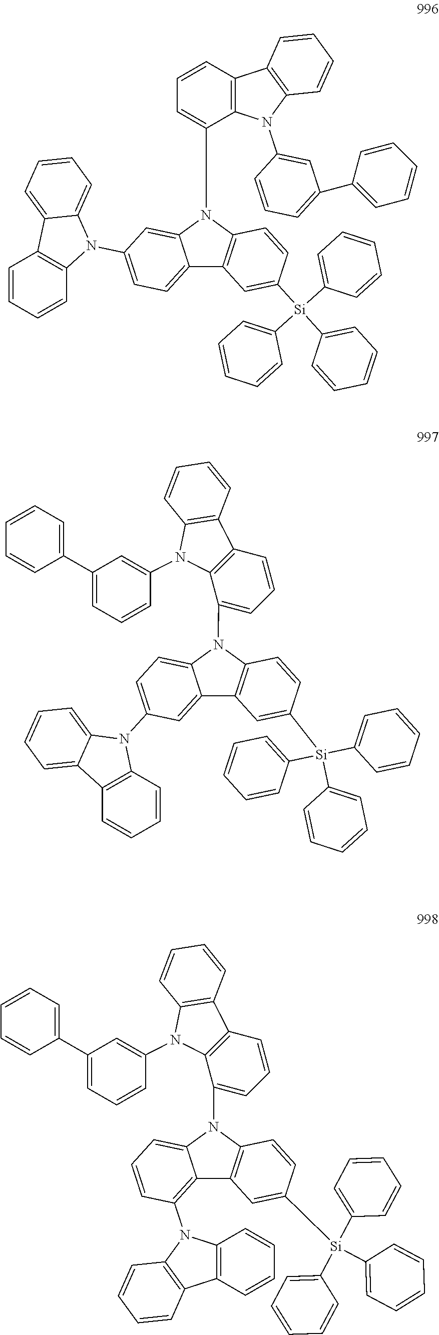 [SMILES: c1ccc(-c2cccc(-n3c4ccccc4c4cccc(-n5c6ccc([Si](c7ccccc7)(c7ccccc7)c7ccccc7)cc6c6ccc(-n7c8ccccc8c8ccccc87)cc65)c43)c2)cc1 ; c1ccc(-c2cccc(-n3c4ccccc4c4cccc(-n5c6ccc(-n7c8ccccc8c8ccccc87)cc6c6cc([Si](c7ccccc7)(c7ccccc7)c7ccccc7)ccc65)c43)c2)cc1 ; c1ccc(-c2cccc(-n3c4ccccc4c4cccc(-n5c6ccc([Si](c7ccccc7)(c7ccccc7)c7ccccc7)cc6c6c(-n7c8ccccc8c8ccccc87)cccc65)c43)c2)cc1]

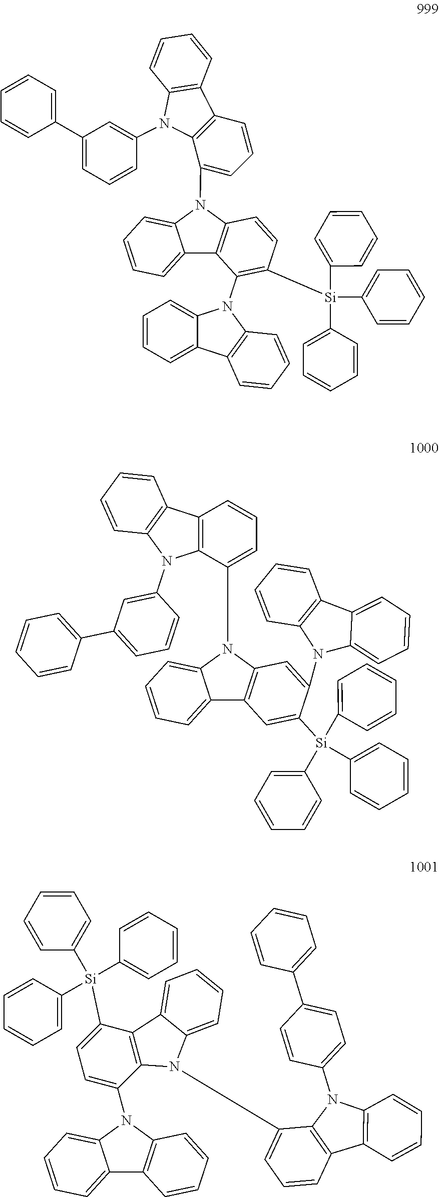 [SMILES: c1ccc(-c2cccc(-n3c4ccccc4c4cccc(-n5c6ccccc6c6c(-n7c8ccccc8c8ccccc87)c([Si](c7ccccc7)(c7ccccc7)c7ccccc7)ccc65)c43)c2)cc1 ; c1ccc(-c2cccc(-n3c4ccccc4c4cccc(-n5c6ccccc6c6cc([Si](c7ccccc7)(c7ccccc7)c7ccccc7)c(-n7c8ccccc8c8ccccc87)cc65)c43)c2)cc1 ; c1ccc(-c2ccc(-n3c4ccccc4c4cccc(-n5c6ccccc6c6c([Si](c7ccccc7)(c7ccccc7)c7ccccc7)ccc(-n7c8ccccc8c8ccccc87)c65)c43)cc2)cc1]

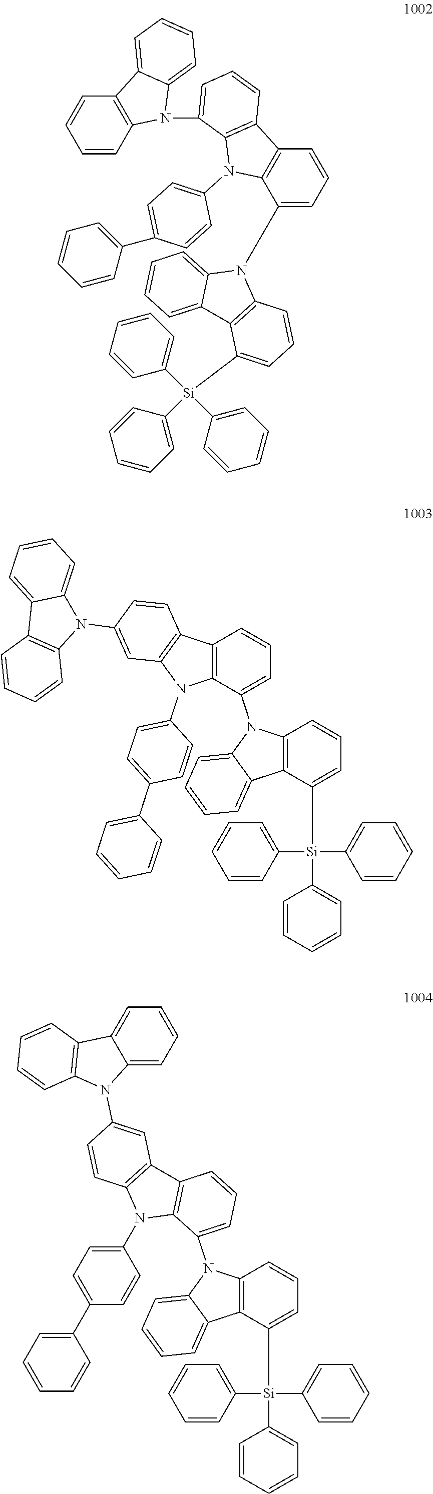 [SMILES: c1ccc(-c2ccc(-n3c4c(-n5c6ccccc6c6ccccc65)cccc4c4cccc(-n5c6ccccc6c6c([Si](c7ccccc7)(c7ccccc7)c7ccccc7)cccc65)c43)cc2)cc1 ; c1ccc(-c2ccc(-n3c4cc(-n5c6ccccc6c6ccccc65)ccc4c4cccc(-n5c6ccccc6c6c([Si](c7ccccc7)(c7ccccc7)c7ccccc7)cccc65)c43)cc2)cc1 ; c1ccc(-c2ccc(-n3c4ccc(-n5c6ccccc6c6ccccc65)cc4c4cccc(-n5c6ccccc6c6c([Si](c7ccccc7)(c7ccccc7)c7ccccc7)cccc65)c43)cc2)cc1]

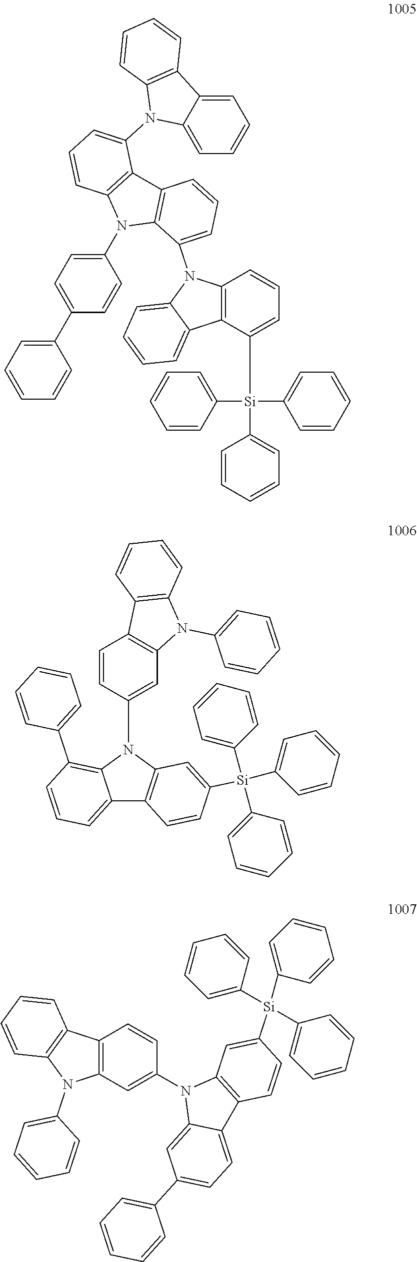 [SMILES: c1ccc(-c2ccc(-n3c4cccc(-n5c6ccccc6c6ccccc65)c4c4cccc(-n5c6ccccc6c6c([Si](c7ccccc7)(c7ccccc7)c7ccccc7)cccc65)c43)cc2)cc1 ; c1ccc(-c2cccc3c4ccc([Si](c5ccccc5)(c5ccccc5)c5ccccc5)cc4n(-c4ccc5c6ccccc6n(-c6ccccc6)c5c4)c23)cc1 ; c1ccc(-c2ccc3c4ccc([Si](c5ccccc5)(c5ccccc5)c5ccccc5)cc4n(-c4ccc5c6ccccc6n(-c6ccccc6)c5c4)c3c2)cc1]

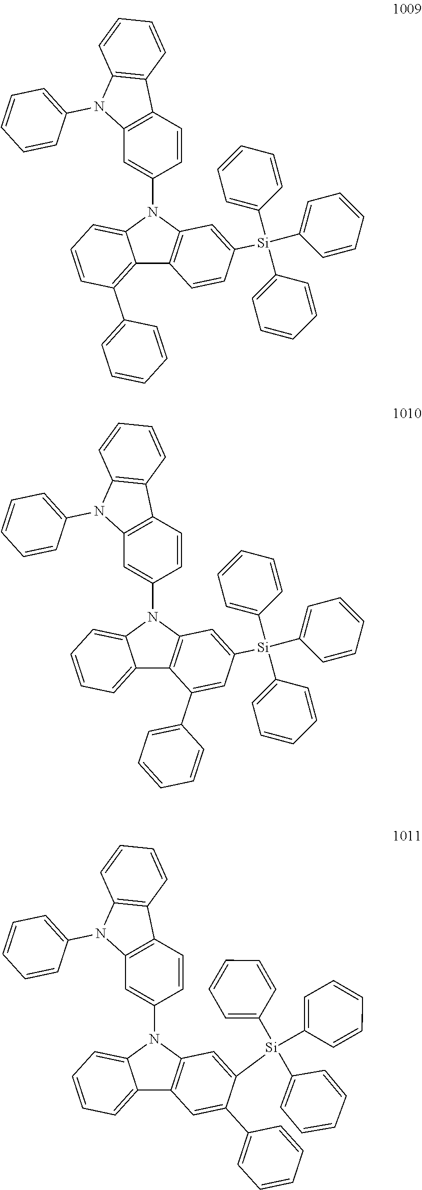

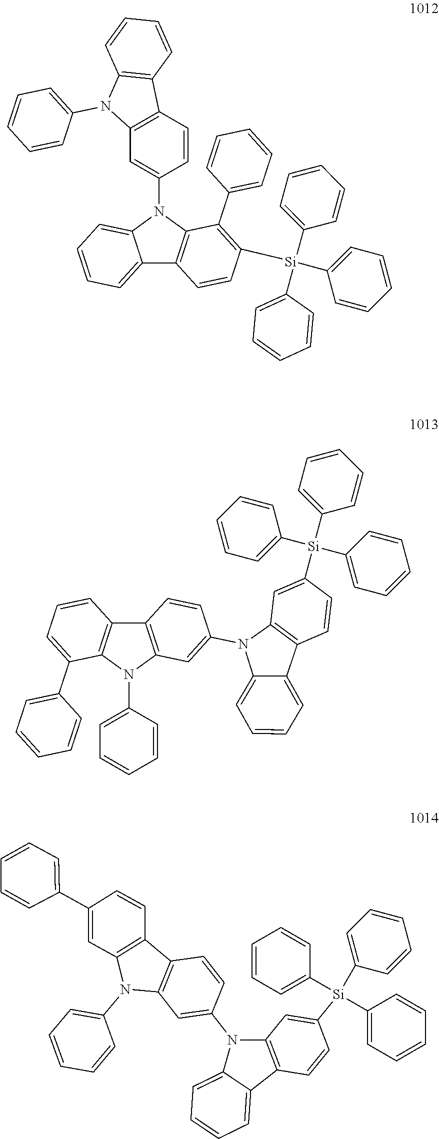 [SMILES: c1ccc(-c2c([Si](c3ccccc3)(c3ccccc3)c3ccccc3)ccc3c4ccccc4n(-c4ccc5c6ccccc6n(-c6ccccc6)c5c4)c23)cc1 ; c1ccc(-c2cccc3c4ccc(-n5c6ccccc6c6ccc([Si](c7ccccc7)(c7ccccc7)c7ccccc7)cc65)cc4n(-c4ccccc4)c23)cc1 ; c1ccc(-c2ccc3c4ccc(-n5c6ccccc6c6ccc([Si](c7ccccc7)(c7ccccc7)c7ccccc7)cc65)cc4n(-c4ccccc4)c3c2)cc1]

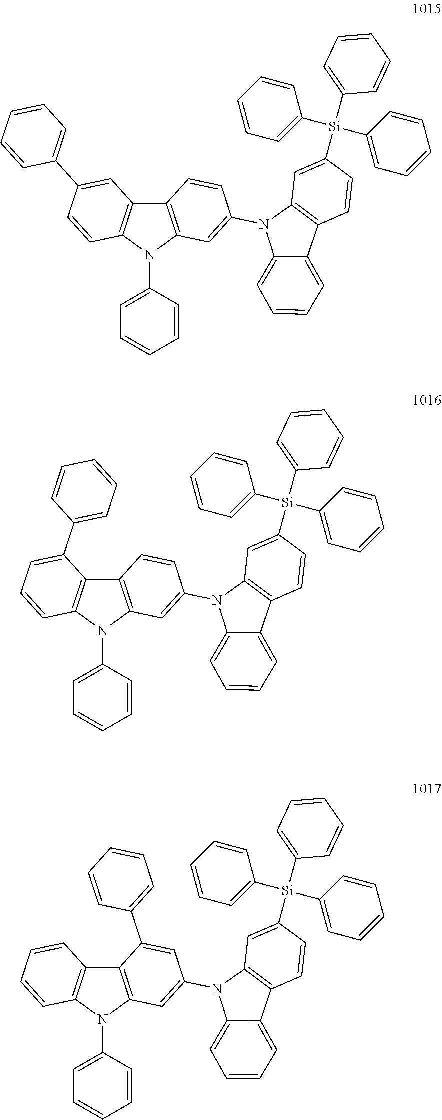 [SMILES: c1ccc(-c2ccc3c(c2)c2ccc(-n4c5ccccc5c5ccc([Si](c6ccccc6)(c6ccccc6)c6ccccc6)cc54)cc2n3-c2ccccc2)cc1 ; c1ccc(-c2cccc3c2c2ccc(-n4c5ccccc5c5ccc([Si](c6ccccc6)(c6ccccc6)c6ccccc6)cc54)cc2n3-c2ccccc2)cc1 ; c1ccc(-c2cc(-n3c4ccccc4c4ccc([Si](c5ccccc5)(c5ccccc5)c5ccccc5)cc43)cc3c2c2ccccc2n3-c2ccccc2)cc1]

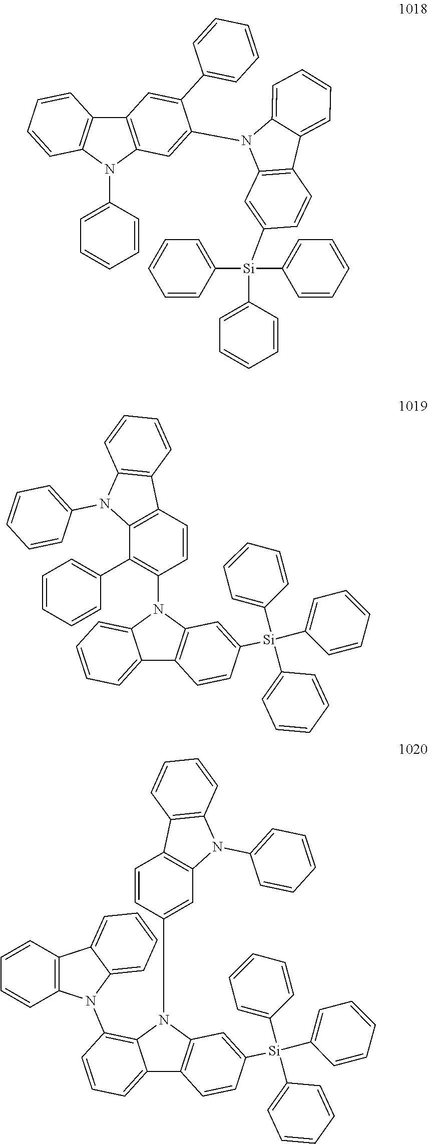 [SMILES: c1ccc(-c2cc3c4ccccc4n(-c4ccccc4)c3cc2-n2c3ccccc3c3ccc([Si](c4ccccc4)(c4ccccc4)c4ccccc4)cc32)cc1 ; c1ccc(-c2c(-n3c4ccccc4c4ccc([Si](c5ccccc5)(c5ccccc5)c5ccccc5)cc43)ccc3c4ccccc4n(-c4ccccc4)c23)cc1 ; c1ccc(-n2c3ccccc3c3ccc(-n4c5cc([Si](c6ccccc6)(c6ccccc6)c6ccccc6)ccc5c5cccc(-n6c7ccccc7c7ccccc76)c54)cc32)cc1]

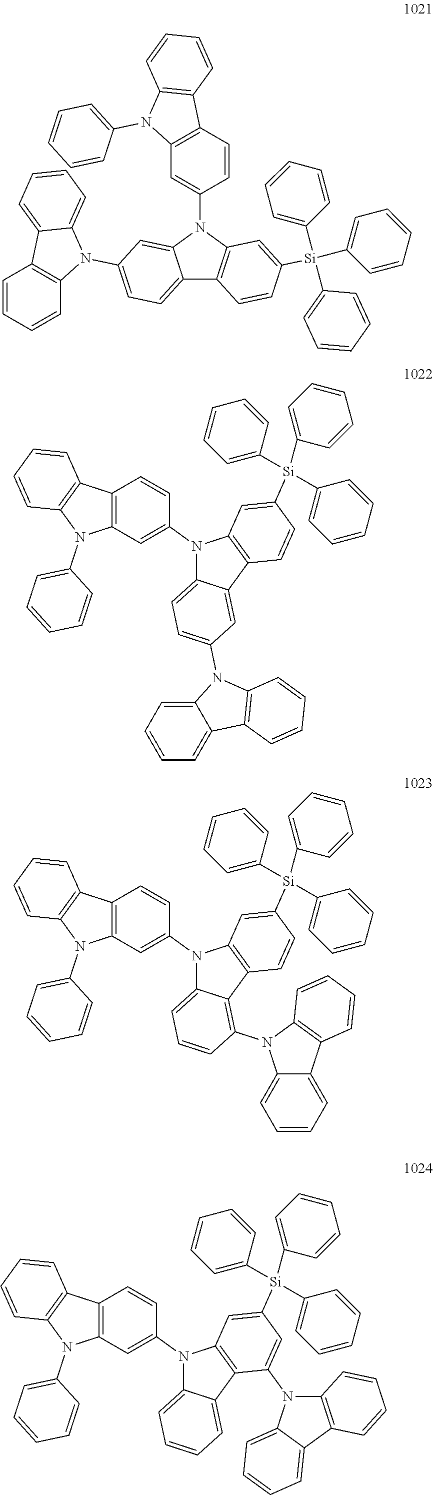

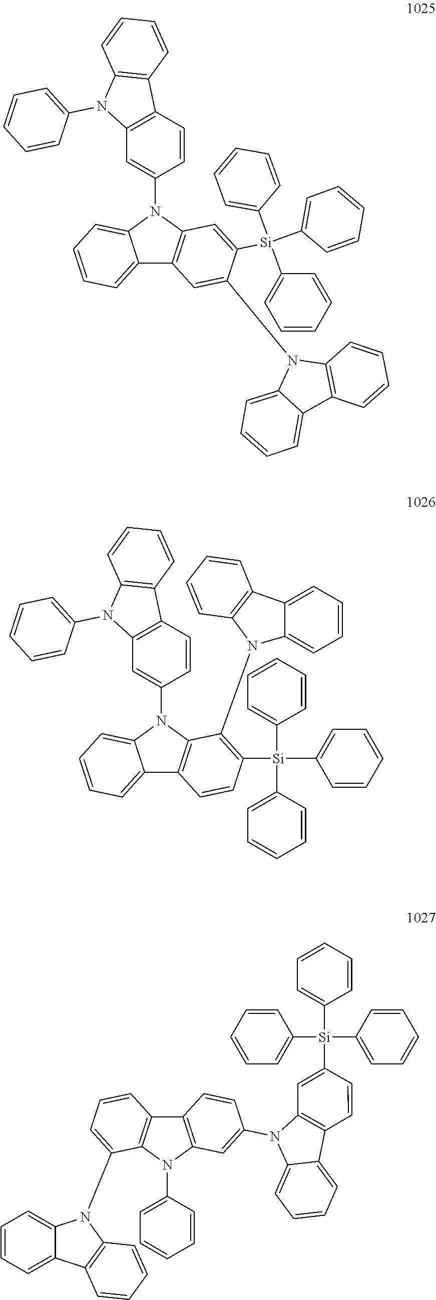 [SMILES: c1ccc(-n2c3ccccc3c3ccc(-n4c5ccccc5c5cc(-n6c7ccccc7c7ccccc76)c([Si](c6ccccc6)(c6ccccc6)c6ccccc6)cc54)cc32)cc1 ; c1ccc(-n2c3ccccc3c3ccc(-n4c5ccccc5c5ccc([Si](c6ccccc6)(c6ccccc6)c6ccccc6)c(-n6c7ccccc7c7ccccc76)c54)cc32)cc1 ; c1ccc(-n2c3cc(-n4c5ccccc5c5ccc([Si](c6ccccc6)(c6ccccc6)c6ccccc6)cc54)ccc3c3cccc(-n4c5ccccc5c5ccccc54)c32)cc1]

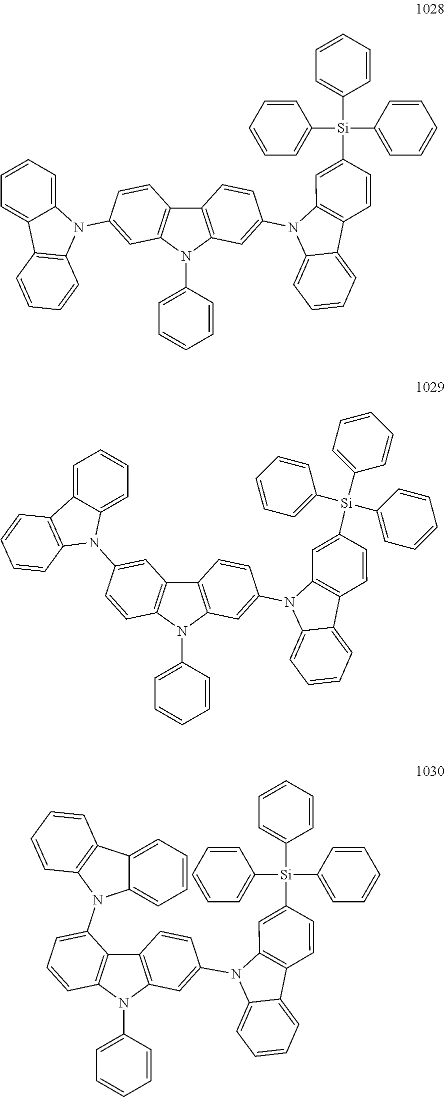 [SMILES: c1ccc(-n2c3cc(-n4c5ccccc5c5ccccc54)ccc3c3ccc(-n4c5ccccc5c5ccc([Si](c6ccccc6)(c6ccccc6)c6ccccc6)cc54)cc32)cc1 ; c1ccc(-n2c3ccc(-n4c5ccccc5c5ccccc54)cc3c3ccc(-n4c5ccccc5c5ccc([Si](c6ccccc6)(c6ccccc6)c6ccccc6)cc54)cc32)cc1 ; c1ccc(-n2c3cc(-n4c5ccccc5c5ccc([Si](c6ccccc6)(c6ccccc6)c6ccccc6)cc54)ccc3c3c(-n4c5ccccc5c5ccccc54)cccc32)cc1]

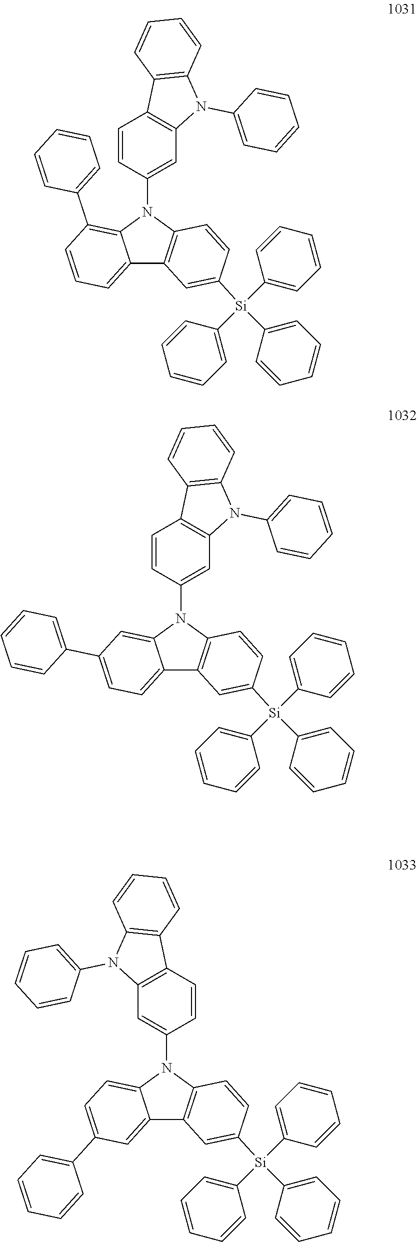

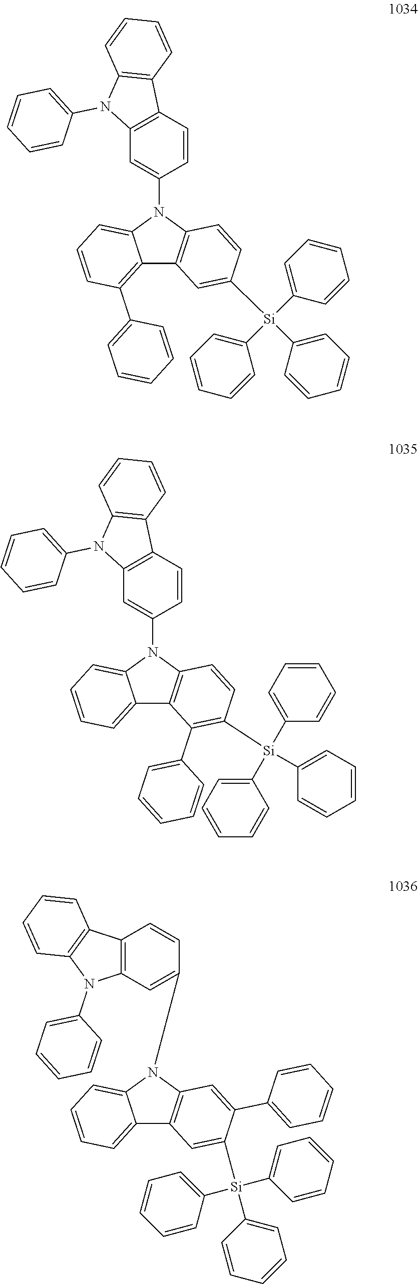 [SMILES: c1ccc(-c2cccc3c2c2cc([Si](c4ccccc4)(c4ccccc4)c4ccccc4)ccc2n3-c2ccc3c4ccccc4n(-c4ccccc4)c3c2)cc1 ; c1ccc(-c2c([Si](c3ccccc3)(c3ccccc3)c3ccccc3)ccc3c2c2ccccc2n3-c2ccc3c4ccccc4n(-c4ccccc4)c3c2)cc1 ; c1ccc(-c2cc3c(cc2[Si](c2ccccc2)(c2ccccc2)c2ccccc2)c2ccccc2n3-c2ccc3c4ccccc4n(-c4ccccc4)c3c2)cc1]

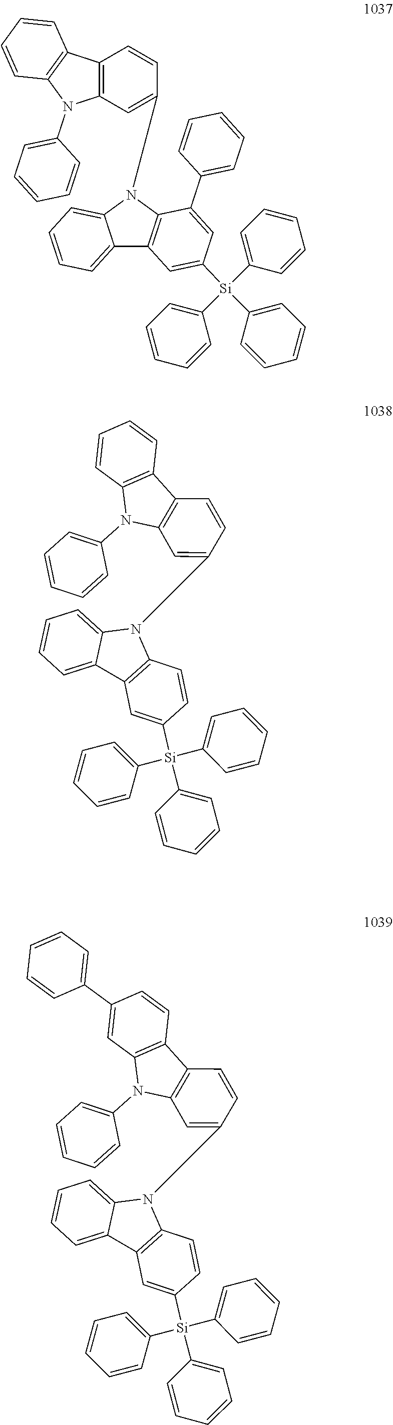 [SMILES: c1ccc(-c2cc([Si](c3ccccc3)(c3ccccc3)c3ccccc3)cc3c4ccccc4n(-c4ccc5c6ccccc6n(-c6ccccc6)c5c4)c23)cc1 ; c1ccc(-n2c3ccccc3c3ccc(-n4c5ccccc5c5cc([Si](c6ccccc6)(c6ccccc6)c6ccccc6)ccc54)cc32)cc1 ; c1ccc(-c2ccc3c4ccc(-n5c6ccccc6c6cc([Si](c7ccccc7)(c7ccccc7)c7ccccc7)ccc65)cc4n(-c4ccccc4)c3c2)cc1]

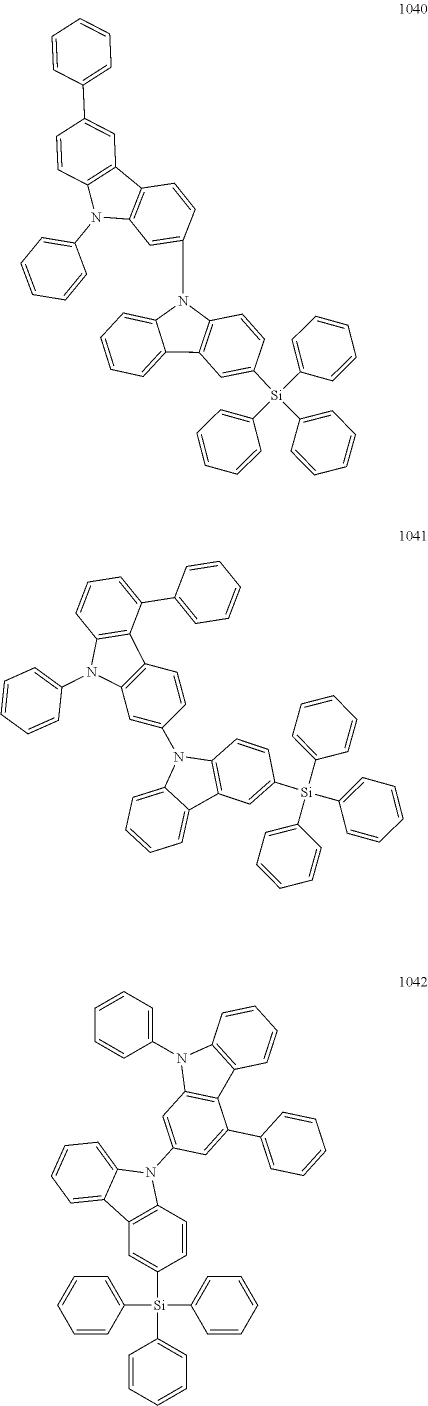 [SMILES: c1ccc(-c2ccc3c(c2)c2ccc(-n4c5ccccc5c5cc([Si](c6ccccc6)(c6ccccc6)c6ccccc6)ccc54)cc2n3-c2ccccc2)cc1 ; c1ccc(-c2cccc3c2c2ccc(-n4c5ccccc5c5cc([Si](c6ccccc6)(c6ccccc6)c6ccccc6)ccc54)cc2n3-c2ccccc2)cc1 ; c1ccc(-c2cc(-n3c4ccccc4c4cc([Si](c5ccccc5)(c5ccccc5)c5ccccc5)ccc43)cc3c2c2ccccc2n3-c2ccccc2)cc1]

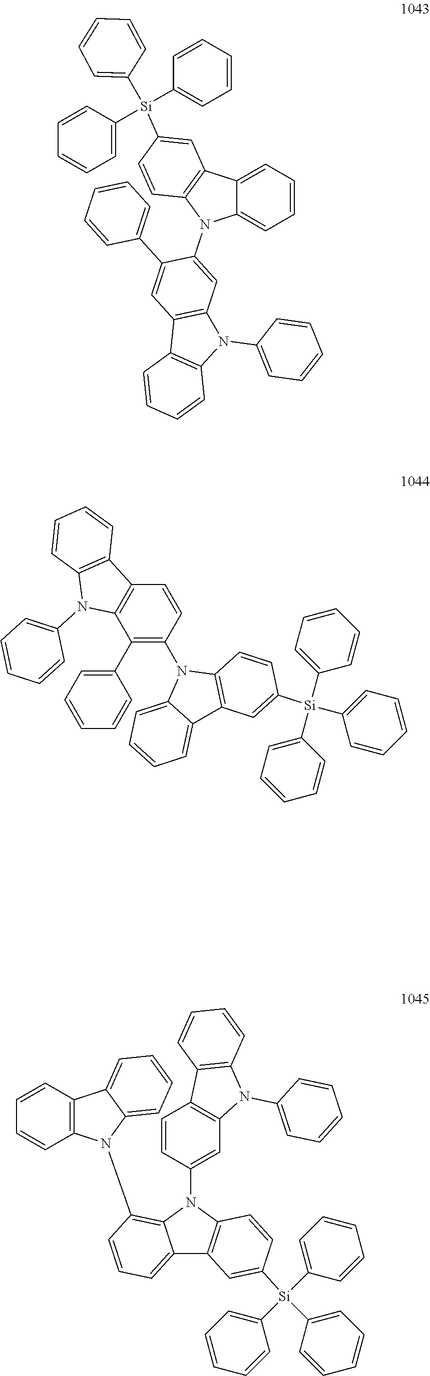 [SMILES: c1ccc(-c2cc3c4ccccc4n(-c4ccccc4)c3cc2-n2c3ccccc3c3cc([Si](c4ccccc4)(c4ccccc4)c4ccccc4)ccc32)cc1 ; c1ccc(-c2c(-n3c4ccccc4c4cc([Si](c5ccccc5)(c5ccccc5)c5ccccc5)ccc43)ccc3c4ccccc4n(-c4ccccc4)c23)cc1 ; c1ccc(-n2c3ccccc3c3ccc(-n4c5ccc([Si](c6ccccc6)(c6ccccc6)c6ccccc6)cc5c5cccc(-n6c7ccccc7c7ccccc76)c54)cc32)cc1]

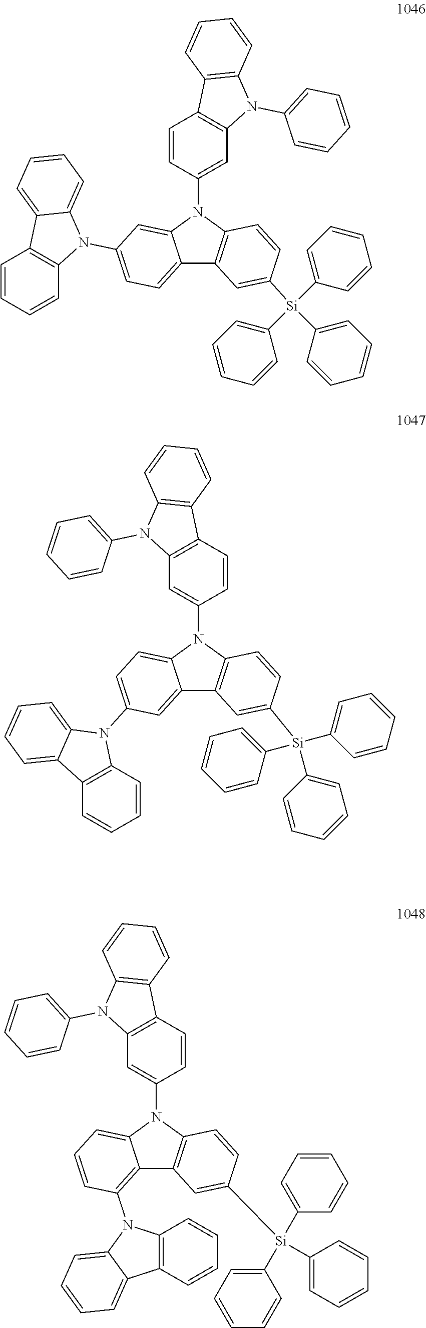 [SMILES: c1ccc(-n2c3ccccc3c3ccc(-n4c5ccc([Si](c6ccccc6)(c6ccccc6)c6ccccc6)cc5c5ccc(-n6c7ccccc7c7ccccc76)cc54)cc32)cc1 ; c1ccc(-n2c3ccccc3c3ccc(-n4c5ccc(-n6c7ccccc7c7ccccc76)cc5c5cc([Si](c6ccccc6)(c6ccccc6)c6ccccc6)ccc54)cc32)cc1 ; c1ccc(-n2c3ccccc3c3ccc(-n4c5ccc([Si](c6ccccc6)(c6ccccc6)c6ccccc6)cc5c5c(-n6c7ccccc7c7ccccc76)cccc54)cc32)cc1]

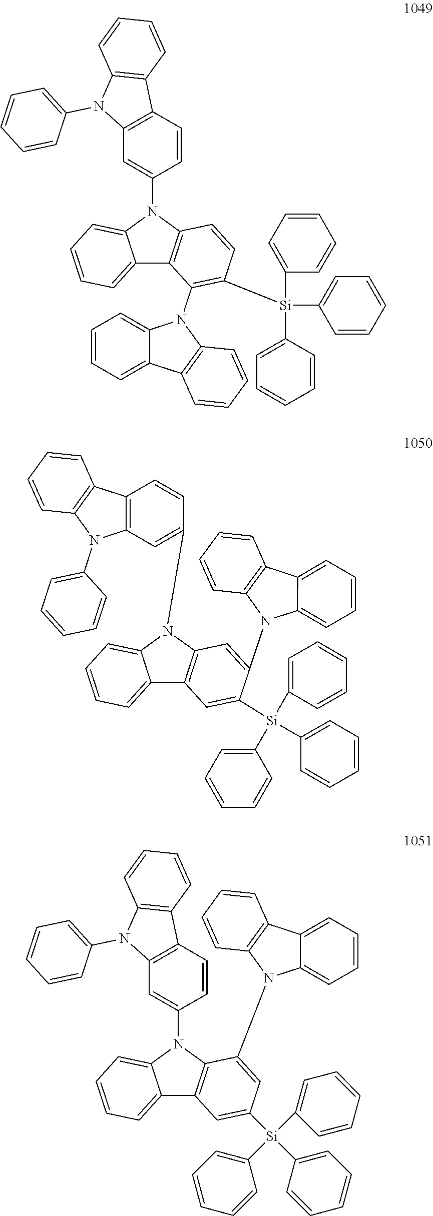 [SMILES: c1ccc(-n2c3ccccc3c3ccc(-n4c5ccccc5c5c(-n6c7ccccc7c7ccccc76)c([Si](c6ccccc6)(c6ccccc6)c6ccccc6)ccc54)cc32)cc1 ; c1ccc(-n2c3ccccc3c3ccc(-n4c5ccccc5c5cc([Si](c6ccccc6)(c6ccccc6)c6ccccc6)c(-n6c7ccccc7c7ccccc76)cc54)cc32)cc1 ; c1ccc(-n2c3ccccc3c3ccc(-n4c5ccccc5c5cc([Si](c6ccccc6)(c6ccccc6)c6ccccc6)cc(-n6c7ccccc7c7ccccc76)c54)cc32)cc1]

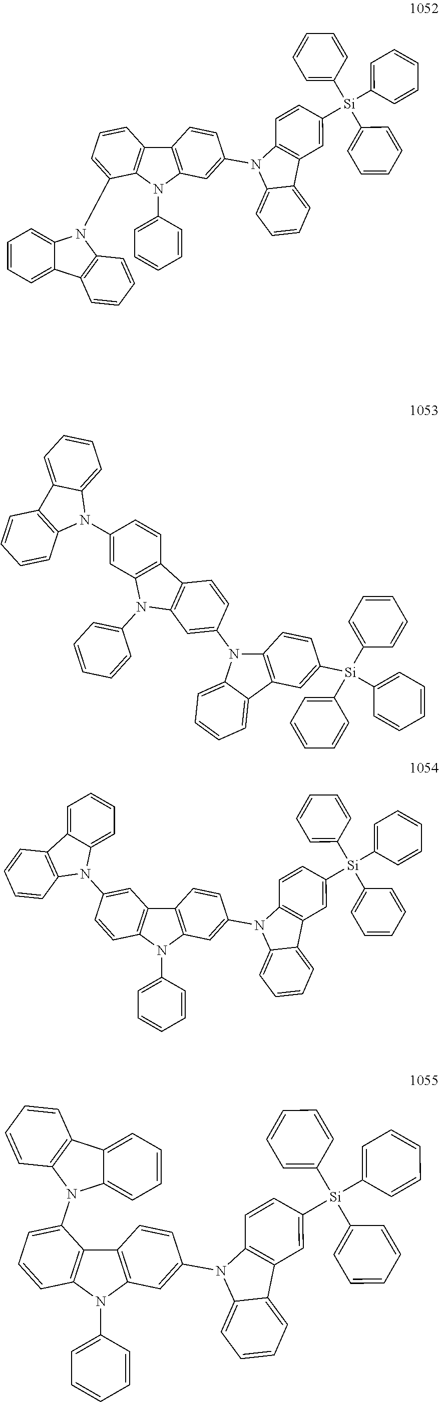 [SMILES: c1ccc(-n2c3cc(-n4c5ccccc5c5cc([Si](c6ccccc6)(c6ccccc6)c6ccccc6)ccc54)ccc3c3cccc(-n4c5ccccc5c5ccccc54)c32)cc1 ; c1ccc(-n2c3cc(-n4c5ccccc5c5ccccc54)ccc3c3ccc(-n4c5ccccc5c5cc([Si](c6ccccc6)(c6ccccc6)c6ccccc6)ccc54)cc32)cc1 ; c1ccc(-n2c3ccc(-n4c5ccccc5c5ccccc54)cc3c3ccc(-n4c5ccccc5c5cc([Si](c6ccccc6)(c6ccccc6)c6ccccc6)ccc54)cc32)cc1 ; c1ccc(-n2c3cc(-n4c5ccccc5c5cc([Si](c6ccccc6)(c6ccccc6)c6ccccc6)ccc54)ccc3c3c(-n4c5ccccc5c5ccccc54)cccc32)cc1]

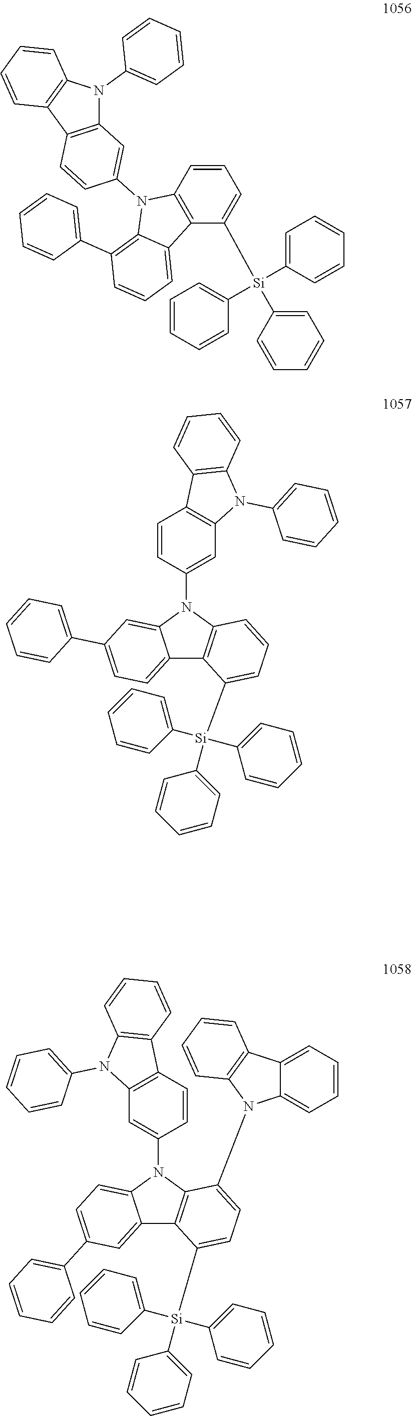 [SMILES: c1ccc(-c2cccc3c4c([Si](c5ccccc5)(c5ccccc5)c5ccccc5)cccc4n(-c4ccc5c6ccccc6n(-c6ccccc6)c5c4)c23)cc1 ; c1ccc(-c2ccc3c4c([Si](c5ccccc5)(c5ccccc5)c5ccccc5)cccc4n(-c4ccc5c6ccccc6n(-c6ccccc6)c5c4)c3c2)cc1 ; c1ccc(-c2ccc3c(c2)c2c([Si](c4ccccc4)(c4ccccc4)c4ccccc4)ccc(-n4c5ccccc5c5ccccc54)c2n3-c2ccc3c4ccccc4n(-c4ccccc4)c3c2)cc1]

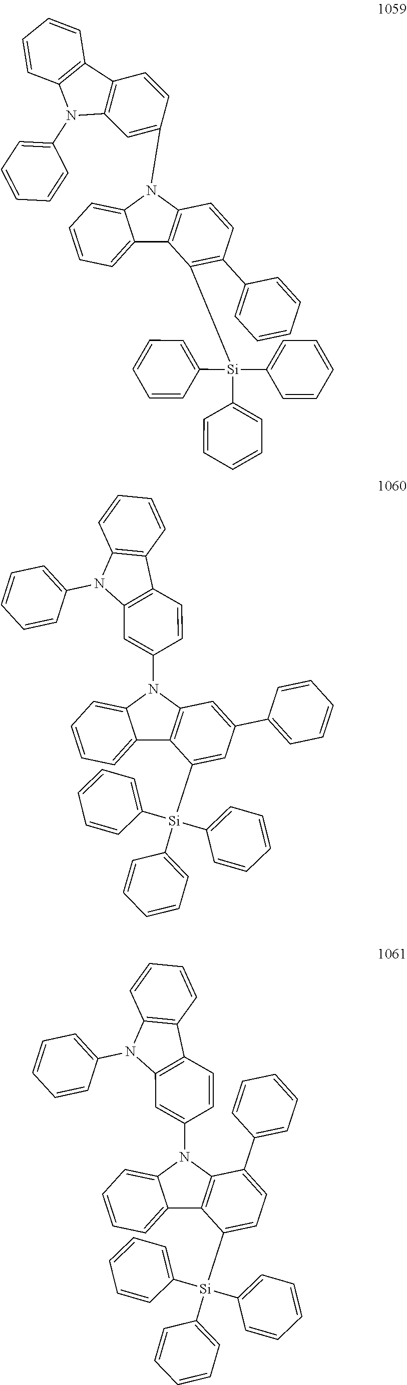 [SMILES: c1ccc(-c2ccc3c(c2[Si](c2ccccc2)(c2ccccc2)c2ccccc2)c2ccccc2n3-c2ccc3c4ccccc4n(-c4ccccc4)c3c2)cc1 ; c1ccc(-c2cc([Si](c3ccccc3)(c3ccccc3)c3ccccc3)c3c4ccccc4n(-c4ccc5c6ccccc6n(-c6ccccc6)c5c4)c3c2)cc1 ; c1ccc(-c2ccc([Si](c3ccccc3)(c3ccccc3)c3ccccc3)c3c4ccccc4n(-c4ccc5c6ccccc6n(-c6ccccc6)c5c4)c23)cc1]

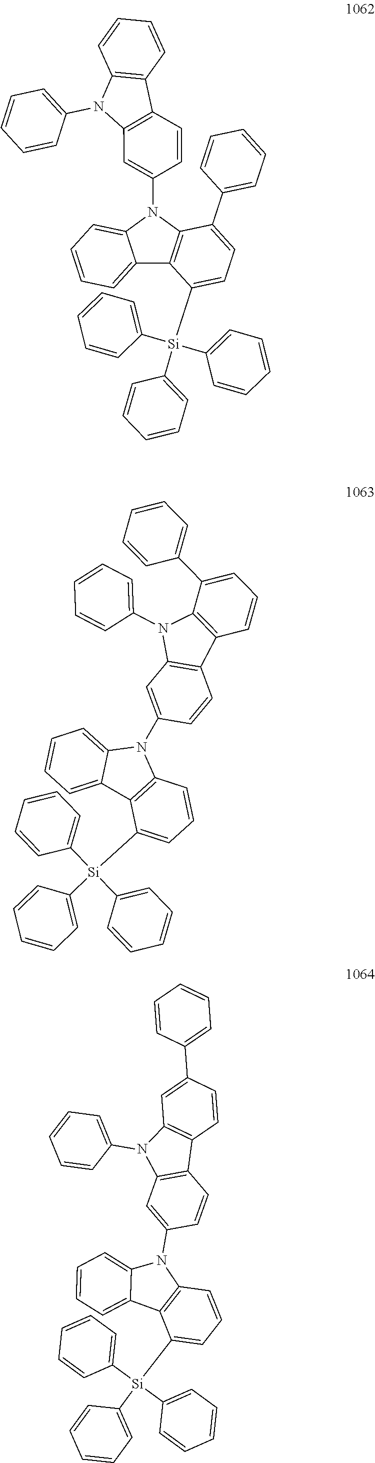

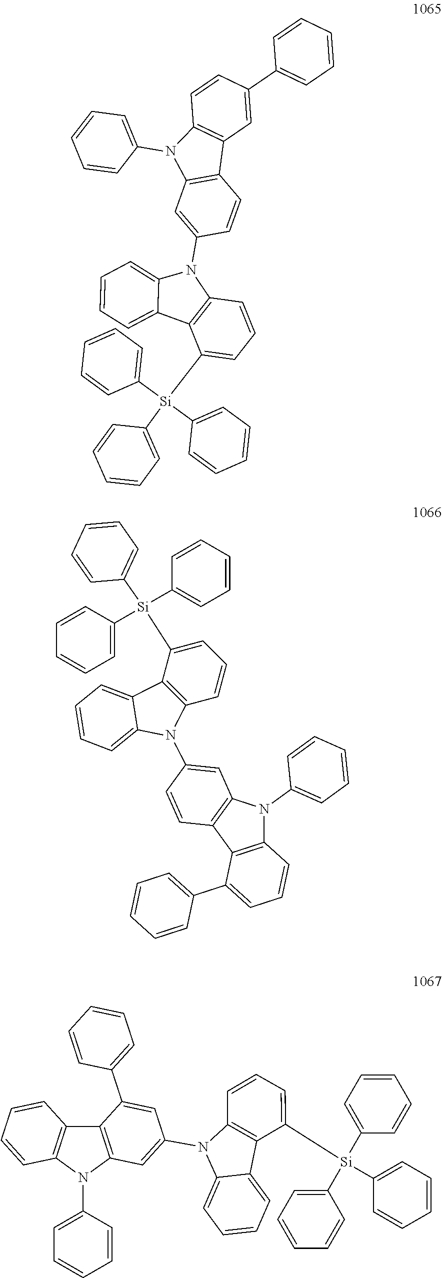

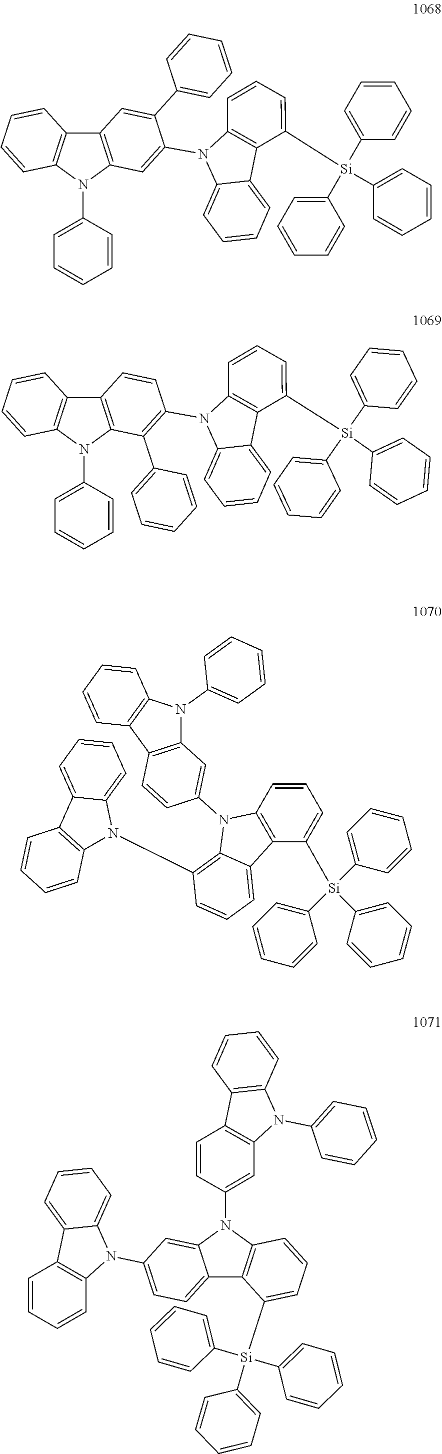 [SMILES: c1ccc(-c2cc3c4ccccc4n(-c4ccccc4)c3cc2-n2c3ccccc3c3c([Si](c4ccccc4)(c4ccccc4)c4ccccc4)cccc32)cc1 ; c1ccc(-c2c(-n3c4ccccc4c4c([Si](c5ccccc5)(c5ccccc5)c5ccccc5)cccc43)ccc3c4ccccc4n(-c4ccccc4)c23)cc1 ; c1ccc(-n2c3ccccc3c3ccc(-n4c5cccc([Si](c6ccccc6)(c6ccccc6)c6ccccc6)c5c5cccc(-n6c7ccccc7c7ccccc76)c54)cc32)cc1 ; c1ccc(-n2c3ccccc3c3ccc(-n4c5cc(-n6c7ccccc7c7ccccc76)ccc5c5c([Si](c6ccccc6)(c6ccccc6)c6ccccc6)cccc54)cc32)cc1]

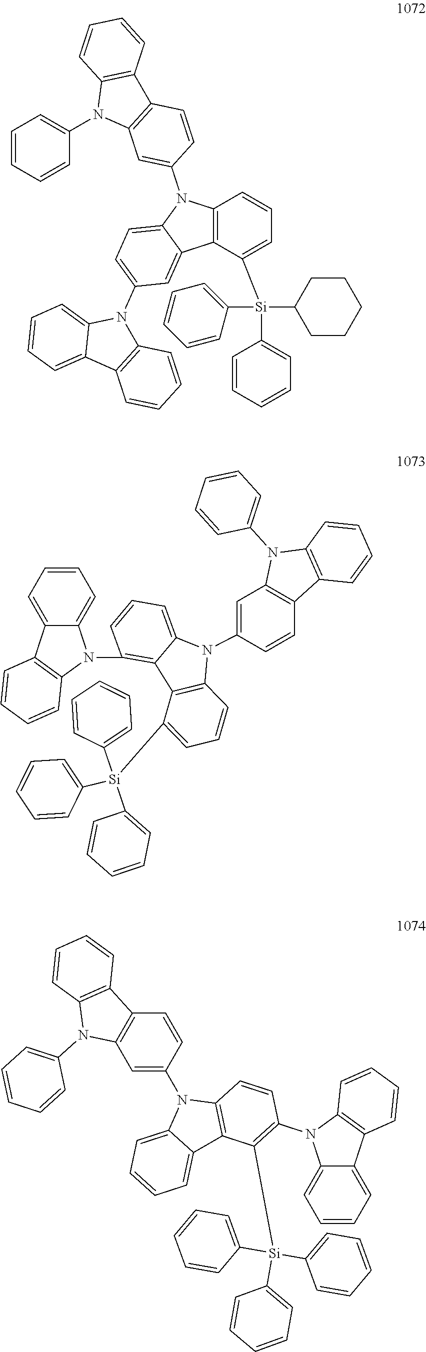 [SMILES: c1ccc(-n2c3ccccc3c3ccc(-n4c5ccc(-n6c7ccccc7c7ccccc76)cc5c5c([Si](c6ccccc6)(c6ccccc6)C6CCCCC6)cccc54)cc32)cc1 ; c1ccc(-n2c3ccccc3c3ccc(-n4c5cccc(-n6c7ccccc7c7ccccc76)c5c5c([Si](c6ccccc6)(c6ccccc6)c6ccccc6)cccc54)cc32)cc1 ; c1ccc(-n2c3ccccc3c3ccc(-n4c5ccccc5c5c([Si](c6ccccc6)(c6ccccc6)c6ccccc6)c(-n6c7ccccc7c7ccccc76)ccc54)cc32)cc1]

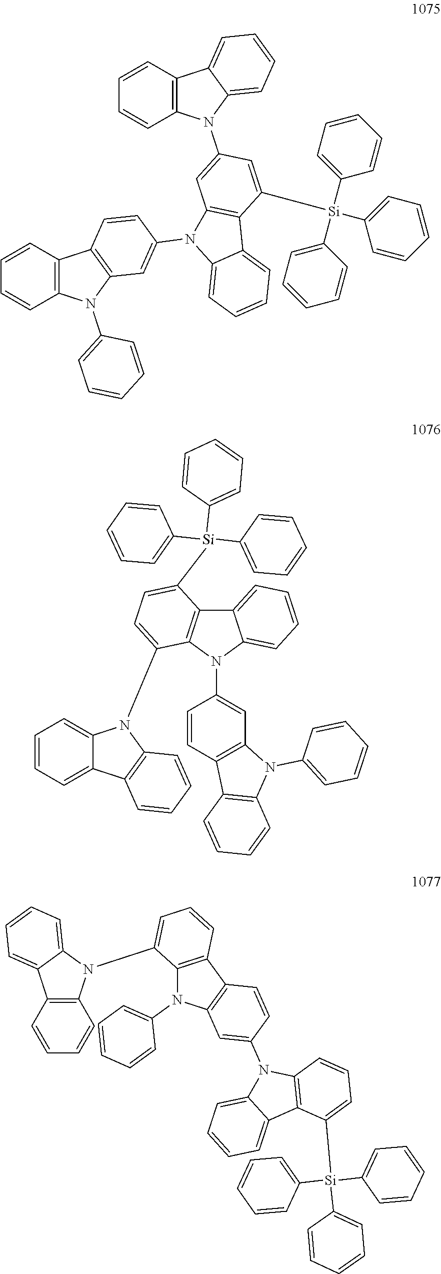 [SMILES: c1ccc(-n2c3ccccc3c3ccc(-n4c5ccccc5c5c([Si](c6ccccc6)(c6ccccc6)c6ccccc6)cc(-n6c7ccccc7c7ccccc76)cc54)cc32)cc1 ; c1ccc(-n2c3ccccc3c3ccc(-n4c5ccccc5c5c([Si](c6ccccc6)(c6ccccc6)c6ccccc6)ccc(-n6c7ccccc7c7ccccc76)c54)cc32)cc1 ; c1ccc(-n2c3cc(-n4c5ccccc5c5c([Si](c6ccccc6)(c6ccccc6)c6ccccc6)cccc54)ccc3c3cccc(-n4c5ccccc5c5ccccc54)c32)cc1]

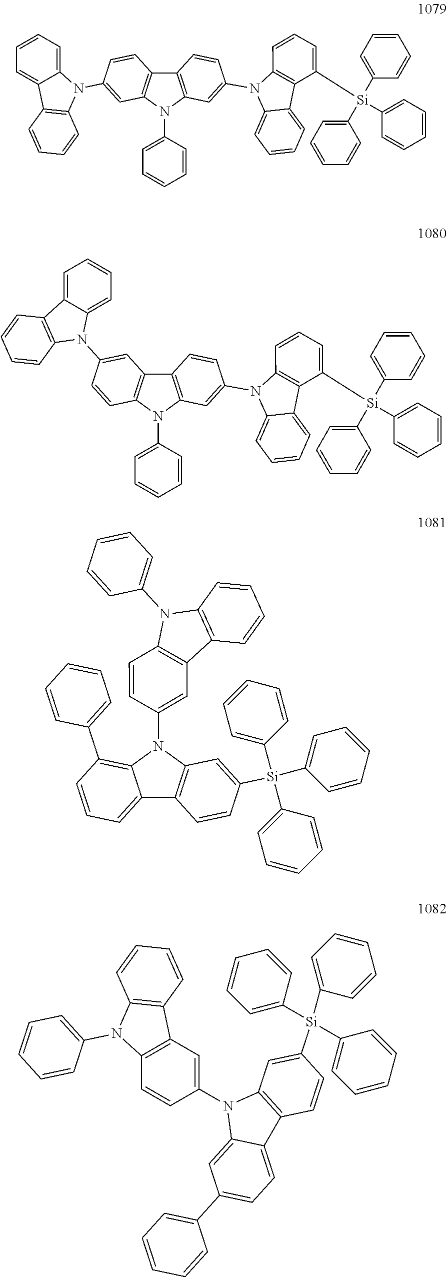 [SMILES: c1ccc(-n2c3cc(-n4c5ccccc5c5ccccc54)ccc3c3ccc(-n4c5ccccc5c5c([Si](c6ccccc6)(c6ccccc6)c6ccccc6)cccc54)cc32)cc1 ; c1ccc(-n2c3ccc(-n4c5ccccc5c5ccccc54)cc3c3ccc(-n4c5ccccc5c5c([Si](c6ccccc6)(c6ccccc6)c6ccccc6)cccc54)cc32)cc1 ; c1ccc(-c2cccc3c4ccc([Si](c5ccccc5)(c5ccccc5)c5ccccc5)cc4n(-c4ccc5c(c4)c4ccccc4n5-c4ccccc4)c23)cc1 ; c1ccc(-c2ccc3c4ccc([Si](c5ccccc5)(c5ccccc5)c5ccccc5)cc4n(-c4ccc5c(c4)c4ccccc4n5-c4ccccc4)c3c2)cc1]

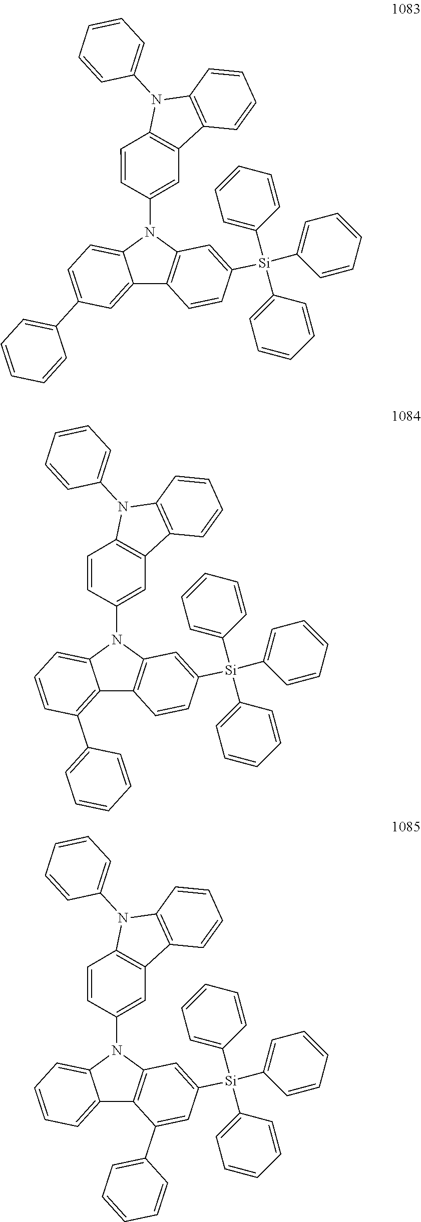

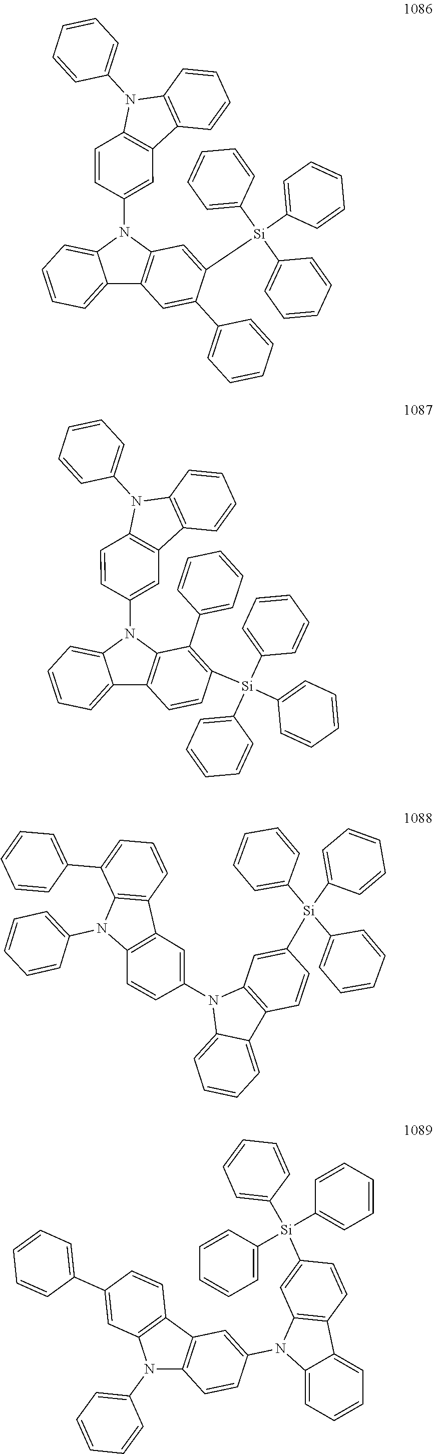

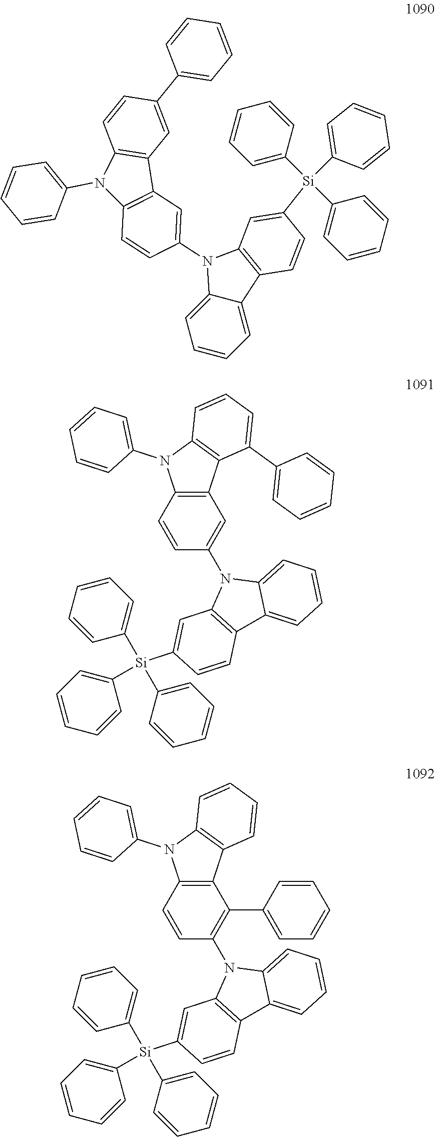

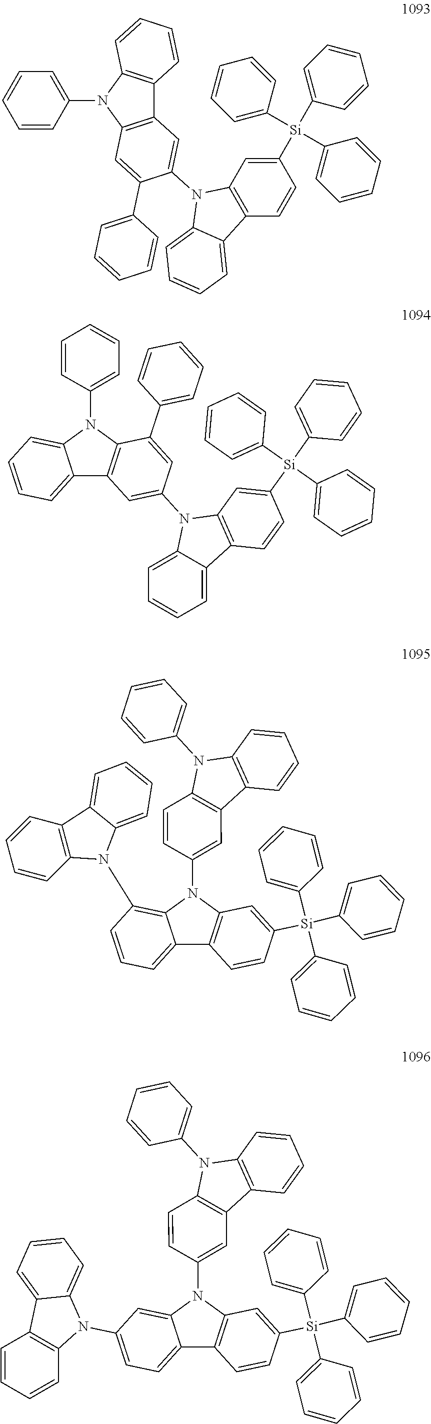 [SMILES: c1ccc(-c2cc3c(cc2-n2c4ccccc4c4ccc([Si](c5ccccc5)(c5ccccc5)c5ccccc5)cc42)c2ccccc2n3-c2ccccc2)cc1 ; c1ccc(-c2cc(-n3c4ccccc4c4ccc([Si](c5ccccc5)(c5ccccc5)c5ccccc5)cc43)cc3c4ccccc4n(-c4ccccc4)c23)cc1 ; c1ccc(-n2c3ccccc3c3cc(-n4c5cc([Si](c6ccccc6)(c6ccccc6)c6ccccc6)ccc5c5cccc(-n6c7ccccc7c7ccccc76)c54)ccc32)cc1 ; c1ccc(-n2c3ccccc3c3cc(-n4c5cc(-n6c7ccccc7c7ccccc76)ccc5c5ccc([Si](c6ccccc6)(c6ccccc6)c6ccccc6)cc54)ccc32)cc1]

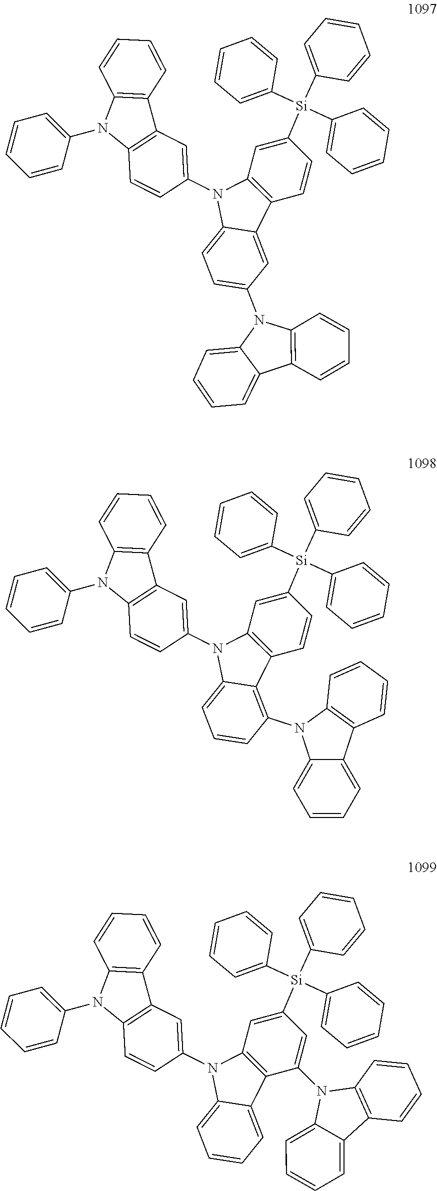 [SMILES: c1ccc(-n2c3ccccc3c3cc(-n4c5ccc(-n6c7ccccc7c7ccccc76)cc5c5ccc([Si](c6ccccc6)(c6ccccc6)c6ccccc6)cc54)ccc32)cc1 ; c1ccc(-n2c3ccccc3c3cc(-n4c5cc([Si](c6ccccc6)(c6ccccc6)c6ccccc6)ccc5c5c(-n6c7ccccc7c7ccccc76)cccc54)ccc32)cc1 ; c1ccc(-n2c3ccccc3c3cc(-n4c5ccccc5c5c(-n6c7ccccc7c7ccccc76)cc([Si](c6ccccc6)(c6ccccc6)c6ccccc6)cc54)ccc32)cc1]

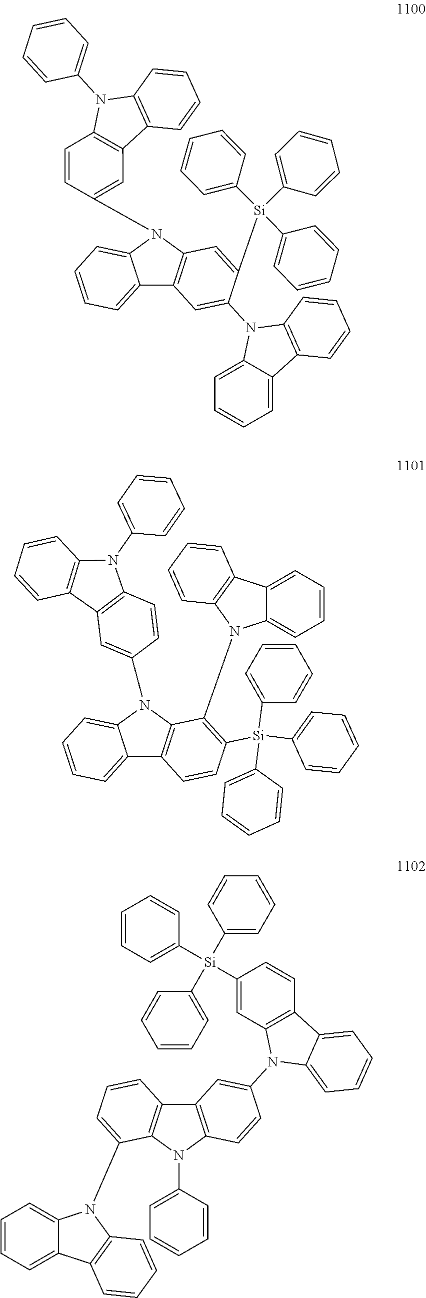

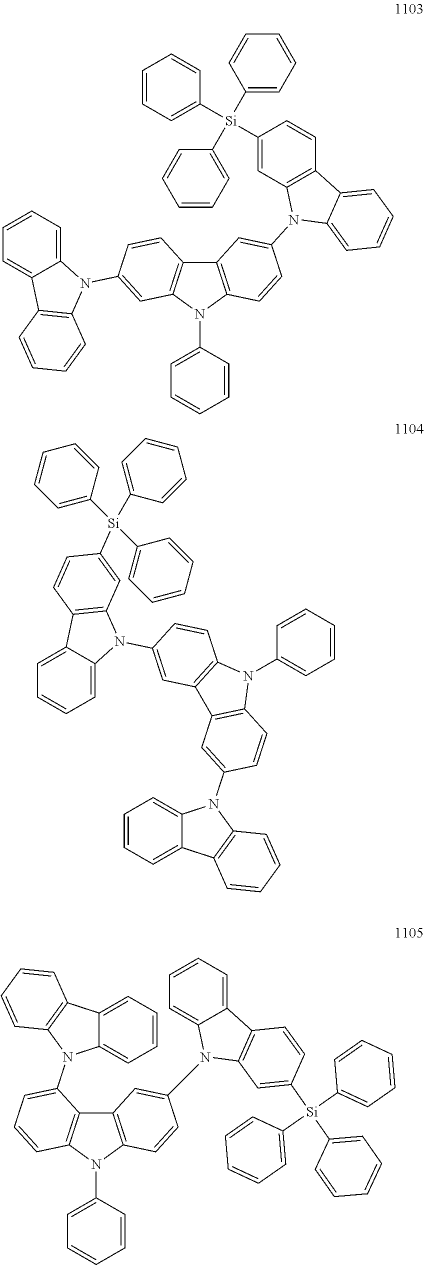

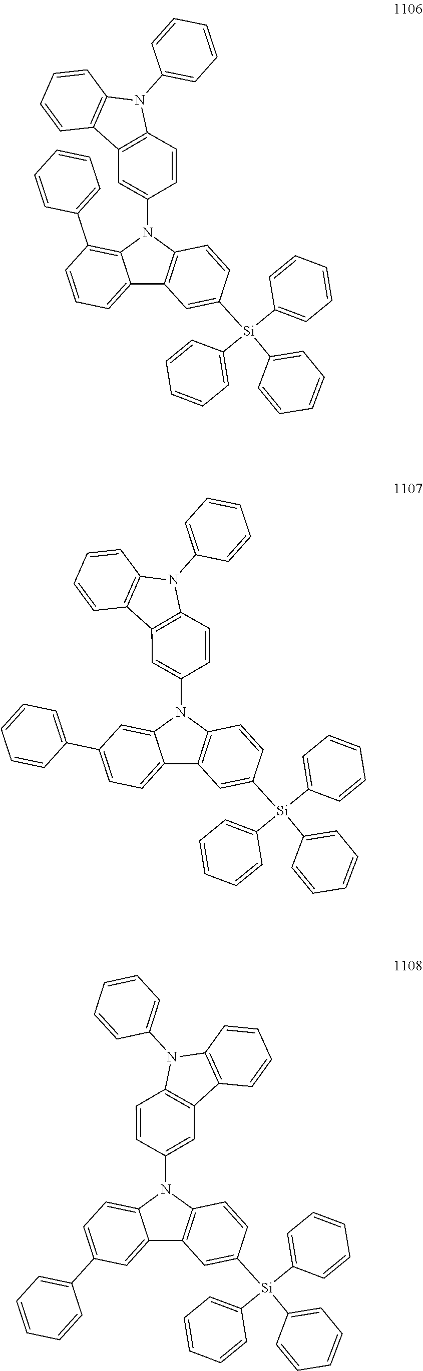

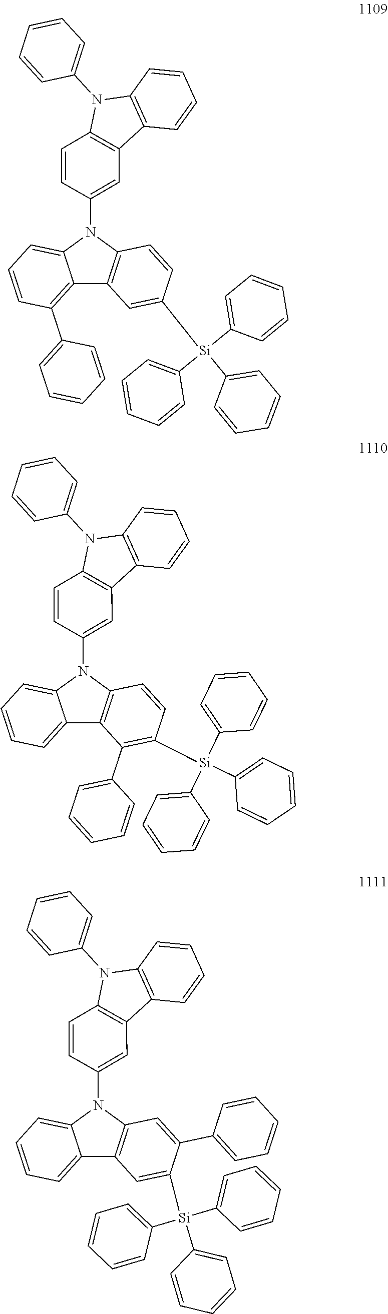

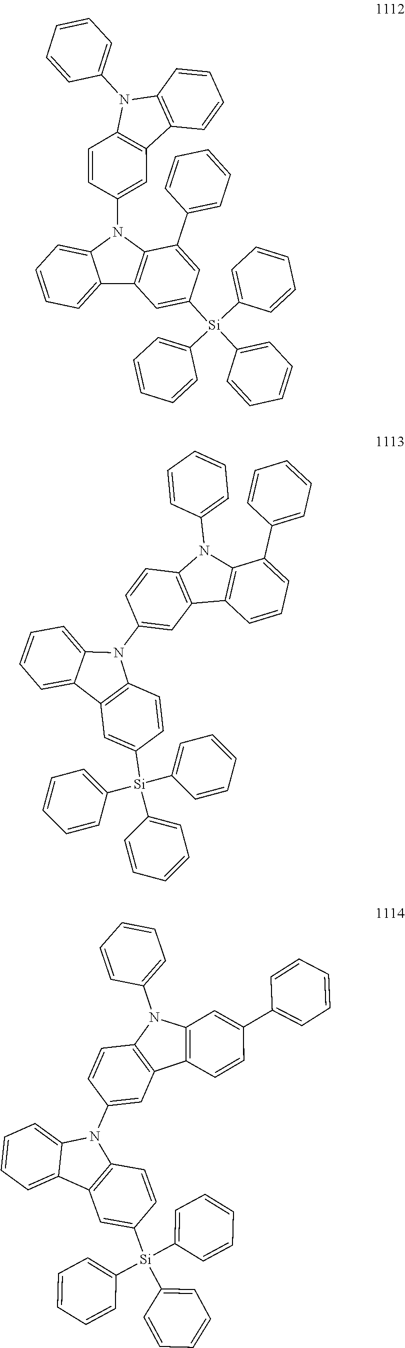

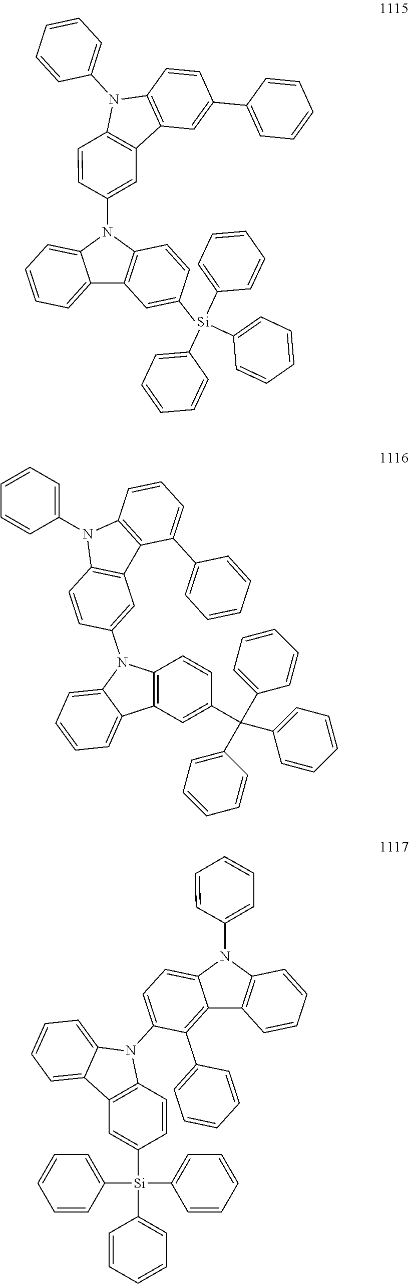

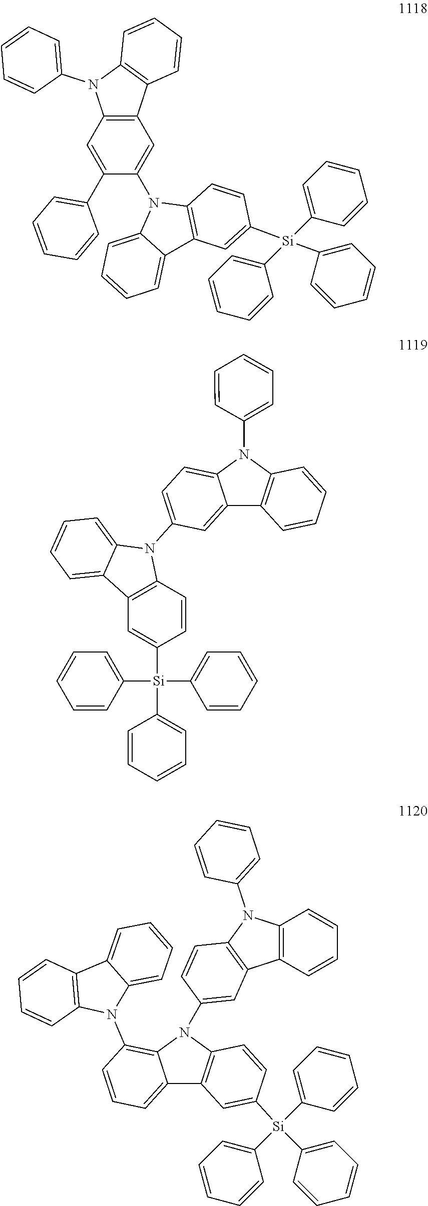

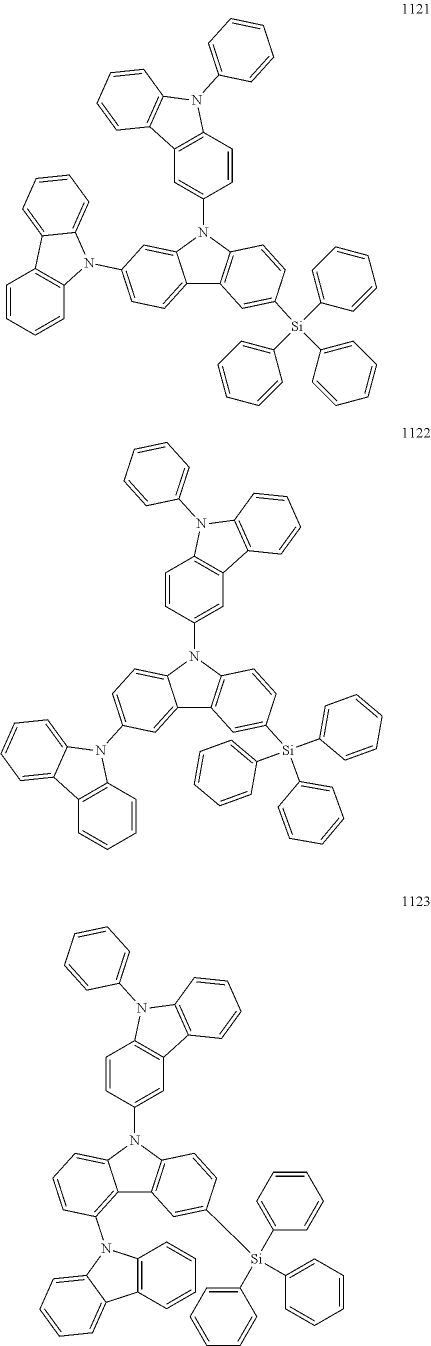 [SMILES: c1ccc(-n2c3ccccc3c3cc(-n4c5ccc([Si](c6ccccc6)(c6ccccc6)c6ccccc6)cc5c5ccc(-n6c7ccccc7c7ccccc76)cc54)ccc32)cc1 ; c1ccc(-n2c3ccccc3c3cc(-n4c5ccc(-n6c7ccccc7c7ccccc76)cc5c5cc([Si](c6ccccc6)(c6ccccc6)c6ccccc6)ccc54)ccc32)cc1 ; c1ccc(-n2c3ccccc3c3cc(-n4c5ccc([Si](c6ccccc6)(c6ccccc6)c6ccccc6)cc5c5c(-n6c7ccccc7c7ccccc76)cccc54)ccc32)cc1]

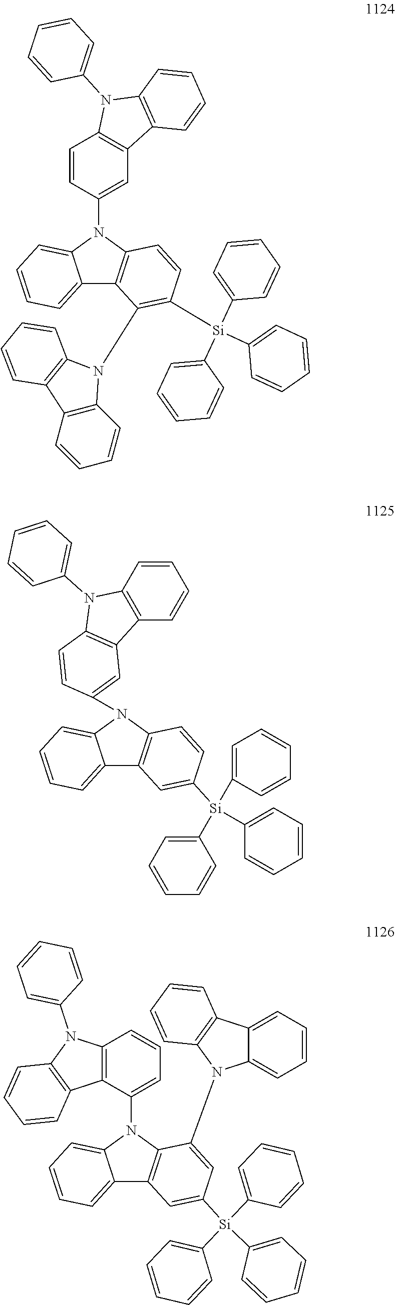 [SMILES: c1ccc(-n2c3ccccc3c3cc(-n4c5ccccc5c5c(-n6c7ccccc7c7ccccc76)c([Si](c6ccccc6)(c6ccccc6)c6ccccc6)ccc54)ccc32)cc1 ; c1ccc(-n2c3ccccc3c3cc(-n4c5ccccc5c5cc([Si](c6ccccc6)(c6ccccc6)c6ccccc6)ccc54)ccc32)cc1 ; c1ccc(-n2c3ccccc3c3c(-n4c5ccccc5c5cc([Si](c6ccccc6)(c6ccccc6)c6ccccc6)cc(-n6c7ccccc7c7ccccc76)c54)cccc32)cc1]

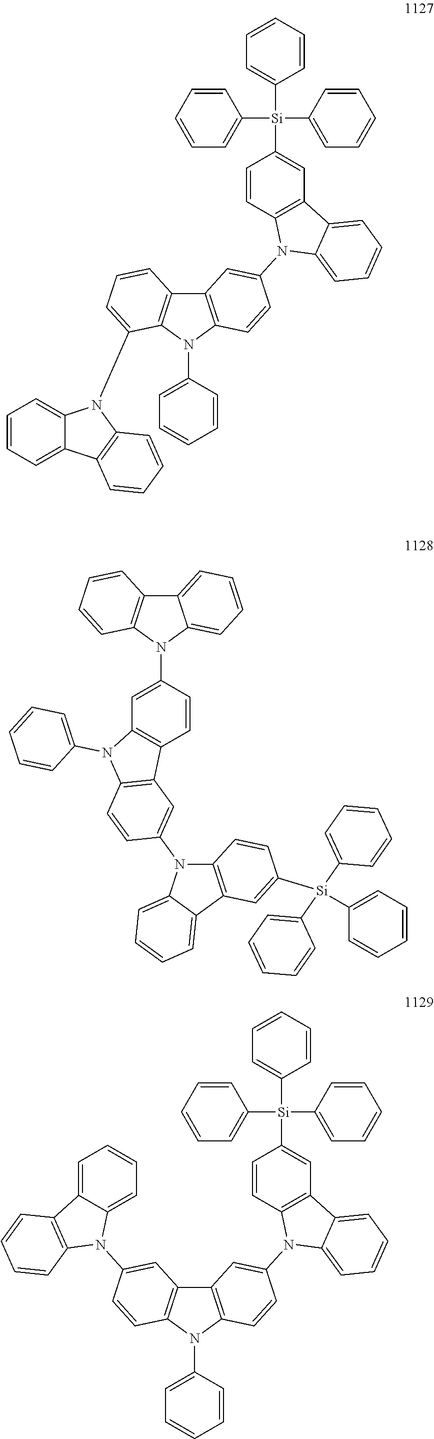

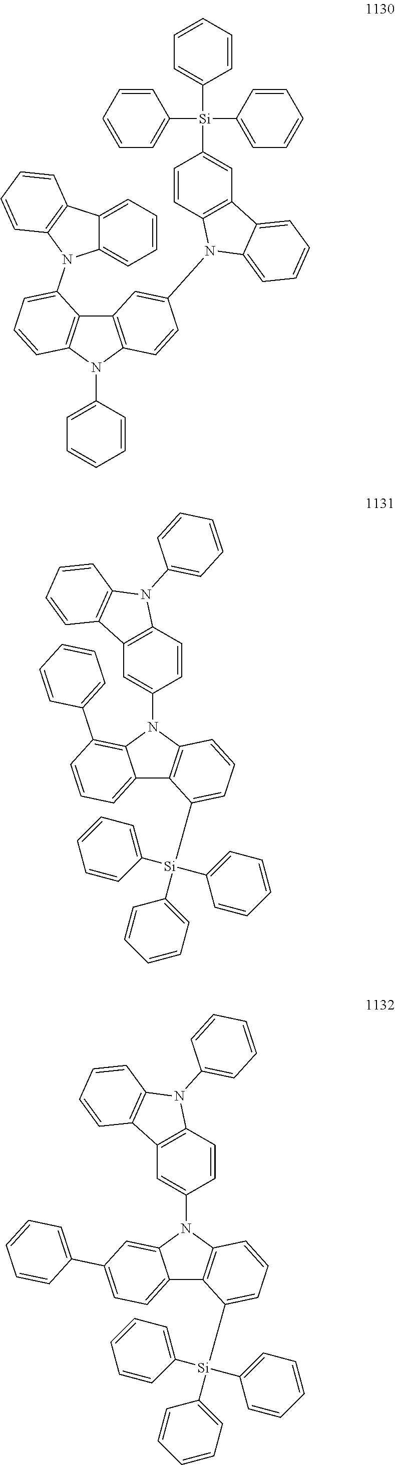 [SMILES: c1ccc(-n2c3ccc(-n4c5ccccc5c5cc([Si](c6ccccc6)(c6ccccc6)c6ccccc6)ccc54)cc3c3c(-n4c5ccccc5c5ccccc54)cccc32)cc1 ; c1ccc(-c2cccc3c4c([Si](c5ccccc5)(c5ccccc5)c5ccccc5)cccc4n(-c4ccc5c(c4)c4ccccc4n5-c4ccccc4)c23)cc1 ; c1ccc(-c2ccc3c4c([Si](c5ccccc5)(c5ccccc5)c5ccccc5)cccc4n(-c4ccc5c(c4)c4ccccc4n5-c4ccccc4)c3c2)cc1]

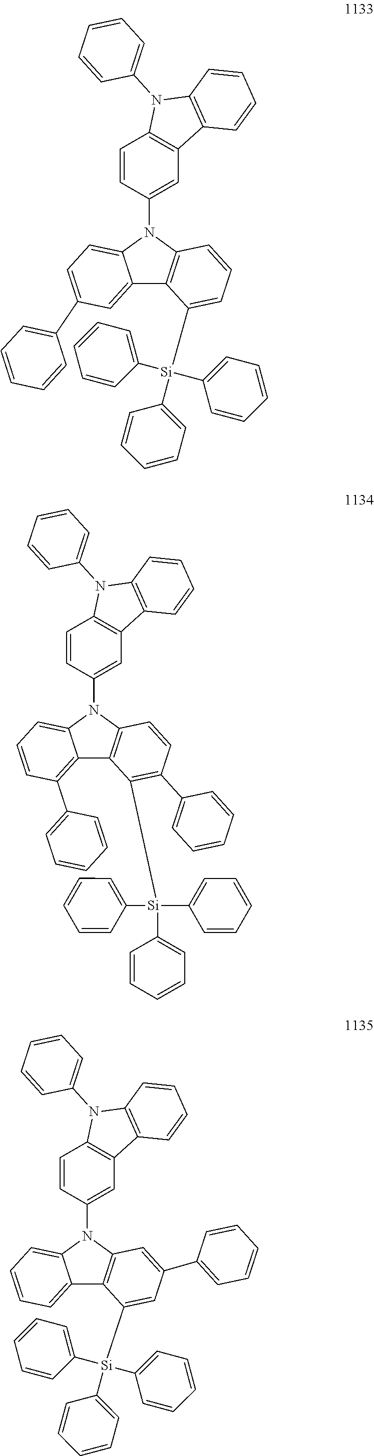 [SMILES: c1ccc(-c2ccc3c(c2)c2c([Si](c4ccccc4)(c4ccccc4)c4ccccc4)cccc2n3-c2ccc3c(c2)c2ccccc2n3-c2ccccc2)cc1 ; c1ccc(-c2ccc3c(c2[Si](c2ccccc2)(c2ccccc2)c2ccccc2)c2c(-c4ccccc4)cccc2n3-c2ccc3c(c2)c2ccccc2n3-c2ccccc2)cc1 ; c1ccc(-c2cc([Si](c3ccccc3)(c3ccccc3)c3ccccc3)c3c4ccccc4n(-c4ccc5c(c4)c4ccccc4n5-c4ccccc4)c3c2)cc1]

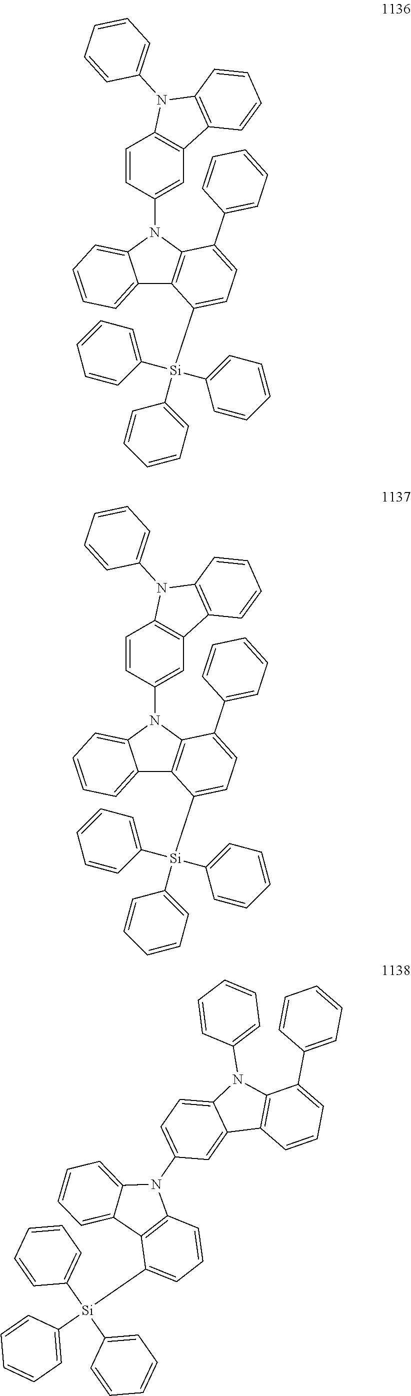

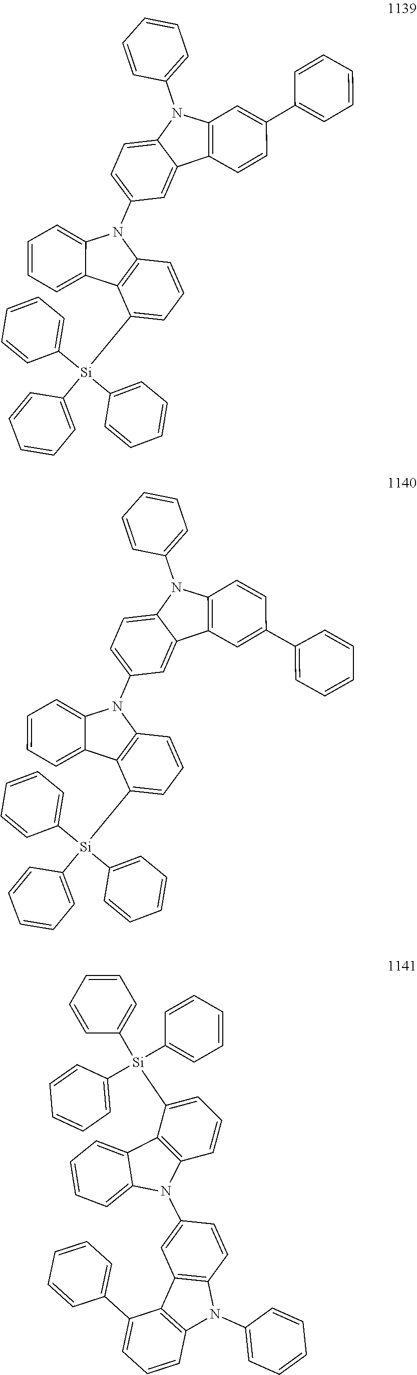 [SMILES: c1ccc(-c2ccc3c4cc(-n5c6ccccc6c6c([Si](c7ccccc7)(c7ccccc7)c7ccccc7)cccc65)ccc4n(-c4ccccc4)c3c2)cc1 ; c1ccc(-c2ccc3c(c2)c2cc(-n4c5ccccc5c5c([Si](c6ccccc6)(c6ccccc6)c6ccccc6)cccc54)ccc2n3-c2ccccc2)cc1 ; c1ccc(-c2cccc3c2c2cc(-n4c5ccccc5c5c([Si](c6ccccc6)(c6ccccc6)c6ccccc6)cccc54)ccc2n3-c2ccccc2)cc1]

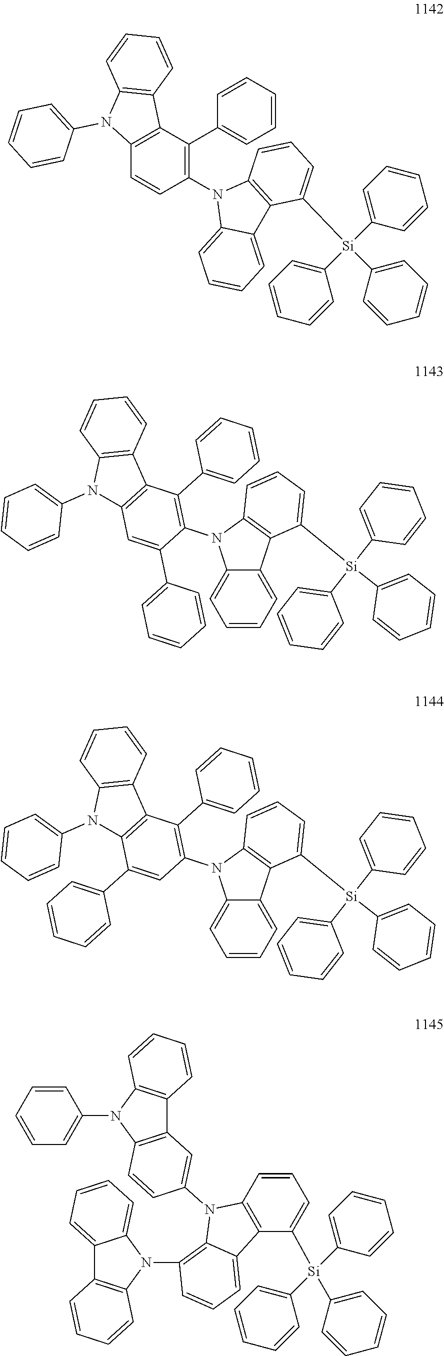 [SMILES: c1ccc(-c2c(-n3c4ccccc4c4c([Si](c5ccccc5)(c5ccccc5)c5ccccc5)cccc43)ccc3c2c2ccccc2n3-c2ccccc2)cc1 ; c1ccc(-c2cc3c(c(-c4ccccc4)c2-n2c4ccccc4c4c([Si](c5ccccc5)(c5ccccc5)c5ccccc5)cccc42)c2ccccc2n3-c2ccccc2)cc1 ; c1ccc(-c2c(-n3c4ccccc4c4c([Si](c5ccccc5)(c5ccccc5)c5ccccc5)cccc43)cc(-c3ccccc3)c3c2c2ccccc2n3-c2ccccc2)cc1 ; c1ccc(-n2c3ccccc3c3cc(-n4c5cccc([Si](c6ccccc6)(c6ccccc6)c6ccccc6)c5c5cccc(-n6c7ccccc7c7ccccc76)c54)ccc32)cc1]

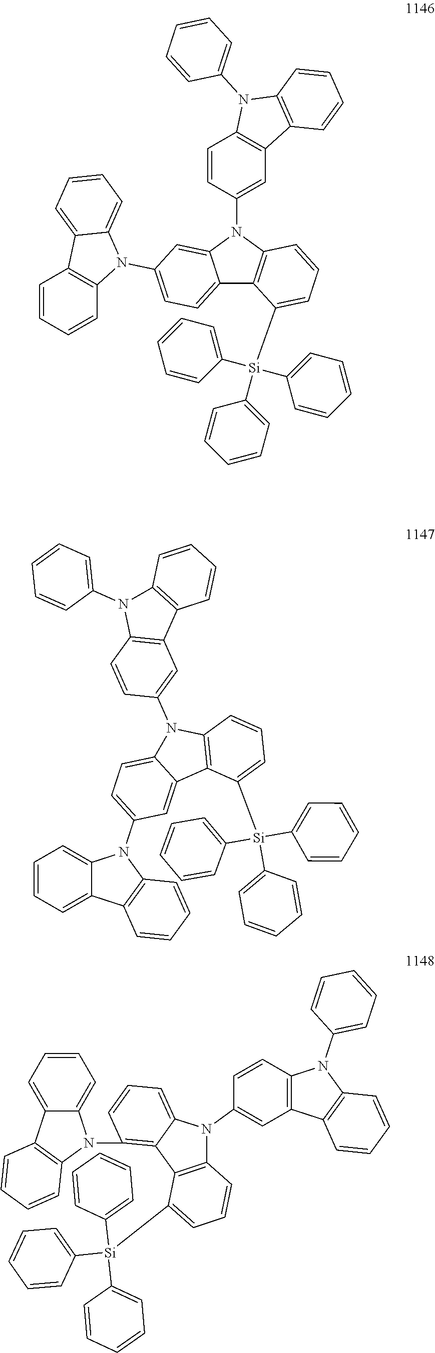 [SMILES: c1ccc(-n2c3ccccc3c3cc(-n4c5cc(-n6c7ccccc7c7ccccc76)ccc5c5c([Si](c6ccccc6)(c6ccccc6)c6ccccc6)cccc54)ccc32)cc1 ; c1ccc(-n2c3ccccc3c3cc(-n4c5ccc(-n6c7ccccc7c7ccccc76)cc5c5c([Si](c6ccccc6)(c6ccccc6)c6ccccc6)cccc54)ccc32)cc1 ; c1ccc(-n2c3ccccc3c3cc(-n4c5cccc(-n6c7ccccc7c7ccccc76)c5c5c([Si](c6ccccc6)(c6ccccc6)c6ccccc6)cccc54)ccc32)cc1]

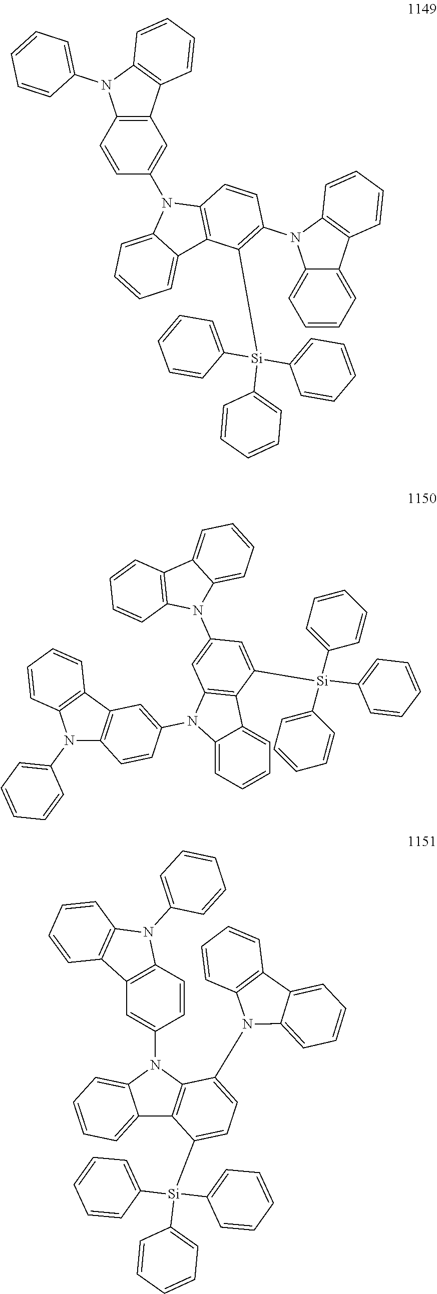 [SMILES: c1ccc(-n2c3ccccc3c3cc(-n4c5ccccc5c5c([Si](c6ccccc6)(c6ccccc6)c6ccccc6)c(-n6c7ccccc7c7ccccc76)ccc54)ccc32)cc1 ; c1ccc(-n2c3ccccc3c3cc(-n4c5ccccc5c5c([Si](c6ccccc6)(c6ccccc6)c6ccccc6)cc(-n6c7ccccc7c7ccccc76)cc54)ccc32)cc1 ; c1ccc(-n2c3ccccc3c3cc(-n4c5ccccc5c5c([Si](c6ccccc6)(c6ccccc6)c6ccccc6)ccc(-n6c7ccccc7c7ccccc76)c54)ccc32)cc1]

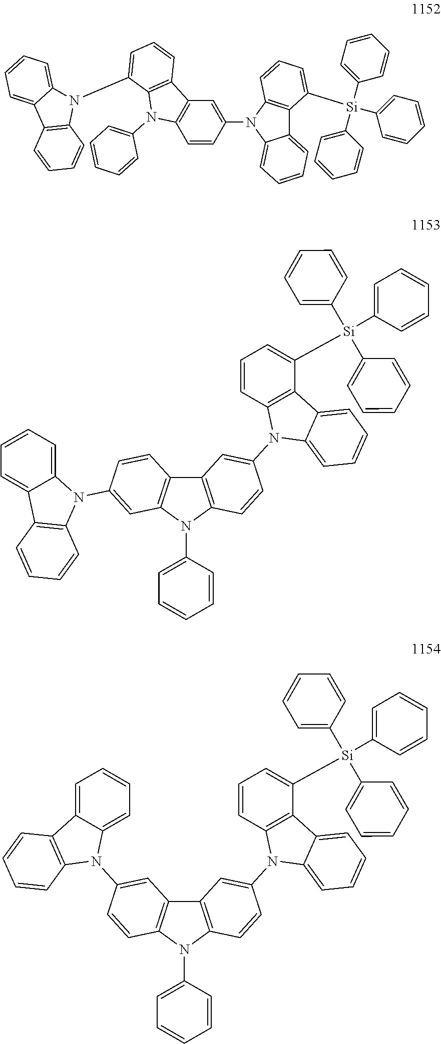 [SMILES: c1ccc(-n2c3ccc(-n4c5ccccc5c5c([Si](c6ccccc6)(c6ccccc6)c6ccccc6)cccc54)cc3c3cccc(-n4c5ccccc5c5ccccc54)c32)cc1 ; c1ccc(-n2c3ccc(-n4c5ccccc5c5c([Si](c6ccccc6)(c6ccccc6)c6ccccc6)cccc54)cc3c3ccc(-n4c5ccccc5c5ccccc54)cc32)cc1 ; c1ccc(-n2c3ccc(-n4c5ccccc5c5ccccc54)cc3c3cc(-n4c5ccccc5c5c([Si](c6ccccc6)(c6ccccc6)c6ccccc6)cccc54)ccc32)cc1]

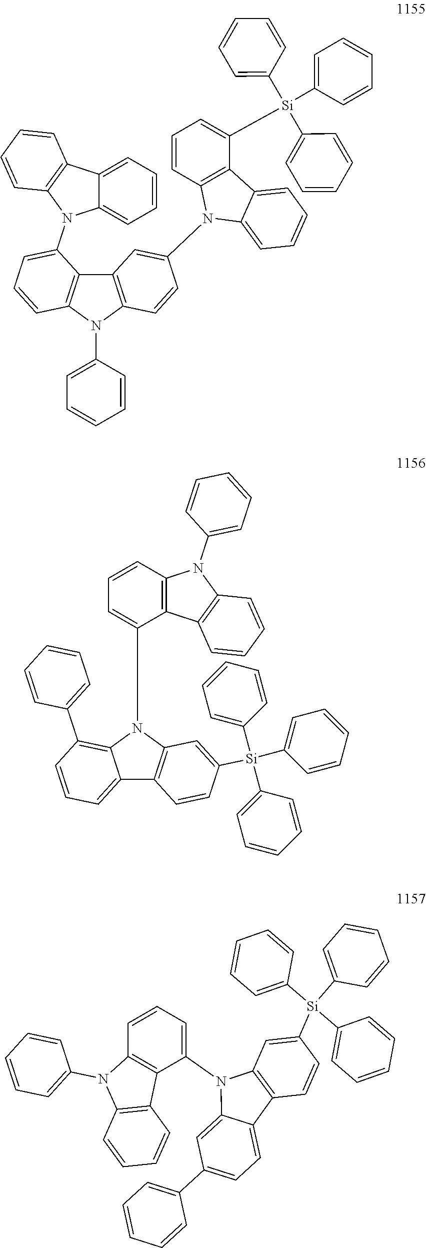 [SMILES: c1ccc(-n2c3ccc(-n4c5ccccc5c5c([Si](c6ccccc6)(c6ccccc6)c6ccccc6)cccc54)cc3c3c(-n4c5ccccc5c5ccccc54)cccc32)cc1 ; c1ccc(-c2cccc3c4ccc([Si](c5ccccc5)(c5ccccc5)c5ccccc5)cc4n(-c4cccc5c4c4ccccc4n5-c4ccccc4)c23)cc1 ; c1ccc(-c2ccc3c4ccc([Si](c5ccccc5)(c5ccccc5)c5ccccc5)cc4n(-c4cccc5c4c4ccccc4n5-c4ccccc4)c3c2)cc1]

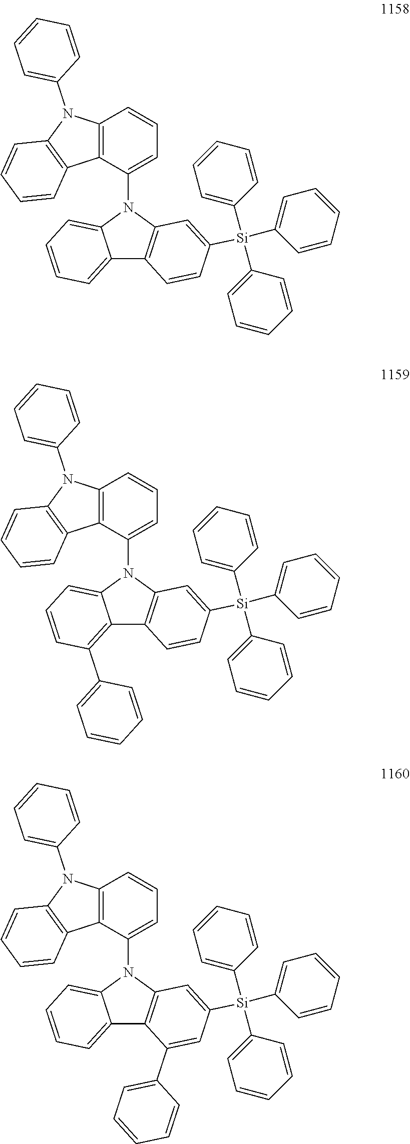 [SMILES: c1ccc(-n2c3ccccc3c3c(-n4c5ccccc5c5ccc([Si](c6ccccc6)(c6ccccc6)c6ccccc6)cc54)cccc32)cc1 ; c1ccc(-c2cccc3c2c2ccc([Si](c4ccccc4)(c4ccccc4)c4ccccc4)cc2n3-c2cccc3c2c2ccccc2n3-c2ccccc2)cc1 ; c1ccc(-c2cc([Si](c3ccccc3)(c3ccccc3)c3ccccc3)cc3c2c2ccccc2n3-c2cccc3c2c2ccccc2n3-c2ccccc2)cc1]

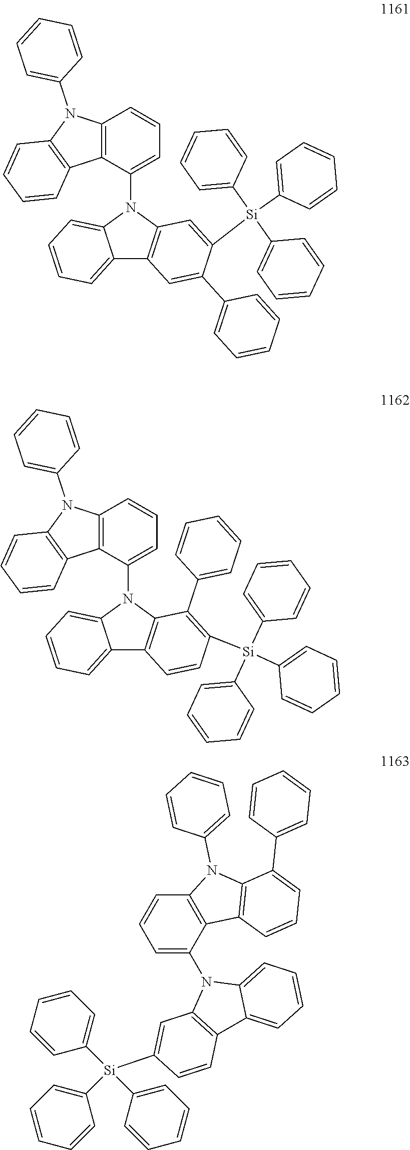

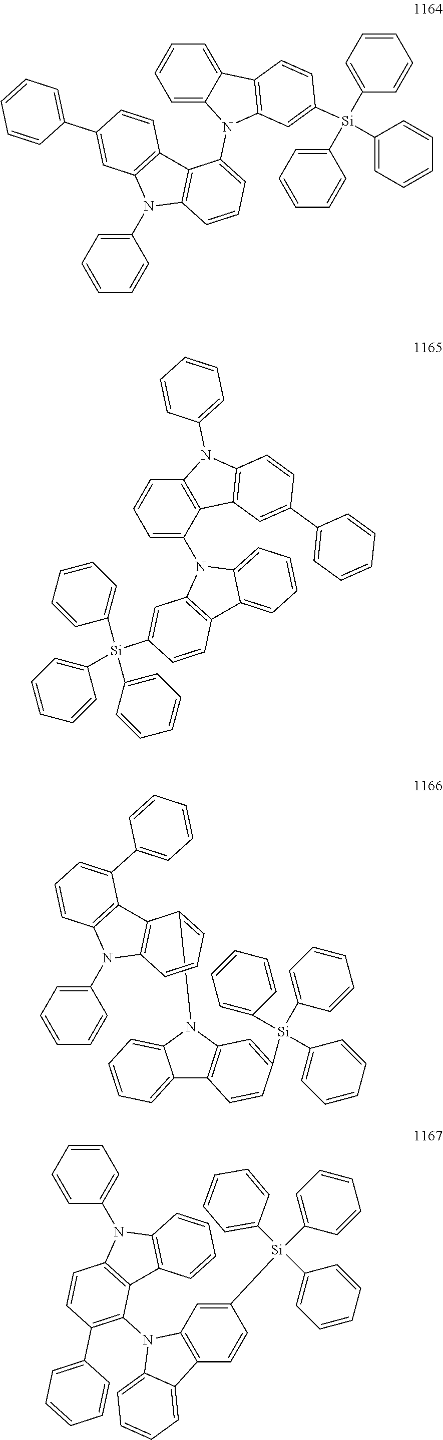 [SMILES: c1ccc(-c2ccc3c4c(-n5c6ccccc6c6ccc([Si](c7ccccc7)(c7ccccc7)c7ccccc7)cc65)cccc4n(-c4ccccc4)c3c2)cc1 ; c1ccc(-c2ccc3c(c2)c2c(-n4c5ccccc5c5ccc([Si](c6ccccc6)(c6ccccc6)c6ccccc6)cc54)cccc2n3-c2ccccc2)cc1 ; c1ccc(-c2cccc3c2c2c(-n4c5ccccc5c5ccc([Si](c6ccccc6)(c6ccccc6)c6ccccc6)cc54)cccc2n3-c2ccccc2)cc1 ; c1ccc(-c2ccc3c(c2-n2c4ccccc4c4ccc([Si](c5ccccc5)(c5ccccc5)c5ccccc5)cc42)c2ccccc2n3-c2ccccc2)cc1]

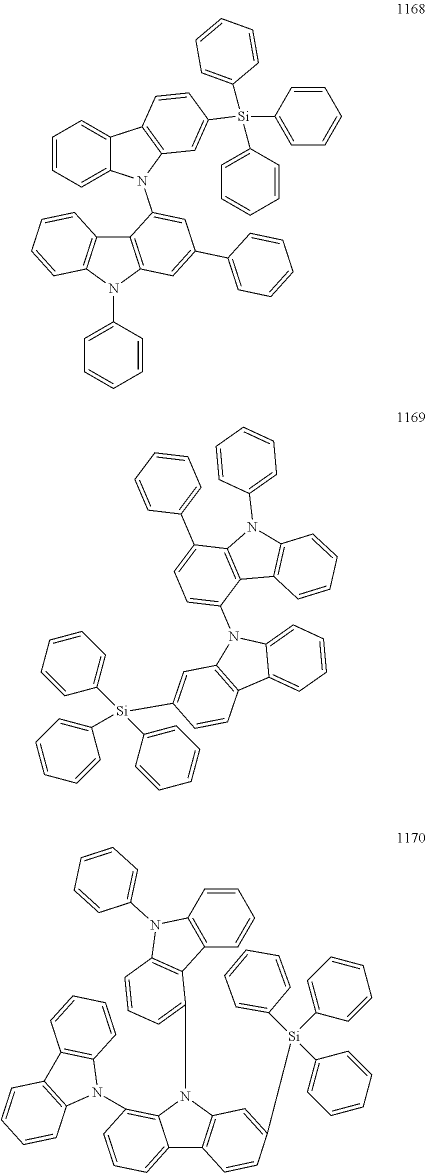 [SMILES: c1ccc(-c2cc(-n3c4ccccc4c4ccc([Si](c5ccccc5)(c5ccccc5)c5ccccc5)cc43)c3c4ccccc4n(-c4ccccc4)c3c2)cc1 ; c1ccc(-c2ccc(-n3c4ccccc4c4ccc([Si](c5ccccc5)(c5ccccc5)c5ccccc5)cc43)c3c4ccccc4n(-c4ccccc4)c23)cc1 ; c1ccc(-n2c3ccccc3c3c(-n4c5cc([Si](c6ccccc6)(c6ccccc6)c6ccccc6)ccc5c5cccc(-n6c7ccccc7c7ccccc76)c54)cccc32)cc1]

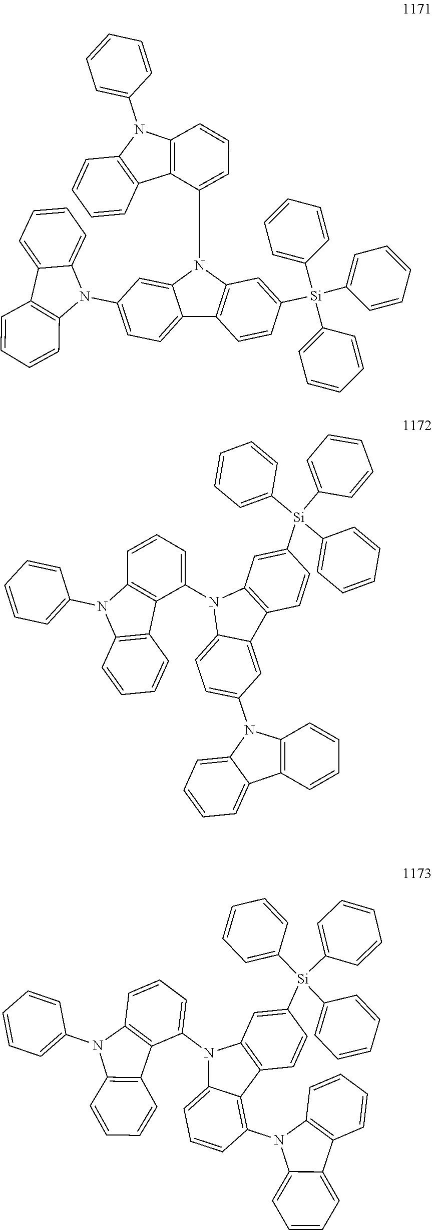

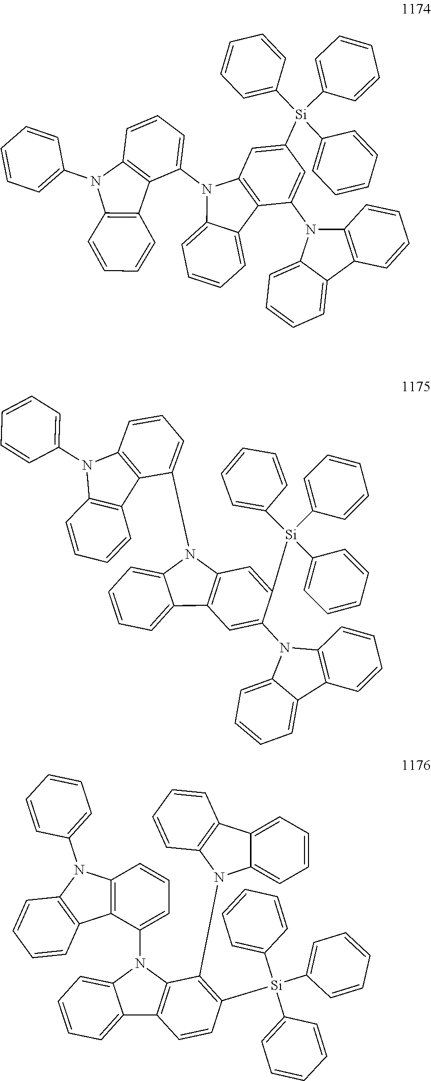 [SMILES: c1ccc(-n2c3ccccc3c3c(-n4c5ccccc5c5c(-n6c7ccccc7c7ccccc76)cc([Si](c6ccccc6)(c6ccccc6)c6ccccc6)cc54)cccc32)cc1 ; c1ccc(-n2c3ccccc3c3c(-n4c5ccccc5c5cc(-n6c7ccccc7c7ccccc76)c([Si](c6ccccc6)(c6ccccc6)c6ccccc6)cc54)cccc32)cc1 ; c1ccc(-n2c3ccccc3c3c(-n4c5ccccc5c5ccc([Si](c6ccccc6)(c6ccccc6)c6ccccc6)c(-n6c7ccccc7c7ccccc76)c54)cccc32)cc1]

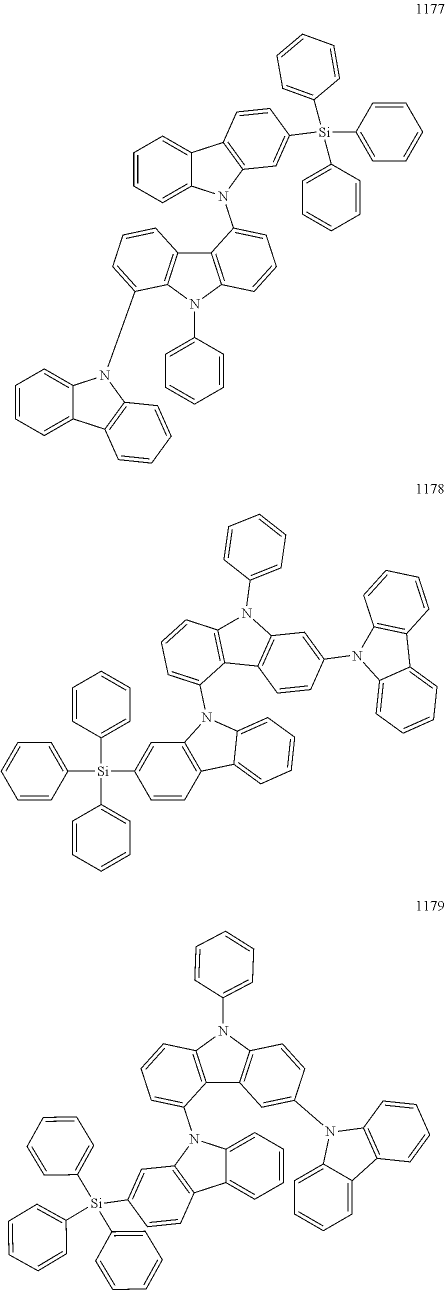 [SMILES: c1ccc(-n2c3cccc(-n4c5ccccc5c5ccc([Si](c6ccccc6)(c6ccccc6)c6ccccc6)cc54)c3c3cccc(-n4c5ccccc5c5ccccc54)c32)cc1 ; c1ccc(-n2c3cc(-n4c5ccccc5c5ccccc54)ccc3c3c(-n4c5ccccc5c5ccc([Si](c6ccccc6)(c6ccccc6)c6ccccc6)cc54)cccc32)cc1 ; c1ccc(-n2c3ccc(-n4c5ccccc5c5ccccc54)cc3c3c(-n4c5ccccc5c5ccc([Si](c6ccccc6)(c6ccccc6)c6ccccc6)cc54)cccc32)cc1]

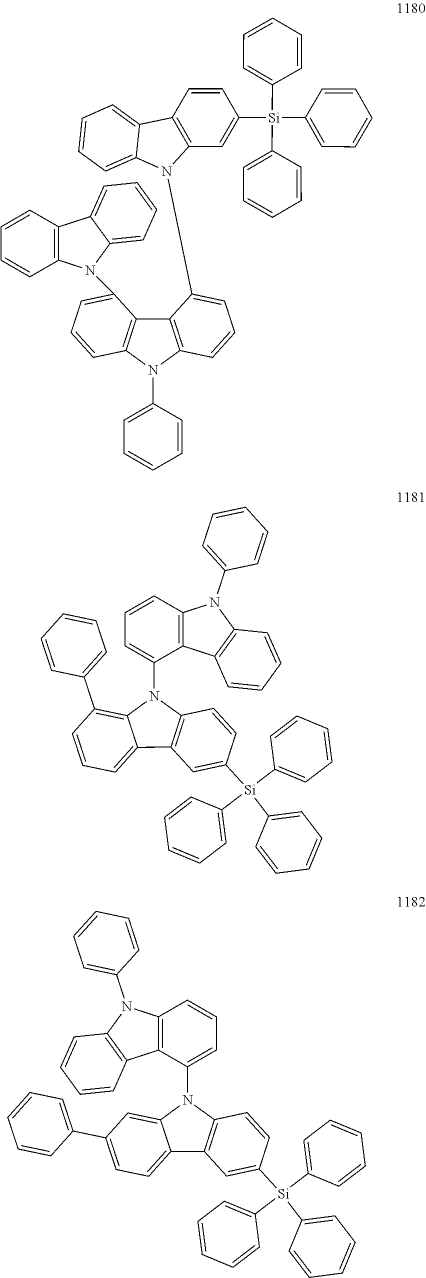 [SMILES: c1ccc(-n2c3cccc(-n4c5ccccc5c5ccccc54)c3c3c(-n4c5ccccc5c5ccc([Si](c6ccccc6)(c6ccccc6)c6ccccc6)cc54)cccc32)cc1 ; c1ccc(-c2cccc3c4cc([Si](c5ccccc5)(c5ccccc5)c5ccccc5)ccc4n(-c4cccc5c4c4ccccc4n5-c4ccccc4)c23)cc1 ; c1ccc(-c2ccc3c4cc([Si](c5ccccc5)(c5ccccc5)c5ccccc5)ccc4n(-c4cccc5c4c4ccccc4n5-c4ccccc4)c3c2)cc1]

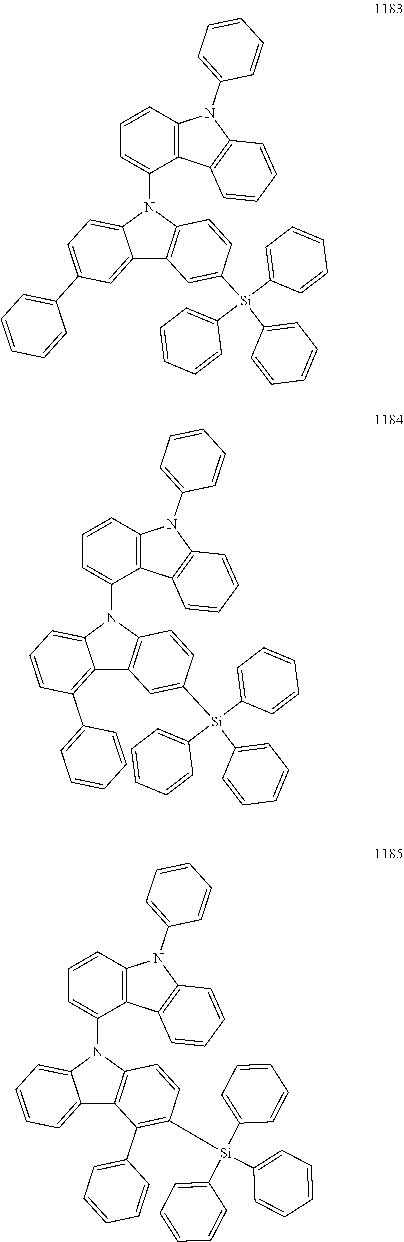 [SMILES: c1ccc(-c2ccc3c(c2)c2cc([Si](c4ccccc4)(c4ccccc4)c4ccccc4)ccc2n3-c2cccc3c2c2ccccc2n3-c2ccccc2)cc1 ; c1ccc(-c2cccc3c2c2cc([Si](c4ccccc4)(c4ccccc4)c4ccccc4)ccc2n3-c2cccc3c2c2ccccc2n3-c2ccccc2)cc1 ; c1ccc(-c2c([Si](c3ccccc3)(c3ccccc3)c3ccccc3)ccc3c2c2ccccc2n3-c2cccc3c2c2ccccc2n3-c2ccccc2)cc1]

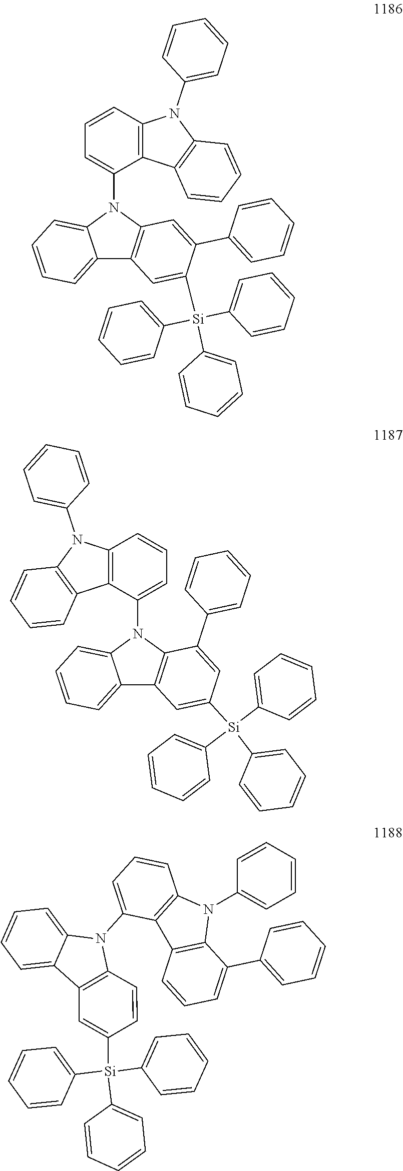

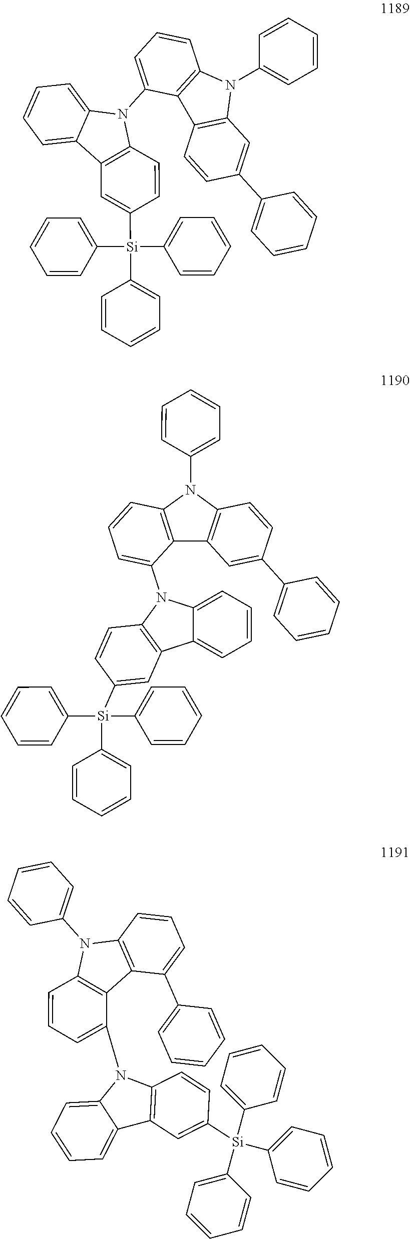 [SMILES: c1ccc(-c2ccc3c4c(-n5c6ccccc6c6cc([Si](c7ccccc7)(c7ccccc7)c7ccccc7)ccc65)cccc4n(-c4ccccc4)c3c2)cc1 ; c1ccc(-c2ccc3c(c2)c2c(-n4c5ccccc5c5cc([Si](c6ccccc6)(c6ccccc6)c6ccccc6)ccc54)cccc2n3-c2ccccc2)cc1 ; c1ccc(-c2cccc3c2c2c(-n4c5ccccc5c5cc([Si](c6ccccc6)(c6ccccc6)c6ccccc6)ccc54)cccc2n3-c2ccccc2)cc1]

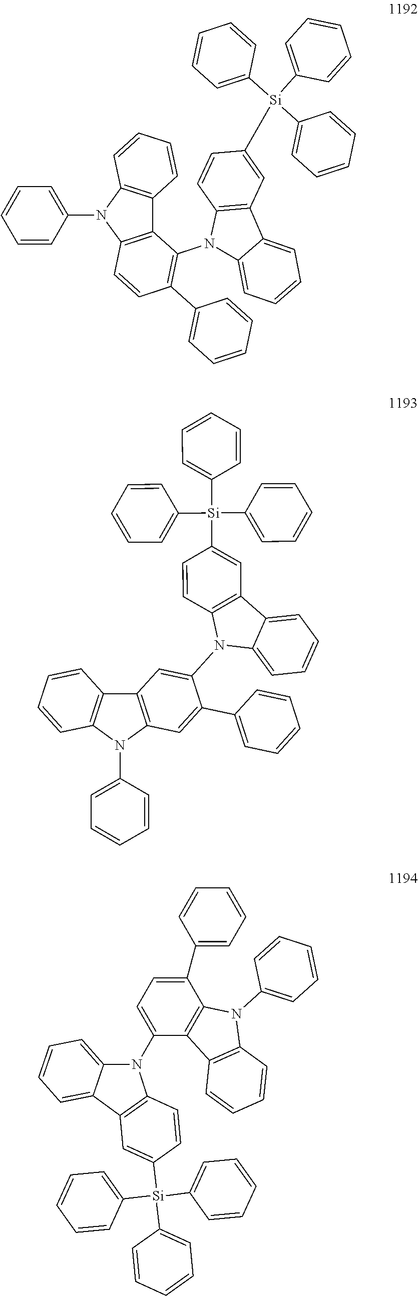 [SMILES: c1ccc(-c2ccc3c(c2-n2c4ccccc4c4cc([Si](c5ccccc5)(c5ccccc5)c5ccccc5)ccc42)c2ccccc2n3-c2ccccc2)cc1 ; c1ccc(-c2cc3c(cc2-n2c4ccccc4c4cc([Si](c5ccccc5)(c5ccccc5)c5ccccc5)ccc42)c2ccccc2n3-c2ccccc2)cc1 ; c1ccc(-c2ccc(-n3c4ccccc4c4cc([Si](c5ccccc5)(c5ccccc5)c5ccccc5)ccc43)c3c4ccccc4n(-c4ccccc4)c23)cc1]

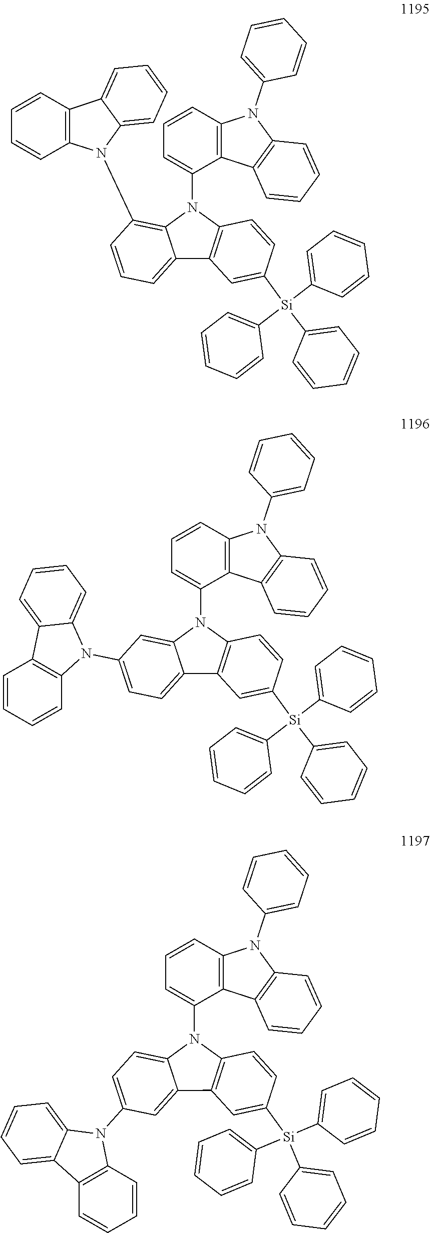 [SMILES: c1ccc(-n2c3ccccc3c3c(-n4c5ccc([Si](c6ccccc6)(c6ccccc6)c6ccccc6)cc5c5cccc(-n6c7ccccc7c7ccccc76)c54)cccc32)cc1 ; c1ccc(-n2c3ccccc3c3c(-n4c5ccc([Si](c6ccccc6)(c6ccccc6)c6ccccc6)cc5c5ccc(-n6c7ccccc7c7ccccc76)cc54)cccc32)cc1 ; c1ccc(-n2c3ccccc3c3c(-n4c5ccc(-n6c7ccccc7c7ccccc76)cc5c5cc([Si](c6ccccc6)(c6ccccc6)c6ccccc6)ccc54)cccc32)cc1]

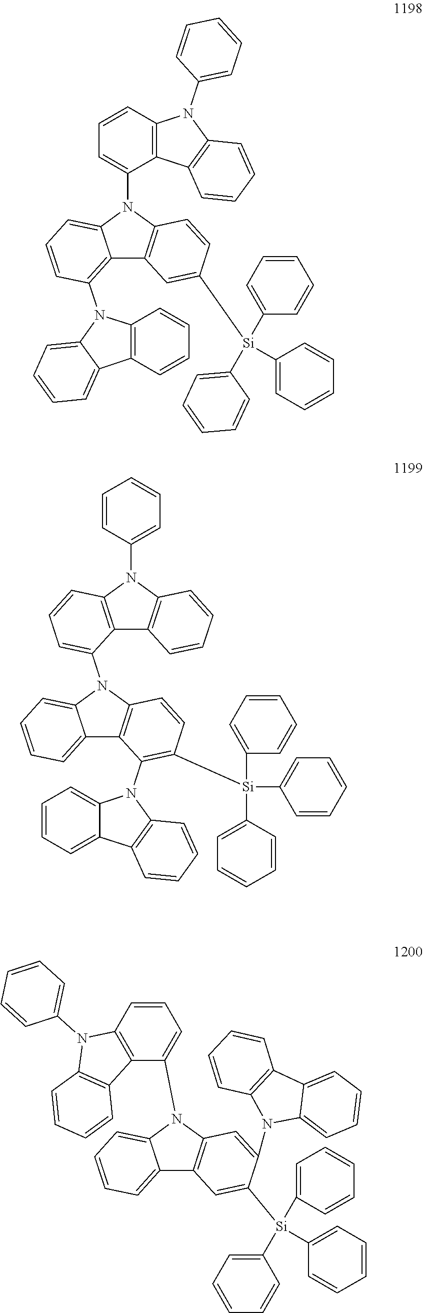 [SMILES: c1ccc(-n2c3ccccc3c3c(-n4c5ccc([Si](c6ccccc6)(c6ccccc6)c6ccccc6)cc5c5c(-n6c7ccccc7c7ccccc76)cccc54)cccc32)cc1 ; c1ccc(-n2c3ccccc3c3c(-n4c5ccccc5c5c(-n6c7ccccc7c7ccccc76)c([Si](c6ccccc6)(c6ccccc6)c6ccccc6)ccc54)cccc32)cc1 ; c1ccc(-n2c3ccccc3c3c(-n4c5ccccc5c5cc([Si](c6ccccc6)(c6ccccc6)c6ccccc6)c(-n6c7ccccc7c7ccccc76)cc54)cccc32)cc1]

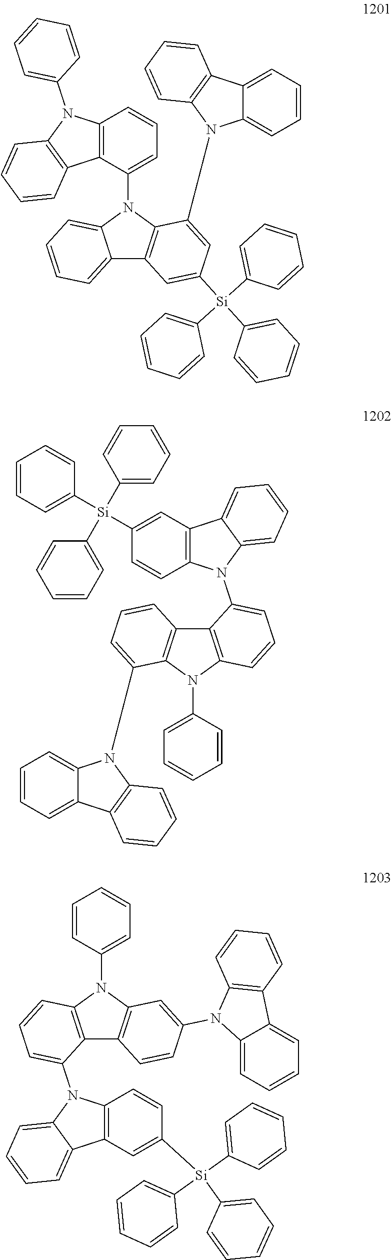 [SMILES: c1ccc(-n2c3ccccc3c3c(-n4c5ccccc5c5cc([Si](c6ccccc6)(c6ccccc6)c6ccccc6)cc(-n6c7ccccc7c7ccccc76)c54)cccc32)cc1 ; c1ccc(-n2c3cccc(-n4c5ccccc5c5cc([Si](c6ccccc6)(c6ccccc6)c6ccccc6)ccc54)c3c3cccc(-n4c5ccccc5c5ccccc54)c32)cc1 ; c1ccc(-n2c3cc(-n4c5ccccc5c5ccccc54)ccc3c3c(-n4c5ccccc5c5cc([Si](c6ccccc6)(c6ccccc6)c6ccccc6)ccc54)cccc32)cc1]

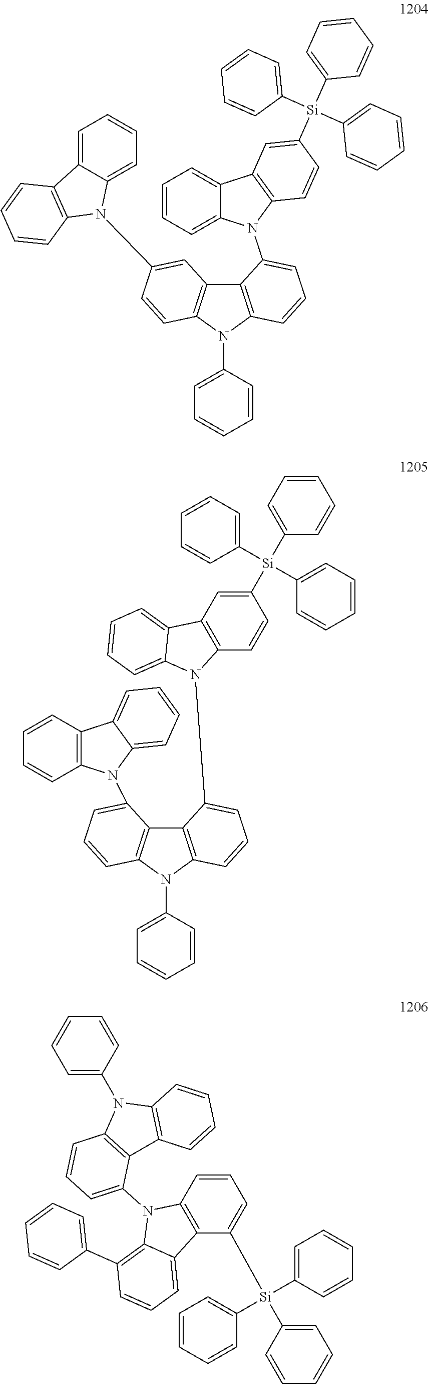 [SMILES: c1ccc(-n2c3ccc(-n4c5ccccc5c5ccccc54)cc3c3c(-n4c5ccccc5c5cc([Si](c6ccccc6)(c6ccccc6)c6ccccc6)ccc54)cccc32)cc1 ; c1ccc(-n2c3cccc(-n4c5ccccc5c5ccccc54)c3c3c(-n4c5ccccc5c5cc([Si](c6ccccc6)(c6ccccc6)c6ccccc6)ccc54)cccc32)cc1 ; c1ccc(-c2cccc3c4c([Si](c5ccccc5)(c5ccccc5)c5ccccc5)cccc4n(-c4cccc5c4c4ccccc4n5-c4ccccc4)c23)cc1]

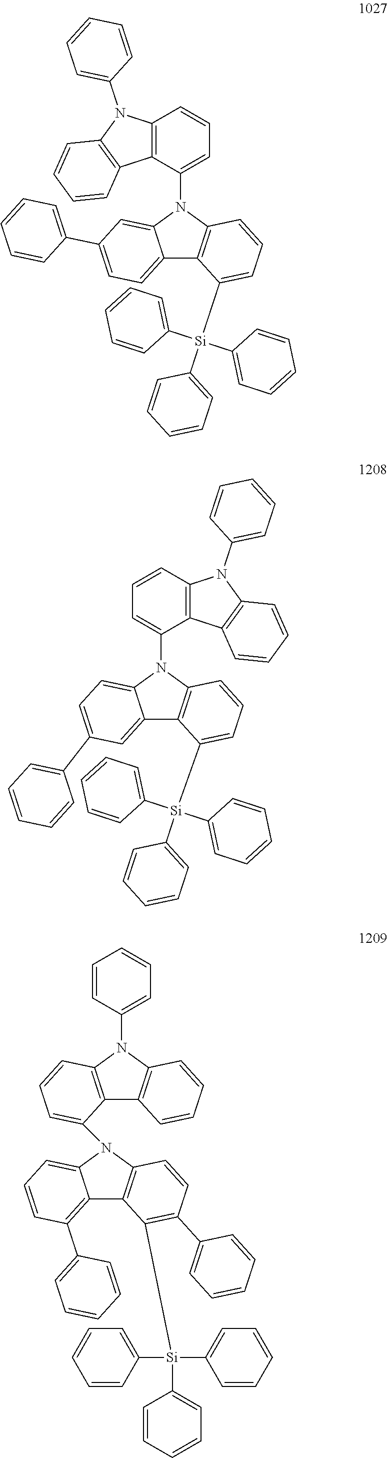 [SMILES: c1ccc(-c2ccc3c4c([Si](c5ccccc5)(c5ccccc5)c5ccccc5)cccc4n(-c4cccc5c4c4ccccc4n5-c4ccccc4)c3c2)cc1 ; c1ccc(-c2ccc3c(c2)c2c([Si](c4ccccc4)(c4ccccc4)c4ccccc4)cccc2n3-c2cccc3c2c2ccccc2n3-c2ccccc2)cc1 ; c1ccc(-c2ccc3c(c2[Si](c2ccccc2)(c2ccccc2)c2ccccc2)c2c(-c4ccccc4)cccc2n3-c2cccc3c2c2ccccc2n3-c2ccccc2)cc1]

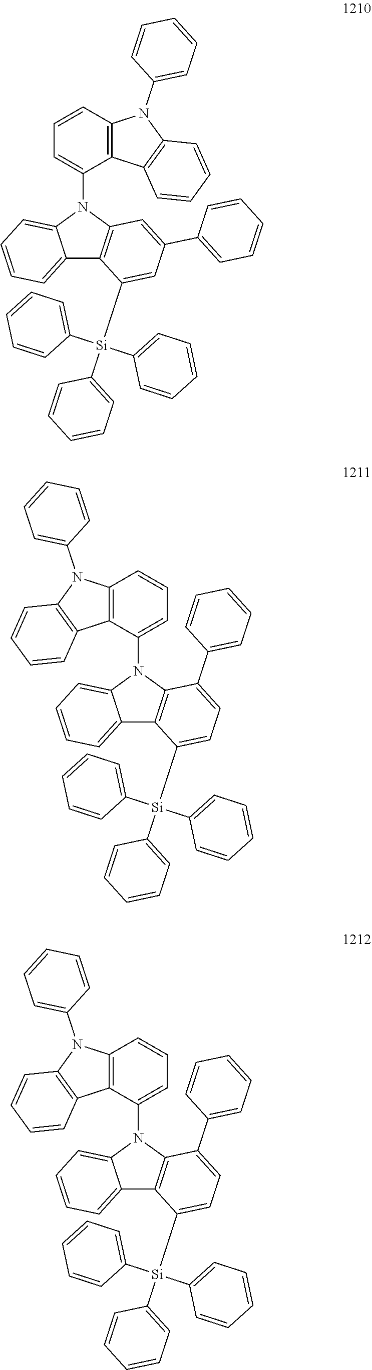 [SMILES: c1ccc(-c2cc([Si](c3ccccc3)(c3ccccc3)c3ccccc3)c3c4ccccc4n(-c4cccc5c4c4ccccc4n5-c4ccccc4)c3c2)cc1 ; c1ccc(-c2ccc([Si](c3ccccc3)(c3ccccc3)c3ccccc3)c3c4ccccc4n(-c4cccc5c4c4ccccc4n5-c4ccccc4)c23)cc1 ; c1ccc(-c2ccc([Si](c3ccccc3)(c3ccccc3)c3ccccc3)c3c4ccccc4n(-c4cccc5c4c4ccccc4n5-c4ccccc4)c23)cc1]

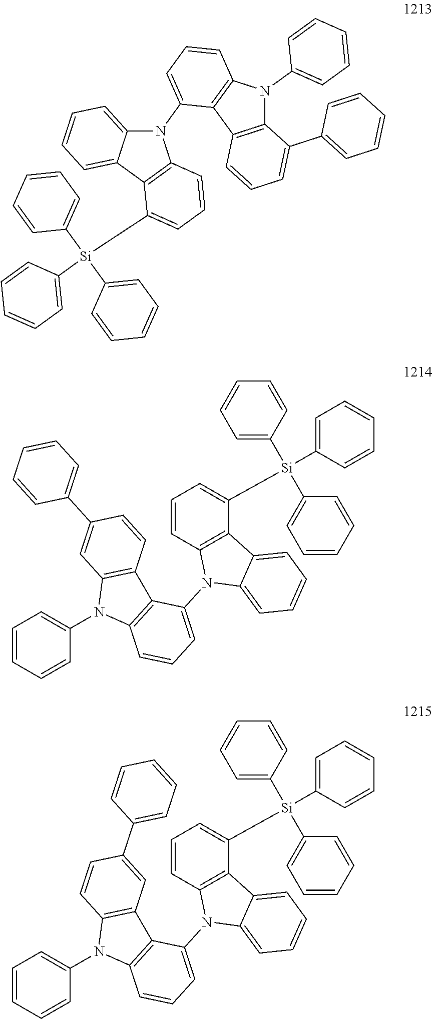 [SMILES: c1ccc(-c2cccc3c4c(-n5c6ccccc6c6c([Si](c7ccccc7)(c7ccccc7)c7ccccc7)cccc65)cccc4n(-c4ccccc4)c23)cc1 ; c1ccc(-c2ccc3c4c(-n5c6ccccc6c6c([Si](c7ccccc7)(c7ccccc7)c7ccccc7)cccc65)cccc4n(-c4ccccc4)c3c2)cc1 ; c1ccc(-c2ccc3c(c2)c2c(-n4c5ccccc5c5c([Si](c6ccccc6)(c6ccccc6)c6ccccc6)cccc54)cccc2n3-c2ccccc2)cc1]

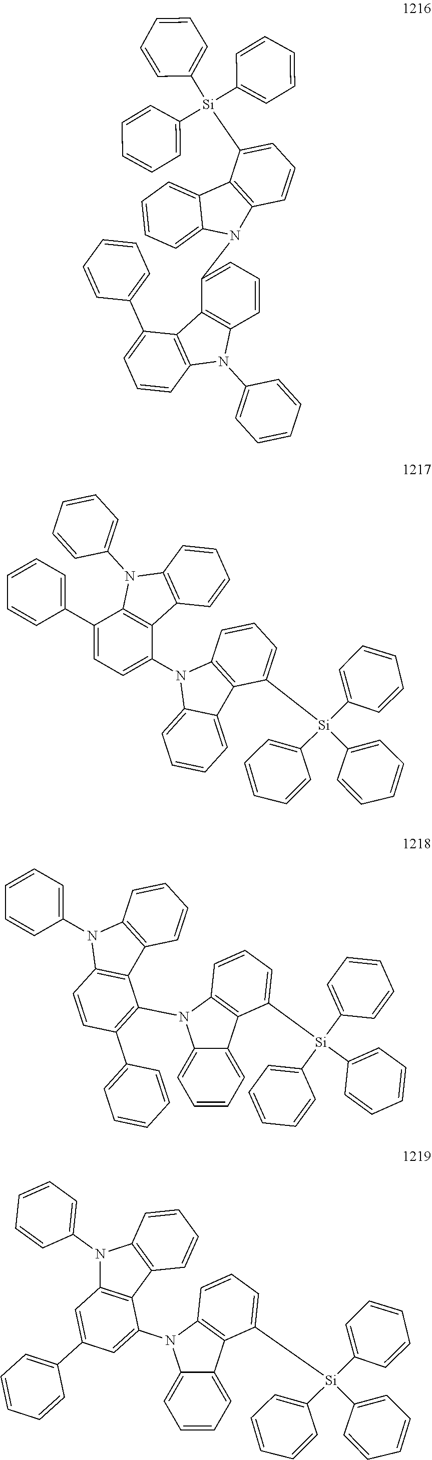 [SMILES: c1ccc(-c2cccc3c2c2c(-n4c5ccccc5c5c([Si](c6ccccc6)(c6ccccc6)c6ccccc6)cccc54)cccc2n3-c2ccccc2)cc1 ; c1ccc(-c2ccc(-n3c4ccccc4c4c([Si](c5ccccc5)(c5ccccc5)c5ccccc5)cccc43)c3c4ccccc4n(-c4ccccc4)c23)cc1 ; c1ccc(-c2ccc3c(c2-n2c4ccccc4c4c([Si](c5ccccc5)(c5ccccc5)c5ccccc5)cccc42)c2ccccc2n3-c2ccccc2)cc1 ; c1ccc(-c2cc(-n3c4ccccc4c4c([Si](c5ccccc5)(c5ccccc5)c5ccccc5)cccc43)c3c4ccccc4n(-c4ccccc4)c3c2)cc1]

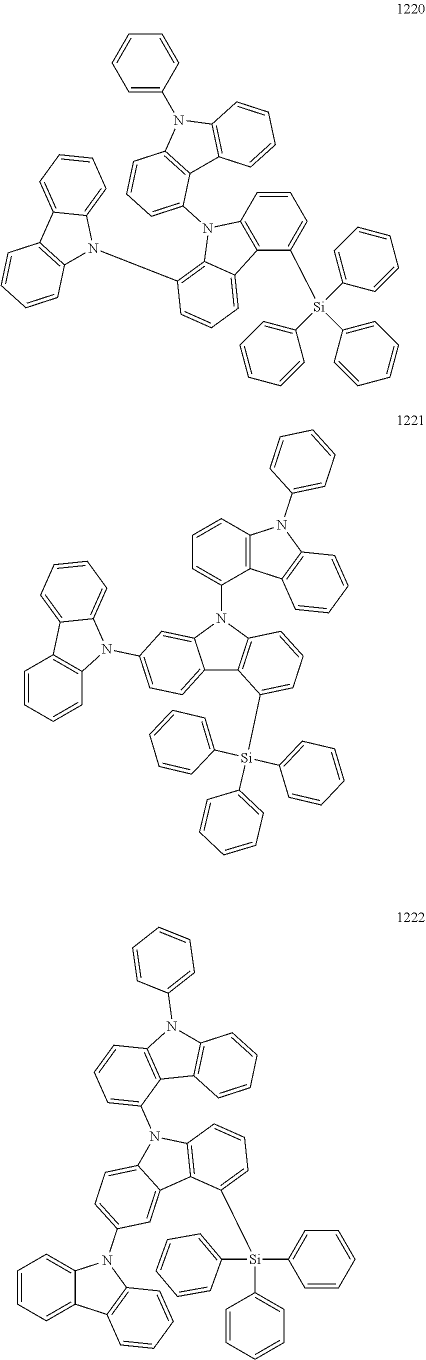 [SMILES: c1ccc(-n2c3ccccc3c3c(-n4c5cccc([Si](c6ccccc6)(c6ccccc6)c6ccccc6)c5c5cccc(-n6c7ccccc7c7ccccc76)c54)cccc32)cc1 ; c1ccc(-n2c3ccccc3c3c(-n4c5cc(-n6c7ccccc7c7ccccc76)ccc5c5c([Si](c6ccccc6)(c6ccccc6)c6ccccc6)cccc54)cccc32)cc1 ; c1ccc(-n2c3ccccc3c3c(-n4c5ccc(-n6c7ccccc7c7ccccc76)cc5c5c([Si](c6ccccc6)(c6ccccc6)c6ccccc6)cccc54)cccc32)cc1]

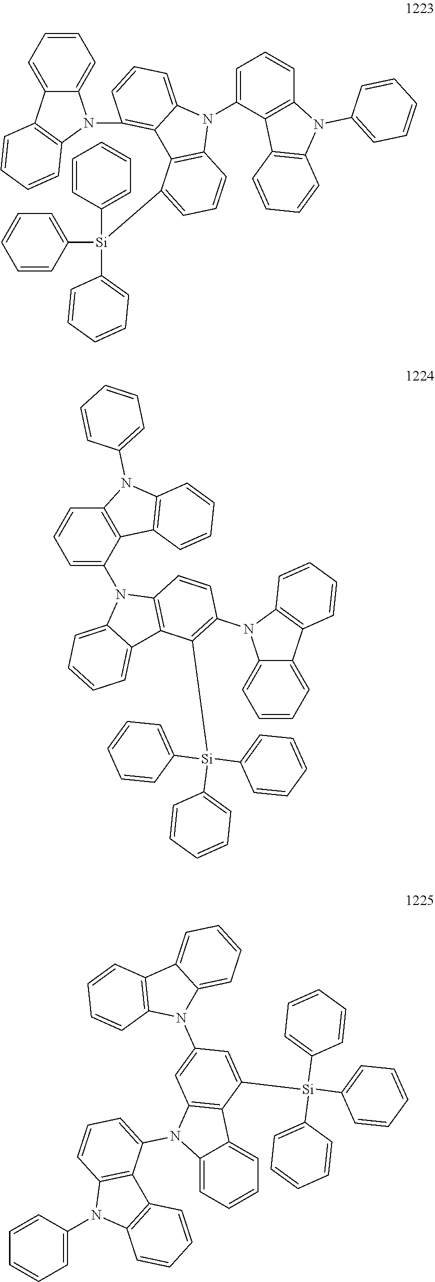

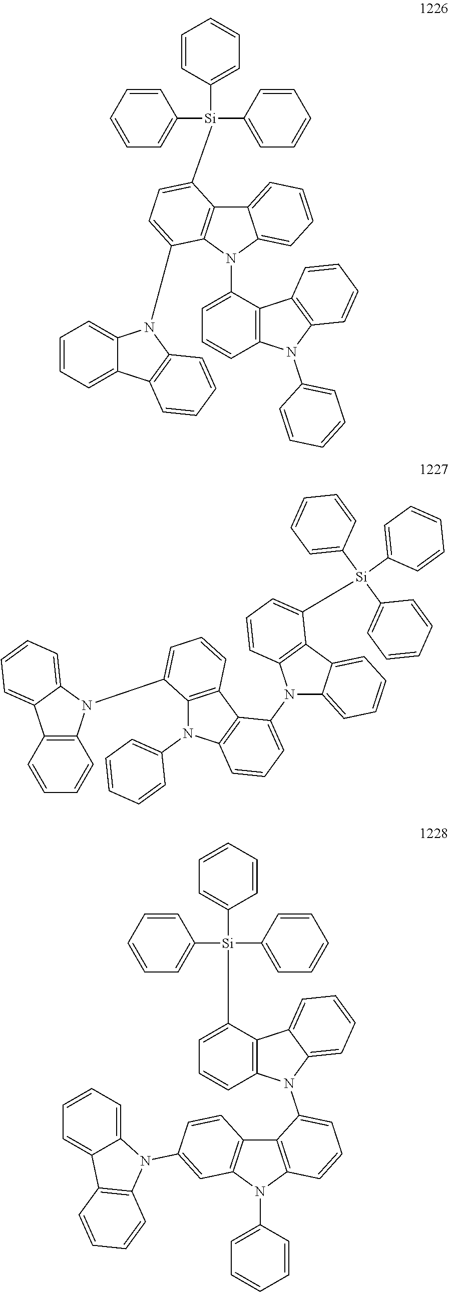 [SMILES: c1ccc(-n2c3ccccc3c3c(-n4c5ccccc5c5c([Si](c6ccccc6)(c6ccccc6)c6ccccc6)ccc(-n6c7ccccc7c7ccccc76)c54)cccc32)cc1 ; c1ccc(-n2c3cccc(-n4c5ccccc5c5c([Si](c6ccccc6)(c6ccccc6)c6ccccc6)cccc54)c3c3cccc(-n4c5ccccc5c5ccccc54)c32)cc1 ; c1ccc(-n2c3cc(-n4c5ccccc5c5ccccc54)ccc3c3c(-n4c5ccccc5c5c([Si](c6ccccc6)(c6ccccc6)c6ccccc6)cccc54)cccc32)cc1]

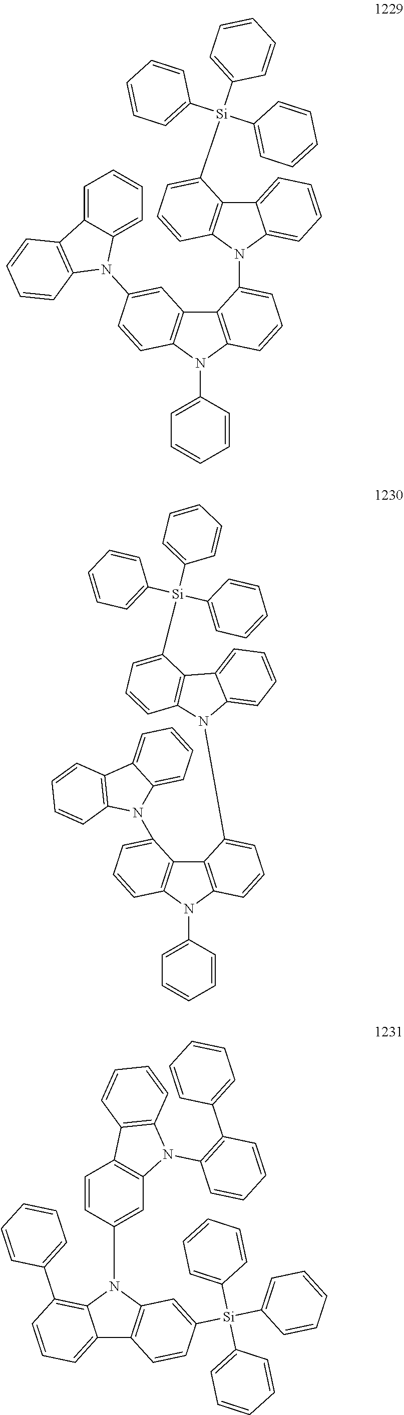

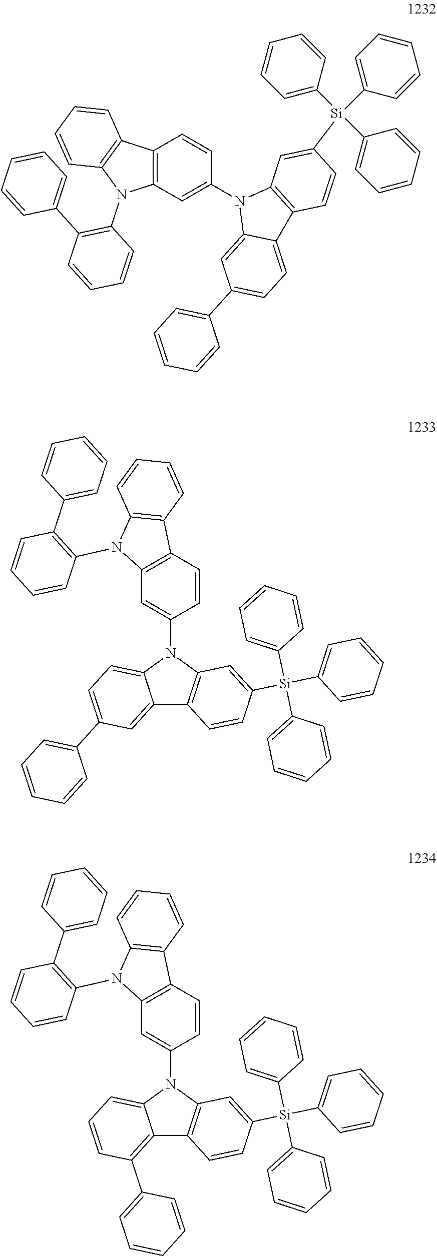 [SMILES: c1ccc(-c2ccc3c4ccc([Si](c5ccccc5)(c5ccccc5)c5ccccc5)cc4n(-c4ccc5c6ccccc6n(-c6ccccc6-c6ccccc6)c5c4)c3c2)cc1 ; c1ccc(-c2ccc3c(c2)c2ccc([Si](c4ccccc4)(c4ccccc4)c4ccccc4)cc2n3-c2ccc3c4ccccc4n(-c4ccccc4-c4ccccc4)c3c2)cc1 ; c1ccc(-c2ccccc2-n2c3ccccc3c3ccc(-n4c5cc([Si](c6ccccc6)(c6ccccc6)c6ccccc6)ccc5c5c(-c6ccccc6)cccc54)cc32)cc1]

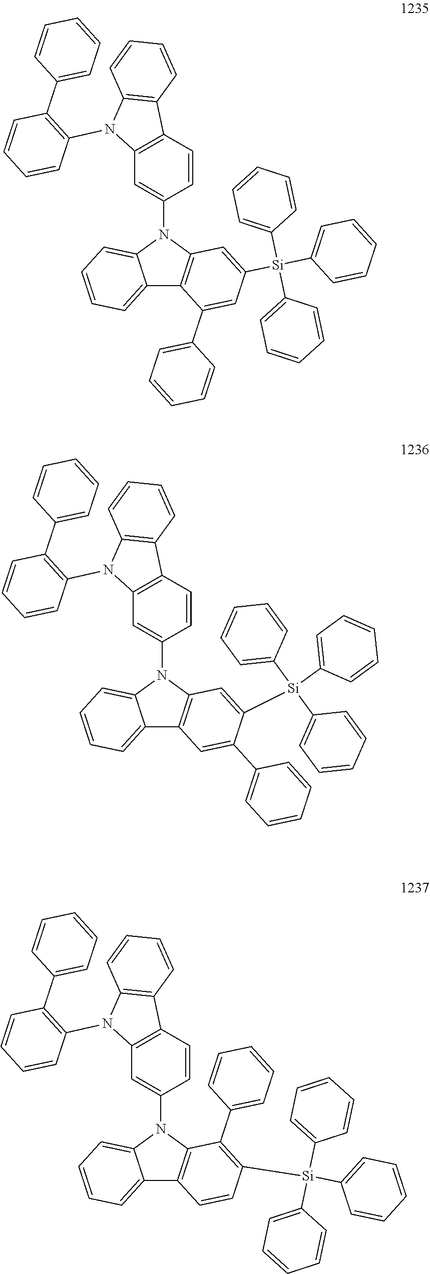 [SMILES: c1ccc(-c2ccccc2-n2c3ccccc3c3ccc(-n4c5ccccc5c5c(-c6ccccc6)cc([Si](c6ccccc6)(c6ccccc6)c6ccccc6)cc54)cc32)cc1 ; c1ccc(-c2ccccc2-n2c3ccccc3c3ccc(-n4c5ccccc5c5cc(-c6ccccc6)c([Si](c6ccccc6)(c6ccccc6)c6ccccc6)cc54)cc32)cc1 ; c1ccc(-c2ccccc2-n2c3ccccc3c3ccc(-n4c5ccccc5c5ccc([Si](c6ccccc6)(c6ccccc6)c6ccccc6)c(-c6ccccc6)c54)cc32)cc1]

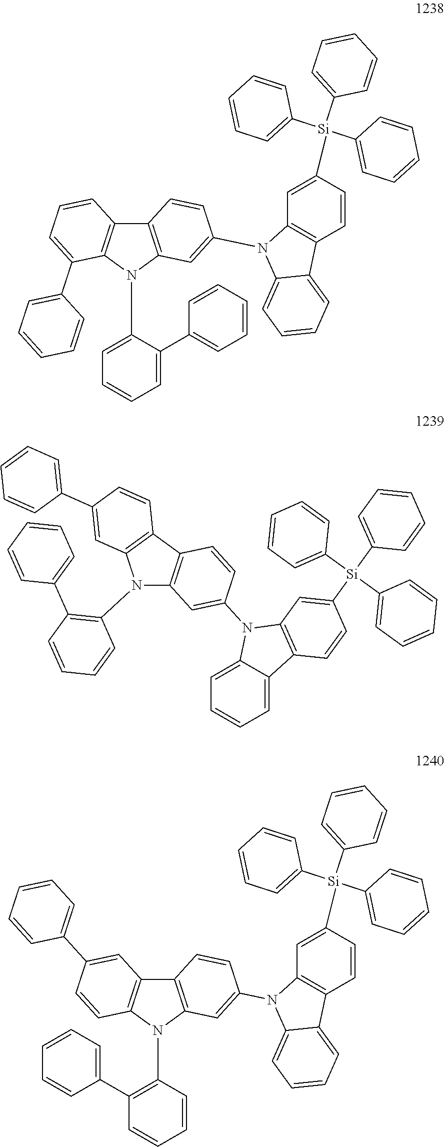 [SMILES: c1ccc(-c2ccccc2-n2c3cc(-n4c5ccccc5c5ccc([Si](c6ccccc6)(c6ccccc6)c6ccccc6)cc54)ccc3c3cccc(-c4ccccc4)c32)cc1 ; c1ccc(-c2ccc3c4ccc(-n5c6ccccc6c6ccc([Si](c7ccccc7)(c7ccccc7)c7ccccc7)cc65)cc4n(-c4ccccc4-c4ccccc4)c3c2)cc1 ; c1ccc(-c2ccc3c(c2)c2ccc(-n4c5ccccc5c5ccc([Si](c6ccccc6)(c6ccccc6)c6ccccc6)cc54)cc2n3-c2ccccc2-c2ccccc2)cc1]

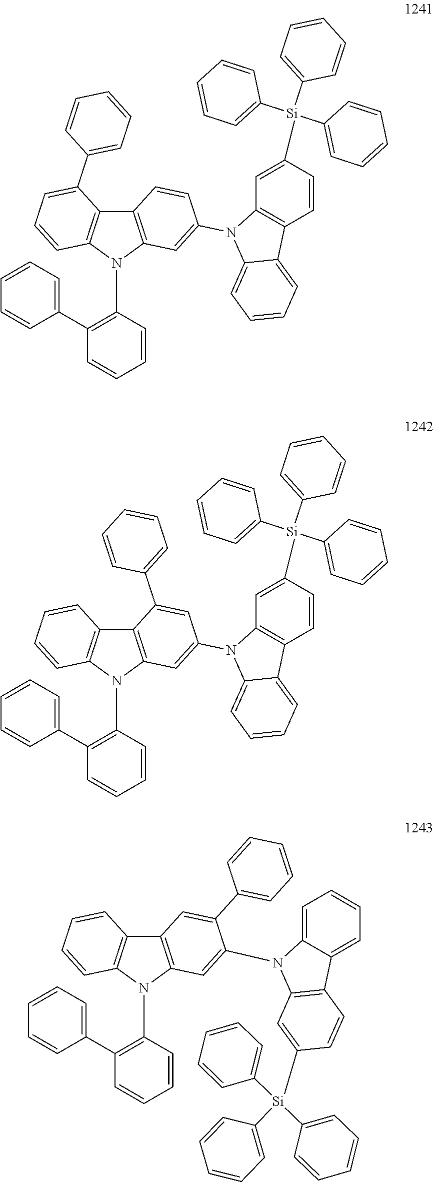 [SMILES: c1ccc(-c2ccccc2-n2c3cc(-n4c5ccccc5c5ccc([Si](c6ccccc6)(c6ccccc6)c6ccccc6)cc54)ccc3c3c(-c4ccccc4)cccc32)cc1 ; c1ccc(-c2ccccc2-n2c3ccccc3c3c(-c4ccccc4)cc(-n4c5ccccc5c5ccc([Si](c6ccccc6)(c6ccccc6)c6ccccc6)cc54)cc32)cc1 ; c1ccc(-c2ccccc2-n2c3ccccc3c3cc(-c4ccccc4)c(-n4c5ccccc5c5ccc([Si](c6ccccc6)(c6ccccc6)c6ccccc6)cc54)cc32)cc1]

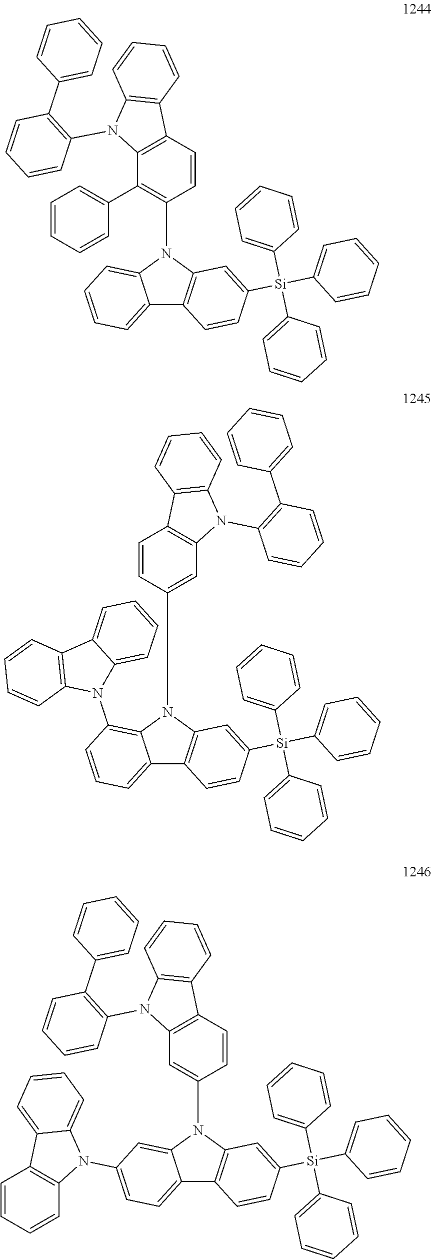

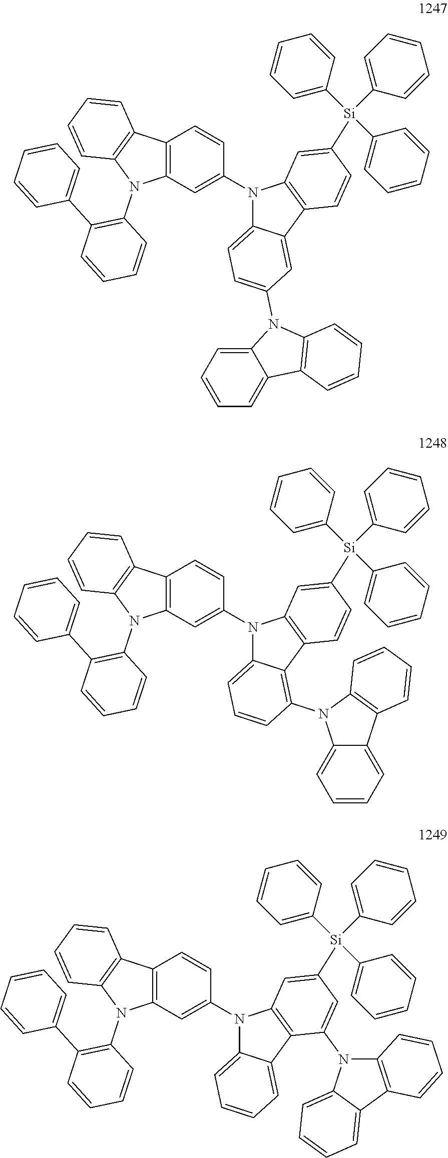 [SMILES: c1ccc(-c2ccccc2-n2c3ccccc3c3ccc(-n4c5ccc(-n6c7ccccc7c7ccccc76)cc5c5ccc([Si](c6ccccc6)(c6ccccc6)c6ccccc6)cc54)cc32)cc1 ; c1ccc(-c2ccccc2-n2c3ccccc3c3ccc(-n4c5cc([Si](c6ccccc6)(c6ccccc6)c6ccccc6)ccc5c5c(-n6c7ccccc7c7ccccc76)cccc54)cc32)cc1 ; c1ccc(-c2ccccc2-n2c3ccccc3c3ccc(-n4c5ccccc5c5c(-n6c7ccccc7c7ccccc76)cc([Si](c6ccccc6)(c6ccccc6)c6ccccc6)cc54)cc32)cc1]

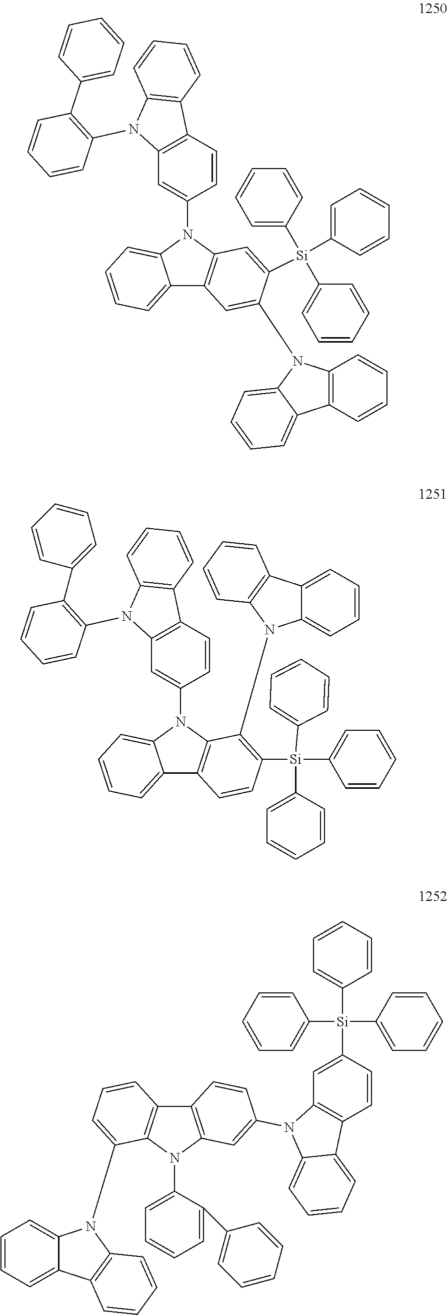 [SMILES: c1ccc(-c2ccccc2-n2c3ccccc3c3ccc(-n4c5ccccc5c5cc(-n6c7ccccc7c7ccccc76)c([Si](c6ccccc6)(c6ccccc6)c6ccccc6)cc54)cc32)cc1 ; c1ccc(-c2ccccc2-n2c3ccccc3c3ccc(-n4c5ccccc5c5ccc([Si](c6ccccc6)(c6ccccc6)c6ccccc6)c(-n6c7ccccc7c7ccccc76)c54)cc32)cc1 ; c1ccc(-c2ccccc2-n2c3cc(-n4c5ccccc5c5ccc([Si](c6ccccc6)(c6ccccc6)c6ccccc6)cc54)ccc3c3cccc(-n4c5ccccc5c5ccccc54)c32)cc1]

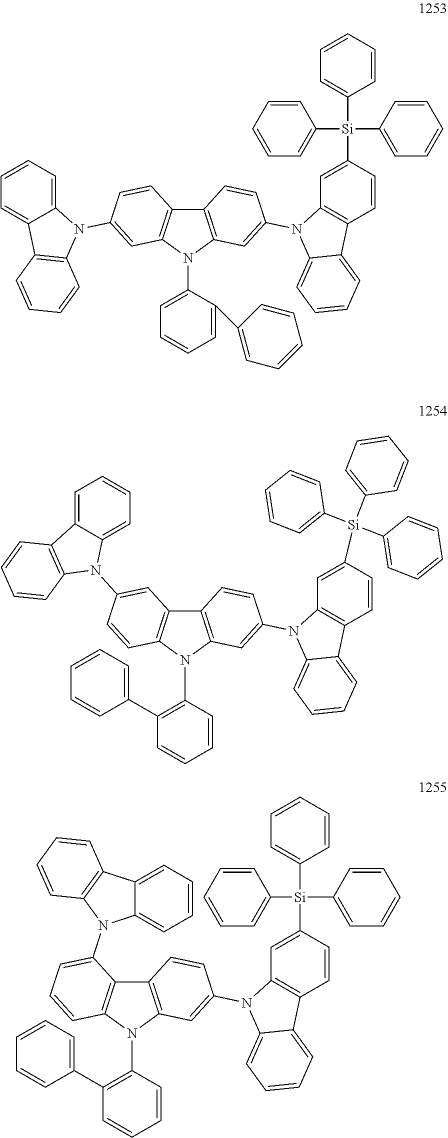 [SMILES: c1ccc(-c2ccccc2-n2c3cc(-n4c5ccccc5c5ccccc54)ccc3c3ccc(-n4c5ccccc5c5ccc([Si](c6ccccc6)(c6ccccc6)c6ccccc6)cc54)cc32)cc1 ; c1ccc(-c2ccccc2-n2c3ccc(-n4c5ccccc5c5ccccc54)cc3c3ccc(-n4c5ccccc5c5ccc([Si](c6ccccc6)(c6ccccc6)c6ccccc6)cc54)cc32)cc1 ; c1ccc(-c2ccccc2-n2c3cc(-n4c5ccccc5c5ccc([Si](c6ccccc6)(c6ccccc6)c6ccccc6)cc54)ccc3c3c(-n4c5ccccc5c5ccccc54)cccc32)cc1]

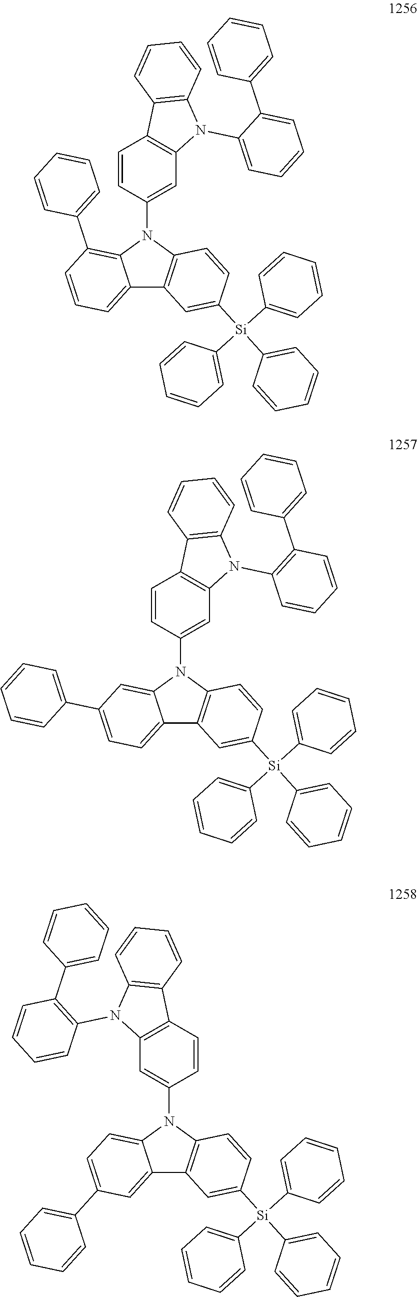

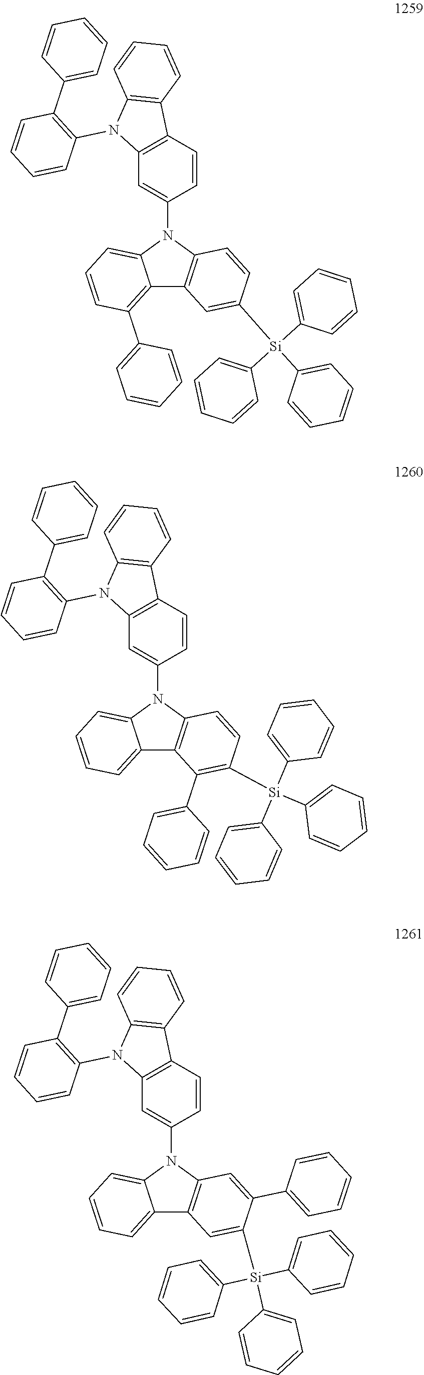 [SMILES: c1ccc(-c2ccccc2-n2c3ccccc3c3ccc(-n4c5ccc([Si](c6ccccc6)(c6ccccc6)c6ccccc6)cc5c5c(-c6ccccc6)cccc54)cc32)cc1 ; c1ccc(-c2ccccc2-n2c3ccccc3c3ccc(-n4c5ccccc5c5c(-c6ccccc6)c([Si](c6ccccc6)(c6ccccc6)c6ccccc6)ccc54)cc32)cc1 ; c1ccc(-c2ccccc2-n2c3ccccc3c3ccc(-n4c5ccccc5c5cc([Si](c6ccccc6)(c6ccccc6)c6ccccc6)c(-c6ccccc6)cc54)cc32)cc1]

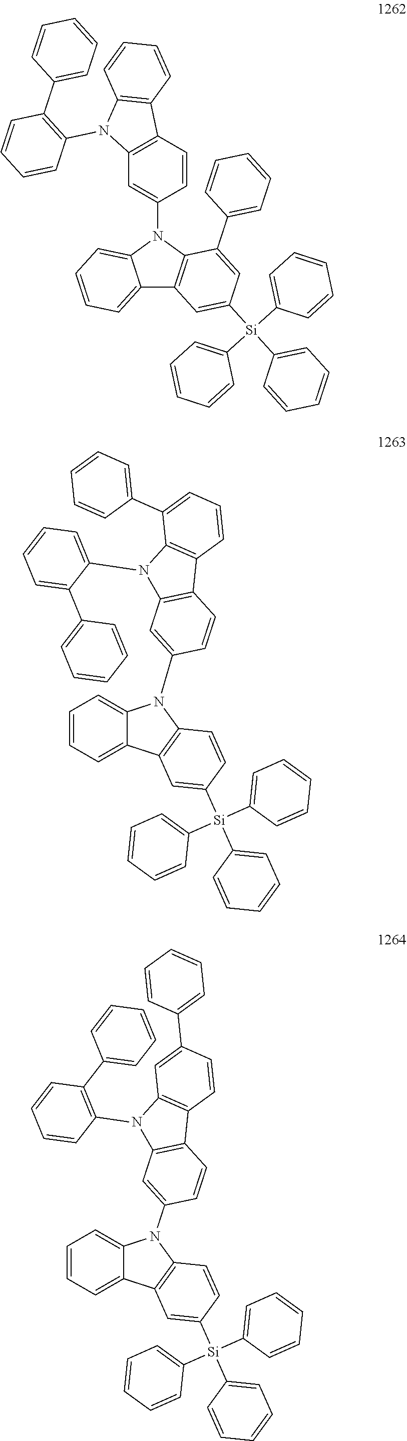 [SMILES: c1ccc(-c2ccccc2-n2c3ccccc3c3ccc(-n4c5ccccc5c5cc([Si](c6ccccc6)(c6ccccc6)c6ccccc6)cc(-c6ccccc6)c54)cc32)cc1 ; c1ccc(-c2ccccc2-n2c3cc(-n4c5ccccc5c5cc([Si](c6ccccc6)(c6ccccc6)c6ccccc6)ccc54)ccc3c3cccc(-c4ccccc4)c32)cc1 ; c1ccc(-c2ccc3c4ccc(-n5c6ccccc6c6cc([Si](c7ccccc7)(c7ccccc7)c7ccccc7)ccc65)cc4n(-c4ccccc4-c4ccccc4)c3c2)cc1]

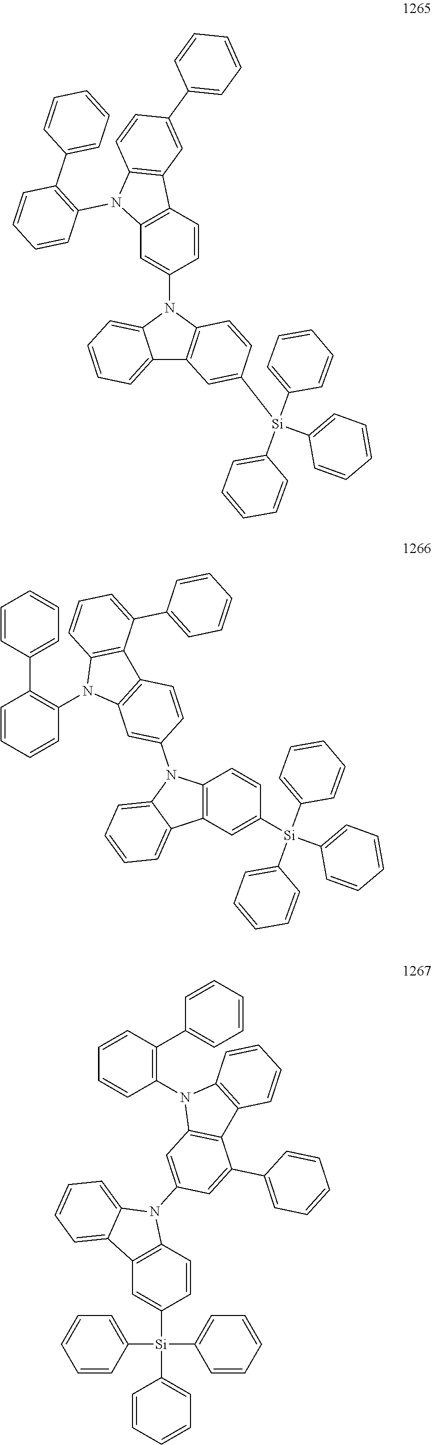 [SMILES: c1ccc(-c2ccc3c(c2)c2ccc(-n4c5ccccc5c5cc([Si](c6ccccc6)(c6ccccc6)c6ccccc6)ccc54)cc2n3-c2ccccc2-c2ccccc2)cc1 ; c1ccc(-c2ccccc2-n2c3cc(-n4c5ccccc5c5cc([Si](c6ccccc6)(c6ccccc6)c6ccccc6)ccc54)ccc3c3c(-c4ccccc4)cccc32)cc1 ; c1ccc(-c2ccccc2-n2c3ccccc3c3c(-c4ccccc4)cc(-n4c5ccccc5c5cc([Si](c6ccccc6)(c6ccccc6)c6ccccc6)ccc54)cc32)cc1]

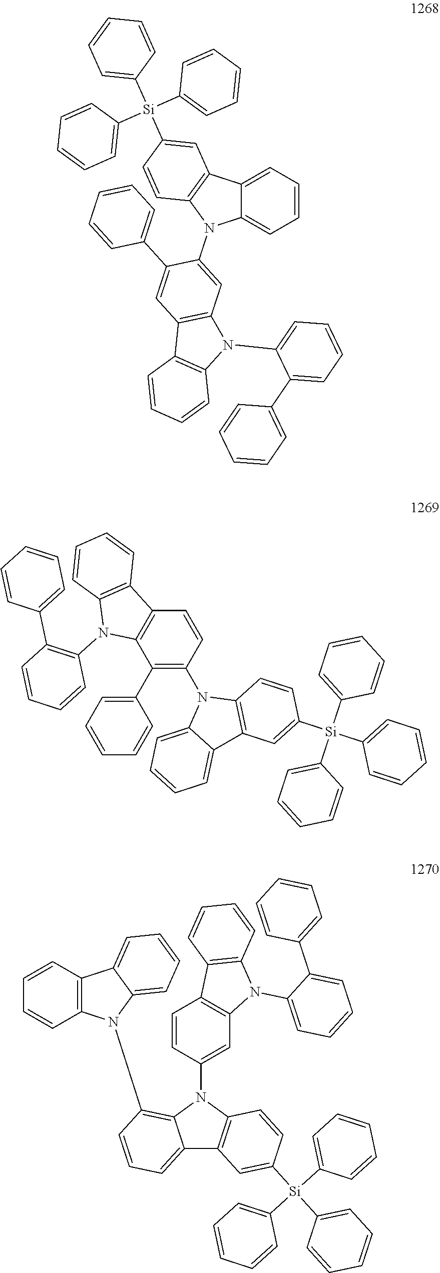 [SMILES: c1ccc(-c2ccccc2-n2c3ccccc3c3cc(-c4ccccc4)c(-n4c5ccccc5c5cc([Si](c6ccccc6)(c6ccccc6)c6ccccc6)ccc54)cc32)cc1 ; c1ccc(-c2ccccc2-n2c3ccccc3c3ccc(-n4c5ccccc5c5cc([Si](c6ccccc6)(c6ccccc6)c6ccccc6)ccc54)c(-c4ccccc4)c32)cc1 ; c1ccc(-c2ccccc2-n2c3ccccc3c3ccc(-n4c5ccc([Si](c6ccccc6)(c6ccccc6)c6ccccc6)cc5c5cccc(-n6c7ccccc7c7ccccc76)c54)cc32)cc1]

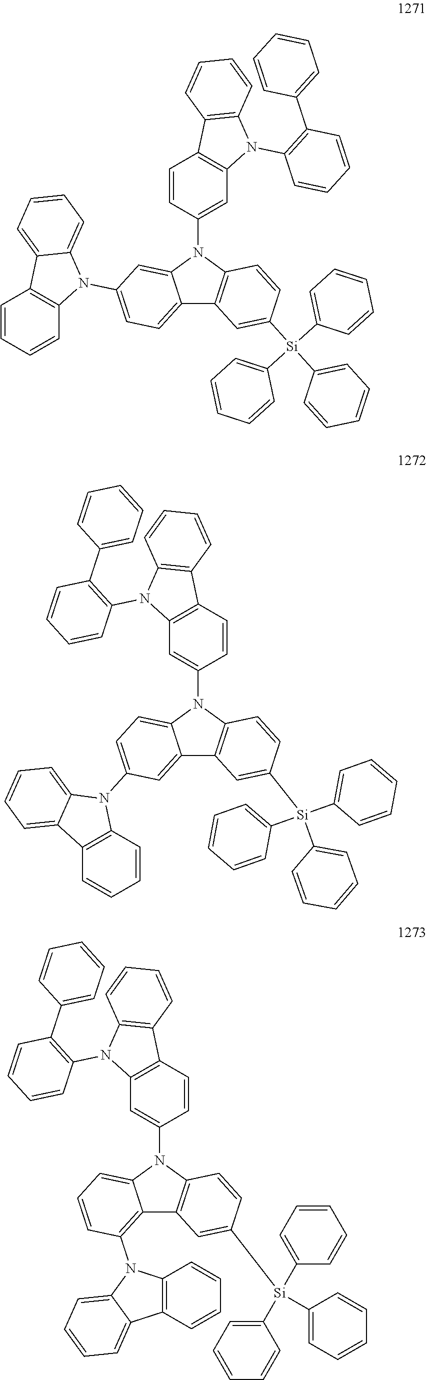 [SMILES: c1ccc(-c2ccccc2-n2c3ccccc3c3ccc(-n4c5ccc([Si](c6ccccc6)(c6ccccc6)c6ccccc6)cc5c5ccc(-n6c7ccccc7c7ccccc76)cc54)cc32)cc1 ; c1ccc(-c2ccccc2-n2c3ccccc3c3ccc(-n4c5ccc(-n6c7ccccc7c7ccccc76)cc5c5cc([Si](c6ccccc6)(c6ccccc6)c6ccccc6)ccc54)cc32)cc1 ; c1ccc(-c2ccccc2-n2c3ccccc3c3ccc(-n4c5ccc([Si](c6ccccc6)(c6ccccc6)c6ccccc6)cc5c5c(-n6c7ccccc7c7ccccc76)cccc54)cc32)cc1]

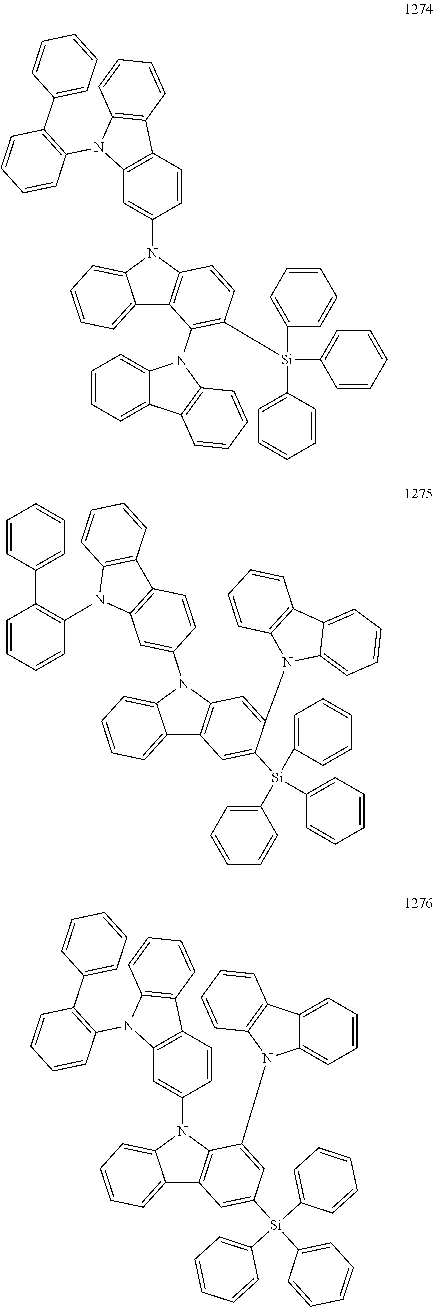 [SMILES: c1ccc(-c2ccccc2-n2c3ccccc3c3ccc(-n4c5ccccc5c5c(-n6c7ccccc7c7ccccc76)c([Si](c6ccccc6)(c6ccccc6)c6ccccc6)ccc54)cc32)cc1 ; c1ccc(-c2ccccc2-n2c3ccccc3c3ccc(-n4c5ccccc5c5cc([Si](c6ccccc6)(c6ccccc6)c6ccccc6)c(-n6c7ccccc7c7ccccc76)cc54)cc32)cc1 ; c1ccc(-c2ccccc2-n2c3ccccc3c3ccc(-n4c5ccccc5c5cc([Si](c6ccccc6)(c6ccccc6)c6ccccc6)cc(-n6c7ccccc7c7ccccc76)c54)cc32)cc1]

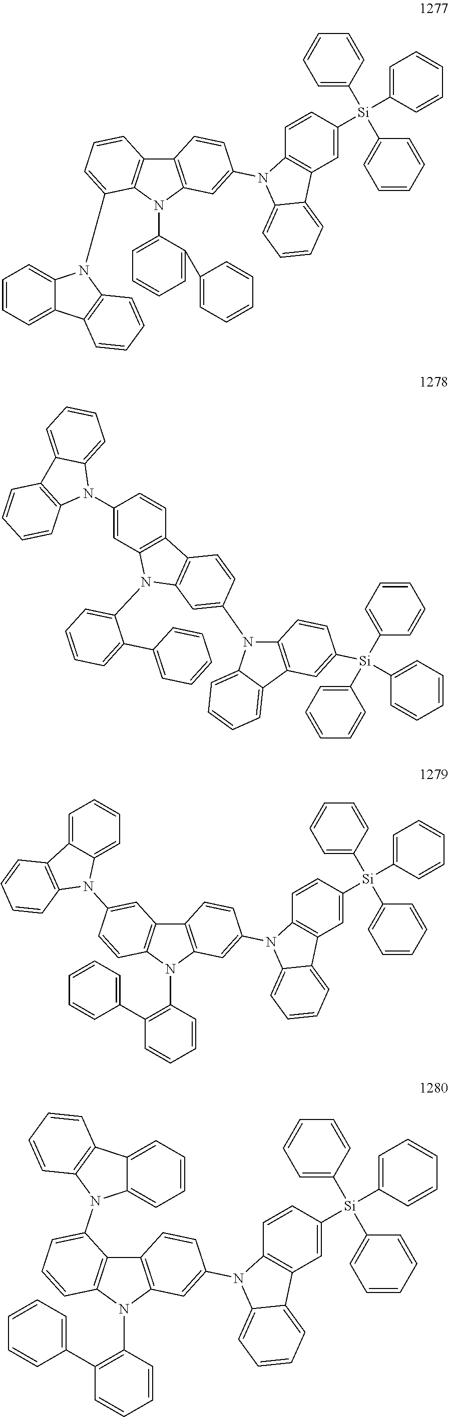 [SMILES: c1ccc(-c2ccccc2-n2c3cc(-n4c5ccccc5c5cc([Si](c6ccccc6)(c6ccccc6)c6ccccc6)ccc54)ccc3c3cccc(-n4c5ccccc5c5ccccc54)c32)cc1 ; c1ccc(-c2ccccc2-n2c3cc(-n4c5ccccc5c5ccccc54)ccc3c3ccc(-n4c5ccccc5c5cc([Si](c6ccccc6)(c6ccccc6)c6ccccc6)ccc54)cc32)cc1 ; c1ccc(-c2ccccc2-n2c3ccc(-n4c5ccccc5c5ccccc54)cc3c3ccc(-n4c5ccccc5c5cc([Si](c6ccccc6)(c6ccccc6)c6ccccc6)ccc54)cc32)cc1 ; c1ccc(-c2ccccc2-n2c3cc(-n4c5ccccc5c5cc([Si](c6ccccc6)(c6ccccc6)c6ccccc6)ccc54)ccc3c3c(-n4c5ccccc5c5ccccc54)cccc32)cc1]

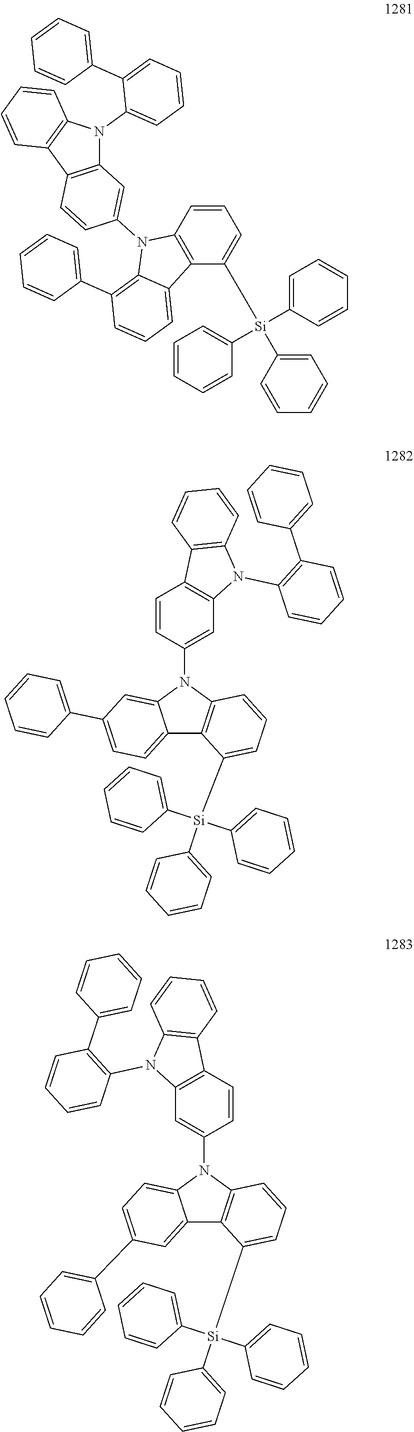 [SMILES: c1ccc(-c2ccccc2-n2c3ccccc3c3ccc(-n4c5cccc([Si](c6ccccc6)(c6ccccc6)c6ccccc6)c5c5cccc(-c6ccccc6)c54)cc32)cc1 ; c1ccc(-c2ccc3c4c([Si](c5ccccc5)(c5ccccc5)c5ccccc5)cccc4n(-c4ccc5c6ccccc6n(-c6ccccc6-c6ccccc6)c5c4)c3c2)cc1 ; c1ccc(-c2ccc3c(c2)c2c([Si](c4ccccc4)(c4ccccc4)c4ccccc4)cccc2n3-c2ccc3c4ccccc4n(-c4ccccc4-c4ccccc4)c3c2)cc1]

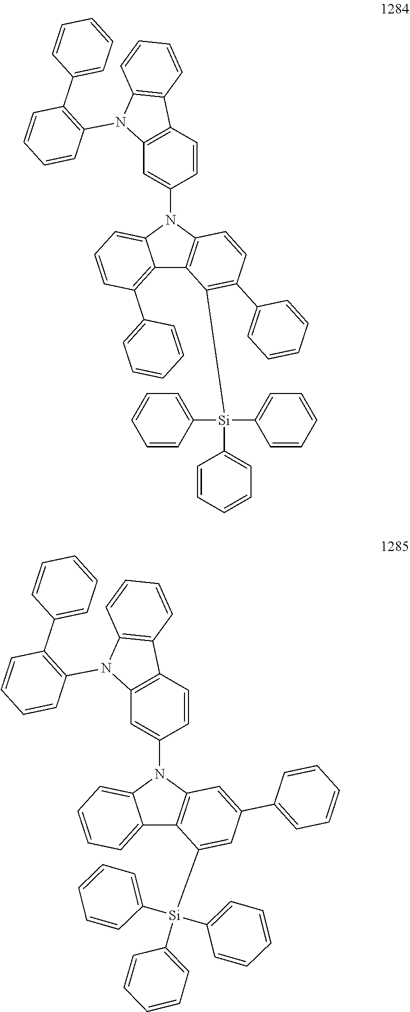 [SMILES: c1ccc(-c2ccccc2-n2c3ccccc3c3ccc(-n4c5cccc(-c6ccccc6)c5c5c([Si](c6ccccc6)(c6ccccc6)c6ccccc6)c(-c6ccccc6)ccc54)cc32)cc1 ; c1ccc(-c2cc([Si](c3ccccc3)(c3ccccc3)c3ccccc3)c3c4ccccc4n(-c4ccc5c6ccccc6n(-c6ccccc6-c6ccccc6)c5c4)c3c2)cc1]

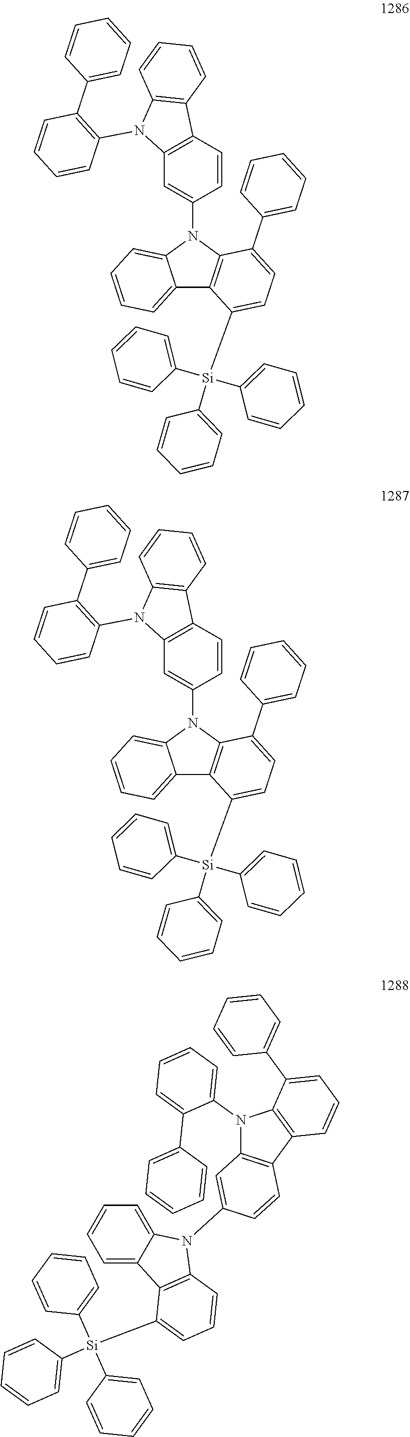 [SMILES: c1ccc(-c2ccccc2-n2c3ccccc3c3ccc(-n4c5ccccc5c5c([Si](c6ccccc6)(c6ccccc6)c6ccccc6)ccc(-c6ccccc6)c54)cc32)cc1 ; c1ccc(-c2ccccc2-n2c3ccccc3c3ccc(-n4c5ccccc5c5c([Si](c6ccccc6)(c6ccccc6)c6ccccc6)ccc(-c6ccccc6)c54)cc32)cc1 ; c1ccc(-c2ccccc2-n2c3cc(-n4c5ccccc5c5c([Si](c6ccccc6)(c6ccccc6)c6ccccc6)cccc54)ccc3c3cccc(-c4ccccc4)c32)cc1]

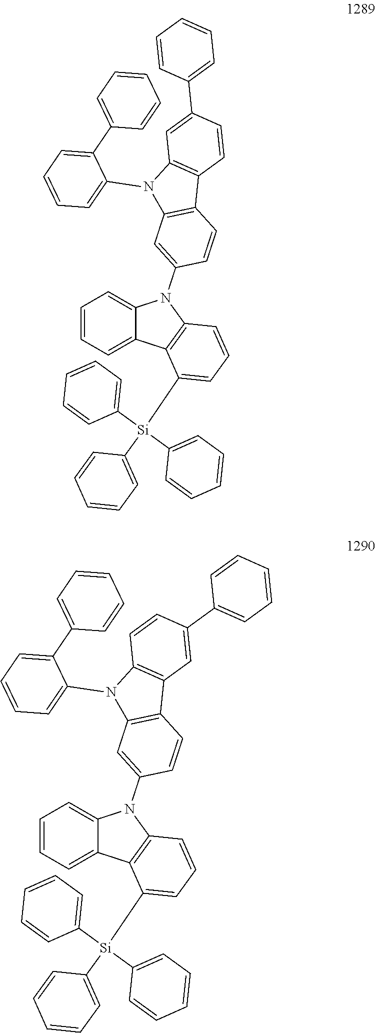 [SMILES: c1ccc(-c2ccc3c4ccc(-n5c6ccccc6c6c([Si](c7ccccc7)(c7ccccc7)c7ccccc7)cccc65)cc4n(-c4ccccc4-c4ccccc4)c3c2)cc1 ; c1ccc(-c2ccc3c(c2)c2ccc(-n4c5ccccc5c5c([Si](c6ccccc6)(c6ccccc6)c6ccccc6)cccc54)cc2n3-c2ccccc2-c2ccccc2)cc1]

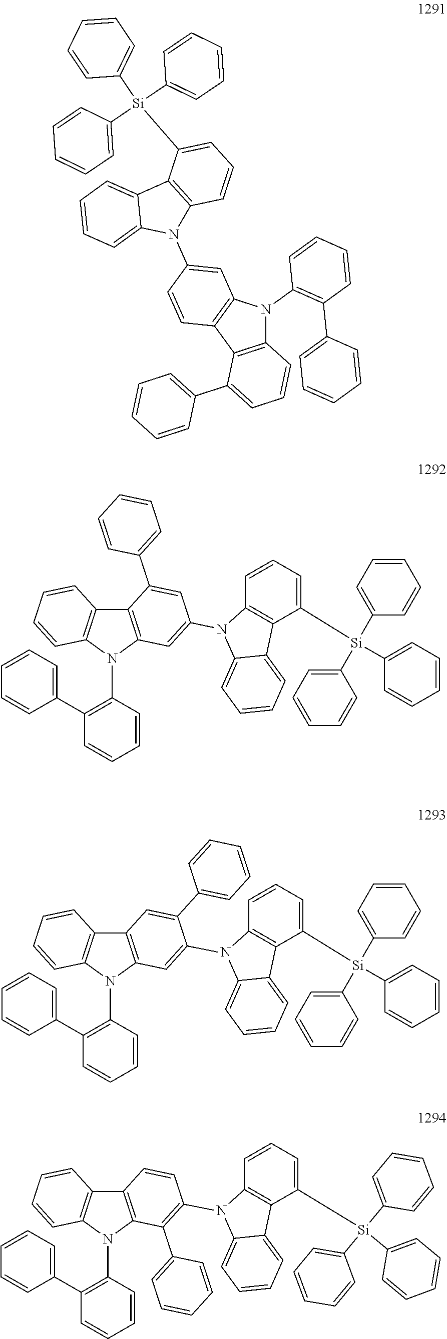 [SMILES: c1ccc(-c2ccccc2-n2c3cc(-n4c5ccccc5c5c([Si](c6ccccc6)(c6ccccc6)c6ccccc6)cccc54)ccc3c3c(-c4ccccc4)cccc32)cc1 ; c1ccc(-c2ccccc2-n2c3ccccc3c3c(-c4ccccc4)cc(-n4c5ccccc5c5c([Si](c6ccccc6)(c6ccccc6)c6ccccc6)cccc54)cc32)cc1 ; c1ccc(-c2ccccc2-n2c3ccccc3c3cc(-c4ccccc4)c(-n4c5ccccc5c5c([Si](c6ccccc6)(c6ccccc6)c6ccccc6)cccc54)cc32)cc1 ; c1ccc(-c2ccccc2-n2c3ccccc3c3ccc(-n4c5ccccc5c5c([Si](c6ccccc6)(c6ccccc6)c6ccccc6)cccc54)c(-c4ccccc4)c32)cc1]

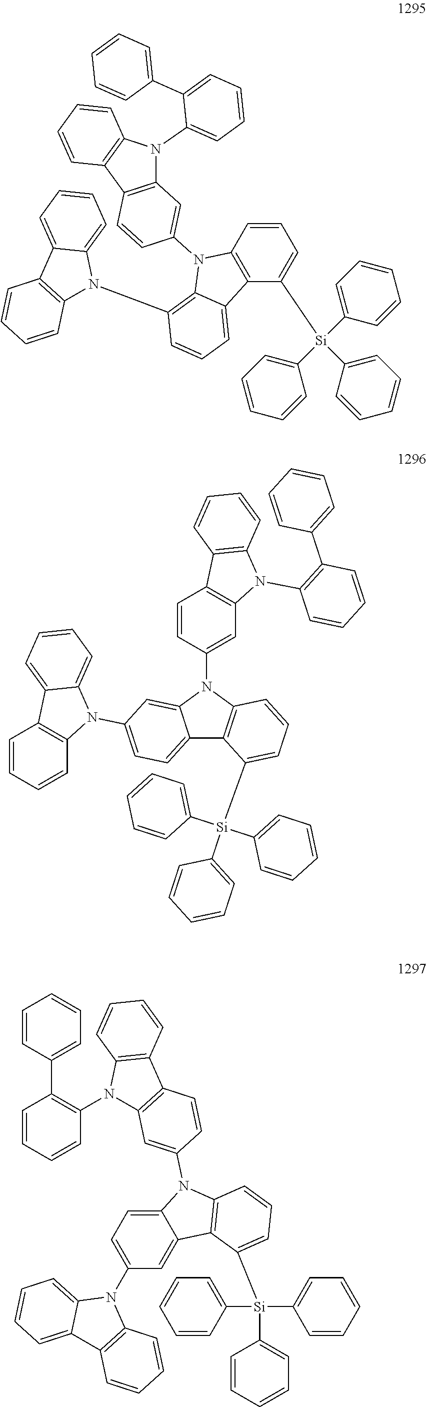 [SMILES: c1ccc(-c2ccccc2-n2c3ccccc3c3ccc(-n4c5cccc([Si](c6ccccc6)(c6ccccc6)c6ccccc6)c5c5cccc(-n6c7ccccc7c7ccccc76)c54)cc32)cc1 ; c1ccc(-c2ccccc2-n2c3ccccc3c3ccc(-n4c5cc(-n6c7ccccc7c7ccccc76)ccc5c5c([Si](c6ccccc6)(c6ccccc6)c6ccccc6)cccc54)cc32)cc1 ; c1ccc(-c2ccccc2-n2c3ccccc3c3ccc(-n4c5ccc(-n6c7ccccc7c7ccccc76)cc5c5c([Si](c6ccccc6)(c6ccccc6)c6ccccc6)cccc54)cc32)cc1]

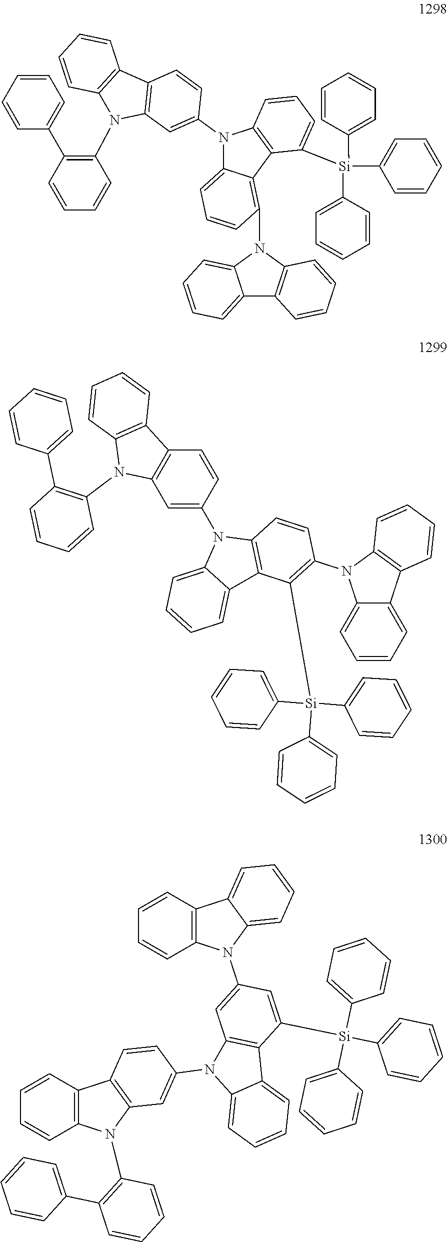 [SMILES: c1ccc(-c2ccccc2-n2c3ccccc3c3ccc(-n4c5cccc(-n6c7ccccc7c7ccccc76)c5c5c([Si](c6ccccc6)(c6ccccc6)c6ccccc6)cccc54)cc32)cc1 ; c1ccc(-c2ccccc2-n2c3ccccc3c3ccc(-n4c5ccccc5c5c([Si](c6ccccc6)(c6ccccc6)c6ccccc6)c(-n6c7ccccc7c7ccccc76)ccc54)cc32)cc1 ; c1ccc(-c2ccccc2-n2c3ccccc3c3ccc(-n4c5ccccc5c5c([Si](c6ccccc6)(c6ccccc6)c6ccccc6)cc(-n6c7ccccc7c7ccccc76)cc54)cc32)cc1]

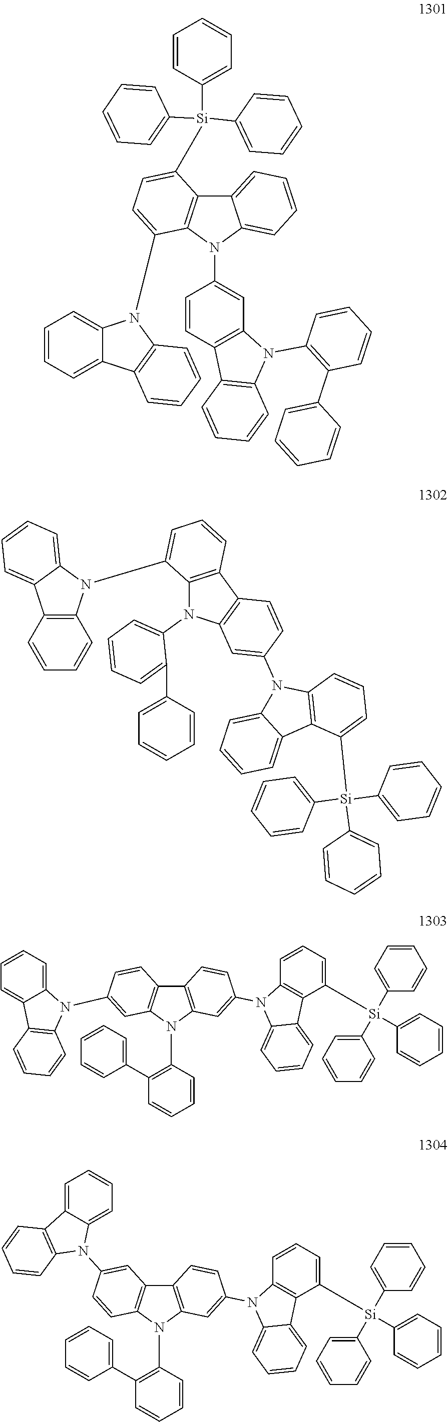 [SMILES: c1ccc(-c2ccccc2-n2c3ccccc3c3ccc(-n4c5ccccc5c5c([Si](c6ccccc6)(c6ccccc6)c6ccccc6)ccc(-n6c7ccccc7c7ccccc76)c54)cc32)cc1 ; c1ccc(-c2ccccc2-n2c3cc(-n4c5ccccc5c5c([Si](c6ccccc6)(c6ccccc6)c6ccccc6)cccc54)ccc3c3cccc(-n4c5ccccc5c5ccccc54)c32)cc1 ; c1ccc(-c2ccccc2-n2c3cc(-n4c5ccccc5c5ccccc54)ccc3c3ccc(-n4c5ccccc5c5c([Si](c6ccccc6)(c6ccccc6)c6ccccc6)cccc54)cc32)cc1 ; c1ccc(-c2ccccc2-n2c3ccc(-n4c5ccccc5c5ccccc54)cc3c3ccc(-n4c5ccccc5c5c([Si](c6ccccc6)(c6ccccc6)c6ccccc6)cccc54)cc32)cc1]

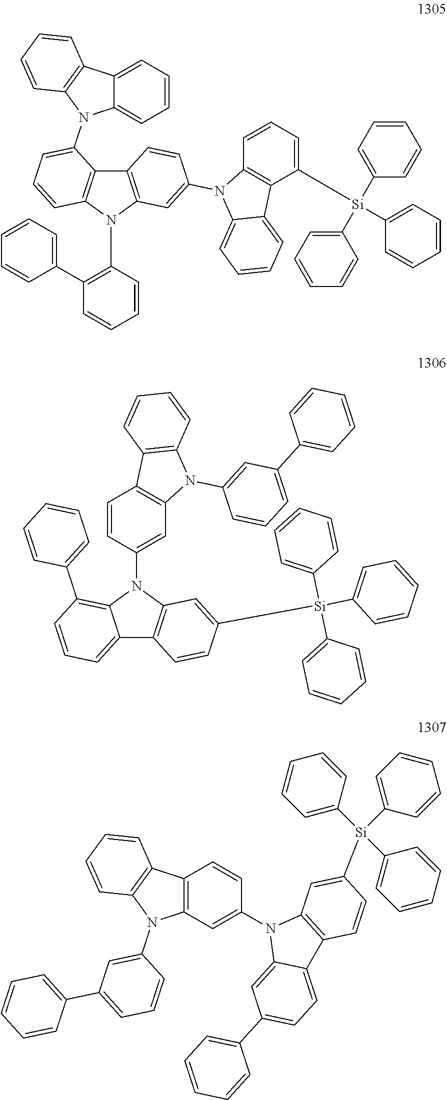 [SMILES: c1ccc(-c2ccccc2-n2c3cc(-n4c5ccccc5c5c([Si](c6ccccc6)(c6ccccc6)c6ccccc6)cccc54)ccc3c3c(-n4c5ccccc5c5ccccc54)cccc32)cc1 ; c1ccc(-c2cccc(-n3c4ccccc4c4ccc(-n5c6cc([Si](c7ccccc7)(c7ccccc7)c7ccccc7)ccc6c6cccc(-c7ccccc7)c65)cc43)c2)cc1 ; c1ccc(-c2cccc(-n3c4ccccc4c4ccc(-n5c6cc(-c7ccccc7)ccc6c6ccc([Si](c7ccccc7)(c7ccccc7)c7ccccc7)cc65)cc43)c2)cc1]

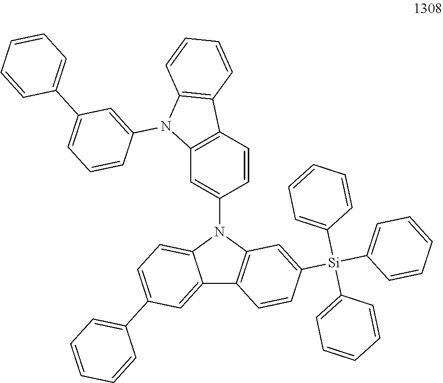 [SMILES: c1ccc(-c2cccc(-n3c4ccccc4c4ccc(-n5c6ccc(-c7ccccc7)cc6c6ccc([Si](c7ccccc7)(c7ccccc7)c7ccccc7)cc65)cc43)c2)cc1]

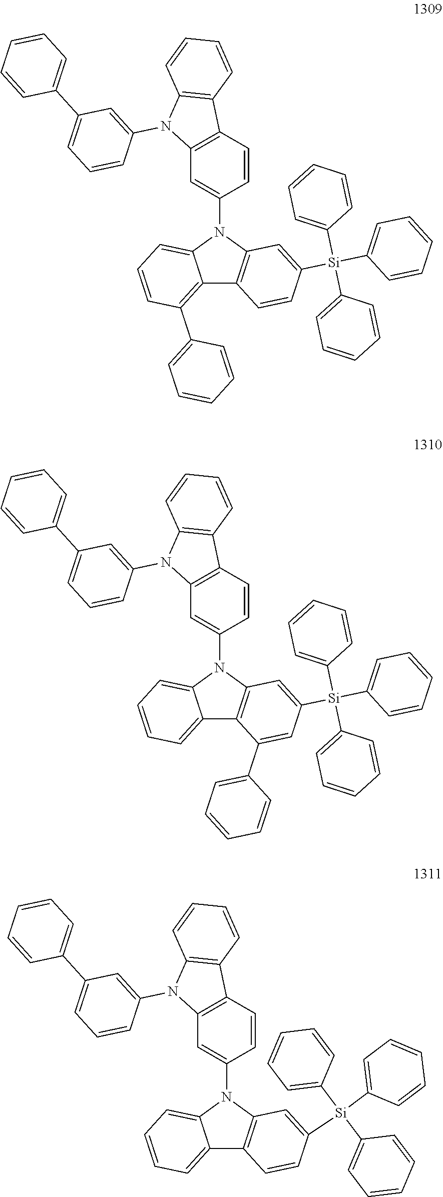 [SMILES: c1ccc(-c2cccc(-n3c4ccccc4c4ccc(-n5c6cc([Si](c7ccccc7)(c7ccccc7)c7ccccc7)ccc6c6c(-c7ccccc7)cccc65)cc43)c2)cc1 ; c1ccc(-c2cccc(-n3c4ccccc4c4ccc(-n5c6ccccc6c6c(-c7ccccc7)cc([Si](c7ccccc7)(c7ccccc7)c7ccccc7)cc65)cc43)c2)cc1 ; c1ccc(-c2cccc(-n3c4ccccc4c4ccc(-n5c6ccccc6c6ccc([Si](c7ccccc7)(c7ccccc7)c7ccccc7)cc65)cc43)c2)cc1]

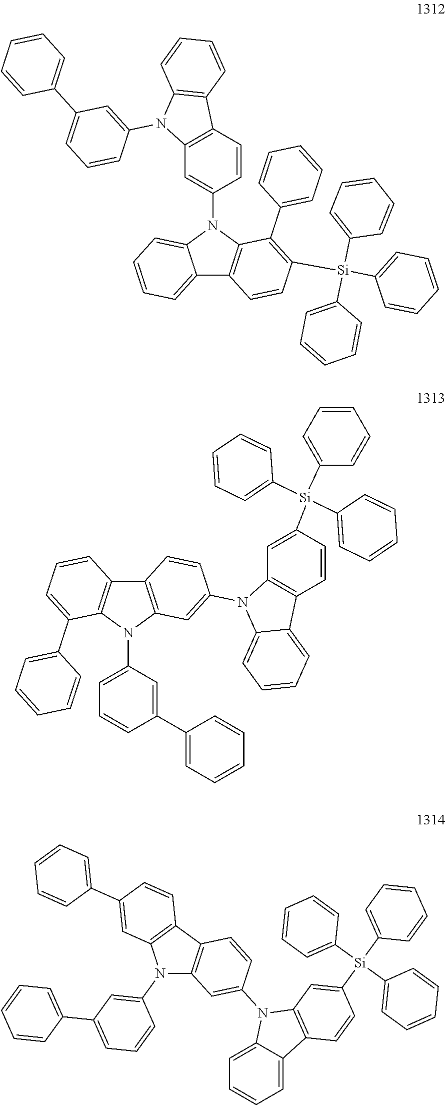

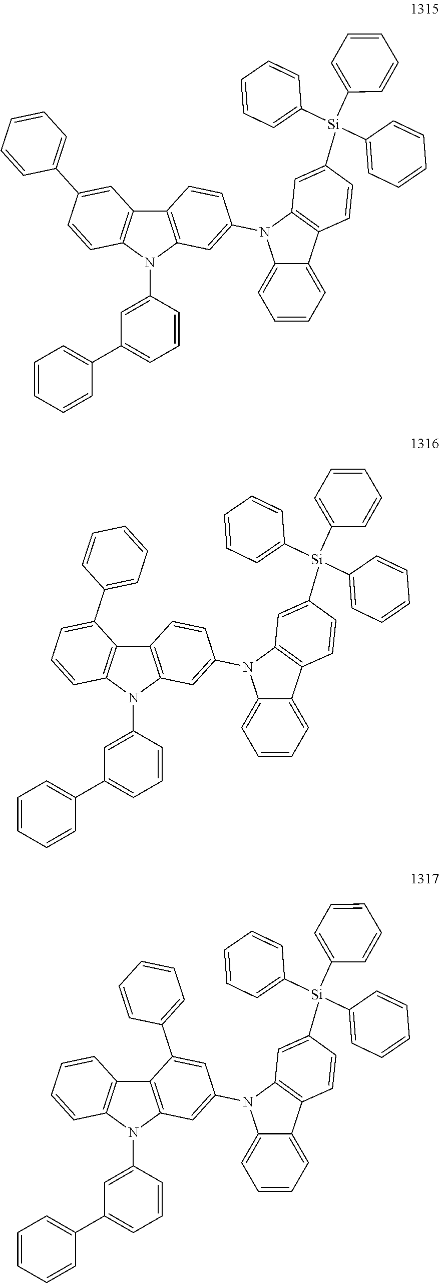 [SMILES: c1ccc(-c2cccc(-n3c4ccc(-c5ccccc5)cc4c4ccc(-n5c6ccccc6c6ccc([Si](c7ccccc7)(c7ccccc7)c7ccccc7)cc65)cc43)c2)cc1 ; c1ccc(-c2cccc(-n3c4cc(-n5c6ccccc6c6ccc([Si](c7ccccc7)(c7ccccc7)c7ccccc7)cc65)ccc4c4c(-c5ccccc5)cccc43)c2)cc1 ; c1ccc(-c2cccc(-n3c4ccccc4c4c(-c5ccccc5)cc(-n5c6ccccc6c6ccc([Si](c7ccccc7)(c7ccccc7)c7ccccc7)cc65)cc43)c2)cc1]

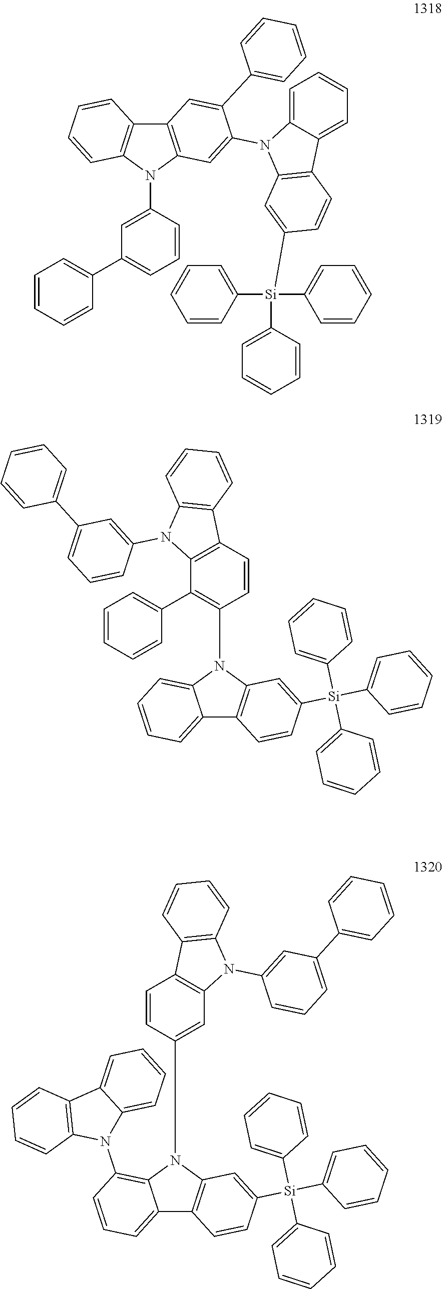 [SMILES: c1ccc(-c2cccc(-n3c4ccccc4c4cc(-c5ccccc5)c(-n5c6ccccc6c6ccc([Si](c7ccccc7)(c7ccccc7)c7ccccc7)cc65)cc43)c2)cc1 ; c1ccc(-c2cccc(-n3c4ccccc4c4ccc(-n5c6ccccc6c6ccc([Si](c7ccccc7)(c7ccccc7)c7ccccc7)cc65)c(-c5ccccc5)c43)c2)cc1 ; c1ccc(-c2cccc(-n3c4ccccc4c4ccc(-n5c6cc([Si](c7ccccc7)(c7ccccc7)c7ccccc7)ccc6c6cccc(-n7c8ccccc8c8ccccc87)c65)cc43)c2)cc1]

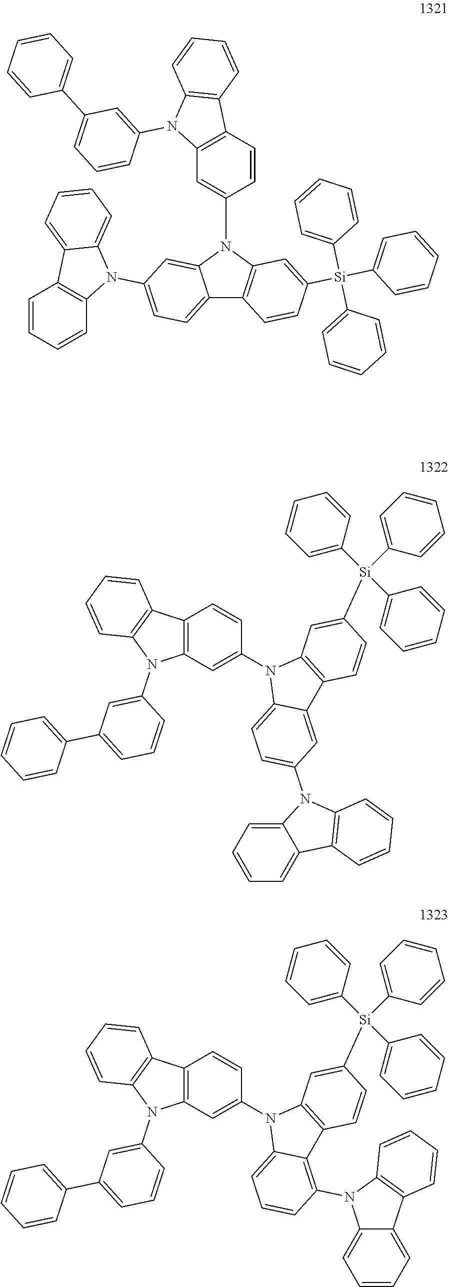 [SMILES: c1ccc(-c2cccc(-n3c4ccccc4c4ccc(-n5c6cc(-n7c8ccccc8c8ccccc87)ccc6c6ccc([Si](c7ccccc7)(c7ccccc7)c7ccccc7)cc65)cc43)c2)cc1 ; c1ccc(-c2cccc(-n3c4ccccc4c4ccc(-n5c6ccc(-n7c8ccccc8c8ccccc87)cc6c6ccc([Si](c7ccccc7)(c7ccccc7)c7ccccc7)cc65)cc43)c2)cc1 ; c1ccc(-c2cccc(-n3c4ccccc4c4ccc(-n5c6cc([Si](c7ccccc7)(c7ccccc7)c7ccccc7)ccc6c6c(-n7c8ccccc8c8ccccc87)cccc65)cc43)c2)cc1]

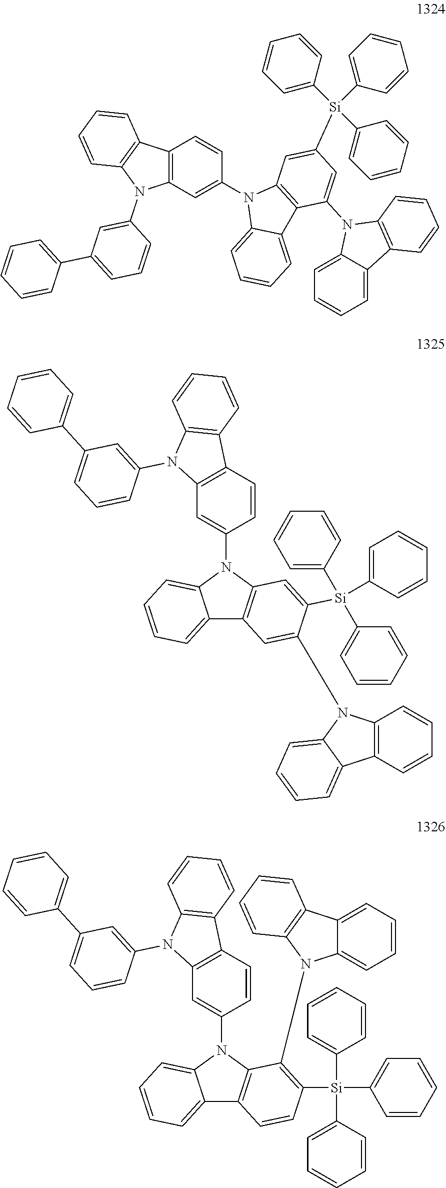 [SMILES: c1ccc(-c2cccc(-n3c4ccccc4c4ccc(-n5c6ccccc6c6c(-n7c8ccccc8c8ccccc87)cc([Si](c7ccccc7)(c7ccccc7)c7ccccc7)cc65)cc43)c2)cc1 ; c1ccc(-c2cccc(-n3c4ccccc4c4ccc(-n5c6ccccc6c6cc(-n7c8ccccc8c8ccccc87)c([Si](c7ccccc7)(c7ccccc7)c7ccccc7)cc65)cc43)c2)cc1 ; c1ccc(-c2cccc(-n3c4ccccc4c4ccc(-n5c6ccccc6c6ccc([Si](c7ccccc7)(c7ccccc7)c7ccccc7)c(-n7c8ccccc8c8ccccc87)c65)cc43)c2)cc1]

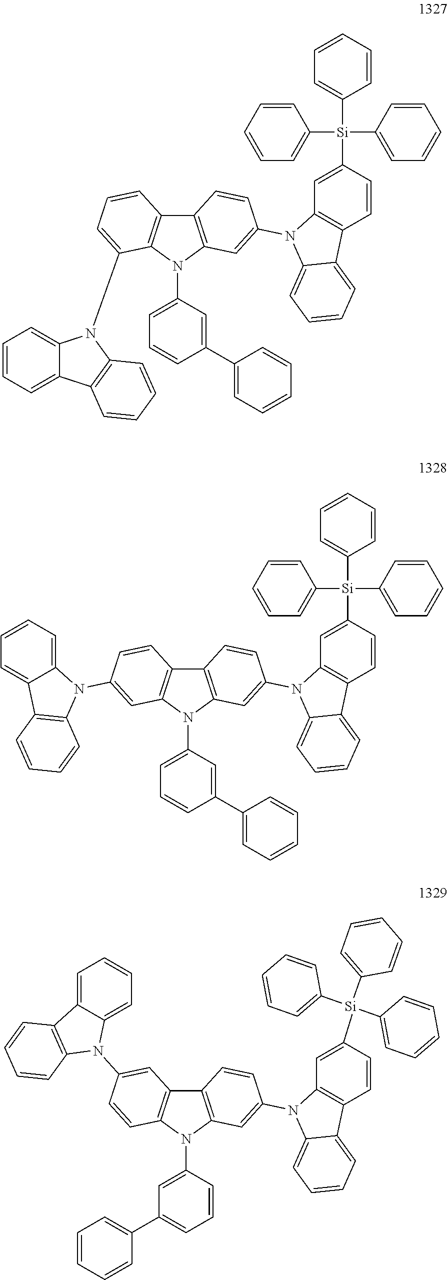 [SMILES: c1ccc(-c2cccc(-n3c4cc(-n5c6ccccc6c6ccc([Si](c7ccccc7)(c7ccccc7)c7ccccc7)cc65)ccc4c4cccc(-n5c6ccccc6c6ccccc65)c43)c2)cc1 ; c1ccc(-c2cccc(-n3c4cc(-n5c6ccccc6c6ccccc65)ccc4c4ccc(-n5c6ccccc6c6ccc([Si](c7ccccc7)(c7ccccc7)c7ccccc7)cc65)cc43)c2)cc1 ; c1ccc(-c2cccc(-n3c4ccc(-n5c6ccccc6c6ccccc65)cc4c4ccc(-n5c6ccccc6c6ccc([Si](c7ccccc7)(c7ccccc7)c7ccccc7)cc65)cc43)c2)cc1]

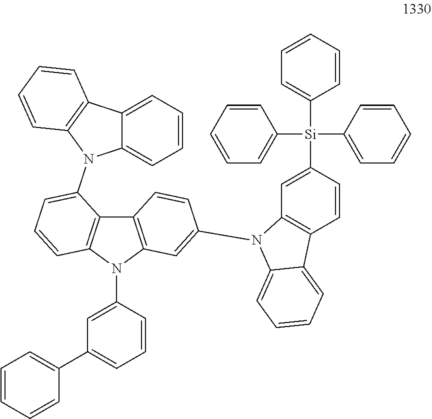 [SMILES: c1ccc(-c2cccc(-n3c4cc(-n5c6ccccc6c6ccc([Si](c7ccccc7)(c7ccccc7)c7ccccc7)cc65)ccc4c4c(-n5c6ccccc6c6ccccc65)cccc43)c2)cc1]

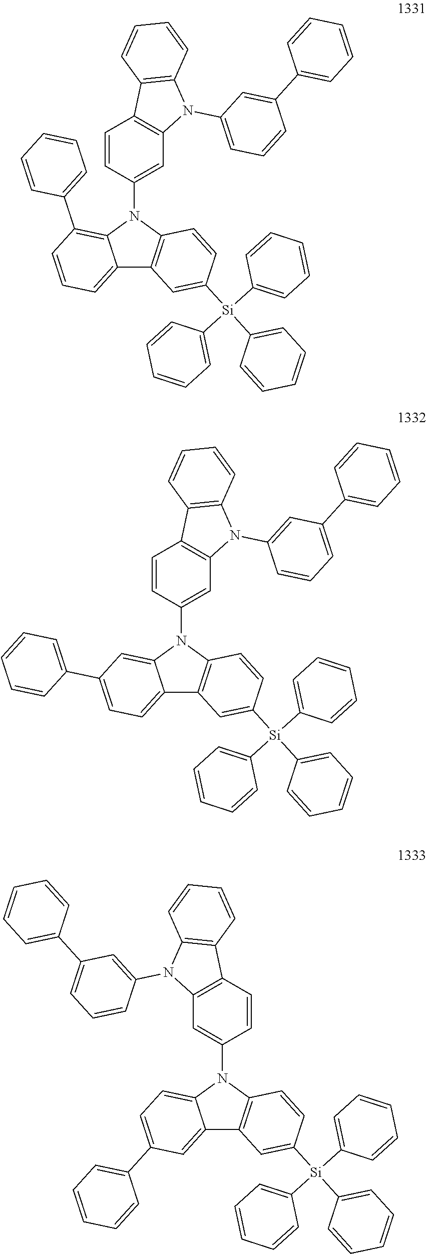 [SMILES: c1ccc(-c2cccc(-n3c4ccccc4c4ccc(-n5c6ccc([Si](c7ccccc7)(c7ccccc7)c7ccccc7)cc6c6cccc(-c7ccccc7)c65)cc43)c2)cc1 ; c1ccc(-c2cccc(-n3c4ccccc4c4ccc(-n5c6ccc([Si](c7ccccc7)(c7ccccc7)c7ccccc7)cc6c6ccc(-c7ccccc7)cc65)cc43)c2)cc1 ; c1ccc(-c2cccc(-n3c4ccccc4c4ccc(-n5c6ccc(-c7ccccc7)cc6c6cc([Si](c7ccccc7)(c7ccccc7)c7ccccc7)ccc65)cc43)c2)cc1]

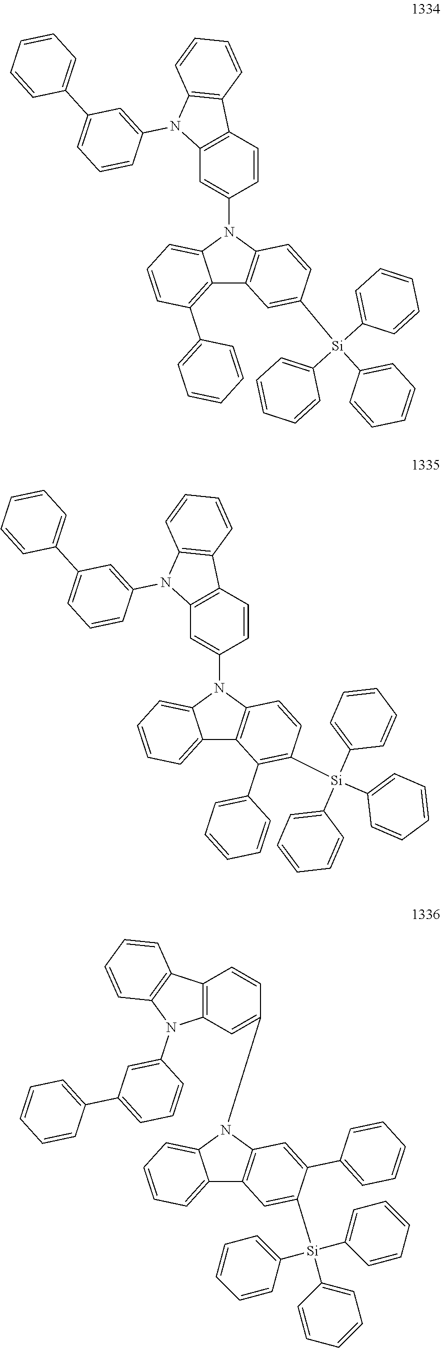 [SMILES: c1ccc(-c2cccc(-n3c4ccccc4c4ccc(-n5c6ccc([Si](c7ccccc7)(c7ccccc7)c7ccccc7)cc6c6c(-c7ccccc7)cccc65)cc43)c2)cc1 ; c1ccc(-c2cccc(-n3c4ccccc4c4ccc(-n5c6ccccc6c6c(-c7ccccc7)c([Si](c7ccccc7)(c7ccccc7)c7ccccc7)ccc65)cc43)c2)cc1 ; c1ccc(-c2cccc(-n3c4ccccc4c4ccc(-n5c6ccccc6c6cc([Si](c7ccccc7)(c7ccccc7)c7ccccc7)c(-c7ccccc7)cc65)cc43)c2)cc1]

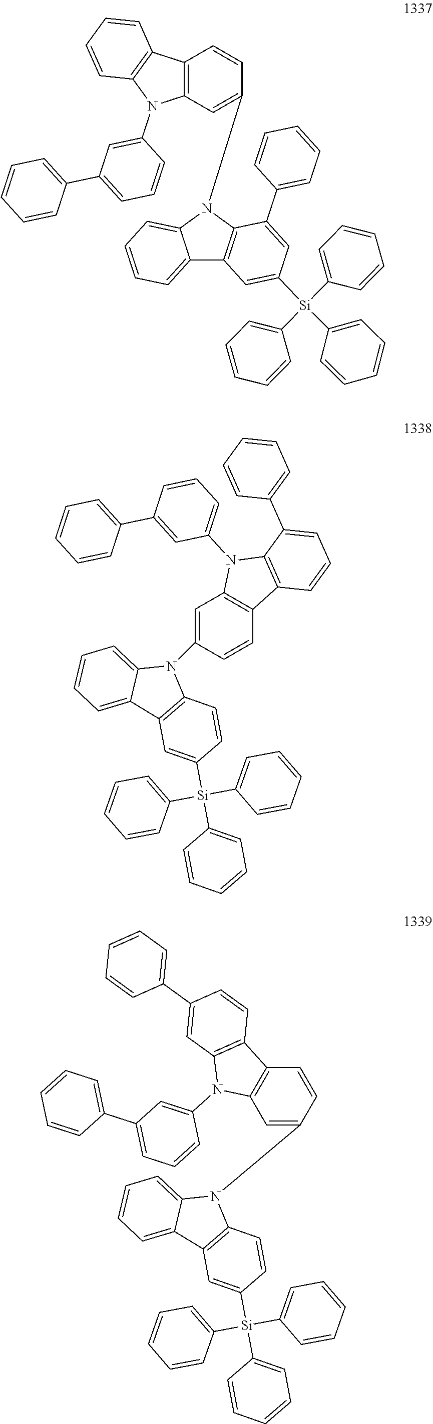 [SMILES: c1ccc(-c2cccc(-n3c4ccccc4c4ccc(-n5c6ccccc6c6cc([Si](c7ccccc7)(c7ccccc7)c7ccccc7)cc(-c7ccccc7)c65)cc43)c2)cc1 ; c1ccc(-c2cccc(-n3c4cc(-n5c6ccccc6c6cc([Si](c7ccccc7)(c7ccccc7)c7ccccc7)ccc65)ccc4c4cccc(-c5ccccc5)c43)c2)cc1 ; c1ccc(-c2cccc(-n3c4cc(-c5ccccc5)ccc4c4ccc(-n5c6ccccc6c6cc([Si](c7ccccc7)(c7ccccc7)c7ccccc7)ccc65)cc43)c2)cc1]

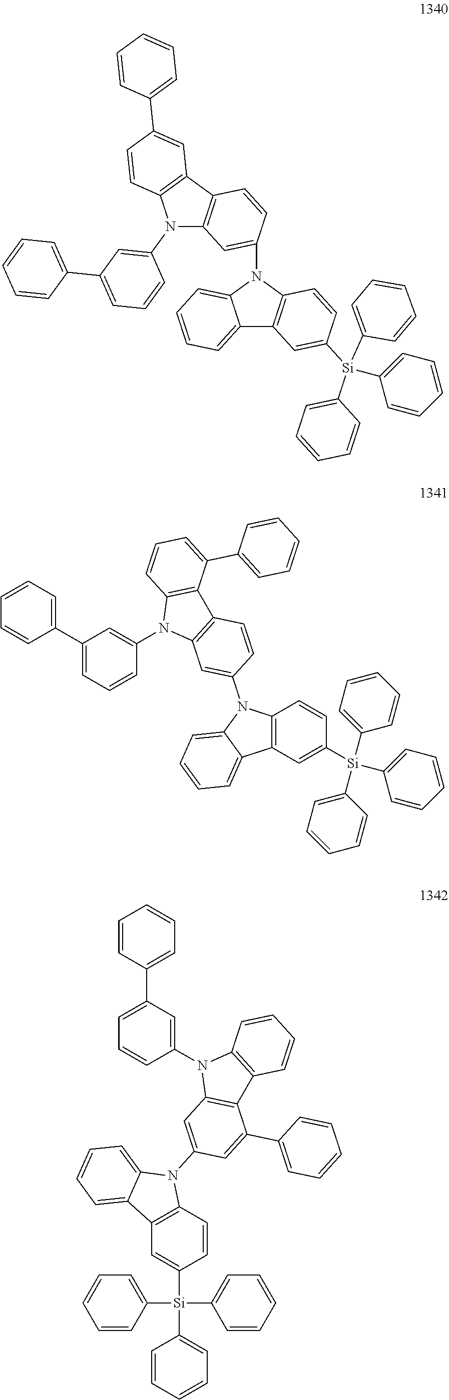 [SMILES: c1ccc(-c2cccc(-n3c4ccc(-c5ccccc5)cc4c4ccc(-n5c6ccccc6c6cc([Si](c7ccccc7)(c7ccccc7)c7ccccc7)ccc65)cc43)c2)cc1 ; c1ccc(-c2cccc(-n3c4cc(-n5c6ccccc6c6cc([Si](c7ccccc7)(c7ccccc7)c7ccccc7)ccc65)ccc4c4c(-c5ccccc5)cccc43)c2)cc1 ; c1ccc(-c2cccc(-n3c4ccccc4c4c(-c5ccccc5)cc(-n5c6ccccc6c6cc([Si](c7ccccc7)(c7ccccc7)c7ccccc7)ccc65)cc43)c2)cc1]

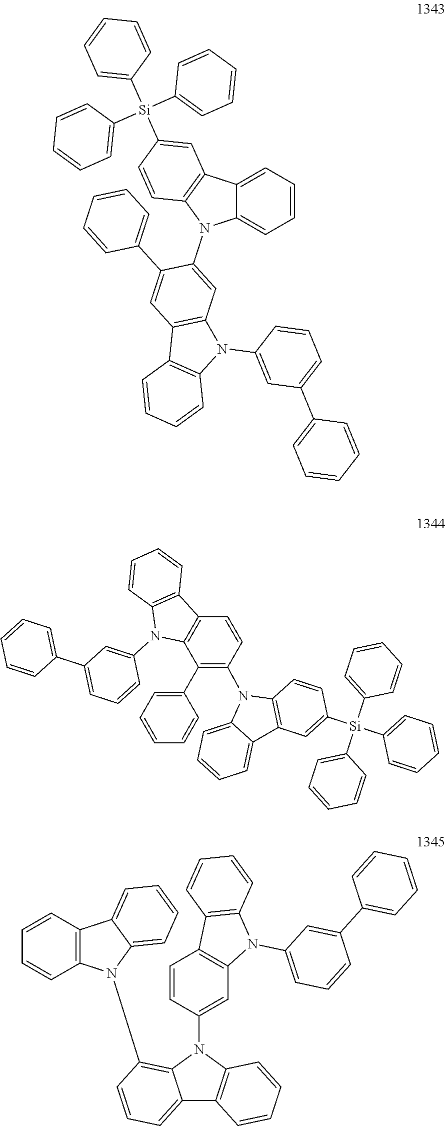 [SMILES: c1ccc(-c2cccc(-n3c4ccccc4c4cc(-c5ccccc5)c(-n5c6ccccc6c6cc([Si](c7ccccc7)(c7ccccc7)c7ccccc7)ccc65)cc43)c2)cc1 ; c1ccc(-c2cccc(-n3c4ccccc4c4ccc(-n5c6ccccc6c6cc([Si](c7ccccc7)(c7ccccc7)c7ccccc7)ccc65)c(-c5ccccc5)c43)c2)cc1 ; c1ccc(-c2cccc(-n3c4ccccc4c4ccc(-n5c6ccccc6c6cccc(-n7c8ccccc8c8ccccc87)c65)cc43)c2)cc1]

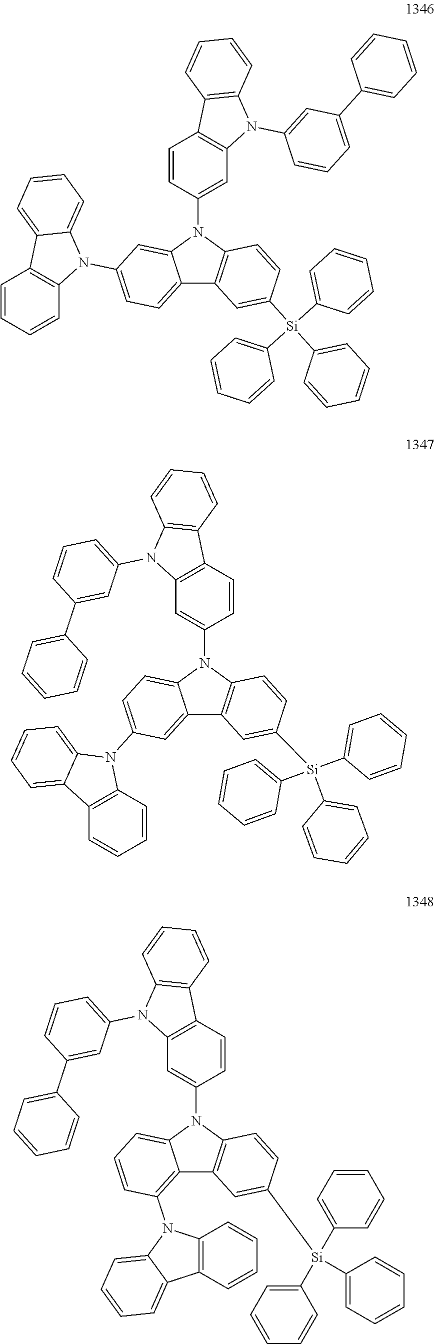 [SMILES: c1ccc(-c2cccc(-n3c4ccccc4c4ccc(-n5c6ccc([Si](c7ccccc7)(c7ccccc7)c7ccccc7)cc6c6ccc(-n7c8ccccc8c8ccccc87)cc65)cc43)c2)cc1 ; c1ccc(-c2cccc(-n3c4ccccc4c4ccc(-n5c6ccc(-n7c8ccccc8c8ccccc87)cc6c6cc([Si](c7ccccc7)(c7ccccc7)c7ccccc7)ccc65)cc43)c2)cc1 ; c1ccc(-c2cccc(-n3c4ccccc4c4ccc(-n5c6ccc([Si](c7ccccc7)(c7ccccc7)c7ccccc7)cc6c6c(-n7c8ccccc8c8ccccc87)cccc65)cc43)c2)cc1]

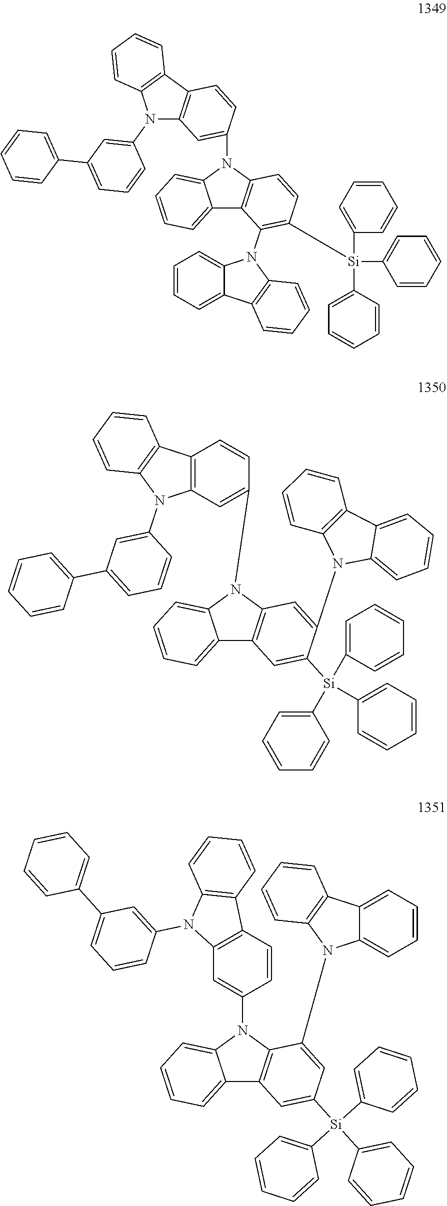 [SMILES: c1ccc(-c2cccc(-n3c4ccccc4c4ccc(-n5c6ccccc6c6c(-n7c8ccccc8c8ccccc87)c([Si](c7ccccc7)(c7ccccc7)c7ccccc7)ccc65)cc43)c2)cc1 ; c1ccc(-c2cccc(-n3c4ccccc4c4ccc(-n5c6ccccc6c6cc([Si](c7ccccc7)(c7ccccc7)c7ccccc7)c(-n7c8ccccc8c8ccccc87)cc65)cc43)c2)cc1 ; c1ccc(-c2cccc(-n3c4ccccc4c4ccc(-n5c6ccccc6c6cc([Si](c7ccccc7)(c7ccccc7)c7ccccc7)cc(-n7c8ccccc8c8ccccc87)c65)cc43)c2)cc1]

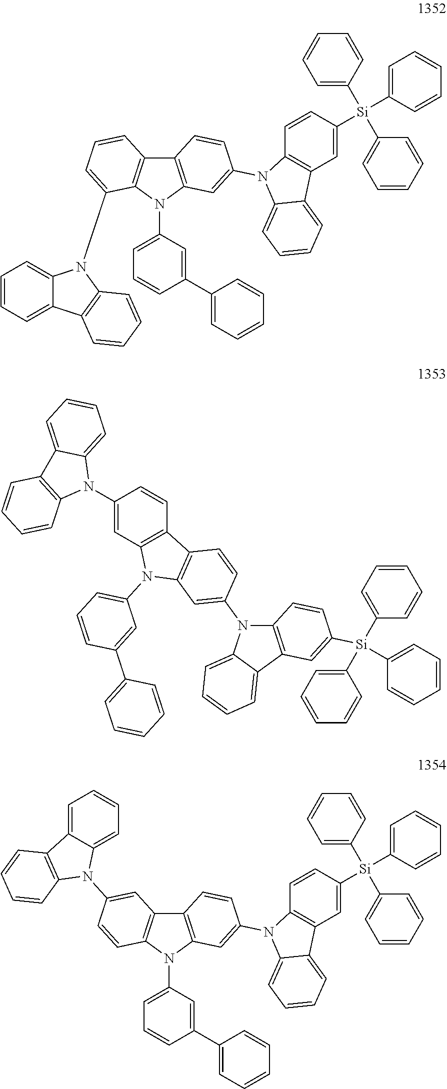 [SMILES: c1ccc(-c2cccc(-n3c4cc(-n5c6ccccc6c6cc([Si](c7ccccc7)(c7ccccc7)c7ccccc7)ccc65)ccc4c4cccc(-n5c6ccccc6c6ccccc65)c43)c2)cc1 ; c1ccc(-c2cccc(-n3c4cc(-n5c6ccccc6c6ccccc65)ccc4c4ccc(-n5c6ccccc6c6cc([Si](c7ccccc7)(c7ccccc7)c7ccccc7)ccc65)cc43)c2)cc1 ; c1ccc(-c2cccc(-n3c4ccc(-n5c6ccccc6c6ccccc65)cc4c4ccc(-n5c6ccccc6c6cc([Si](c7ccccc7)(c7ccccc7)c7ccccc7)ccc65)cc43)c2)cc1]

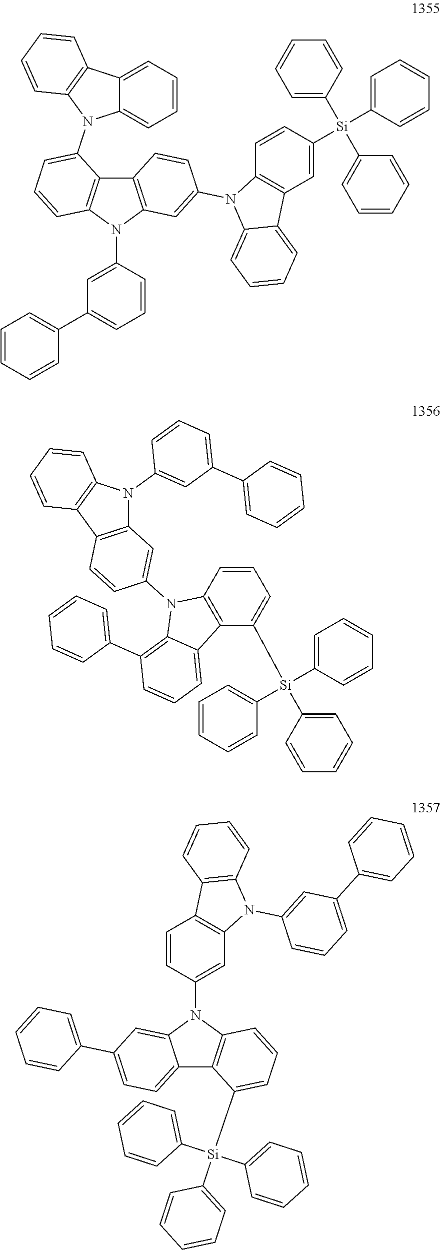 [SMILES: c1ccc(-c2cccc(-n3c4cc(-n5c6ccccc6c6cc([Si](c7ccccc7)(c7ccccc7)c7ccccc7)ccc65)ccc4c4c(-n5c6ccccc6c6ccccc65)cccc43)c2)cc1 ; c1ccc(-c2cccc(-n3c4ccccc4c4ccc(-n5c6cccc([Si](c7ccccc7)(c7ccccc7)c7ccccc7)c6c6cccc(-c7ccccc7)c65)cc43)c2)cc1 ; c1ccc(-c2cccc(-n3c4ccccc4c4ccc(-n5c6cc(-c7ccccc7)ccc6c6c([Si](c7ccccc7)(c7ccccc7)c7ccccc7)cccc65)cc43)c2)cc1]

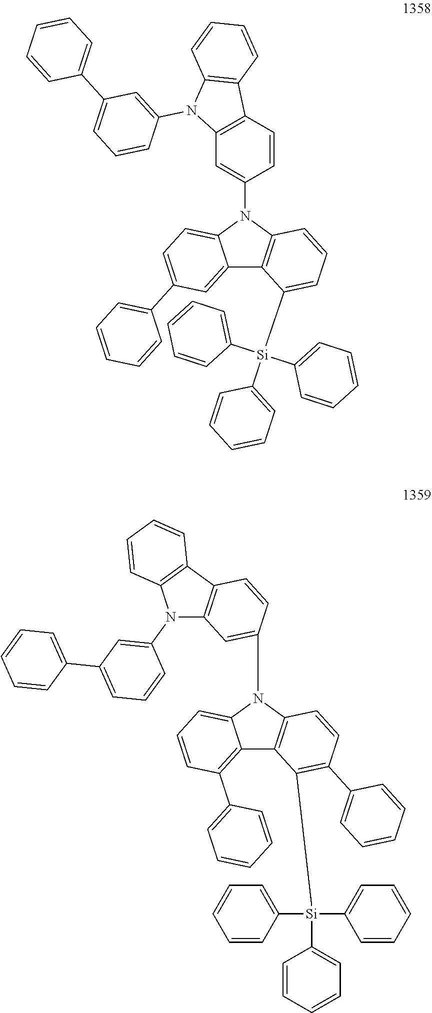 [SMILES: c1ccc(-c2cccc(-n3c4ccccc4c4ccc(-n5c6ccc(-c7ccccc7)cc6c6c([Si](c7ccccc7)(c7ccccc7)c7ccccc7)cccc65)cc43)c2)cc1 ; c1ccc(-c2cccc(-n3c4ccccc4c4ccc(-n5c6cccc(-c7ccccc7)c6c6c([Si](c7ccccc7)(c7ccccc7)c7ccccc7)c(-c7ccccc7)ccc65)cc43)c2)cc1]

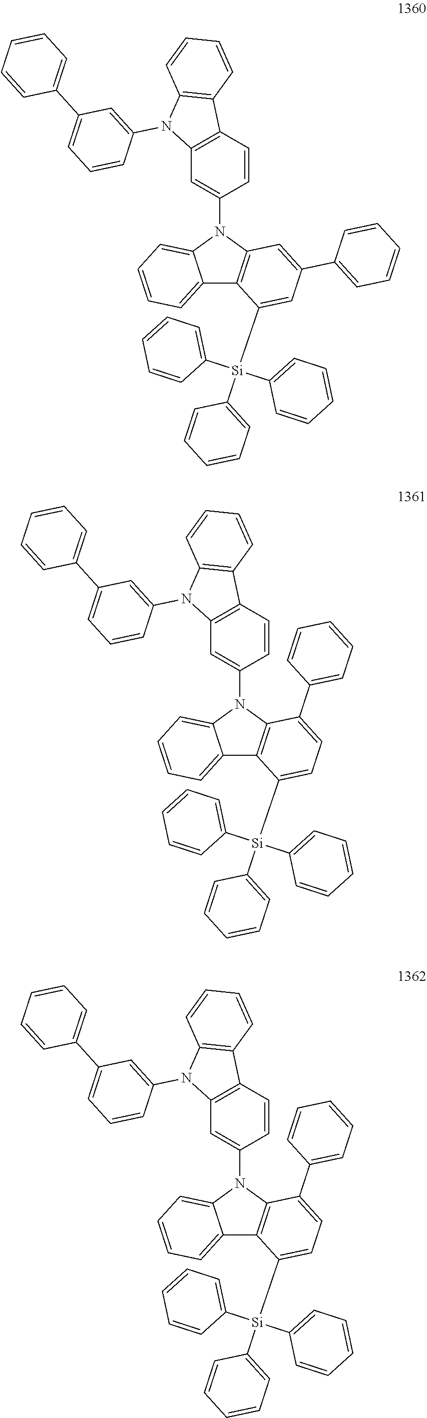

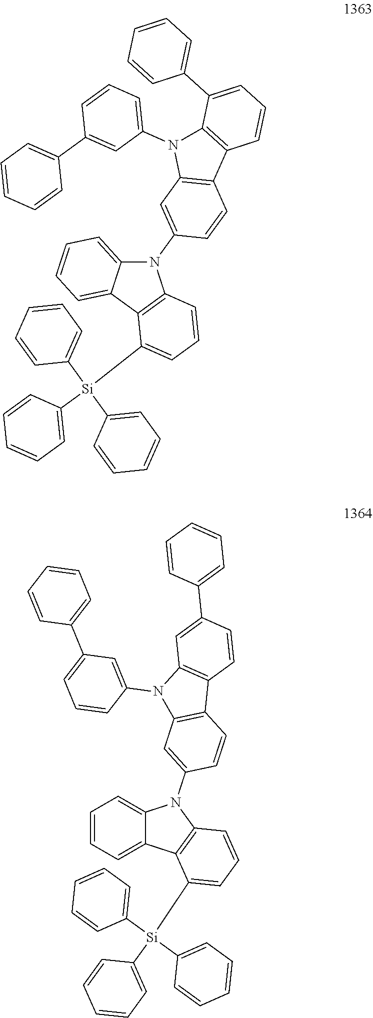 [SMILES: c1ccc(-c2cccc(-n3c4cc(-n5c6ccccc6c6c([Si](c7ccccc7)(c7ccccc7)c7ccccc7)cccc65)ccc4c4cccc(-c5ccccc5)c43)c2)cc1 ; c1ccc(-c2cccc(-n3c4cc(-c5ccccc5)ccc4c4ccc(-n5c6ccccc6c6c([Si](c7ccccc7)(c7ccccc7)c7ccccc7)cccc65)cc43)c2)cc1]

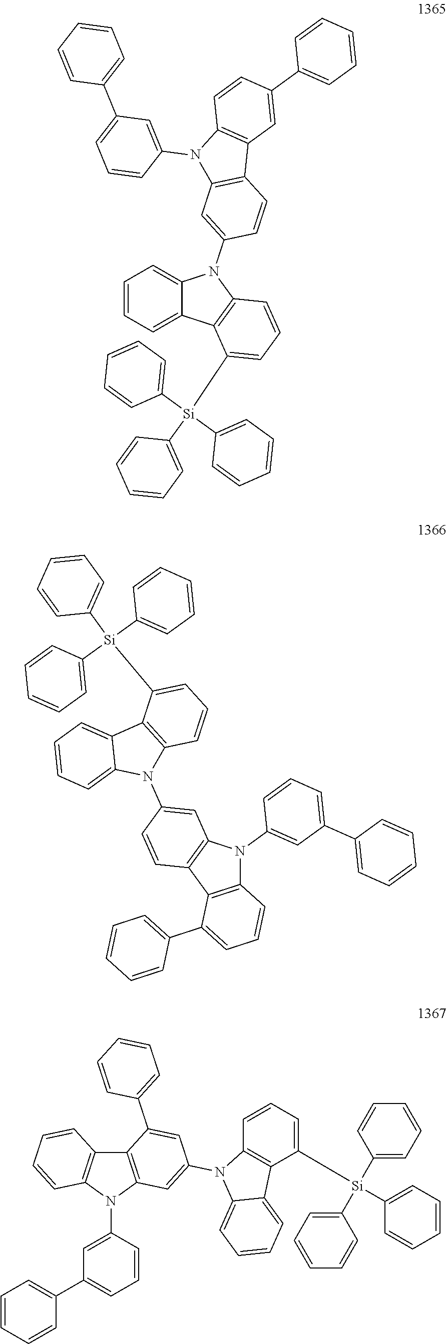 [SMILES: c1ccc(-c2cccc(-n3c4ccc(-c5ccccc5)cc4c4ccc(-n5c6ccccc6c6c([Si](c7ccccc7)(c7ccccc7)c7ccccc7)cccc65)cc43)c2)cc1 ; c1ccc(-c2cccc(-n3c4cc(-n5c6ccccc6c6c([Si](c7ccccc7)(c7ccccc7)c7ccccc7)cccc65)ccc4c4c(-c5ccccc5)cccc43)c2)cc1 ; c1ccc(-c2cccc(-n3c4ccccc4c4c(-c5ccccc5)cc(-n5c6ccccc6c6c([Si](c7ccccc7)(c7ccccc7)c7ccccc7)cccc65)cc43)c2)cc1]

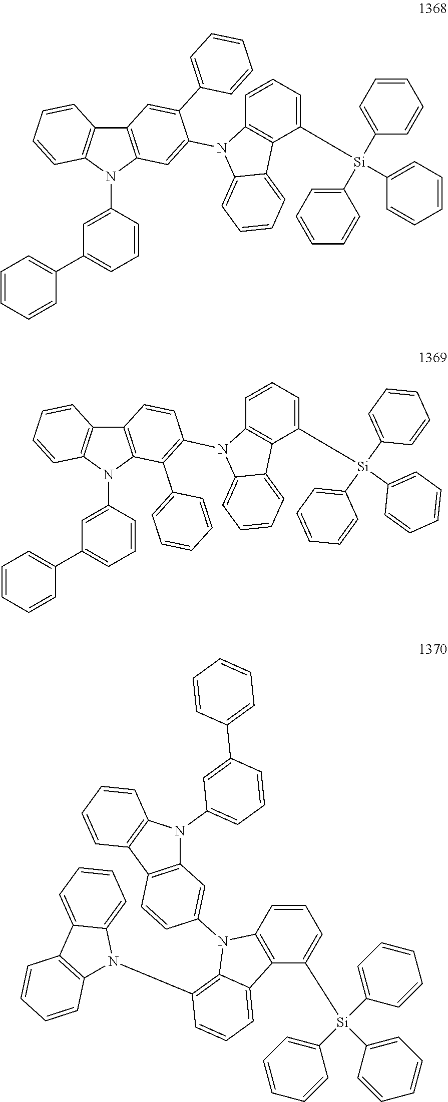 [SMILES: c1ccc(-c2cccc(-n3c4ccccc4c4cc(-c5ccccc5)c(-n5c6ccccc6c6c([Si](c7ccccc7)(c7ccccc7)c7ccccc7)cccc65)cc43)c2)cc1 ; c1ccc(-c2cccc(-n3c4ccccc4c4ccc(-n5c6ccccc6c6c([Si](c7ccccc7)(c7ccccc7)c7ccccc7)cccc65)c(-c5ccccc5)c43)c2)cc1 ; c1ccc(-c2cccc(-n3c4ccccc4c4ccc(-n5c6cccc([Si](c7ccccc7)(c7ccccc7)c7ccccc7)c6c6cccc(-n7c8ccccc8c8ccccc87)c65)cc43)c2)cc1]

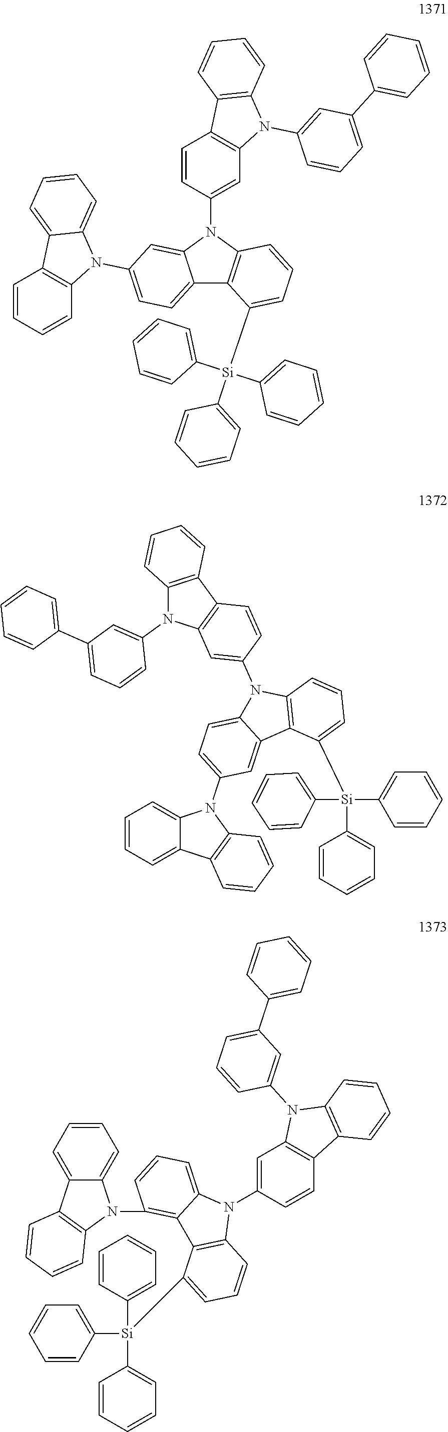 [SMILES: c1ccc(-c2cccc(-n3c4ccccc4c4ccc(-n5c6cc(-n7c8ccccc8c8ccccc87)ccc6c6c([Si](c7ccccc7)(c7ccccc7)c7ccccc7)cccc65)cc43)c2)cc1 ; c1ccc(-c2cccc(-n3c4ccccc4c4ccc(-n5c6ccc(-n7c8ccccc8c8ccccc87)cc6c6c([Si](c7ccccc7)(c7ccccc7)c7ccccc7)cccc65)cc43)c2)cc1 ; c1ccc(-c2cccc(-n3c4ccccc4c4ccc(-n5c6cccc(-n7c8ccccc8c8ccccc87)c6c6c([Si](c7ccccc7)(c7ccccc7)c7ccccc7)cccc65)cc43)c2)cc1]

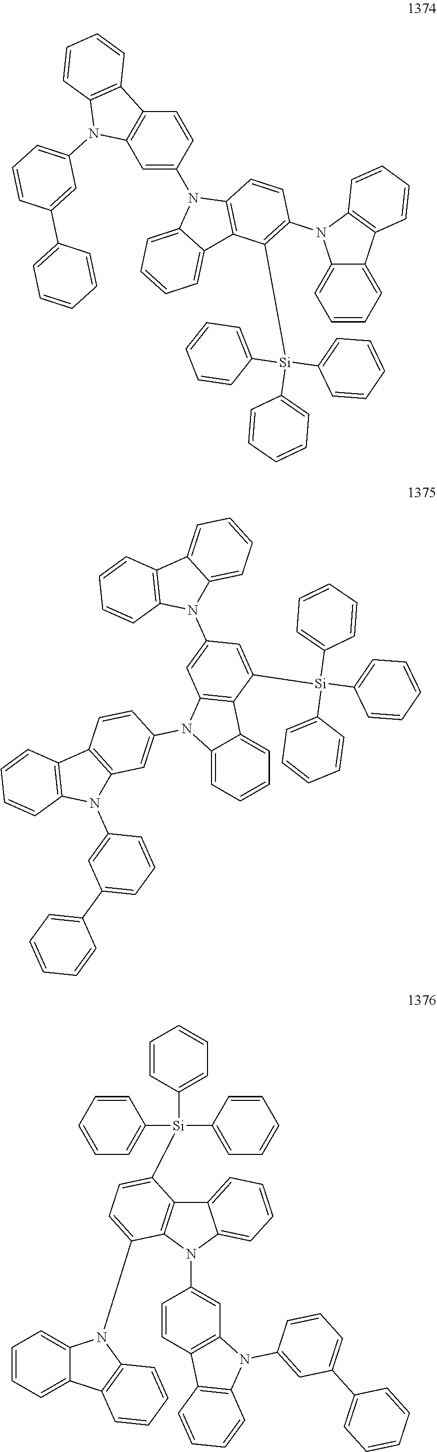 [SMILES: c1ccc(-c2cccc(-n3c4ccccc4c4ccc(-n5c6ccccc6c6c([Si](c7ccccc7)(c7ccccc7)c7ccccc7)c(-n7c8ccccc8c8ccccc87)ccc65)cc43)c2)cc1 ; c1ccc(-c2cccc(-n3c4ccccc4c4ccc(-n5c6ccccc6c6c([Si](c7ccccc7)(c7ccccc7)c7ccccc7)cc(-n7c8ccccc8c8ccccc87)cc65)cc43)c2)cc1 ; c1ccc(-c2cccc(-n3c4ccccc4c4ccc(-n5c6ccccc6c6c([Si](c7ccccc7)(c7ccccc7)c7ccccc7)ccc(-n7c8ccccc8c8ccccc87)c65)cc43)c2)cc1]

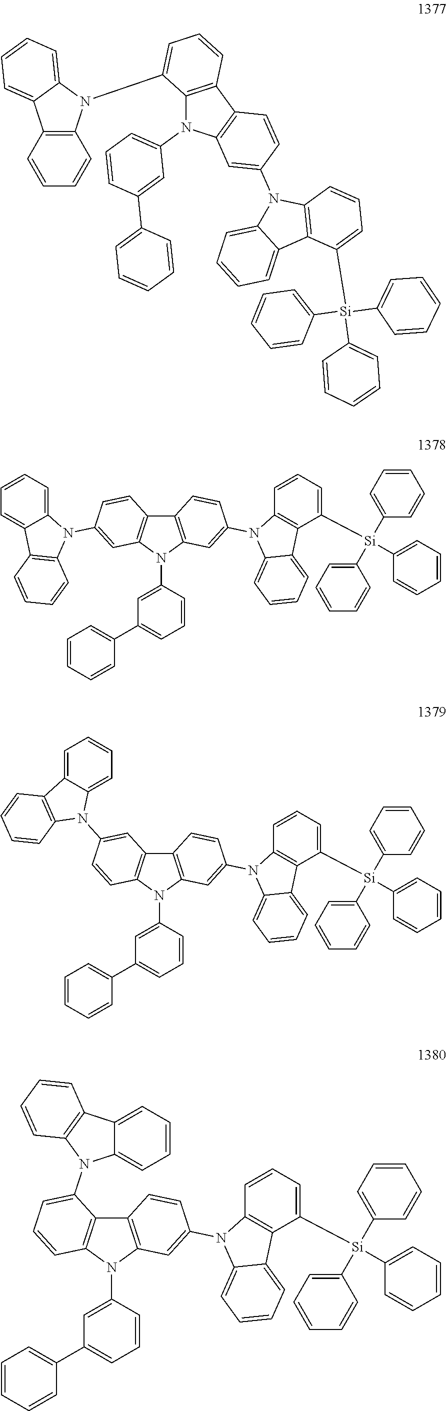 [SMILES: c1ccc(-c2cccc(-n3c4cc(-n5c6ccccc6c6c([Si](c7ccccc7)(c7ccccc7)c7ccccc7)cccc65)ccc4c4cccc(-n5c6ccccc6c6ccccc65)c43)c2)cc1 ; c1ccc(-c2cccc(-n3c4cc(-n5c6ccccc6c6ccccc65)ccc4c4ccc(-n5c6ccccc6c6c([Si](c7ccccc7)(c7ccccc7)c7ccccc7)cccc65)cc43)c2)cc1 ; c1ccc(-c2cccc(-n3c4ccc(-n5c6ccccc6c6ccccc65)cc4c4ccc(-n5c6ccccc6c6c([Si](c7ccccc7)(c7ccccc7)c7ccccc7)cccc65)cc43)c2)cc1 ; c1ccc(-c2cccc(-n3c4cc(-n5c6ccccc6c6c([Si](c7ccccc7)(c7ccccc7)c7ccccc7)cccc65)ccc4c4c(-n5c6ccccc6c6ccccc65)cccc43)c2)cc1]

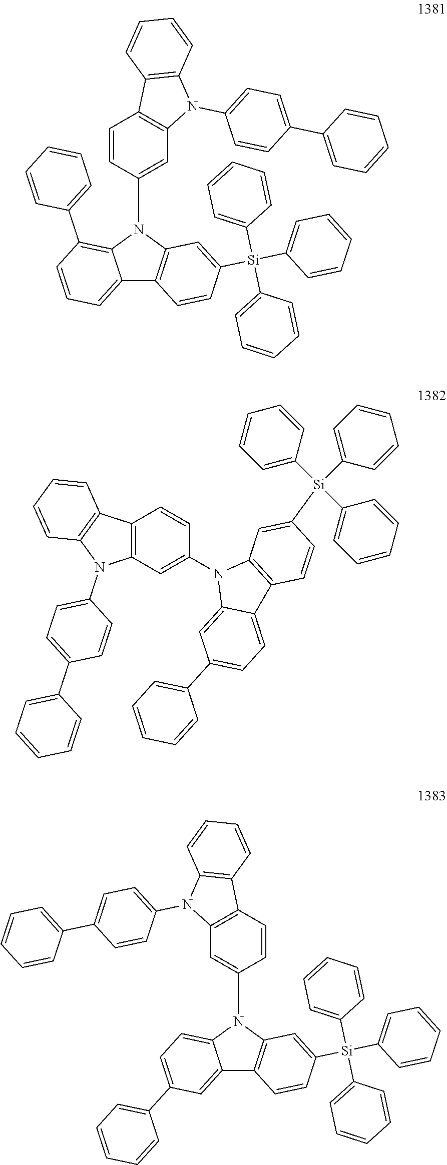 [SMILES: c1ccc(-c2ccc(-n3c4ccccc4c4ccc(-n5c6cc([Si](c7ccccc7)(c7ccccc7)c7ccccc7)ccc6c6cccc(-c7ccccc7)c65)cc43)cc2)cc1 ; c1ccc(-c2ccc(-n3c4ccccc4c4ccc(-n5c6cc(-c7ccccc7)ccc6c6ccc([Si](c7ccccc7)(c7ccccc7)c7ccccc7)cc65)cc43)cc2)cc1 ; c1ccc(-c2ccc(-n3c4ccccc4c4ccc(-n5c6ccc(-c7ccccc7)cc6c6ccc([Si](c7ccccc7)(c7ccccc7)c7ccccc7)cc65)cc43)cc2)cc1]

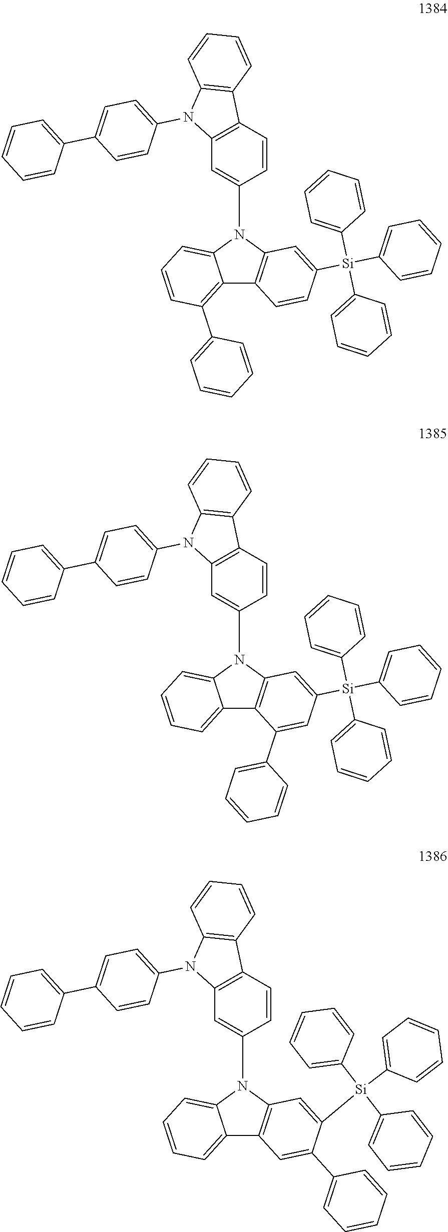 [SMILES: c1ccc(-c2ccc(-n3c4ccccc4c4ccc(-n5c6cc([Si](c7ccccc7)(c7ccccc7)c7ccccc7)ccc6c6c(-c7ccccc7)cccc65)cc43)cc2)cc1 ; c1ccc(-c2ccc(-n3c4ccccc4c4ccc(-n5c6ccccc6c6c(-c7ccccc7)cc([Si](c7ccccc7)(c7ccccc7)c7ccccc7)cc65)cc43)cc2)cc1 ; c1ccc(-c2ccc(-n3c4ccccc4c4ccc(-n5c6ccccc6c6cc(-c7ccccc7)c([Si](c7ccccc7)(c7ccccc7)c7ccccc7)cc65)cc43)cc2)cc1]

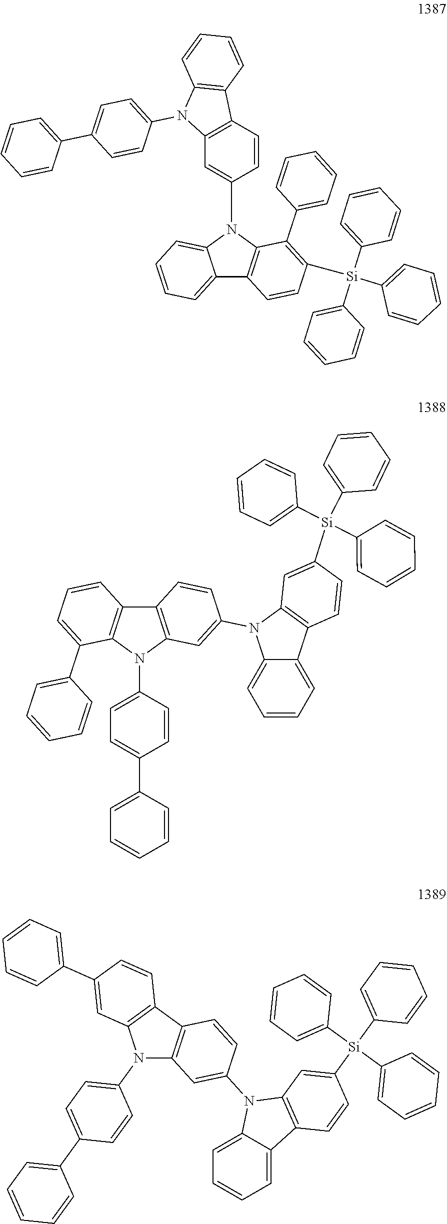 [SMILES: c1ccc(-c2ccc(-n3c4ccccc4c4ccc(-n5c6ccccc6c6ccc([Si](c7ccccc7)(c7ccccc7)c7ccccc7)c(-c7ccccc7)c65)cc43)cc2)cc1 ; c1ccc(-c2ccc(-n3c4cc(-n5c6ccccc6c6ccc([Si](c7ccccc7)(c7ccccc7)c7ccccc7)cc65)ccc4c4cccc(-c5ccccc5)c43)cc2)cc1 ; c1ccc(-c2ccc(-n3c4cc(-c5ccccc5)ccc4c4ccc(-n5c6ccccc6c6ccc([Si](c7ccccc7)(c7ccccc7)c7ccccc7)cc65)cc43)cc2)cc1]

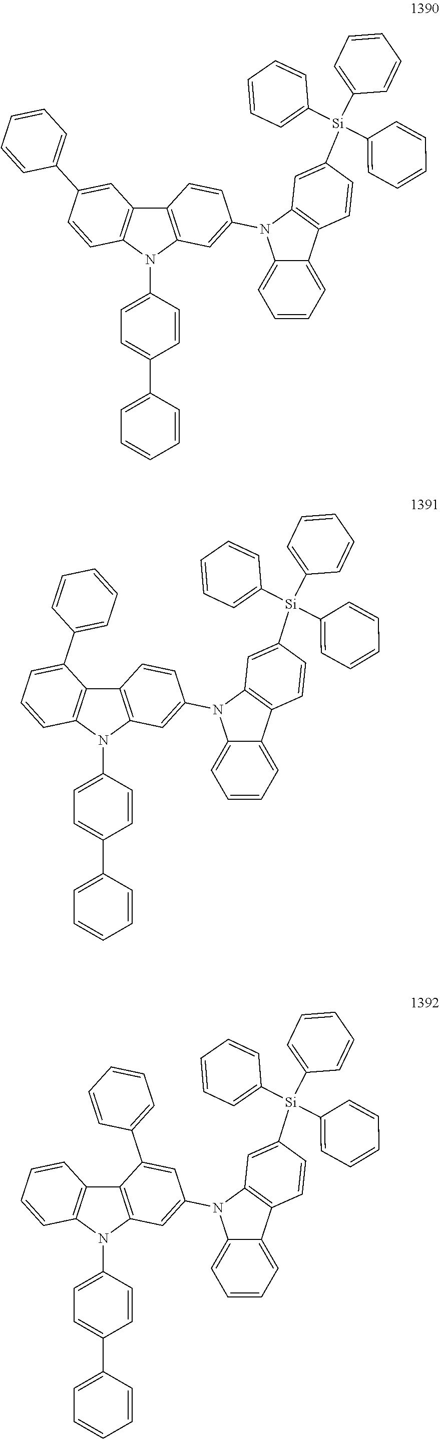 [SMILES: c1ccc(-c2ccc(-n3c4ccc(-c5ccccc5)cc4c4ccc(-n5c6ccccc6c6ccc([Si](c7ccccc7)(c7ccccc7)c7ccccc7)cc65)cc43)cc2)cc1 ; c1ccc(-c2ccc(-n3c4cc(-n5c6ccccc6c6ccc([Si](c7ccccc7)(c7ccccc7)c7ccccc7)cc65)ccc4c4c(-c5ccccc5)cccc43)cc2)cc1 ; c1ccc(-c2ccc(-n3c4ccccc4c4c(-c5ccccc5)cc(-n5c6ccccc6c6ccc([Si](c7ccccc7)(c7ccccc7)c7ccccc7)cc65)cc43)cc2)cc1]

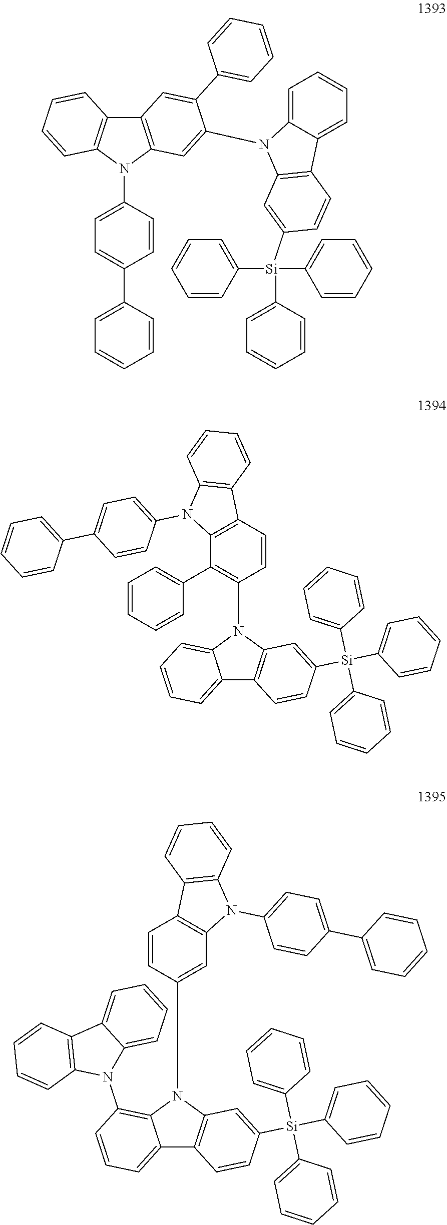 [SMILES: c1ccc(-c2ccc(-n3c4ccccc4c4cc(-c5ccccc5)c(-n5c6ccccc6c6ccc([Si](c7ccccc7)(c7ccccc7)c7ccccc7)cc65)cc43)cc2)cc1 ; c1ccc(-c2ccc(-n3c4ccccc4c4ccc(-n5c6ccccc6c6ccc([Si](c7ccccc7)(c7ccccc7)c7ccccc7)cc65)c(-c5ccccc5)c43)cc2)cc1 ; c1ccc(-c2ccc(-n3c4ccccc4c4ccc(-n5c6cc([Si](c7ccccc7)(c7ccccc7)c7ccccc7)ccc6c6cccc(-n7c8ccccc8c8ccccc87)c65)cc43)cc2)cc1]

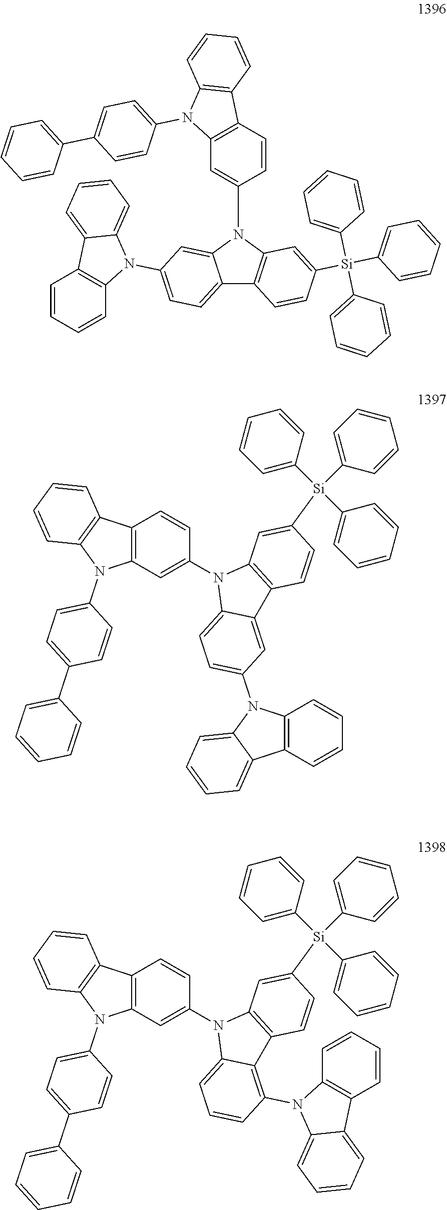 [SMILES: c1ccc(-c2ccc(-n3c4ccccc4c4ccc(-n5c6cc(-n7c8ccccc8c8ccccc87)ccc6c6ccc([Si](c7ccccc7)(c7ccccc7)c7ccccc7)cc65)cc43)cc2)cc1 ; c1ccc(-c2ccc(-n3c4ccccc4c4ccc(-n5c6ccc(-n7c8ccccc8c8ccccc87)cc6c6ccc([Si](c7ccccc7)(c7ccccc7)c7ccccc7)cc65)cc43)cc2)cc1 ; c1ccc(-c2ccc(-n3c4ccccc4c4ccc(-n5c6cc([Si](c7ccccc7)(c7ccccc7)c7ccccc7)ccc6c6c(-n7c8ccccc8c8ccccc87)cccc65)cc43)cc2)cc1]

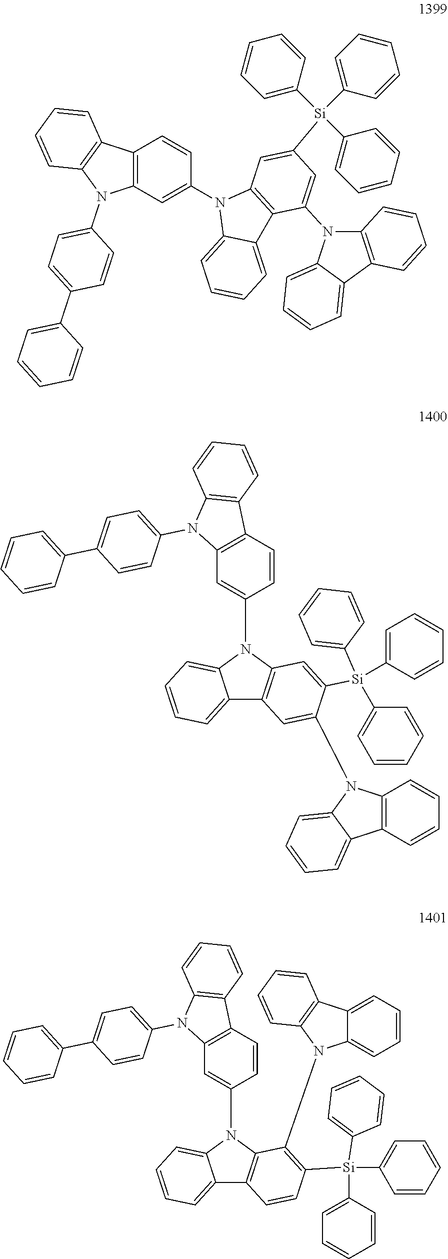 [SMILES: c1ccc(-c2ccc(-n3c4ccccc4c4ccc(-n5c6ccccc6c6c(-n7c8ccccc8c8ccccc87)cc([Si](c7ccccc7)(c7ccccc7)c7ccccc7)cc65)cc43)cc2)cc1 ; c1ccc(-c2ccc(-n3c4ccccc4c4ccc(-n5c6ccccc6c6cc(-n7c8ccccc8c8ccccc87)c([Si](c7ccccc7)(c7ccccc7)c7ccccc7)cc65)cc43)cc2)cc1 ; c1ccc(-c2ccc(-n3c4ccccc4c4ccc(-n5c6ccccc6c6ccc([Si](c7ccccc7)(c7ccccc7)c7ccccc7)c(-n7c8ccccc8c8ccccc87)c65)cc43)cc2)cc1]

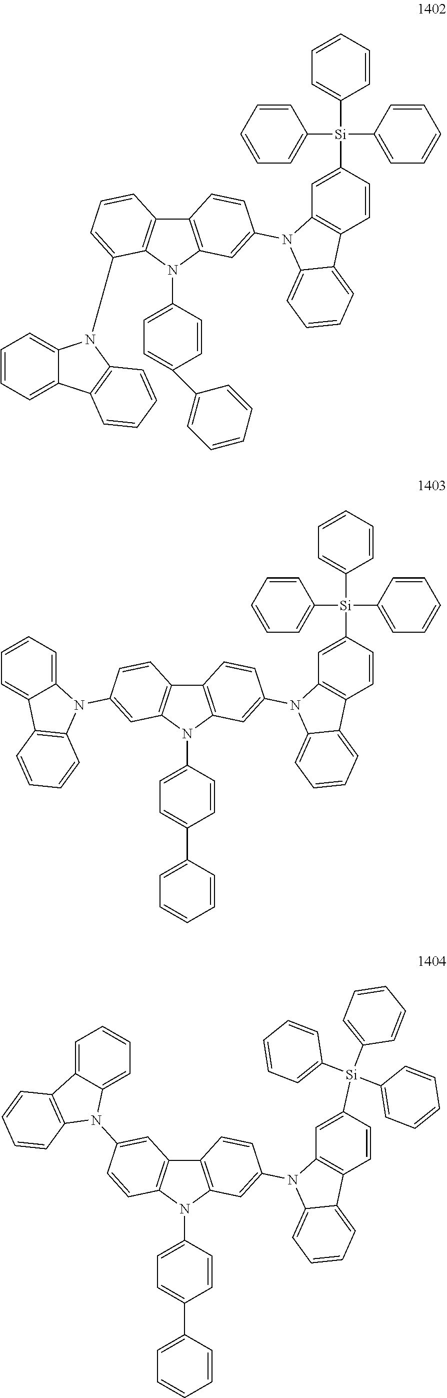 [SMILES: c1ccc(-c2ccc(-n3c4cc(-n5c6ccccc6c6ccc([Si](c7ccccc7)(c7ccccc7)c7ccccc7)cc65)ccc4c4cccc(-n5c6ccccc6c6ccccc65)c43)cc2)cc1 ; c1ccc(-c2ccc(-n3c4cc(-n5c6ccccc6c6ccccc65)ccc4c4ccc(-n5c6ccccc6c6ccc([Si](c7ccccc7)(c7ccccc7)c7ccccc7)cc65)cc43)cc2)cc1 ; c1ccc(-c2ccc(-n3c4ccc(-n5c6ccccc6c6ccccc65)cc4c4ccc(-n5c6ccccc6c6ccc([Si](c7ccccc7)(c7ccccc7)c7ccccc7)cc65)cc43)cc2)cc1]

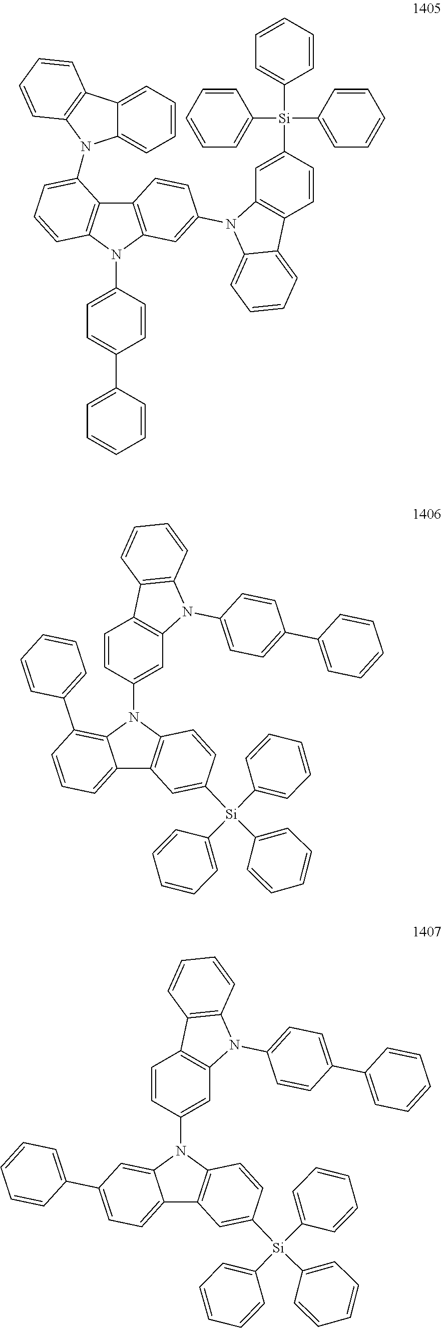

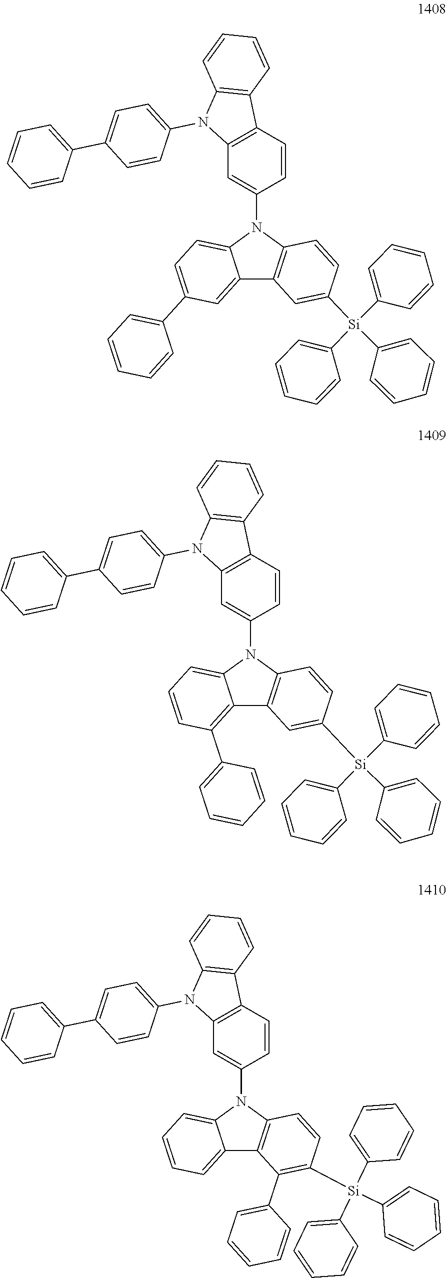 [SMILES: c1ccc(-c2ccc(-n3c4ccccc4c4ccc(-n5c6ccc(-c7ccccc7)cc6c6cc([Si](c7ccccc7)(c7ccccc7)c7ccccc7)ccc65)cc43)cc2)cc1 ; c1ccc(-c2ccc(-n3c4ccccc4c4ccc(-n5c6ccc([Si](c7ccccc7)(c7ccccc7)c7ccccc7)cc6c6c(-c7ccccc7)cccc65)cc43)cc2)cc1 ; c1ccc(-c2ccc(-n3c4ccccc4c4ccc(-n5c6ccccc6c6c(-c7ccccc7)c([Si](c7ccccc7)(c7ccccc7)c7ccccc7)ccc65)cc43)cc2)cc1]

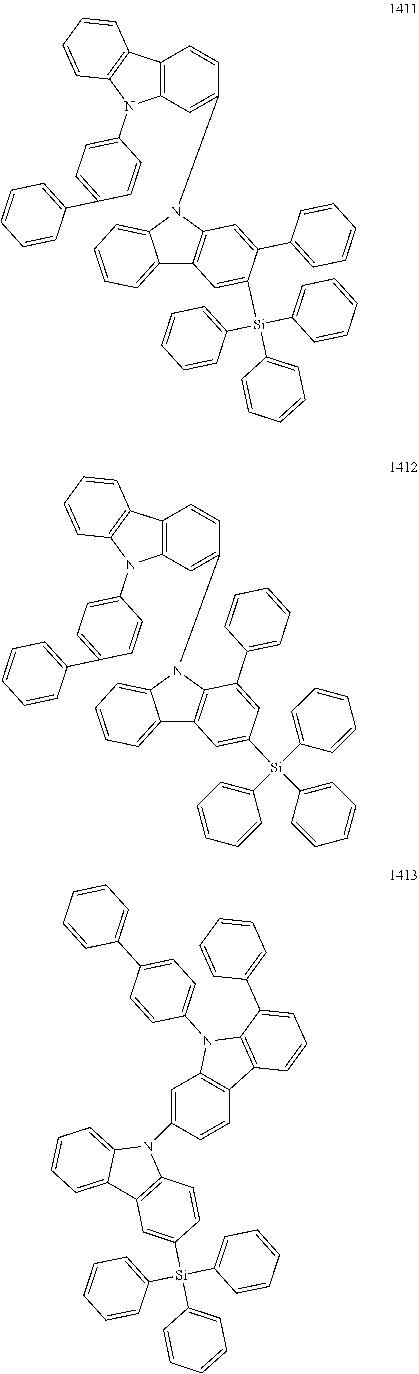 [SMILES: c1ccc(-c2ccc(-n3c4ccccc4c4ccc(-n5c6ccccc6c6cc([Si](c7ccccc7)(c7ccccc7)c7ccccc7)c(-c7ccccc7)cc65)cc43)cc2)cc1 ; c1ccc(-c2ccc(-n3c4ccccc4c4ccc(-n5c6ccccc6c6cc([Si](c7ccccc7)(c7ccccc7)c7ccccc7)cc(-c7ccccc7)c65)cc43)cc2)cc1 ; c1ccc(-c2ccc(-n3c4cc(-n5c6ccccc6c6cc([Si](c7ccccc7)(c7ccccc7)c7ccccc7)ccc65)ccc4c4cccc(-c5ccccc5)c43)cc2)cc1]

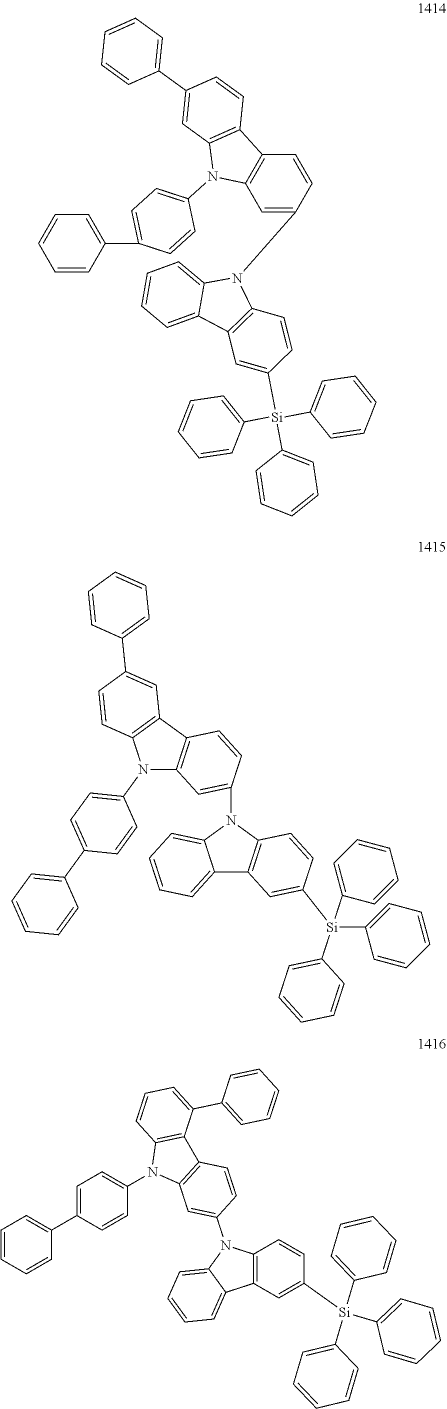 [SMILES: c1ccc(-c2ccc(-n3c4cc(-c5ccccc5)ccc4c4ccc(-n5c6ccccc6c6cc([Si](c7ccccc7)(c7ccccc7)c7ccccc7)ccc65)cc43)cc2)cc1 ; c1ccc(-c2ccc(-n3c4ccc(-c5ccccc5)cc4c4ccc(-n5c6ccccc6c6cc([Si](c7ccccc7)(c7ccccc7)c7ccccc7)ccc65)cc43)cc2)cc1 ; c1ccc(-c2ccc(-n3c4cc(-n5c6ccccc6c6cc([Si](c7ccccc7)(c7ccccc7)c7ccccc7)ccc65)ccc4c4c(-c5ccccc5)cccc43)cc2)cc1]

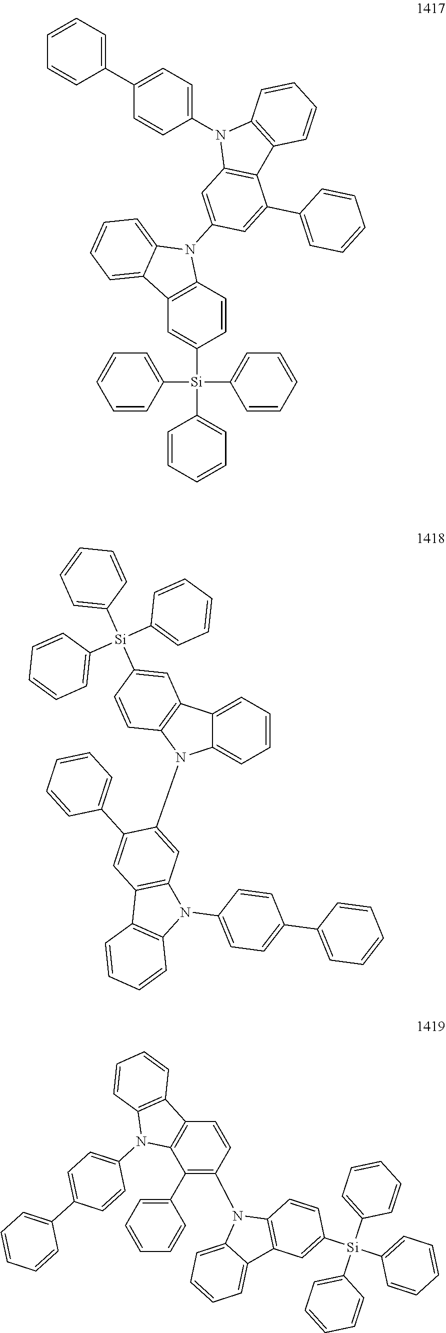 [SMILES: c1ccc(-c2ccc(-n3c4ccccc4c4c(-c5ccccc5)cc(-n5c6ccccc6c6cc([Si](c7ccccc7)(c7ccccc7)c7ccccc7)ccc65)cc43)cc2)cc1 ; c1ccc(-c2ccc(-n3c4ccccc4c4cc(-c5ccccc5)c(-n5c6ccccc6c6cc([Si](c7ccccc7)(c7ccccc7)c7ccccc7)ccc65)cc43)cc2)cc1 ; c1ccc(-c2ccc(-n3c4ccccc4c4ccc(-n5c6ccccc6c6cc([Si](c7ccccc7)(c7ccccc7)c7ccccc7)ccc65)c(-c5ccccc5)c43)cc2)cc1]

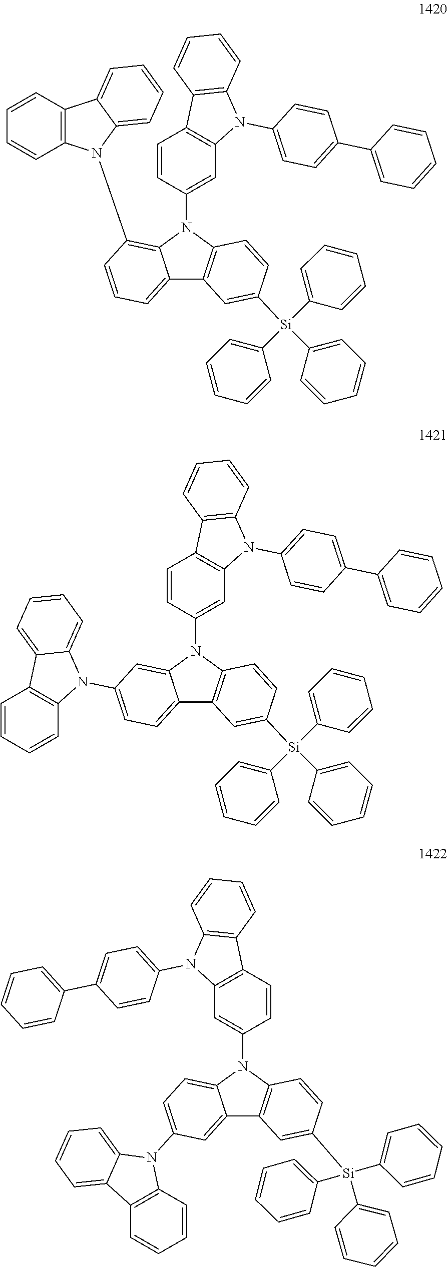 [SMILES: c1ccc(-c2ccc(-n3c4ccccc4c4ccc(-n5c6ccc([Si](c7ccccc7)(c7ccccc7)c7ccccc7)cc6c6cccc(-n7c8ccccc8c8ccccc87)c65)cc43)cc2)cc1 ; c1ccc(-c2ccc(-n3c4ccccc4c4ccc(-n5c6ccc([Si](c7ccccc7)(c7ccccc7)c7ccccc7)cc6c6ccc(-n7c8ccccc8c8ccccc87)cc65)cc43)cc2)cc1 ; c1ccc(-c2ccc(-n3c4ccccc4c4ccc(-n5c6ccc(-n7c8ccccc8c8ccccc87)cc6c6cc([Si](c7ccccc7)(c7ccccc7)c7ccccc7)ccc65)cc43)cc2)cc1]

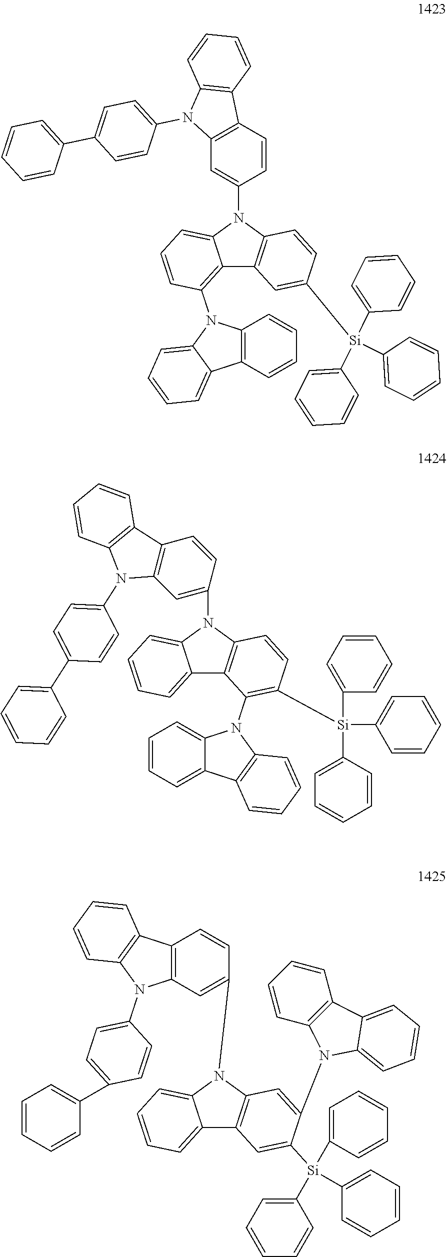 [SMILES: c1ccc(-c2ccc(-n3c4ccccc4c4ccc(-n5c6ccc([Si](c7ccccc7)(c7ccccc7)c7ccccc7)cc6c6c(-n7c8ccccc8c8ccccc87)cccc65)cc43)cc2)cc1 ; c1ccc(-c2ccc(-n3c4ccccc4c4ccc(-n5c6ccccc6c6c(-n7c8ccccc8c8ccccc87)c([Si](c7ccccc7)(c7ccccc7)c7ccccc7)ccc65)cc43)cc2)cc1 ; c1ccc(-c2ccc(-n3c4ccccc4c4ccc(-n5c6ccccc6c6cc([Si](c7ccccc7)(c7ccccc7)c7ccccc7)c(-n7c8ccccc8c8ccccc87)cc65)cc43)cc2)cc1]

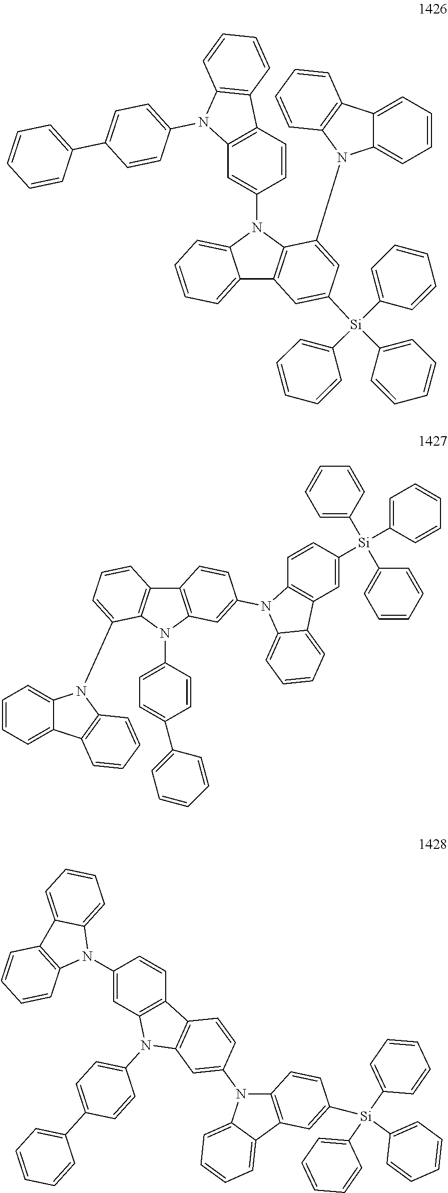 [SMILES: c1ccc(-c2ccc(-n3c4ccccc4c4ccc(-n5c6ccccc6c6cc([Si](c7ccccc7)(c7ccccc7)c7ccccc7)cc(-n7c8ccccc8c8ccccc87)c65)cc43)cc2)cc1 ; c1ccc(-c2ccc(-n3c4cc(-n5c6ccccc6c6cc([Si](c7ccccc7)(c7ccccc7)c7ccccc7)ccc65)ccc4c4cccc(-n5c6ccccc6c6ccccc65)c43)cc2)cc1 ; c1ccc(-c2ccc(-n3c4cc(-n5c6ccccc6c6ccccc65)ccc4c4ccc(-n5c6ccccc6c6cc([Si](c7ccccc7)(c7ccccc7)c7ccccc7)ccc65)cc43)cc2)cc1]

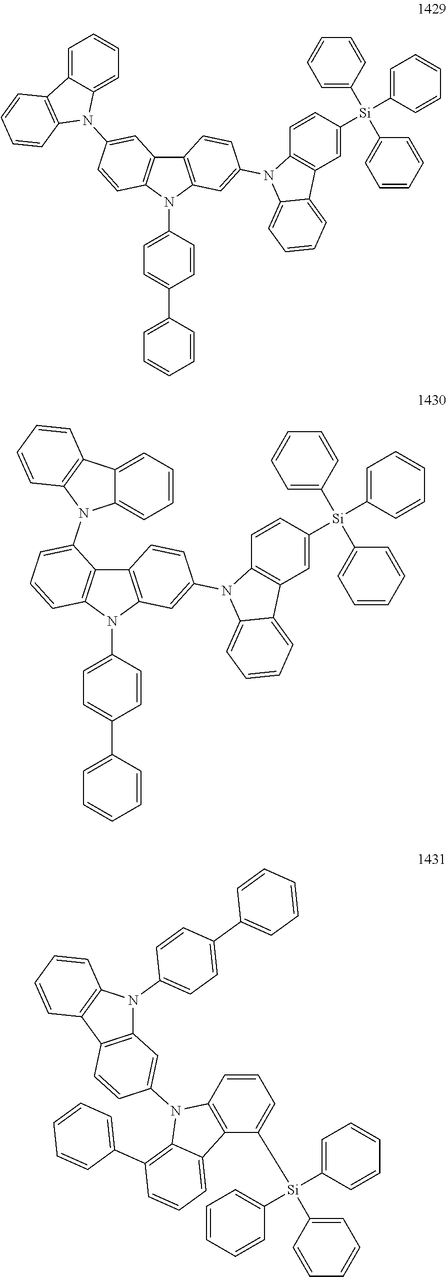 [SMILES: c1ccc(-c2ccc(-n3c4ccc(-n5c6ccccc6c6ccccc65)cc4c4ccc(-n5c6ccccc6c6cc([Si](c7ccccc7)(c7ccccc7)c7ccccc7)ccc65)cc43)cc2)cc1 ; c1ccc(-c2ccc(-n3c4cc(-n5c6ccccc6c6cc([Si](c7ccccc7)(c7ccccc7)c7ccccc7)ccc65)ccc4c4c(-n5c6ccccc6c6ccccc65)cccc43)cc2)cc1 ; c1ccc(-c2ccc(-n3c4ccccc4c4ccc(-n5c6cccc([Si](c7ccccc7)(c7ccccc7)c7ccccc7)c6c6cccc(-c7ccccc7)c65)cc43)cc2)cc1]

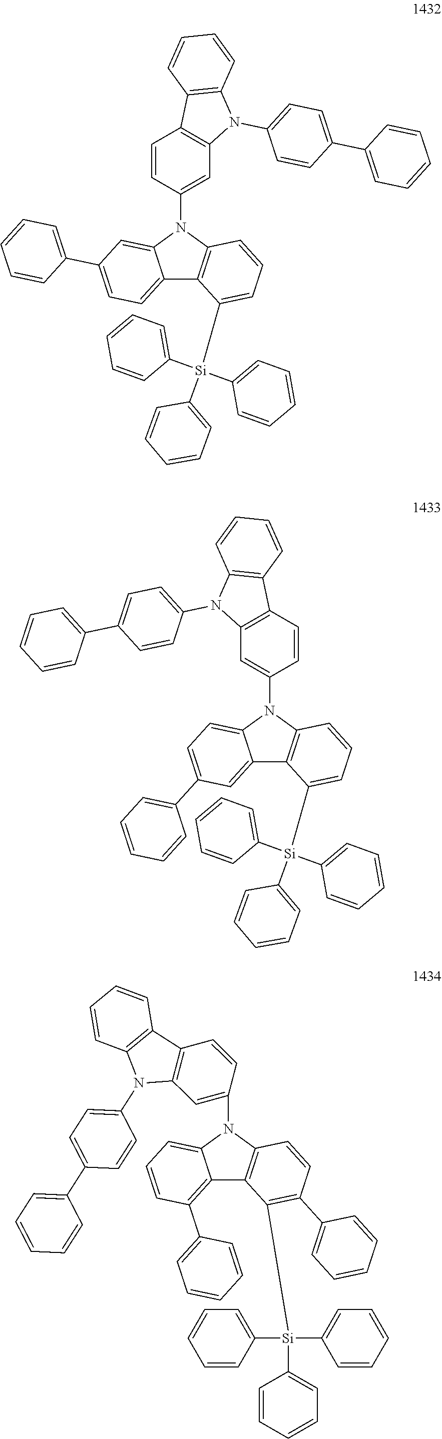 [SMILES: c1ccc(-c2ccc(-n3c4ccccc4c4ccc(-n5c6cc(-c7ccccc7)ccc6c6c([Si](c7ccccc7)(c7ccccc7)c7ccccc7)cccc65)cc43)cc2)cc1 ; c1ccc(-c2ccc(-n3c4ccccc4c4ccc(-n5c6ccc(-c7ccccc7)cc6c6c([Si](c7ccccc7)(c7ccccc7)c7ccccc7)cccc65)cc43)cc2)cc1 ; c1ccc(-c2ccc(-n3c4ccccc4c4ccc(-n5c6cccc(-c7ccccc7)c6c6c([Si](c7ccccc7)(c7ccccc7)c7ccccc7)c(-c7ccccc7)ccc65)cc43)cc2)cc1]

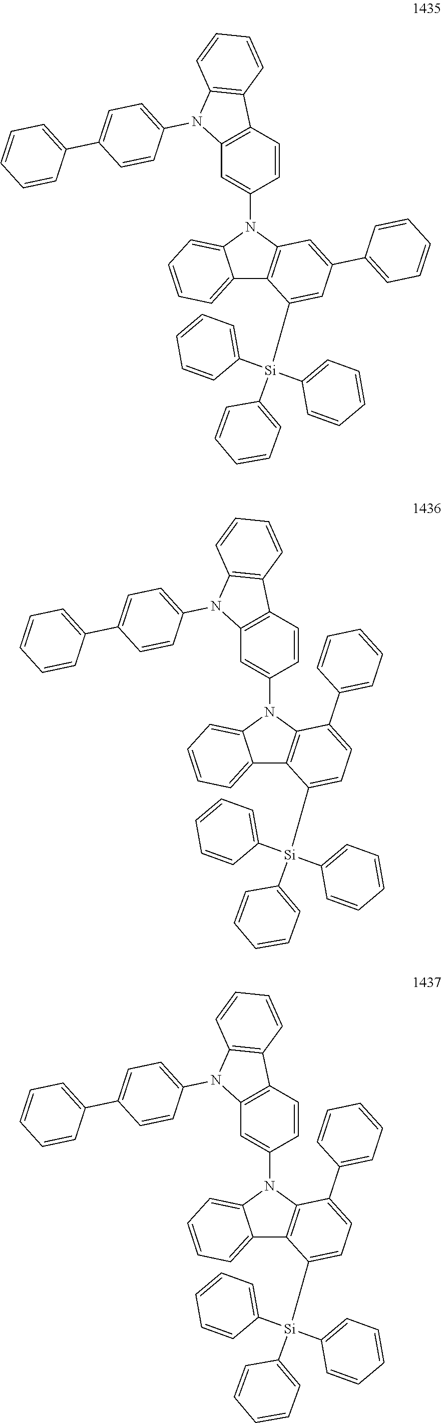 [SMILES: c1ccc(-c2ccc(-n3c4ccccc4c4ccc(-n5c6ccccc6c6c([Si](c7ccccc7)(c7ccccc7)c7ccccc7)cc(-c7ccccc7)cc65)cc43)cc2)cc1 ; c1ccc(-c2ccc(-n3c4ccccc4c4ccc(-n5c6ccccc6c6c([Si](c7ccccc7)(c7ccccc7)c7ccccc7)ccc(-c7ccccc7)c65)cc43)cc2)cc1 ; c1ccc(-c2ccc(-n3c4ccccc4c4ccc(-n5c6ccccc6c6c([Si](c7ccccc7)(c7ccccc7)c7ccccc7)ccc(-c7ccccc7)c65)cc43)cc2)cc1]

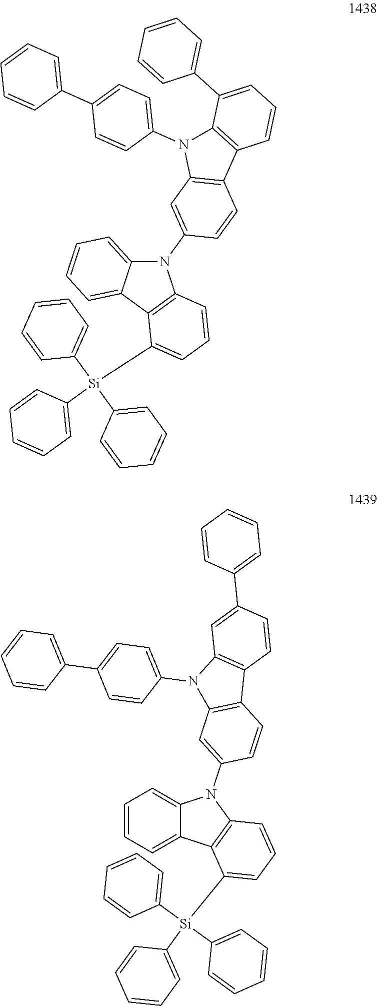 [SMILES: c1ccc(-c2ccc(-n3c4cc(-n5c6ccccc6c6c([Si](c7ccccc7)(c7ccccc7)c7ccccc7)cccc65)ccc4c4cccc(-c5ccccc5)c43)cc2)cc1 ; c1ccc(-c2ccc(-n3c4cc(-c5ccccc5)ccc4c4ccc(-n5c6ccccc6c6c([Si](c7ccccc7)(c7ccccc7)c7ccccc7)cccc65)cc43)cc2)cc1]

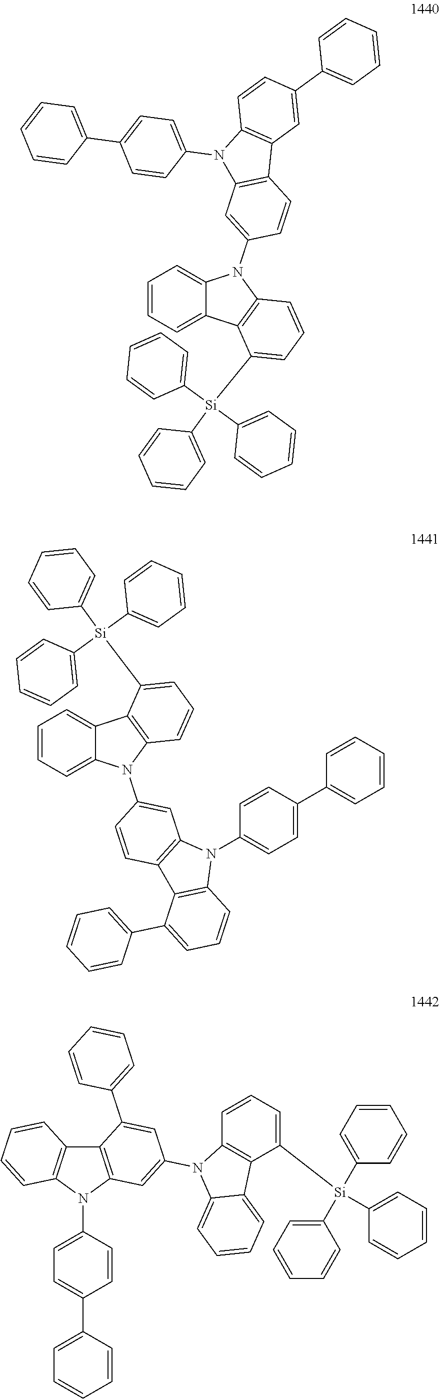 [SMILES: c1ccc(-c2ccc(-n3c4ccc(-c5ccccc5)cc4c4ccc(-n5c6ccccc6c6c([Si](c7ccccc7)(c7ccccc7)c7ccccc7)cccc65)cc43)cc2)cc1 ; c1ccc(-c2ccc(-n3c4cc(-n5c6ccccc6c6c([Si](c7ccccc7)(c7ccccc7)c7ccccc7)cccc65)ccc4c4c(-c5ccccc5)cccc43)cc2)cc1 ; c1ccc(-c2ccc(-n3c4ccccc4c4c(-c5ccccc5)cc(-n5c6ccccc6c6c([Si](c7ccccc7)(c7ccccc7)c7ccccc7)cccc65)cc43)cc2)cc1]

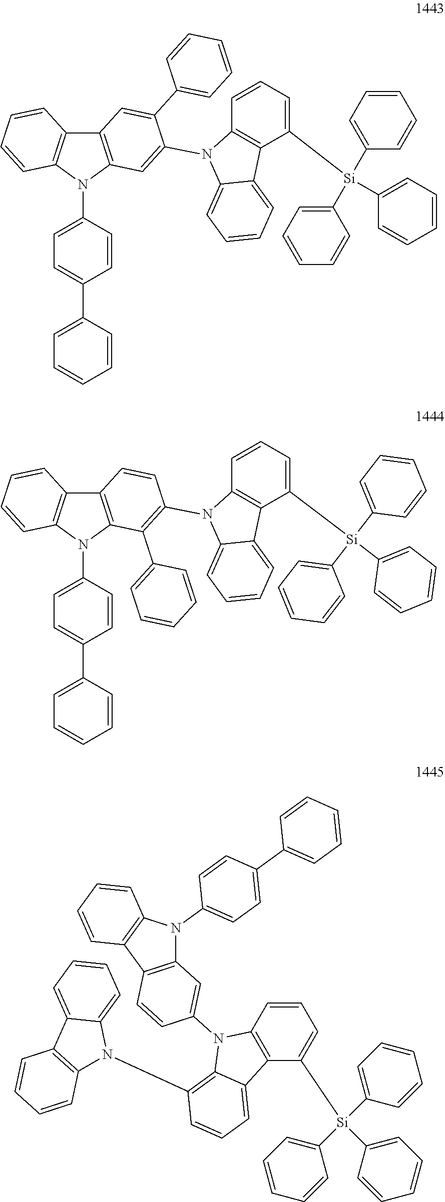 [SMILES: c1ccc(-c2ccc(-n3c4ccccc4c4cc(-c5ccccc5)c(-n5c6ccccc6c6c([Si](c7ccccc7)(c7ccccc7)c7ccccc7)cccc65)cc43)cc2)cc1 ; c1ccc(-c2ccc(-n3c4ccccc4c4ccc(-n5c6ccccc6c6c([Si](c7ccccc7)(c7ccccc7)c7ccccc7)cccc65)c(-c5ccccc5)c43)cc2)cc1 ; c1ccc(-c2ccc(-n3c4ccccc4c4ccc(-n5c6cccc([Si](c7ccccc7)(c7ccccc7)c7ccccc7)c6c6cccc(-n7c8ccccc8c8ccccc87)c65)cc43)cc2)cc1]

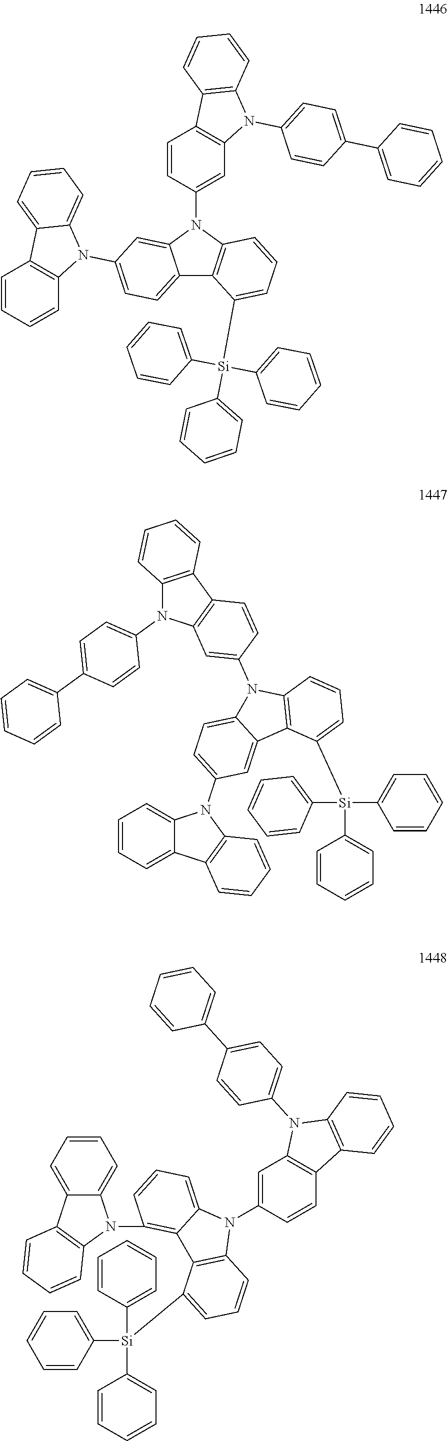 [SMILES: c1ccc(-c2ccc(-n3c4ccccc4c4ccc(-n5c6cc(-n7c8ccccc8c8ccccc87)ccc6c6c([Si](c7ccccc7)(c7ccccc7)c7ccccc7)cccc65)cc43)cc2)cc1 ; c1ccc(-c2ccc(-n3c4ccccc4c4ccc(-n5c6ccc(-n7c8ccccc8c8ccccc87)cc6c6c([Si](c7ccccc7)(c7ccccc7)c7ccccc7)cccc65)cc43)cc2)cc1 ; c1ccc(-c2ccc(-n3c4ccccc4c4ccc(-n5c6cccc(-n7c8ccccc8c8ccccc87)c6c6c([Si](c7ccccc7)(c7ccccc7)c7ccccc7)cccc65)cc43)cc2)cc1]

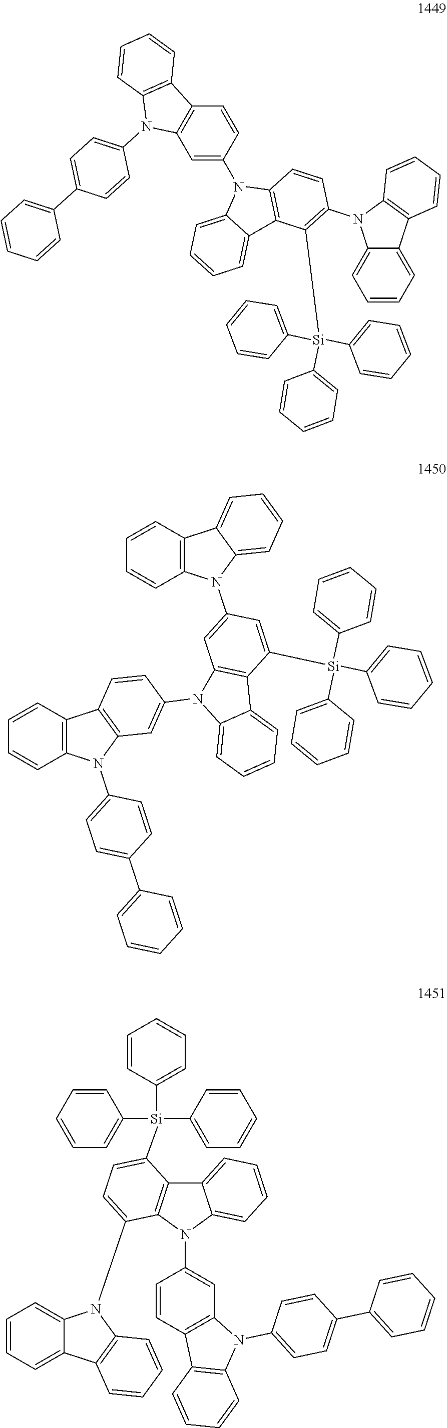 [SMILES: c1ccc(-c2ccc(-n3c4ccccc4c4ccc(-n5c6ccccc6c6c([Si](c7ccccc7)(c7ccccc7)c7ccccc7)c(-n7c8ccccc8c8ccccc87)ccc65)cc43)cc2)cc1 ; c1ccc(-c2ccc(-n3c4ccccc4c4ccc(-n5c6ccccc6c6c([Si](c7ccccc7)(c7ccccc7)c7ccccc7)cc(-n7c8ccccc8c8ccccc87)cc65)cc43)cc2)cc1 ; c1ccc(-c2ccc(-n3c4ccccc4c4ccc(-n5c6ccccc6c6c([Si](c7ccccc7)(c7ccccc7)c7ccccc7)ccc(-n7c8ccccc8c8ccccc87)c65)cc43)cc2)cc1]

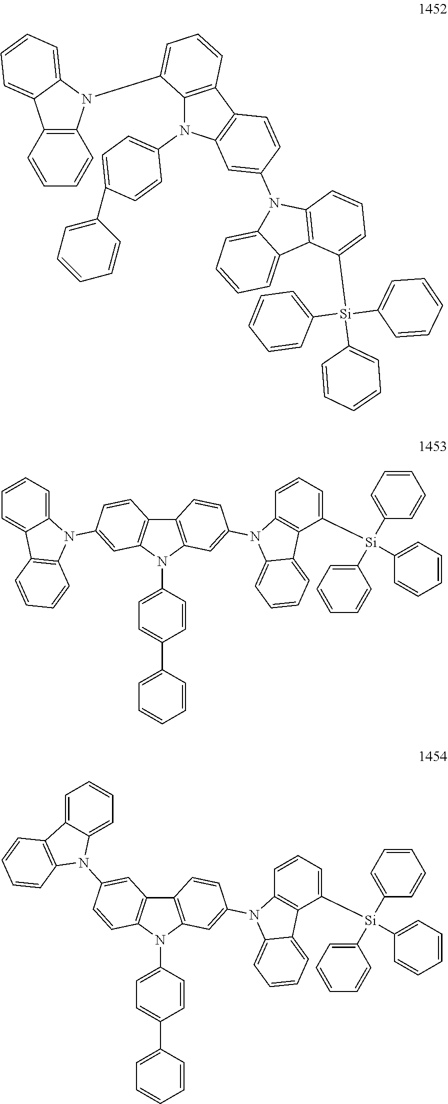 [SMILES: c1ccc(-c2ccc(-n3c4cc(-n5c6ccccc6c6c([Si](c7ccccc7)(c7ccccc7)c7ccccc7)cccc65)ccc4c4cccc(-n5c6ccccc6c6ccccc65)c43)cc2)cc1 ; c1ccc(-c2ccc(-n3c4cc(-n5c6ccccc6c6ccccc65)ccc4c4ccc(-n5c6ccccc6c6c([Si](c7ccccc7)(c7ccccc7)c7ccccc7)cccc65)cc43)cc2)cc1 ; c1ccc(-c2ccc(-n3c4ccc(-n5c6ccccc6c6ccccc65)cc4c4ccc(-n5c6ccccc6c6c([Si](c7ccccc7)(c7ccccc7)c7ccccc7)cccc65)cc43)cc2)cc1]

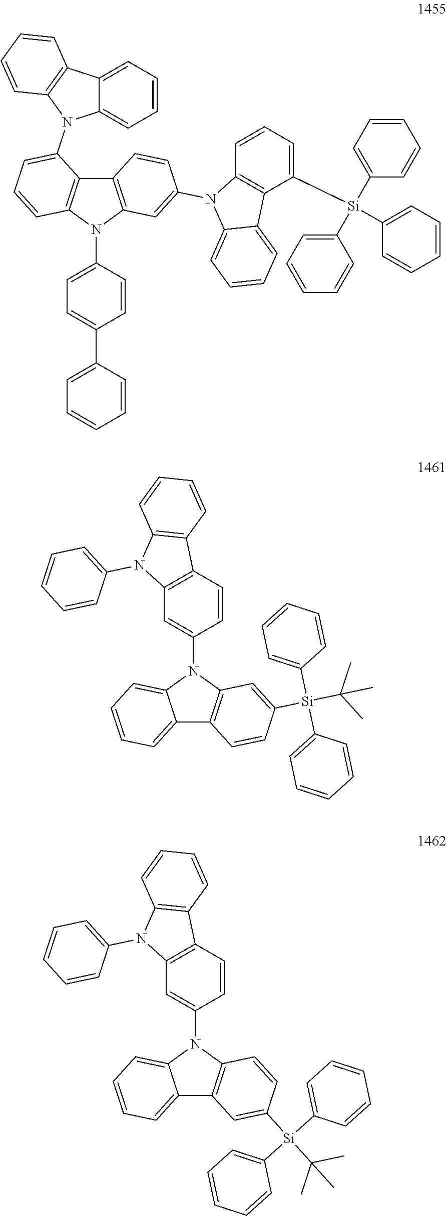 [SMILES: c1ccc(-c2ccc(-n3c4cc(-n5c6ccccc6c6c([Si](c7ccccc7)(c7ccccc7)c7ccccc7)cccc65)ccc4c4c(-n5c6ccccc6c6ccccc65)cccc43)cc2)cc1 ; CC(C)(C)[Si](c1ccccc1)(c1ccccc1)c1ccc2c3ccccc3n(-c3ccc4c5ccccc5n(-c5ccccc5)c4c3)c2c1 ; CC(C)(C)[Si](c1ccccc1)(c1ccccc1)c1ccc2c(c1)c1ccccc1n2-c1ccc2c3ccccc3n(-c3ccccc3)c2c1]

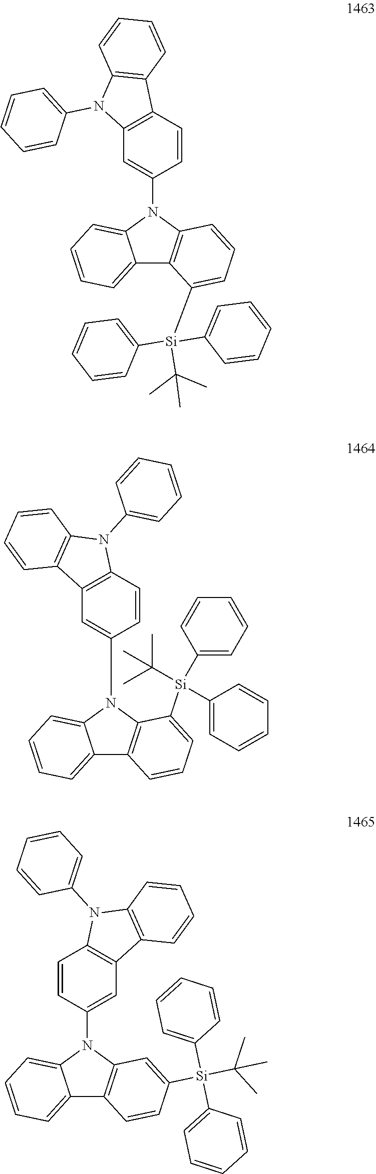 [SMILES: CC(C)(C)[Si](c1ccccc1)(c1ccccc1)c1cccc2c1c1ccccc1n2-c1ccc2c3ccccc3n(-c3ccccc3)c2c1 ; CC(C)(C)[Si](c1ccccc1)(c1ccccc1)c1cccc2c3ccccc3n(-c3ccc4c(c3)c3ccccc3n4-c3ccccc3)c12 ; CC(C)(C)[Si](c1ccccc1)(c1ccccc1)c1ccc2c3ccccc3n(-c3ccc4c(c3)c3ccccc3n4-c3ccccc3)c2c1]

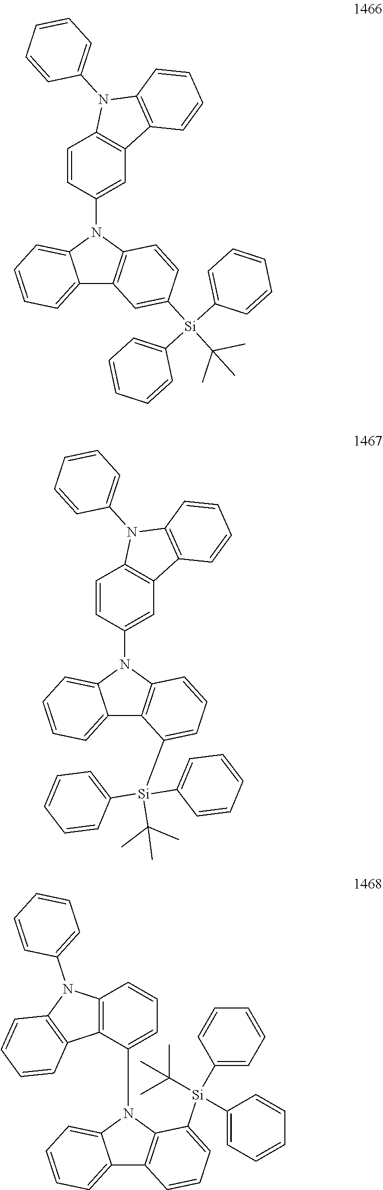 [SMILES: CC(C)(C)[Si](c1ccccc1)(c1ccccc1)c1ccc2c(c1)c1ccccc1n2-c1ccc2c(c1)c1ccccc1n2-c1ccccc1 ; CC(C)(C)[Si](c1ccccc1)(c1ccccc1)c1cccc2c1c1ccccc1n2-c1ccc2c(c1)c1ccccc1n2-c1ccccc1 ; CC(C)(C)[Si](c1ccccc1)(c1ccccc1)c1cccc2c3ccccc3n(-c3cccc4c3c3ccccc3n4-c3ccccc3)c12]

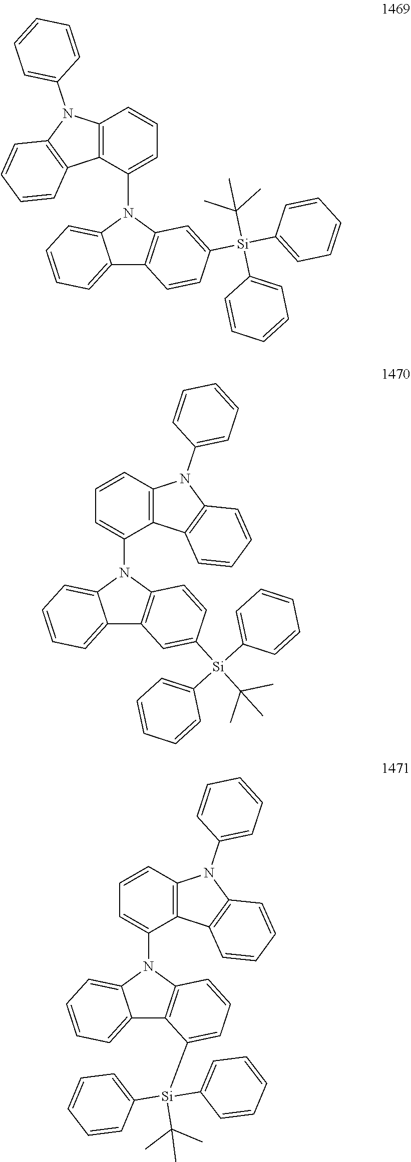 [SMILES: CC(C)(C)[Si](c1ccccc1)(c1ccccc1)c1ccc2c3ccccc3n(-c3cccc4c3c3ccccc3n4-c3ccccc3)c2c1 ; CC(C)(C)[Si](c1ccccc1)(c1ccccc1)c1ccc2c(c1)c1ccccc1n2-c1cccc2c1c1ccccc1n2-c1ccccc1 ; CC(C)(C)[Si](c1ccccc1)(c1ccccc1)c1cccc2c1c1ccccc1n2-c1cccc2c1c1ccccc1n2-c1ccccc1]

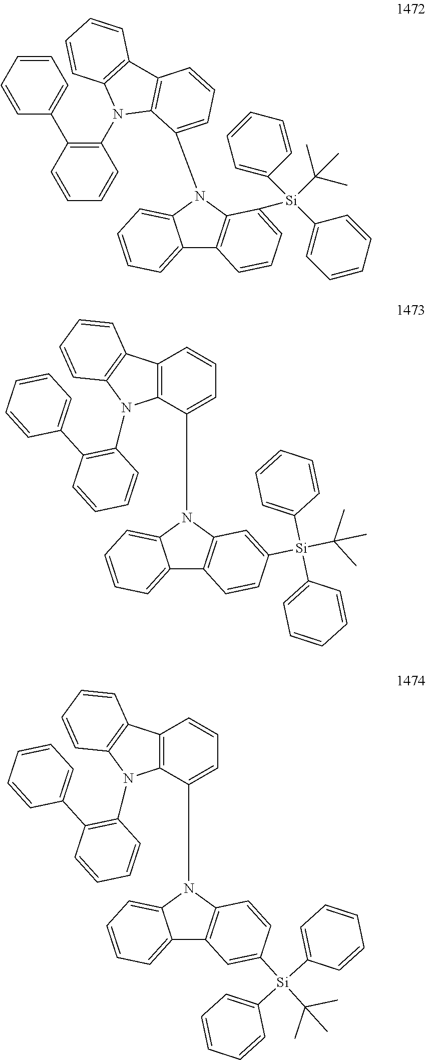 [SMILES: CC(C)(C)[Si](c1ccccc1)(c1ccccc1)c1cccc2c3ccccc3n(-c3cccc4c5ccccc5n(-c5ccccc5-c5ccccc5)c34)c12 ; CC(C)(C)[Si](c1ccccc1)(c1ccccc1)c1ccc2c3ccccc3n(-c3cccc4c5ccccc5n(-c5ccccc5-c5ccccc5)c34)c2c1 ; CC(C)(C)[Si](c1ccccc1)(c1ccccc1)c1ccc2c(c1)c1ccccc1n2-c1cccc2c3ccccc3n(-c3ccccc3-c3ccccc3)c12]

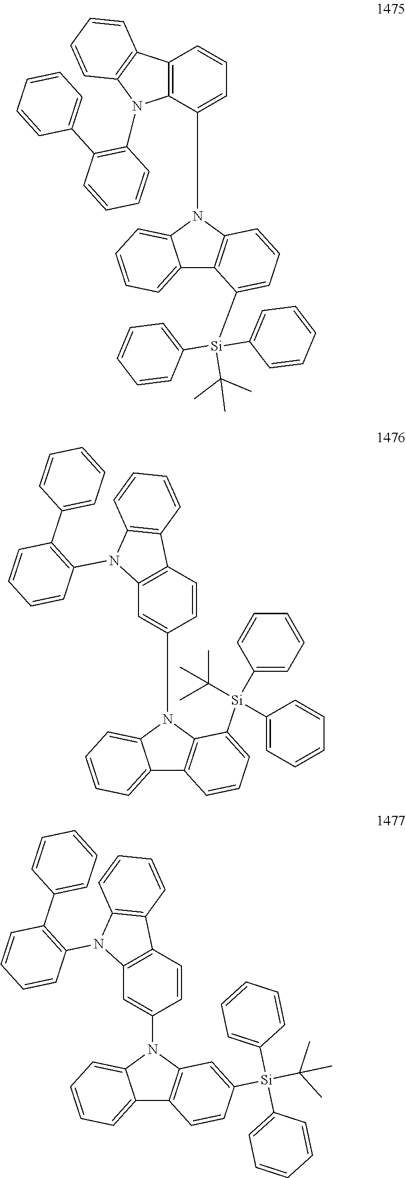

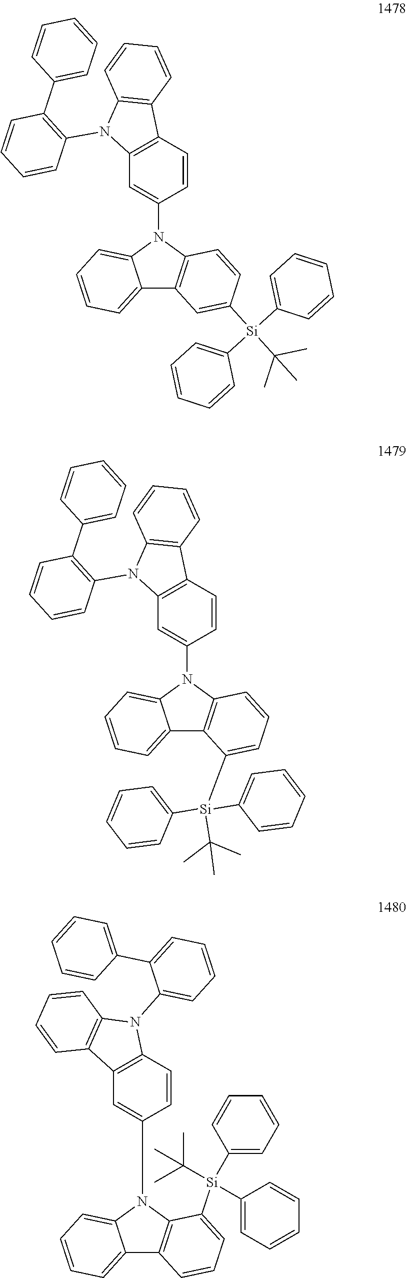 [SMILES: CC(C)(C)[Si](c1ccccc1)(c1ccccc1)c1ccc2c(c1)c1ccccc1n2-c1ccc2c3ccccc3n(-c3ccccc3-c3ccccc3)c2c1 ; CC(C)(C)[Si](c1ccccc1)(c1ccccc1)c1cccc2c1c1ccccc1n2-c1ccc2c3ccccc3n(-c3ccccc3-c3ccccc3)c2c1 ; CC(C)(C)[Si](c1ccccc1)(c1ccccc1)c1cccc2c3ccccc3n(-c3ccc4c(c3)c3ccccc3n4-c3ccccc3-c3ccccc3)c12]

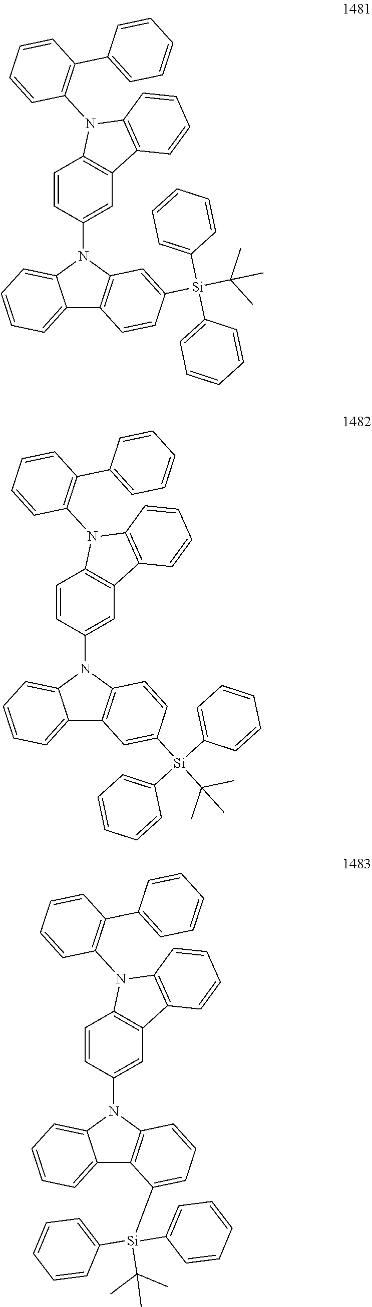

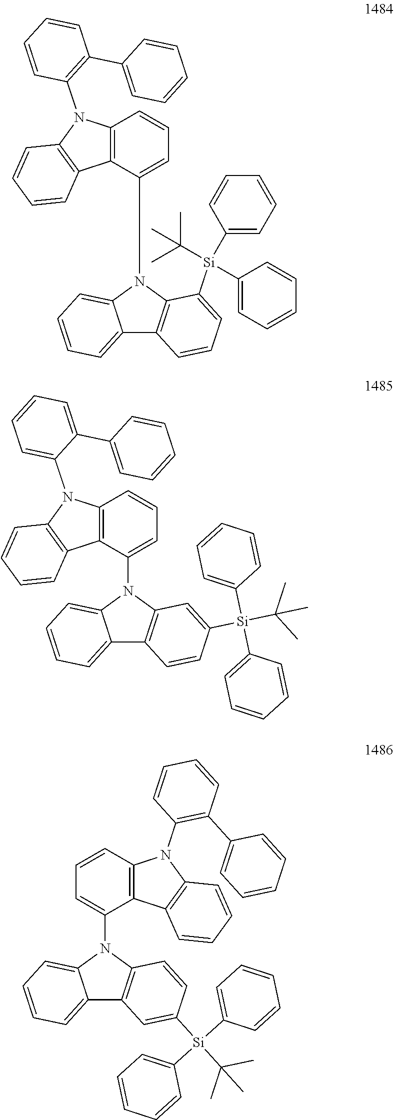 [SMILES: CC(C)(C)[Si](c1ccccc1)(c1ccccc1)c1cccc2c3ccccc3n(-c3cccc4c3c3ccccc3n4-c3ccccc3-c3ccccc3)c12 ; CC(C)(C)[Si](c1ccccc1)(c1ccccc1)c1ccc2c3ccccc3n(-c3cccc4c3c3ccccc3n4-c3ccccc3-c3ccccc3)c2c1 ; CC(C)(C)[Si](c1ccccc1)(c1ccccc1)c1ccc2c(c1)c1ccccc1n2-c1cccc2c1c1ccccc1n2-c1ccccc1-c1ccccc1]

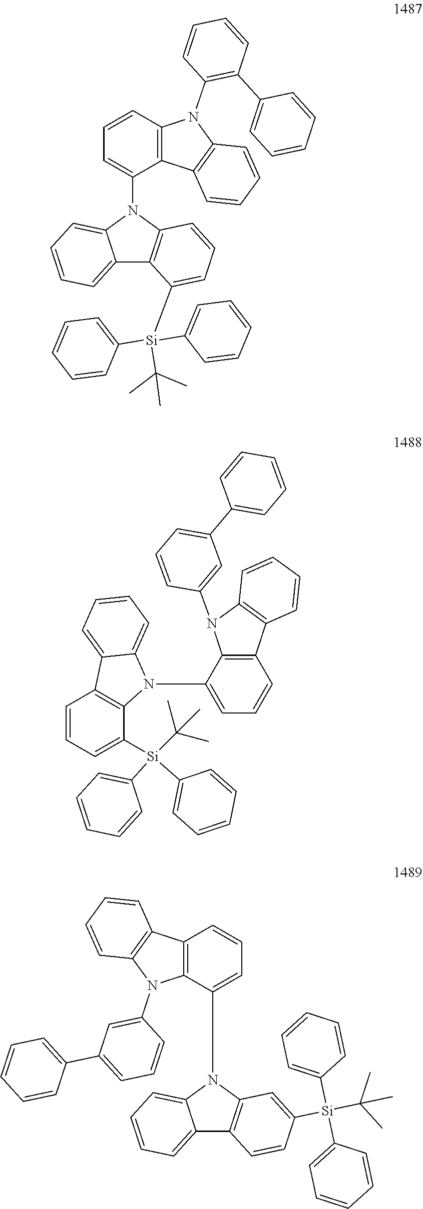 [SMILES: CC(C)(C)[Si](c1ccccc1)(c1ccccc1)c1cccc2c1c1ccccc1n2-c1cccc2c1c1ccccc1n2-c1ccccc1-c1ccccc1 ; CC(C)(C)[Si](c1ccccc1)(c1ccccc1)c1cccc2c3ccccc3n(-c3cccc4c5ccccc5n(-c5cccc(-c6ccccc6)c5)c34)c12 ; CC(C)(C)[Si](c1ccccc1)(c1ccccc1)c1ccc2c3ccccc3n(-c3cccc4c5ccccc5n(-c5cccc(-c6ccccc6)c5)c34)c2c1]

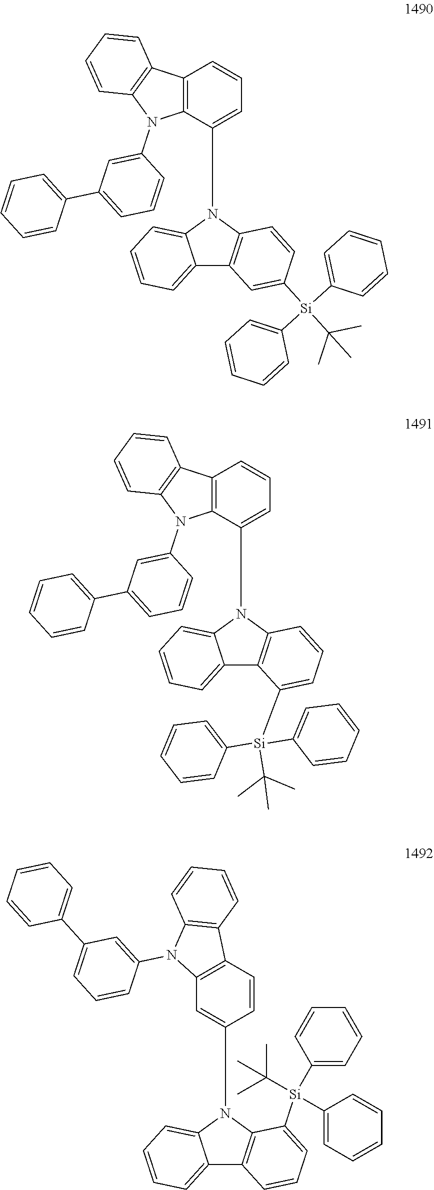 [SMILES: CC(C)(C)[Si](c1ccccc1)(c1ccccc1)c1ccc2c(c1)c1ccccc1n2-c1cccc2c3ccccc3n(-c3cccc(-c4ccccc4)c3)c12 ; CC(C)(C)[Si](c1ccccc1)(c1ccccc1)c1cccc2c1c1ccccc1n2-c1cccc2c3ccccc3n(-c3cccc(-c4ccccc4)c3)c12 ; CC(C)(C)[Si](c1ccccc1)(c1ccccc1)c1cccc2c3ccccc3n(-c3ccc4c5ccccc5n(-c5cccc(-c6ccccc6)c5)c4c3)c12]

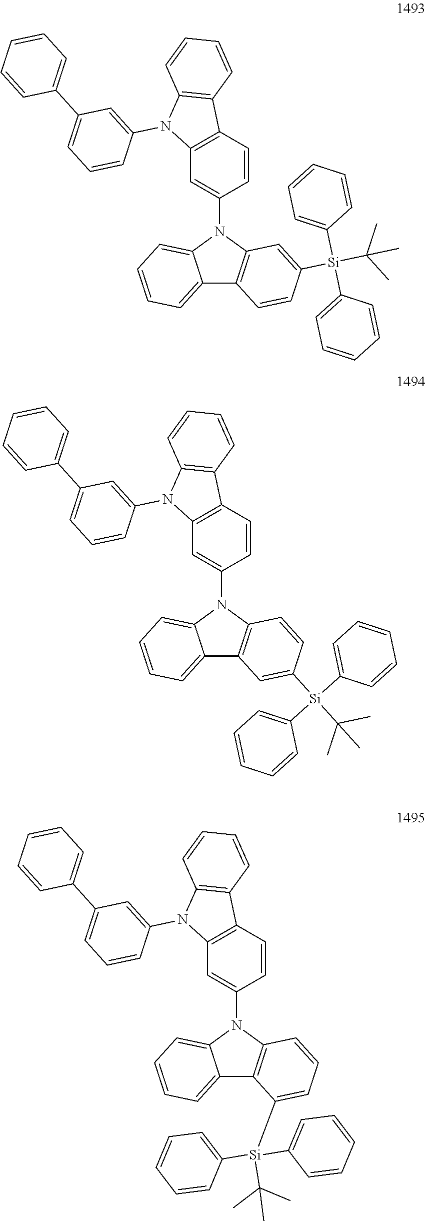 [SMILES: CC(C)(C)[Si](c1ccccc1)(c1ccccc1)c1ccc2c3ccccc3n(-c3ccc4c5ccccc5n(-c5cccc(-c6ccccc6)c5)c4c3)c2c1 ; CC(C)(C)[Si](c1ccccc1)(c1ccccc1)c1ccc2c(c1)c1ccccc1n2-c1ccc2c3ccccc3n(-c3cccc(-c4ccccc4)c3)c2c1 ; CC(C)(C)[Si](c1ccccc1)(c1ccccc1)c1cccc2c1c1ccccc1n2-c1ccc2c3ccccc3n(-c3cccc(-c4ccccc4)c3)c2c1]

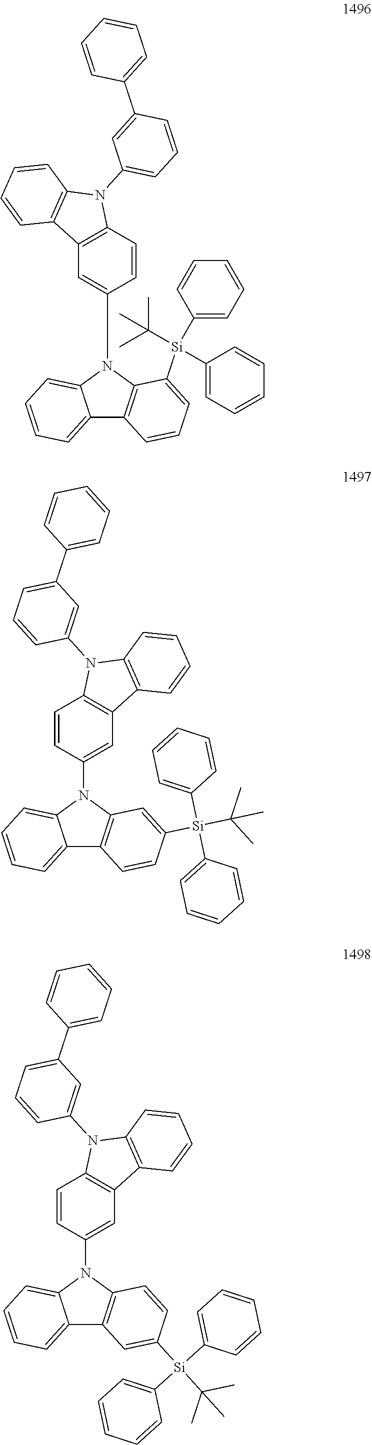 [SMILES: CC(C)(C)[Si](c1ccccc1)(c1ccccc1)c1cccc2c3ccccc3n(-c3ccc4c(c3)c3ccccc3n4-c3cccc(-c4ccccc4)c3)c12 ; CC(C)(C)[Si](c1ccccc1)(c1ccccc1)c1ccc2c3ccccc3n(-c3ccc4c(c3)c3ccccc3n4-c3cccc(-c4ccccc4)c3)c2c1 ; CC(C)(C)[Si](c1ccccc1)(c1ccccc1)c1ccc2c(c1)c1ccccc1n2-c1ccc2c(c1)c1ccccc1n2-c1cccc(-c2ccccc2)c1]

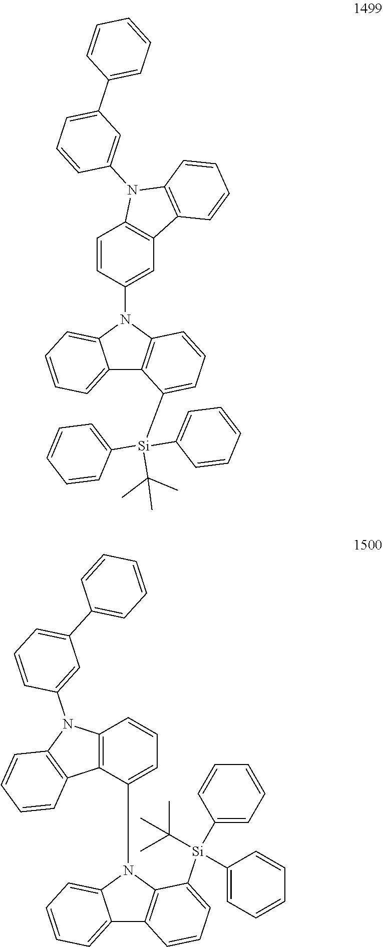 [SMILES: CC(C)(C)[Si](c1ccccc1)(c1ccccc1)c1cccc2c1c1ccccc1n2-c1ccc2c(c1)c1ccccc1n2-c1cccc(-c2ccccc2)c1 ; CC(C)(C)[Si](c1ccccc1)(c1ccccc1)c1cccc2c3ccccc3n(-c3cccc4c3c3ccccc3n4-c3cccc(-c4ccccc4)c3)c12]

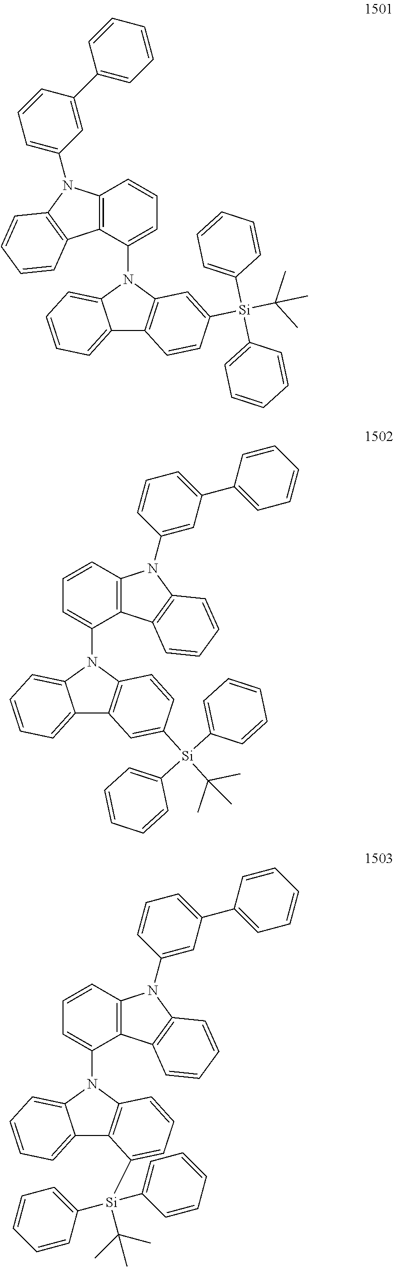

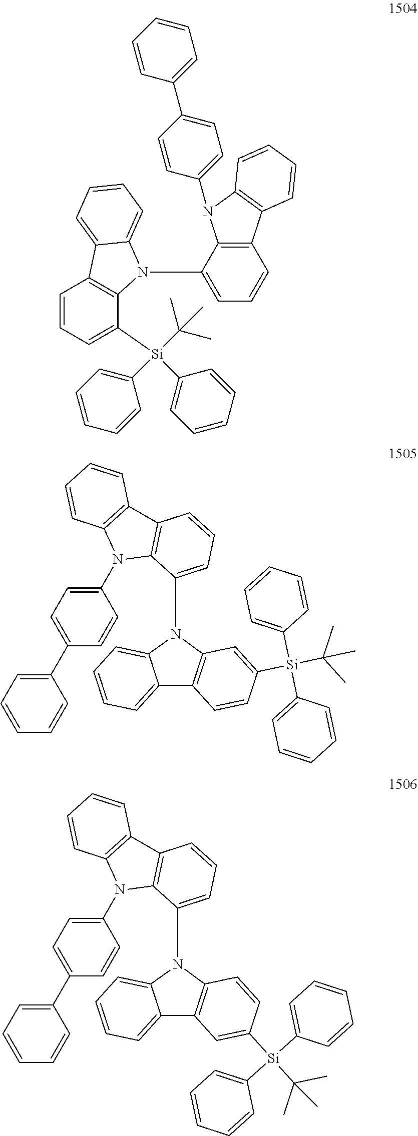

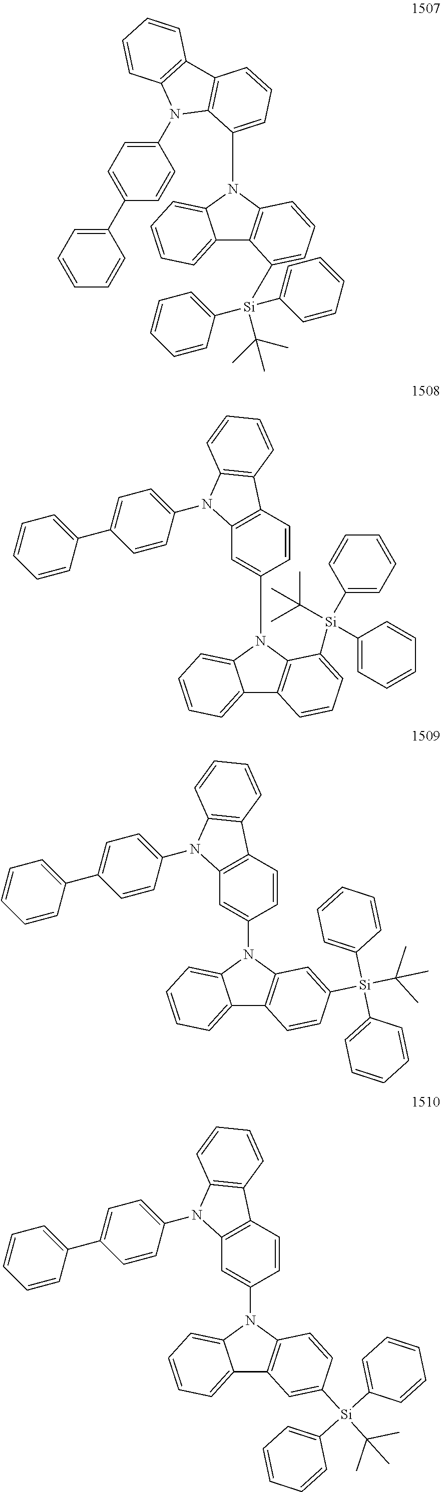

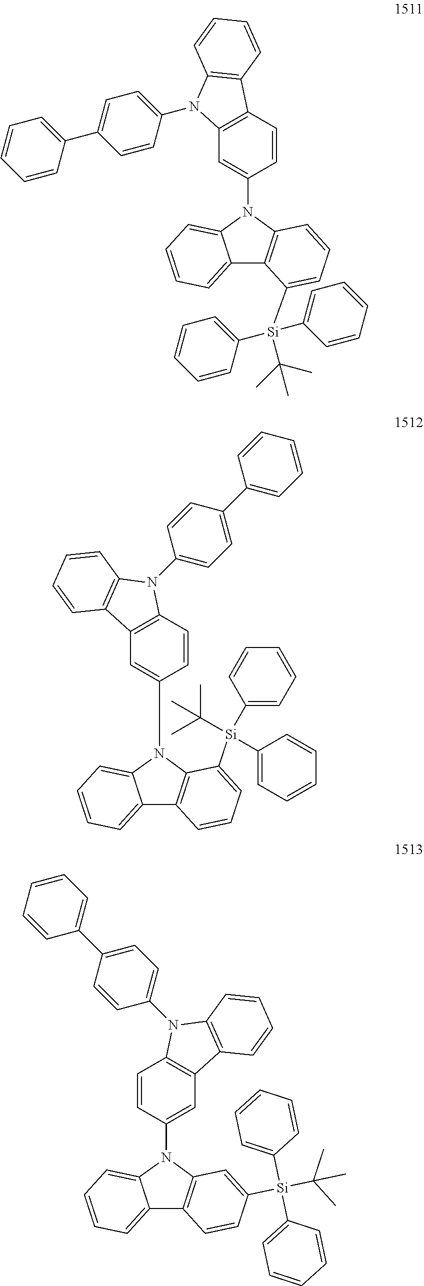

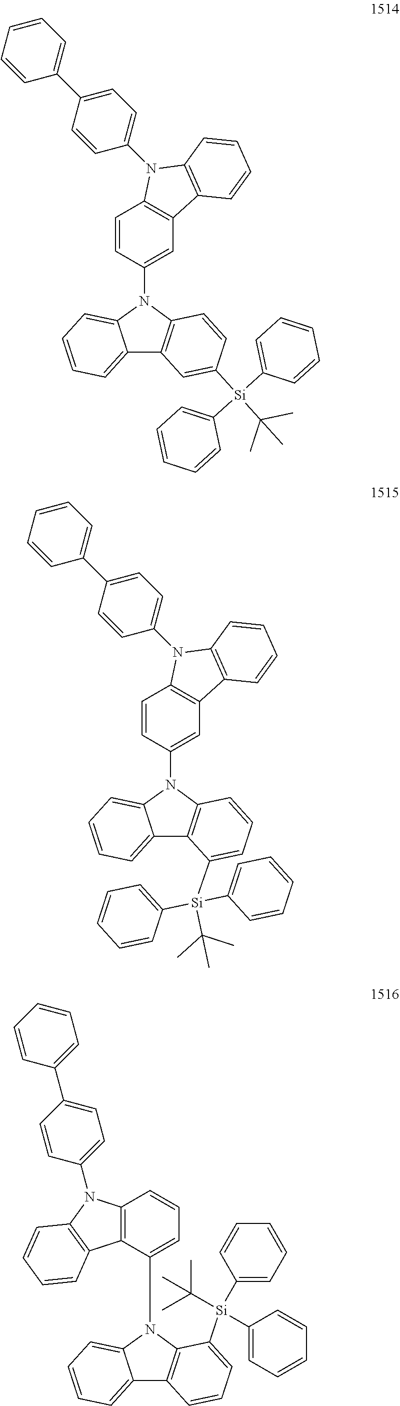 [SMILES: CC(C)(C)[Si](c1ccccc1)(c1ccccc1)c1ccc2c(c1)c1ccccc1n2-c1ccc2c(c1)c1ccccc1n2-c1ccc(-c2ccccc2)cc1 ; CC(C)(C)[Si](c1ccccc1)(c1ccccc1)c1cccc2c1c1ccccc1n2-c1ccc2c(c1)c1ccccc1n2-c1ccc(-c2ccccc2)cc1 ; CC(C)(C)[Si](c1ccccc1)(c1ccccc1)c1cccc2c3ccccc3n(-c3cccc4c3c3ccccc3n4-c3ccc(-c4ccccc4)cc3)c12]

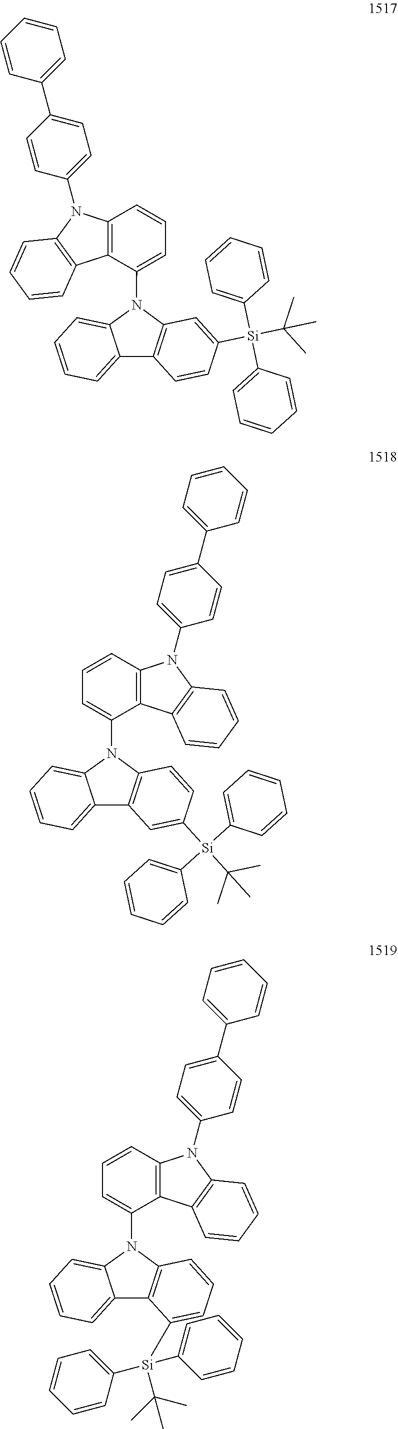

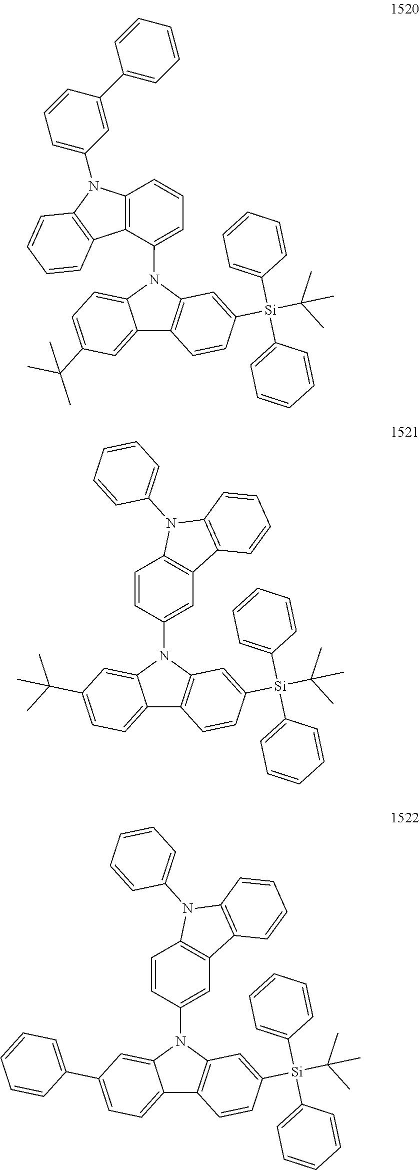

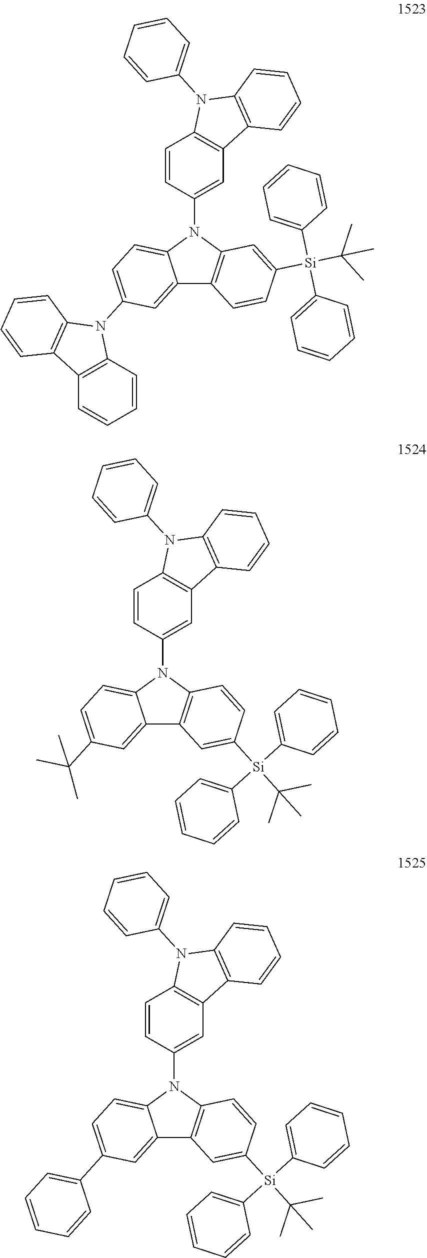

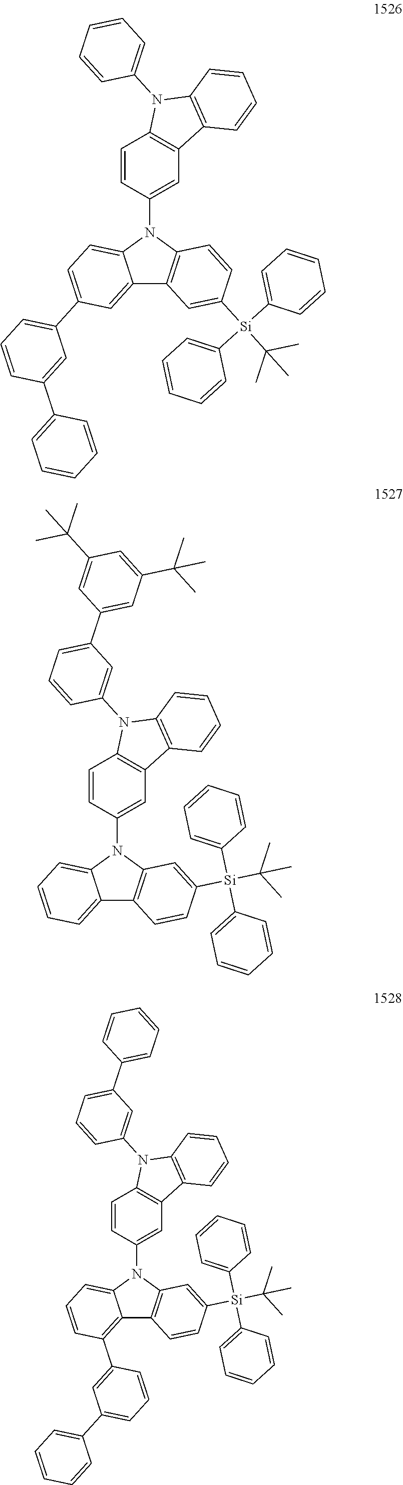

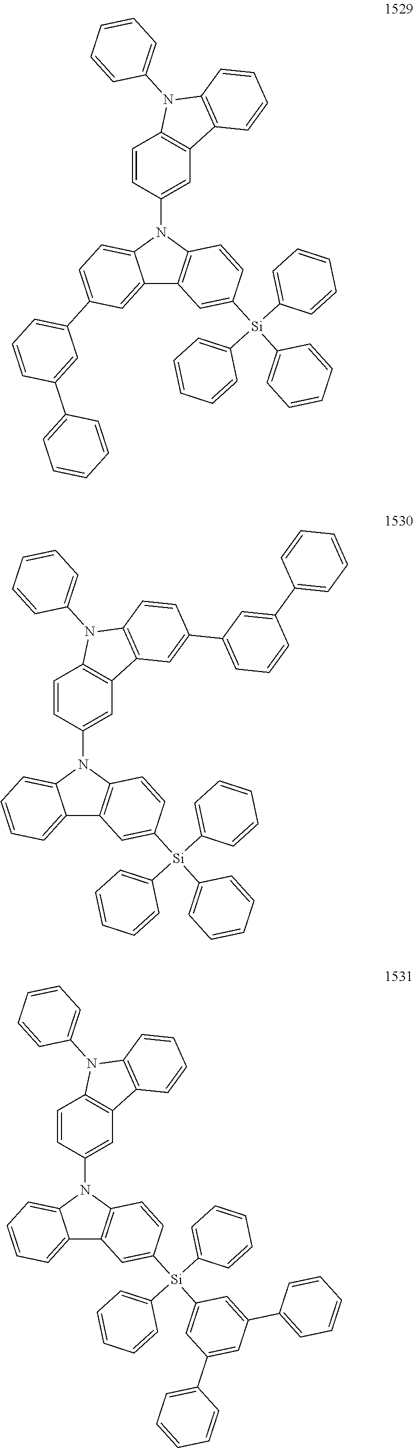 [SMILES: c1ccc(-c2cccc(-c3ccc4c(c3)c3cc([Si](c5ccccc5)(c5ccccc5)c5ccccc5)ccc3n4-c3ccc4c(c3)c3ccccc3n4-c3ccccc3)c2)cc1 ; c1ccc(-c2cccc(-c3ccc4c(c3)c3cc(-n5c6ccccc6c6cc([Si](c7ccccc7)(c7ccccc7)c7ccccc7)ccc65)ccc3n4-c3ccccc3)c2)cc1 ; c1ccc(-c2cc(-c3ccccc3)cc([Si](c3ccccc3)(c3ccccc3)c3ccc4c(c3)c3ccccc3n4-c3ccc4c(c3)c3ccccc3n4-c3ccccc3)c2)cc1]

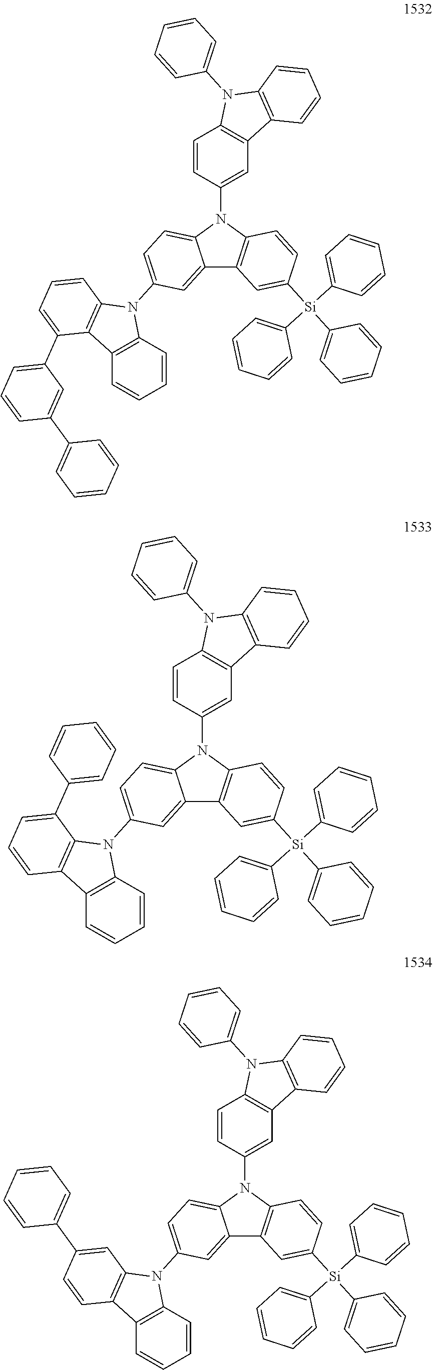 [SMILES: c1ccc(-c2cccc(-c3cccc4c3c3ccccc3n4-c3ccc4c(c3)c3cc([Si](c5ccccc5)(c5ccccc5)c5ccccc5)ccc3n4-c3ccc4c(c3)c3ccccc3n4-c3ccccc3)c2)cc1 ; c1ccc(-c2cccc3c4ccccc4n(-c4ccc5c(c4)c4cc([Si](c6ccccc6)(c6ccccc6)c6ccccc6)ccc4n5-c4ccc5c(c4)c4ccccc4n5-c4ccccc4)c23)cc1 ; c1ccc(-c2ccc3c4ccccc4n(-c4ccc5c(c4)c4cc([Si](c6ccccc6)(c6ccccc6)c6ccccc6)ccc4n5-c4ccc5c(c4)c4ccccc4n5-c4ccccc4)c3c2)cc1]

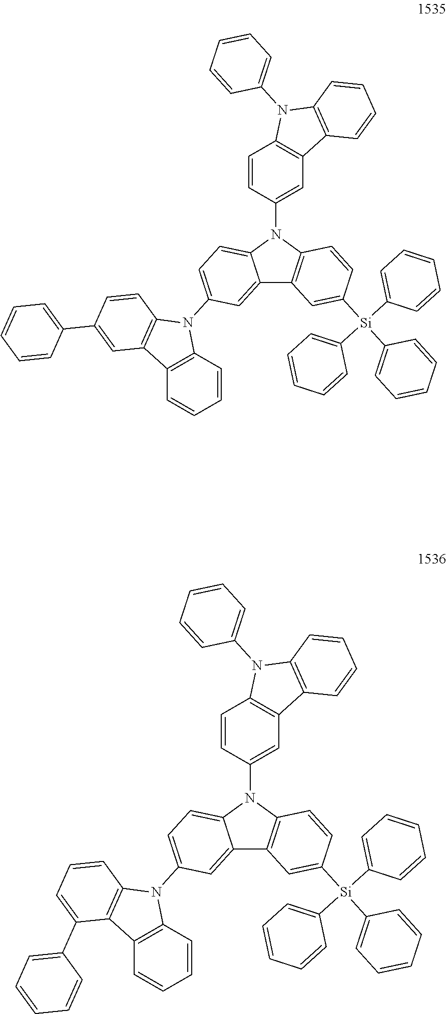 [SMILES: c1ccc(-c2ccc3c(c2)c2ccccc2n3-c2ccc3c(c2)c2cc([Si](c4ccccc4)(c4ccccc4)c4ccccc4)ccc2n3-c2ccc3c(c2)c2ccccc2n3-c2ccccc2)cc1 ; c1ccc(-c2cccc3c2c2ccccc2n3-c2ccc3c(c2)c2cc([Si](c4ccccc4)(c4ccccc4)c4ccccc4)ccc2n3-c2ccc3c(c2)c2ccccc2n3-c2ccccc2)cc1]

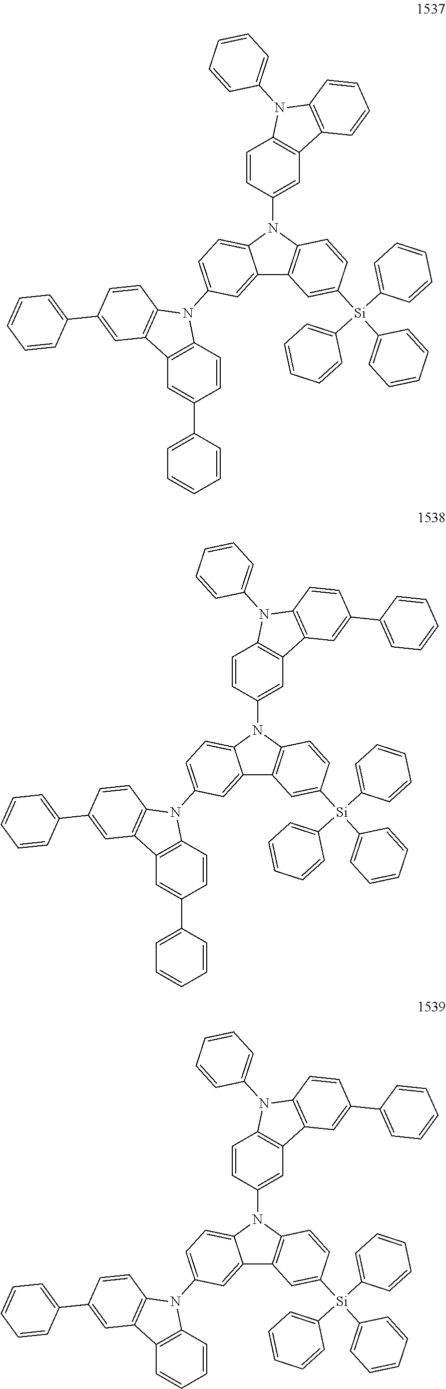 [SMILES: c1ccc(-c2ccc3c(c2)c2cc(-c4ccccc4)ccc2n3-c2ccc3c(c2)c2cc([Si](c4ccccc4)(c4ccccc4)c4ccccc4)ccc2n3-c2ccc3c(c2)c2ccccc2n3-c2ccccc2)cc1 ; c1ccc(-c2ccc3c(c2)c2cc(-c4ccccc4)ccc2n3-c2ccc3c(c2)c2cc([Si](c4ccccc4)(c4ccccc4)c4ccccc4)ccc2n3-c2ccc3c(c2)c2cc(-c4ccccc4)ccc2n3-c2ccccc2)cc1 ; c1ccc(-c2ccc3c(c2)c2ccccc2n3-c2ccc3c(c2)c2cc([Si](c4ccccc4)(c4ccccc4)c4ccccc4)ccc2n3-c2ccc3c(c2)c2cc(-c4ccccc4)ccc2n3-c2ccccc2)cc1]

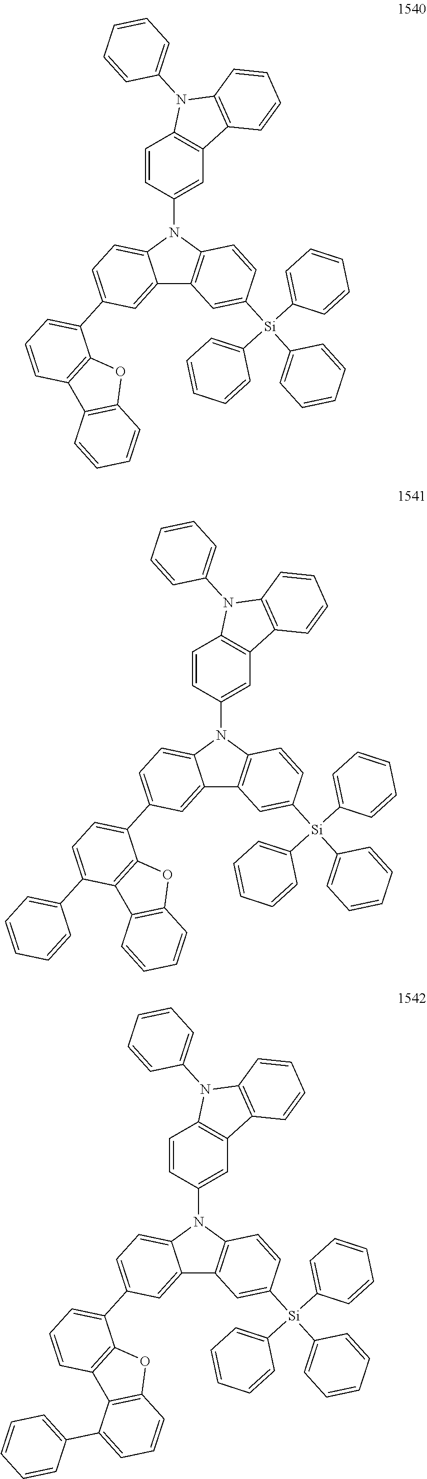

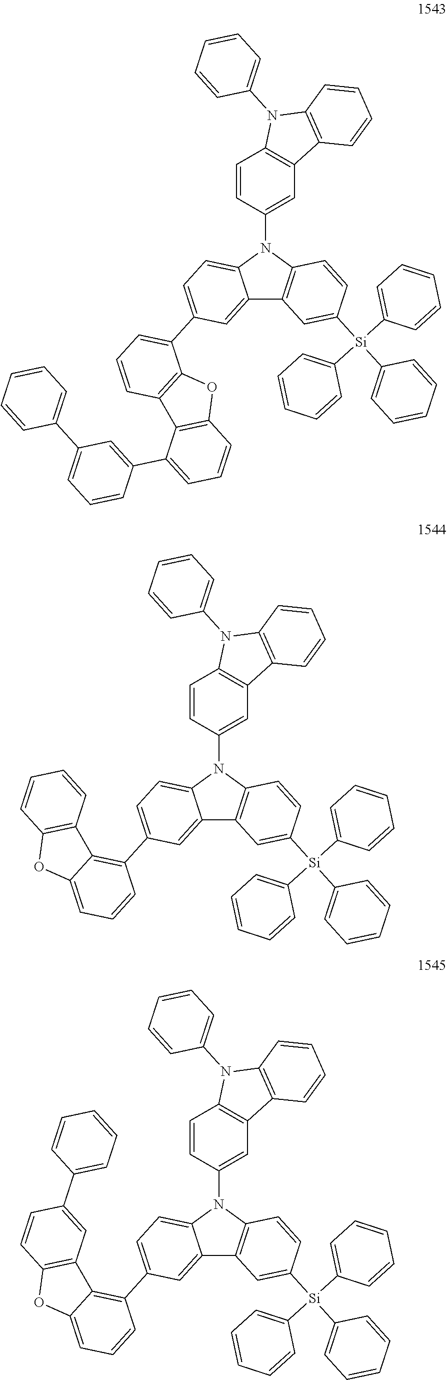 [SMILES: c1ccc(-c2cccc(-c3cccc4oc5c(-c6ccc7c(c6)c6cc([Si](c8ccccc8)(c8ccccc8)c8ccccc8)ccc6n7-c6ccc7c(c6)c6ccccc6n7-c6ccccc6)cccc5c34)c2)cc1 ; c1ccc(-n2c3ccccc3c3cc(-n4c5ccc(-c6cccc7oc8ccccc8c67)cc5c5cc([Si](c6ccccc6)(c6ccccc6)c6ccccc6)ccc54)ccc32)cc1 ; c1ccc(-c2ccc3oc4cccc(-c5ccc6c(c5)c5cc([Si](c7ccccc7)(c7ccccc7)c7ccccc7)ccc5n6-c5ccc6c(c5)c5ccccc5n6-c5ccccc5)c4c3c2)cc1]

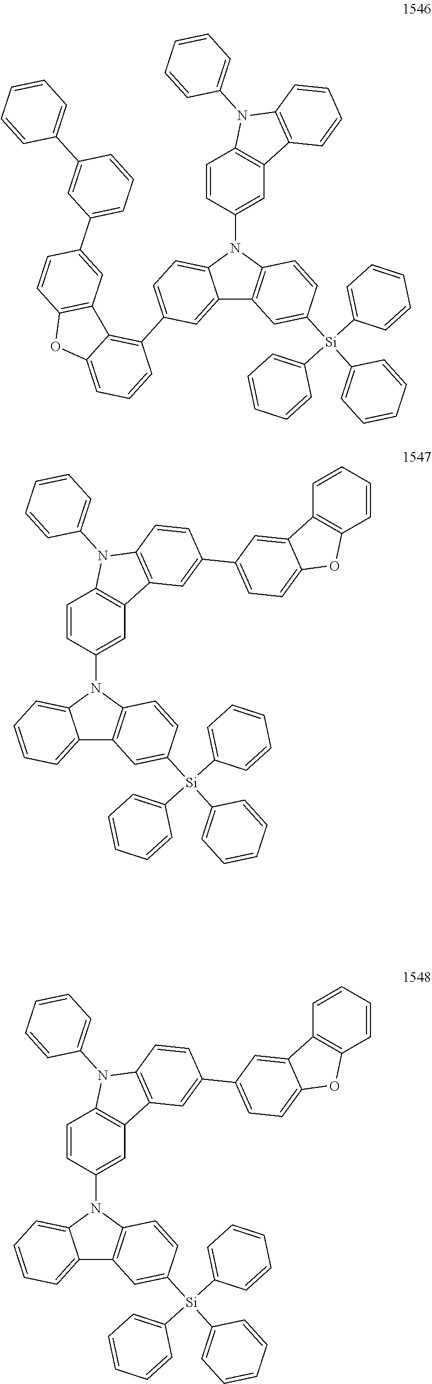 [SMILES: c1ccc(-c2cccc(-c3ccc4oc5cccc(-c6ccc7c(c6)c6cc([Si](c8ccccc8)(c8ccccc8)c8ccccc8)ccc6n7-c6ccc7c(c6)c6ccccc6n7-c6ccccc6)c5c4c3)c2)cc1 ; c1ccc(-n2c3ccc(-c4ccc5oc6ccccc6c5c4)cc3c3cc(-n4c5ccccc5c5cc([Si](c6ccccc6)(c6ccccc6)c6ccccc6)ccc54)ccc32)cc1 ; c1ccc(-n2c3ccc(-c4ccc5oc6ccccc6c5c4)cc3c3cc(-n4c5ccccc5c5cc([Si](c6ccccc6)(c6ccccc6)c6ccccc6)ccc54)ccc32)cc1]

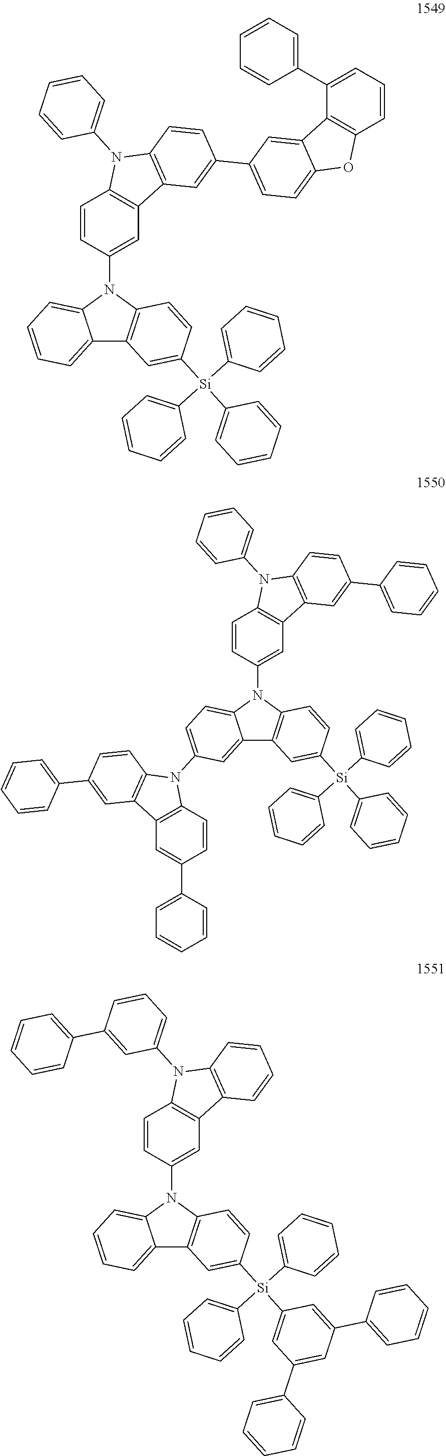

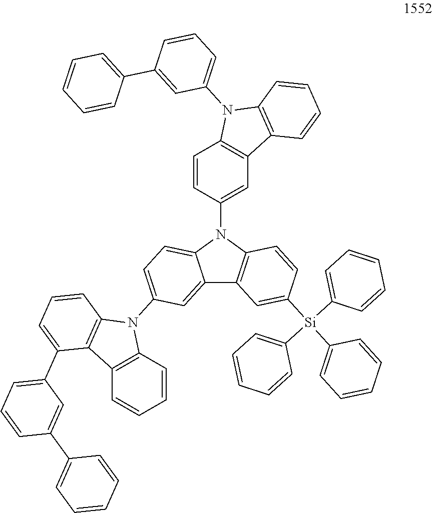 [SMILES: c1ccc(-c2cccc(-c3cccc4c3c3ccccc3n4-c3ccc4c(c3)c3cc([Si](c5ccccc5)(c5ccccc5)c5ccccc5)ccc3n4-c3ccc4c(c3)c3ccccc3n4-c3cccc(-c4ccccc4)c3)c2)cc1]

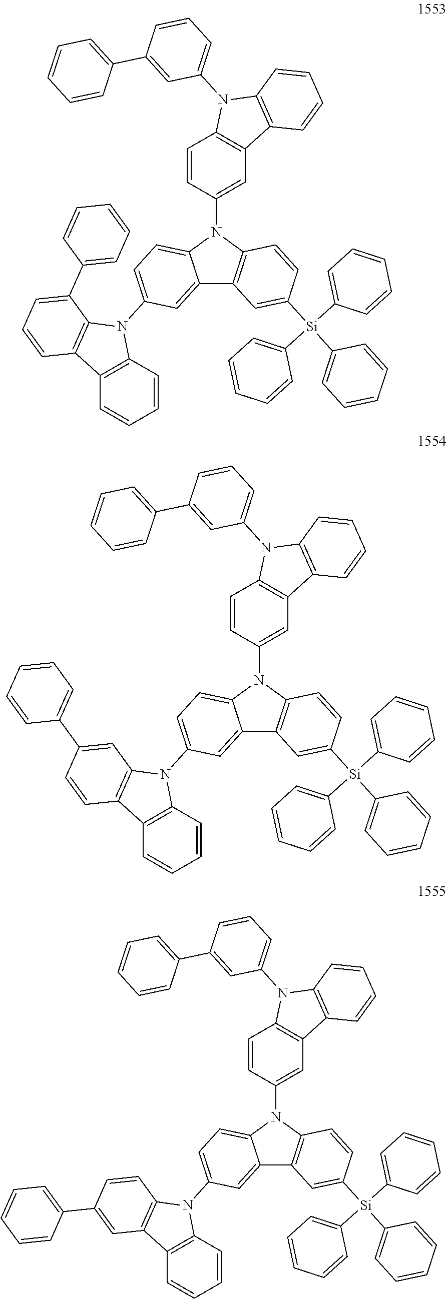 [SMILES: c1ccc(-c2cccc(-n3c4ccccc4c4cc(-n5c6ccc(-n7c8ccccc8c8cccc(-c9ccccc9)c87)cc6c6cc([Si](c7ccccc7)(c7ccccc7)c7ccccc7)ccc65)ccc43)c2)cc1 ; c1ccc(-c2cccc(-n3c4ccccc4c4cc(-n5c6ccc(-n7c8ccccc8c8ccc(-c9ccccc9)cc87)cc6c6cc([Si](c7ccccc7)(c7ccccc7)c7ccccc7)ccc65)ccc43)c2)cc1 ; c1ccc(-c2cccc(-n3c4ccccc4c4cc(-n5c6ccc(-n7c8ccccc8c8cc(-c9ccccc9)ccc87)cc6c6cc([Si](c7ccccc7)(c7ccccc7)c7ccccc7)ccc65)ccc43)c2)cc1]

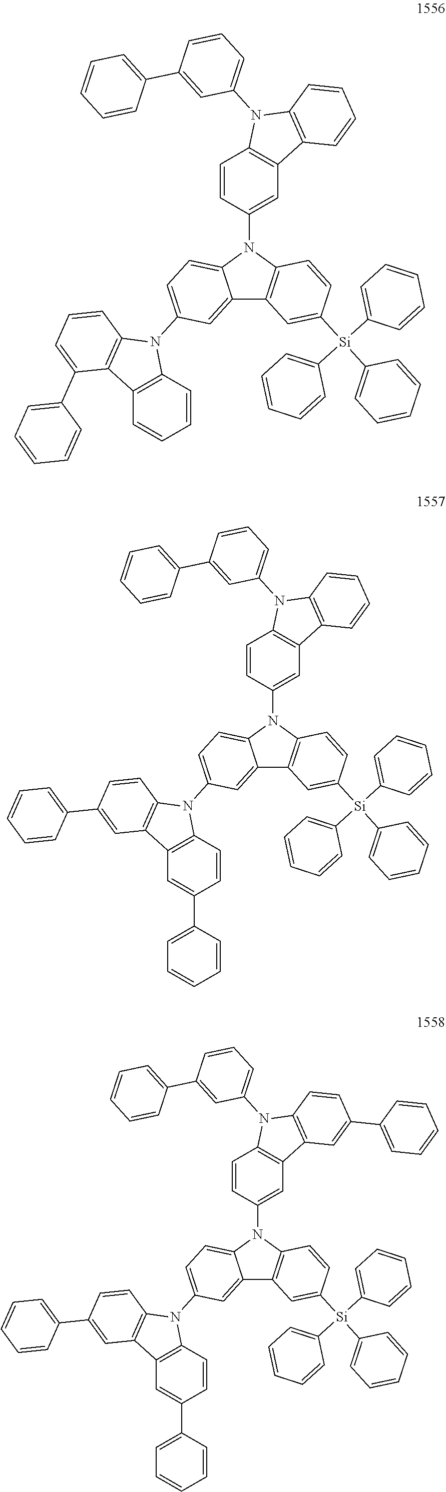 [SMILES: c1ccc(-c2cccc(-n3c4ccccc4c4cc(-n5c6ccc(-n7c8ccccc8c8c(-c9ccccc9)cccc87)cc6c6cc([Si](c7ccccc7)(c7ccccc7)c7ccccc7)ccc65)ccc43)c2)cc1 ; c1ccc(-c2cccc(-n3c4ccccc4c4cc(-n5c6ccc(-n7c8ccc(-c9ccccc9)cc8c8cc(-c9ccccc9)ccc87)cc6c6cc([Si](c7ccccc7)(c7ccccc7)c7ccccc7)ccc65)ccc43)c2)cc1 ; c1ccc(-c2cccc(-n3c4ccc(-c5ccccc5)cc4c4cc(-n5c6ccc(-n7c8ccc(-c9ccccc9)cc8c8cc(-c9ccccc9)ccc87)cc6c6cc([Si](c7ccccc7)(c7ccccc7)c7ccccc7)ccc65)ccc43)c2)cc1]

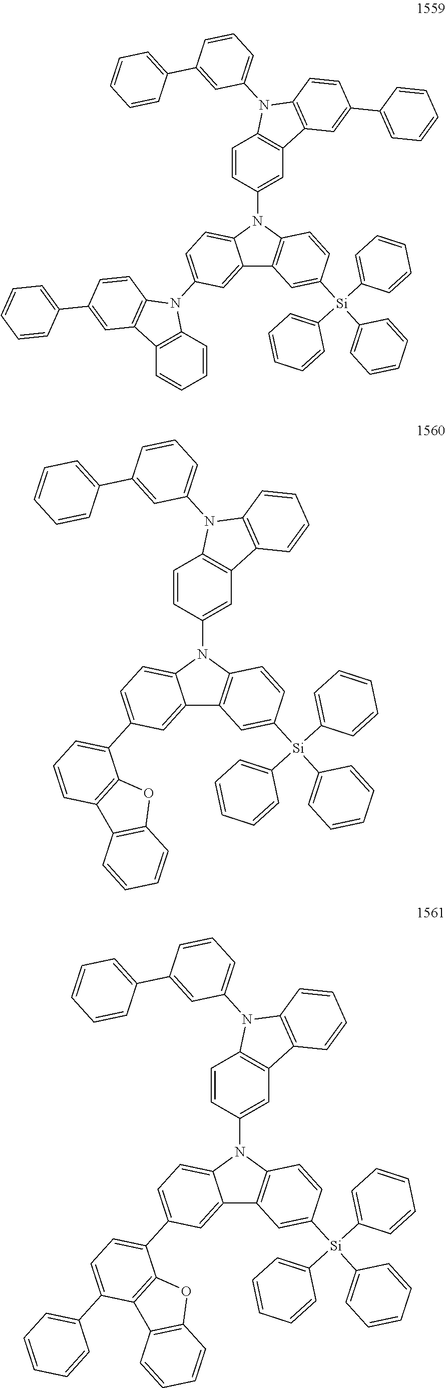 [SMILES: c1ccc(-c2cccc(-n3c4ccc(-c5ccccc5)cc4c4cc(-n5c6ccc(-n7c8ccccc8c8cc(-c9ccccc9)ccc87)cc6c6cc([Si](c7ccccc7)(c7ccccc7)c7ccccc7)ccc65)ccc43)c2)cc1 ; c1ccc(-c2cccc(-n3c4ccccc4c4cc(-n5c6ccc(-c7cccc8c7oc7ccccc78)cc6c6cc([Si](c7ccccc7)(c7ccccc7)c7ccccc7)ccc65)ccc43)c2)cc1 ; c1ccc(-c2cccc(-n3c4ccccc4c4cc(-n5c6ccc(-c7ccc(-c8ccccc8)c8c7oc7ccccc78)cc6c6cc([Si](c7ccccc7)(c7ccccc7)c7ccccc7)ccc65)ccc43)c2)cc1]

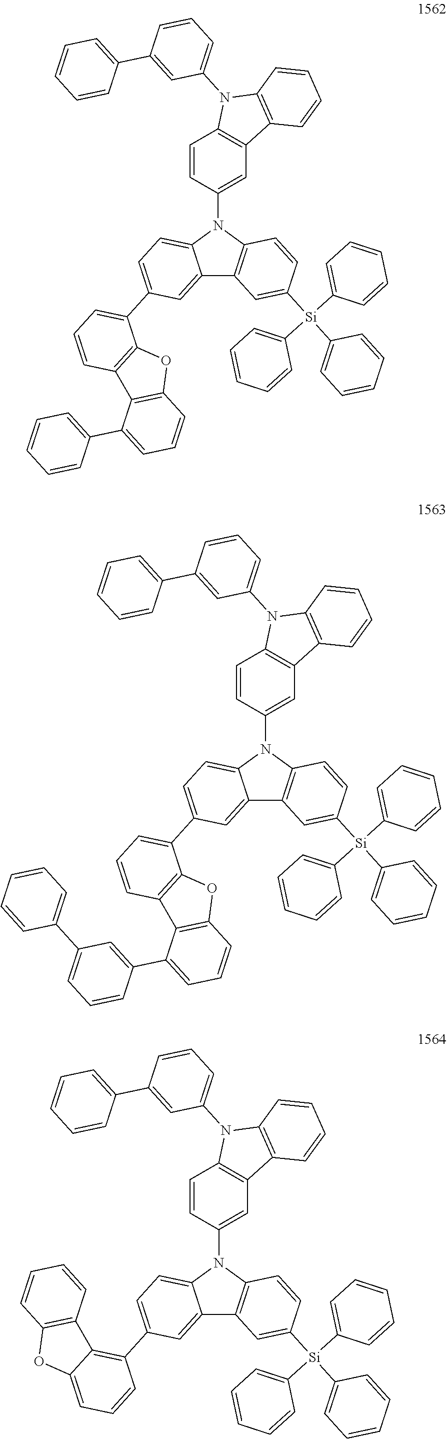 [SMILES: c1ccc(-c2cccc(-n3c4ccccc4c4cc(-n5c6ccc(-c7cccc8c7oc7cccc(-c9ccccc9)c78)cc6c6cc([Si](c7ccccc7)(c7ccccc7)c7ccccc7)ccc65)ccc43)c2)cc1 ; c1ccc(-c2cccc(-c3cccc4oc5c(-c6ccc7c(c6)c6cc([Si](c8ccccc8)(c8ccccc8)c8ccccc8)ccc6n7-c6ccc7c(c6)c6ccccc6n7-c6cccc(-c7ccccc7)c6)cccc5c34)c2)cc1 ; c1ccc(-c2cccc(-n3c4ccccc4c4cc(-n5c6ccc(-c7cccc8oc9ccccc9c78)cc6c6cc([Si](c7ccccc7)(c7ccccc7)c7ccccc7)ccc65)ccc43)c2)cc1]

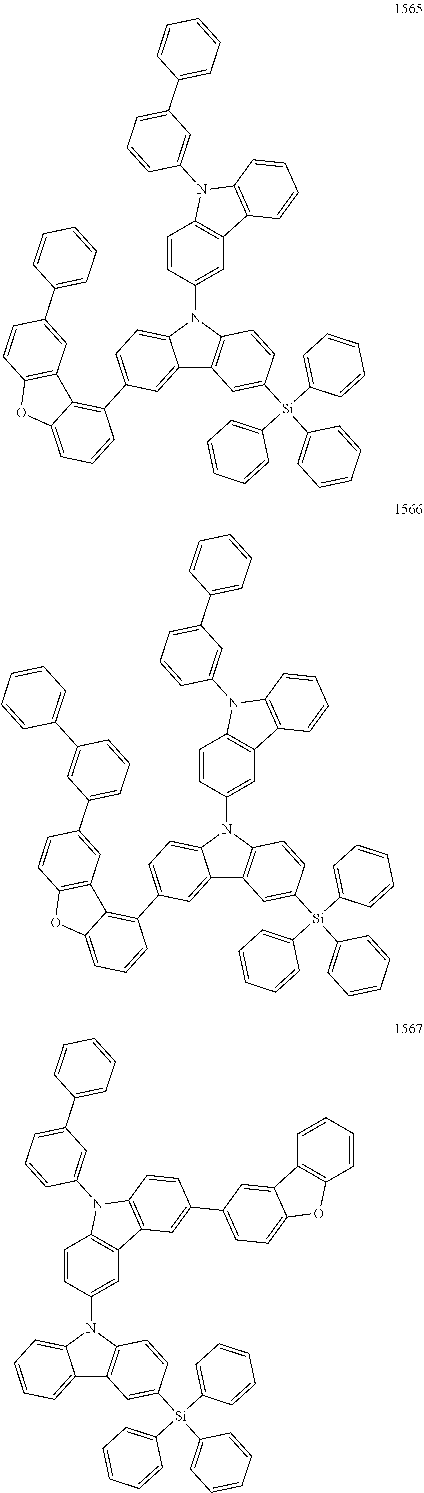 [SMILES: c1ccc(-c2cccc(-n3c4ccccc4c4cc(-n5c6ccc(-c7cccc8oc9ccc(-c%10ccccc%10)cc9c78)cc6c6cc([Si](c7ccccc7)(c7ccccc7)c7ccccc7)ccc65)ccc43)c2)cc1 ; c1ccc(-c2cccc(-c3ccc4oc5cccc(-c6ccc7c(c6)c6cc([Si](c8ccccc8)(c8ccccc8)c8ccccc8)ccc6n7-c6ccc7c(c6)c6ccccc6n7-c6cccc(-c7ccccc7)c6)c5c4c3)c2)cc1 ; c1ccc(-c2cccc(-n3c4ccc(-c5ccc6oc7ccccc7c6c5)cc4c4cc(-n5c6ccccc6c6cc([Si](c7ccccc7)(c7ccccc7)c7ccccc7)ccc65)ccc43)c2)cc1]

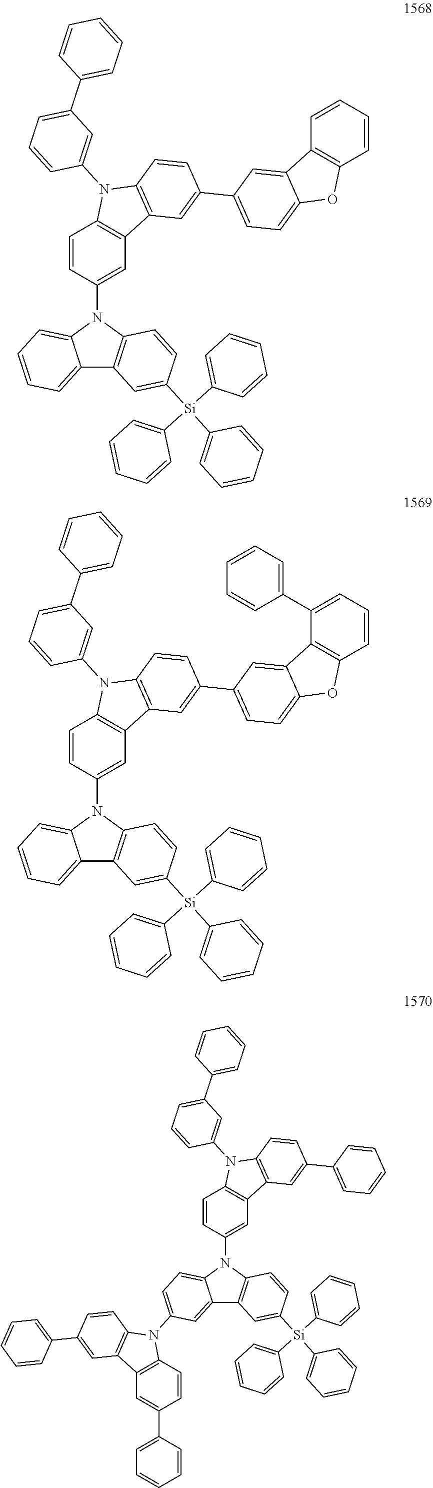

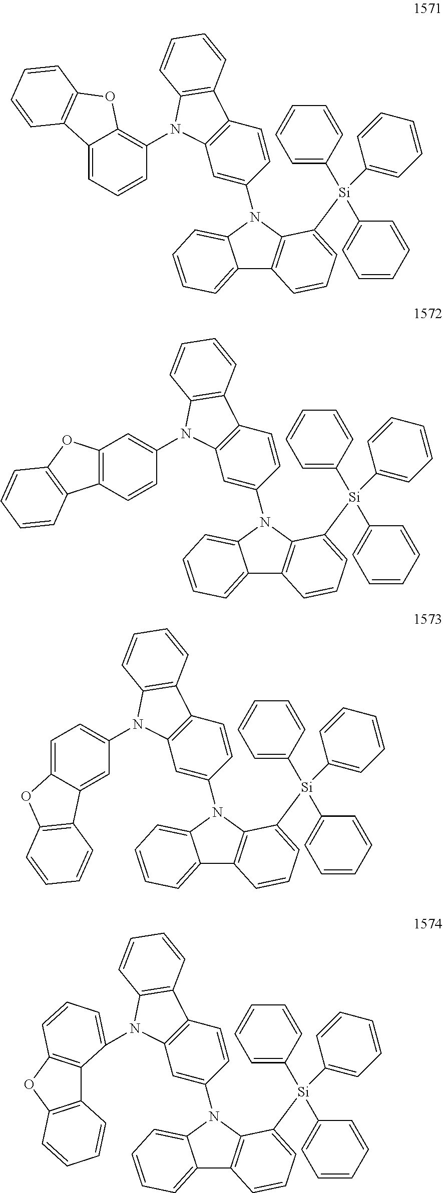

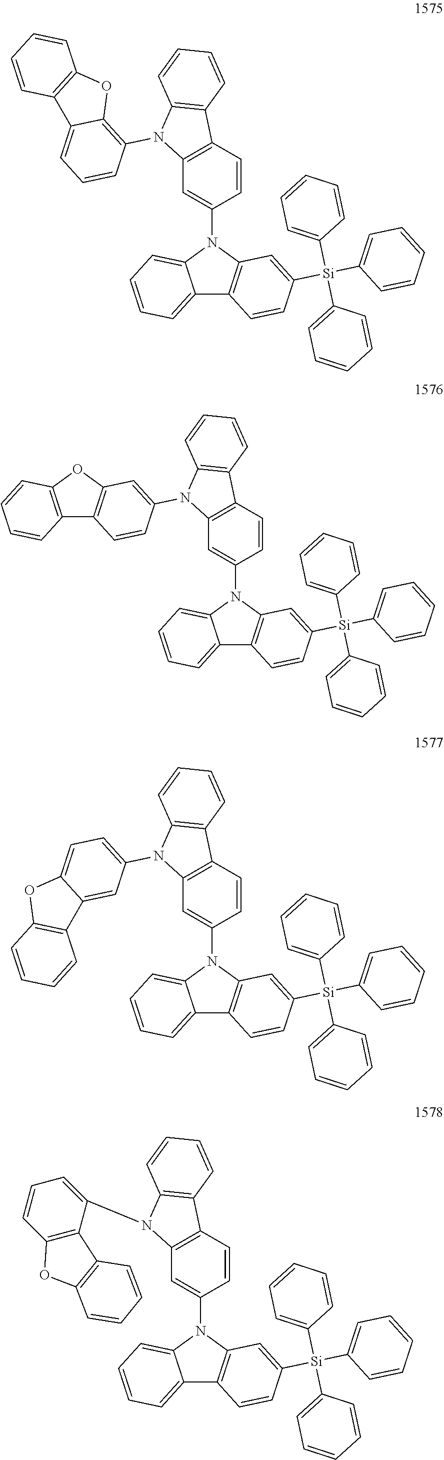 [SMILES: c1ccc([Si](c2ccccc2)(c2ccccc2)c2ccc3c4ccccc4n(-c4ccc5c6ccccc6n(-c6cccc7c6oc6ccccc67)c5c4)c3c2)cc1 ; c1ccc([Si](c2ccccc2)(c2ccccc2)c2ccc3c4ccccc4n(-c4ccc5c6ccccc6n(-c6ccc7c(c6)oc6ccccc67)c5c4)c3c2)cc1 ; c1ccc([Si](c2ccccc2)(c2ccccc2)c2ccc3c4ccccc4n(-c4ccc5c6ccccc6n(-c6ccc7oc8ccccc8c7c6)c5c4)c3c2)cc1 ; c1ccc([Si](c2ccccc2)(c2ccccc2)c2ccc3c4ccccc4n(-c4ccc5c6ccccc6n(-c6cccc7oc8ccccc8c67)c5c4)c3c2)cc1]

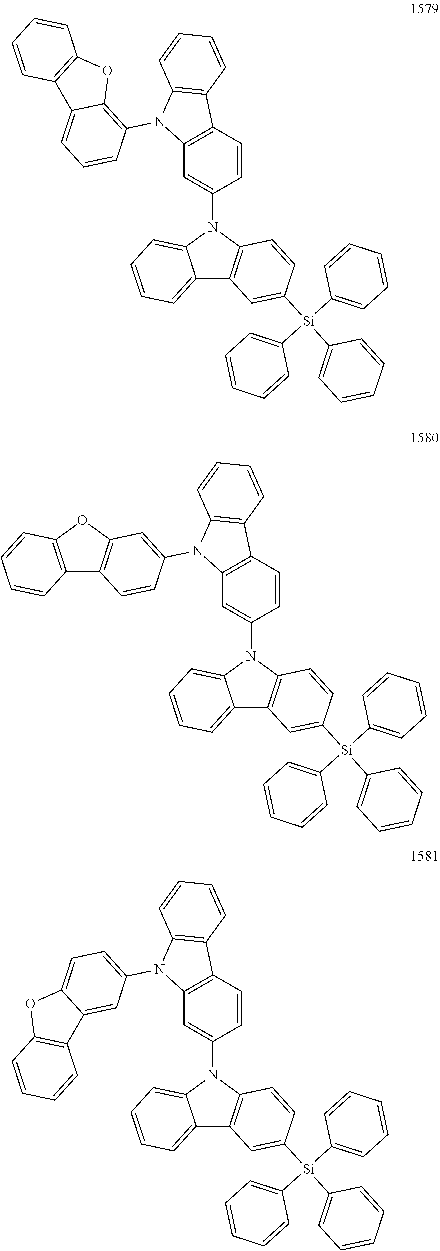 [SMILES: c1ccc([Si](c2ccccc2)(c2ccccc2)c2ccc3c(c2)c2ccccc2n3-c2ccc3c4ccccc4n(-c4cccc5c4oc4ccccc45)c3c2)cc1 ; c1ccc([Si](c2ccccc2)(c2ccccc2)c2ccc3c(c2)c2ccccc2n3-c2ccc3c4ccccc4n(-c4ccc5c(c4)oc4ccccc45)c3c2)cc1 ; c1ccc([Si](c2ccccc2)(c2ccccc2)c2ccc3c(c2)c2ccccc2n3-c2ccc3c4ccccc4n(-c4ccc5oc6ccccc6c5c4)c3c2)cc1]

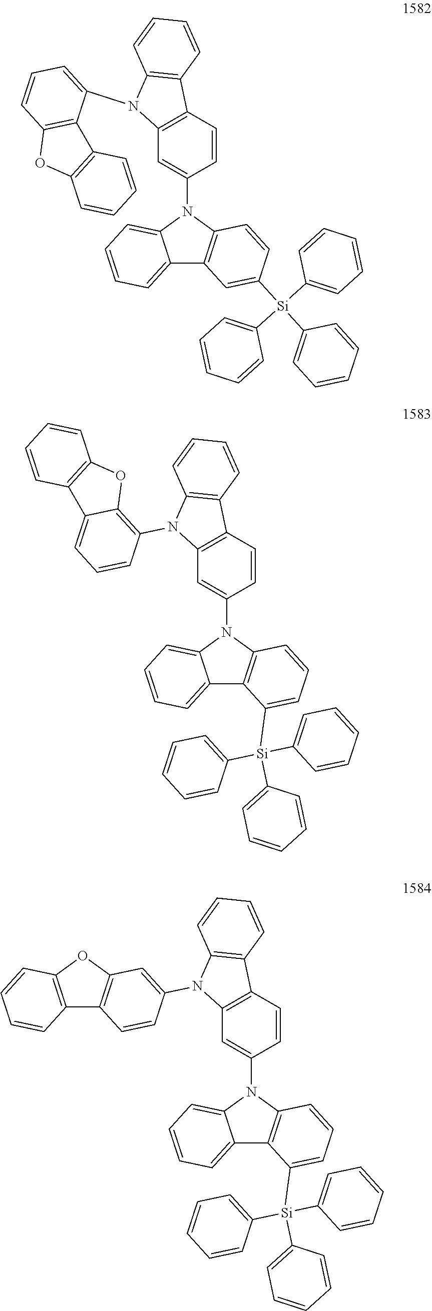 [SMILES: c1ccc([Si](c2ccccc2)(c2ccccc2)c2ccc3c(c2)c2ccccc2n3-c2ccc3c4ccccc4n(-c4cccc5oc6ccccc6c45)c3c2)cc1 ; c1ccc([Si](c2ccccc2)(c2ccccc2)c2cccc3c2c2ccccc2n3-c2ccc3c4ccccc4n(-c4cccc5c4oc4ccccc45)c3c2)cc1 ; c1ccc([Si](c2ccccc2)(c2ccccc2)c2cccc3c2c2ccccc2n3-c2ccc3c4ccccc4n(-c4ccc5c(c4)oc4ccccc45)c3c2)cc1]

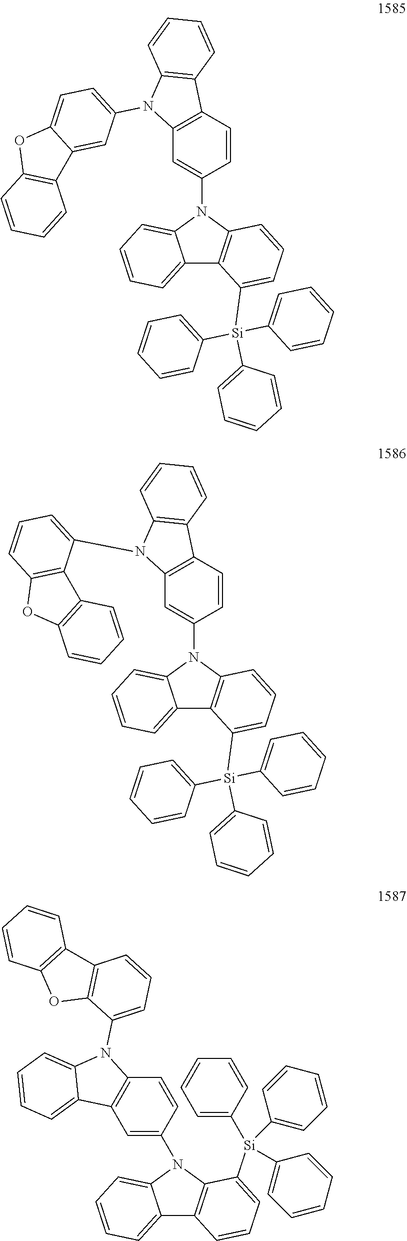 [SMILES: c1ccc([Si](c2ccccc2)(c2ccccc2)c2cccc3c2c2ccccc2n3-c2ccc3c4ccccc4n(-c4ccc5oc6ccccc6c5c4)c3c2)cc1 ; c1ccc([Si](c2ccccc2)(c2ccccc2)c2cccc3c2c2ccccc2n3-c2ccc3c4ccccc4n(-c4cccc5oc6ccccc6c45)c3c2)cc1 ; c1ccc([Si](c2ccccc2)(c2ccccc2)c2cccc3c4ccccc4n(-c4ccc5c(c4)c4ccccc4n5-c4cccc5c4oc4ccccc45)c23)cc1]

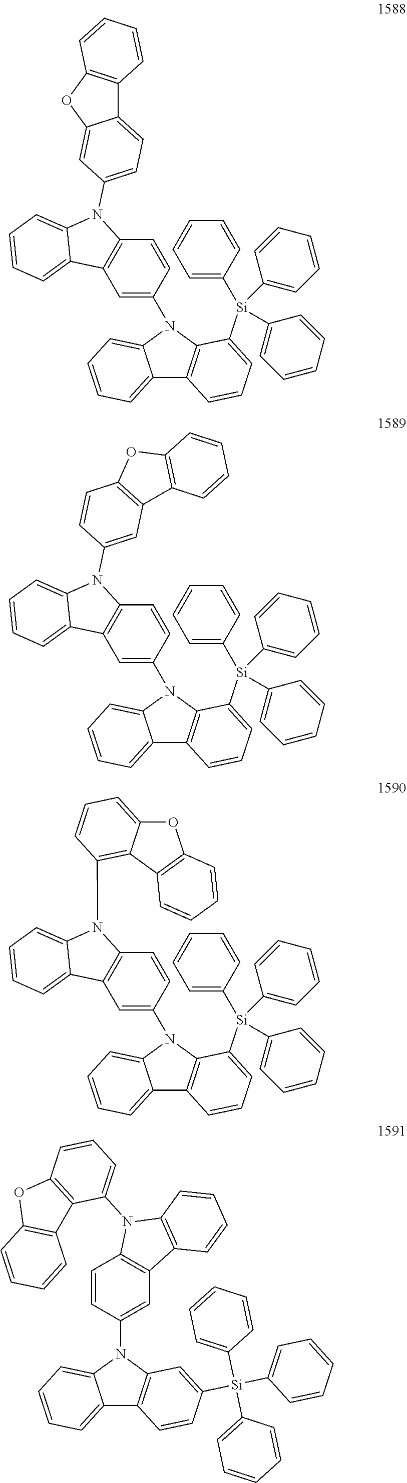

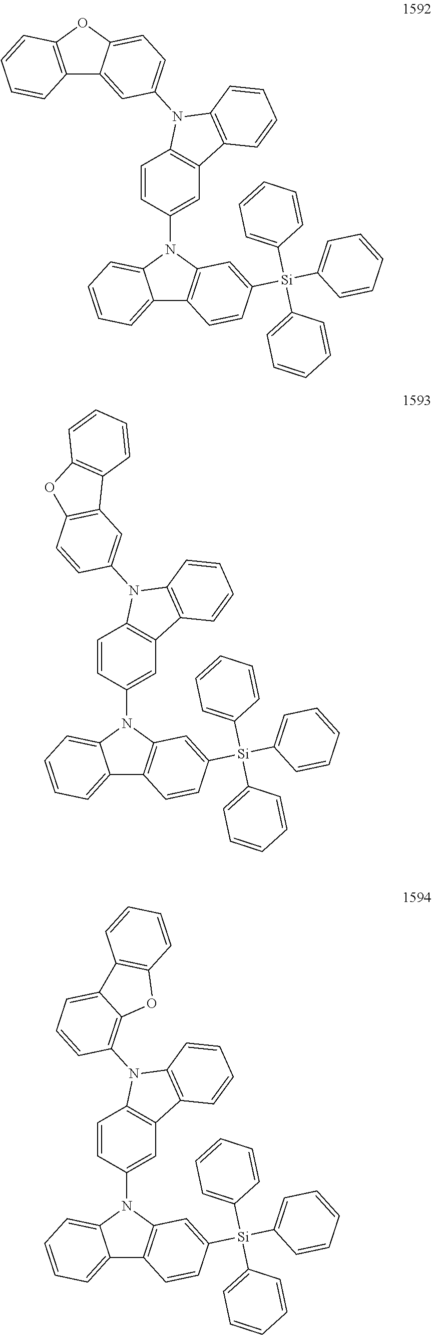 [SMILES: c1ccc([Si](c2ccccc2)(c2ccccc2)c2ccc3c4ccccc4n(-c4ccc5c(c4)c4ccccc4n5-c4ccc5oc6ccccc6c5c4)c3c2)cc1 ; c1ccc([Si](c2ccccc2)(c2ccccc2)c2ccc3c4ccccc4n(-c4ccc5c(c4)c4ccccc4n5-c4ccc5oc6ccccc6c5c4)c3c2)cc1 ; c1ccc([Si](c2ccccc2)(c2ccccc2)c2ccc3c4ccccc4n(-c4ccc5c(c4)c4ccccc4n5-c4cccc5c4oc4ccccc45)c3c2)cc1]

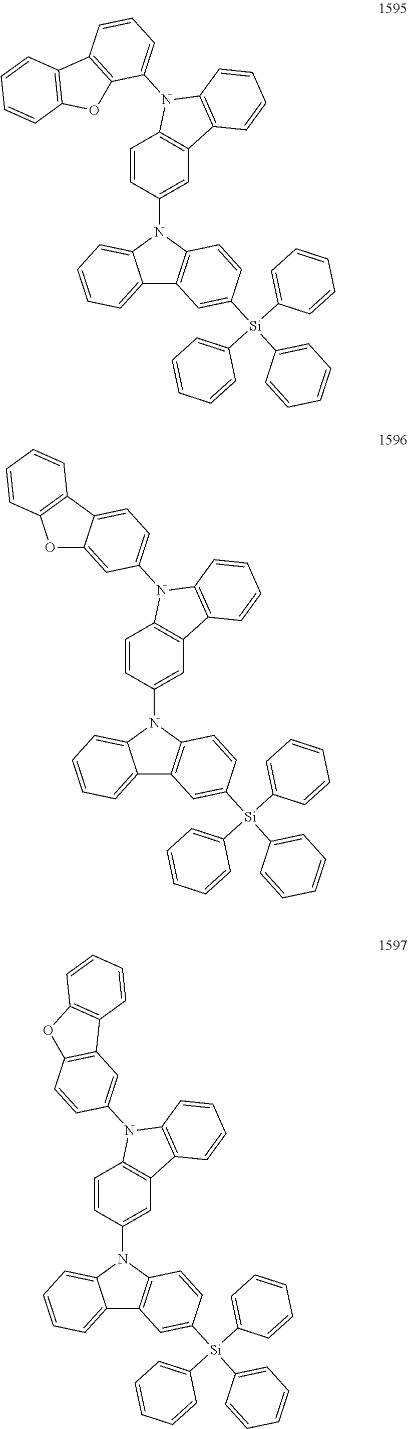 [SMILES: c1ccc([Si](c2ccccc2)(c2ccccc2)c2ccc3c(c2)c2ccccc2n3-c2ccc3c(c2)c2ccccc2n3-c2cccc3c2oc2ccccc23)cc1 ; c1ccc([Si](c2ccccc2)(c2ccccc2)c2ccc3c(c2)c2ccccc2n3-c2ccc3c(c2)c2ccccc2n3-c2ccc3c(c2)oc2ccccc23)cc1 ; c1ccc([Si](c2ccccc2)(c2ccccc2)c2ccc3c(c2)c2ccccc2n3-c2ccc3c(c2)c2ccccc2n3-c2ccc3oc4ccccc4c3c2)cc1]

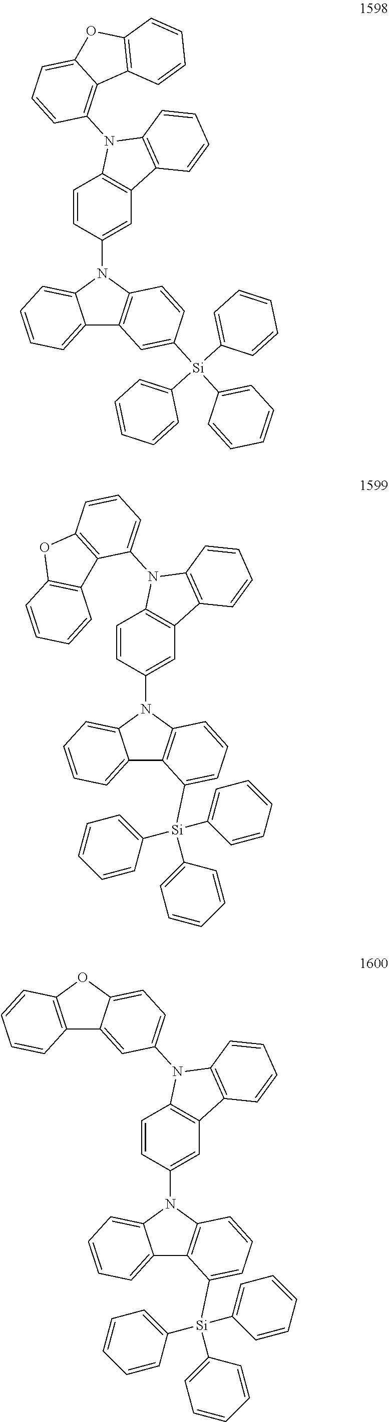 [SMILES: c1ccc([Si](c2ccccc2)(c2ccccc2)c2ccc3c(c2)c2ccccc2n3-c2ccc3c(c2)c2ccccc2n3-c2cccc3oc4ccccc4c23)cc1 ; c1ccc([Si](c2ccccc2)(c2ccccc2)c2cccc3c2c2ccccc2n3-c2ccc3c(c2)c2ccccc2n3-c2cccc3oc4ccccc4c23)cc1 ; c1ccc([Si](c2ccccc2)(c2ccccc2)c2cccc3c2c2ccccc2n3-c2ccc3c(c2)c2ccccc2n3-c2ccc3oc4ccccc4c3c2)cc1]

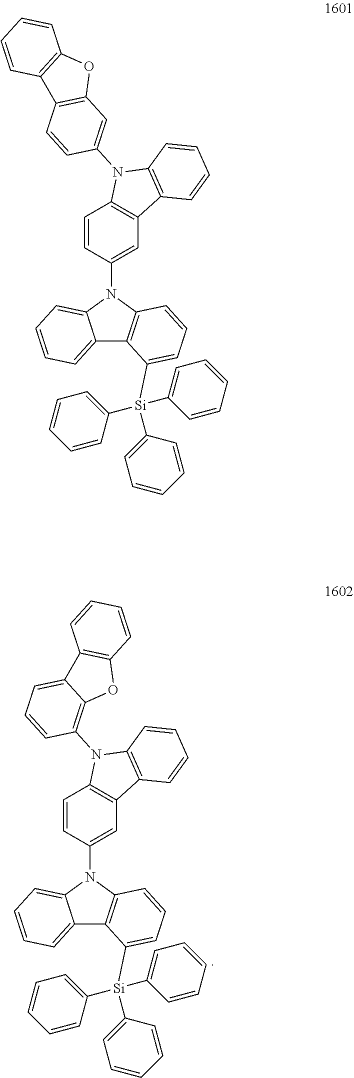 [SMILES: c1ccc([Si](c2ccccc2)(c2ccccc2)c2cccc3c2c2ccccc2n3-c2ccc3c(c2)c2ccccc2n3-c2ccc3c(c2)oc2ccccc23)cc1 ; c1ccc([Si](c2ccccc2)(c2ccccc2)c2cccc3c2c2ccccc2n3-c2ccc3c(c2)c2ccccc2n3-c2cccc3c2oc2ccccc23)cc1]

In one or more embodiments, the condensed cyclic compound represented by Formula 1 may be a deuterium-substituted compound of a compound of Group I, but embodiments are not limited thereto. In detail, in the deuterium-substituted compound of a compound of Group I, 10% or more, 20% or more, 30% or more, 99% or less, 95% or less, or 90% or less of hydrogen in the compound of Group I may be substituted with deuterium.

Since the condensed cyclic compound represented by Formula 1 essentially includes X₁ in a biscarbazole structure, the condensed cyclic compound may have a highest occupied molecular orbital (HOMO) energy level that is suitable for use in an electronic device, for example, an organic light-emitting device (as another example, an organic light-emitting device that emits blue light), and thus, an organic light-emitting device including the condensed cyclic compound may exhibit improved driving characteristics. In addition, the condensed cyclic compound may have improved light stability and thermal stability through a relatively high lowest excited triplet (T₁) energy level and a relatively low lowest excited singlet (S₁) energy level. Accordingly, an electronic device, for example, an organic light-emitting device (as another example, an organic light-emitting device that emits blue light), including the condensed cyclic compound represented by Formula 1 may have high luminescence efficiency and/or long lifespan.

In detail, the condensed cyclic compound represented by Formula 1 may have a triplet energy level of about 2.85 eV or more, or in a range of about 2.85 eV to about 3.5 eV.

In detail, the condensed cyclic compound represented by Formula 1 may have a HOMO energy level of about −5.30 eV or more, or in a range of about −5.10 eV to about −5.30 eV.

The triplet energy level and the HOMO energy level may be evaluated by the density functional theory (DFT).

For example, the HOMO energy level, lowest unoccupied molecular orbital (LUMO) energy level, T₁ energy level, and S₁ energy level of some compounds of the condensed cyclic compound represented by Formula 1 were evaluated using the DFT method of the Gaussian program (structurally optimized at the level of B3LYP, 6-31G(d,p)). Results thereof are shown in Table 1.

TABLE 1

| Compound No. | HOMO (eV) | LUMO (eV) | S₁ (eV) | T₁ (eV) | ΔE_{ST} (eV) |
|---|---|---|---|---|---|
| 11 | −5.188 | −0.982 | 3.644 | 3.153 | 0.491 |
| 43 | −5.177 | −1.095 | 3.637 | 3.156 | 0.481 |
| 1129 | −5.195 | −1.228 | 3.604 | 3.147 | 0.458 |
| A | −5.142 | −0.928 | 3.810 | 3.296 | 0.514 |
| B | −5.290 | −0.888 | 3.854 | 3.300 | 0.554 |
| C | −5.231 | −1.033 | 3.812 | 3.309 | 0.503 |

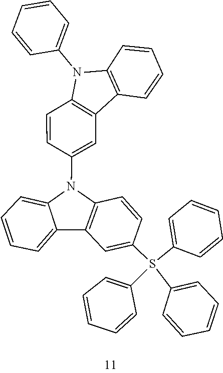 [SMILES: c1ccc(-n2c3ccccc3c3cc(-n4c5ccccc5c5cc(S(c6ccccc6)(c6ccccc6)c6ccccc6)ccc54)ccc32)cc1]

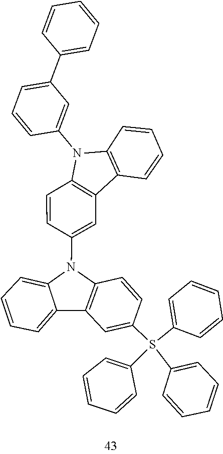 [SMILES: c1ccc(-c2cccc(-n3c4ccccc4c4cc(-n5c6ccccc6c6cc(S(c7ccccc7)(c7ccccc7)c7ccccc7)ccc65)ccc43)c2)cc1]

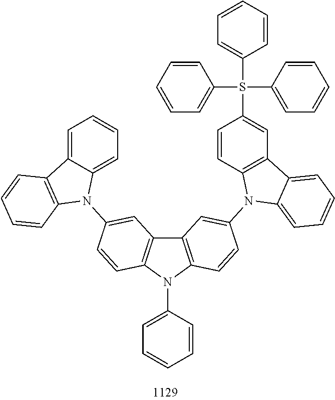 [SMILES: c1ccc(-n2c3ccc(-n4c5ccccc5c5ccccc54)cc3c3cc(-n4c5ccccc5c5cc(S(c6ccccc6)(c6ccccc6)c6ccccc6)ccc54)ccc32)cc1]

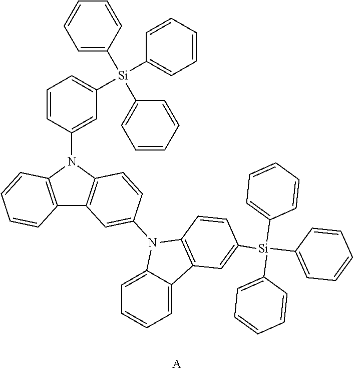

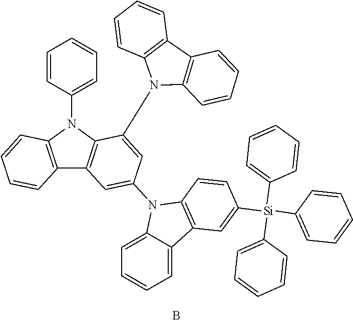

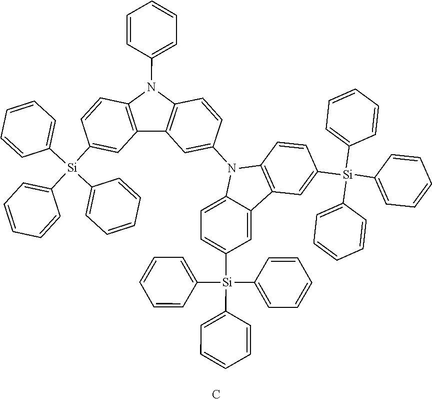

From Table 1, it can be seen that the compounds represented by Formula 1 each have a relatively high T₁ energy level and a relatively low S₁ energy level. From these results, it can be seen that an electronic device, for example, an organic light-emitting device, including the condensed cyclic compound represented by Formula 1 may have high luminescence efficiency.

Synthesis methods of the condensed cyclic compound represented by Formula 1 may be recognizable by one of ordinary skill in the art by referring to Synthesis Examples provided below.

### [Composition]

Another aspect of the disclosure provides a composition including the condensed cyclic compound represented by Formula 1 as described herein (a first compound) and a bipolar host or an electron transporting host (a second compound).

The electron transporting host may include at least one electron transporting moiety, and the bipolar host may include at least one electron transporting moiety and at least one hole transporting moiety.

The electron transporting moiety as used herein may be a cyano group, —F, —CFH₂, —CF₂H, —CF₃, a π electron-deficient nitrogen-containing C₁-C₆₀ cyclic group, or a group represented by an ET-moiety:

ET-Moieties

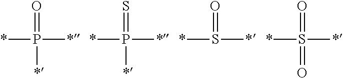

wherein, in the ET-moieties, *, *′, *″, and *′″ may each indicate a binding site to a neighboring atom.

The hole transporting moiety as used herein may be a π electron-rich C₃-C₆₀ cyclic group and a group represented by an HT-moiety:

HT-Moiety

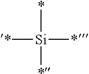

wherein, in the HT-moiety, *, *′, *″, and *′″ may each indicate a binding site to a neighboring atom.

The term “π electron-deficient nitrogen-containing C₁-C₆₀ cyclic group” as used herein refers to a cyclic group having 1 to 60 carbon atoms and including at least one *—N═*′ (wherein * and *′ each indicate a binding site to a neighboring atom) as a ring-forming moiety. For example, the π electron-deficient nitrogen-containing C₁-C₆₀ cyclic group may be a) a first ring, b) a condensed ring in which at least two first rings are condensed, or c) a condensed ring in which at least one first ring and at least one second ring are condensed.

The “first ring” as used herein may be an imidazole group, a pyrazole group, a thiazole group, an isothiazole group, an oxazole group, an isoxazole group, a pyridine group, a pyrazine group, a pyridazine group, a pyrimidine group, a triazole group, a tetrazole group, an oxadiazole group, a triazine group, or a thiadiazole group.

The “second ring” as used herein may be a benzene group, a cyclopentadiene group, a pyrrole group, a furan group, a thiophene group, or a silole group.

For example, the π electron-deficient nitrogen-containing C₁-C₆₀ cyclic group may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinoline group, a phthalazine group, a naphthyridine group, a quinoxaline group, a benzoquinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, an azacarbazole group, an azadibenzofuran group, an azadibenzothiophene group, an azadibenzosilole group, an acridine group, or a pyridopyrazine group.

The term “π electron-rich C₃-C₆₀ cyclic group” as used herein refers to a cyclic group having 3 to 60 carbon atoms and not including at least one *—N═*′ (wherein * and *′ each indicate a binding site to a neighboring atom) as a ring-forming moiety. For example, the π electron-rich C₃-C₆₀ cyclic group may be a) a second ring or b) a condensed ring in which at least two second rings are condensed.

For example, the π electron-rich C₃-C₆₀ cyclic group may be a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, a furan group, a thiophene group, an isoindole group, an indole group, an indene group, a benzofuran group, a benzothiophene group, a benzosilole group, a naphthopyrrole group, a naphthofuran group, a naphthothiophene group, a naphthosilole group, a benzocarbazole group, a dibenzocarbazole group, a dibenzofuran group, a dibenzothiophene group, a carbazole group, a dibenzosilole group, an indenocarbazole group, an indolocarbazole group, a benzofurocarbazole group, a benzothienocarbazole group, a benzosilolocarbazole group, a triindolobenzene group, a pyrrolophenanthrene group, a furanophenanthrene group, a thienophenanthrene group, a benzonaphthofuran group, a benzonaphthothiophene group, an (indolo)phenanthrene group, a (benzofurano)phenanthrene group, or a (benzothieno)phenanthrene group.

The composition may be used in the manufacture of an organic layer of, for example, an electronic device (for example, an organic light-emitting device).

The condensed cyclic compound represented by Formula 1 in the composition may be a hole transporting host.

In an embodiment, the composition may consist of the first compound and the second compound, but embodiments are not limited thereto.

A weight ratio of the first compound to the second compound in the composition may be in a range of about 1:99 to about 99:1, for example, about 70:30 to about 30:70. For example, the weight ratio of the first compound to the second compound in the composition may be about 40:60 to about 60:40, but embodiments are not limited thereto. When the weight ratio of the first compound to the second compound in the composition satisfies the ranges described above, the composition may provide an excellent charge transport balance.

### [Organic Light-Emitting Device]

Another aspect of the disclosure provides an organic light-emitting device including: a first electrode; a second electrode; and an organic layer arranged between the first electrode and the second electrode and including an emission layer, wherein the organic layer includes the condensed cyclic compound represented by Formula 1.

The term “organic layer” as used herein refers to a single layer and/or a plurality of layers arranged between the first electrode and the second electrode of the organic light-emitting device. The “organic layer” may include, in addition to an organic compound, an organometallic complex including metal.

In the organic light-emitting device,
the first electrode may be an anode, and the second electrode may be a cathode,
the organic layer may include a hole transport region arranged between the first electrode and the emission layer and an electron transport region arranged between the emission layer and the second electrode,
the hole transport region may include a hole injection layer, a hole transport layer, an electron blocking layer, a buffer layer, or any combination thereof, and
the electron transport region may include a hole blocking layer, an electron transport layer, an electron injection layer, or any combination thereof, but embodiments are not limited thereto.

In an embodiment, the emission layer in the organic light-emitting device may include a host and a dopant, the host and the dopant may be different from each other, an amount of the host may be greater than an amount of the dopant, and the host may include the condensed cyclic compound. For example, the dopant may be a phosphorescent dopant, a fluorescent dopant, and/or a delayed fluorescence dopant. The host may further include, in addition to the condensed cyclic compound represented by Formula 1, any host, for example, an electron transporting host and/or a bipolar host. For example, the emission layer may emit blue light. In detail, the emission layer may be a blue emission layer including a phosphorescent dopant, a fluorescent dopant, and/or a delayed fluorescence dopant, but embodiments are not limited thereto. The host and the dopant may each be the same as described herein.

In one or more embodiments, the emission layer in the organic light-emitting device may include a host, a dopant, and a sensitizer, the host, the dopant, and the sensitizer may be different from each other, an amount of the host may be greater than an amount of the sensitizer, the amount of the sensitizer may be greater than an amount of the dopant, and the host may include the condensed cyclic compound. For example, the dopant may be a fluorescent dopant and/or a delayed fluorescence dopant. The host may further include, in addition to the condensed cyclic compound represented by Formula 1, any host, for example, an electron transporting host and/or a bipolar host. For example, the emission layer may emit blue light. In detail, the emission layer may be a blue emission layer including a fluorescent dopant and/or a delayed fluorescence dopant, but embodiments are not limited thereto. The host, the dopant, and the sensitizer may each be the same as described herein.

### DESCRIPTION OF THE FIGURE

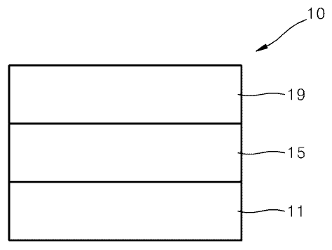

The FIG. 1s a schematic cross-sectional view of an organic light-emitting device 10 according to an exemplary embodiment. Hereinafter, the structure and manufacturing method of the organic light-emitting device 10 according to an embodiment will be described with reference to the FIGURE. The organic light-emitting device 10 has a structure in which a first electrode 11, an organic layer 15, and a second electrode 19 are sequentially stacked.

A substrate may be additionally arranged under the first electrode 11 or above the second electrode 19. For use as the substrate, any substrate that is used in organic light-emitting devices available in the art may be used, and for example, a glass substrate or a transparent plastic substrate, each having excellent mechanical strength, thermal stability, transparency, surface smoothness, ease of handling, and water resistance, may be used.

### [First Electrode 11]

The first electrode 11 may be, for example, formed by depositing or sputtering a material for forming the first electrode 11 on the substrate. The first electrode 11 may be an anode. The material for forming the first electrode 11 may be a material with a high work function to facilitate hole injection. The first electrode 11 may be a reflective electrode, a semi-transmissive electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be a metal, such as magnesium (Mg), aluminum (Al), aluminum-lithium (Al—Li), calcium (Ca), magnesium-indium (Mg—In), or magnesium-silver (Mg—Ag).

The first electrode 11 may have a single-layered structure or a multi-layered structure including a plurality of layers. For example, the first electrode 11 may have a three-layered structure of ITO/Ag/ITO, but embodiments are not limited thereto.

### [Organic Layer 15]

The organic layer 15 is arranged on the first electrode 11.

The organic layer 15 may include a hole transport region, an emission layer, and an electron transport region.

The hole transport region may be arranged between the first electrode 11 and the emission layer.

The hole transport region may include at least one of a hole injection layer, a hole transport layer, an electron blocking layer, a buffer layer, or any combination thereof.

The hole transport region may include only a hole injection layer or only a hole transport layer. In one or more embodiments, the hole transport region may have a hole injection layer/hole transport layer structure or a hole injection layer/hole transport layer/electron blocking layer structure, wherein, for each structure, respective layers are sequentially stacked in this stated order from the first electrode 11.

When the hole transport region includes a hole injection layer, the hole injection layer may be formed on the first electrode 11 by using various methods, for example, vacuum deposition, spin coating, casting, Langmuir-Blodgett (LB) deposition, and the like.

When the hole injection layer is formed by vacuum deposition, the deposition conditions may vary according to a material that is used to form the hole injection layer, and the structure and thermal characteristics of the hole injection layer. For example, the deposition conditions may include a deposition temperature in a range of about 100° C. to about 500° C., a vacuum pressure in a range of about 10⁻⁸ torr to about 10⁻³ torr, and a deposition rate in a range of about 0.01 Å/sec to about 100 Å/sec, but embodiments are not limited thereto.

When the hole injection layer is formed by spin coating, the coating conditions may vary according to a material that is used to form the hole injection layer, and the structure and thermal characteristics of the hole injection layer. For example, the coating conditions may include a coating speed in a range of about 2,000 rpm to about 5,000 rpm and a heat treatment temperature for removing a solvent after coating in a range of about 80° C. to about 200° C., but embodiments are not limited thereto.

The conditions for forming the hole transport layer and the electron blocking layer may be the same as the conditions for forming the hole injection layer.

The hole transport region may include at least one of m-MTDATA, TDATA, 2-TNATA, NPB, β—NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201, a compound represented by Formula 202, or any combination thereof:

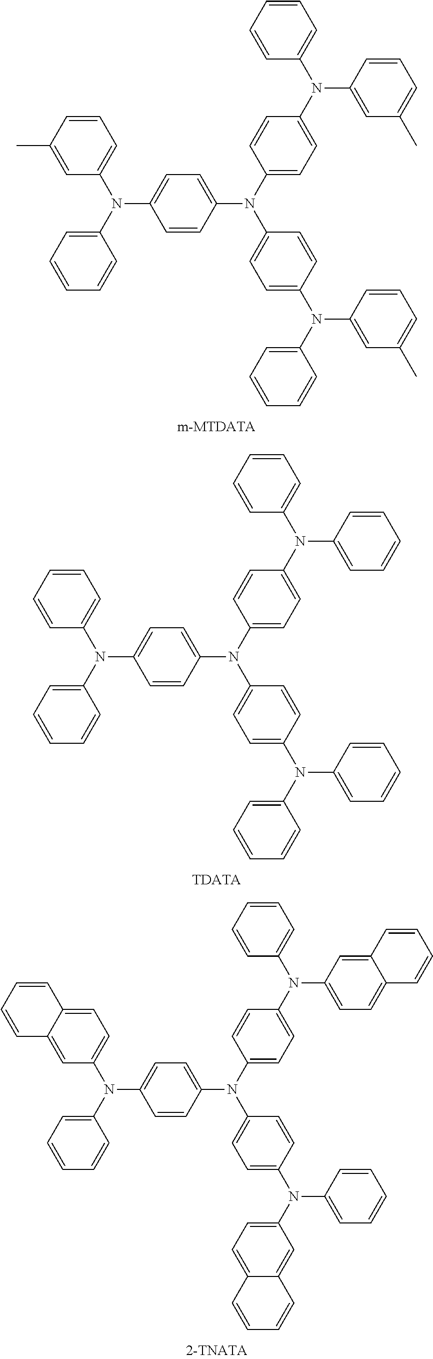

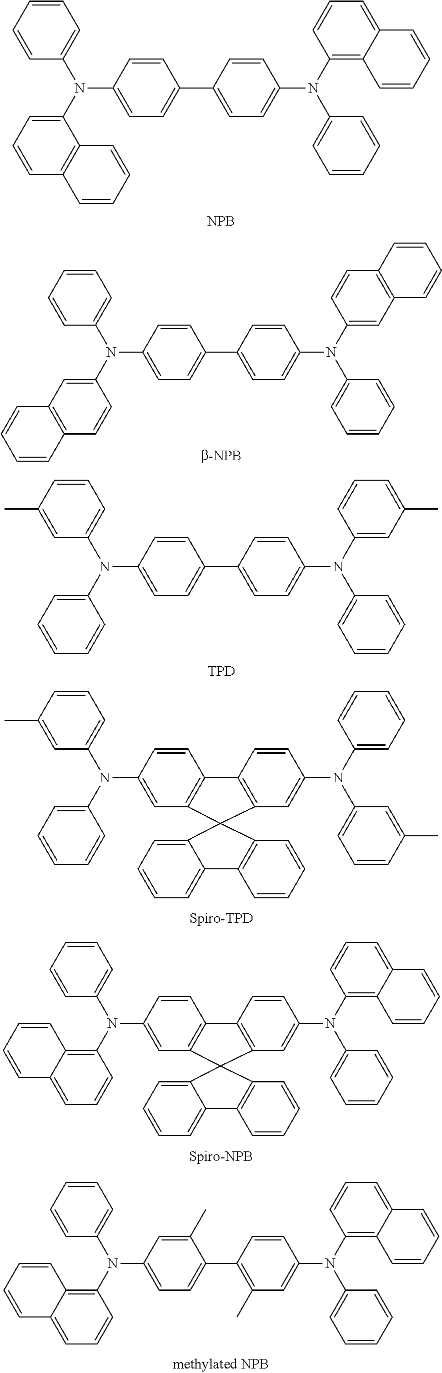

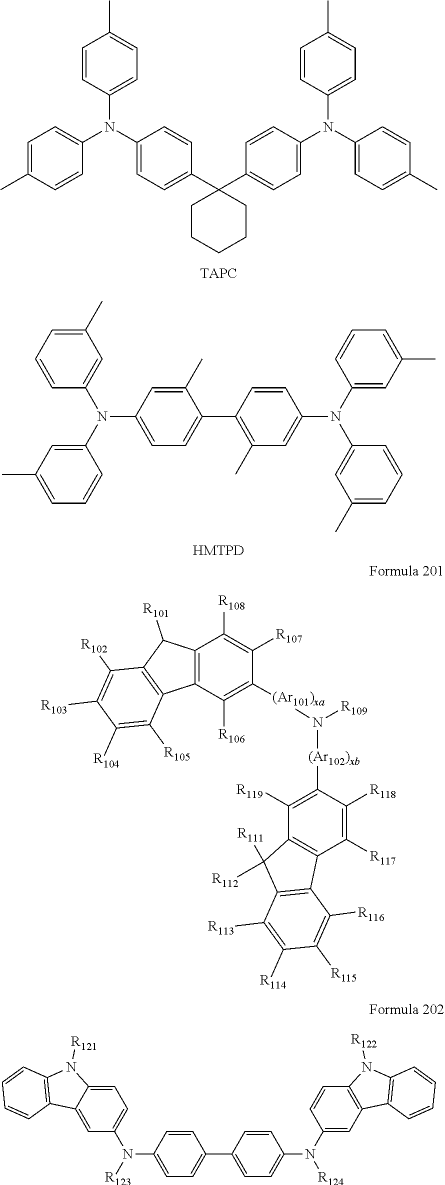

wherein, in Formula 201, Ar₁₀₁ and Ar₁₀₂ may each independently be:
a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, or a pentacenylene group; or
a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, or a pentacenylene group, each substituted with at least one deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, or any combination thereof.

In Formula 201, xa and xb may each independently be an integer from 0 to 5, or may each independently be 0, 1, or 2. For example, xa may be 1 and xb may be 0, but embodiments are not limited thereto.

In Formulae 201 and 202, R₁₀₁ to R₁₀₈, R₁₁₁ to R₁₁₉, and R₁₂₁ to R₁₂₄ may each independently be:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, pentyl group, a hexyl group, etc.), or a C₁-C₁₀ alkoxy group (for example, a methoxy group, an ethoxy group, a propoxy group, a butoxy group, a pentoxy group, etc.);
a C₁-C₁₀ alkyl group or a C₁-C₁₀ alkoxy group, each substituted with at least one deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or a combination thereof;
a phenyl group, a naphthyl group, an anthracenyl group, a fluorenyl group, or a pyrenyl group; or
a phenyl group, a naphthyl group, an anthracenyl group, a fluorenyl group, or a pyrenyl group, each substituted with at least one deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, or any combination thereof, but embodiments are not limited thereto.

In Formula 201, R₁₀₉ may be:
a phenyl group, a naphthyl group, an anthracenyl group, or a pyridinyl group; or
a phenyl group, a naphthyl group, an anthracenyl group, or a pyridinyl group, each substituted with at least one deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyridinyl group, or any combination thereof.

In an embodiment, the compound represented by Formula 201 may be represented by Formula 201A, but embodiments are not limited thereto:

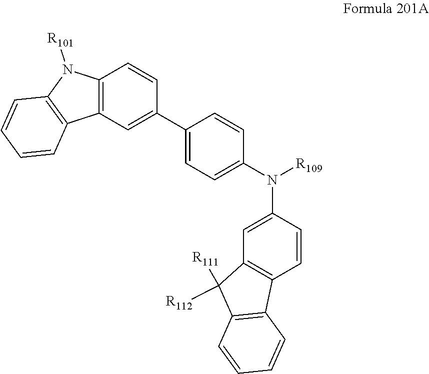

wherein, in Formula 201A, R₁₀₁, R₁₁₁, R₁₁₂, and R₁₀₉ may each be the same as described herein.

For example, the compound represented by Formula 201 and the compound represented by Formula 202 may include Compounds HT1 to HT20, but embodiments are not limited thereto:

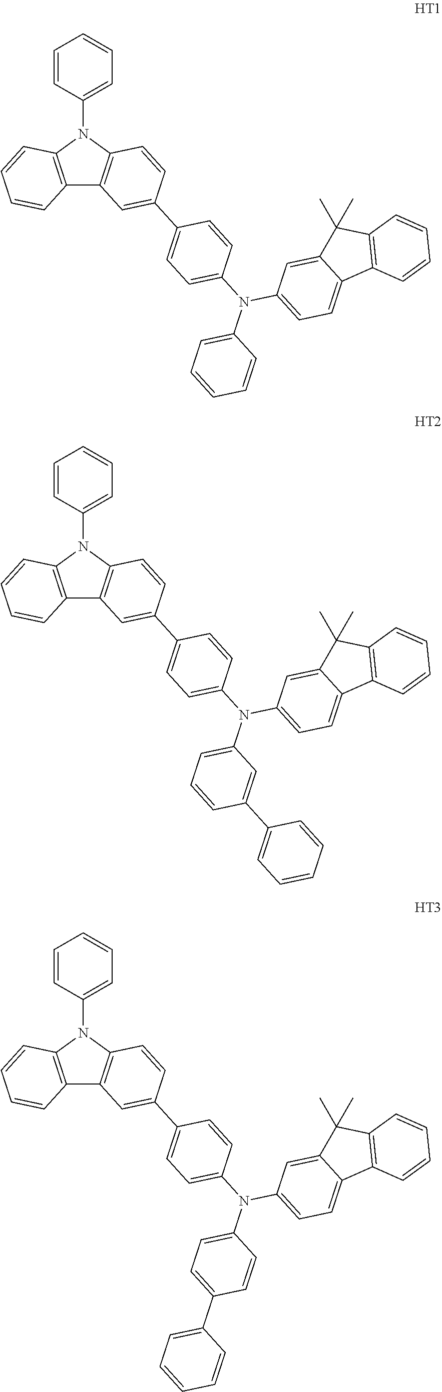 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

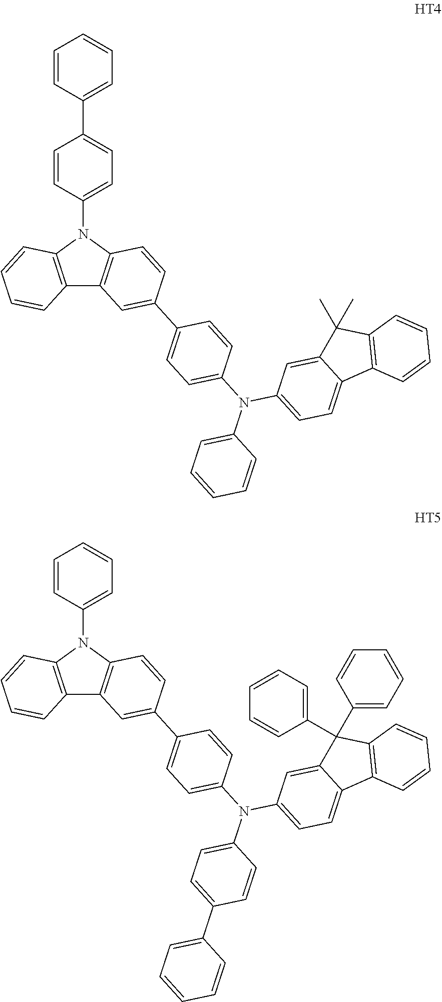 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

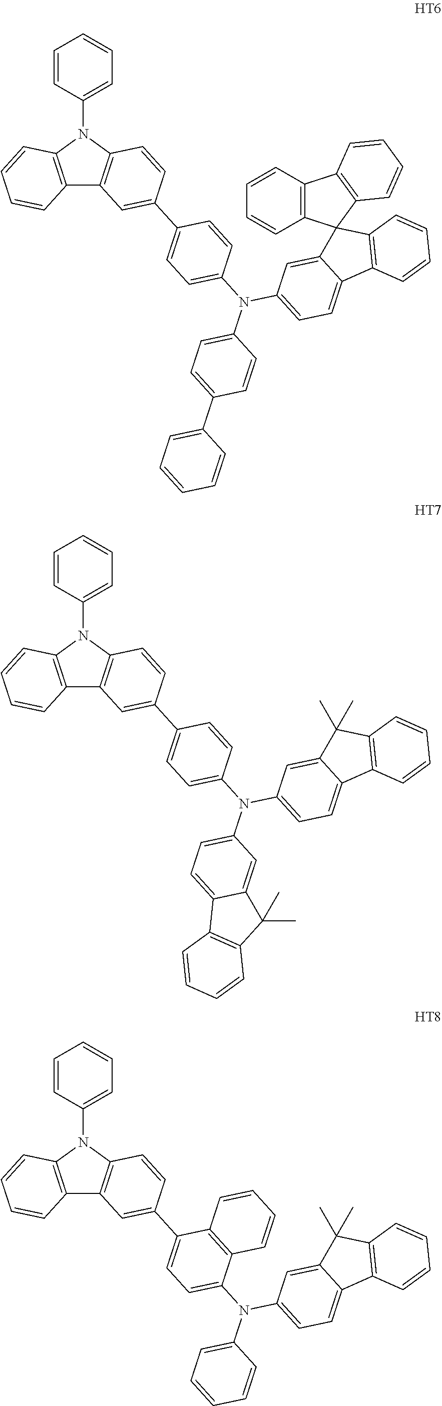 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

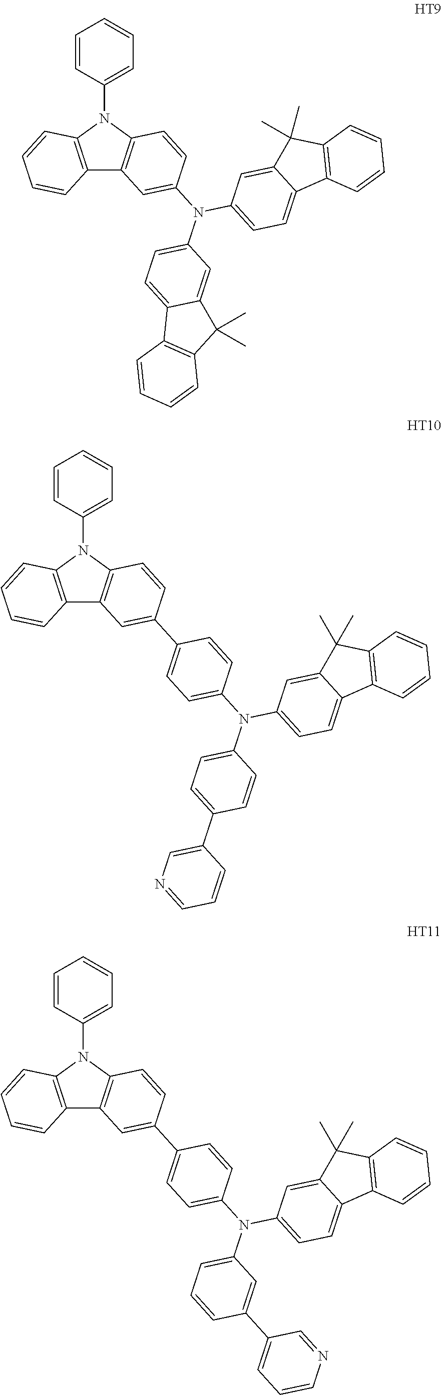 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

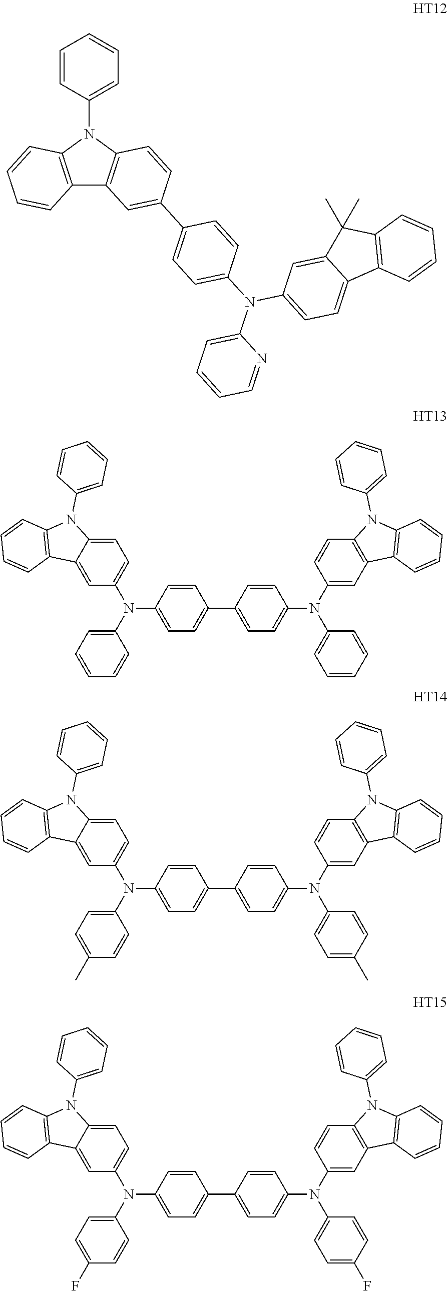 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

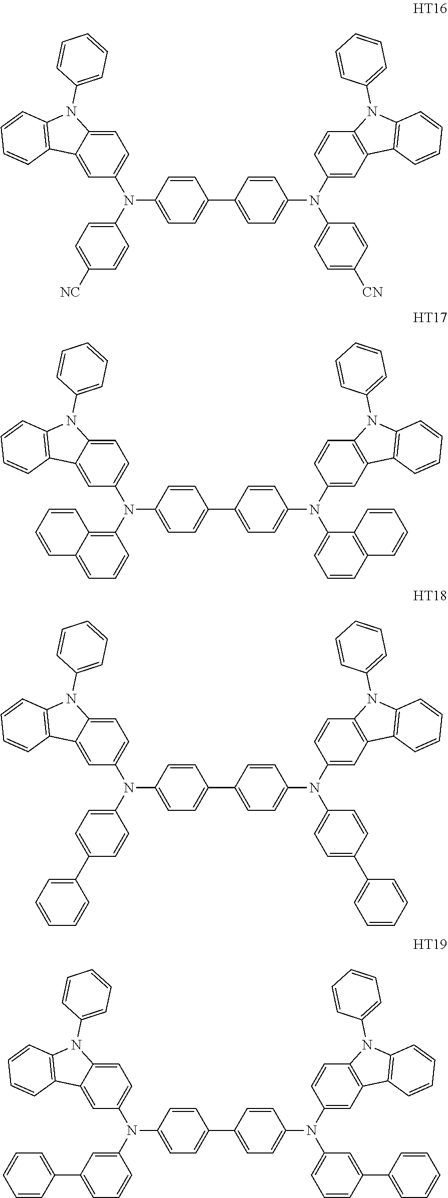 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

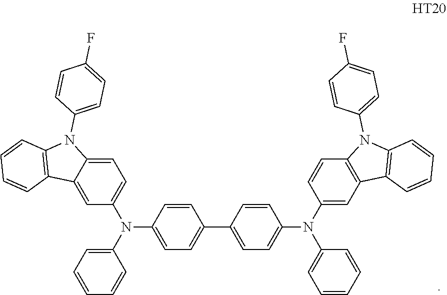 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Å to about 10,000 Å, for example, about 100 Å to about 1,000 Å. When the hole transport region includes both a hole injection layer and a hole transport layer, a thickness of the hole injection layer may be in a range of about 100 Å to about 10,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The hole transport region may further include, in addition to the materials described above, a charge-generation material for improving conductive properties. The charge-generation material may be homogeneously or non-homogeneously dispersed in the hole transport region.

The charge-generation material may be, for example, a p-dopant. The p-dopant may be a quinone derivative, a metal oxide, or a cyano group-containing compound, but embodiments are not limited thereto. Non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide; and a cyano group-containing compound, such as Compound HT-D1 or HP-1, but embodiments are not limited thereto:

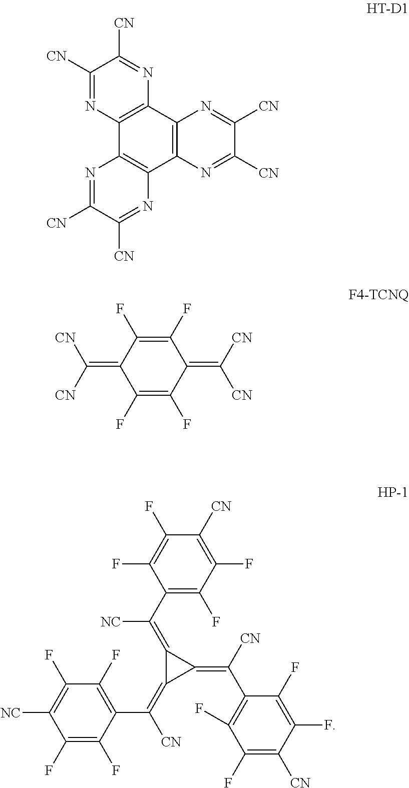

The hole transport region may further include a buffer layer.

The buffer layer may compensate for an optical resonance distance according to a wavelength of light emitted from the emission layer, and thus, the efficiency of a formed organic light-emitting device may be improved.

The hole transport region may further include an electron blocking layer. The electron blocking layer may include a material available in the art, for example, mCP, but embodiments are not limited thereto:

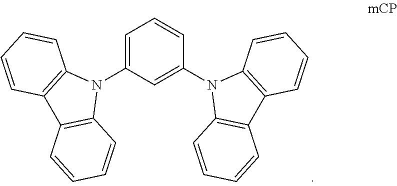 [SMILES: c1cc(-n2c3ccccc3c3ccccc32)cc(-n2c3ccccc3c3ccccc32)c1]

The emission layer may be formed on the hole transport region by vacuum deposition, spin coating, casting, LB deposition, or the like. When the emission layer is formed by vacuum deposition or spin coating, the deposition or coating conditions may be similar to those applied in forming the hole injection layer, though the deposition or coating conditions may vary according to a material that is used.

When the organic light-emitting device 10 is a full-color organic light-emitting device, the emission layer may be patterned into a red emission layer, a green emission layer, and a blue emission layer. In one or more embodiments, due to a stacked structure including a red emission layer, a green emission layer, and/or a blue emission layer, the emission layer may emit white light, and various modifications are possible.

The emission layer may include the condensed cyclic compound represented by Formula 1. As described above, the emission layer may further include a host, a dopant, and/or a sensitizer.

For example, the host may include a fluorene-containing compound, a carbazole-containing compound, a dibenzofuran-containing compound, a dibenzothiophene-containing compound, an indenocarbazole-containing compound, an indolocarbazole-containing compound, a benzofurocarbazole-containing compound, a benzothienocarbazole-containing compound, an acridine-containing compound, a dihydroacridine-containing compound, a triindolobenzene-containing compound, a pyridine-containing compound, a pyrimidine-containing compound, a triazine-containing compound, a silicon-containing compound, a cyano group-containing compound, a phosphine oxide-containing compound, a sulfoxide-containing compound, a sulfonyl-containing compound, or any combination thereof.

For example, the host may be a compound including at least one carbazole ring and at least one cyano group, or may be a phosphine oxide-containing compound.

The host may include, for example, at least one compound CBP, mCBP (Compound H7), and Compounds H1 to H24:

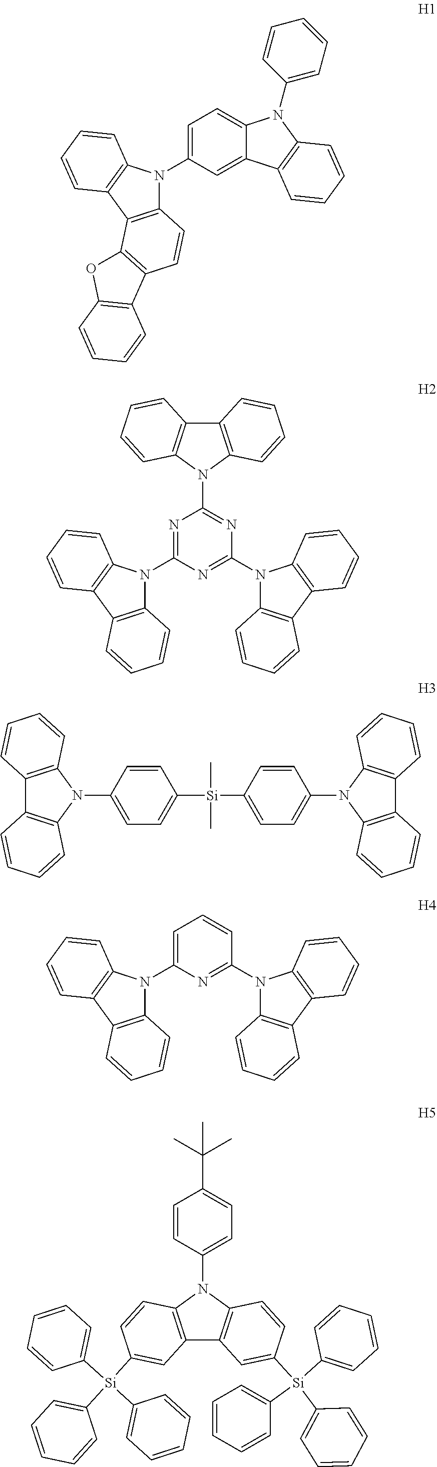

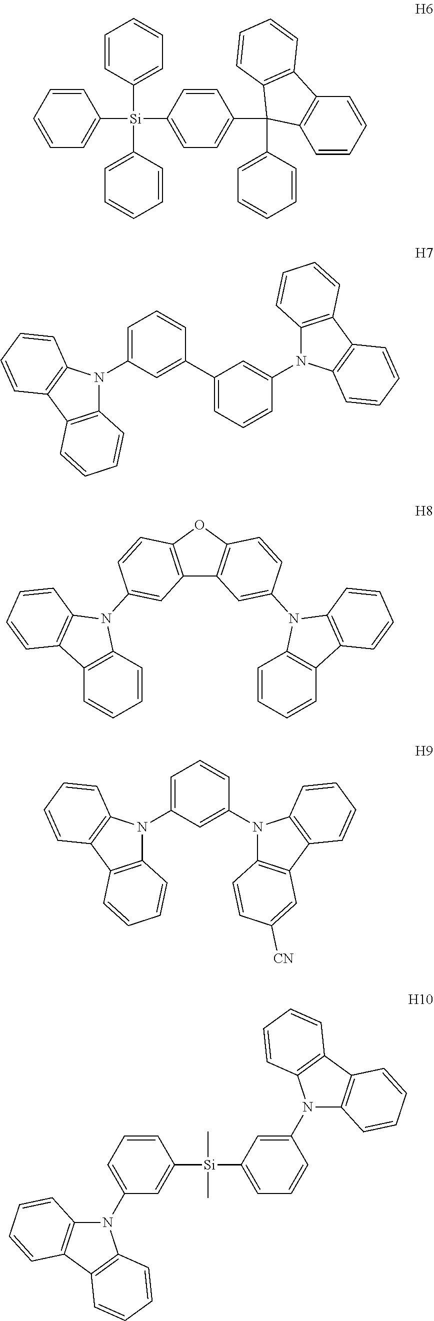 [SMILES: c1ccc(C2(c3ccc([Si](c4ccccc4)(c4ccccc4)c4ccccc4)cc3)c3ccccc3-c3ccccc32)cc1 ; c1cc(-c2cccc(-n3c4ccccc4c4ccccc43)c2)cc(-n2c3ccccc3c3ccccc32)c1 ; c1ccc2c(c1)c1ccccc1n2-c1ccc2oc3ccc(-n4c5ccccc5c5ccccc54)cc3c2c1 ; N#Cc1ccc2c(c1)c1ccccc1n2-c1cccc(-n2c3ccccc3c3ccccc32)c1 ; C[Si](C)(c1cccc(-n2c3ccccc3c3ccccc32)c1)c1cccc(-n2c3ccccc3c3ccccc32)c1]

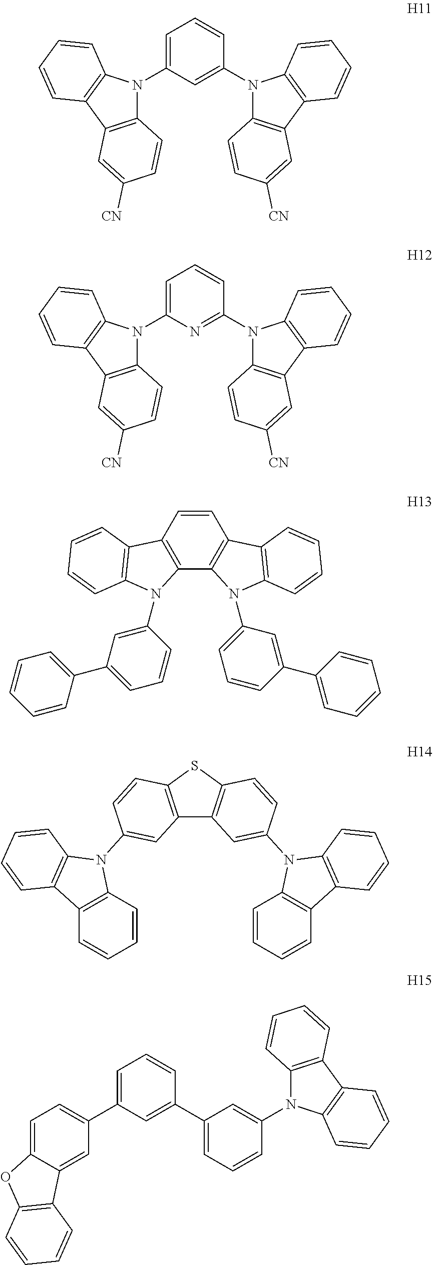

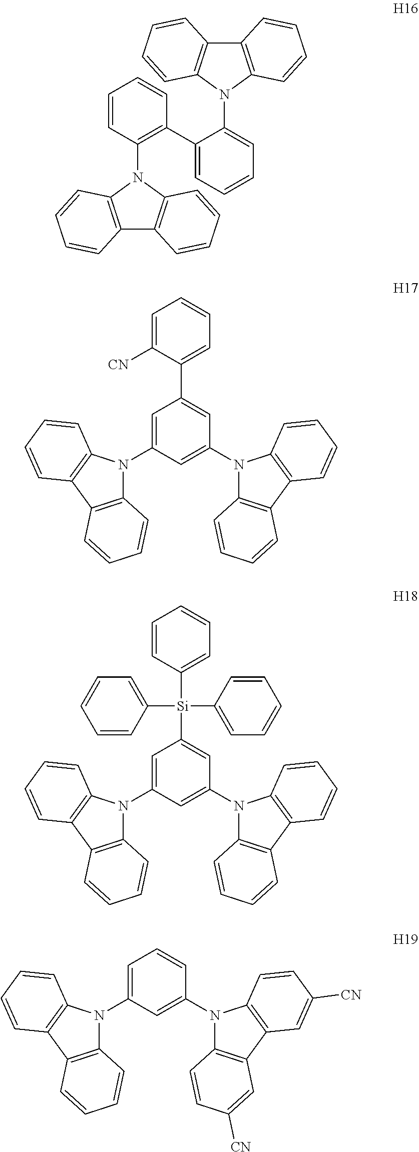

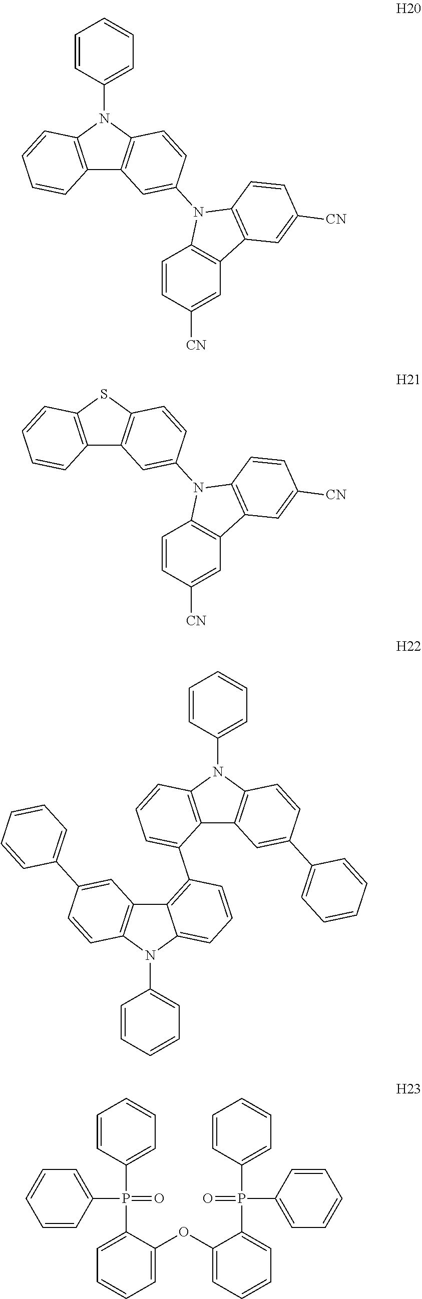 [SMILES: N#Cc1ccc2c(c1)c1cc(C#N)ccc1n2-c1ccc2c(c1)c1ccccc1n2-c1ccccc1 ; N#Cc1ccc2c(c1)c1cc(C#N)ccc1n2-c1ccc2sc3ccccc3c2c1 ; c1ccc(-c2ccc3c(c2)c2c(-c4cccc5c4c4cc(-c6ccccc6)ccc4n5-c4ccccc4)cccc2n3-c2ccccc2)cc1 ; O=P(c1ccccc1)(c1ccccc1)c1ccccc1Oc1ccccc1P(=O)(c1ccccc1)c1ccccc1]

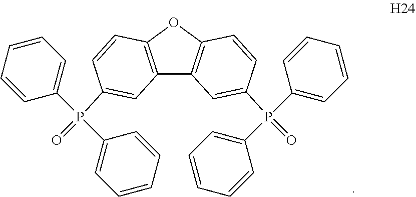 [SMILES: O=P(c1ccccc1)(c1ccccc1)c1ccc2oc3ccc(P(=O)(c4ccccc4)c4ccccc4)cc3c2c1]

For example, the dopant may be a phosphorescent dopant. In an embodiment, the phosphorescent dopant may include a transition metal complex, for example, a platinum complex. In detail, the transition metal complex may include a transition metal and 1 to 4 ligands bonded to the transition metal. In more detail, the ligand may include a carbene moiety.

In one or more embodiments, the dopant may be a fluorescent dopant and/or a delayed fluorescence dopant. In an embodiment, the fluorescent dopant and/or the delayed fluorescence dopant may include a condensed cyclic compound including boron (B). In one or more embodiments, the fluorescent dopant and/or the delayed fluorescence dopant may include an arene core, such as anthracene core or a pyrene core, and a substituted or unsubstituted amino group.

For example, the sensitizer may be a phosphorescent dopant or a delayed fluorescence dopant. The type of the sensitizer is not limited, provided that the sensitizer is a compound capable of promoting reverse intersystem crossing.

When the emission layer includes a host and a dopant, an amount of the dopant may be in a range of about 0.01 parts by weight to about 20 parts by weight based on 100 parts by weight of the emission layer, but embodiments are not limited thereto. When the amount of the dopant is within this range, light emission without quenching may be realized.

A thickness of the emission layer may be in a range of about 100 Å to about 1,000 Å, for example, about 200 Å to about 600 Å. When the thickness of the emission layer is within this range, excellent light-emission characteristics may be obtained without a substantial increase in driving voltage.

Next, the electron transport region is arranged on the emission layer.

The electron transport region may include at least one of a hole blocking layer, an electron transport layer, an electron injection layer, or any combination thereof.

For example, the electron transport region may have a hole blocking layer/electron transport layer/electron injection layer structure or an electron transport layer/electron injection layer structure, but embodiments are not limited thereto. The electron transport layer may have a single-layered structure or a multi-layered structure including two or more different materials.

Conditions for forming the hole blocking layer, the electron transport layer, and the electron injection layer which constitute the electron transport region may be the same as the conditions for forming the hole injection layer.

When the electron transport region includes a hole blocking layer, the hole blocking layer may include, for example, BCP, Bphen, BAlq, or any combination thereof:

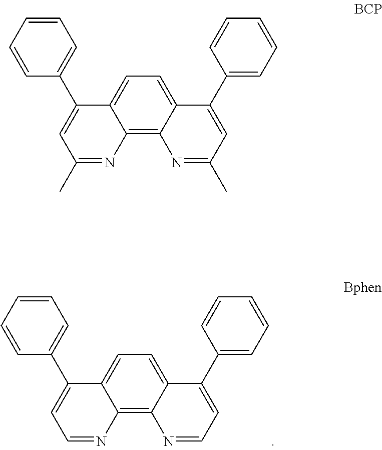 [SMILES: Cc1cc(-c2ccccc2)c2ccc3c(-c4ccccc4)cc(C)nc3c2n1 ; c1ccc(-c2ccnc3c2ccc2c(-c4ccccc4)ccnc23)cc1]

In one or more embodiments, the hole blocking layer may include a host compound described above. For example, the hole blocking layer may include Compound H19, but embodiments are not limited thereto.

A thickness of the hole blocking layer may be in a range of about 20 Å to about 1,000 Å, for example, about 30 Å to about 300 Å. When the thickness of the hole blocking layer is within this range, excellent hole blocking characteristics may be obtained without a substantial increase in driving voltage.

The electron transport layer may include BCP, Bphen, TPBi, Alq₃, BaIq, TAZ, NTAZ, or any combination thereof:

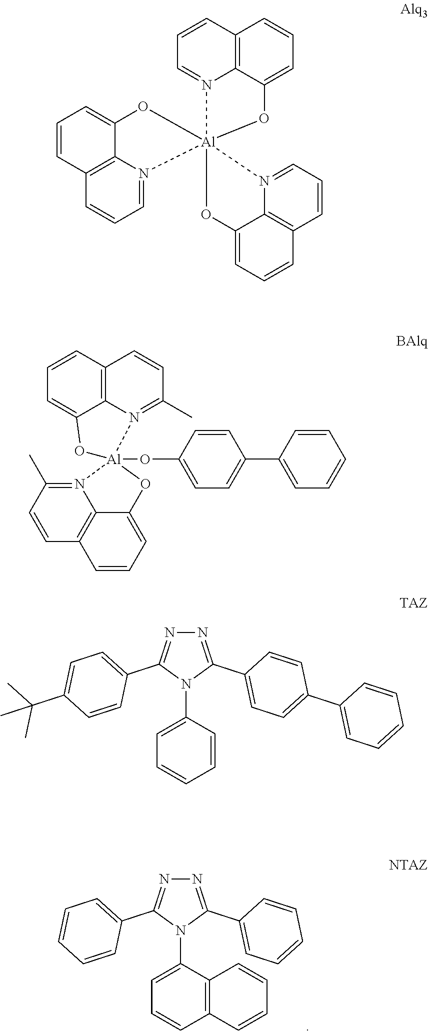

In one or more embodiments, the electron transport layer may include at least one of Compounds ET1 to ET25:

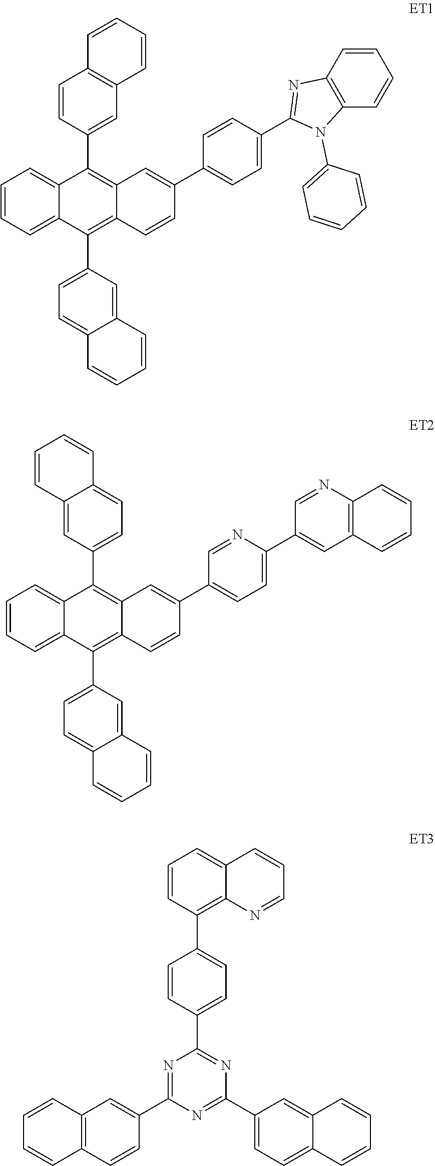 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

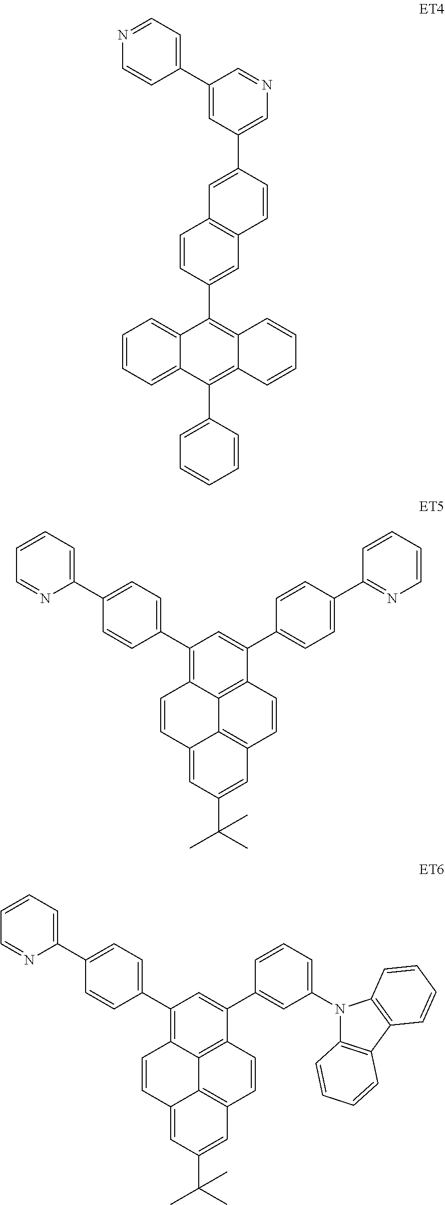 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

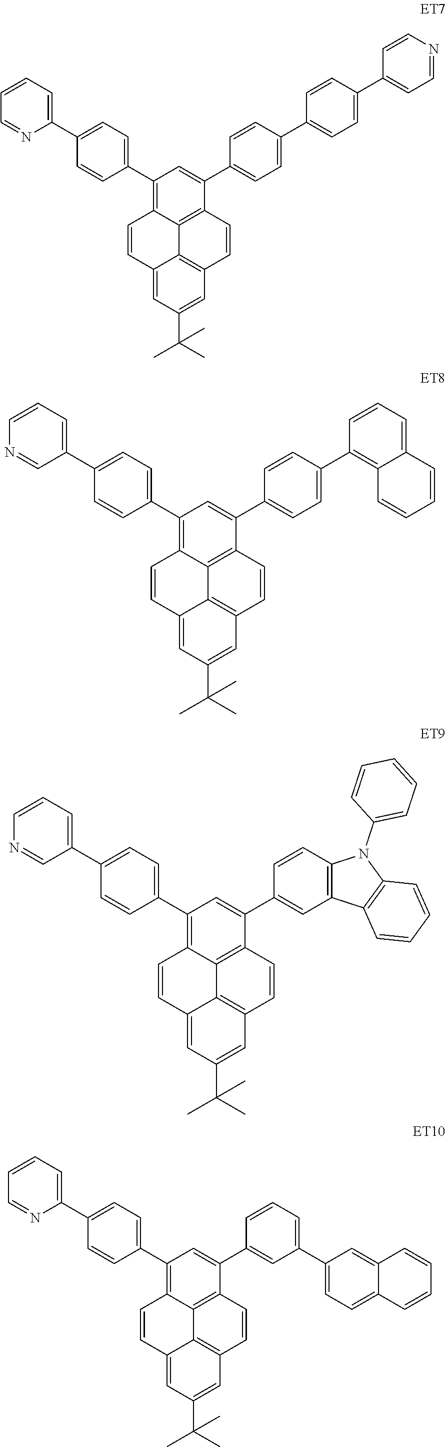 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34 ; CC(C)(C)c1cc2ccc3c(-c4ccc(-c5ccccn5)cc4)cc(-c4cccc(-c5ccc6ccccc6c5)c4)c4ccc(c1)c2c34]

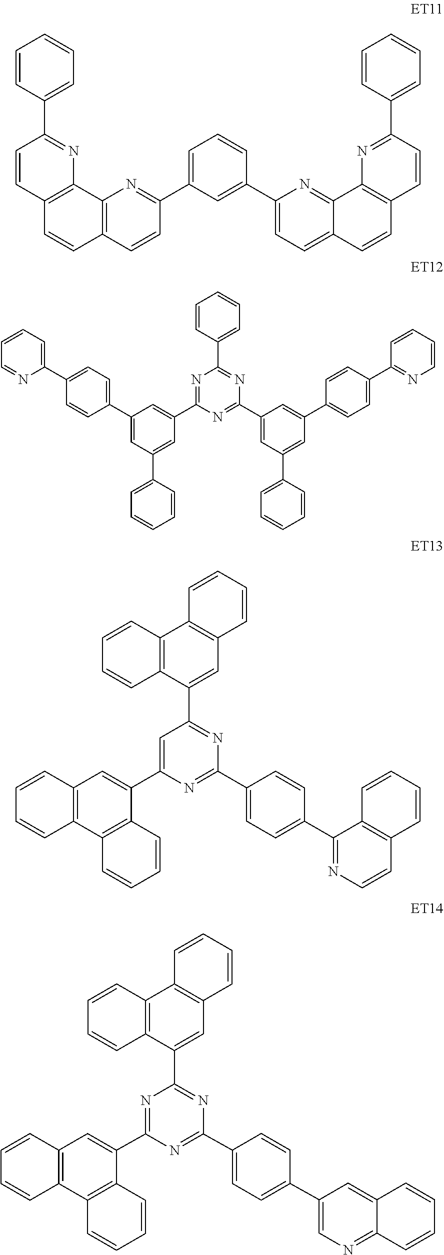 [SMILES: c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

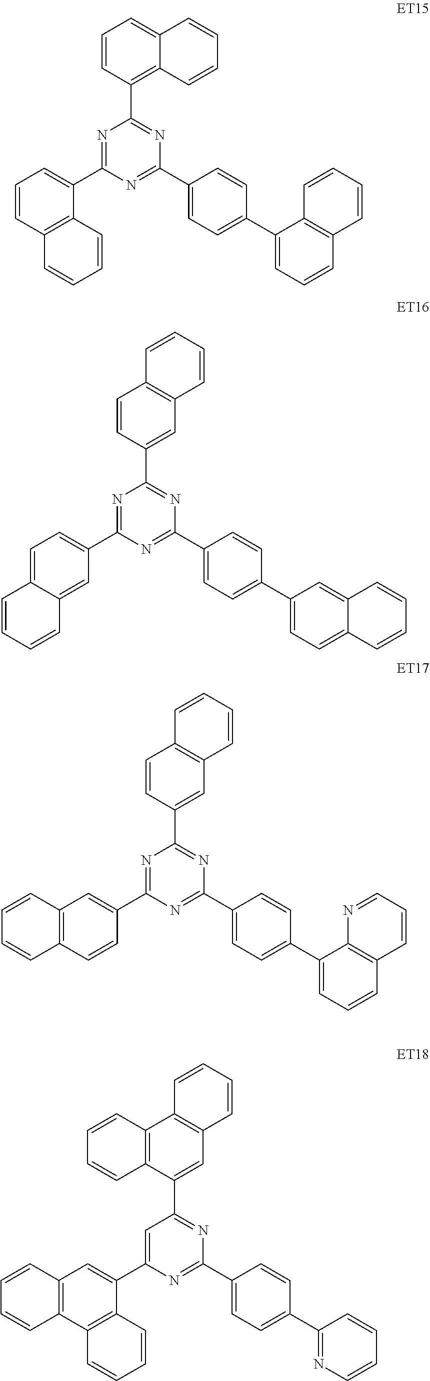 [SMILES: c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1 ; c1ccc(-c2ccc(-c3nc(-c4cc5ccccc5c5ccccc45)cc(-c4cc5ccccc5c5ccccc45)n3)cc2)nc1]

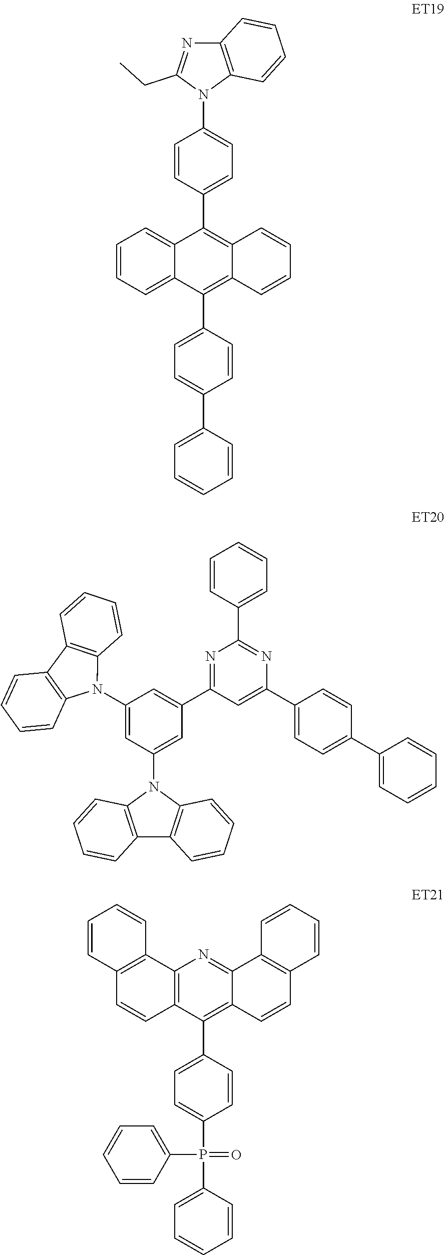

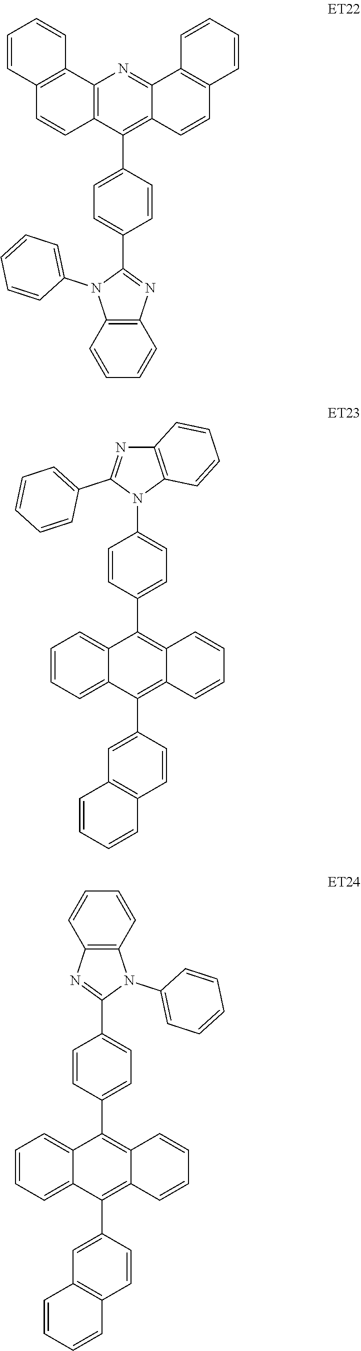

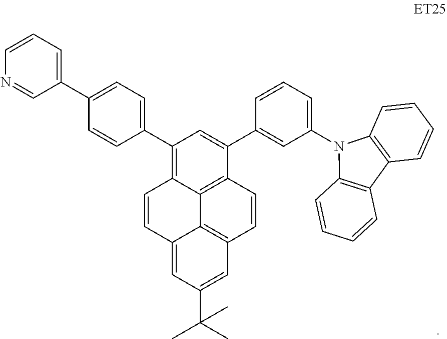 [SMILES: CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. When the thickness of the electron transport layer is within this range, excellent electron transporting characteristics may be obtained without a substantial increase in driving voltage.

The electron transport layer may further include, in addition to the materials described above, a metal-containing material.

The metal-containing material may include a Li complex. The Li complex may include, for example, Compound ET-D1 (lithium quinolate, LiQ) or ET-D2:

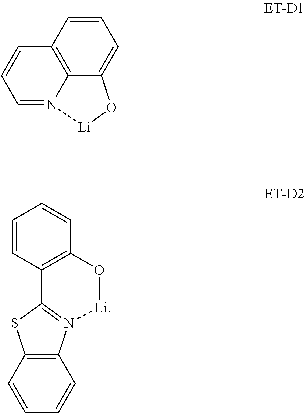

The electron transport region may include an electron injection layer that promotes the flow of electrons from the second electrode 19 thereinto.

The electron injection layer may include at least one LiF, NaCl, CsF, Li₂O, BaO, or any combination thereof.

A thickness of the electron injection layer may be in a range of about 1 Å to about 100 Å, for example, about 3 Å to about 90 Å. When the thickness of the electron injection layer is within this range, satisfactory electron injection characteristics may be obtained without a substantial increase in driving voltage.

### [Second Electrode 19]

The second electrode 19 is arranged on the organic layer 15. The second electrode 19 may be a cathode. A material for forming the second electrode 19 may be a metal, an alloy, an electrically conductive compound, or a combination thereof, which has a relatively low work function. For example, the material for forming the second electrode 19 may be lithium (Li), magnesium (Mg), aluminum (AI), aluminum-lithium (Al—Li), calcium (Ca), magnesium-indium (Mg—In), or magnesium-silver (Mg—Ag). In one or more embodiments, to manufacture a top-emission type light-emitting device, a transmissive electrode formed using ITO or IZO may be used as the second electrode 19.

Hereinbefore, the organic light-emitting device has been described with reference to the FIGURE, but embodiments are not limited thereto.

### [Electronic Apparatus]

Another aspect of the disclosure provides an electronic apparatus including the organic light-emitting device.

The electronic apparatus may be a light-emitting apparatus.

Explanation of Terms

The term “C₁-C₆₀ alkyl group” as used herein refers to a linear or branched saturated aliphatic hydrocarbon monovalent group having 1 to 60 carbon atoms, and examples thereof include a methyl group, an ethyl group, a propyl group, an isobutyl group, a sec-butyl group, a tert-butyl group, a pentyl group, an isoamyl group, and a hexyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by -OA₁₀₁ (wherein A₁₀₁ is the C₁-C₆₀ alkyl group), and examples thereof include a methoxy group, an ethoxy group, and an isopropoxy group.

The term “C₂-C₆₀ alkenyl group” as used herein refers to a hydrocarbon group formed by substituting at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof include an ethynyl group and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₂-C₁₀ heterocycloalkyl group” as used herein refers to a monovalent saturated monocyclic group having at least one heteroatom of N, O, P, S, Si, B, or Ge as a ring-forming atom and 1 to 10 carbon atoms, and examples thereof include a tetrahydrofuranyl group and a tetrahydrothiophenyl group. The term “C₂-C₁₀ heterocycloalkylene group” as used herein refers to a divalent group having the same structure as the C₂-C₁₀ heterocycloalkyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₂-C₁₀ heterocycloalkenyl group” as used herein refers to a monovalent monocyclic group that has at least one heteroatom of N, O, P, S, Si, B, or Ge as a ring-forming atom, 2 to 10 carbon atoms, and at least one double bond in its ring. Examples of the C₂-C₁₀ heterocycloalkenyl group include a 2,3-dihydrofuranyl group and a 2,3-dihydrothiophenyl group. The term “C₂-C₁₀ heterocycloalkenylene group” as used herein refers to a divalent group having the same structure as the C₂-C₁₀ heterocycloalkenyl group.

The term “C₆-C₆₀ aryl group” as used herein refers to a monovalent group that includes a carbocyclic aromatic system having 6 to 60 carbon atoms, and the term “C₆-C₆₀ arylene group” as used herein refers to a divalent group that includes a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the two or more rings may be fused to each other.

The term “C₇-C₆₀ alkylaryl group” as used herein refers to a C₆-C₆₀ aryl group substituted with at least one C₁-C₆₀ alkyl group.

The term “C₂-C₆₀ heteroaryl group” as used herein refers to a monovalent group having at least one heteroatom of N, O, P, S, Si, B, or Ge as a ring-forming atom and a heterocyclic aromatic system having 2 to 60 carbon atoms, and the term “C₂-C₆₀ heteroarylene group” as used herein refers to a divalent group having at least one heteroatom of N, O, P, S, Si, B, or Ge as a ring-forming atom and a heterocyclic aromatic system having 2 to 60 carbon atoms. Examples of the C₂-C₆₀ heteroaryl group include a pyridinyl group, a pyrimidinyl group, a pyrazinyl group, a pyridazinyl group, a triazinyl group, a quinolinyl group, and an isoquinolinyl group. When the C₂-C₆₀ heteroaryl group and the C₂-C₆₀ heteroarylene group each include two or more rings, the two or more rings may be fused to each other.

The term “C₂-C₆₀ alkylheteroaryl group” as used herein refers to a C₁-C₆₀ heteroaryl group substituted with at least one C₁-C₆₀ alkyl group.

The terms “a (C₁-C₂₀ alkyl)phenyl group” and “(C₁-C₂₀ alkyl)biphenyl group” refer to a monovalent phenyl group or biphenyl group, respectively, attached to an alkylene group. A non-limiting example of a (C₁-C₂₀ alkyl)phenyl group includes a —CH₂-phenyl group A non-limiting example of a (C₁-C₂₀ alkyl)biphenyl group includes a —CH₂-biphenyl group

The term “C₆-C₆₀ aryloxy group” as used herein refers to —OA₁₀₂ (wherein A₁₀₂ is the C₆-C₆₀ aryl group), and the term “C₆-C₆₀ arylthio group” as used herein refers to —SA₁₀₃ (wherein A₁₀₃ is the C₆-C₆₀ aryl group).

The term “monovalent non-aromatic condensed polycyclic group” as used herein refers to a monovalent group having two or more rings condensed with each other, only carbon atoms (for example, having 8 to 60 carbon atoms) as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group having two or more rings condensed with each other, a heteroatom of N, O, P, S, Si, B, or Ge, other than carbon atoms (for example, having 2 to 60 carbon atoms), as a ring-forming atom, and no aromaticity in its entire molecular structure. Examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

The term “C₅-C₆₀ carbocyclic group” as used herein refers to a saturated or unsaturated cyclic group including 5 to 60 carbon atoms only as ring-forming atoms. The C₅-C₆₀ carbocyclic group may be a monocyclic group or a polycyclic group, and may be a monovalent, divalent, trivalent, tetravalent, pentavalent, or hexavalent group, depending on the formula structure.

The term “C₂-C₆₀ heterocyclic group” as used herein refers to a saturated or unsaturated cyclic group having, as a ring-forming atom, at least one heteroatom of N, O, P, S, Si, B, or Ge other than 2 to 60 carbon atoms. The C₂-C₆₀ heterocyclic group may be a monocyclic group or a polycyclic group, and may be a monovalent, divalent, trivalent, tetravalent, pentavalent, or hexavalent group, depending on the formula structure.

As used herein, the number of carbons in each group that is substituted (e.g., C₁-C₆₀) excludes the number of carbons in the substituent. For example, a C₁-C₆₀ alkyl group can be substituted with a C₁-C₆₀ alkyl group. The total number of carbons included in the C₁-C₆₀ alkyl group substituted with the C₁-C₆₀ alkyl group is not limited to 60 carbons. In addition, more than one C₁-C₆₀ alkyl substituent may be present on the C₁-C₆₀ alkyl group. This definition is not limited to the C₁-C₆₀ alkyl group and applies to all substituted groups that recite a carbon range.

At least one substituent of the substituted C₅-C₆₀ carbocyclic group, the substituted C₂-C₆₀ heterocyclic group, the substituted π electron-deficient nitrogen-containing C₂-C₆₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, or a C₁-C₆₀ alkoxy group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₁)(Q₁₂)(Q₁₃), —B(Q₁₁)(Q₁₂), or —P(═O)(Q₁₁)(Q₁₂);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group; a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₁)(Q₂₂)(Q₂₃), —B(Q₂₁)(Q₂₂), —P(═O)(Q₂₁)(Q₂₂), or any combination thereof; or
—N(Q₃₁)(Q₃₂), —Si(Q₃₁)(Q₃₂)(Q₃₃), —B(Q₃₁)(Q₃₂), or —P(═O)(Q₃₁)(Q₃₂), and
Q₁₁ to Q₁₃, Q₂₁ to Q₂₃, and Q₃₁ to Q₃₃ may each independently be hydrogen, deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one a C₁-C₆₀ alkyl group, a C₆-C₆₀ aryl group, or a combination thereof, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group.

The term “room temperature” as used herein refers to a temperature of about 25° C.

Hereinafter, a compound and an organic light-emitting device according to embodiments will be described in detail with reference to Synthesis Examples and Examples. However, the disclosure is not limited thereto. The wording “‘B’ was used instead of ‘A’” as used in describing Synthesis Examples means that an amount of ‘A’ used was identical to an amount of ‘B’ used, in terms of a molar equivalent.

### EXAMPLES

### Synthesis Example 1: Synthesis of Compound 11

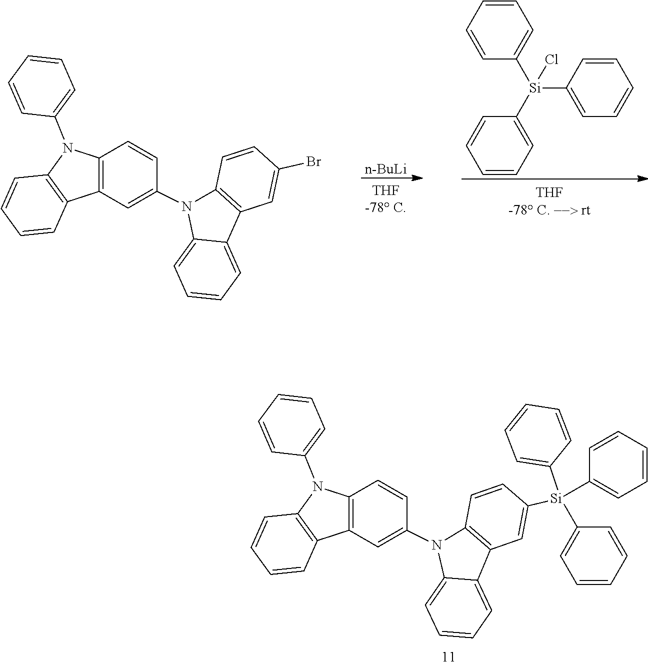

3′-bromo-9-phenyl-9H-3,9′-biscarbazole (10 g, 20.52 mmol) was dissolved in 50 ml of an anhydrous tetrahydrofuran (THF) solvent, and then stirred for 1 hour in a low temperature reactor at −78° C. Then, 2.5 M n-BuLi in hexane (9 ml, 22.57 mmol) was slowly added to the reaction mixture. After stirring at −78° C. for 40 minutes, a solution of triphenylsilane chloride (6.65 g, 22.57 mmol) dissolved in 20 ml of anhydrous THF was slowly added to the reaction mixture at −78° C. After 10 minutes, the reaction mixture was heated to room temperature, and then stirred for 18 hours. After quenching the reaction with water, an organic layer was extracted using ethyl acetate, and the obtained organic layer was dried using anhydrous magnesium sulfate (MgSO₄), concentrated, and then purified by silica gel column chromatography. The product was recrystallized using methanol to obtain 7.8 g (yield of 57%) of Compound 11 as a white solid.

LC-Mass (calculated: 666.25 g/mol, found: M+1=667 g/mol (M)).

### Synthesis Example 2: Synthesis of Compound 43

Compound 43 was synthesized according to the following reaction scheme.

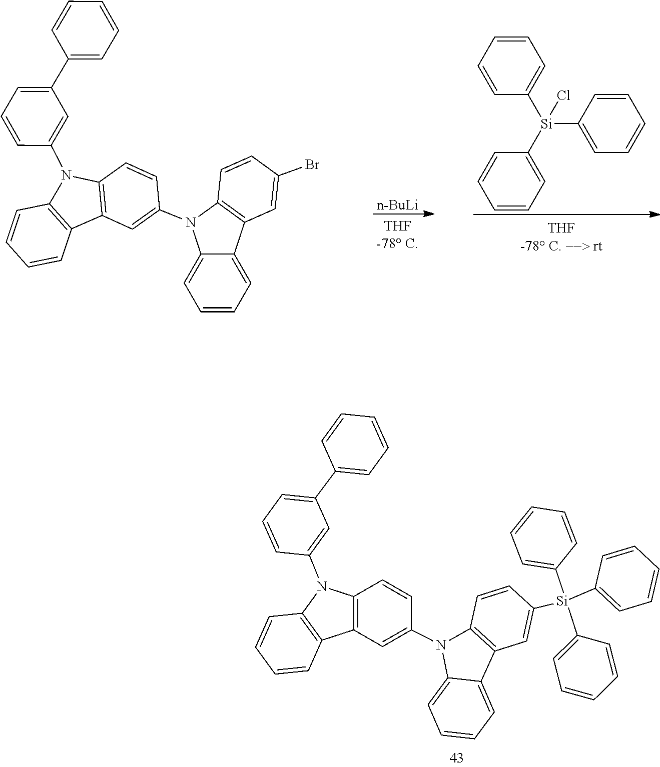

9-([1,1′-biphenyl]-3-yl)-3′-bromo-9H-3,9′-biscarbazole (5.0 g, 8.87 mmol) was dissolved in 50 ml of an anhydrous THF solvent, and then stirred for 1 hour in a low temperature reactor at −78° C. Then, 1.6 M n-BuLi in hexane (6.7 ml, 10.65 mmol) was slowly added to the reaction mixture. After stirring at −78° C. for 40 minutes, a solution of triphenylsilane chloride (3.4 g, 11.54 mmol) dissolved in 20 ml of anhydrous THF was slowly added to the reaction mixture at −78° C. After 10 minutes, the reaction mixture was heated to room temperature, and then stirred again for 18 hours. After quenching the reaction with water, an organic layer was extracted using ethyl acetate, and the obtained organic layer was dried using anhydrous magnesium sulfate (MgSO₄), concentrated, and then purified by silica gel column chromatography. The product was recrystallized using methanol to obtain 1.6 g (yield of 24%) of Compound 43 as a white solid.

LC-Mass (calculated: 742.28 g/mol, found: M+1=743 g/mol).

### Synthesis Example 3: Synthesis of Compound 1129

Compound 1129 was synthesized according to the following reaction scheme.

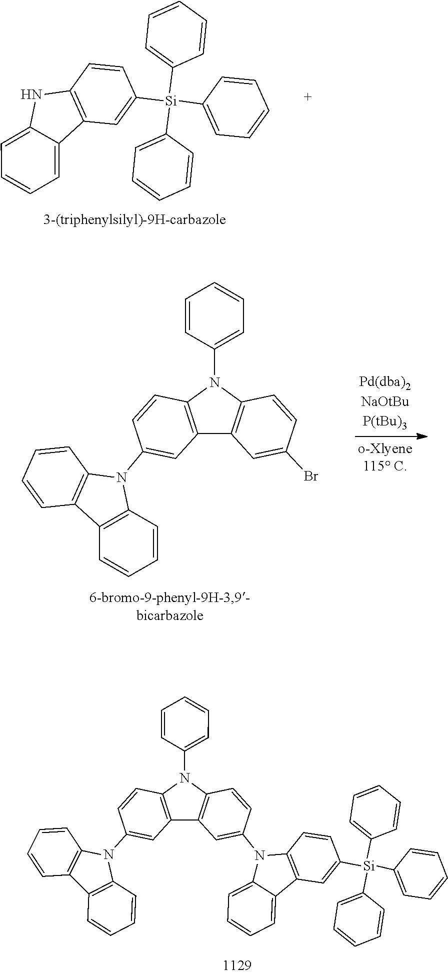 [SMILES: c1ccc([Si](c2ccccc2)(c2ccccc2)c2ccc3[nH]c4ccccc4c3c2)cc1 ; Brc1ccc2c(c1)c1cc(-n3c4ccccc4c4ccccc43)ccc1n2-c1ccccc1 ; c1ccc(-n2c3ccc(-n4c5ccccc5c5ccccc54)cc3c3cc(-n4c5ccccc5c5cc([Si](c6ccccc6)(c6ccccc6)c6ccccc6)ccc54)ccc32)cc1]

6-bromo-9-phenyl-9H-3,9′-biscarbazole (7.03 g, 14.42 mmol), 3-(triphenylsilyl)-9H-carbazole (7.37 g, 17.31 mmol), Pd(dba)₂ (0.83 g, 1.44 mmol), P(tBu)₃ (50 wt % toluene solution, 1.18 g, 2.88 mmol), and NaOtBu (2.77 g, 28.84 mmol) were dissolved in 40 ml of xylene. The reaction mixture was stirred under reflux for 12 hours. After completion of the reaction, the temperature was lowered to room temperature, and then, ethyl acetate and a saturated aqueous ammonium chloride solution were added to the reaction mixture. The filtrate was concentrated and purified through silica gel column chromatography to obtain 8.51 g (yield of 71%) of Compound 1129.

LC-Mass (calculated: 831.31 g/mol, found: M+1=832 g/mol).

### COMPARATIVE EXAMPLES

### Synthesis Example 4: Synthesis of Compound A

Compound A was synthesized according to the following reaction scheme.

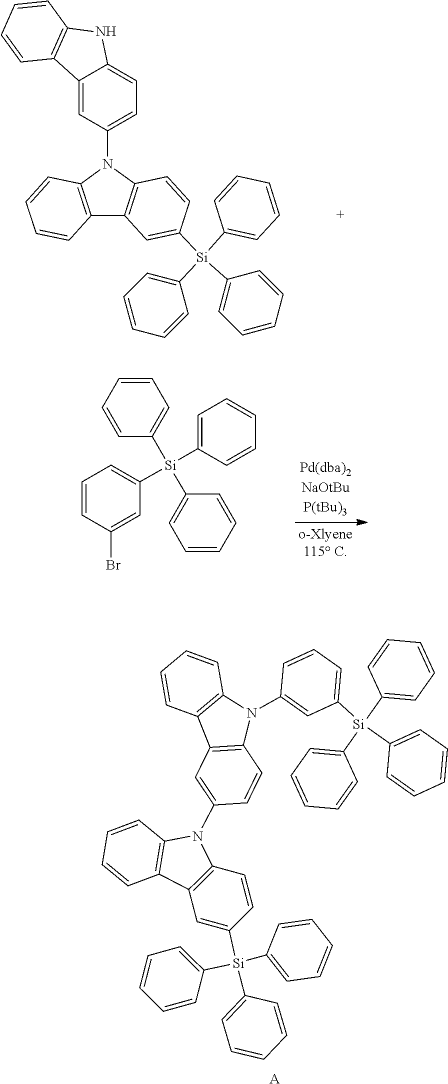

3′-(triphenylsilyl)-9H-3,9′-biscarbazole (4.49 g, 10.81 mmol), (3-bromophenyl)triphenylsilane (7.66 g, 12.97 mmol), Pd(dba)₂ (0.62 g, 1.08 mmol), P(tBu)₃ (50 wt % toluene solution, 0.88 g, 2.16 mmol), and NaOtBu (2.08 g, 21.61 mmol) were dissolved in 30 ml of xylene. The reaction mixture was stirred under reflux for 12 hours. After completion of the reaction, the temperature was lowered to room temperature, and then, ethyl acetate and a saturated aqueous ammonium chloride solution were added to the reaction mixture. An organic layer was extracted using ethyl acetate, dried using anhydrous MgSO₄, and then filtered. The filtrate was concentrated and purified through silica gel column chromatography to obtain 3.82 g (yield of 38%) of Compound A.

LC-Mass (calculated: 924.34 g/mol, found: M+1=925 g/mol).

### Synthesis Example 5: Synthesis of Compound B

Compound B was synthesized according to the following reaction scheme.

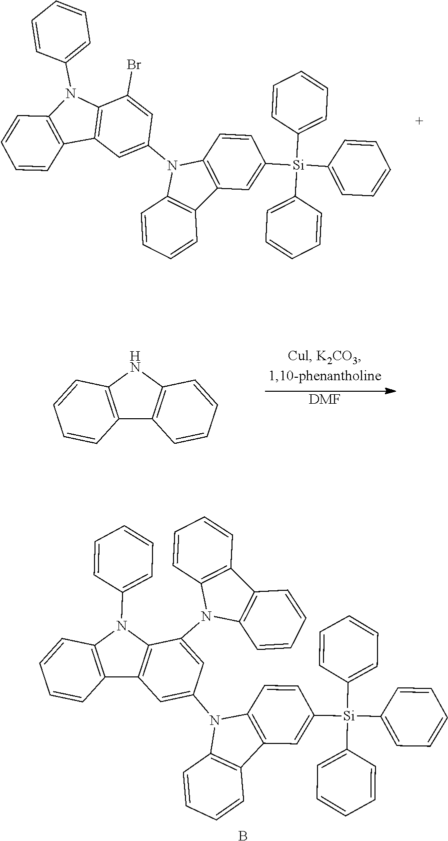

1-bromo-9-phenyl-3′-(triphenylsilyl)-9H-3,9′-biscarbazole (8.96 g, 12.02 mmol), 9H-carbazole (3.01 g, 18.03 mmol), CuI (2.29 g, 12.02 mmol), K₂CO₃ (8.31 g, 60.09 mmol), and 1,10-phenantholine (4.33 g, 24.04 mmol) were dissolved in 40 ml of N,N-dimethylformamide (DMF). The reaction mixture was stirred under reflux for 12 hours. After completion of the reaction, the temperature was lowered to room temperature, and then, ethyl acetate and a saturated aqueous ammonium chloride solution were added to the reaction mixture. An organic layer was extracted using ethyl acetate, dried using anhydrous MgSO₄, and then filtered. The filtrate was concentrated and purified through silica gel column chromatography to obtain 1.21 g (yield of 12%) of Compound B.

LC-Mass (calculated: 831.31 g/mol, found: M+1=832 g/mol).

### Synthesis Example 6: Synthesis of Compound C

Compound C was synthesized according to the following reaction scheme.

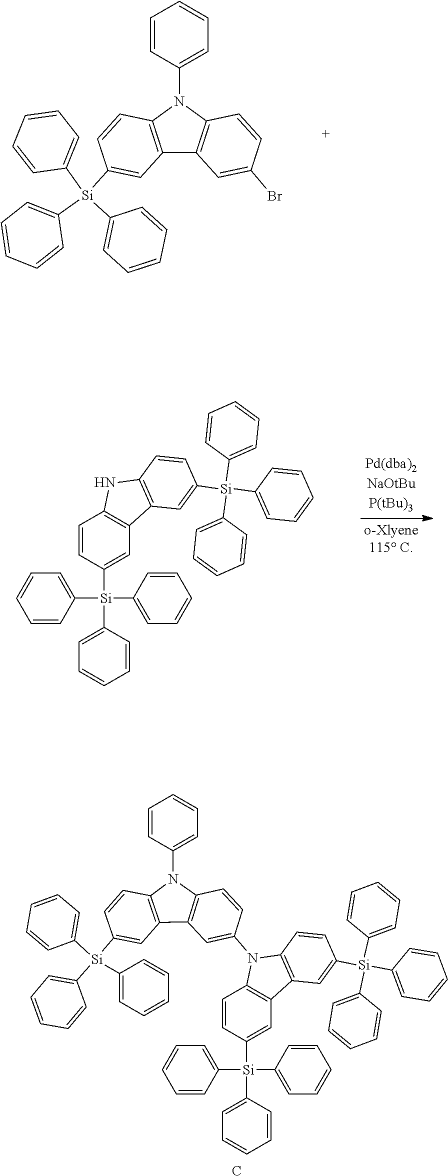

3-bromo-9-phenyl-6-(triphenylsilyl)-9H-carbazole (3.92 g, 6.76 mmol), 3,6-bis(triphenylsilyl)-9H-carbazole (5.55 g, 8.11 mmol), Pd(dba)₂ (0.39 g, 0.68 mmol), P(tBu)₃ (50 wt % toluene solution, 0.55 g, 1.35 mmol), and NaOtBu (1.30 g, 13.52 mmol) were dissolved in 20 ml of xylene. The reaction mixture was stirred under reflux for 12 hours. After completion of the reaction, the temperature was lowered to room temperature, and then, ethyl acetate and a saturated aqueous ammonium chloride solution were added to the reaction mixture. An organic layer was extracted using ethyl acetate, dried using anhydrous MgSO₄, and then filtered. The filtrate was concentrated and purified through silica gel column chromatography to obtain 4.20 g (yield of 53%) of Compound C.

LC-Mass (calculated: 1182.42 g/mol, found: M+1=1183 g/mol).

### Example 1

A glass substrate having an indium tin oxide (ITO) electrode (first electrode, anode) formed thereon at a thickness of 1,500 Å was washed with distilled water in the presence of ultrasound waves. Once the washing with distilled water was complete, ultrasound wave washing was performed on the substrate using solvents, such as isopropyl alcohol, acetone, and methanol. Subsequently, the substrate was dried, transferred to a plasma washer, washed for 5 minutes using oxygen plasma, and transferred to a vacuum depositor.

Compound HT3 and Compound HT-D2 were co-deposited on the ITO electrode of the glass substrate to form a hole injection layer having a thickness of 100 Å, Compound HT3 was deposited on the hole injection layer to form a hole transport layer having a thickness of 1,300 Å, and mCP was deposited on the hole transport layer to form an electron blocking layer having a thickness of 100 Å, thereby forming a hole transport region.

Compound 11 (host) and FIr6 (dopant, 10 wt %) were co-deposited on the hole transport region to form an emission layer having a thickness of 400 Å.

BCP was vacuum-deposited on the emission layer to form a hole blocking layer having a thickness of 100 Å, Compound ET3 and LiQ were co-vacuum-deposited on the hole blocking layer to form an electron transport layer having a thickness of 300 Å, LiQ was deposited on the electron transport layer to form an electron injection layer having a thickness of 10 Å, and an Al second electrode (cathode) having a thickness of 1,200 Å was formed on the electron injection layer, thereby completing the manufacture of an organic light-emitting device.

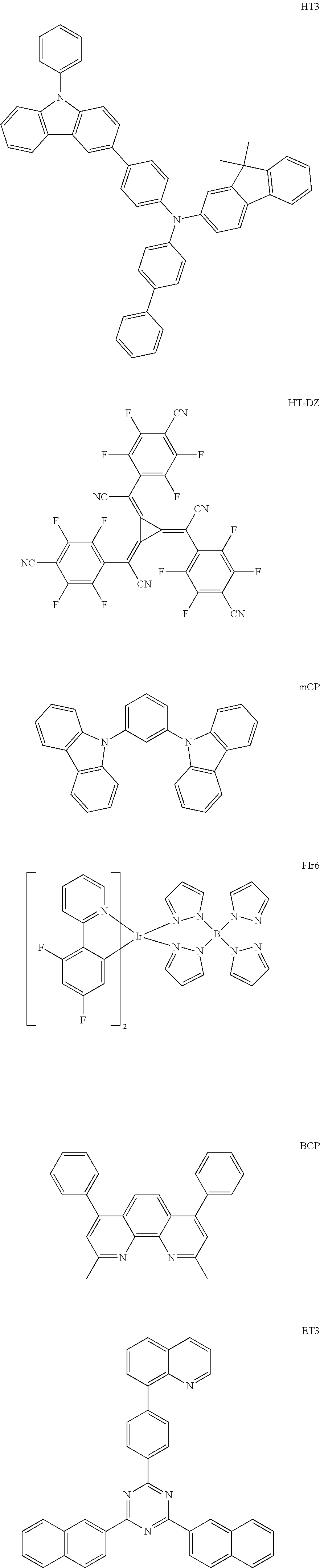

### Examples 2 and 3 and Comparative Examples 1 to 3

Organic light-emitting devices were manufactured in the same manner as in Example 1, except that compounds shown in Table 2 were each used instead of Compound 11 as a host in forming an emission layer.

### Evaluation Example 3: Evaluation of Characteristics of Organic Light-Emitting Devices

The driving voltage (V), current efficiency (cd/A), and lifespan (T₉₅ at 1,000 nit, hr) of each of the organic light-emitting devices manufactured according to Examples 1 to 3 and Comparative Examples 1 to 3 were evaluated using a current-voltmeter (Keithley 2400) and a luminance meter (Minolta Cs-1000A). Results thereof are shown in Table 2. The lifespan (T₉₅) refers to a time that is taken for the luminance to become 95% with respect to the initial luminance of 100%. The driving voltage, current efficiency, and lifespan shown in Table 2 are represented as relative values when the driving voltage, current efficiency, and lifespan of the organic light-emitting device manufactured according to Comparative Example 1 are 100%.

TABLE 2

| | | | Driving | Current | Lifespan |
|---|---|---|---|---|---|
| | | | voltage | efficiency | (LT₉₅) |
| | | Luminance | (Relative | (Relative | (Relative |
| | Host | (cd/m²) | value, %) | value, %) | value, %) |
| Example 1 | Compound | 1000 | 98 | 131 | 279 |
| | 11 | | | | |
| Example 2 | Compound | 1000 | 99 | 135 | 216 |
| | 43 | | | | |
| Example 3 | Compound | 1000 | 101 | 123 | 191 |
| | 1129 | | | | |
| Comparative | Compound | 1000 | 100 | 100 | 100 |
| Example 1 | A | | | | |
| Comparative | Compound | 1000 | 121 | 83 | 51 |
| Example 2 | B | | | | |
| Comparative | Compound | 1000 | 116 | 92 | 32 |
| Example 3 | C | | | | |

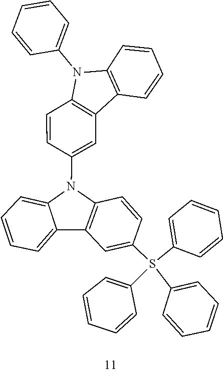 [SMILES: c1ccc(-n2c3ccccc3c3cc(-n4c5ccccc5c5cc(S(c6ccccc6)(c6ccccc6)c6ccccc6)ccc54)ccc32)cc1]

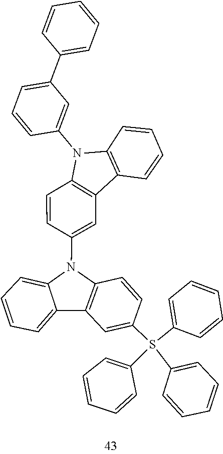 [SMILES: c1ccc(-c2cccc(-n3c4ccccc4c4cc(-n5c6ccccc6c6cc(S(c7ccccc7)(c7ccccc7)c7ccccc7)ccc65)ccc43)c2)cc1]

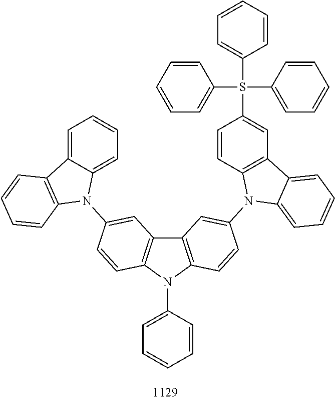 [SMILES: c1ccc(-n2c3ccc(-n4c5ccccc5c5ccccc54)cc3c3cc(-n4c5ccccc5c5cc(S(c6ccccc6)(c6ccccc6)c6ccccc6)ccc54)ccc32)cc1]

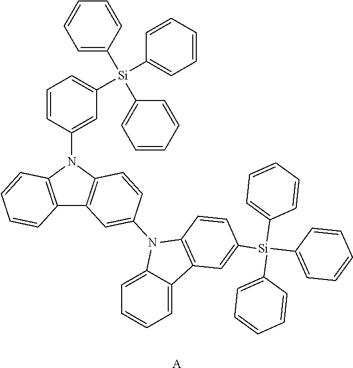

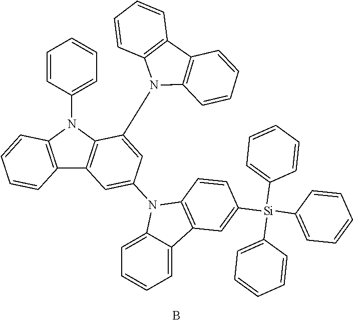

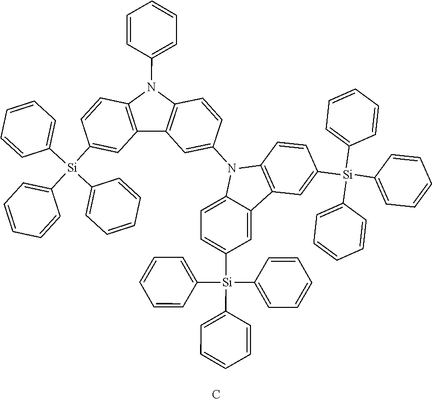

Referring to Table 2, it was confirmed that the organic light-emitting devices of Examples 1 to 3 had low driving voltage, high efficiency, and/or long lifespan, as compared with the organic light-emitting devices of Comparative Examples 1 to 3.

The condensed cyclic compound has improved electric characteristics and thermal stability. Accordingly, an organic light-emitting device including the condensed cyclic compound may have low driving voltage, high current efficiency, high power efficiency, high quantum efficiency, and/or long lifespan characteristics.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A condensed cyclic compound represented by Formula 1: 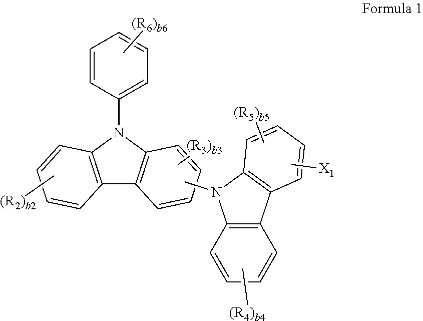
wherein, in Formula 1,
X₁ is represented by Formula 2, 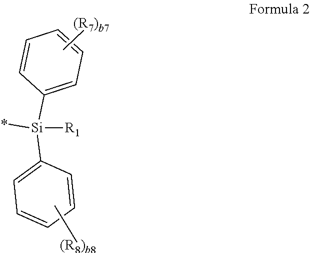
in Formulae 1 and 2,
R₁ is a substituted or unsubstituted C₁-C₆₀ alkyl group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group,
R₂ is hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —N(Q₁)(Q₂), or —B(Q₁)(Q₂),
R₃ is hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted monovalent non-aromatic condensed polycyclic group, —Si(Q₁)(Q₂)(Q₃), —N(Q₁)(Q₂), or —B(Q₁)(Q₂),
R₄ to R₈ are each independently hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), or —B(Q₁)(Q₂),
b2 and b4 are each independently an integer from 1 to 4,
b3 and b5 are each independently an integer from 1 to 3,
b6 to b8 are each independently an integer from 1 to 5,
Q₁ to Q₃ are each independently hydrogen, deuterium, —F, —Cl, —Br, —I, a hydroxyl group, a cyano group, a nitro group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkylaryl group, a C₆-C₆₀ aryloxy group, a C₆-C₆₀ arylthio group, a C₁-C₆₀ heteroaryl group, a C₂-C₆₀ alkylheteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, a C₁-C₆₀ alkyl group substituted with at least one deuterium, —F, a cyano group, a C₁-C₂₀ alkyl group, a C₆-C₃₀ aryl group, or a combination thereof, or a C₆-C₆₀ aryl group substituted with at least one deuterium, —F, a cyano group, a C₁-C₂₀ alkyl group, a C₆-C₃₀ aryl group, or a combination thereof, and
* indicates a binding site to a neighboring atom.

2. The condensed cyclic compound of claim 1, wherein X₁ is represented by Formula 2-1: 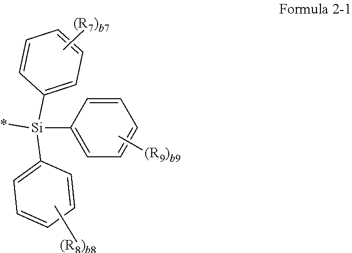
wherein, in Formula 2-1,
R₉ is the same as described in connection with R₇ in claim 1,
b9 is the same as described in connection with b7 in claim 1, and
* indicates a binding site to a neighboring atom.

3. The condensed cyclic compound of claim 1, wherein R₂ is:
hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, or a C₁-C₂₀ alkoxy group;
a C₁-C₂₀ alkyl group or a C₁-C₂₀ alkoxy group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a pyridinyl group, a pyrimidinyl group, or any combination thereof;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, an imidazopyrimidinyl group, —Si(Q₁₁)(Q₁₂)(Q₁₃), —B(Q₁₁)(Q₁₂), —N(Q₁₁)(Q₁₂), or any combination thereof; or
—Si(Q₁)(Q₂)(Q₃), —B(Q₁)(Q₂), or —N(Q₁)(Q₂),
R₃ is: hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, or a C₁-C₂₀ alkoxy group;
a C₁-C₂₀ alkyl group or a C₁-C₂₀ alkoxy group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a pyridinyl group, a pyrimidinyl group, or any combination thereof;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, or a chrysenyl group;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, or a chrysenyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, an imidazopyrimidinyl group, —Si(Q₁₁)(Q₁₂)(Q₁₃), —B(Q₁₁)(Q₁₂), —N(Q₁₁)(Q₁₂), or any combination thereof; or
—Si(Q₁)(Q₂)(Q₃), —B(Q₁)(Q₂), or —N(Q₁)(Q₂), and
Q₁ to Q₃ and Q₁₁ to Q₁₃ are each independently:
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group; or
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, or a naphthyl group, each substituted with at least one deuterium. a phenyl group, or any combination thereof.

4. The condensed cyclic compound of claim 1, wherein R₄ to R₈ are each independently:
hydrogen, deuterium, —F, —Cl, —Br, —I, a hydroxyl group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, or a C₁-C₂₀ alkoxy group;
a C₁-C₂₀ alkyl group or a C₁-C₂₀ alkoxy group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a pyridinyl group, a pyrimidinyl group, or any combination thereof;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group;
a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, or an imidazopyrimidinyl group, each substituted with at least one deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, a bicyclo[2.2.1]heptanyl group, an adamantanyl group, a norbornanyl group, a norbornenyl group, a cyclopentenyl group, a cyclohexenyl group, a cycloheptenyl group, a phenyl group, a biphenyl group, a C₁-C₂₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzocarbazolyl group, a dibenzocarbazolyl group, an imidazopyridinyl group, an imidazopyrimidinyl group, —B(Q₁₁)(Q₁₂), —N(Q₁₁)(Q₁₂), or any combination thereof; or
—B(Q₁)(Q₂) or —N(Q₁)(Q₂), and
Q₁, Q₂, Q₁₁, and Q₁₂ are each independently:
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group; or
a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, or a naphthyl group, each substituted with at least one deuterium and a phenyl group.

5. The condensed cyclic compound of claim 1, wherein the condensed cyclic compound is represented by Formula 1-1: 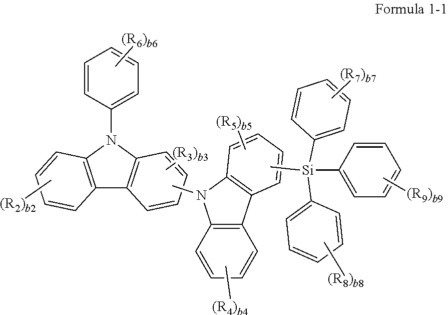
wherein, in Formula 1-1,
R₉ is the same as described in connection with R₇ in claim 1, and
b9 is the same as described in connection with b7 in claim 1.

6. The condensed cyclic compound of claim 1, wherein a moiety represented by 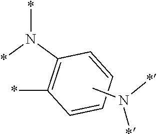
in Formula 1-1 is represented by one of Formulae 1B-1 to 1B-4, and
a moiety represented by 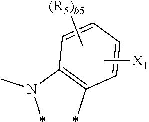
in Formula 1-1 is represented by one of Formulae 1D-1 to 1D-4: 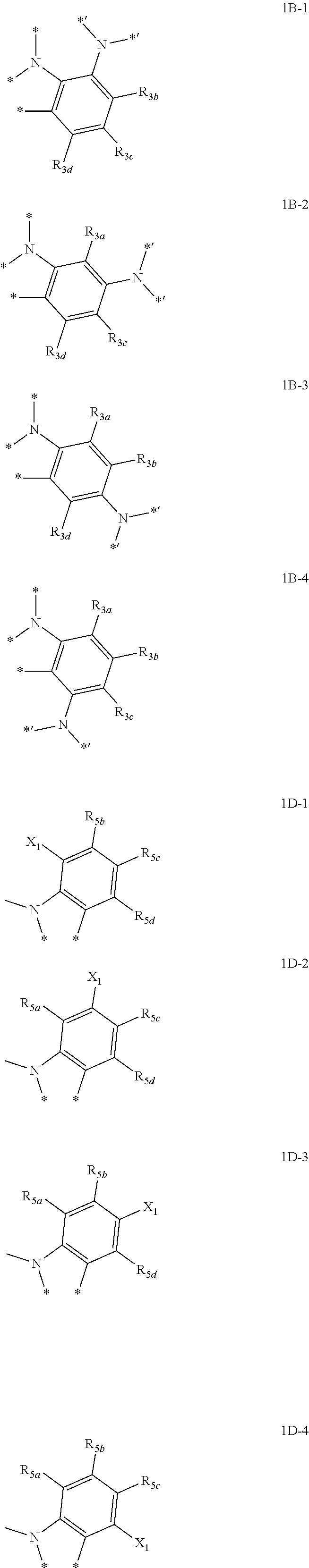
wherein, in Formulae 1B-1 to 1B-4 and 1D-1 to 1D-4,
R₃ₐ to R_{3d} are each the same as described in connection with R₃ in claim 1,
R₅ₐ to R_{5d} are each the same as described in connection with R₅ in claim 1, and
* and *′ each indicate a binding site to a neighboring atom.

7. The condensed cyclic compound of claim 1, wherein the condensed cyclic compound is represented by one of Formulae 1-11 to 1-14:

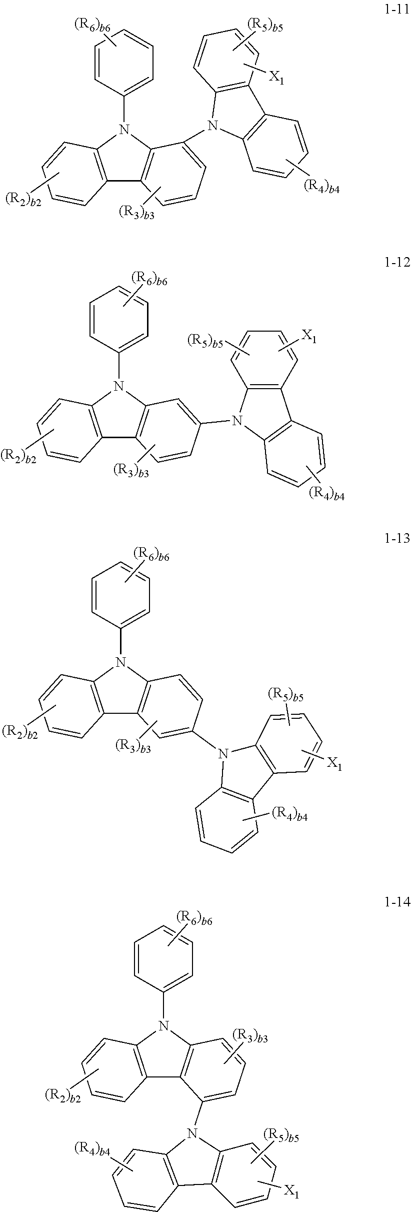

8. The condensed cyclic compound of claim 7, wherein a moiety represented by 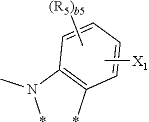
in Formulae 1-11 to 1-14 is represented by one of Formulae 1D-1 to 1D-4: 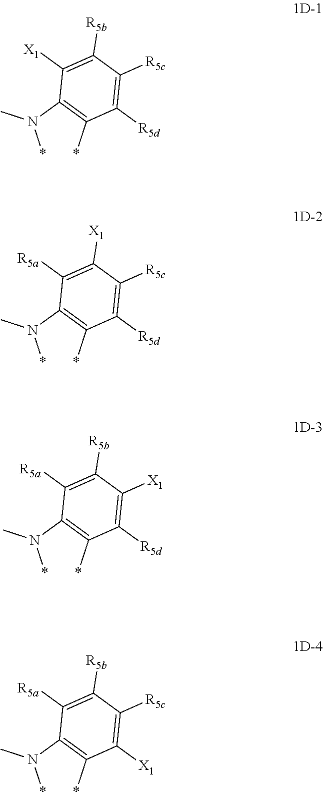
wherein, in Formulae 1D-1 to 1D-4,
R₅ₐ to R_{5d} are each the same as described in connection with R₅ in claim 1, and
* indicates a binding site to a neighboring atom.

9. The condensed cyclic compound of claim 1, wherein the condensed cyclic compound is represented by one of Formulae 1-21 to 1-24:

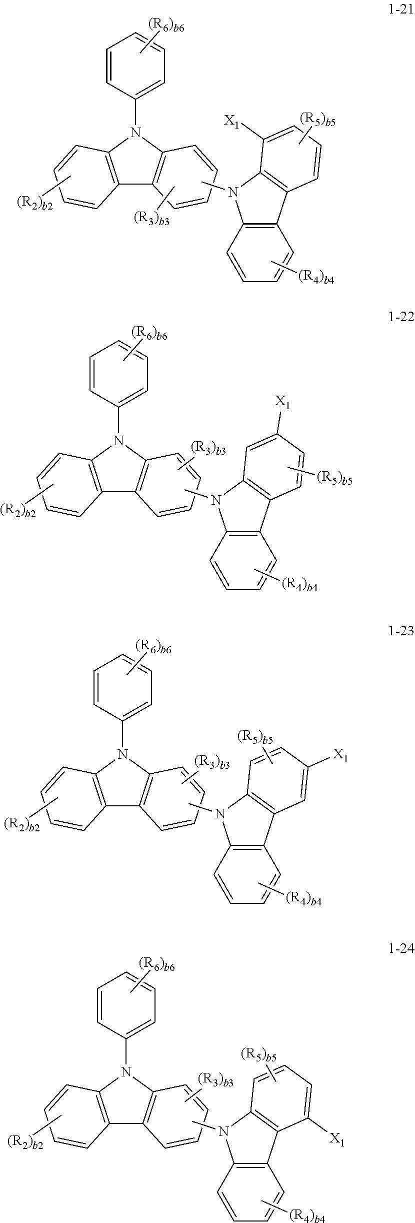

10. The condensed cyclic compound of claim 9, wherein a moiety represented by 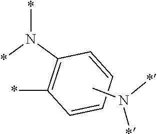
in Formulae 1-21 to 1-24 is represented by one of Formulae 1B-1 to 1B-4: 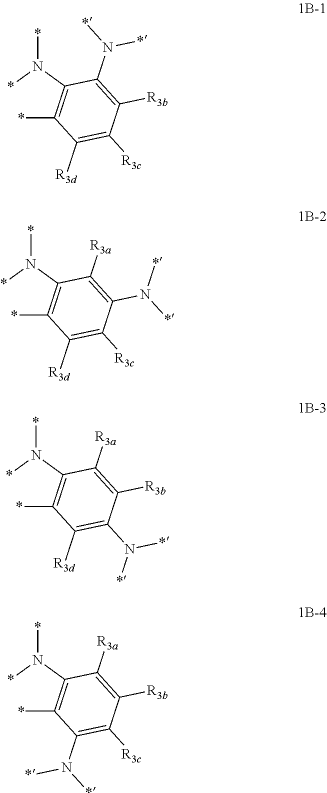
wherein, in Formulae 1B-1 to 1B-4,
R₃ₐ to R_{3d} are each the same as described in connection with R₃ in claim 1, and
* and *′ each indicate a binding site to a neighboring atom.

11. The condensed cyclic compound of claim 1, wherein, in Formula 1, i) R₂ is hydrogen, deuterium, a methyl group, an ethyl group, an n-propyl group, an isopropyl group, an n-butyl group, an isobutyl group, a sec-butyl group, a tert-butyl group, a phenyl group, a carbazolyl group, or one of a methyl group, an ethyl group, an n-propyl group, an isopropyl group, an n-butyl group, an isobutyl group, a sec-butyl group, a tert-butyl group, a phenyl group or a carbazolyl group, each substituted with deuterium; ii) R₃ is hydrogen, deuterium, a methyl group, an ethyl group, an n-propyl group, an isopropyl group, an n-butyl group, an isobutyl group, a sec-butyl group, a tert-butyl group, a phenyl group, or one of a methyl group, an ethyl group, an n-propyl group, an isopropyl group, an n-butyl group, an isobutyl group, a sec-butyl group, a tert-butyl group, or a phenyl group, each substituted with deuterium; iii) R₆ is hydrogen, deuterium, a phenyl group, a biphenyl group, or one of a phenyl group or a biphenyl group, each substituted with deuterium; iv) R₄ is hydrogen, deuterium, a methyl group, an ethyl group, an n-propyl group, an isopropyl group, an n-butyl group, an isobutyl group, a sec-butyl group, a tert-butyl group, a phenyl group, a carbazolyl group, or one of a methyl group, an ethyl group, an n-propyl group, an isopropyl group, an n-butyl group, an isobutyl group, a sec-butyl group, a tert-butyl group, a phenyl group, or a carbazolyl group, each substituted with deuterium; or v) R₅ is hydrogen, deuterium, a methyl group, an ethyl group, an n-propyl group, an isopropyl group, an n-butyl group, an isobutyl group, a sec-butyl group, a tert-butyl group, a phenyl group, a carbazolyl group, or one of a methyl group, an ethyl group, an n-propyl group, an isopropyl group, an n-butyl group, an isobutyl group, a sec-butyl group, a tert-butyl group, a phenyl group, or a carbazolyl group, each substituted with deuterium; or
in Formula 2, R₁ is a methyl group, an ethyl group, an n-propyl group, an isopropyl group, an n-butyl group, an isobutyl group, a sec-butyl group, a tert-butyl group, a phenyl group, or one of a methyl group, an ethyl group, an n-propyl group, an isopropyl group, an n-butyl group, an isobutyl group, a sec-butyl group, a tert-butyl group, or a phenyl group, each substituted with deuterium.

12. An organic light-emitting device comprising:
a first electrode;
a second electrode; and
an organic layer arranged between the first electrode and the second electrode and comprising an emission layer,
wherein the organic layer comprises the condensed cyclic compound of claim 1.

13. The organic light-emitting device of claim 12, wherein the emission layer comprises the condensed cyclic compound.

14. The organic light-emitting device of claim 13, wherein the emission layer comprises a host and a dopant,
the host and the dopant are different from each other,
an amount of the host is greater than an amount of the dopant, and
the host comprises the condensed cyclic compound.

15. The organic light-emitting device of claim 14, wherein the emission layer emits blue light.

16. The organic light-emitting device of claim 14, wherein the dopant is a phosphorescent dopant, a fluorescent dopant, a delayed fluorescence dopant, or a combination thereof.

17. The organic light-emitting device of claim 13, wherein the emission layer comprises a host, a dopant, and a sensitizer,
the host, the dopant, and the sensitizer are different from each other,
an amount of the host is greater than an amount of the sensitizer,
the amount of the sensitizer is greater than an amount of the dopant, and
the host comprises the condensed cyclic compound.

18. The organic light-emitting device of claim 17, wherein the emission layer emits blue light.

19. The organic light-emitting device of claim 17, wherein the dopant is a fluorescent dopant and/or a delayed fluorescence dopant.

20. An electronic apparatus comprising the organic light-emitting device of claim 12.
